(19) United States
(12) Patent Application Publication
(10) Pub. No.: US 2025/0072284 A1
(43) Pub. Date: Feb. 27, 2025

(54) LIGHT EMITTING ELEMENT, FUSED POLYCYCLIC COMPOUND FOR THE SAME, AND DISPLAY DEVICE INCLUDING THE LIGHT EMITTING ELEMENT

(71) Applicant: Samsung Display Co., Ltd., Yongin-si (KR)

(72) Inventors: CHANSEOK OH, Yongin-si (KR); TAEIL KIM, Yongin-si (KR); SUN YOUNG PAK, Yongin-si (KR); MinJae SUNG, Yongin-si (KR); MUN-KI SIM, Yongin-si (KR); Giwoong HAN, Yongin-si (KR)

(21) Appl. No.: 18/766,504

(22) Filed: Jul. 8, 2024

(30) Foreign Application Priority Data
Aug. 2, 2023 (KR) 10-2023-0101265

(51) Int. Cl. H10K 85/60; C07B 59/00; C09K 11/06; H10K 101/20

(52) U.S. Cl. CPC H10K 85/658; C07B 59/004; C09K 11/06; H10K 85/6572; C07B 2200/05; H10K 2101/20

(57) ABSTRACT

A light emitting element including a first electrode, a second electrode facing the first electrode, and a functional layer provided between the first electrode and the second electrode is provided. The functional layer includes a fused polycyclic compound represented by Formula 1 that may function as a dopant material. The fused ring core includes three aromatic rings connected to at least three heteroatoms, and includes a first linker connected to at least two substituents such as a polycyclic heteroaryl group and an electron-withdrawing group.

### CROSS-REFERENCE TO RELATED APPLICATION

This application claims priority to and the benefit of Korean Patent Application No. 10-2023-0101265, filed on Aug. 2, 2023 in the Korean Intellectual Property Office, the entire content of which is hereby incorporated by reference.

### BACKGROUND

### 1. Field

The present disclosure herein relates to a light emitting element, a fused polycyclic compound utilized therein, and a display device including the light emitting element.

### 2. Description of the Related Art

Recently, the development of an organic electroluminescence display device as an image display device is being actively conducted. Unlike liquid crystal display devices and/or the like, the organic electroluminescence display device is a so-called “self-luminescent” display device in which holes and electrons, respectively, injected from a first electrode and a second electrode combine in an emission layer of the display device. Subsequently, a luminescent material including an organic compound in the emission layer (e.g., light-emitting layer) emits light to implement display (e.g., of an image).

Implementation of an organic electroluminescence element to a display device requires, (or there is a demand or desire for) an organic electroluminescence element having a relatively low driving voltage, a relatively high luminous efficiency, and a relatively long service life. Therefore the need or desire exists for continued research and of development focused on materials, for an organic electroluminescence element, capable of stably attaining such (e.g., desired) characteristics.

In recent years, particularly in order to implement a highly efficient organic electroluminescence element, technologies are being developed that focus on phosphorescence emission (e.g., utilizing triplet state energy) and/or fluorescence (e.g., utilizing triplet-triplet annihilation (TTA) in which singlet excitons are generated by collision of triplet excitons). In addition, technologies focused on thermally activated delayed fluorescence (TADF) materials utilizing delayed fluorescence phenomenon are being developed or pursued.

### SUMMARY

One or more aspects of embodiments of the present disclosure provides a light emitting element in which luminescence characteristics and an element service life are improved.

One or more aspects of embodiments of the present disclosure also provides a fused polycyclic compound capable of improving luminescence characteristics and an element service life of a light emitting element.

One or more aspects of embodiments of the present disclosure also provides a display device including the light emitting element in which the luminous efficiency and service life are improved, thereby having excellent or suitable display quality.

One or more embodiments of the present disclosure provides a light emitting element including a first electrode, a second electrode provided on the first electrode, and at least one functional layer which is provided between the first electrode and the second electrode and includes a first compound represented by Formula 1.

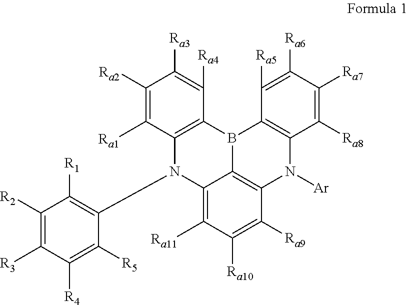

In Formula 1, Rₐ₁ to Rₐ₁₁ and R₁ to R₅ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, at least one selected from among R₁ to R₅ is a cyano group, at least another one (e.g., a remaining one selected from among R₁ to R₅) is a substituent represented by Formula 2, and Ar is a substituted or unsubstituted aryl group having 6 to 30 ring-forming carbon atoms, or a substituted or unsubstituted heteroaryl group having 2 to 30 ring-forming carbon atoms.

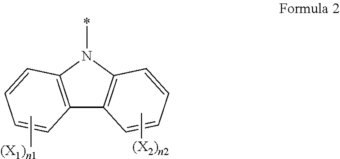

In Formula 2, X₁ and X₂ may each independently be a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, n1 and n2 may each independently be an integer of 0 to 4, and

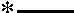 [SMILES: *C]

is a position linked to Formula 1.

In one or more embodiments, the at least one functional layer may include an emission layer, a hole transport region provided between the first electrode and the emission layer, and an electron transport region provided between the emission layer and the second electrode, and the emission layer may include the first compound.

In one or more embodiments, the emission layer may be to emit (e.g., configured to emit) delayed fluorescence having a luminescence center wavelength of about 430 nanometer (nm) to about 490 nm.

In one or more embodiments, the first compound represented by Formula 1 may be represented by Formula 1-1 or Formula 1-2.

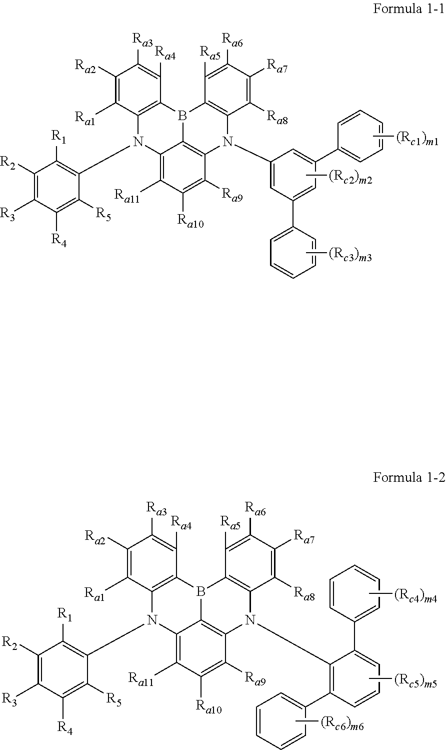

In Formula 1-1 and Formula 1-2, R_{c1} to R_{c6} may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, m1, m3, m4, and m6 may each independently be an integer of 0 to 3, m2 and m5 may each independently be an integer of 0 to 3, and Rₐ₁ to Rₐ₁₁ and R₁ to R₅ may each independently be as defined for Formula 1.

In one or more embodiments, R_{c1} to R_{c6} may each independently be a hydrogen atom, a deuterium atom, a substituted or unsubstituted t-butyl group, or a substituted or unsubstituted phenyl group.

In one or more embodiments, the first compound represented by Formula 1 may be represented by Formula 1-3.

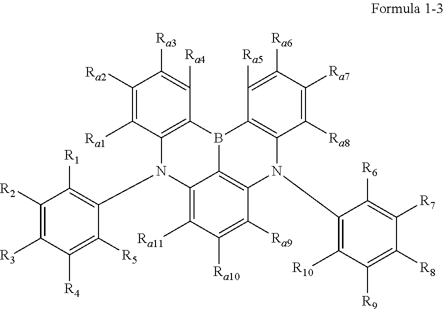

In Formula 1-3, R₆ to R₁₀ may each independently be a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, at least one selected from among R₆ to R₁₀ may be a cyano group, at least another one (e.g., a remaining one selected from among R₆ to R₁₀) may be a substituent represented by Formula 2, and Rₐ₁ to Rₐ₁₁ and R₁ to R₅ may each independently be as defined for Formula 1.

In one or more embodiments, the first compound represented by Formula 1 may be represented by any one selected from among Formula 1-4 to Formula 1-6.

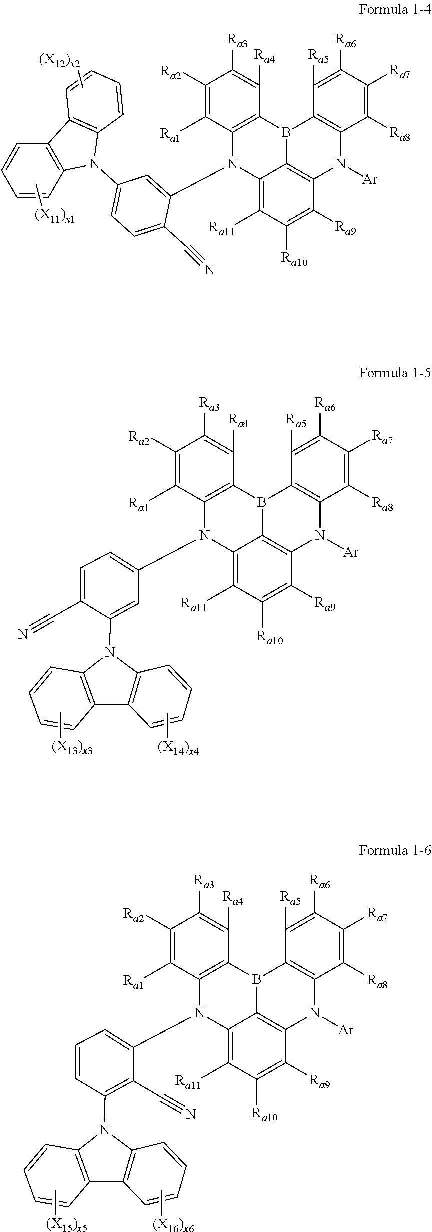

In Formula 1-4 to Formula 1-6, X₁₁ to X₁₆ may each independently be a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, x1 to x6 may each independently be an integer of 0 to 4, and Rₐ₁ to Rₐ₁₁ and Ar may each independently be as defined for Formula 1.

In one or more embodiments, X₁₁ to X₁₆ may each independently be a hydrogen atom, a deuterium atom, a cyano group, a substituted or unsubstituted t-butyl group, or a substituted or unsubstituted phenyl group.

In one or more embodiments, the first compound represented by Formula 1 may be represented by any one selected from among Formula 1-7 to Formula 1-9.

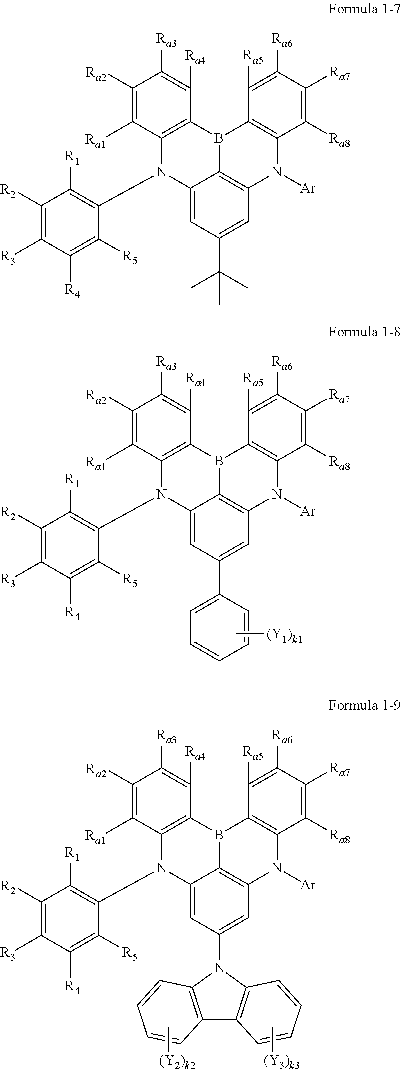

In Formula 1-7 to Formula 1-9, Y₁ to Y₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, k1 may be an integer of 0 to 5, k2 and k3 may each independently be an integer of 0 to 4, and Rₐ₁ to Rₐ₈, R₁ to R₅, and Ar may each independently be as defined for Formula 1.

In one or more embodiments, in Formula 1, Rₐ₂, Rₐ₃, Rₐ₆, and Rₐ₇ may each independently be a hydrogen atom, a deuterium atom, or a substituent represented by any one selected from among Formula 3-1 to Formula 3-7.

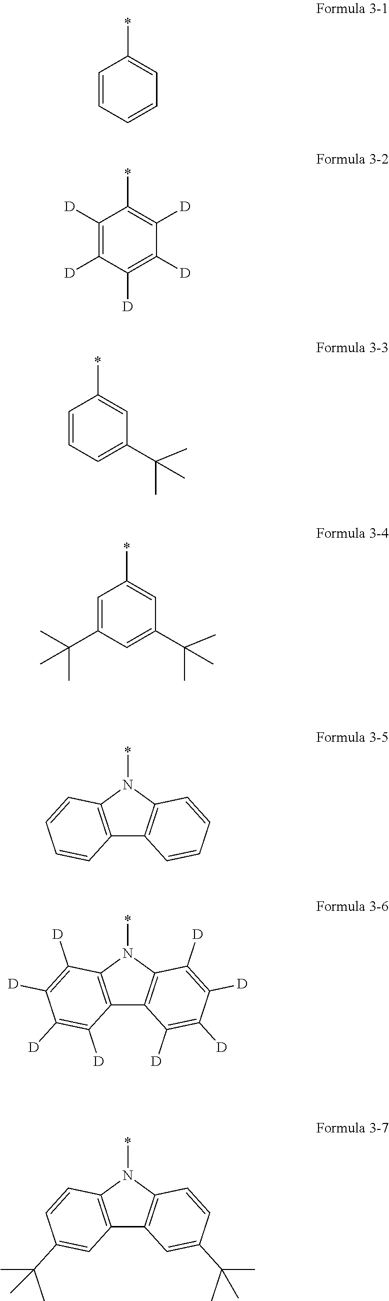

In Formula 3-1 to Formula 3-7,

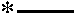 [SMILES: *C]

may be a position linked to Formula 1.

In one or more embodiments of the present disclosure, a fused polycyclic compound may be represented by Formula 1.

In one or more embodiments of the present disclosure, a display device may include a base layer, a circuit layer provided on the base layer, and a display element layer which is provided on the circuit layer and includes a light emitting element. In one or more embodiments, the light emitting element may include a first electrode, a second electrode provided on the first electrode, and an emission layer which is provided between the first electrode and the second electrode and includes the first compound according to one or more one or more embodiments as described herein.

### BRIEF DESCRIPTION OF DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is a plan view of a display device according to one or more embodiments of the present disclosure;

FIG. 2 is a cross-sectional view of the display device according to the embodiment of the present disclosure;

FIG. 3 is a cross-sectional view schematically illustrating a light emitting element according to one or more embodiments of the present disclosure;

FIG. 4 is a cross-sectional view schematically illustrating a light emitting element according to one or more embodiments of the present disclosure;

FIG. 5 is a cross-sectional view schematically illustrating a light emitting element according to one or more embodiments of the present disclosure;

FIG. 6 is a cross-sectional view schematically illustrating a light emitting element according to one or more embodiments of the present disclosure;

FIGS. 7-8 are each a cross-sectional view of a display device according to one or more embodiments of the present disclosure;

FIG. 9 is a cross-sectional view illustrating a display device according to one or more embodiments of the present disclosure;

FIG. 10 is a cross-sectional view illustrating a display device according to one or more embodiments of the present disclosure; and

FIG. 11 is a view illustrating a vehicle in which display devices are provided according to embodiments of the present disclosure.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are utilized for referring to like elements. In the accompanying drawings, the dimensions of each structure are exaggeratingly illustrated for clarity of the present disclosure. It will be understood that, although the terms “first,” “second,” and/or the like, may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the present disclosure.

As utilized herein, the singular forms, “a,” “an,” and “the” are intended to include the plural forms as well, unless the context clearly indicates otherwise.

As utilized herein, the term “and/or” includes any and all combinations that the associated configurations can define.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

In the present application, it will be understood that the terms “include,” “includes,” “including,” “comprise,” “comprises”, “comprising,” “has,” “having,” “have,” and/or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present application, when a layer, a film, a region, or a plate is referred to as being “on” or “in an upper proton of” another layer, film, region, or plate, it may be not only “directly on” the layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be provided above the other part, or provided under the other part as well. The preceding comparative terms are relative concepts and are described based on the directions indicated in the drawings. It will be understood that the terms have a relative concept and are described on the basis of the orientation depicted in the drawings. It will be understood that the spatially relative terms are intended to encompass different orientations of the device in use or operation in addition to the orientation depicted in the drawings. For example, if the device in the drawings is turned over, elements described as “beneath” other elements or features would then be oriented “above” or “over” the other elements or features. Thus, the term “beneath” may encompass both an orientation of above and below. The device may be otherwise oriented (rotated 90 degrees or at other orientations), and the spatially relative descriptors used herein should be interpreted accordingly.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same meaning as commonly understood by one of ordinary skill in the art to which this present disclosure belongs. It will be further understood that terms, such as those defined in commonly utilized dictionaries, should be interpreted as having a meaning that is consistent with their meaning in the context of the relevant art and will not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component’” “exclude a or any ‘component’”, “‘component’-free”, and/or the like refers to that the “component” not being added, selected or utilized as a component in the composition/sturcture, but the “component” of less than a suitable amount may still be included due to other impurities and/or external factor.

### Definitions

In the specification, the term “substituted or unsubstituted” may refer to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified herein may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 1 to 10. Examples of the alkenyl group include a vinyl group, a 1-butenyl group, a 1-pentenyl group, a 1,3-butadienyl aryl group, a styrenyl group, a styryl vinyl group, and/or the like, but the embodiment of the present disclosure is not limited thereto.

In the specification, an alkynyl group refers to a hydrocarbon group. including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, and/or the like, but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

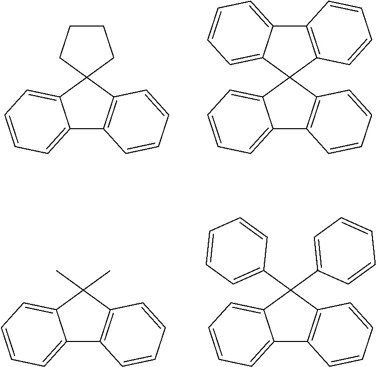

The heterocyclic group herein refers to any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiment of the present disclosure is not limited thereto.

In the specification, the description of the aryl group may be applied to an arylene group except that the arylene group is a divalent group. The description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

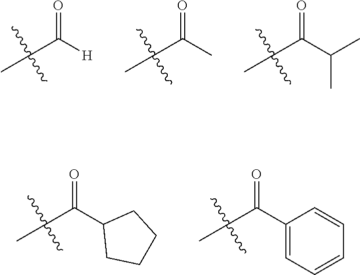

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined herein. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but the embodiment of the present disclosure is not limited thereto.

The boron group herein may refer to that a boron atom is bonded to the alkyl group or the aryl group as defined herein. The boron group includes an alkyl boron group and an aryl boron group. Examples of the boron group may include a dimethylboron group, a trimethylboron group, a t-butyldimethylboron group, a diphenylboron group, a phenylboron group, and/or the like, but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described herein.

In the specification, the aryl group among an aryloxy group, an arylthio group, an arylsulfoxy group, an arylamino group, an arylboron group, an arylsilyl group, an arylamine group is the same as the examples of the aryl group described herein.

In the specification, a direct linkage may refer to a single bond.

In some embodiments, in the specification,

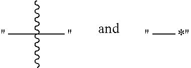

refer to a position to be connected.

Hereinafter, embodiments of the present disclosure will be described with reference to the accompanying drawings.

### Display Apparatus

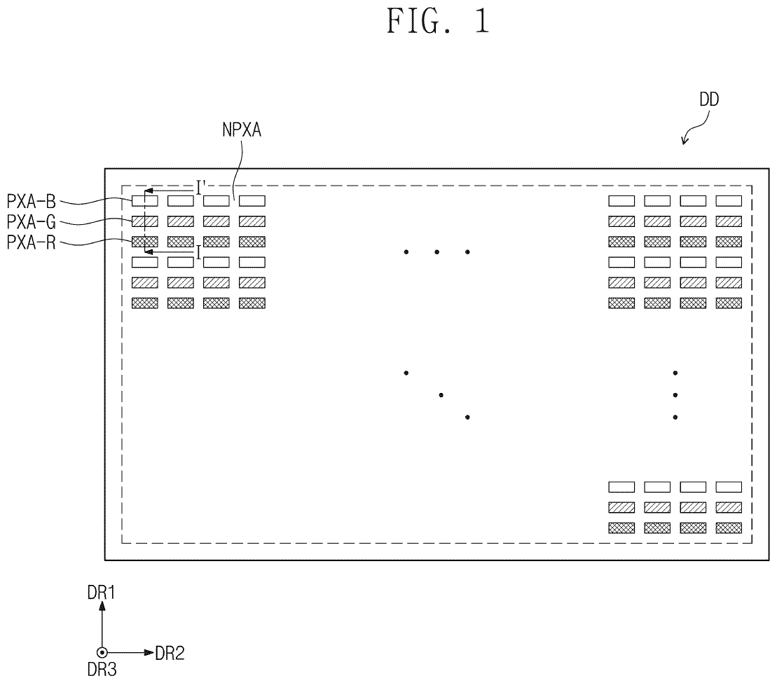

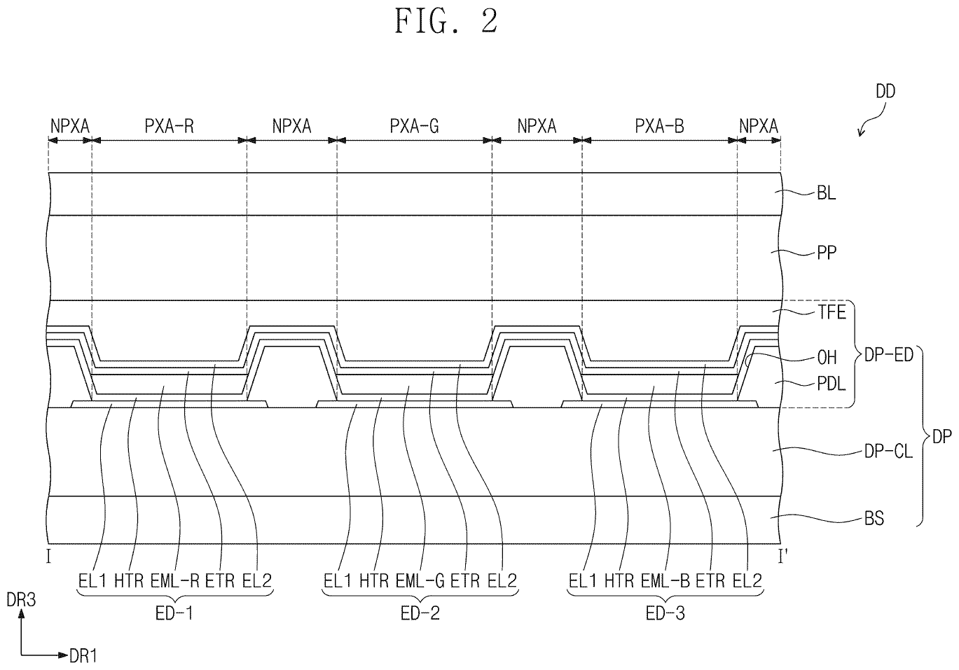

FIG. 1 is a plan view illustrating one or more embodiments of a display apparatus DD. FIG. 2 is a cross-sectional view of the display apparatus DD of the embodiment. FIG. 2 is a cross-sectional view illustrating a part taken along line I-I′ of FIG. 1.

The display apparatus DD may include a display panel DP and an optical layer PP provided on the display panel DP. The display panel DP includes light emitting devices ED-1, ED-2, and ED-3. The display apparatus DD may include a plurality of light emitting devices ED-1, ED-2, and ED-3. The optical layer PP may be provided on the display panel DP to control reflected light in the display panel DP due to external light. The optical layer PP may include, for example, a polarization layer or a color filter layer. In some embodiments, unlike the configuration illustrated in the drawing, the optical layer PP may not be provided (e.g., be excluded) from the display apparatus DD of one or more embodiments.

A base substrate BL may be provided on the optical layer PP. The base substrate BL may be a member which provides a base surface on which the optical layer PP provided. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments unlike the configuration illustrated, in one or more embodiments, the base substrate BL may not be provided (e.g., be excluded).

The display apparatus DD according to one or more embodiments may further include a filling layer. The filling layer may be provided between a display device layer DP-ED and the base substrate BL. The filling layer may be an organic material layer. The filling layer may include at least one of an acrylic-based resin, a silicone-based resin, or an epoxy-based resin (e.g., at least one selected from among an acrylic-based resin, a silicone-based resin, and an epoxy-based resin).

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 provided between portions of the pixel defining film PDL, and an encapsulation layer TFE provided on the light emitting devices ED-1, ED-2, and ED-3.

The base layer BS may be a member which provides a base surface on which the display device layer DP-ED is provided. The base layer BS may be a glass substrate, a metal substrate, a plastic substrate, and/or the like. However, the embodiment is not limited thereto, and the base layer BS may be an inorganic layer, an organic layer, or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting devices ED-1, ED-2, and ED-3 of the display device layer DP-ED.

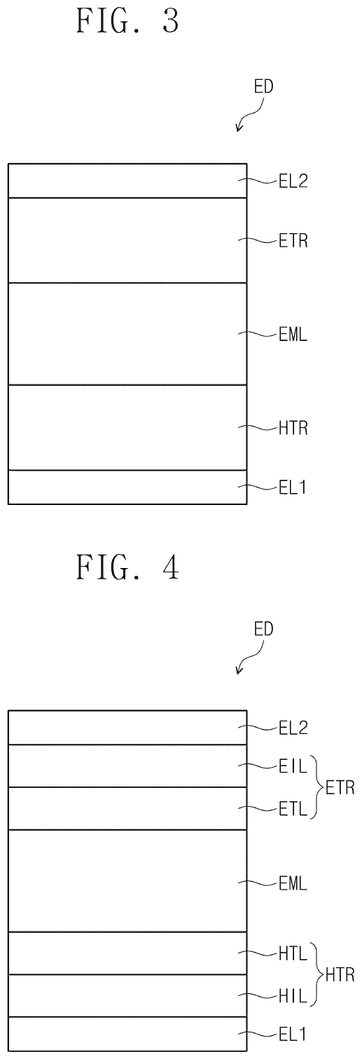

Each of the light emitting devices ED-1, ED-2, and ED-3 may have a structure of each light emitting device ED of embodiments according to FIGS. 3 to 6, as described in more detail herein. Each of the light emitting devices ED-1, ED-2, and ED-3 may include a first electrode EL1, a hole transport region HTR, a layer selected from emission layers EML-R, EML-G, and EML-B, an electron transport region ETR, and a second electrode EL2.

FIG. 2 illustrates one or more embodiments in which the emission layers EML-R, EML-G, and EML-B of the light emitting devices ED-1, ED-2, and ED-3 are provided in openings OH defined in the pixel defining film PDL, and the hole transport region HTR, the electron transport region ETR, and the second electrode EL2 are provided as a common layer in the entire light emitting devices ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in one or more embodiments may be provided by being patterned in an inkjet printing method.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be provided on the second electrode EL2 and may be provided filling the opening OH.

Referring to FIGS. 1 and 2, the display apparatus DD may include one or more non-light emitting region(s) NPXA and also include light emitting regions PXA-R, PXA-G, and PXA-B. The light emitting regions PXA-R, PXA-G, and PXA-B may be regions in which light generated by the respective light emitting devices ED-1, ED-2, and ED-3 are emitted. The light emitting regions PXA-R, PXA-G, and PXA-B may be spaced and/or apart from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In some embodiments, in the specification, the light emitting regions PXA-R, PXA-G, and PXA-B may respectively correspond to pixels. The pixel defining film PDL may divide the light emitting devices ED-1, ED-2, and ED-3. The emission layers EML-R, EML-G, and EML-B of the light emitting devices ED-1, ED-2, and ED-3 may be provided in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display apparatus DD according to one or more embodiments, the plurality of light emitting devices ED-1, ED-2 and ED-3 may be to emit light beams having wavelengths different from each other. For example, in one or more embodiments, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, the embodiment of the present disclosure is not limited thereto, and the first to third light emitting devices ED-1, ED-2, and ED-3 may be to emit light beams in substantially the same wavelength range or at least one light emitting device may be to emit a light beam in a wavelength range different from the others. For example, the first to third light emitting devices ED-1, ED-2, and ED-3 may all emit blue light.

The light emitting regions PXA-R, PXA-G, and PXA-B in the display apparatus DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B each may be arranged along the second directional axis DR2. In some embodiments, the red light emitting region PXA-R, the green light emitting region PXA-G, and the blue light emitting region PXA-B may be alternately arranged with each other in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2 (e.g., in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, the arrangement form of the light emitting regions PXA-R, PXA-G, and PXA-B may be a pentile (PENTILE™) arrangement form or a diamond (Diamond Pixel™) arrangement form, (PENTILE™ and Diamond Pixel™ are registered trademarks owned by Samsung Display Co., Ltd.).

In some embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

Hereinafter, FIG. 3 to FIG. 6 are cross-sectional views schematically showing light emitting devices according to one or more embodiments. The light emitting device ED of one or more embodiments may include a first electrode EL1, a hole transport region HTR, an emission layer EML, an electron transport region ETR, and a second electrode EL2 stacked in order.

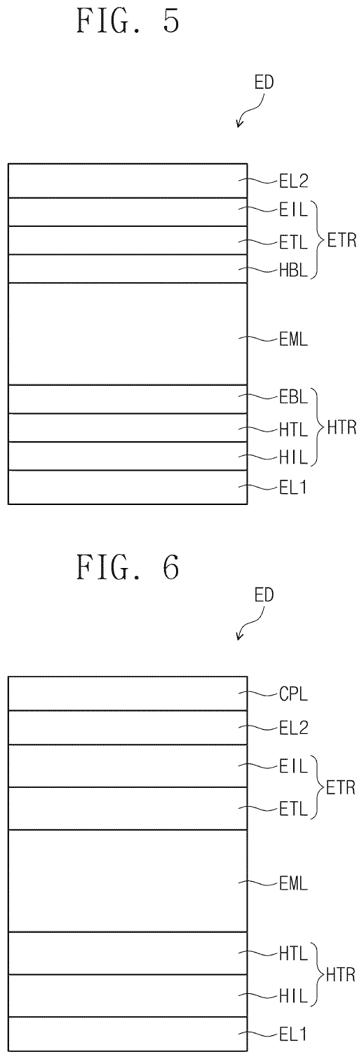

Compared with FIG. 3, FIG. 4 illustrates a cross-sectional view of a light emitting device ED of one or more embodiments, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light emitting device ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting device ED of one or more embodiments including a capping layer CPL provided on a second electrode EL2.

The first electrode EL1 has conductivity (e.g., is a conductor). The first electrode EL1 may include (e.g., be formed of) a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film including (e.g., formed of) the herein-described materials, and a transparent conductive film including (e.g., formed of) ITO, IZO, ZnO, ITZO, and/or the like. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the herein-described metal materials, combinations of at least two metal materials of the herein-described metal materials, oxides of the herein-described metal materials, and/or the like. The thickness of the first electrode EL1 may be from about 700 angstrom (Å) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer including (e.g., formed of) a single material, a single layer including (e.g., formed of) a plurality of different materials, or a multilayer structure including a plurality of layers including (e.g., formed of) a plurality of different materials.

For example, the hole transport region HTR may have a single layer structure of the hole injection layer HIL or the hole transport layer HTL, or may have a single layer structure including (e.g., formed of) a hole injection material and a hole transport material. In some embodiments, the hole transport region HTR may have a single layer structure including (e.g., formed of) a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

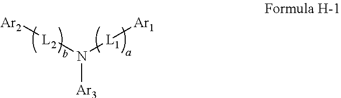

In Formula H-1 herein, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. The variables a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 herein may be a monoamine compound. In some embodiments, the compound represented by Formula H-2 herein may be a diamine compound in which at least one selected from among Ar₁ to Ar₃ includes the amine group as a substituent. In some embodiments, the compound represented by Formula H-1 herein may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one (e.g., one) selected from among the compounds in Compound Group H. However, the compounds listed in Compound Group H are examples, and the compounds represented by Formula H-1 are not limited to those represented by Compound Group H:

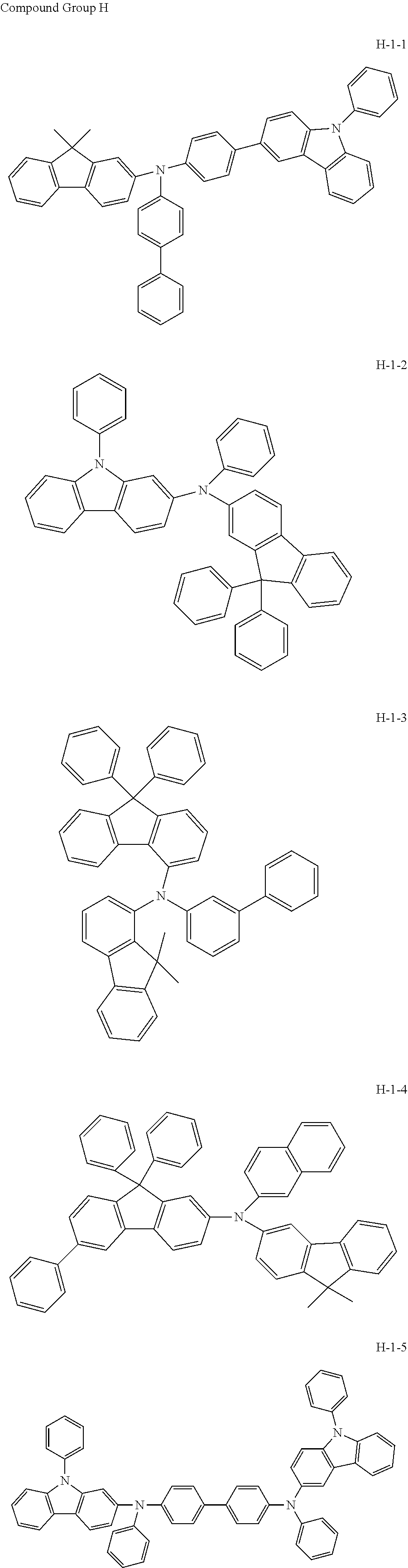 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

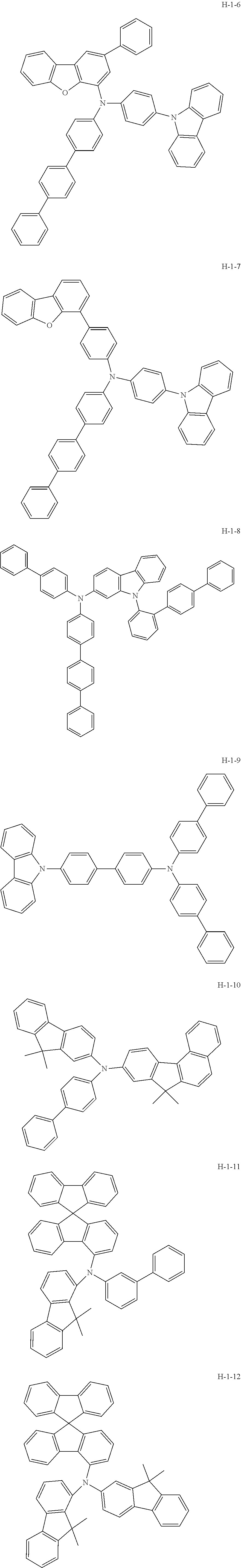

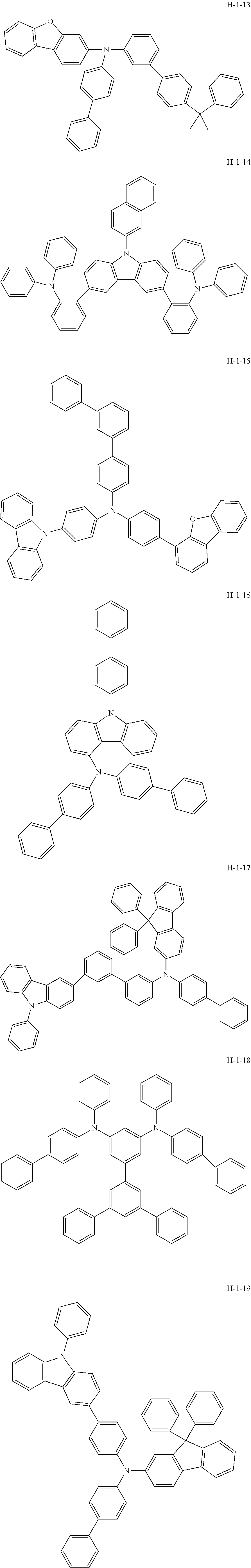

The hole transport region HTR may include a phthalocyanine compound such as copper phthalocyanine, N¹,N^{1′}—([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

The hole transport region HTR may include a carbazole-based derivative such as N-phenyl carbazole or polyvinyl carbazole, a fluorene-based derivative, a triphenylamine-based derivative. For example, the hole transport region HTR may include N,N′-bis(3-methylphenyl)-N,N′-diphenyl-[1,1-biphenyl]-4,4′-diamine (TPD) or 4,4′,4″-tris(N-carbazolyl)triphenylamine (TCTA)), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the herein-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the herein-described ranges, satisfactory hole transport properties may be achieved without a substantial increase in driving voltage.

The hole transport region HTR may further include a charge generating material to increase conductivity in addition to the herein-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described herein, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer including (e.g., formed of) a single material, a single layer including (e.g., formed of) multiple different materials, or a multi-layered structure having a plurality of layers including (e.g., formed of) multiple different materials.

The emission layer EML may be formed by utilizing one or more suitable methods such as a vacuum deposition method, a spin coating method, a casting method, a Langmuir-Blodgett (LB) method, an inject printing method, a laser printing method, and a laser induced thermal imaging (LITI) method.

The light emitting element ED of one or more embodiments may include a fused polycyclic compound represented by Formula 1 in at least one functional layer provided between the first electrode EL1 and the second electrode EL2. The emission layer EML in the light emitting element ED according to one or more embodiments may include a fused polycyclic compound of one or more embodiments. In one or more embodiments, the emission layer EML may include the fused polycyclic compound of one or more embodiments as a dopant. The fused polycyclic compound of one or more embodiments may be a dopant material of the emission layer EML. In some embodiments, in the specification, the fused polycyclic compound of one or more embodiments, which will be described later, may be referred to as a first compound.

### Fused Polycyclic Compound

The fused polycyclic compound of one or more embodiments may include a structure in which a plurality of aromatic rings are fused via a boron atom and two heteroatoms. For example, the fused polycyclic compound of one or more embodiments may include a structure in which first to third aromatic rings are fused via one boron atom, a first nitrogen atom, and a second nitrogen atom. The first to third aromatic rings may each be linked to the boron atom, the first aromatic ring and the third aromatic ring may be linked to each other via the first nitrogen atom, and the second aromatic ring and the third aromatic ring may be linked to each other via the second nitrogen atom. In one or more embodiments, the first to third aromatic rings may be 6-membered aromatic hydrocarbon rings. For example, the first to third aromatic rings may be benzene rings. In some embodiments, in the present specification, the boron atom, the first nitrogen atom, and the second nitrogen atom, and the first to third aromatic rings which are fused via the boron atom, the first nitrogen atom, and the second nitrogen atom may be referred to as “fused ring core.”

The fused polycyclic compound of one or more embodiments may include a first linker linked to the first nitrogen atom of the fused ring core. The first linker may include a benzene moiety linked to the first nitrogen atom of the fused ring core. The first linker may be a substituted or unsubstituted phenylene linker.

The fused polycyclic compound of one or more embodiments may include a first substituent and a second substituent linked to the first linker. The first substituent may include a carbazole moiety, and the second substituent may include a nitrile moiety. The first substituent may be a substituted or unsubstituted carbazole group, and the second substituent may be a cyano group. The first substituent may be linked to the carbon at the meta position with respect to the carbon linked to the first nitrogen atom among carbons constituting the first linker. The second substituent may be linked to the carbon at the ortho or para position with respect to the carbon linked to the first nitrogen atom among carbons constituting the first linker. Among the carbons constituting the first linker, the carbon to which the first substituent is linked may be in the ortho relation or para relation with the carbon to which the second substituent is linked.

Thus, the fused polycyclic compound of one or more embodiments may have an increase in multiple resonance effects because the first substituent and the second substituent are linked to the fused ring core via the first linker. Therefore, the fused polycyclic compound of one or more embodiments may achieve high efficiency and a long service life when applied to the light emitting element.

The fused polycyclic compound of one or more embodiments may be represented by Formula 1:

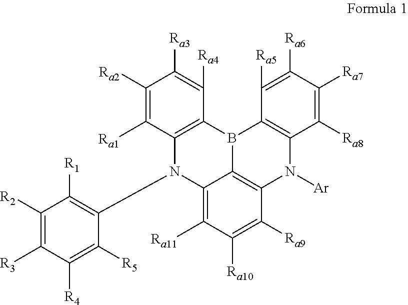

The fused polycyclic compound represented by Formula 1 of one or more embodiments may include a structure in which three aromatic rings are fused via one boron atom, the first nitrogen atom, and the second nitrogen atom.

In Formula 1, Rₐ₁ to Rₐ₁₁ and R₁ to R₅ may each independently be a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. At least one selected from among R₁ to R₅ may be a cyano group and at least another one (e.g., one selected from among any remaining R₁ to R₅) may be a substituent represented by Formula 2. For example, Rₐ₁ to Rₐ₁₁ may each independently be a hydrogen atom, a deuterium atom, a cyano group, a substituted or unsubstituted t-butyl group, a substituted or unsubstituted phenyl group, or a substituted or unsubstituted carbazole group. For example, R₂ may be a substituent represented by Formula 2, any one selected from among R₁, R₃, and R₅ may be a cyano group, and the others (e.g., selected from among any remaining R₁ to R₅) may be hydrogen atoms or deuterium atoms.

In Formula 1, Ar may be a substituted or unsubstituted aryl group having 6 to 30 ring-forming carbon atoms, or a substituted or unsubstituted heteroaryl group having 2 to 30 ring-forming carbon atoms. For example, Ar may be a substituted or unsubstituted biphenyl group, or a substituted or unsubstituted terphenyl group. When Ar is a substituted biphenyl group, the substituent may be a deuterium atom, a cyano group, or a carbazole group. When Ar is a substituted terphenyl group, the substituent may be a deuterium atom, an unsubstituted aryl group having 6 to 12 carbon atoms, or an unsubstituted t-butyl group.

In some embodiments, in the present specification, in Formula 1, the benzene ring which is substituted with substituents represented by Rₐ₁ to Rₐ₄ may correspond to the aforementioned first aromatic ring, the benzene ring which is substituted with substituents represented by Rₐ₅ to Rₐ₈ may correspond to the aforementioned second aromatic ring, and the benzene ring which is substituted with substituents represented by Rₐ₉ to Rₐ₁₁ may correspond to the aforementioned third aromatic ring. A plurality of Ns in Formula 1 may correspond to the first nitrogen atom and the second nitrogen atom, respectively, as described herein. In Formula 1, the benzene moiety substituted with substituents represented by R₁ to R₅ may correspond to the aforementioned first linker. In Formula 1, the substituent corresponding to a cyano group among R₁ to R₅ may correspond to the aforementioned second substituent.

In Formula 1, at least one selected from among R₁ to R₅ may be a substituent represented by Formula 2:

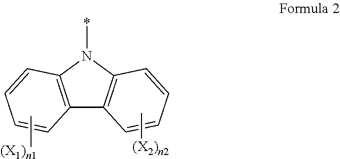

In Formula 2, X₁ and X₂ may each independently be a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, X₁ and X₂ may each independently be a hydrogen atom, a deuterium atom, a cyano group, a substituted or unsubstituted t-butyl group, or a substituted or unsubstituted phenyl group.

In Formula 2, n1 and n2 may each independently be an integer of 0 to 4. When each of n1 and n2 is 0, the fused polycyclic compound of one or more 1 embodiments may not be substituted with each of X₁ and X₂. The case where each of n1 and n2 is 4 and X₁'s and X₂'s are each hydrogen atoms may be the same as the case where each of n1 and n2 is 0. When each of n1 and n2 is an integer of 2 or greater, a plurality of X₁'s and X₂'s may each be the same or at least one selected from among the plurality of X₁'s and X₂'s may be different from the others (e.g., selected from among any remaining Xi's and X₂'s).

In Formula 2,

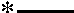 [SMILES: *C]

is a position linked to Formula 1 herein.

In some embodiments, in the present specification, Formula 2 may correspond to the aforementioned first substituent.

In one or more embodiments, the fused polycyclic compound represented by Formula 1 may be represented by Formula 1-1 or Formula 1-2:

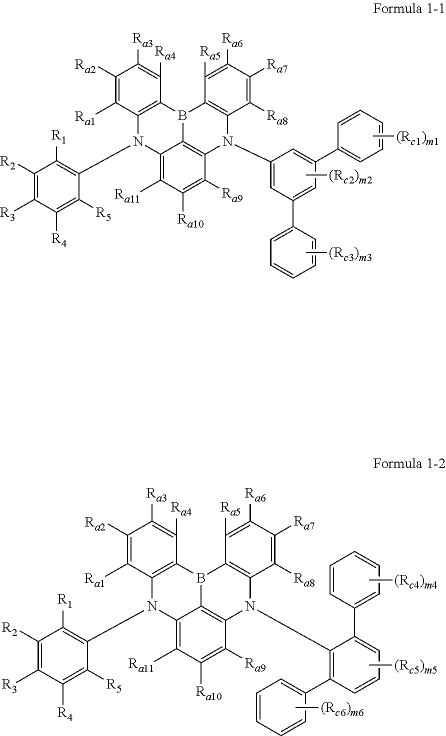

Formula 1-1 and Formula 1-2 each represent the cases where the types (kinds) of substituents represented by Ar are specified in Formula 1.

In Formula 1-1 and Formula 1-2, R_{c1} to R_{c6} may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{c1} to R_{c6} may each independently be a hydrogen atom, a deuterium atom, a substituted or unsubstituted t-butyl group, or a substituted or unsubstituted phenyl group.

In Formula 1-1, m1 and m3 may each independently be an integer of 0 to 4.

When each of m1 and m3 is 0, the fused polycyclic compound of one or more embodiments may not be substituted with each of R_{c1} and R_{c3}. The case where each of m1 and m3 is 4 and R_{c1}'s and R_{c3}'s each are hydrogen atoms may be the same as the case where each of m1 and m3 is 0. When each of m1 and m3 is an integer of 2 or greater, a plurality of R_{c1}'s and R_{c3}'s may each be the same or at least one selected from among the plurality of R_{c1}'s and R_{c3}'s may be different from the others (e.g., selected from among any remaining R_{c1}'s and R_{c3}'s).

In Formula 1-1, m2 is an integer of 0 to 3. When m2 is 0, the fused polycyclic compound of one or more embodiments may not be substituted with R_{c2}.

The case where m2 is 3 and R_{c2}'s each are all hydrogen atoms may be the same as the case where m2 is 0. When m2 is an integer of 2 or greater, a plurality of R_{c2}'s may each be the same, or at least one selected from among the plurality of R_{c2}'s may be different from the others (e.g., selected from among any remaining R_{c2}'s).

In Formula 1-2, m4 and m6 may each independently be an integer of 0 to 4. When each of m4 and m6 is 0, the fused polycyclic compound of one or more embodiments may not be substituted with each of R_{c4} and R_{c6}. The case where each of m4 and m6 is 4 and R_{c4}'s and R_{c6}'s each are hydrogen atoms may be the same as the case where each of m4 and m6 is 0. When each of m4 and m6 is an integer of 2 or greater, a plurality of R_{c4}'s and R_{c6}'s may each be the same or at least one selected from among the plurality of R_{c4}'s and R_{c6}'s may be different from the others (e.g., selected from among any remaining R_{c4}'s and R_{c6}'s).

In Formula 1-2, m5 may be an integer of 0 to 3. When m5 is 0, the fused polycyclic compound of one or more embodiments may not be substituted with R_{c5}. The case where m5 is 3 and R_{c5}'s each are all hydrogen atoms may be the same as the case where m5 is 0. When m4 is an integer of 2 or greater, a plurality of R_{c5}'s may each be the same, or at least one selected from among the plurality of R_{c5}'s may be different from the others (e.g., selected from among any remaining R_{c5}'s).

In some embodiments, in Formula 1-1 and Formula 1-2, the definitions as described in Formula 1 herein may be applied to Rₐ₁ to Rₐ₁₁, and R₁ to R₅.

In one or more embodiments, the fused polycyclic compound represented by Formula 1 may be represented by Formula 1-3:

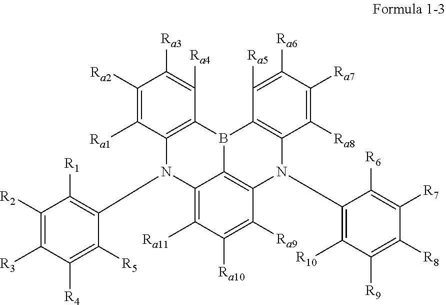

Formula 1-3 represents the case where the type or kind of substituent represented by Ar is specified in Formula 1.

In Formula 1-3, R₆ to R₁₀ may each independently be a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, when selected from among R₆ to R₁₀, R₇ may be a substituent represented by Formula 2 herein, any one selected from among R₆, R₈, and R₁₀ may be a cyano group, and the others (e.g., selected from among any remaining R₆ to R₁₀) may be hydrogen atoms or deuterium atoms.

In some embodiments, in Formula 1-3, the definitions as described in Formula 1 herein may be applied to Rₐ₁ to Rₐ₁₁, and R₁ to R₅.

In one or more embodiments, the fused polycyclic compound represented by Formula 1 may be represented by any one selected from among Formula 1-4 to Formula 1-6:

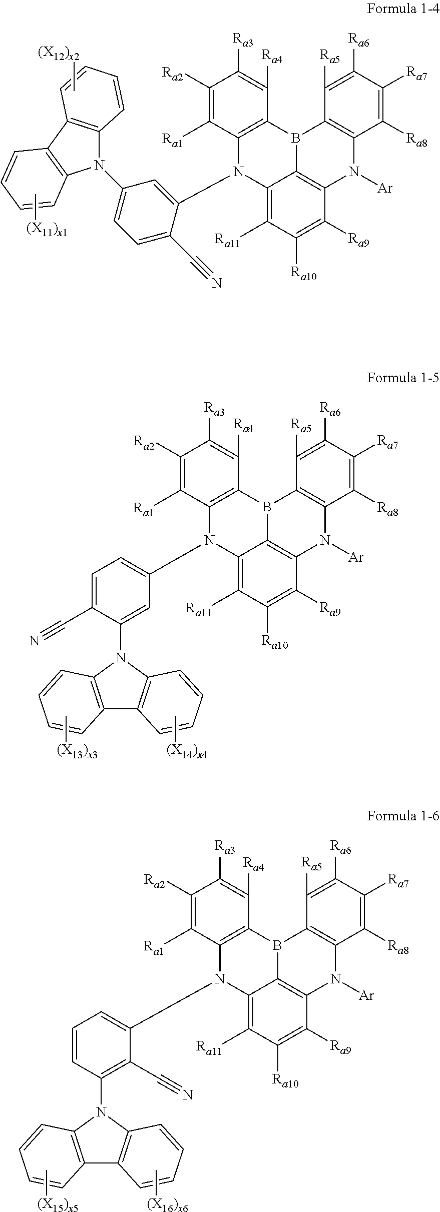

Formula 1-4 to Formula 1-6 represent the cases where the types (kinds) of substituents represented by R₁ to R₅ are specified in Formula 1.

In Formula 1-4 to Formula 1-6, X₁₁ to X₁₆ may each independently be a hydrogen atom, a deuterium atom, a halogen atom, a cyano group, a hydroxy group, a nitrile group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, X₁₁ to X₁₆ may each independently be a hydrogen atom, a deuterium atom, a nitrile group, a substituted or unsubstituted t-butyl group, or a substituted or unsubstituted phenyl group.

In Formula 1-4 to Formula 1-6, x1 to x6 may each independently be an integer of 0 to 4. When each of x1 to x6 is 0, the fused polycyclic compound of one or more embodiments may not be substituted with each of X₁₁ to X₁₆. The case where each of x1 to x6 is 4 and X₁₁'s to X₁₆'s each are hydrogen atoms may be the same as the case where each of x1 to x6 is 0. When each of x1 to x6 is an integer of 2 or greater, a plurality of X₁₁'s to X₁₆'s may each be the same or at least one selected from among the plurality of X₁₁'s to X₁₆'s may be different from the others (e.g., selected from among any remaining X₁₁'s to X₁₆'s).

In some embodiments, in Formula 1-4 to Formula 1-6, the definitions as described in Formula 1 herein may be applied to Rₐ₁ to Rₐ₁₁, and Ar.

In one or more embodiments, the fused polycyclic compound represented by Formula 1 may be a compound represented by any one selected from among Formula 1-7 to Formula 1-9:

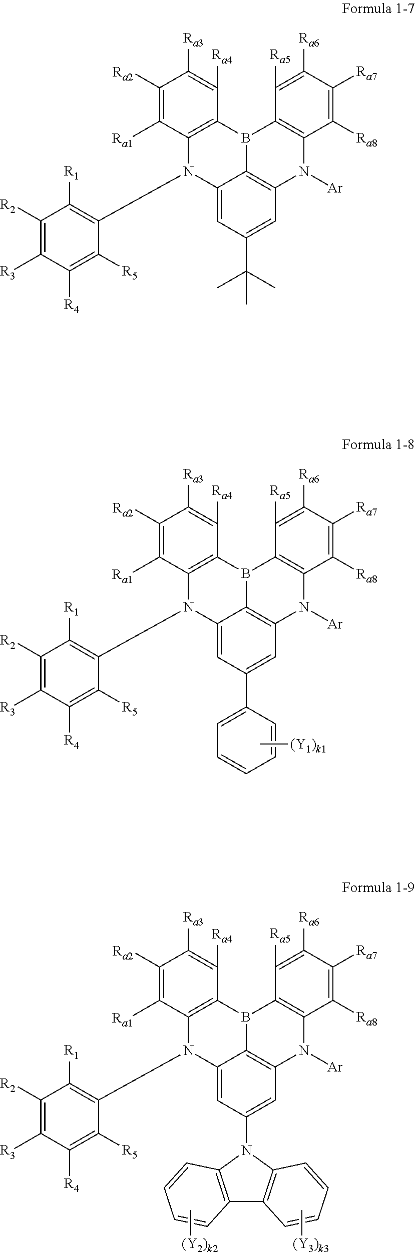

Formula 1-7 to Formula 1-9 represent the cases where the types (kinds) of substituents represented by Rₐ₉ to Rₐ₁₁ are specified in Formula 1.

In Formula 1-8 and Formula 1-9, Y₁ to Y₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Y₁ to Y₃ may each independently be a hydrogen atom, a deuterium atom, a cyano group, a substituted or unsubstituted t-butyl group, or a substituted or unsubstituted phenyl group.

In Formula 1-8, k1 is an integer of 0 to 5. When k1 is 0, the fused polycyclic compound of one or more embodiments may not be substituted with Y₁. The case where k1 is 5 and Y₁'s are each hydrogen atoms may be the same as the case where k1 is 0. When k1 is an integer of 2 or greater, a plurality of Y₁'s may each be the same, or at least one selected from among the plurality of Y₁'s may be different from the others (e.g., selected from among any remaining Y₁'s).

In Formula 1-9, k2 and k3 may each independently be an integer of 0 to 4. When each of k2 and k3 is 0, the fused polycyclic compound of one or more embodiments may not be substituted with each of Y₂ and Y₃. The case where each of k2 and k3 is 4 and Y₂'s and Y₃'s are each hydrogen atoms may be the same as the case where each of k2 and k3 is 0. When each of k2 and k3 is an integer of 2 or greater, a plurality of Y₂'s and Y₃'s may each be the same or at least one the plurality of Y₂'s and Y₃'s may be different from the others (e.g., selected from among any remaining Y₂'s and Y₃'s).

In some embodiments, in Formula 1-7 to Formula 1-9, the definitions as described in Formula 1 herein may be applied to Rₐ₁ to Rₐ₈, R₁ to R₅, and Ar.

In the fused polycyclic compound represented by Formula 1 of one or more embodiments, Rₐ₂, Rₐ₃, Rₐ₆, and Rₐ₇ may each independently be a hydrogen atom, a deuterium atom, or a substituent represented by any one selected from among Formula 3-1 to Formula 3-7:

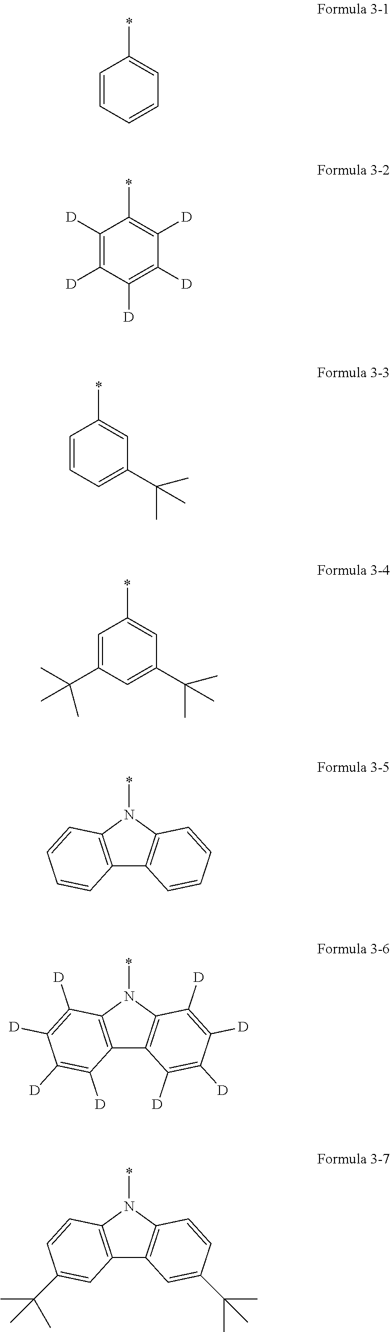

In Formula 3-1 to Formula 3-7 herein, *- may be a position linked to Formula 1 herein.

The fused polycyclic compound of one or more embodiments may be any one (e.g., one) selected from among the compounds represented by Compound Group 1. The light emitting element ED of one or more embodiments may include at least one (e.g., one or more) fused polycyclic compound selected from among the compounds represented by Compound Group 1 in the emission layer EML.

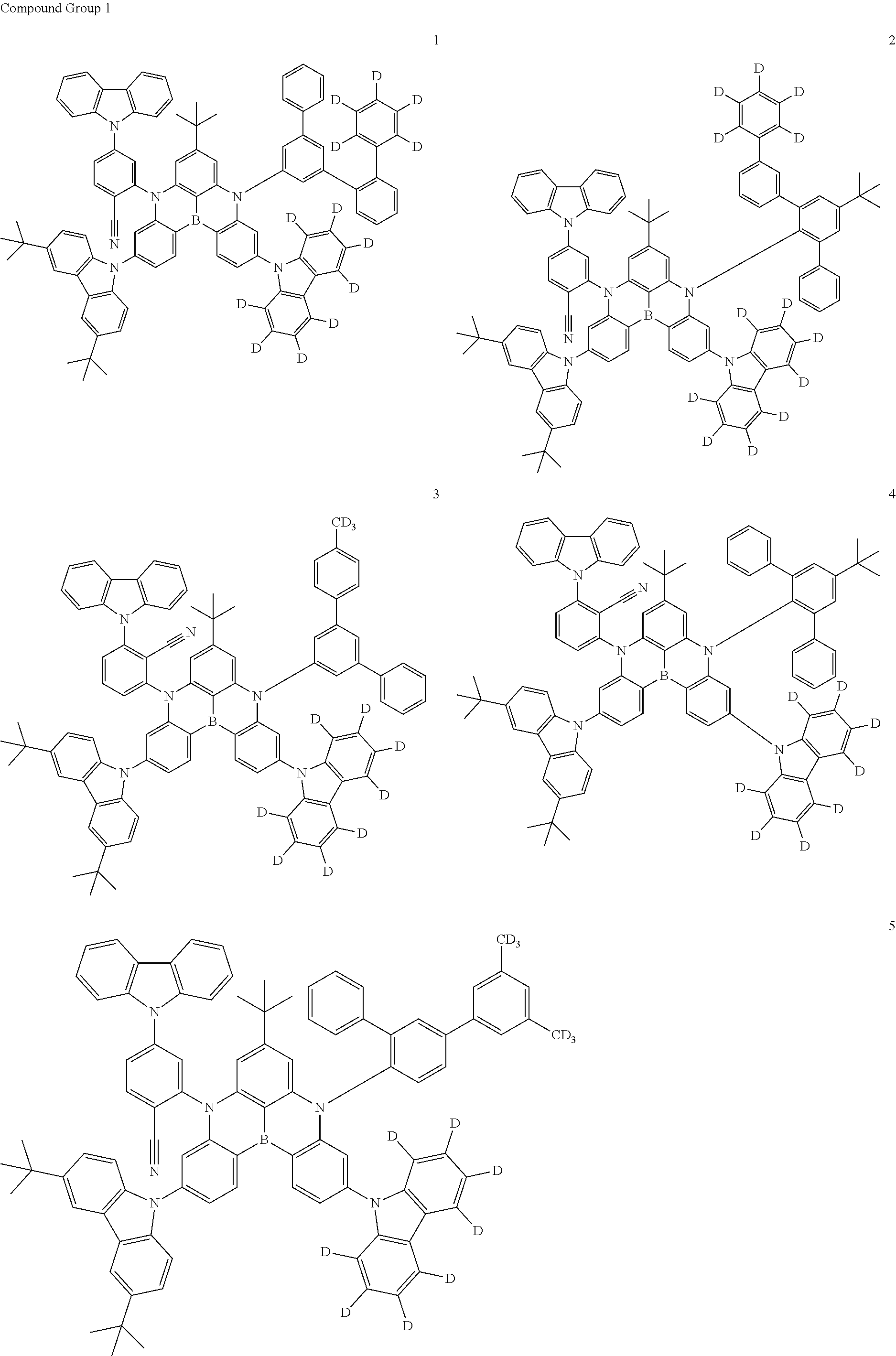

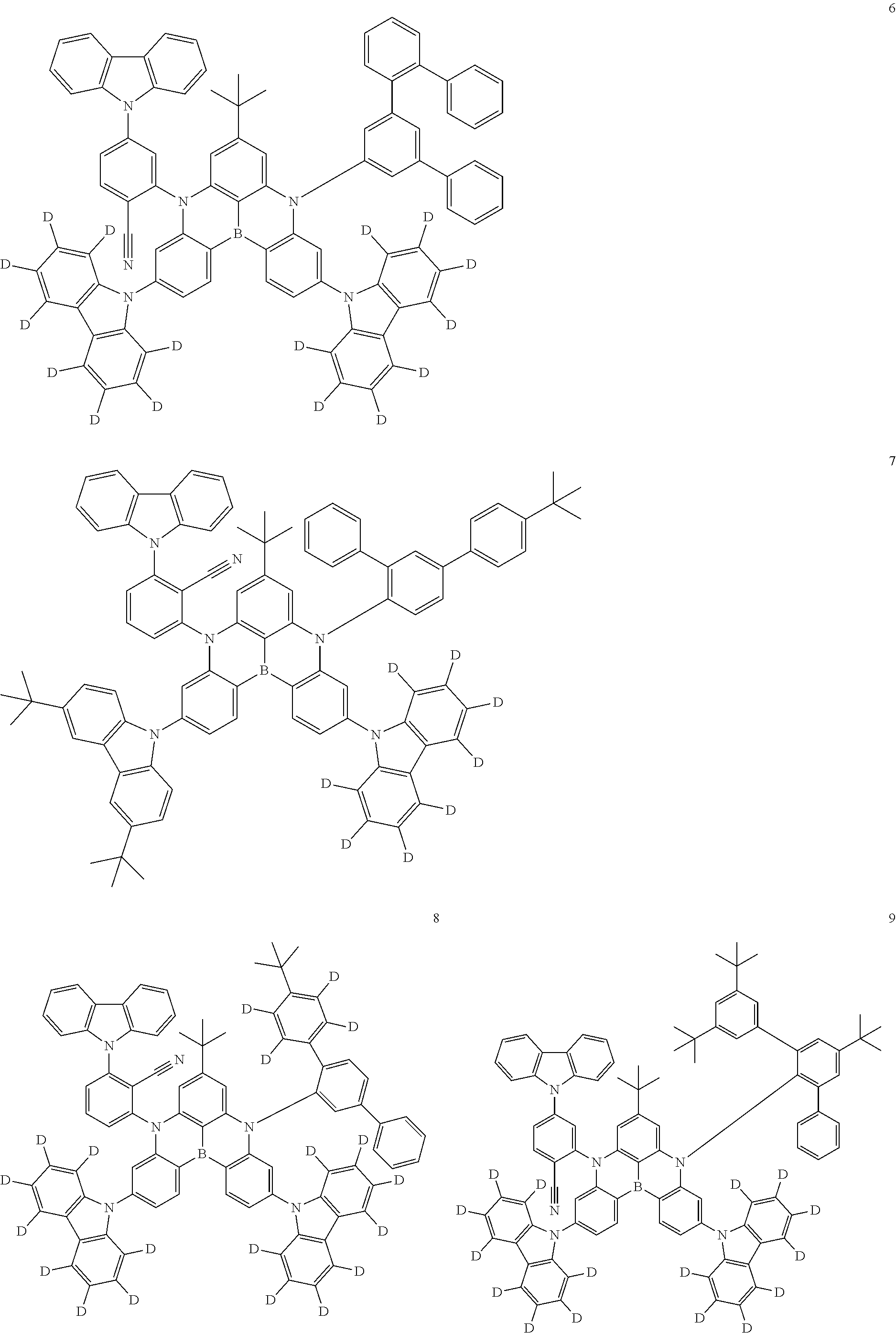

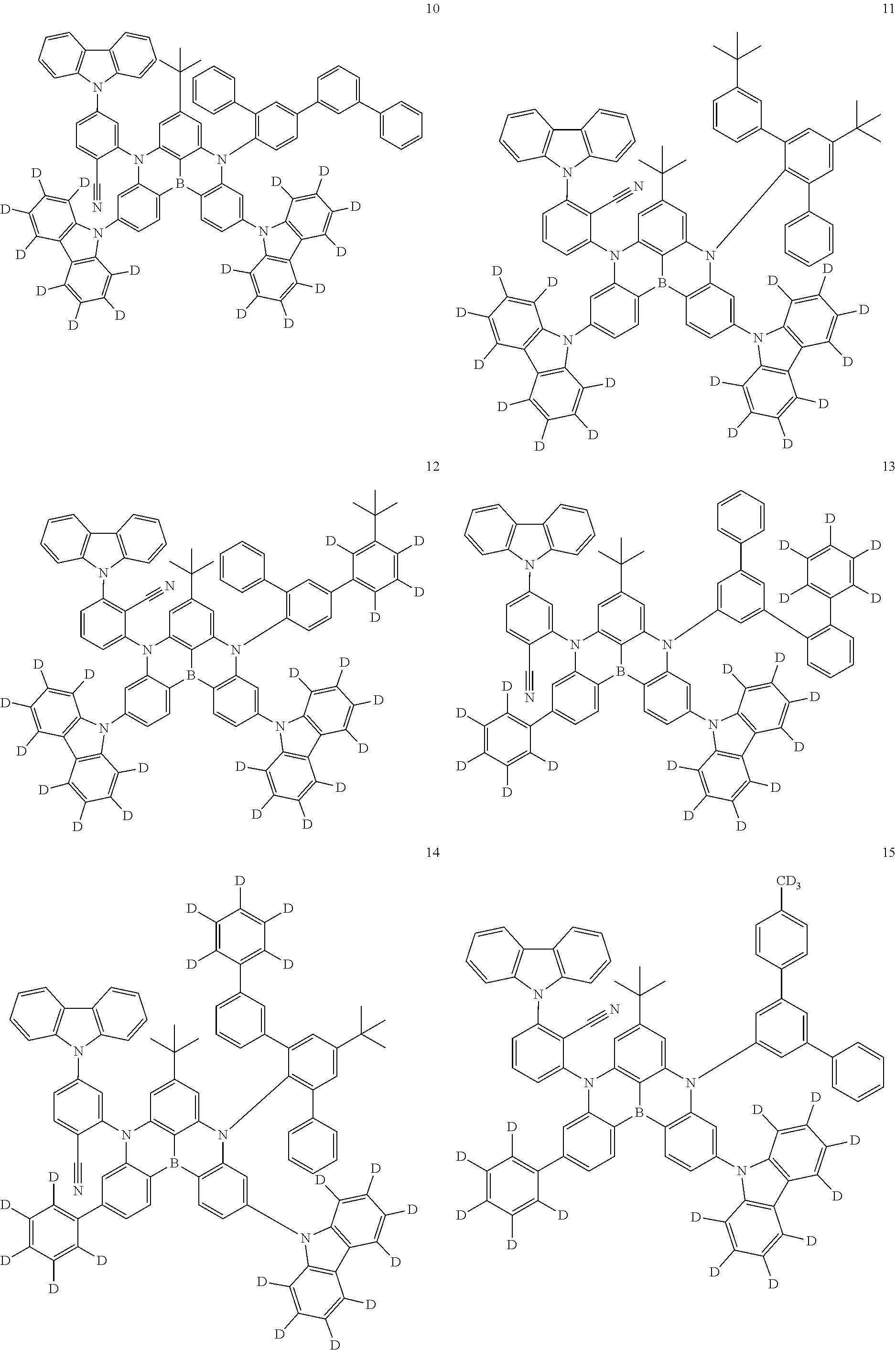

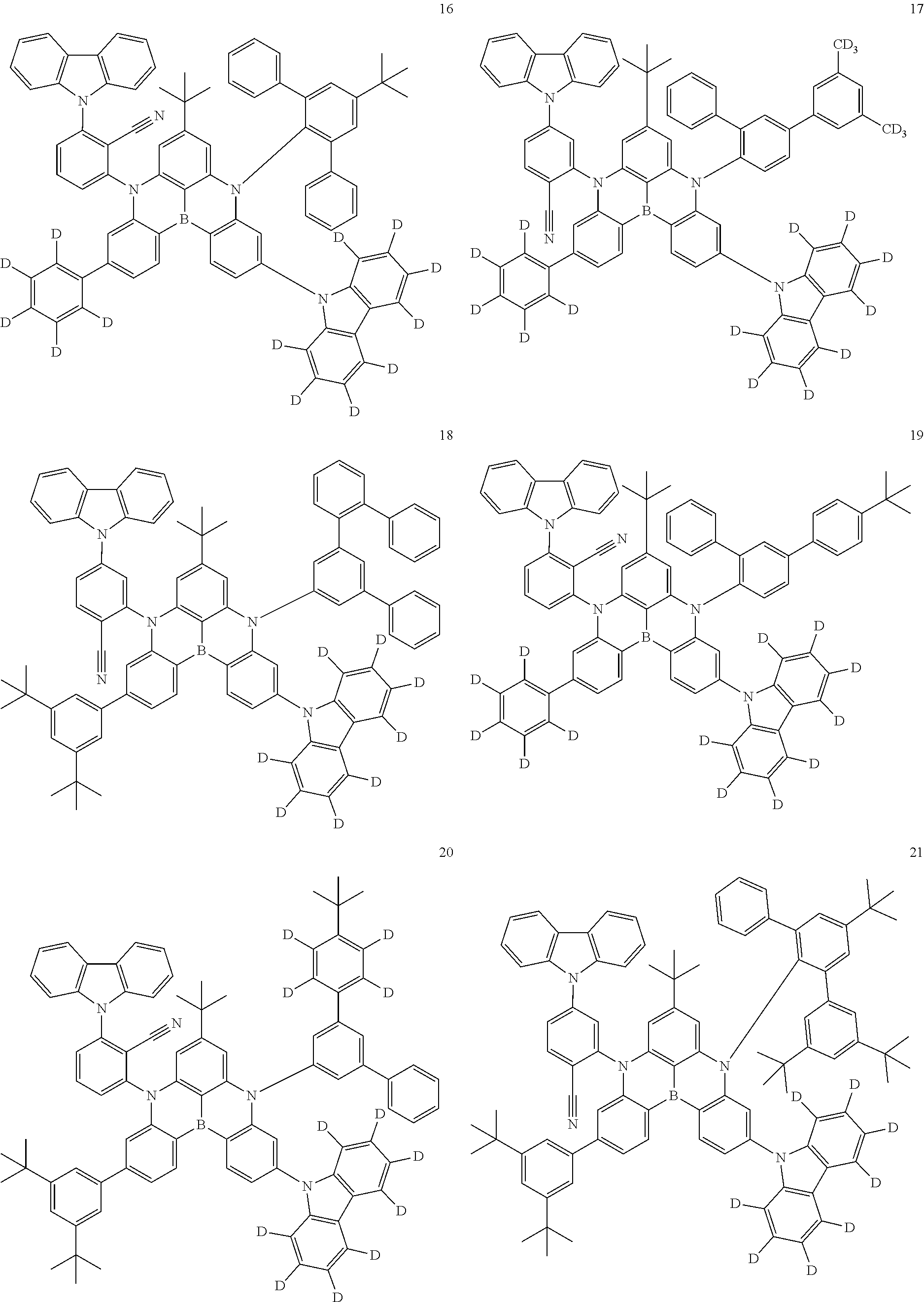

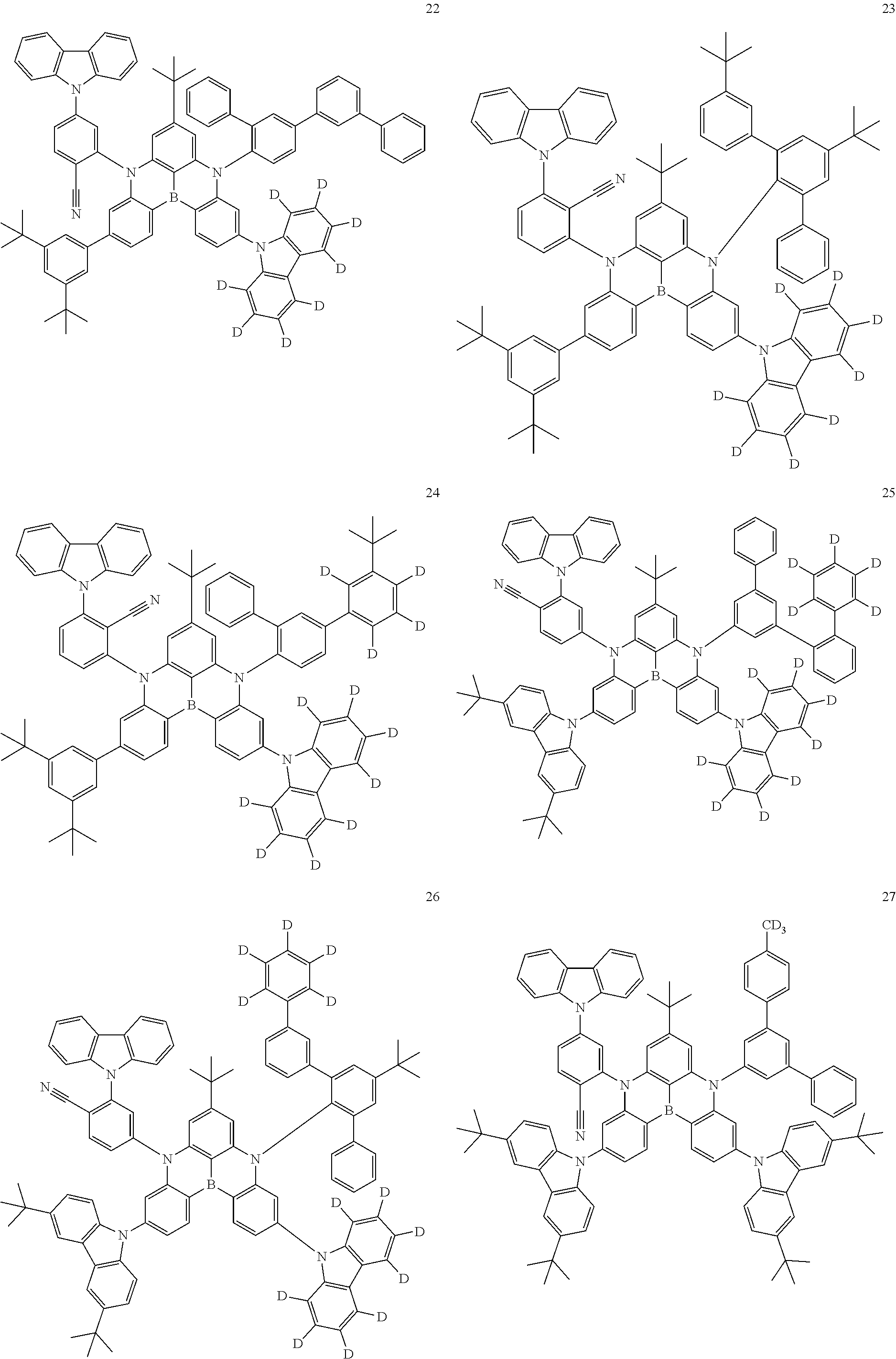

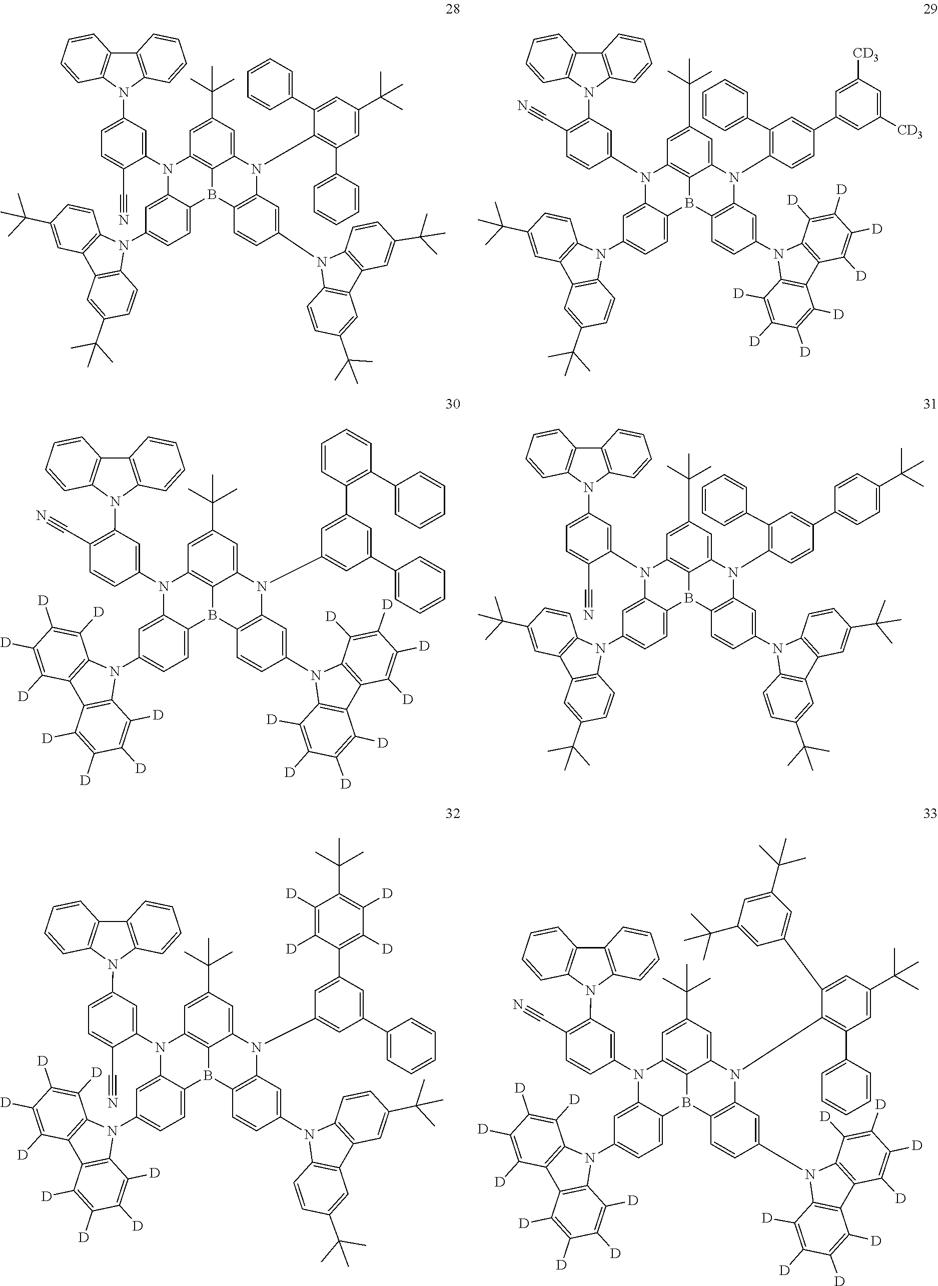

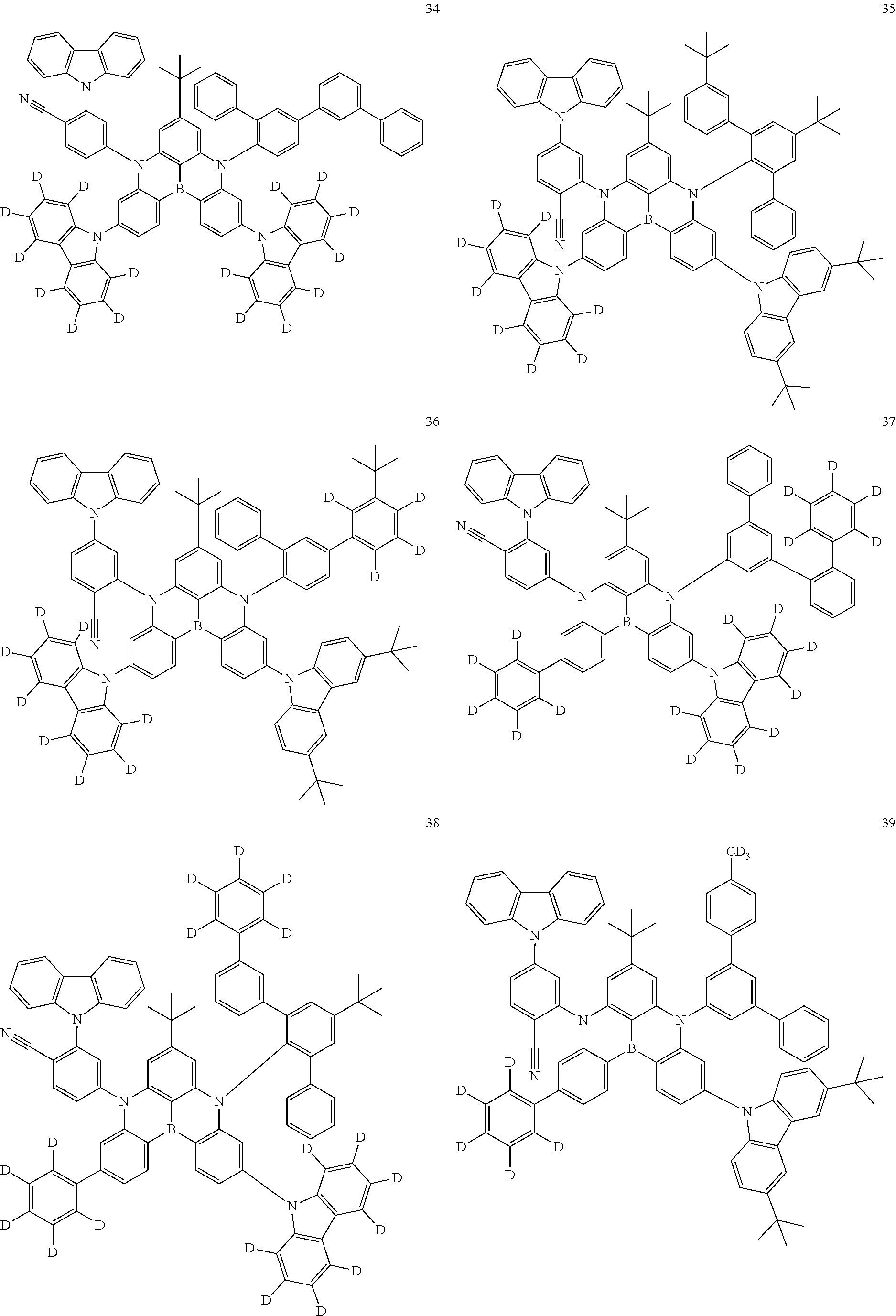

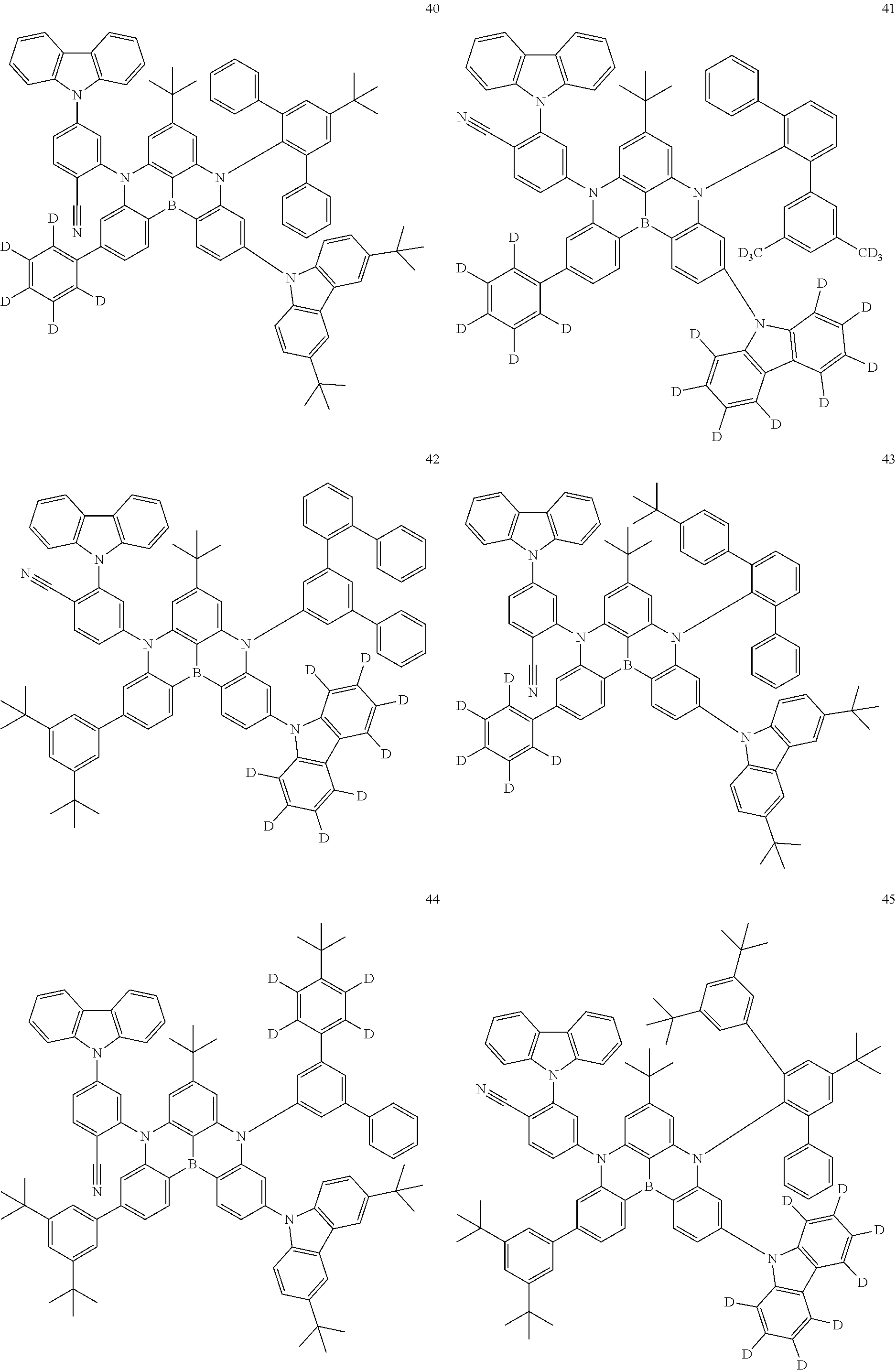

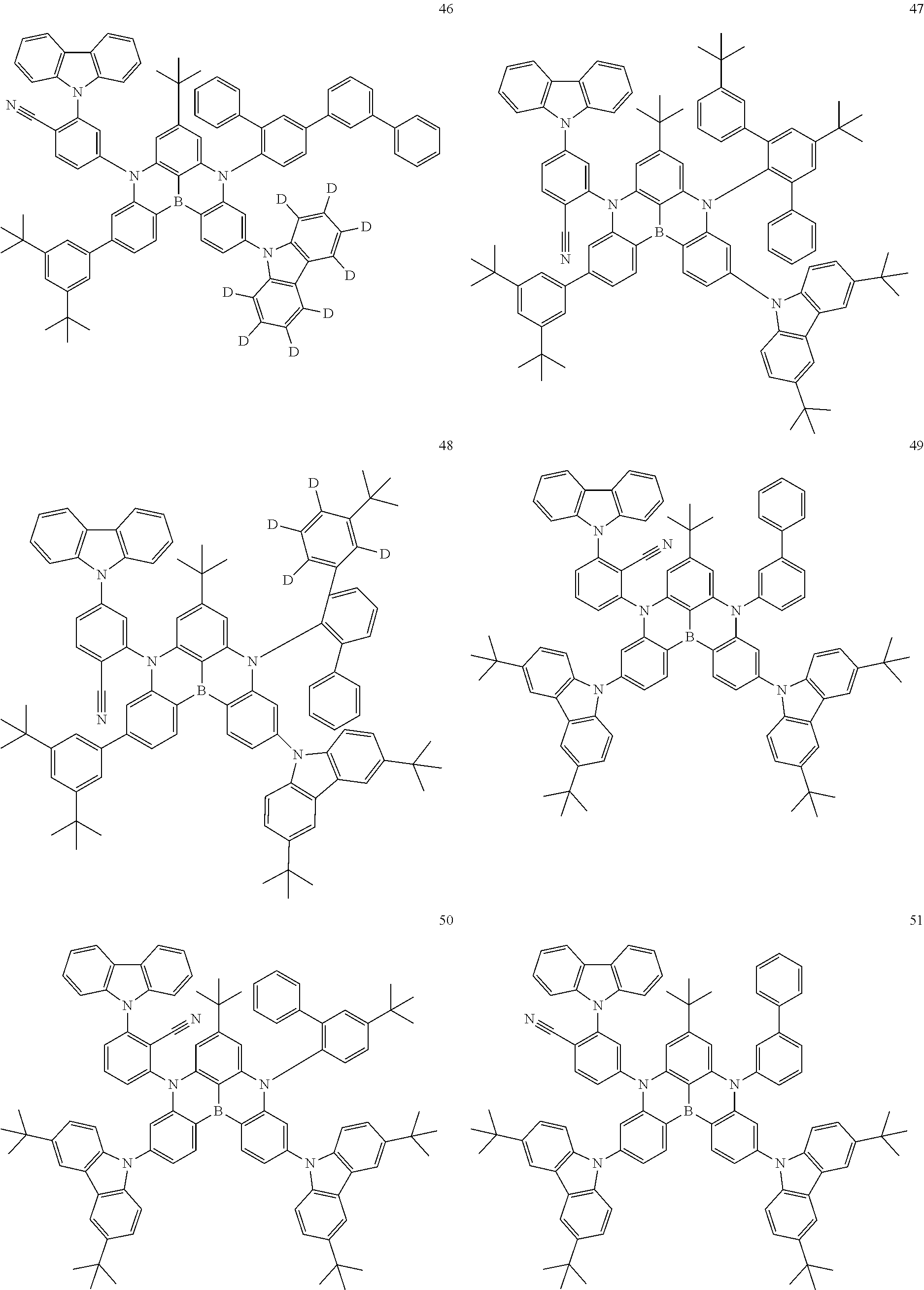

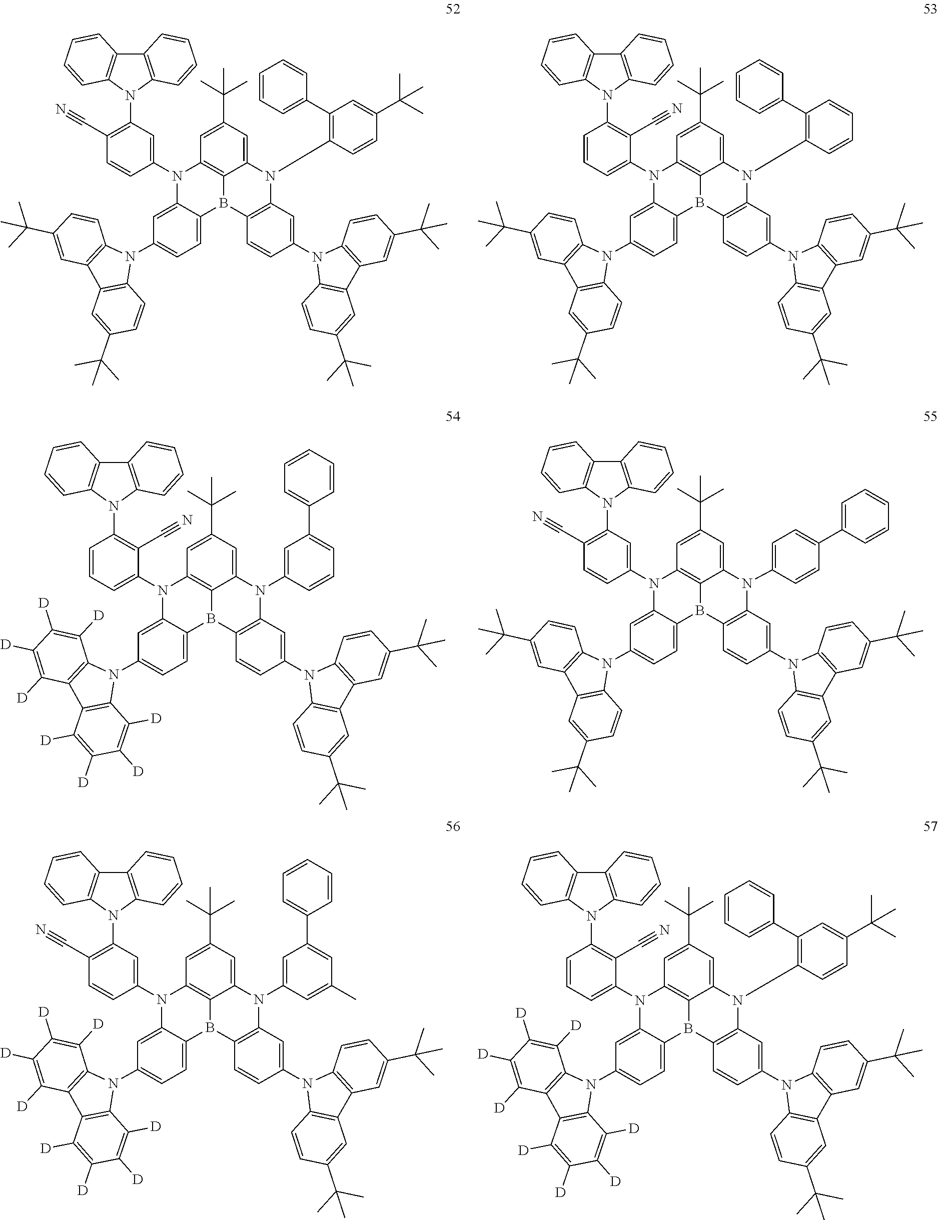

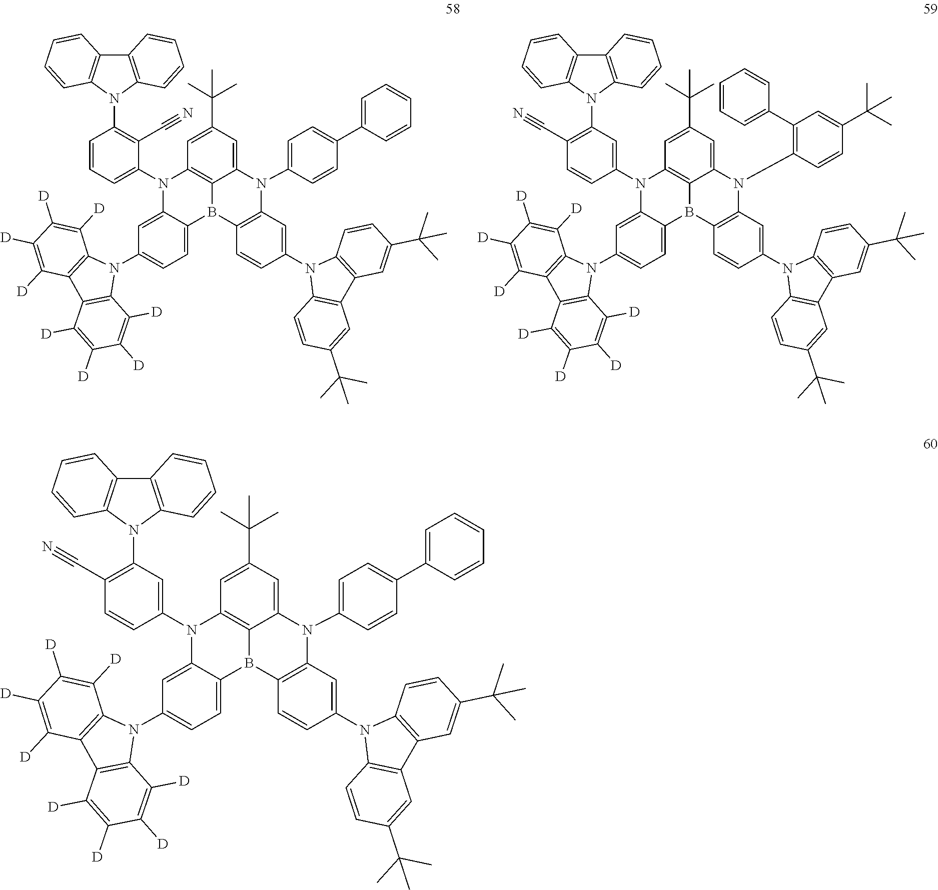

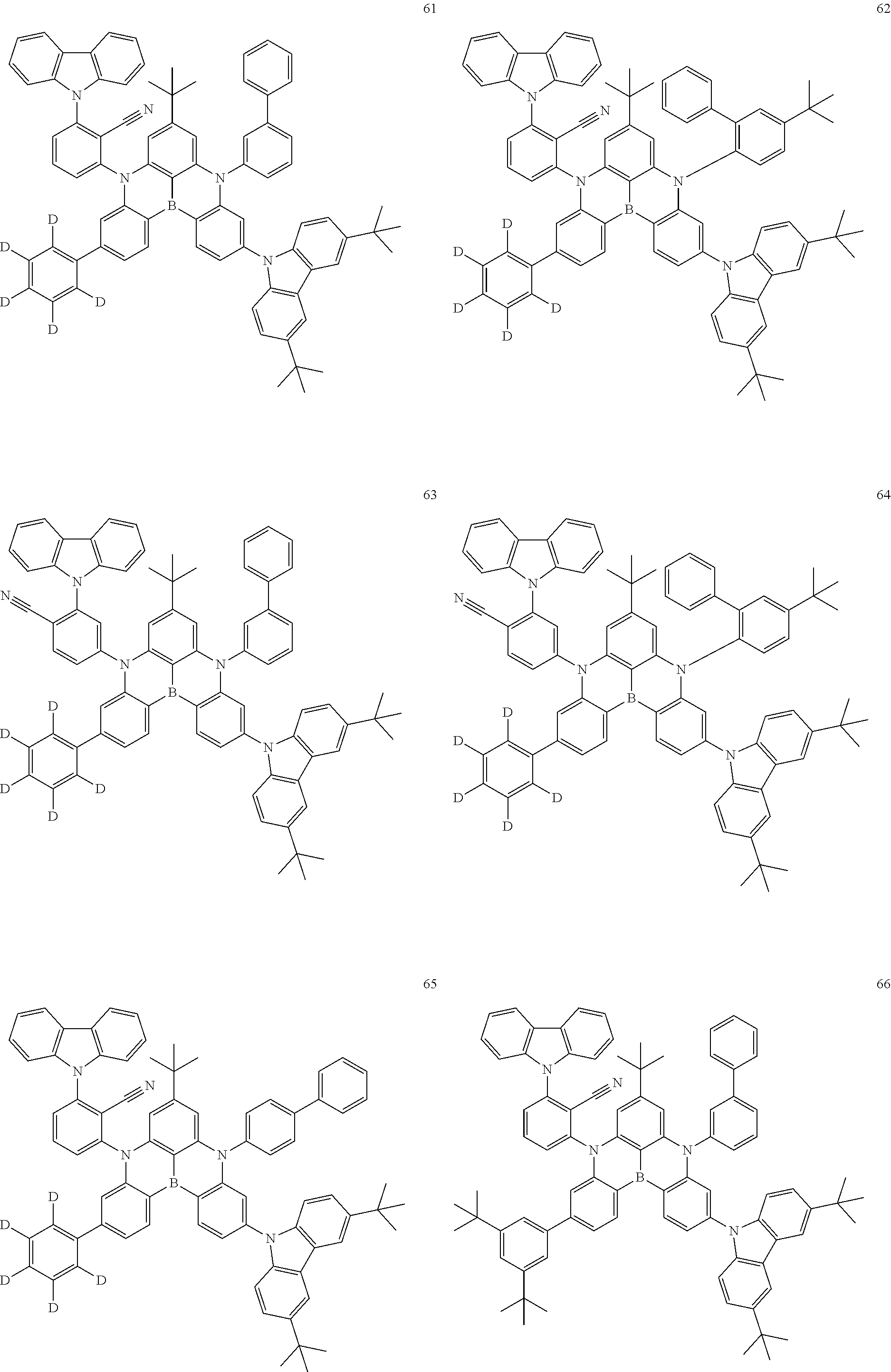

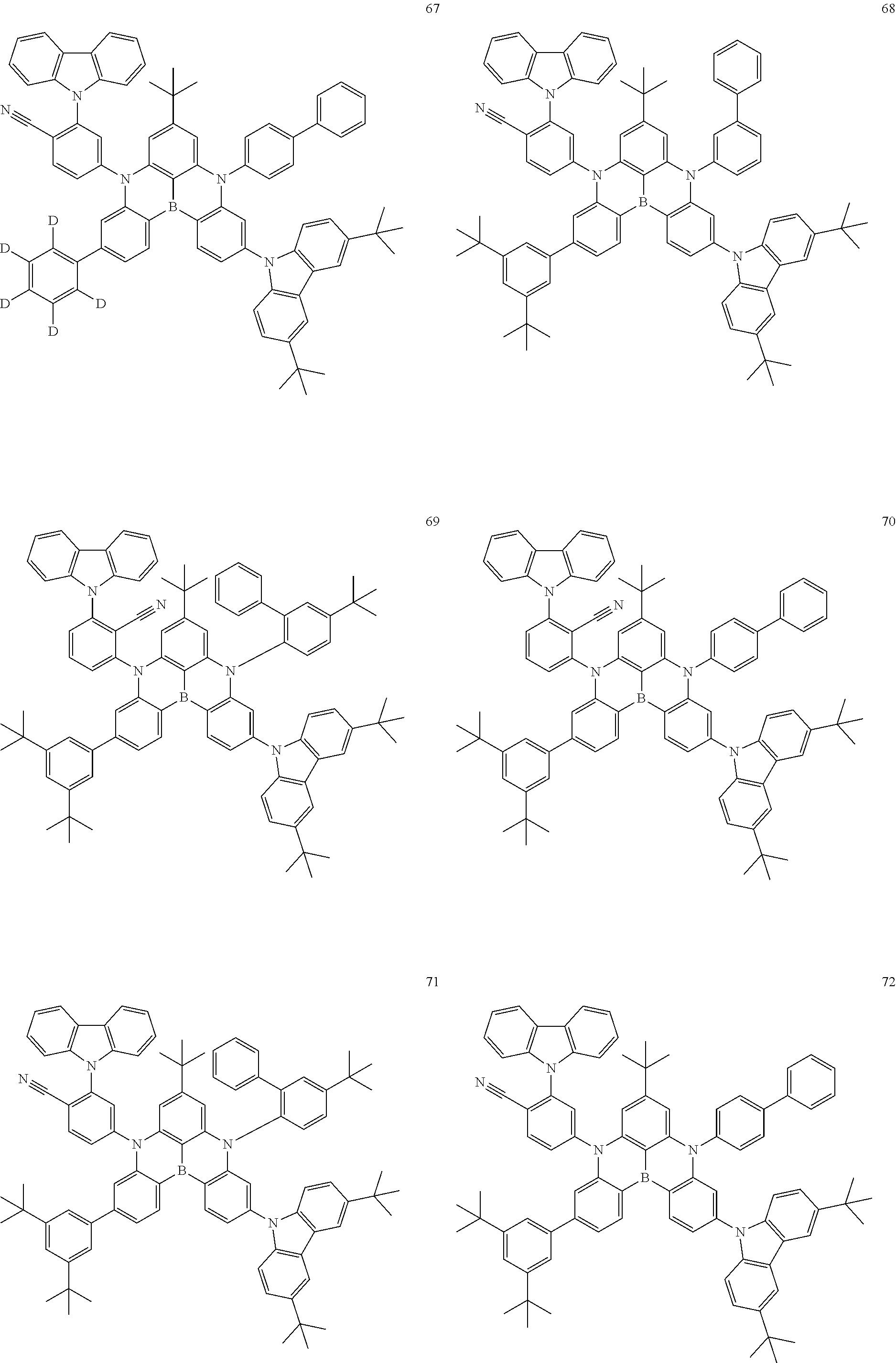

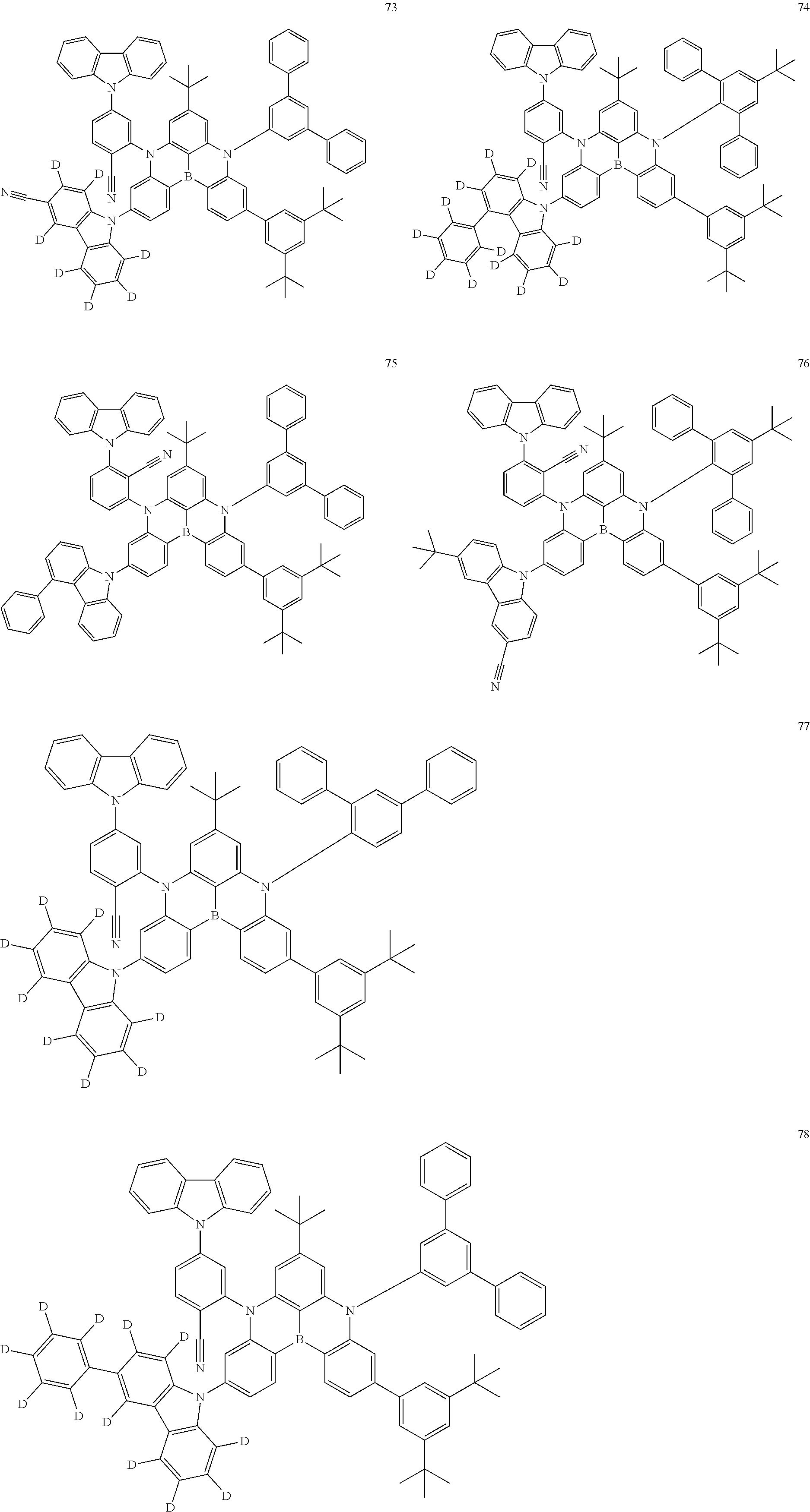

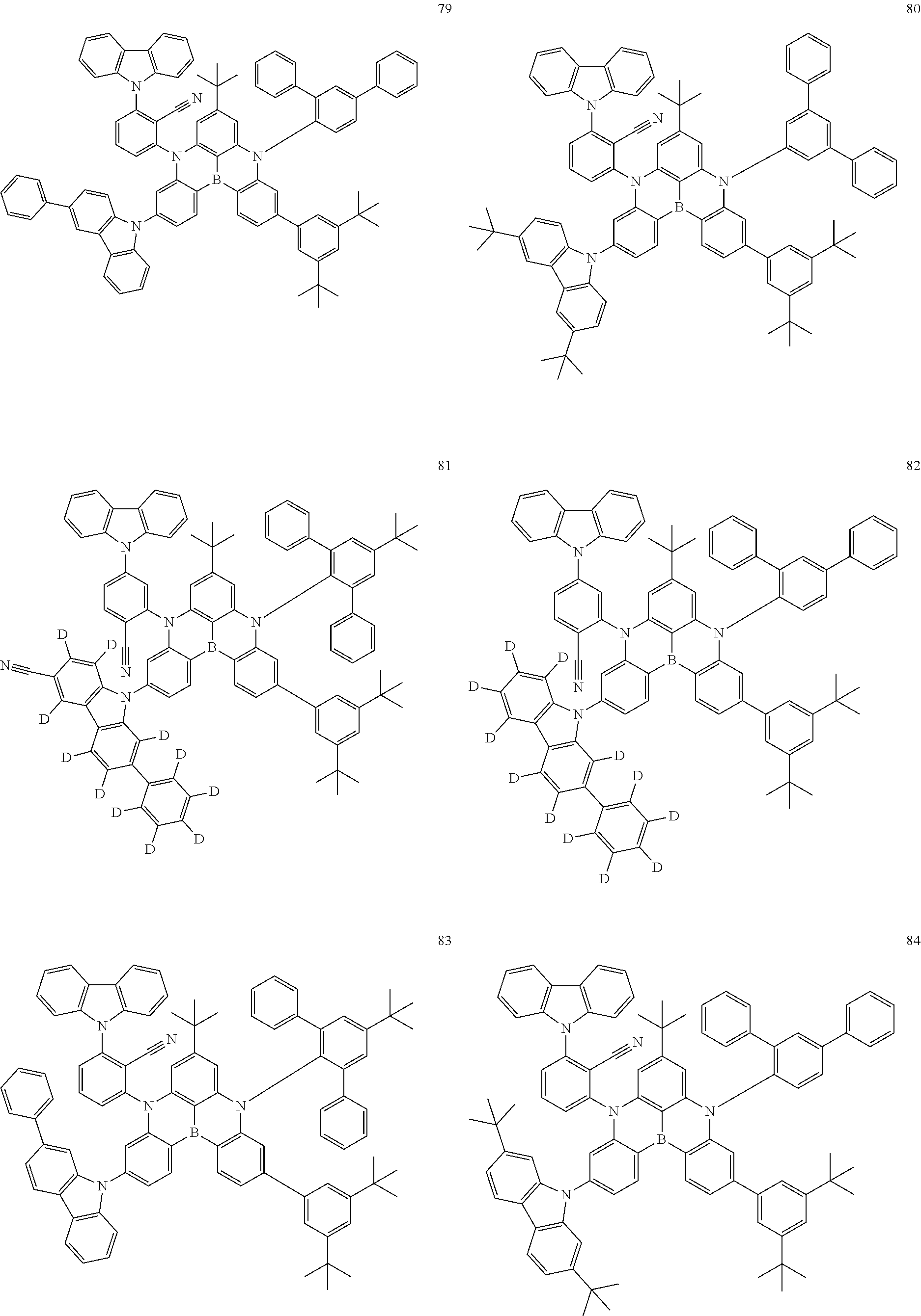

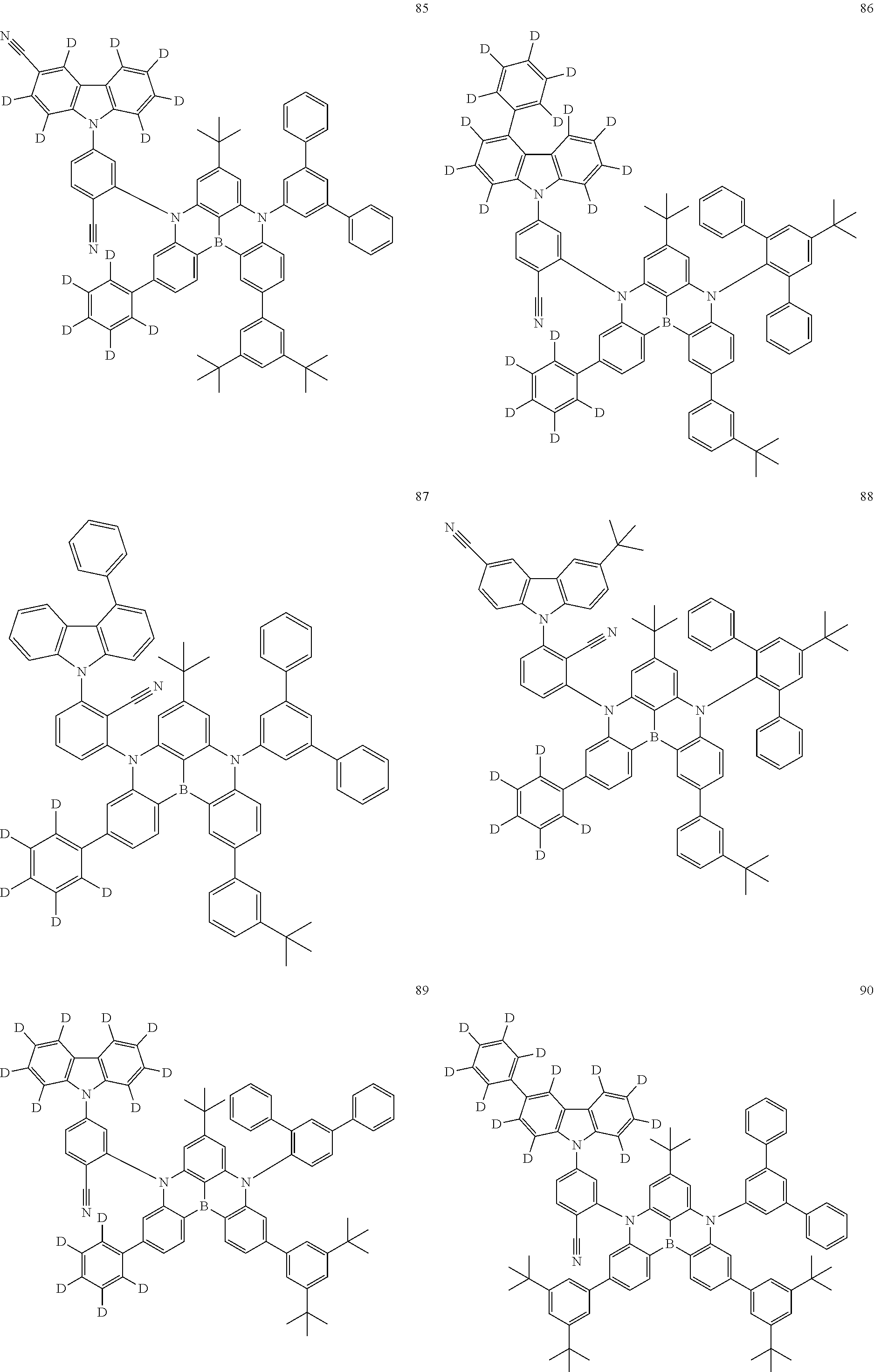

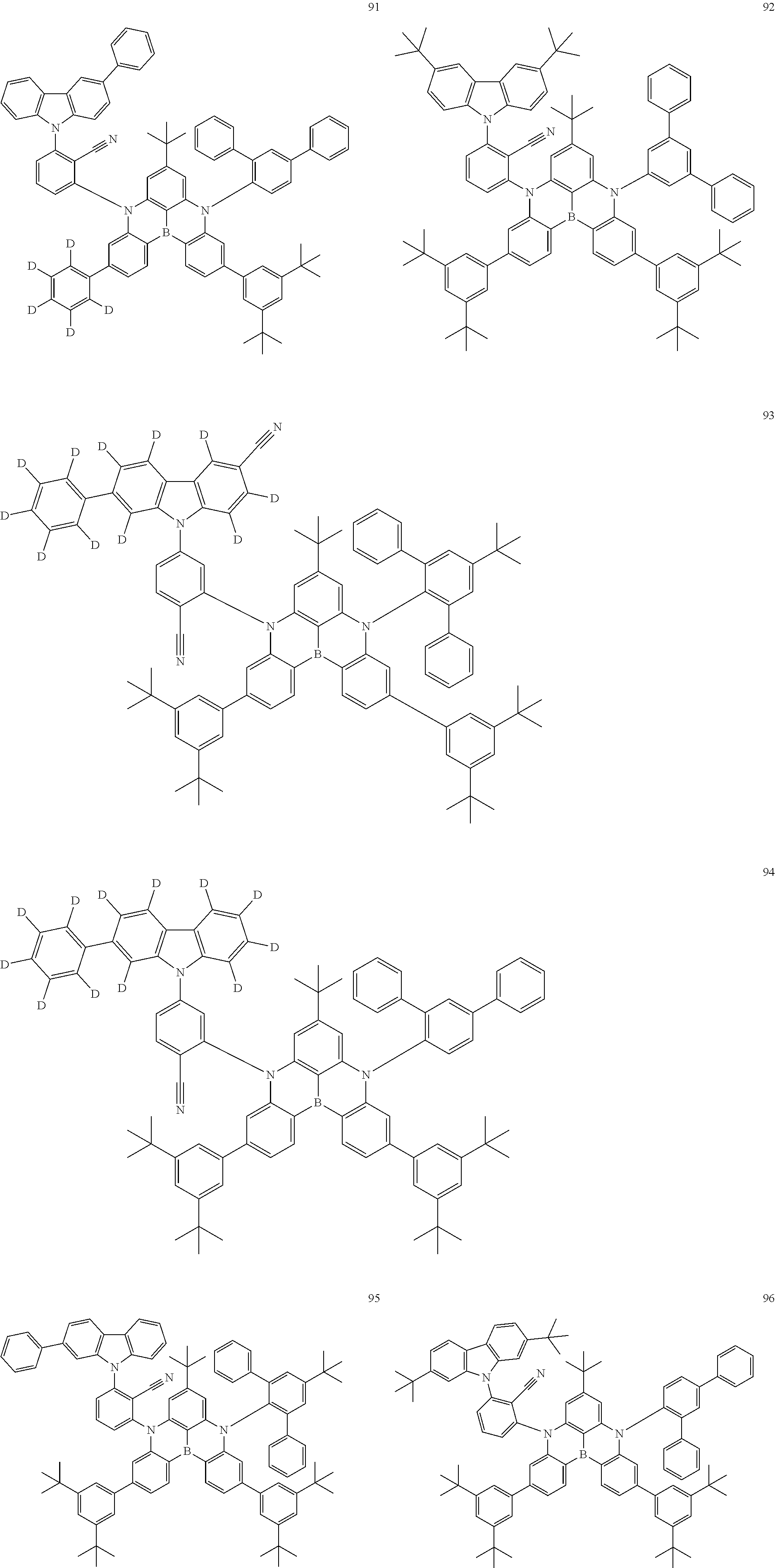

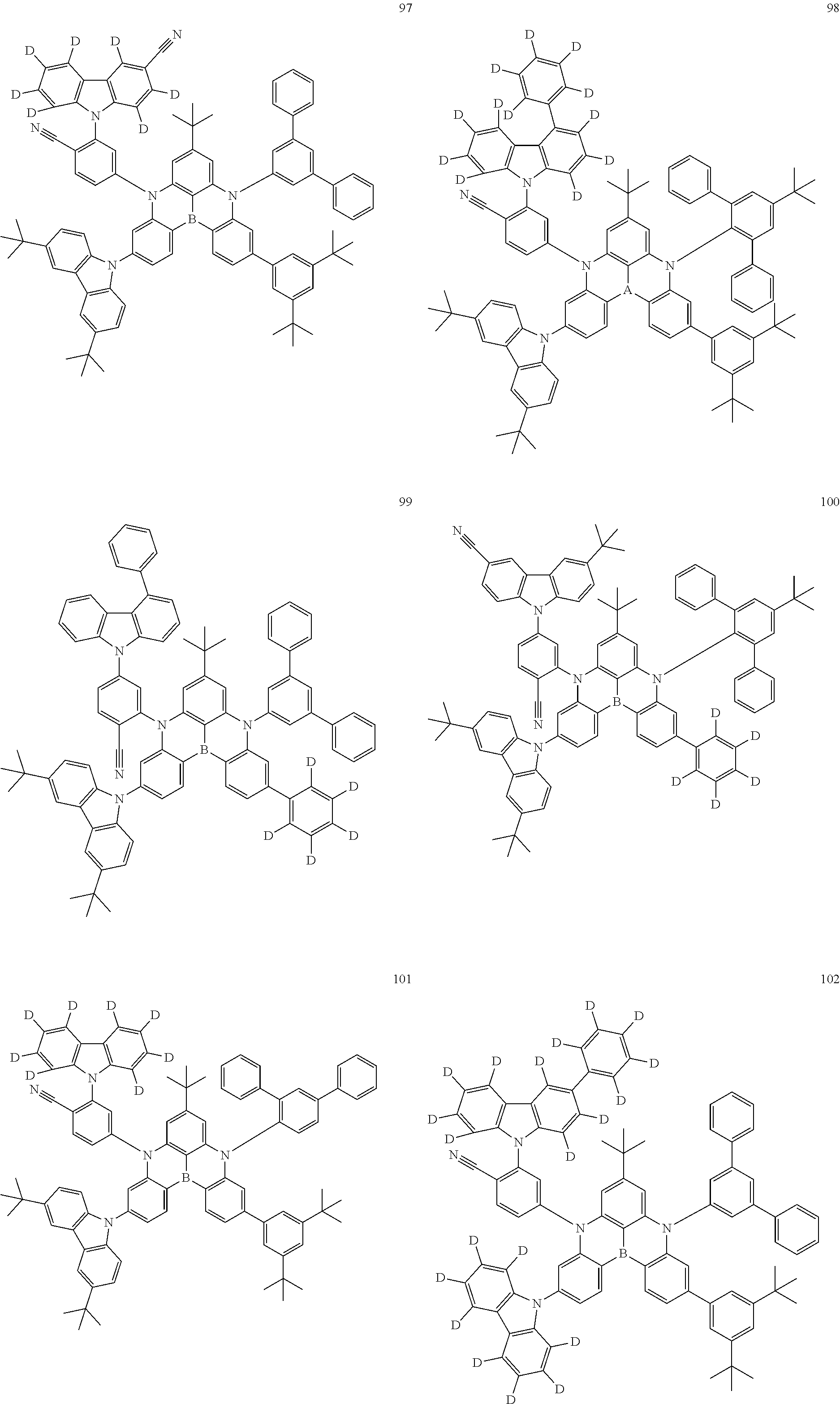

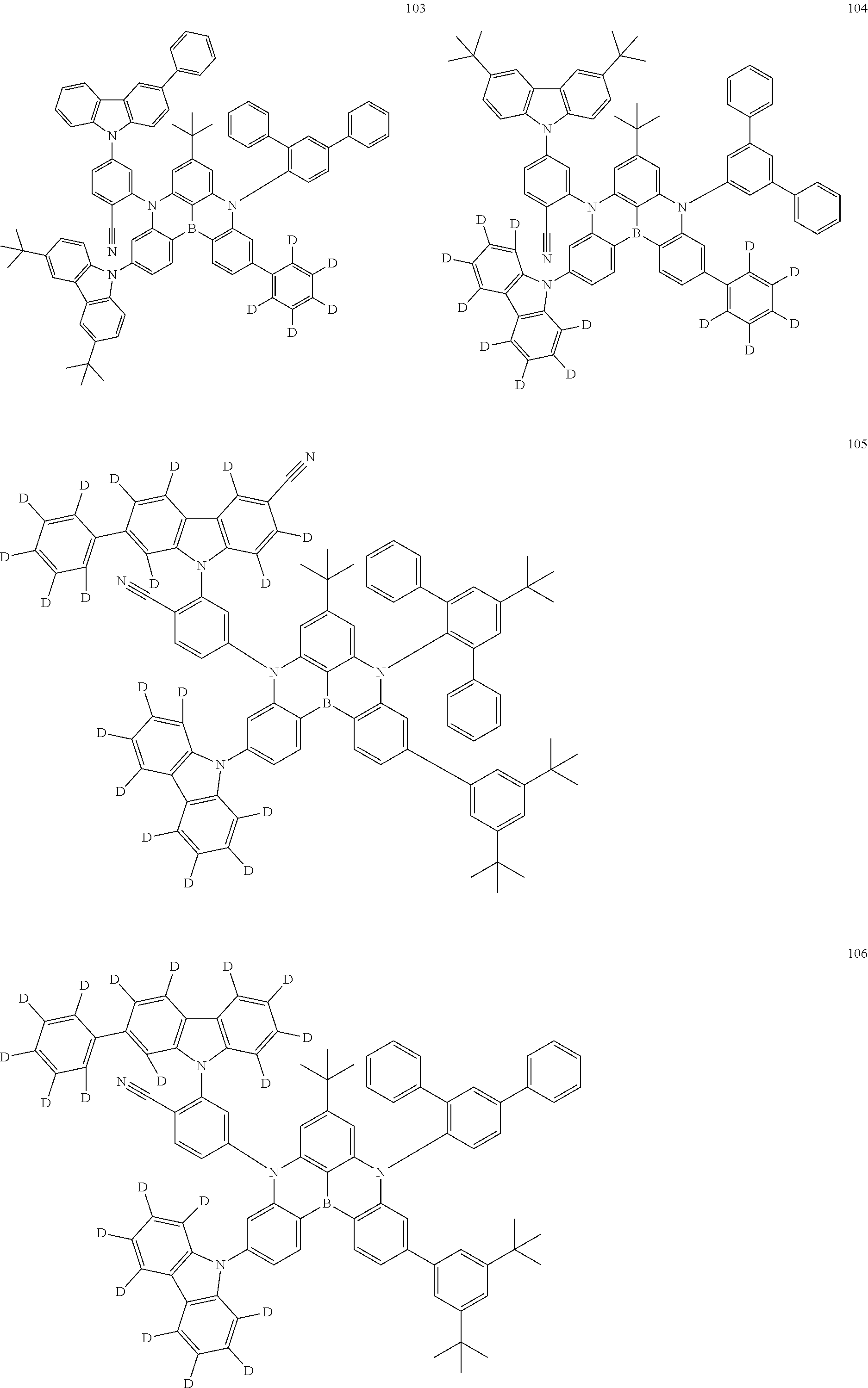

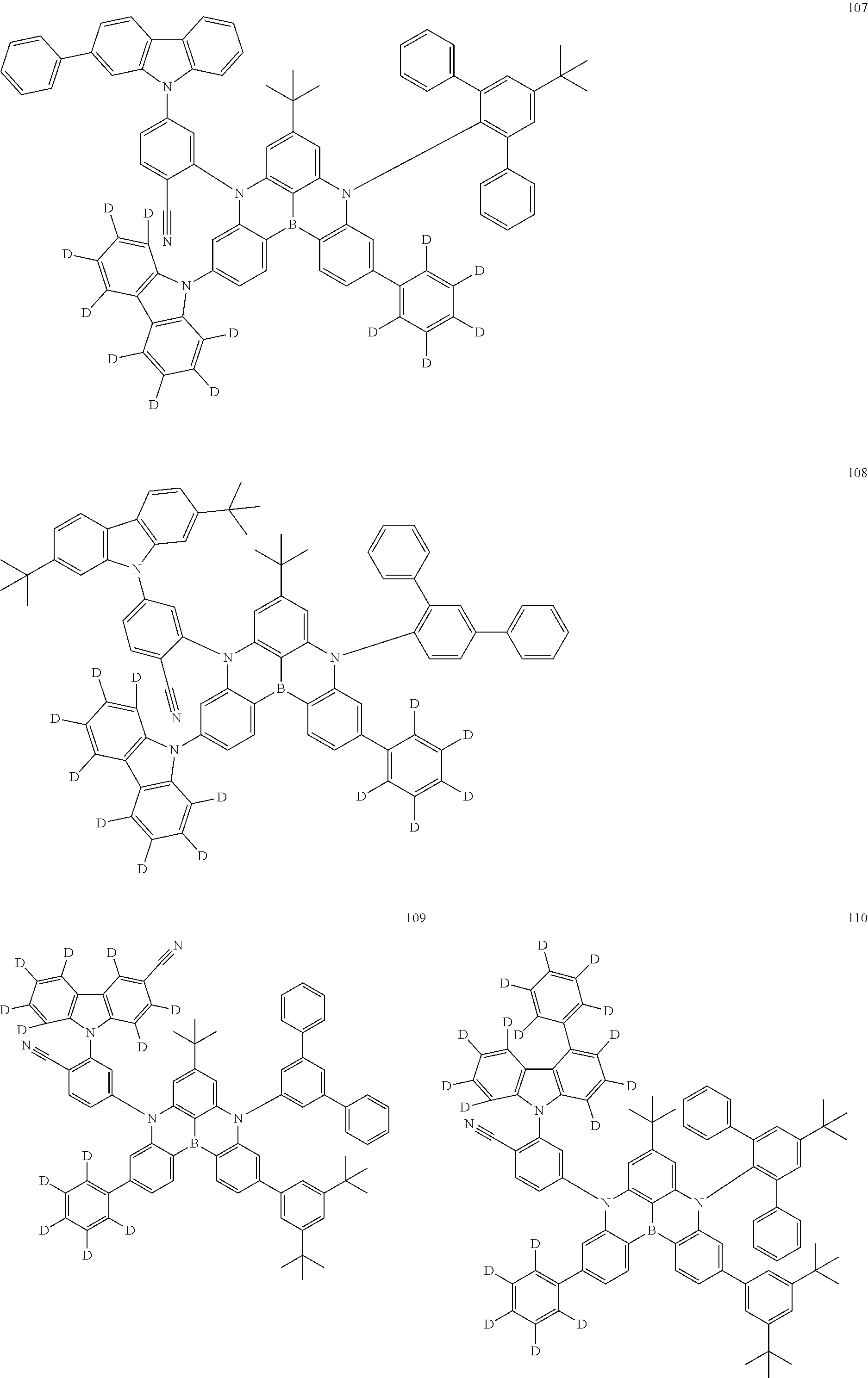

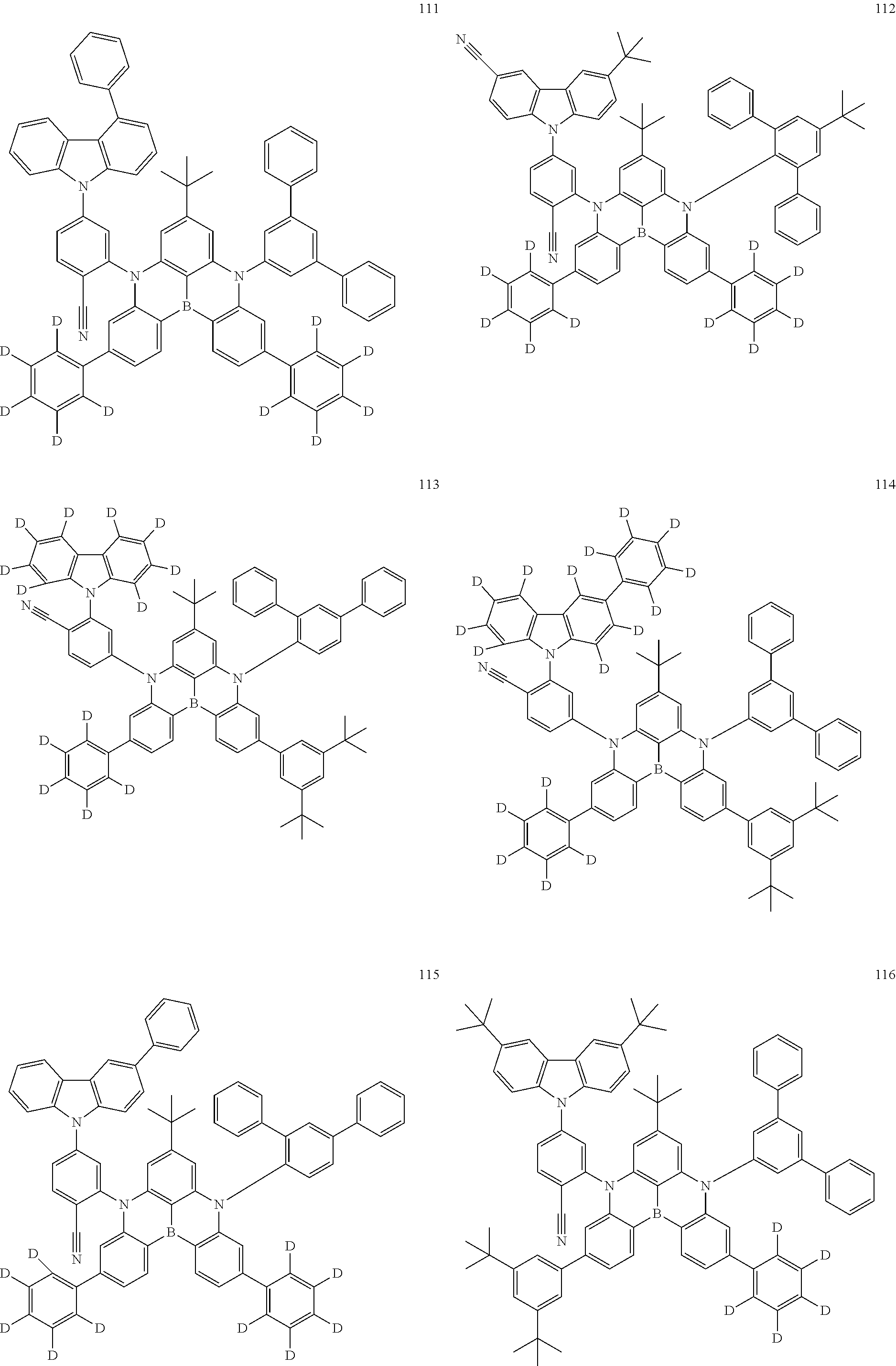

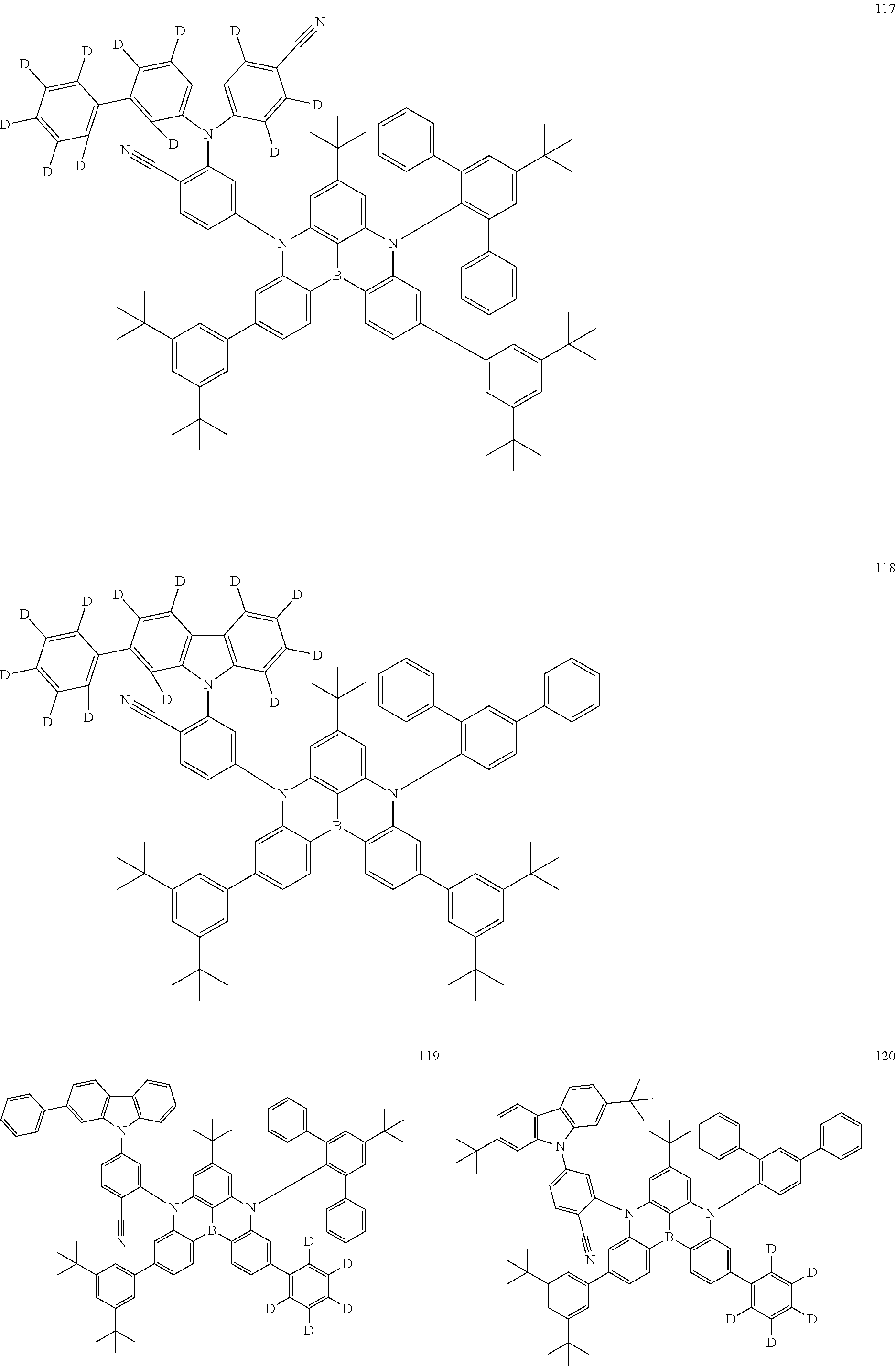

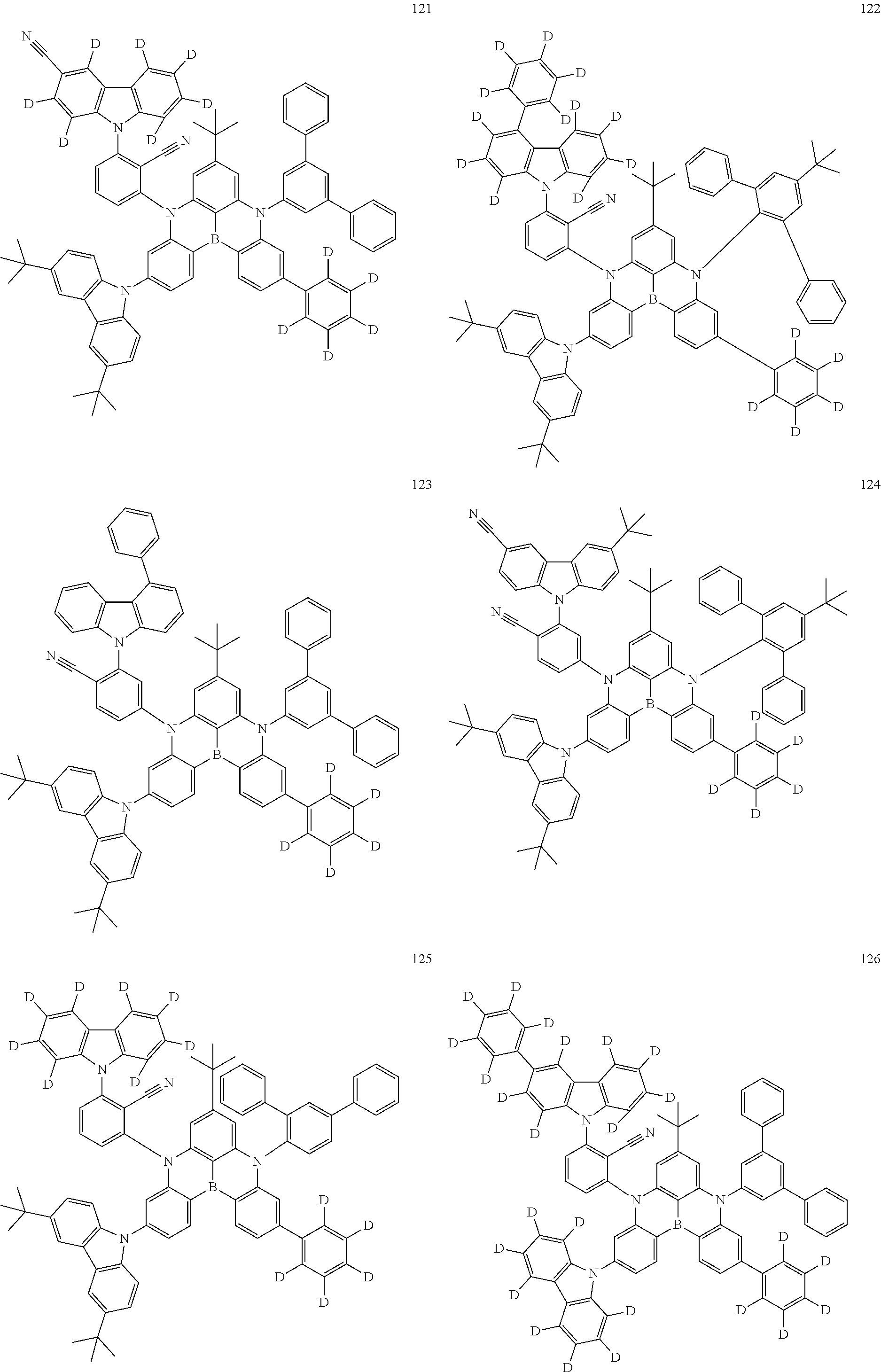

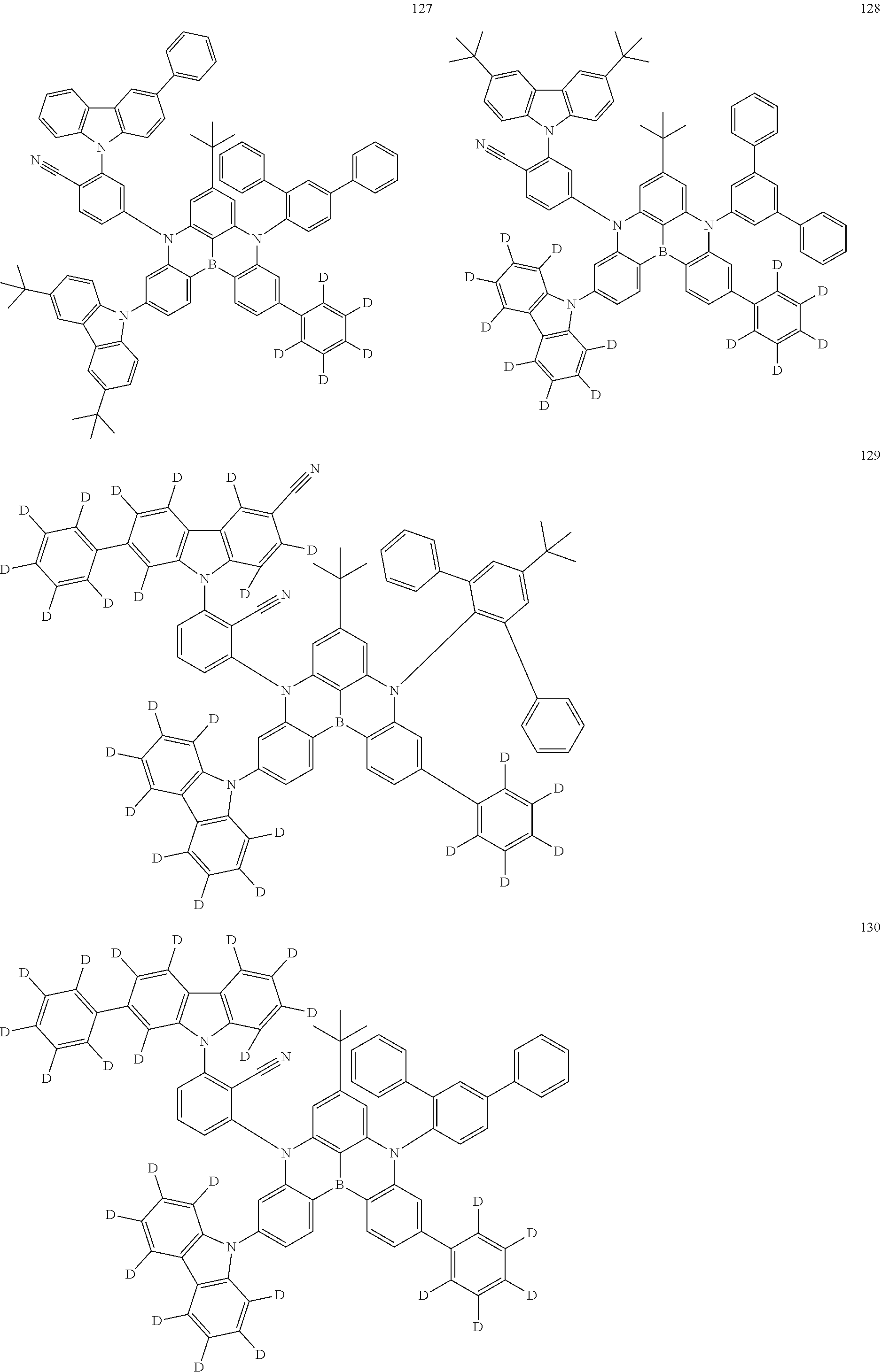

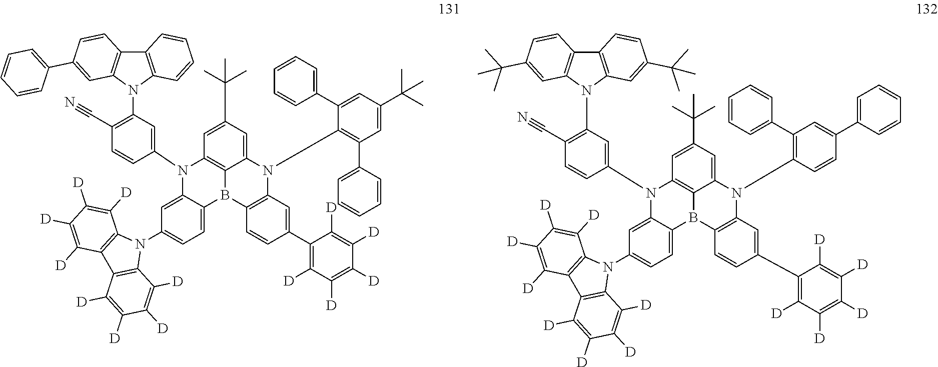 [SMILES: [2H]c1c([2H])c([2H])c(-c2ccc3c(c2)N(c2c(-c4ccccc4)cc(C(C)(C)C)cc2-c2ccccc2)c2cc(C(C)(C)C)cc4c2B3c2ccc(-n3c5c([2H])c([2H])c([2H])c([2H])c5c5c([2H])c([2H])c([2H])c([2H])c53)cc2N4c2ccc(C#N)c(-n3c4ccccc4c4ccc(-c5ccccc5)cc43)c2)c([2H])c1[2H] ; [2H]c1c([2H])c([2H])c(-c2ccc3c(c2)N(c2ccc(-c4ccccc4)cc2-c2ccccc2)c2cc(C(C)(C)C)cc4c2B3c2ccc(-n3c5c([2H])c([2H])c([2H])c([2H])c5c5c([2H])c([2H])c([2H])c([2H])c53)cc2N4c2ccc(C#N)c(-n3c4cc(C(C)(C)C)ccc4c4ccc(C(C)(C)C)cc43)c2)c([2H])c1[2H]]

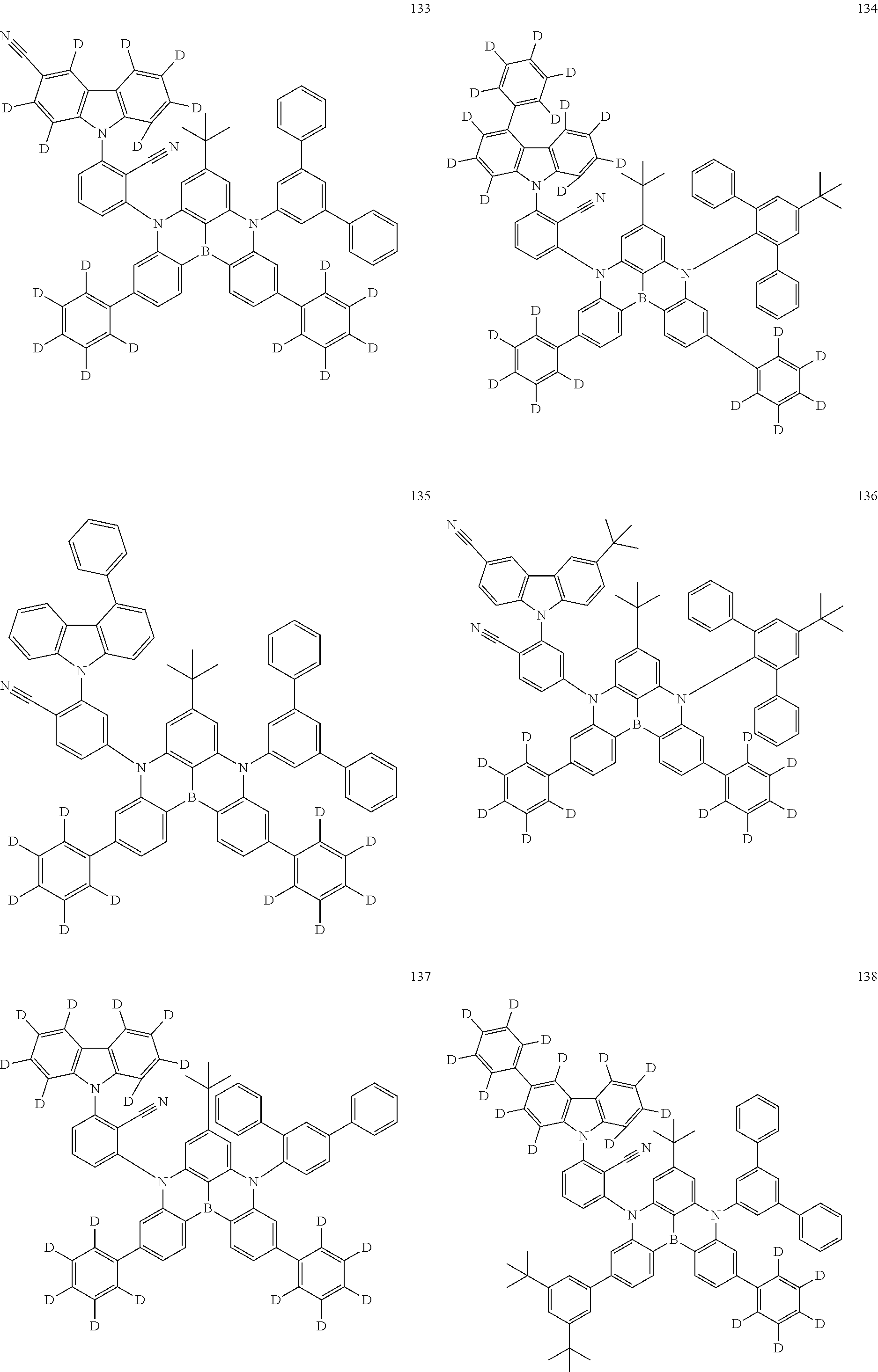

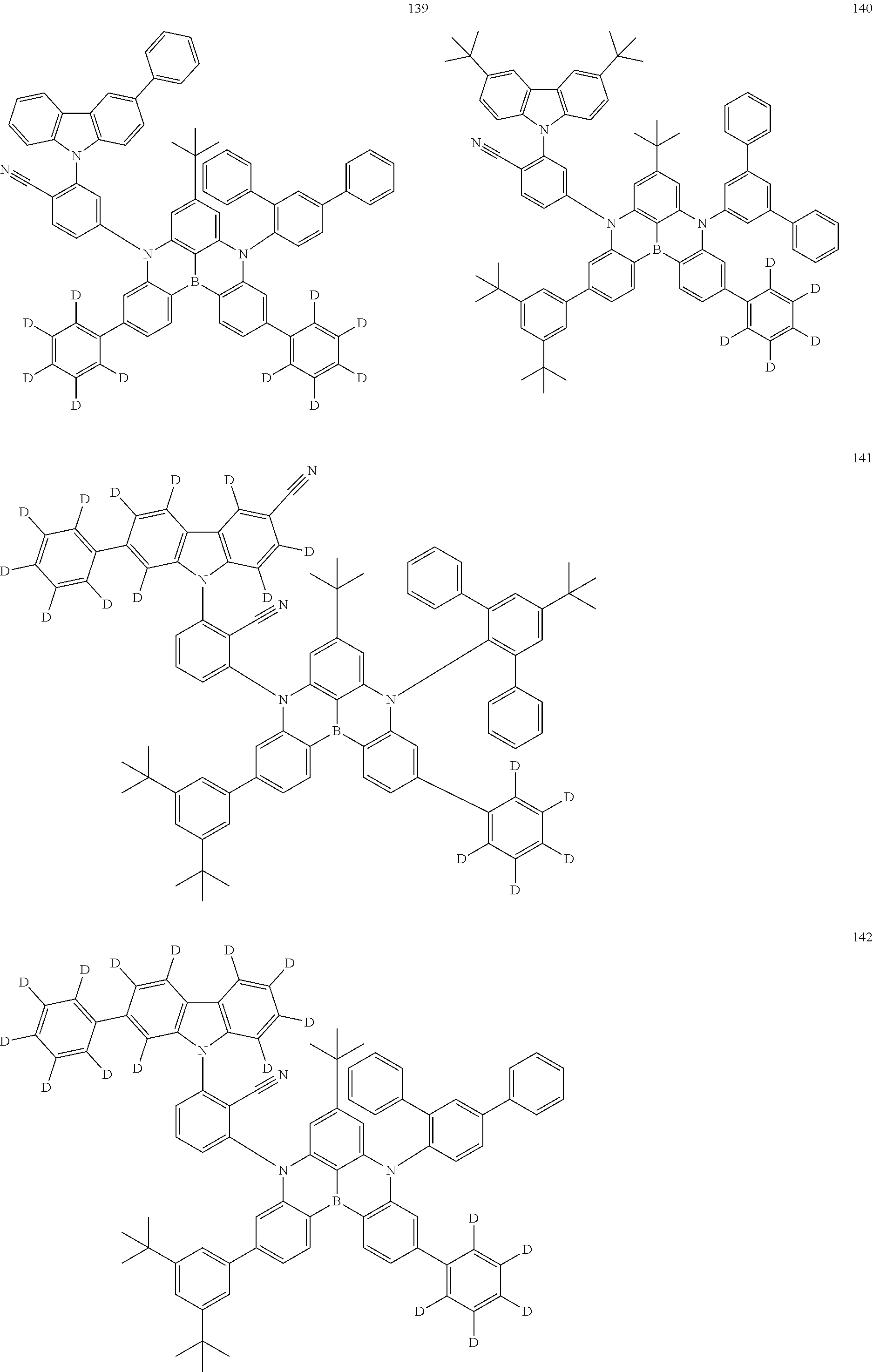

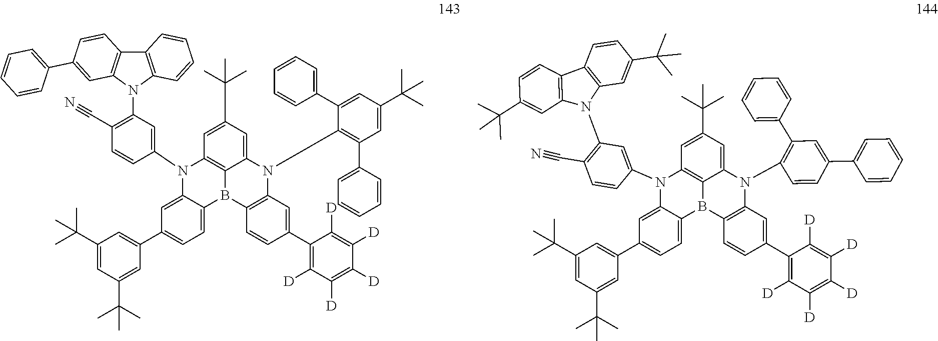 [SMILES: [2H]c1c([2H])c([2H])c(-c2ccc3c(c2)N(c2c(-c4ccccc4)cc(C(C)(C)C)cc2-c2ccccc2)c2cc(C(C)(C)C)cc4c2B3c2ccc(-c3cc(C(C)(C)C)cc(C(C)(C)C)c3)cc2N4c2ccc(C#N)c(-n3c4ccccc4c4ccc(-c5ccccc5)cc43)c2)c([2H])c1[2H] ; [2H]c1c([2H])c([2H])c(-c2ccc3c(c2)N(c2ccc(-c4ccccc4)cc2-c2ccccc2)c2cc(C(C)(C)C)cc4c2B3c2ccc(-c3cc(C(C)(C)C)cc(C(C)(C)C)c3)cc2N4c2ccc(C#N)c(-n3c4cc(C(C)(C)C)ccc4c4ccc(C(C)(C)C)cc43)c2)c([2H])c1[2H]]

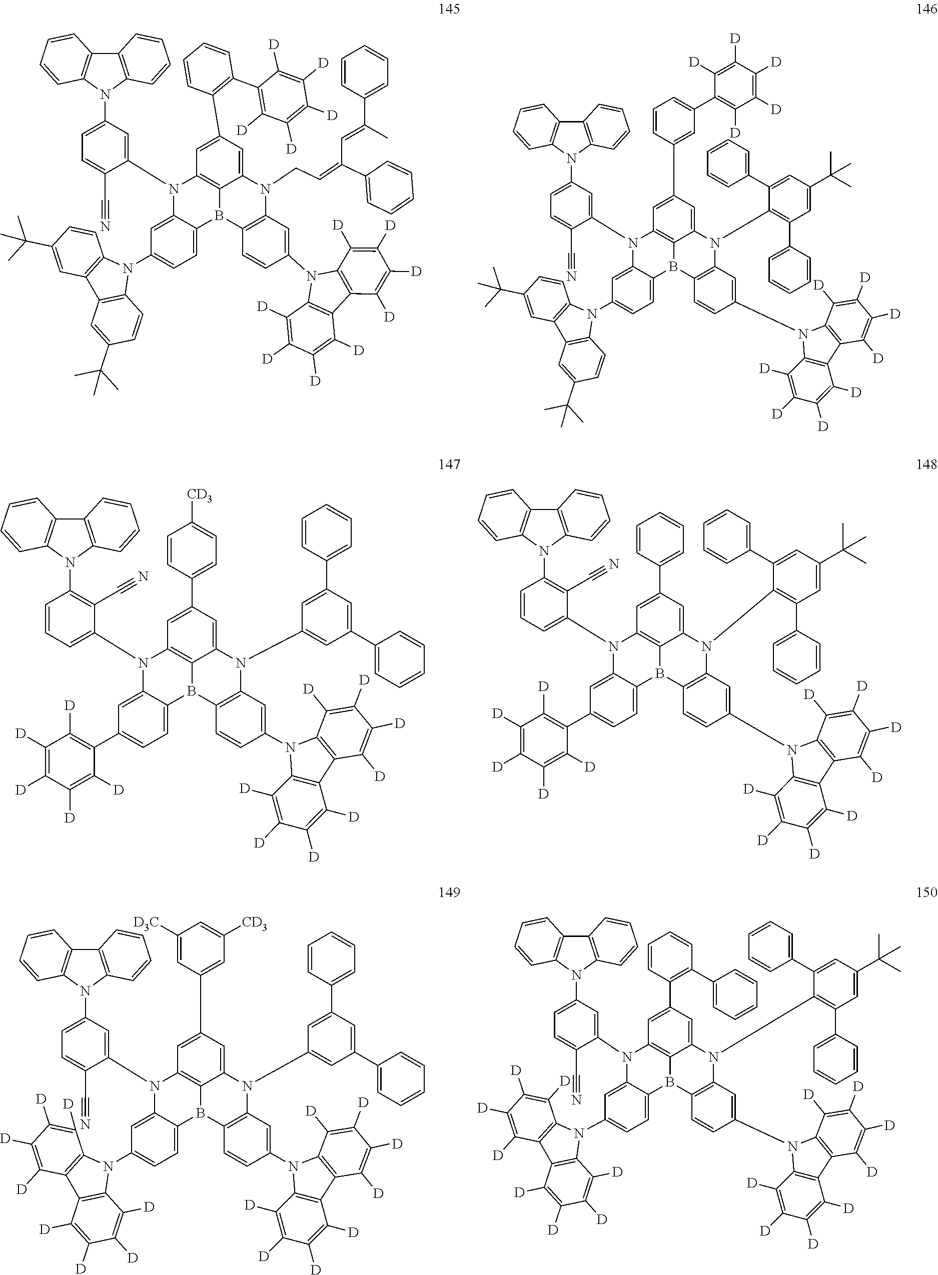

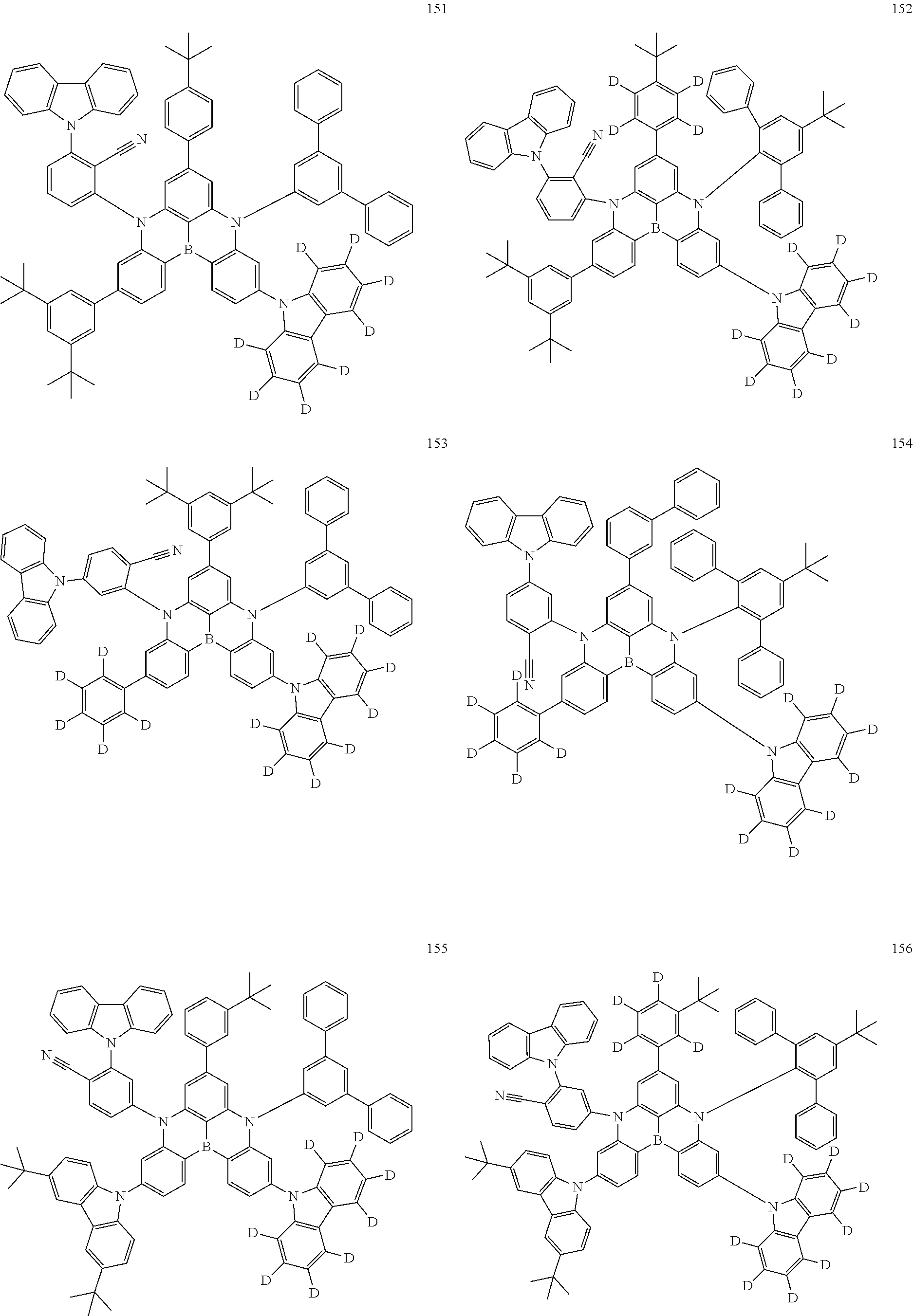

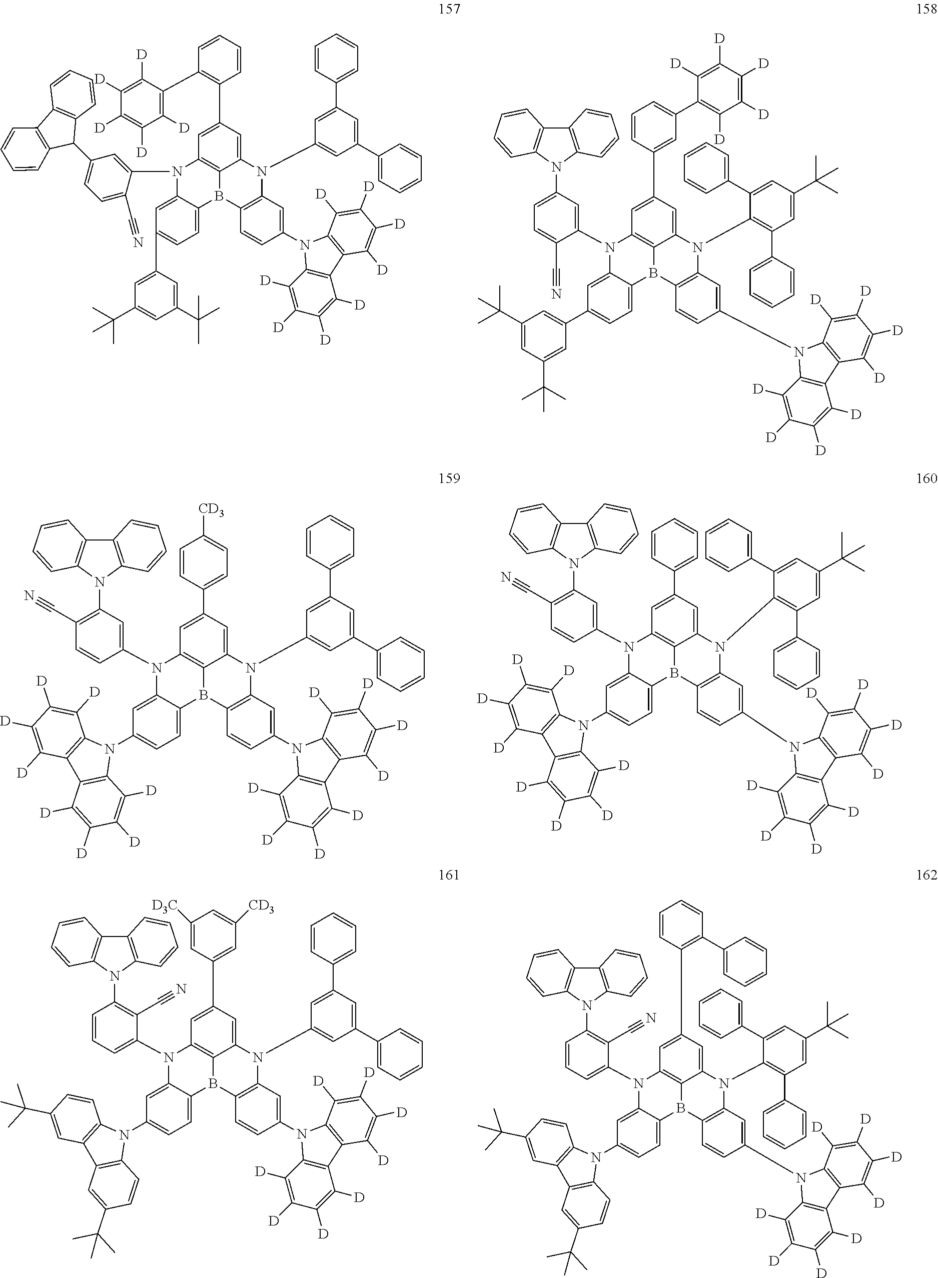

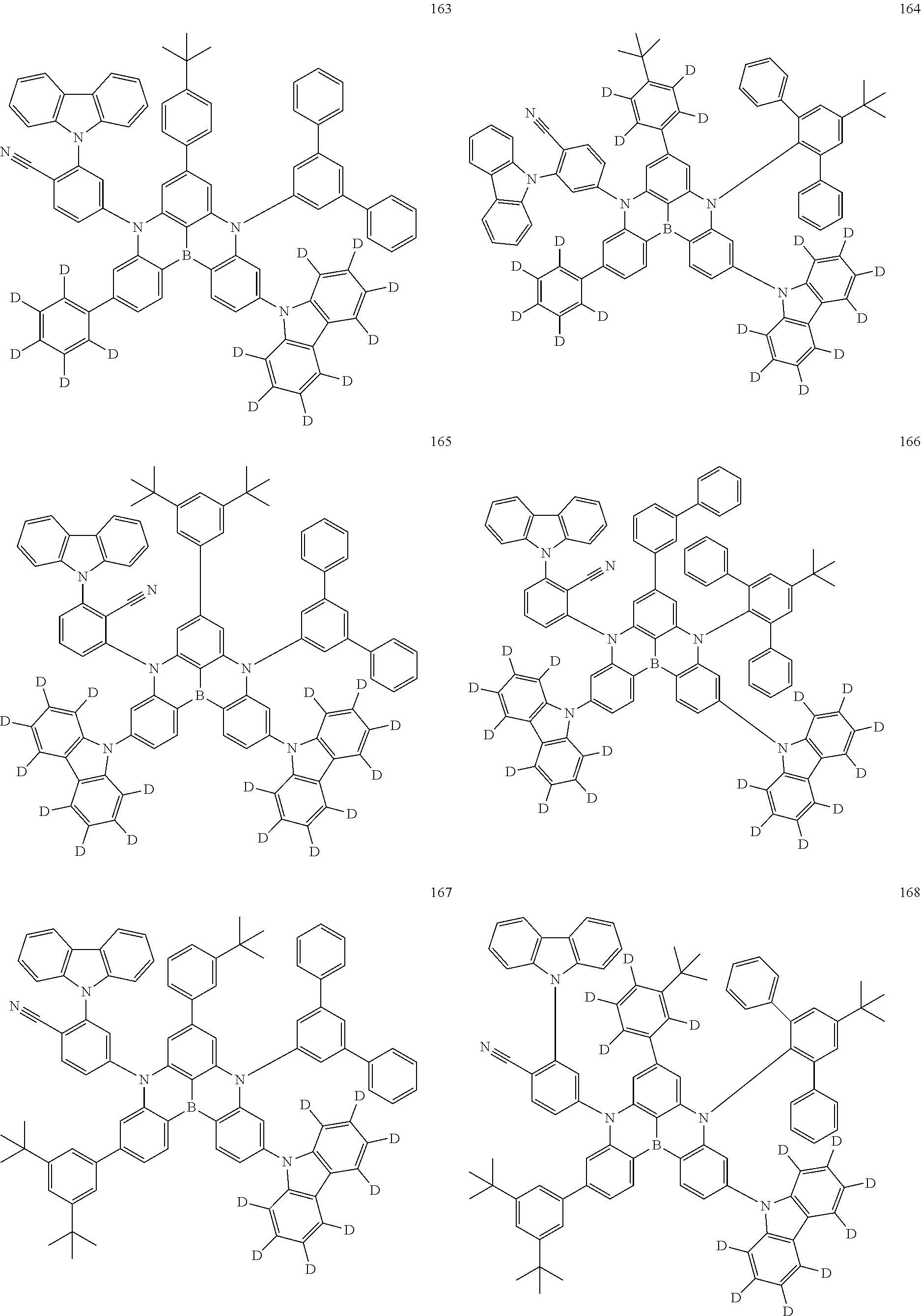

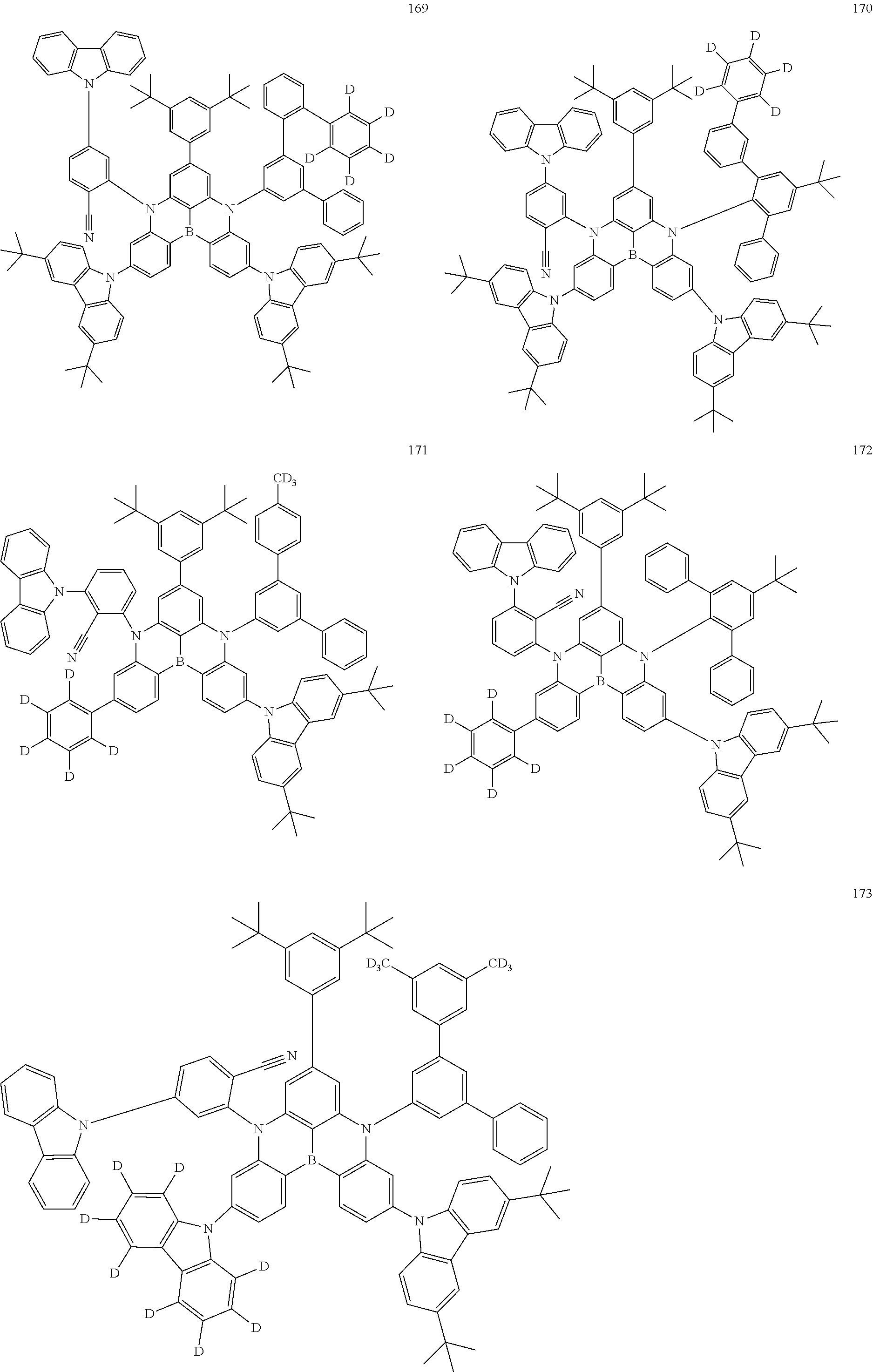

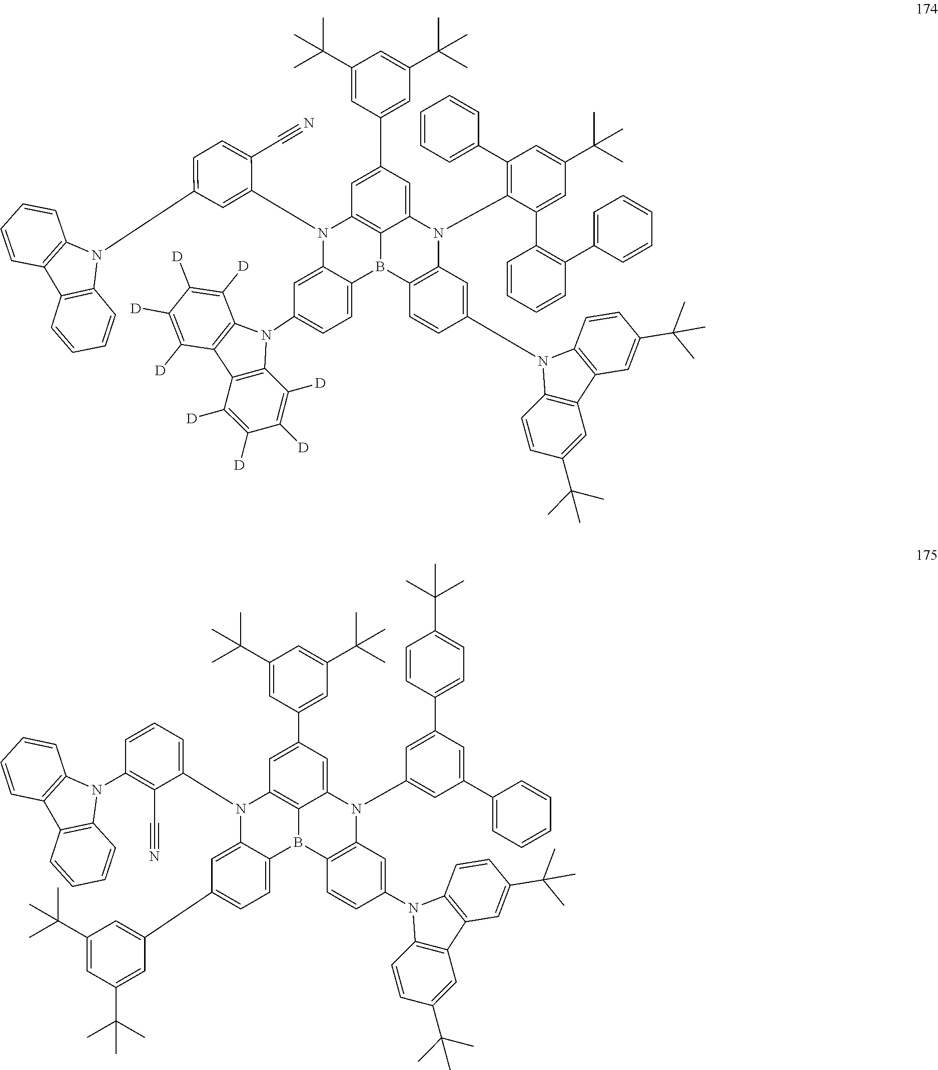 [SMILES: [2H]c1c([2H])c([2H])c2c(c1[2H])c1c([2H])c([2H])c([2H])c([2H])c1n2-c1ccc2c(c1)N(c1cc(-n3c4ccccc4c4ccccc43)ccc1C#N)c1cc(-c3cc(C(C)(C)C)cc(C(C)(C)C)c3)cc3c1B2c1ccc(-n2c4ccc(C(C)(C)C)cc4c4cc(C(C)(C)C)ccc42)cc1N3c1c(-c2ccccc2)cc(C(C)(C)C)cc1-c1ccccc1-c1ccccc1 ; CC(C)(C)c1ccc(-c2cc(-c3ccccc3)cc(N3c4cc(-n5c6ccc(C(C)(C)C)cc6c6cc(C(C)(C)C)ccc65)ccc4B4c5ccc(-c6cc(C(C)(C)C)cc(C(C)(C)C)c6)cc5N(c5cccc(-n6c7ccccc7c7ccccc76)c5C#N)c5cc(-c6cc(C(C)(C)C)cc(C(C)(C)C)c6)cc3c54)c2)cc1]

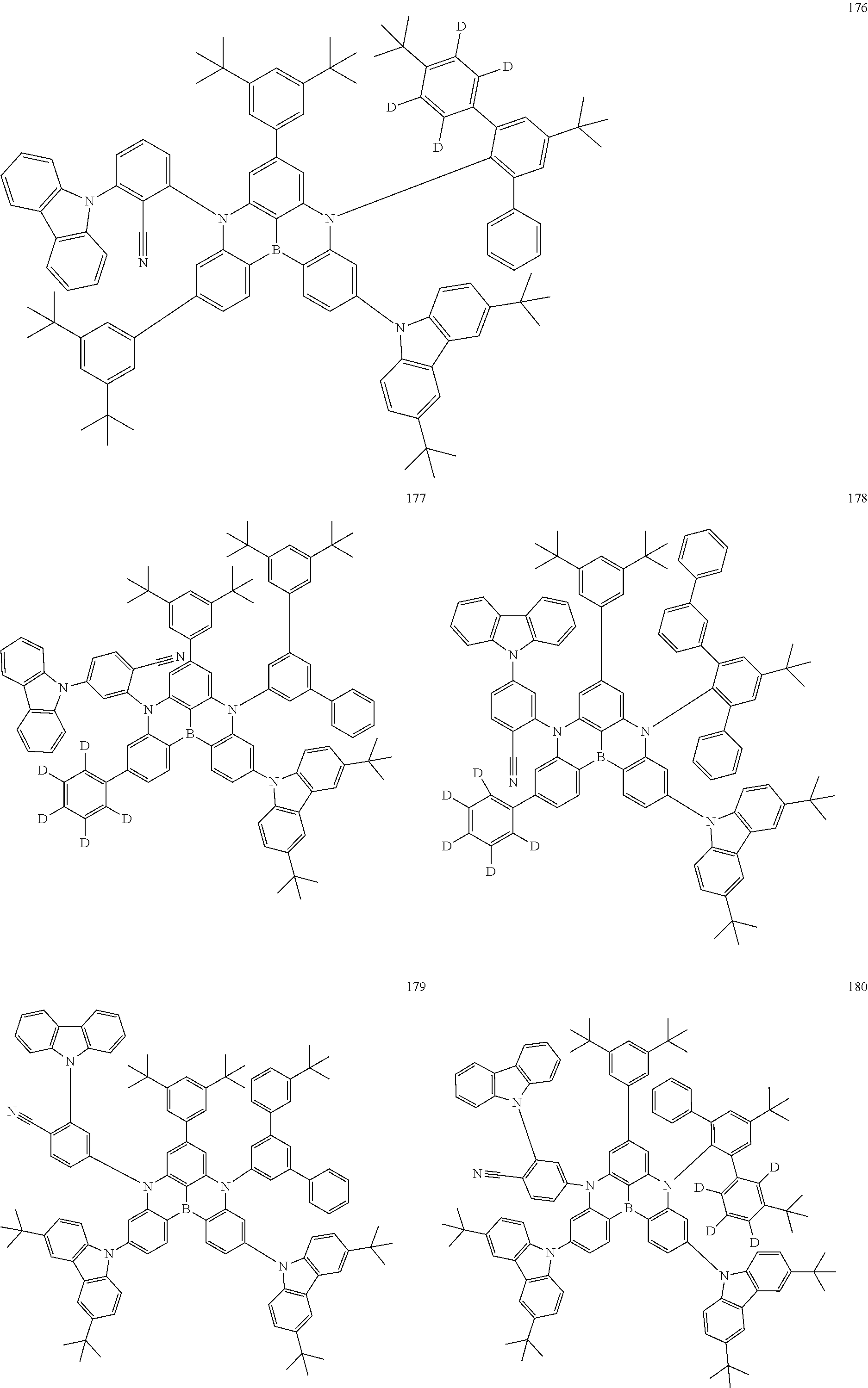

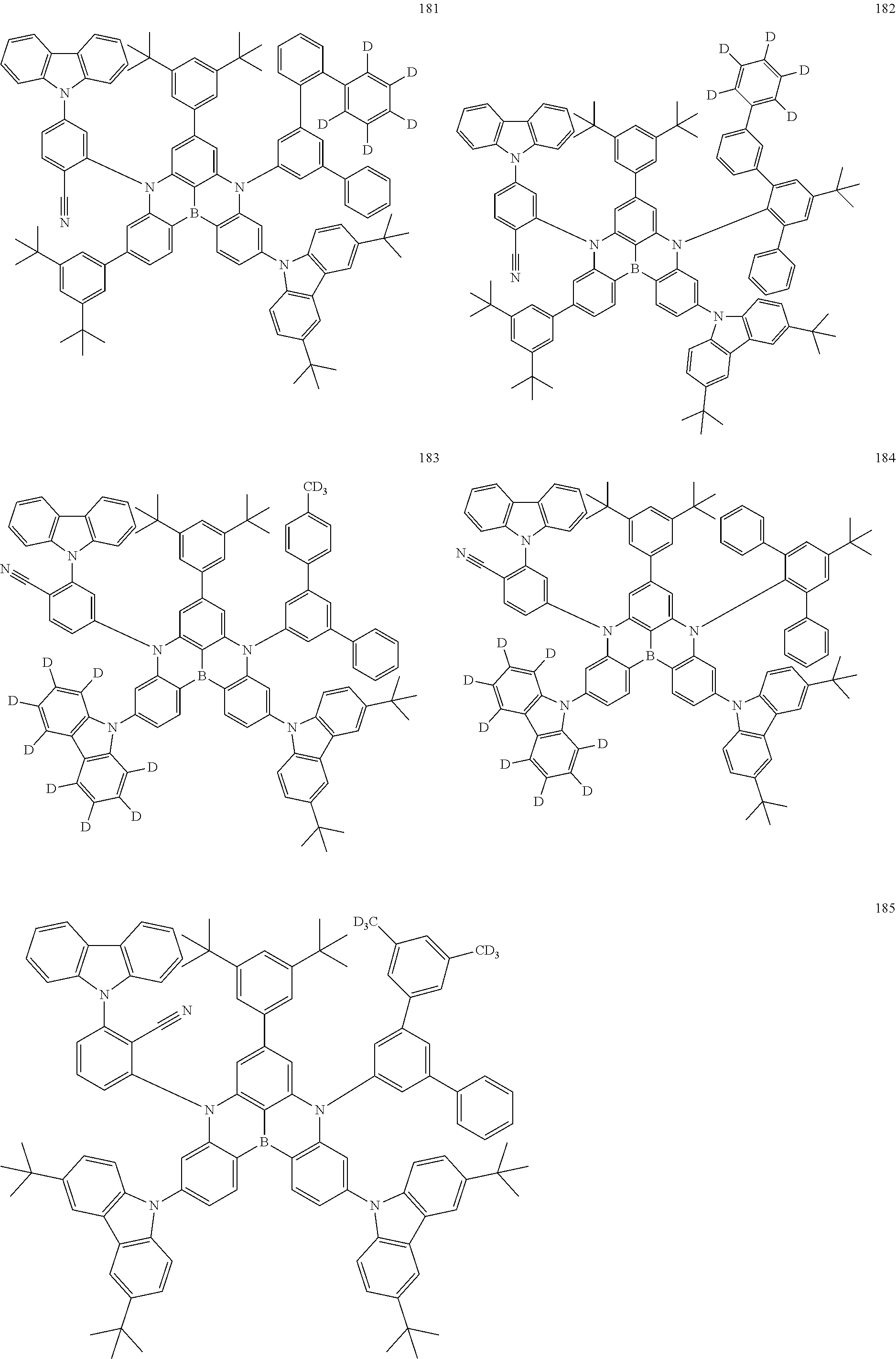

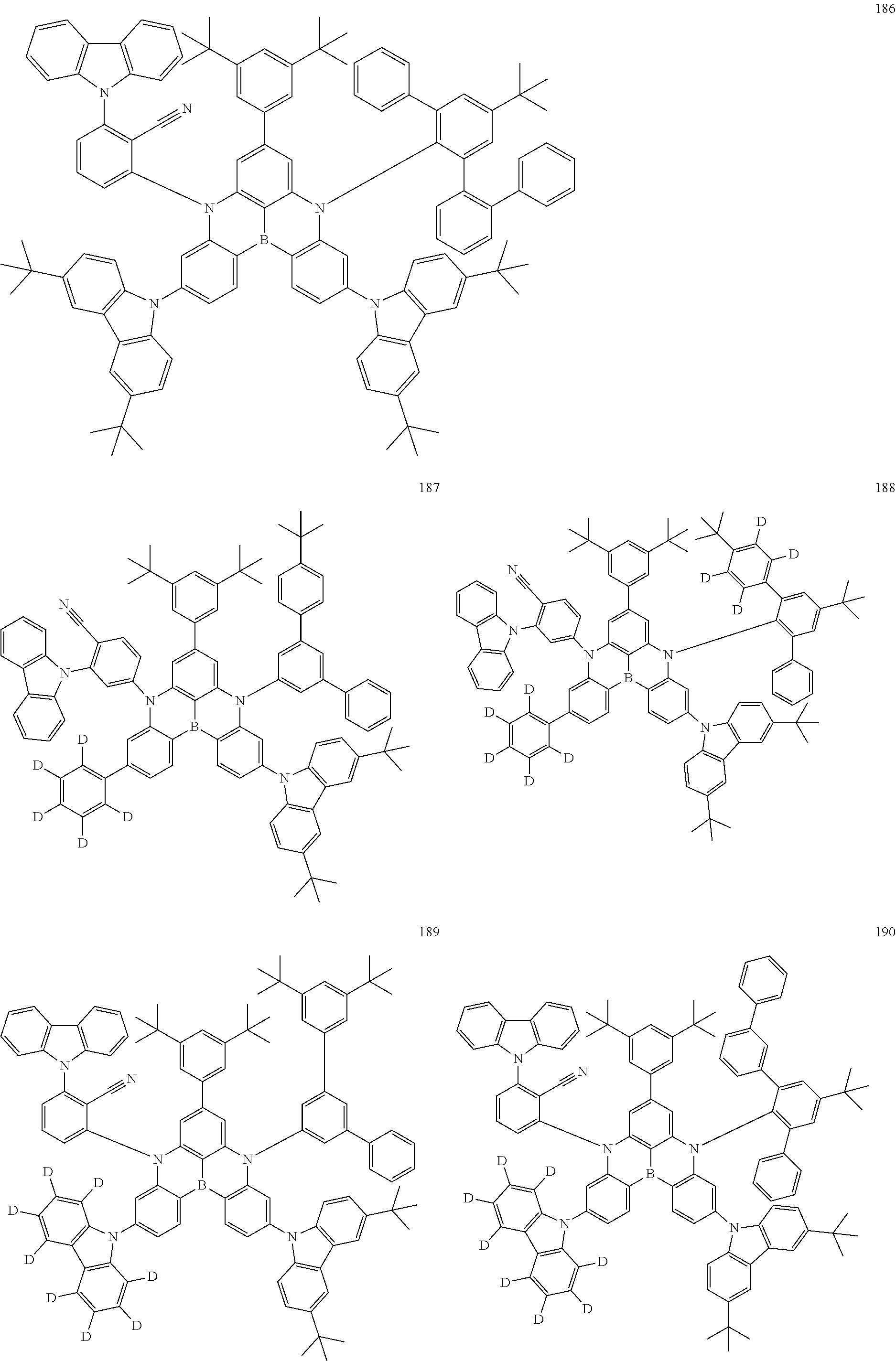

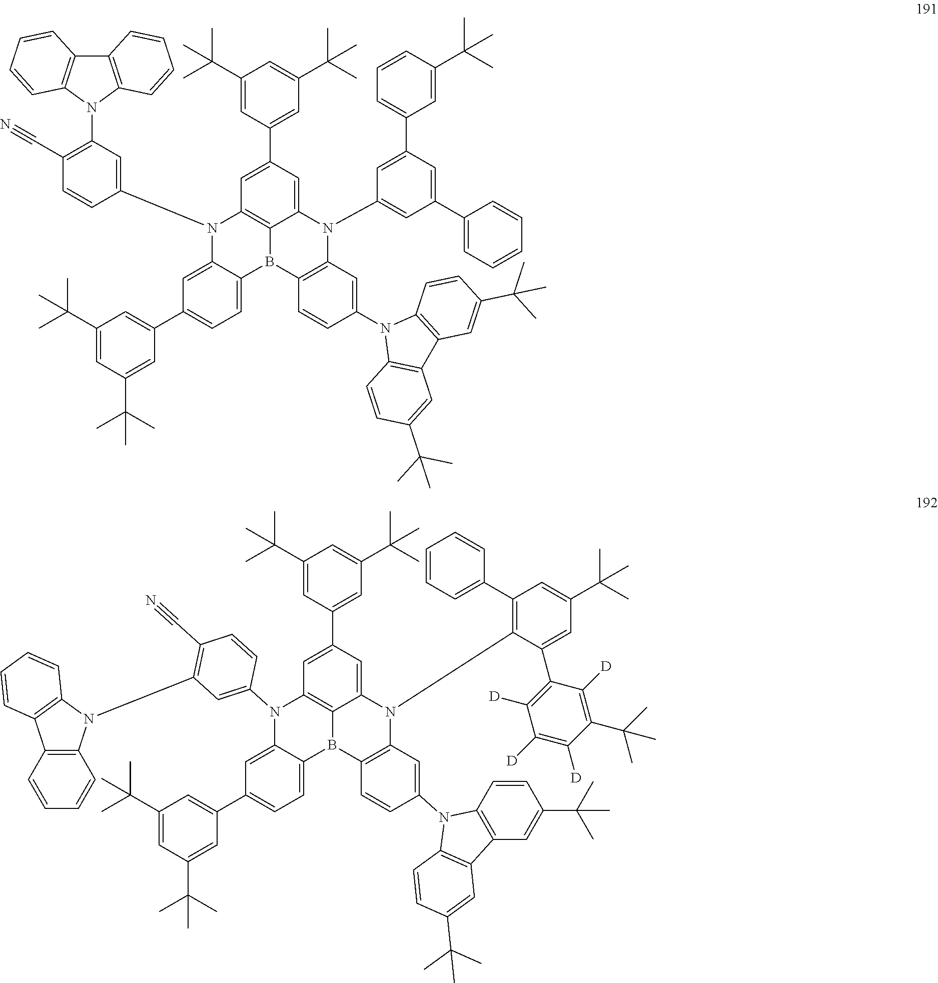

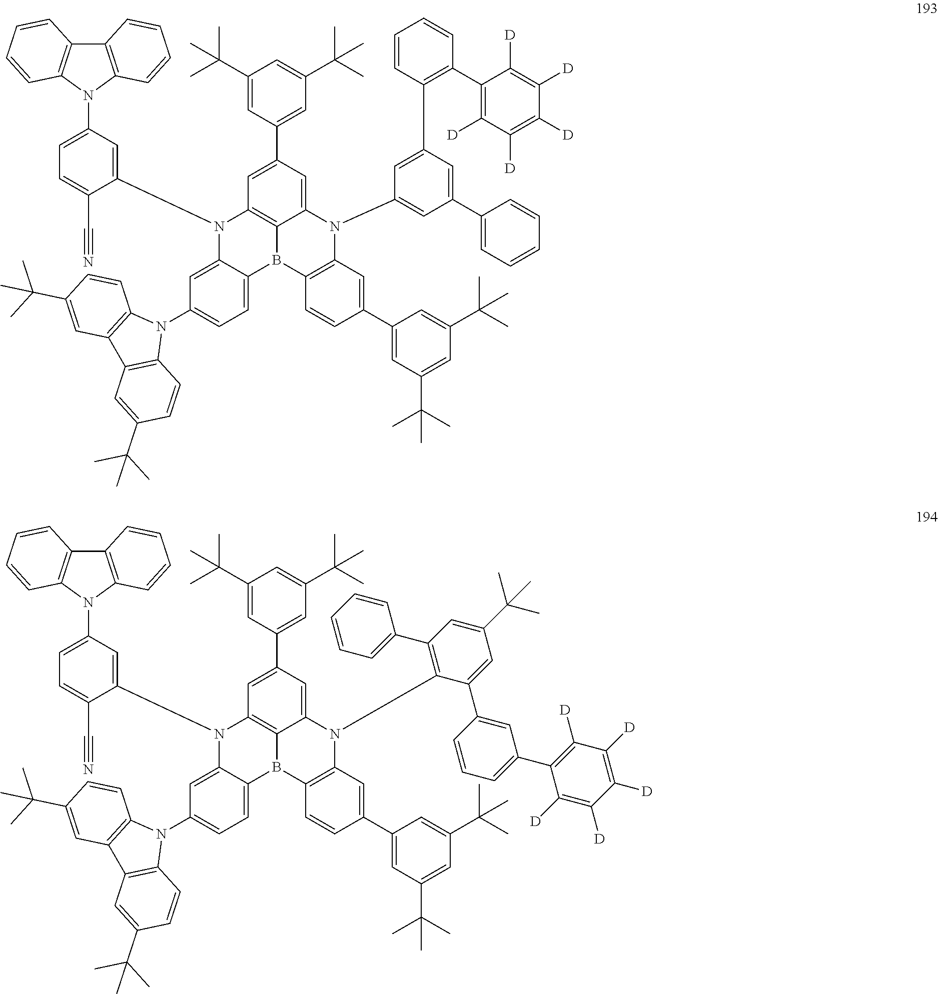

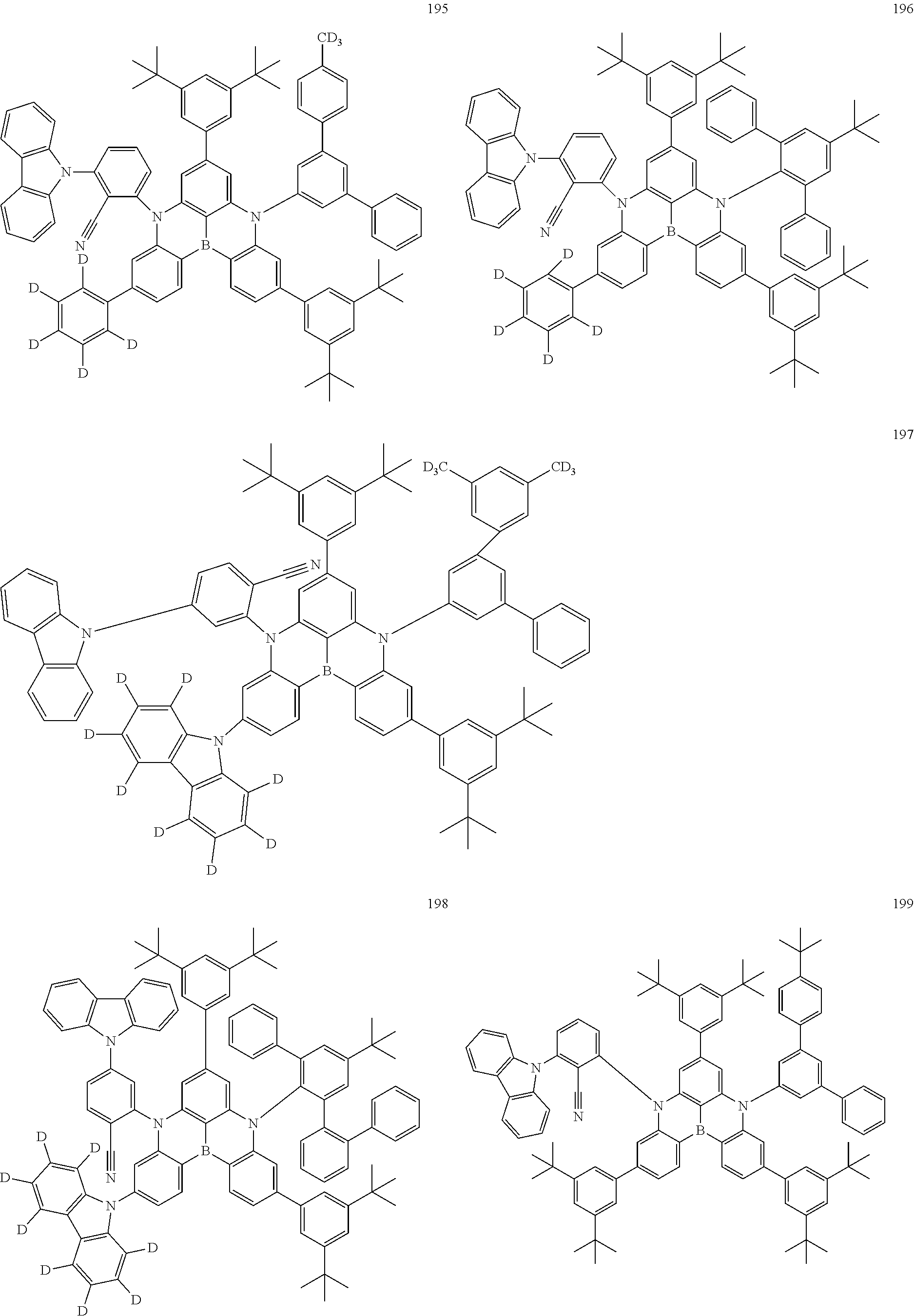

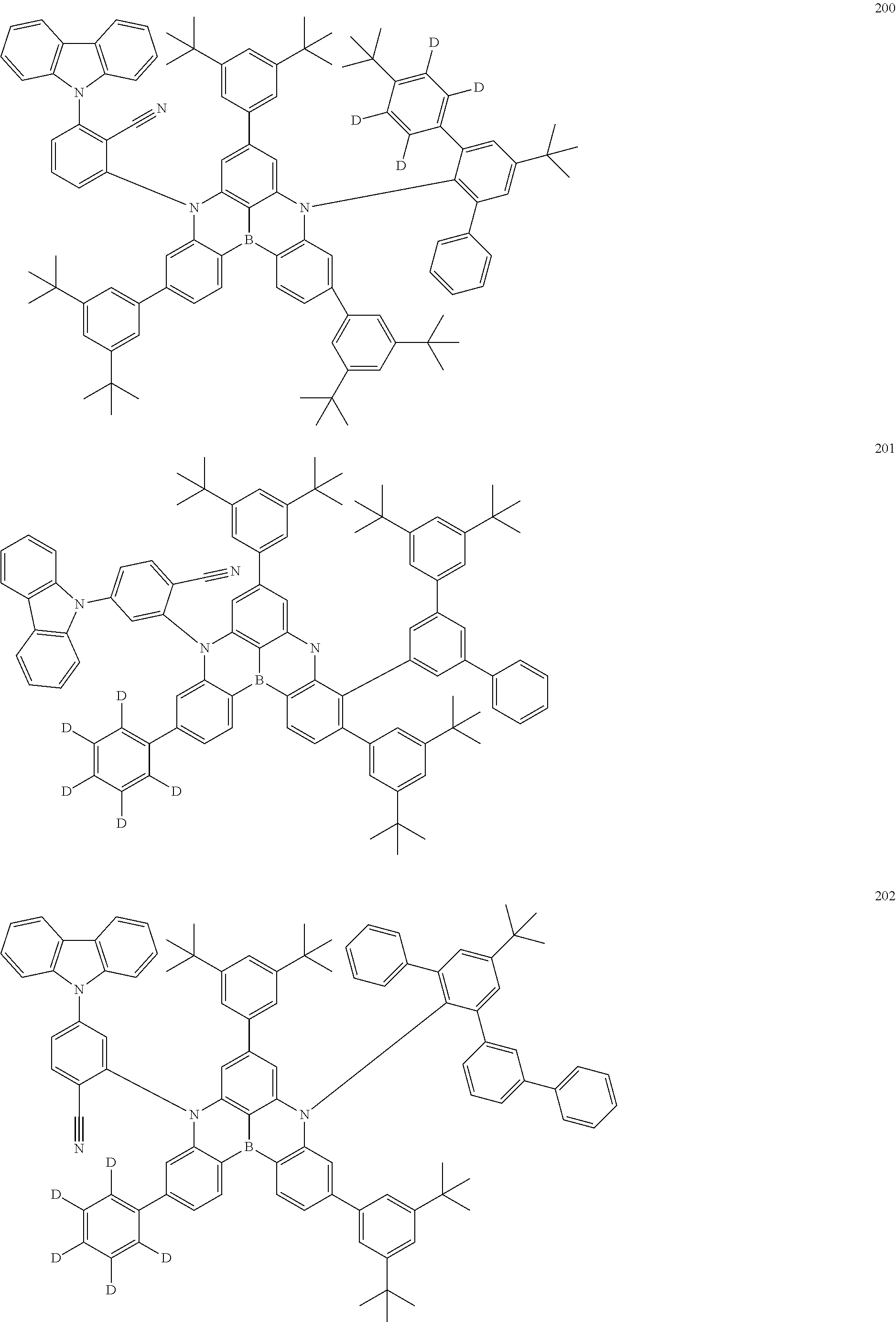

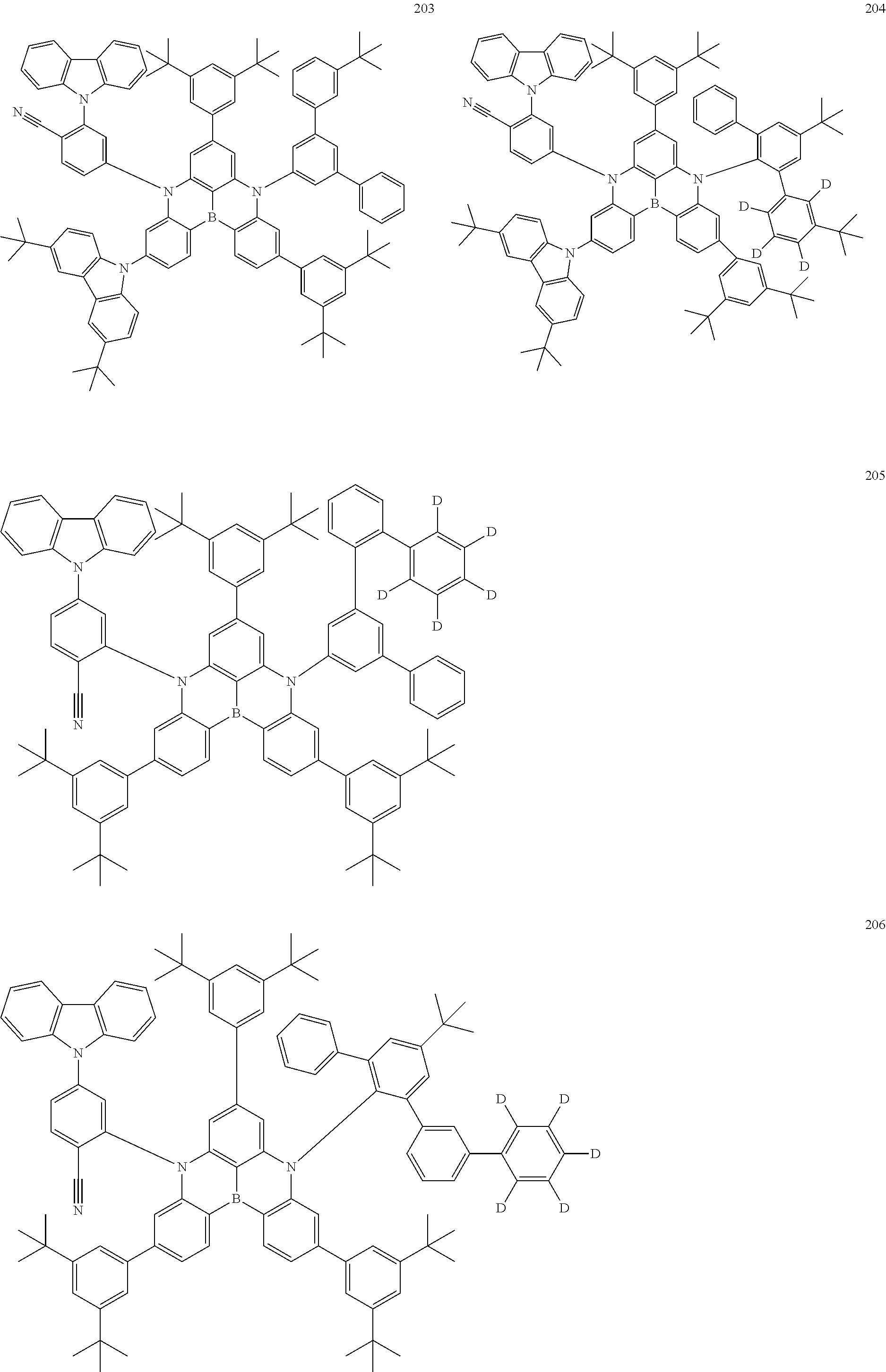

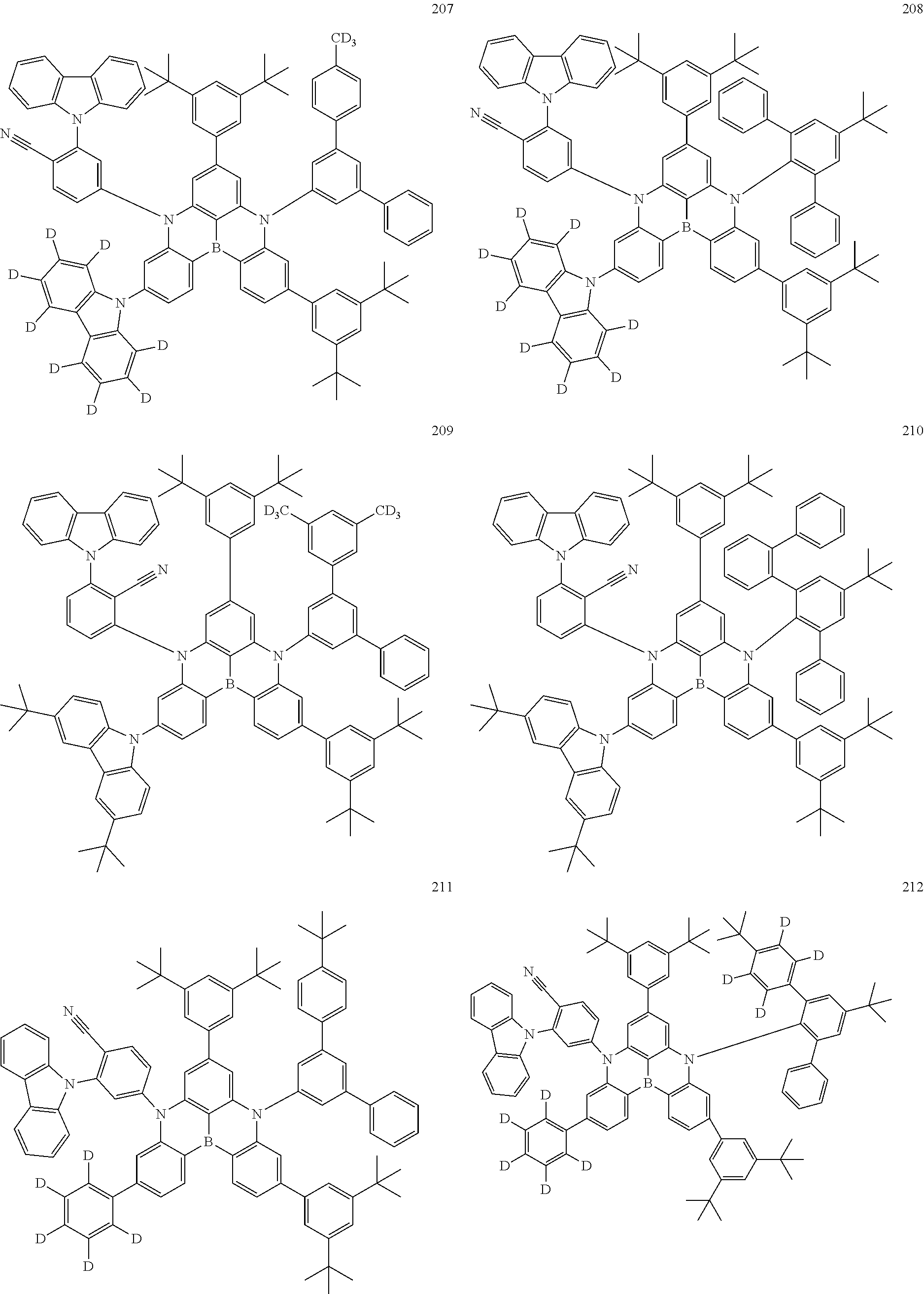

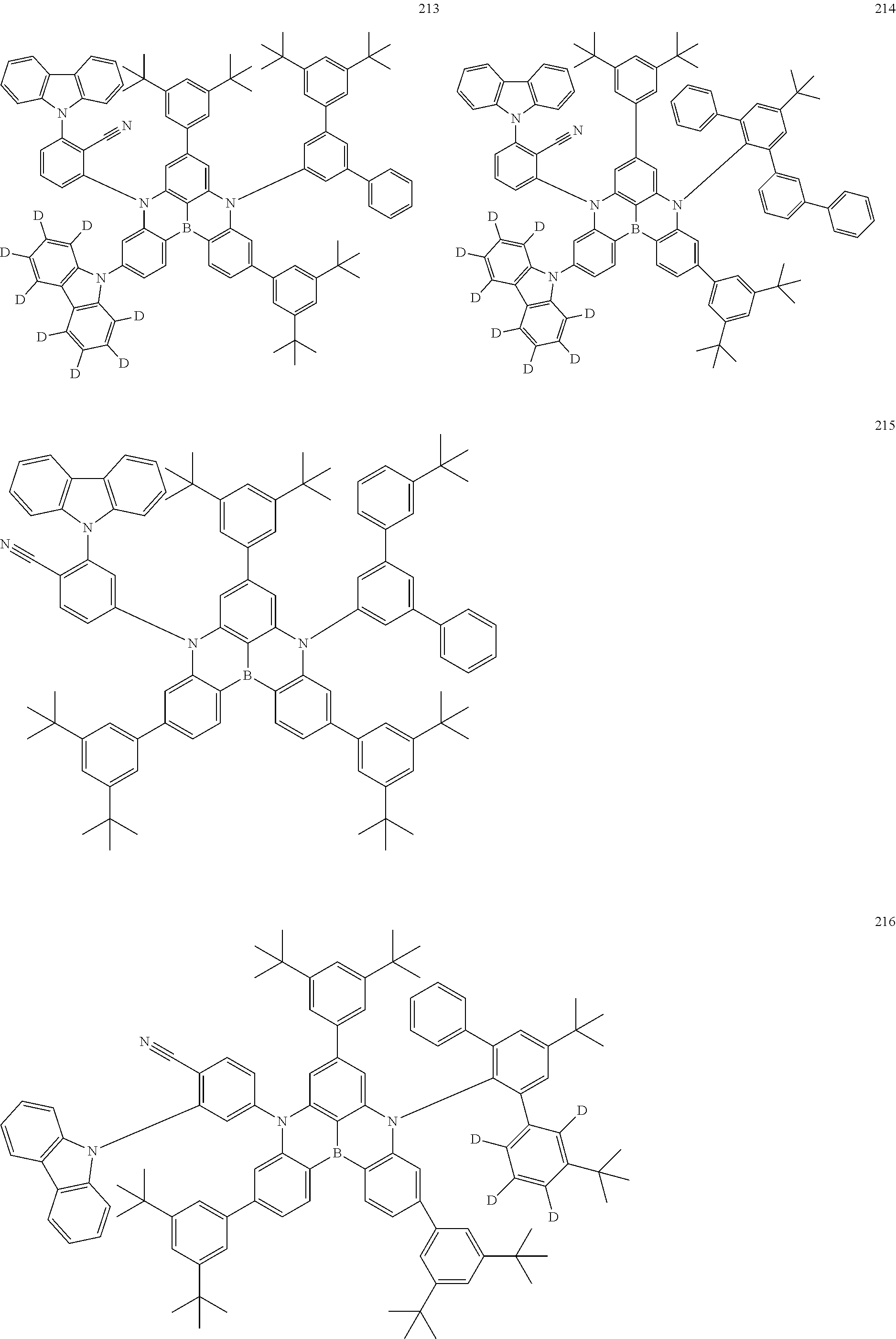

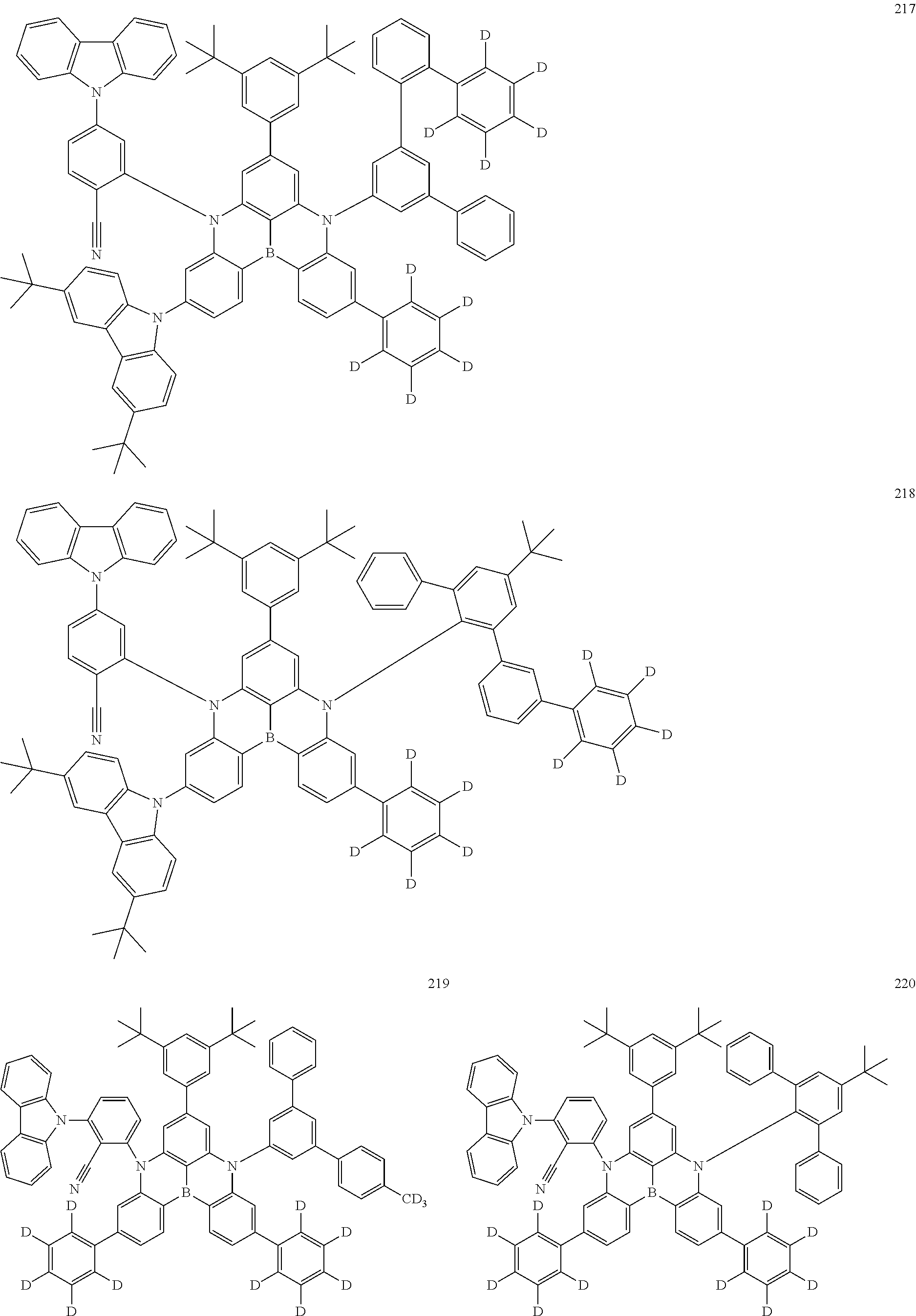

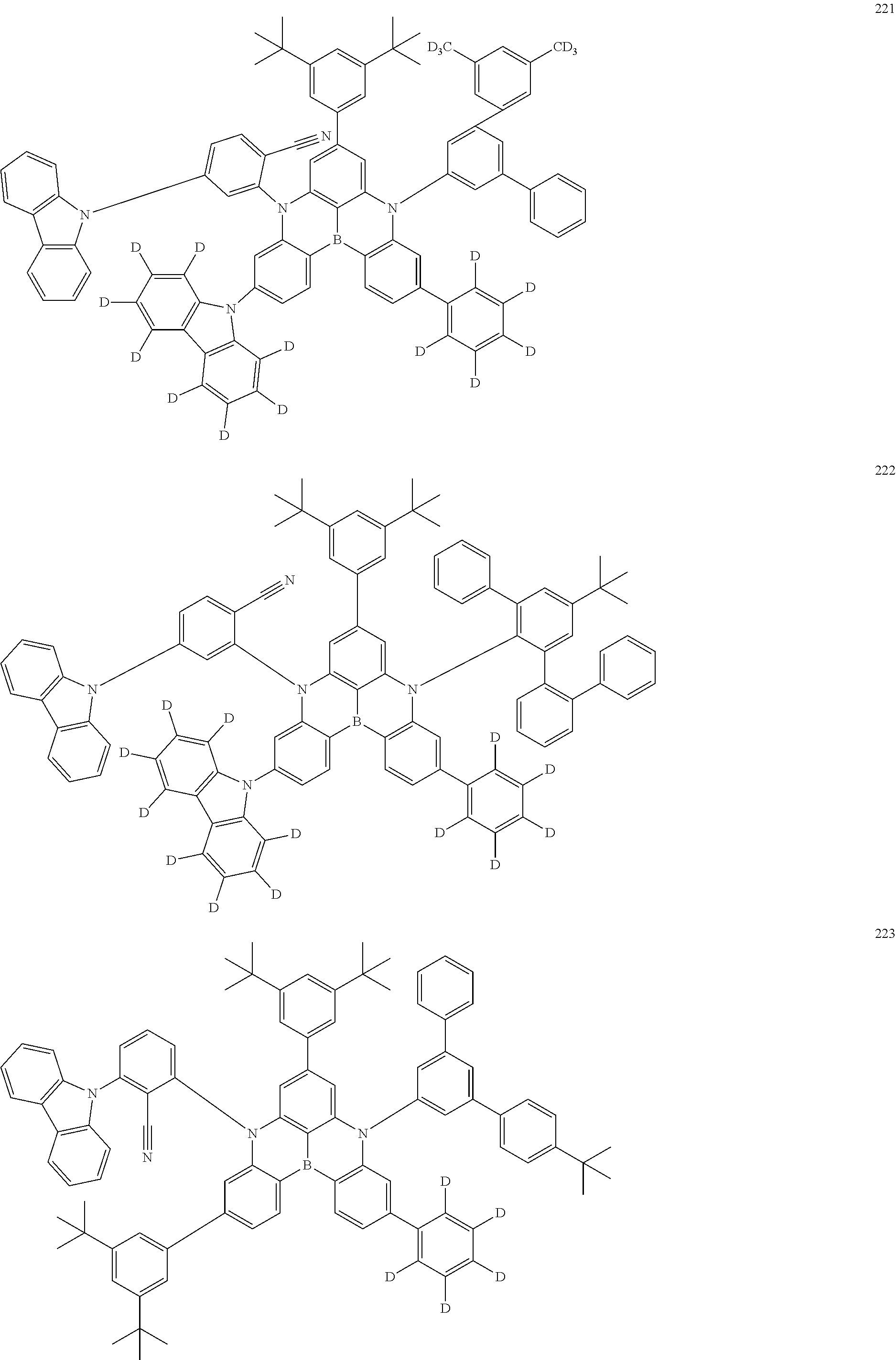

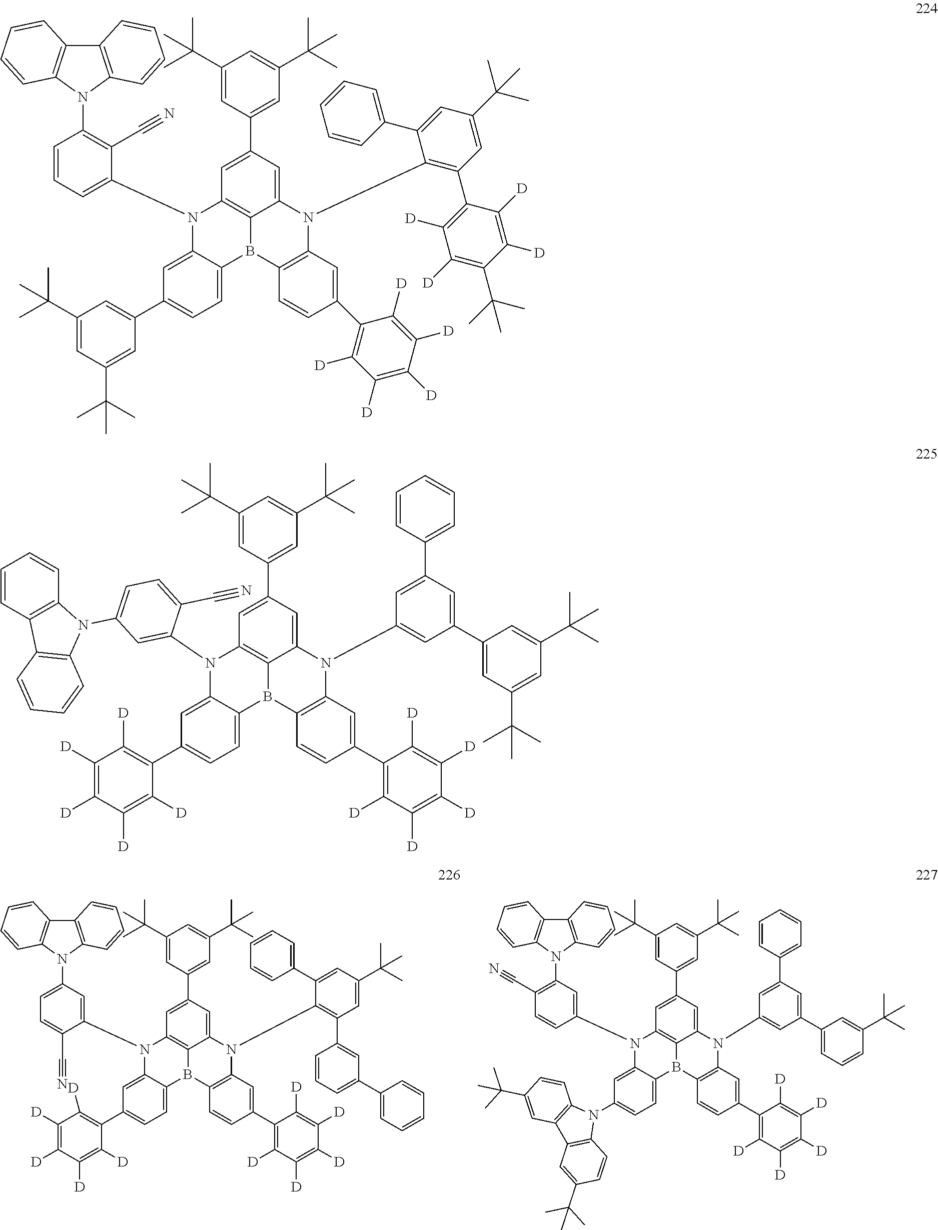

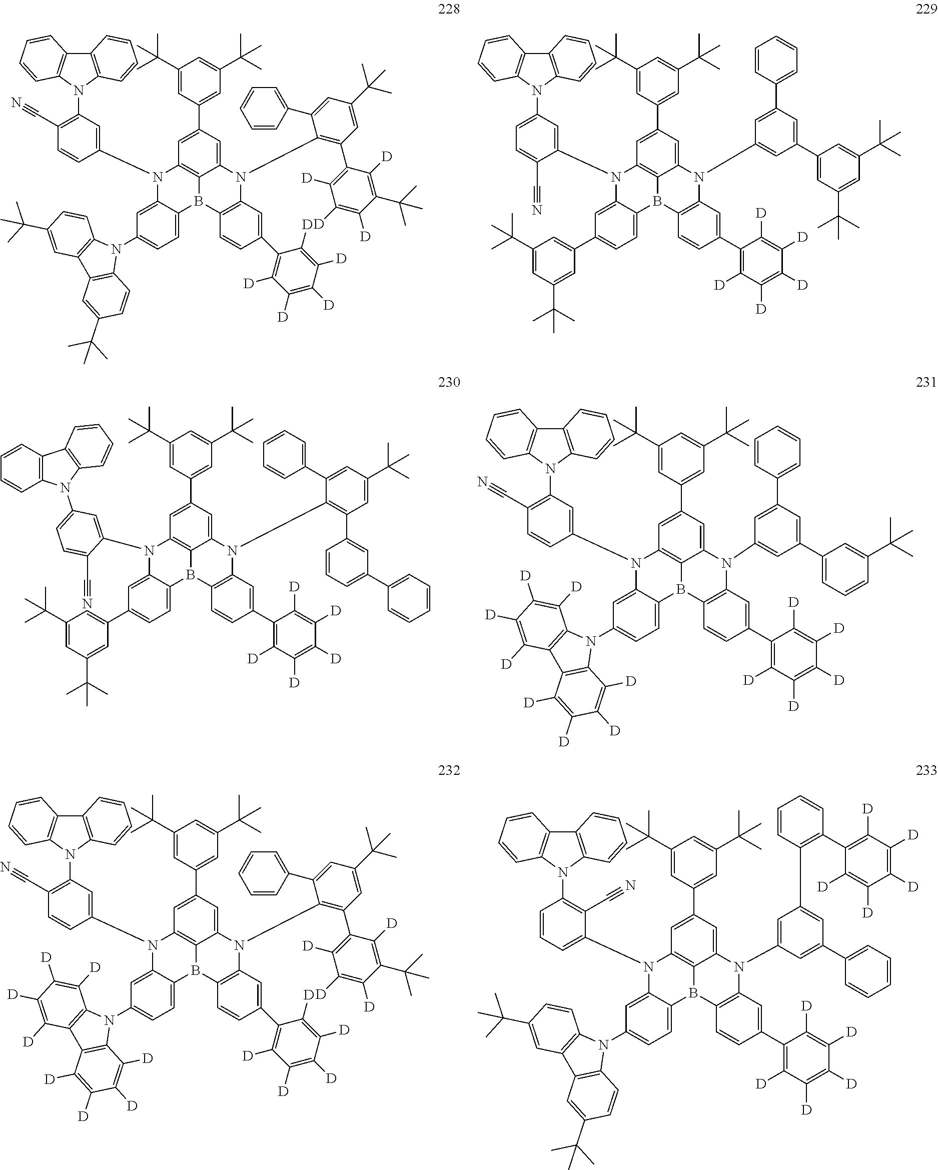

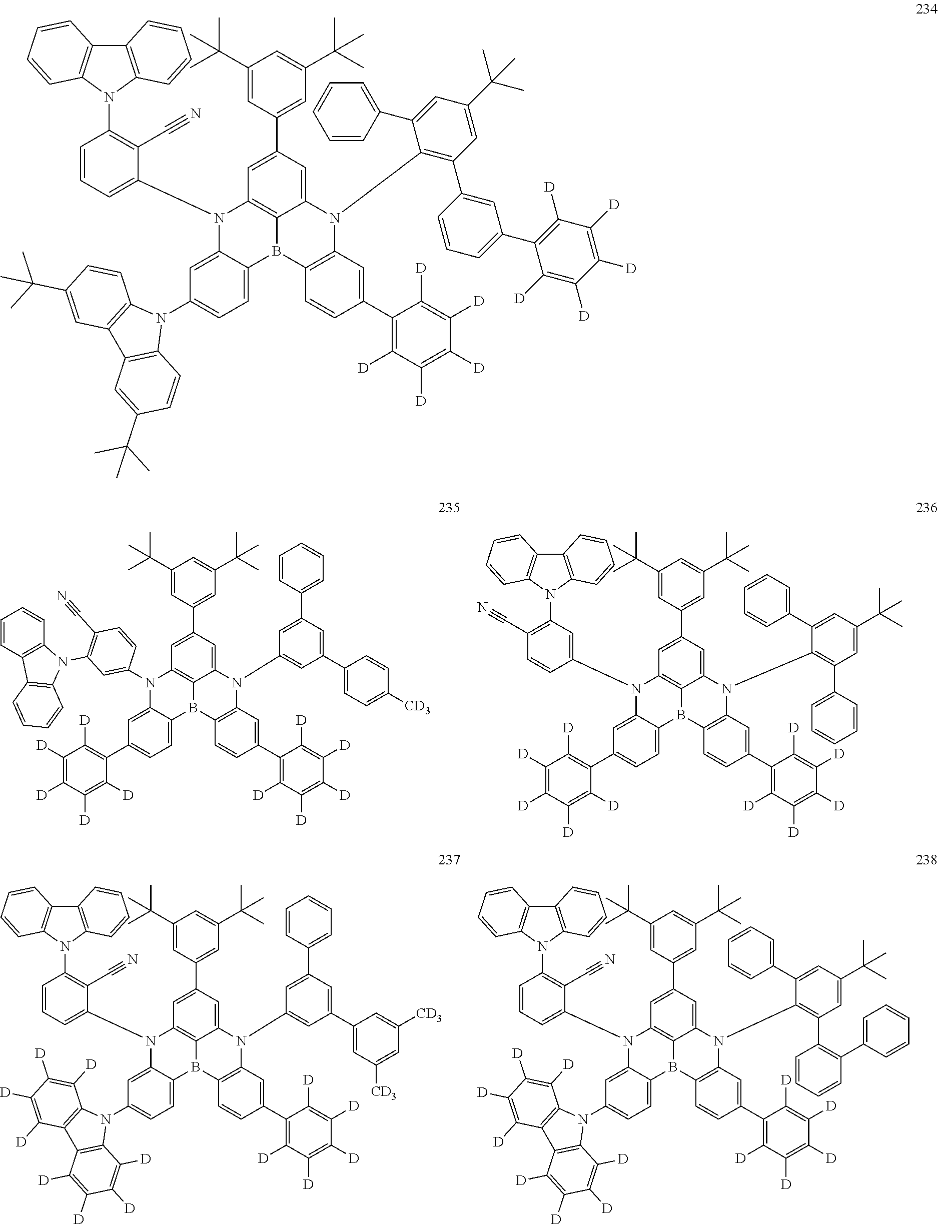

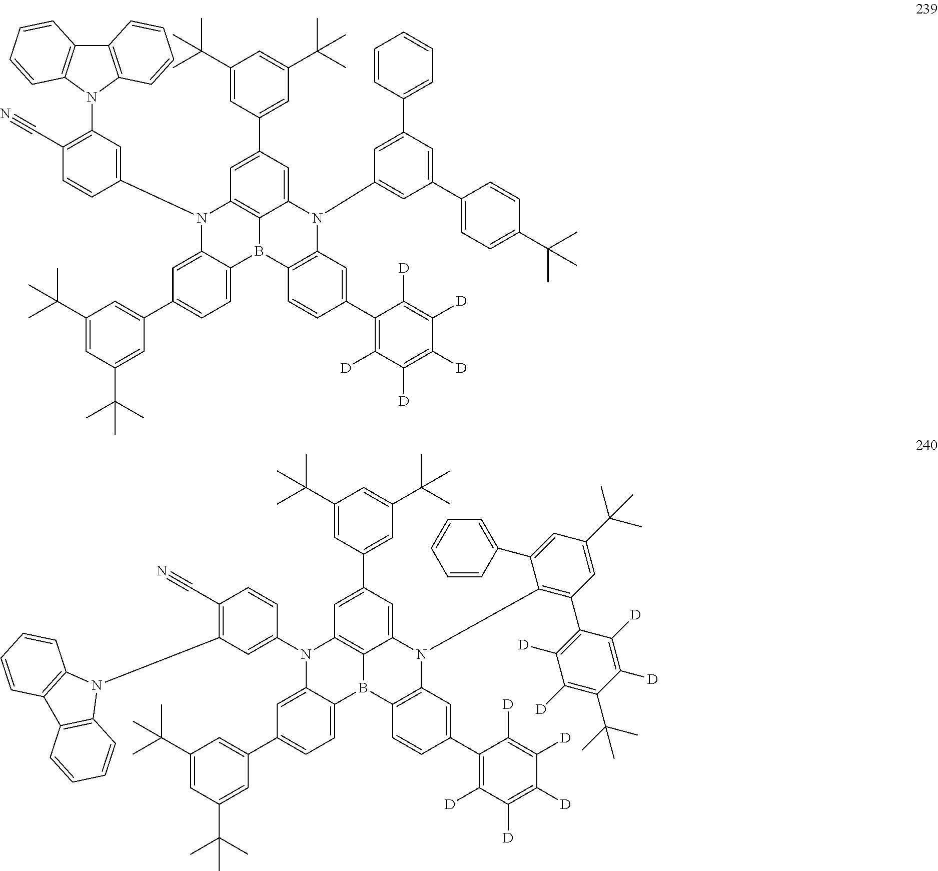 [SMILES: [2H]c1c([2H])c([2H])c(-c2ccc3c(c2)N(c2cc(-c4ccccc4)cc(-c4ccc(C(C)(C)C)cc4)c2)c2cc(-c4cc(C(C)(C)C)cc(C(C)(C)C)c4)cc4c2B3c2ccc(-c3cc(C(C)(C)C)cc(C(C)(C)C)c3)cc2N4c2ccc(C#N)c(-n3c4ccccc4c4ccccc43)c2)c([2H])c1[2H] ; [2H]c1c([2H])c([2H])c(-c2ccc3c(c2)N(c2c(-c4ccccc4)cc(C(C)(C)C)cc2-c2c([2H])c([2H])c(C(C)(C)C)c([2H])c2[2H])c2cc(-c4cc(C(C)(C)C)cc(C(C)(C)C)c4)cc4c2B3c2ccc(-c3cc(C(C)(C)C)cc(C(C)(C)C)c3)cc2N4c2ccc(C#N)c(-n3c4ccccc4c4ccccc43)c2)c([2H])c1[2H]]

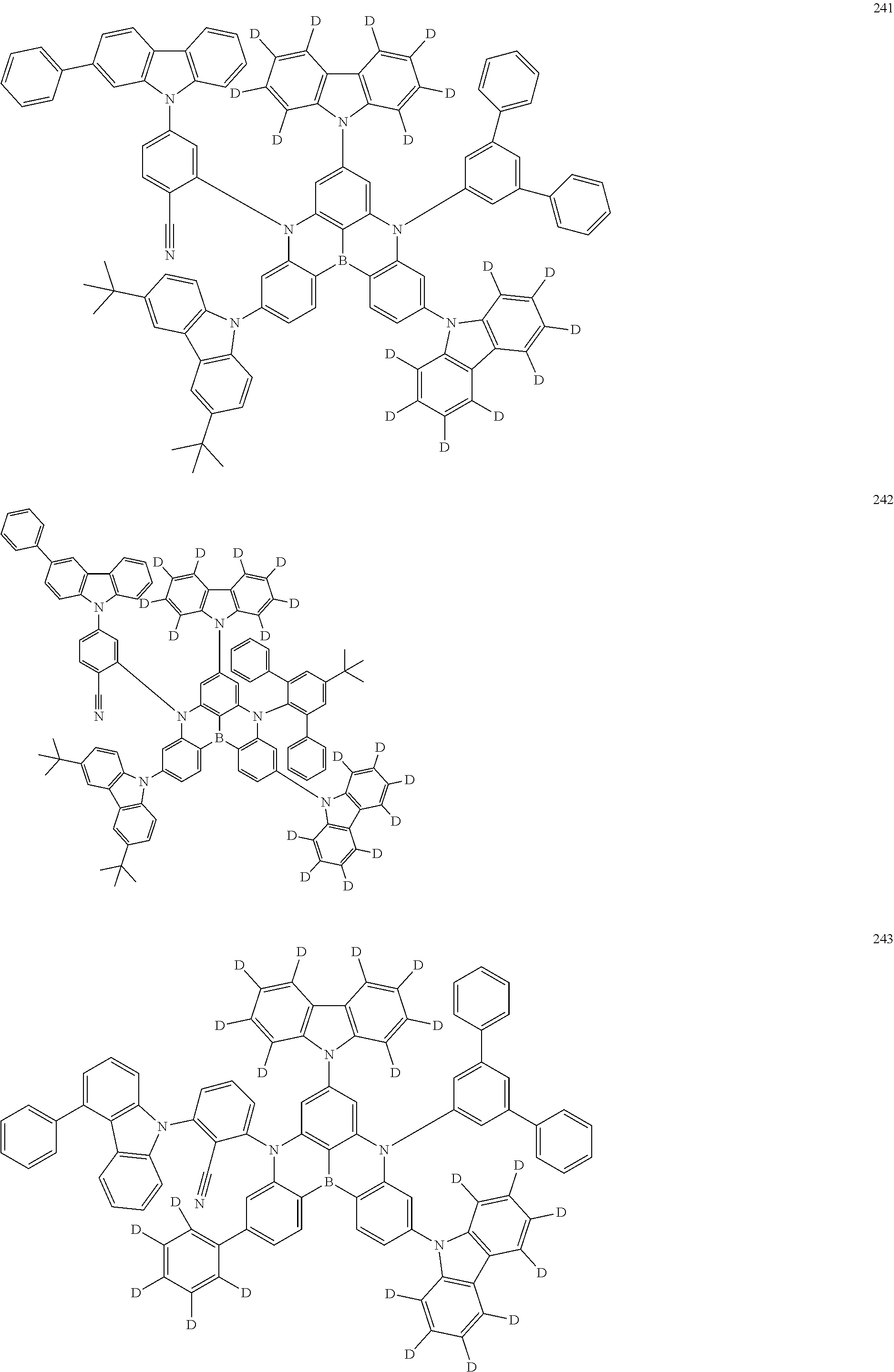

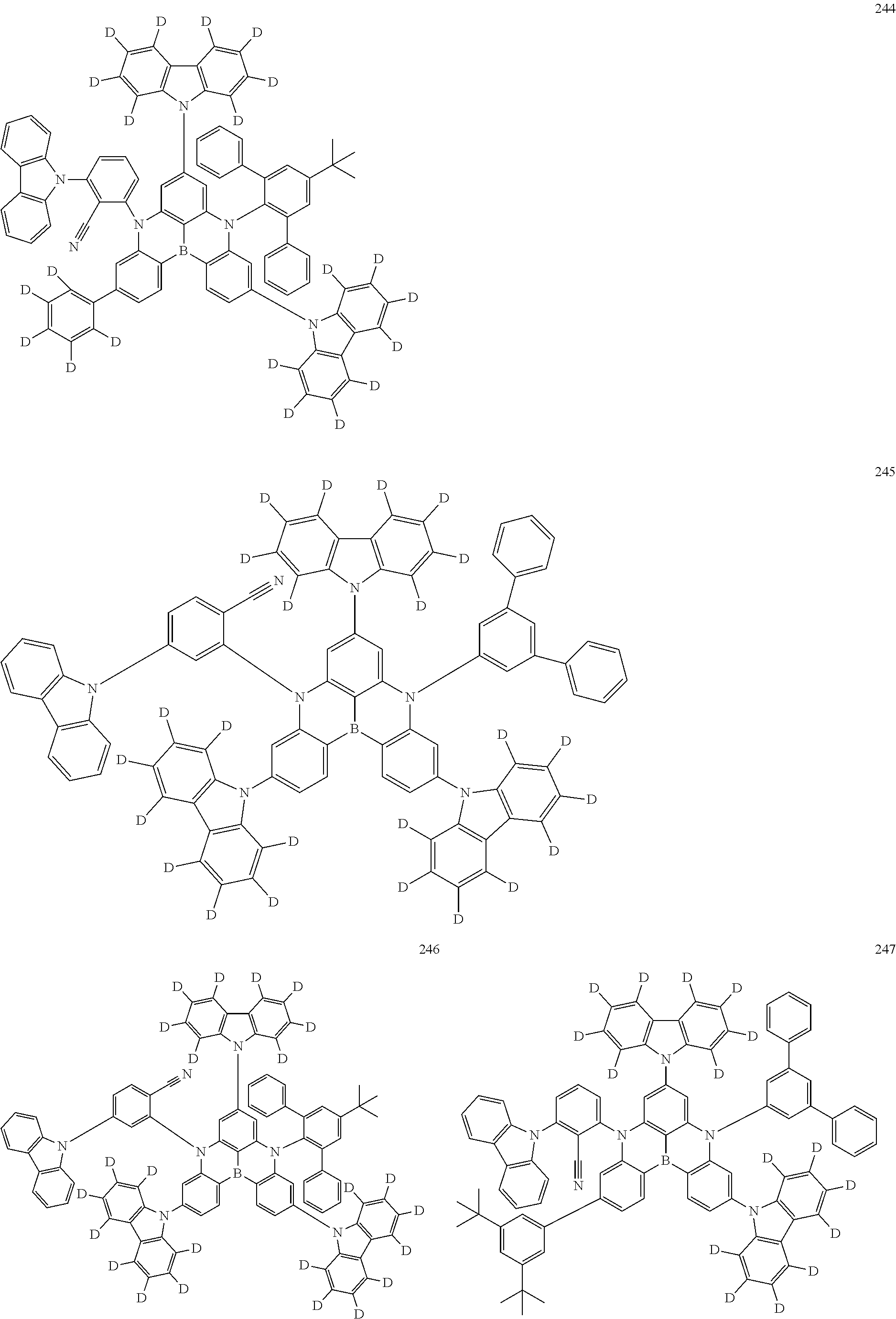

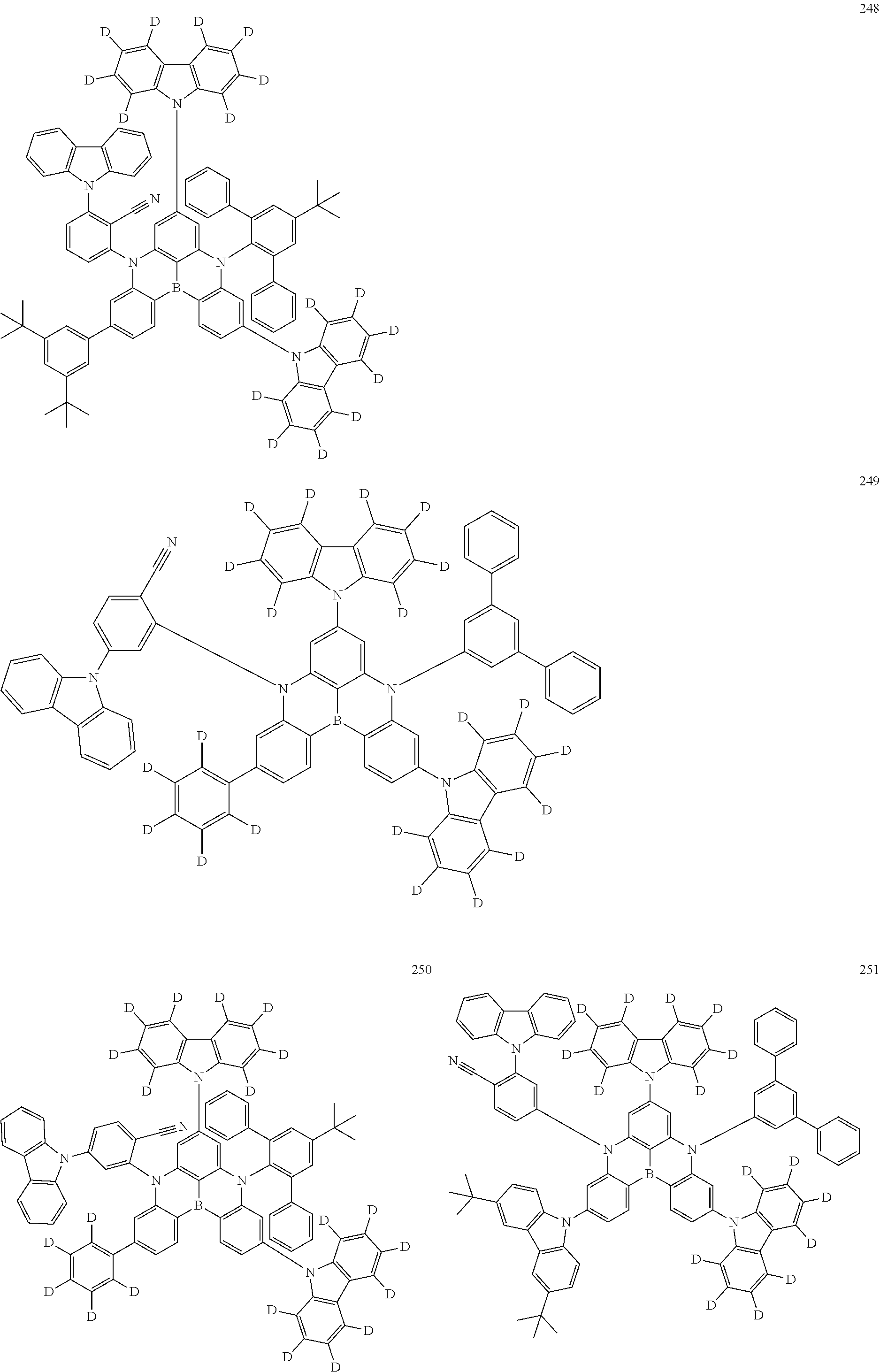

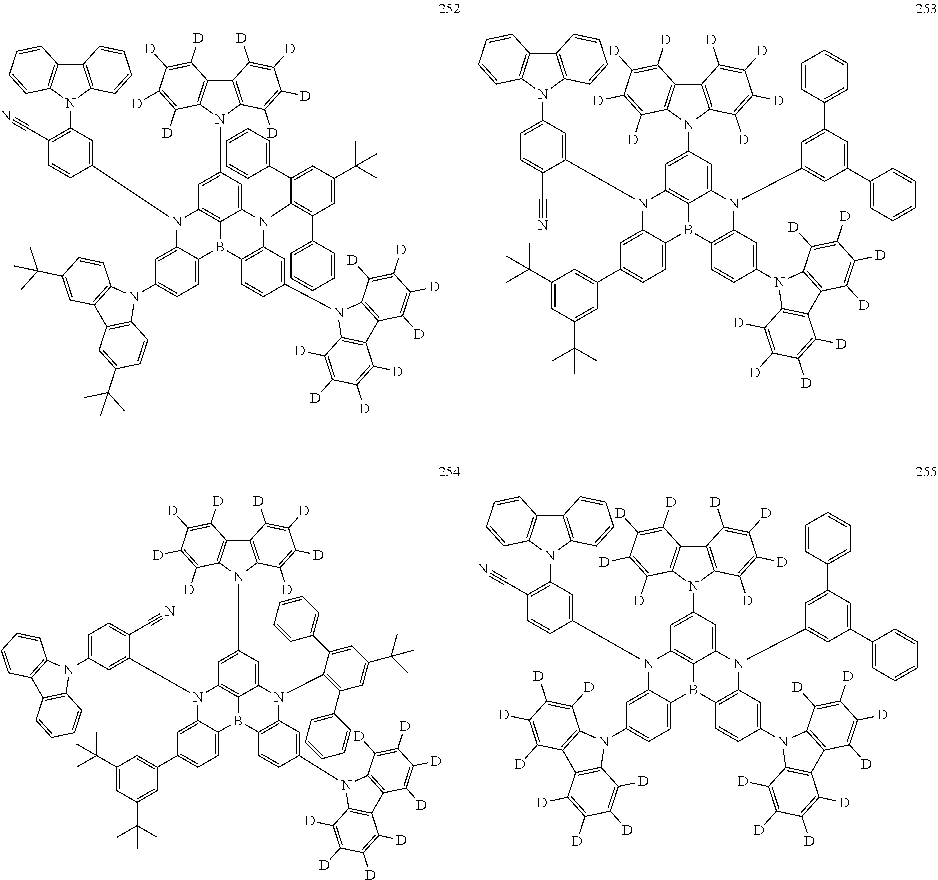

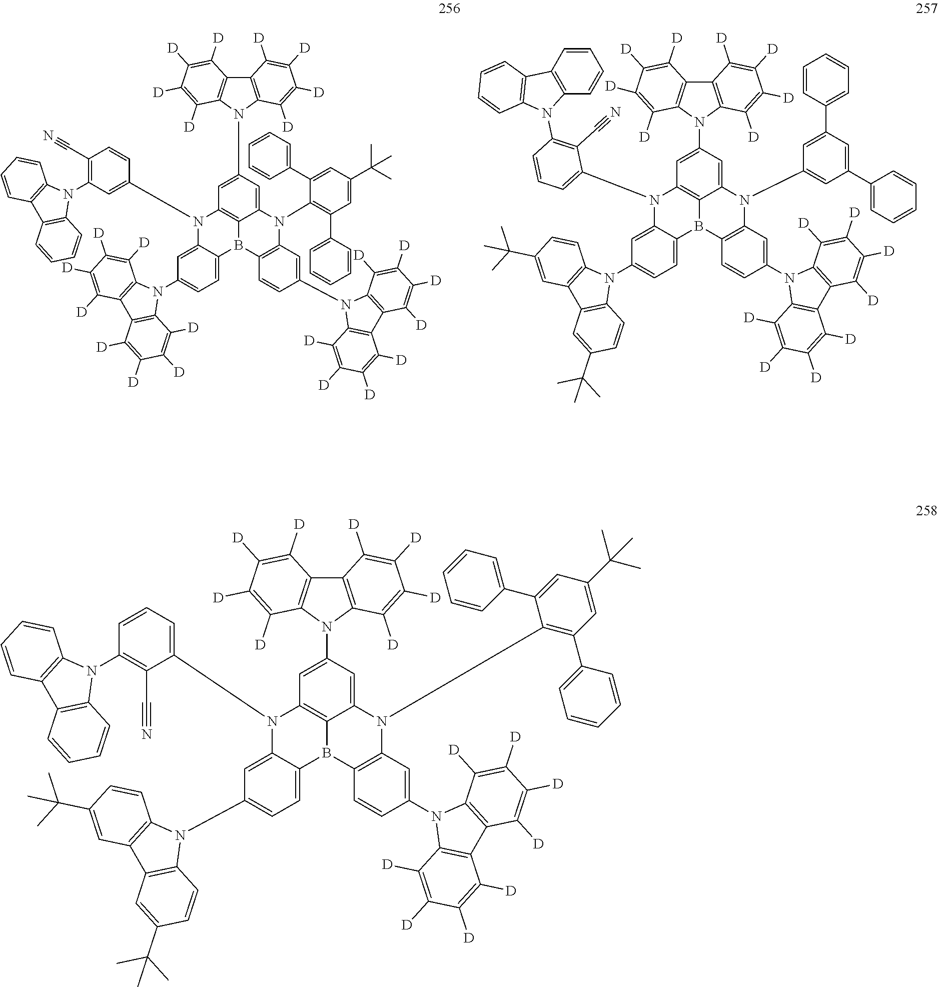

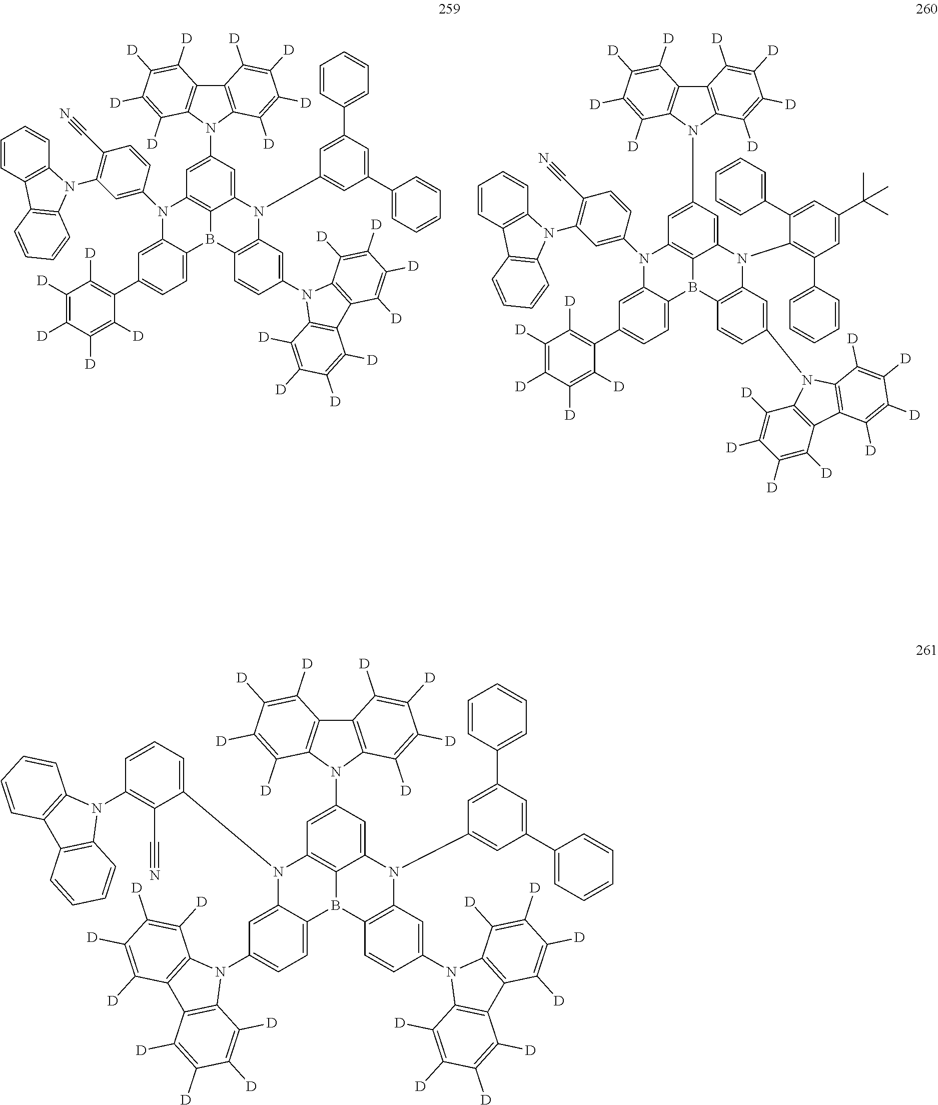

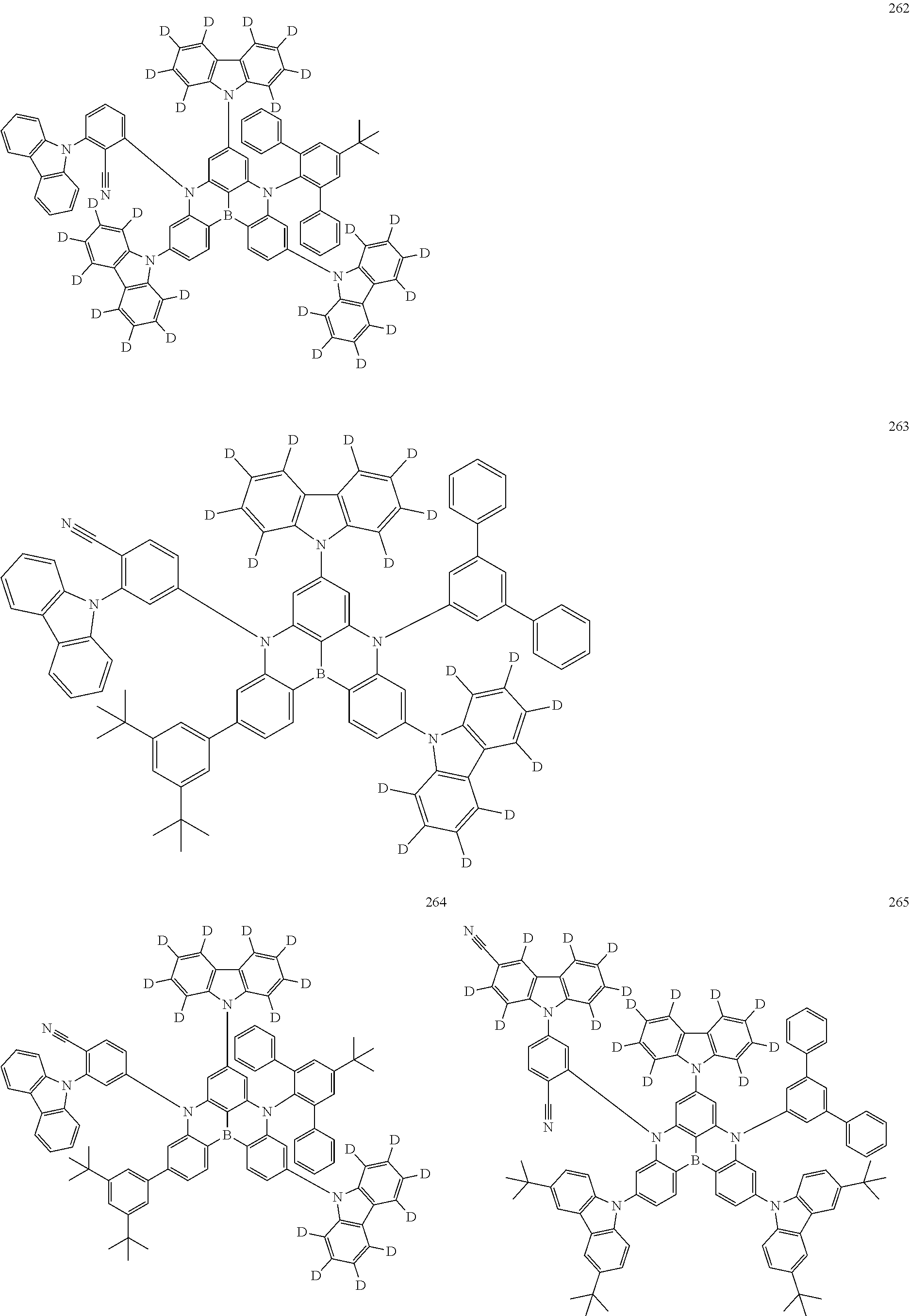

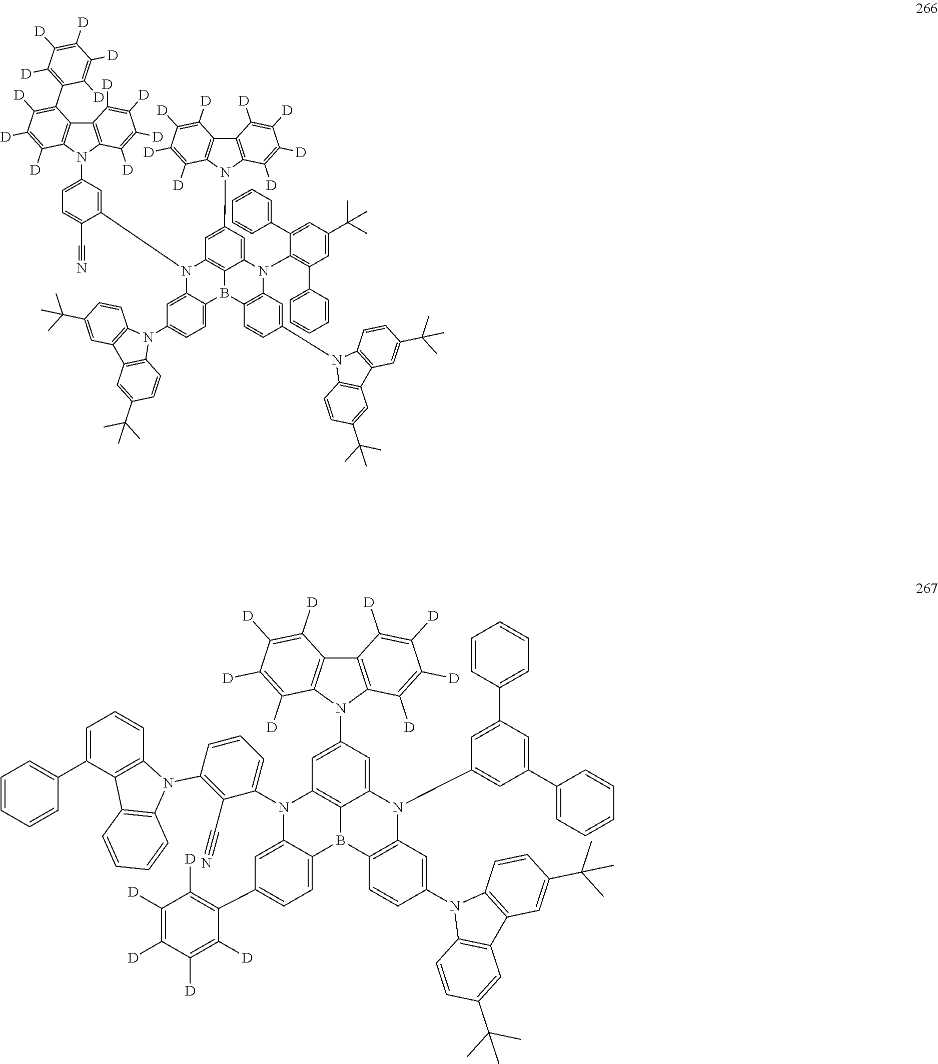

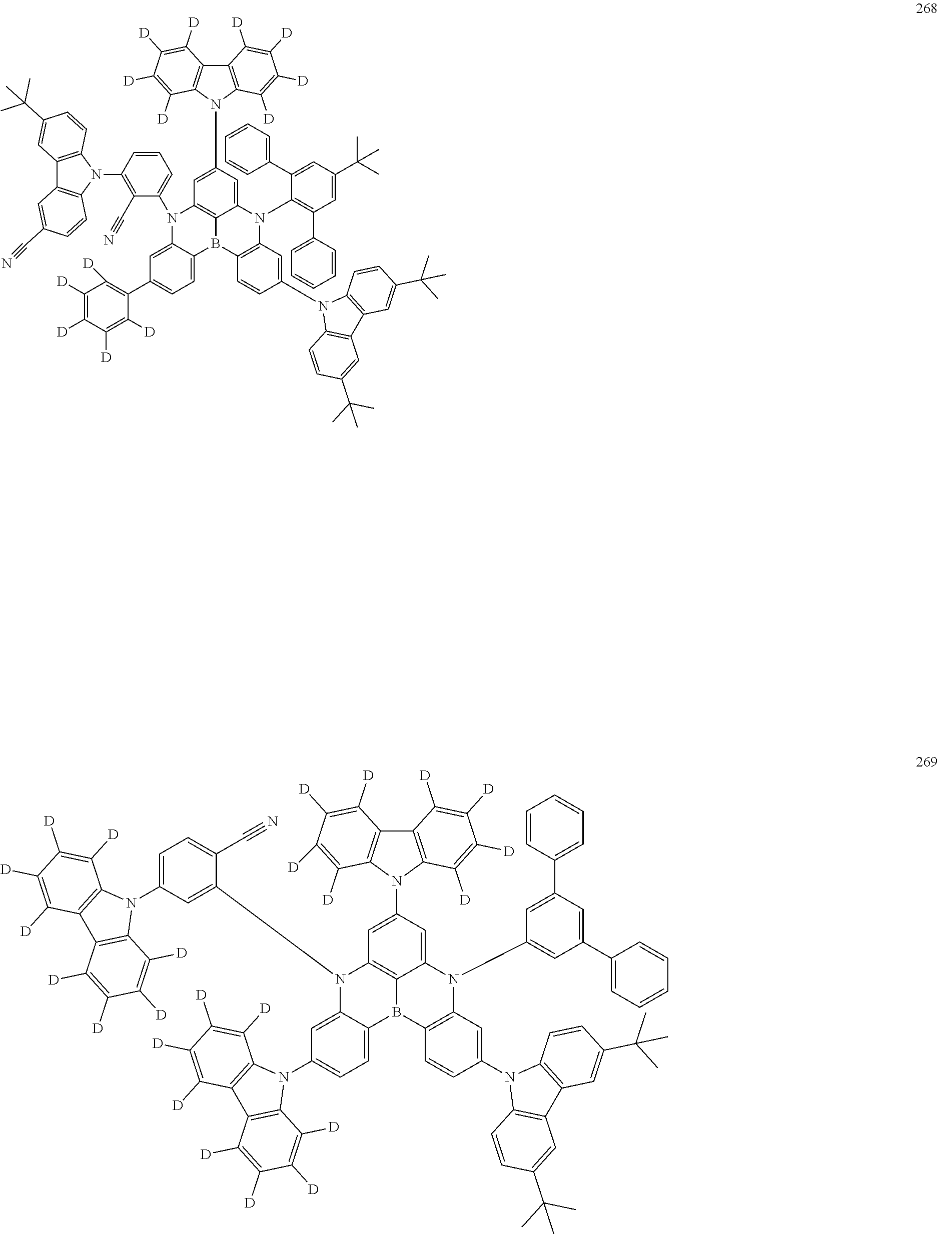

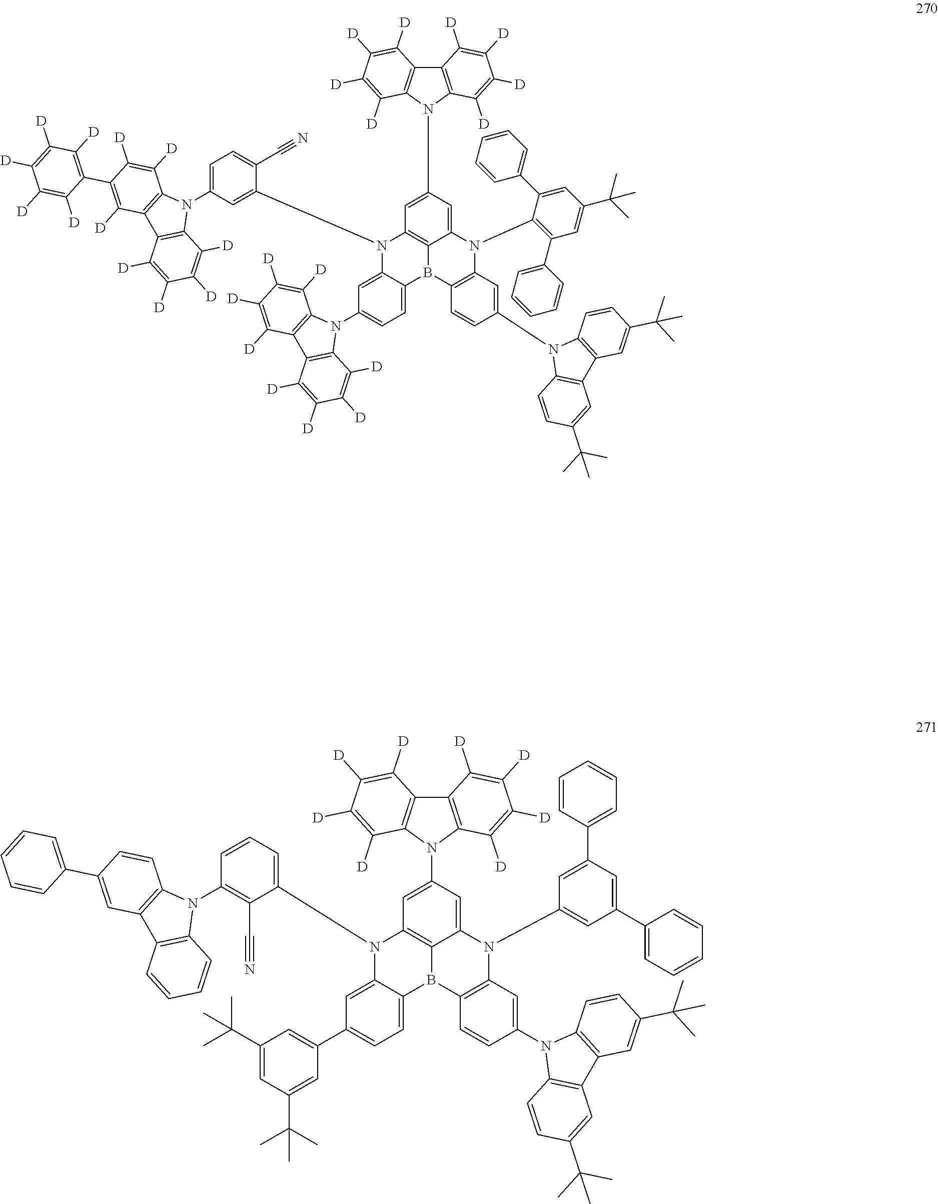

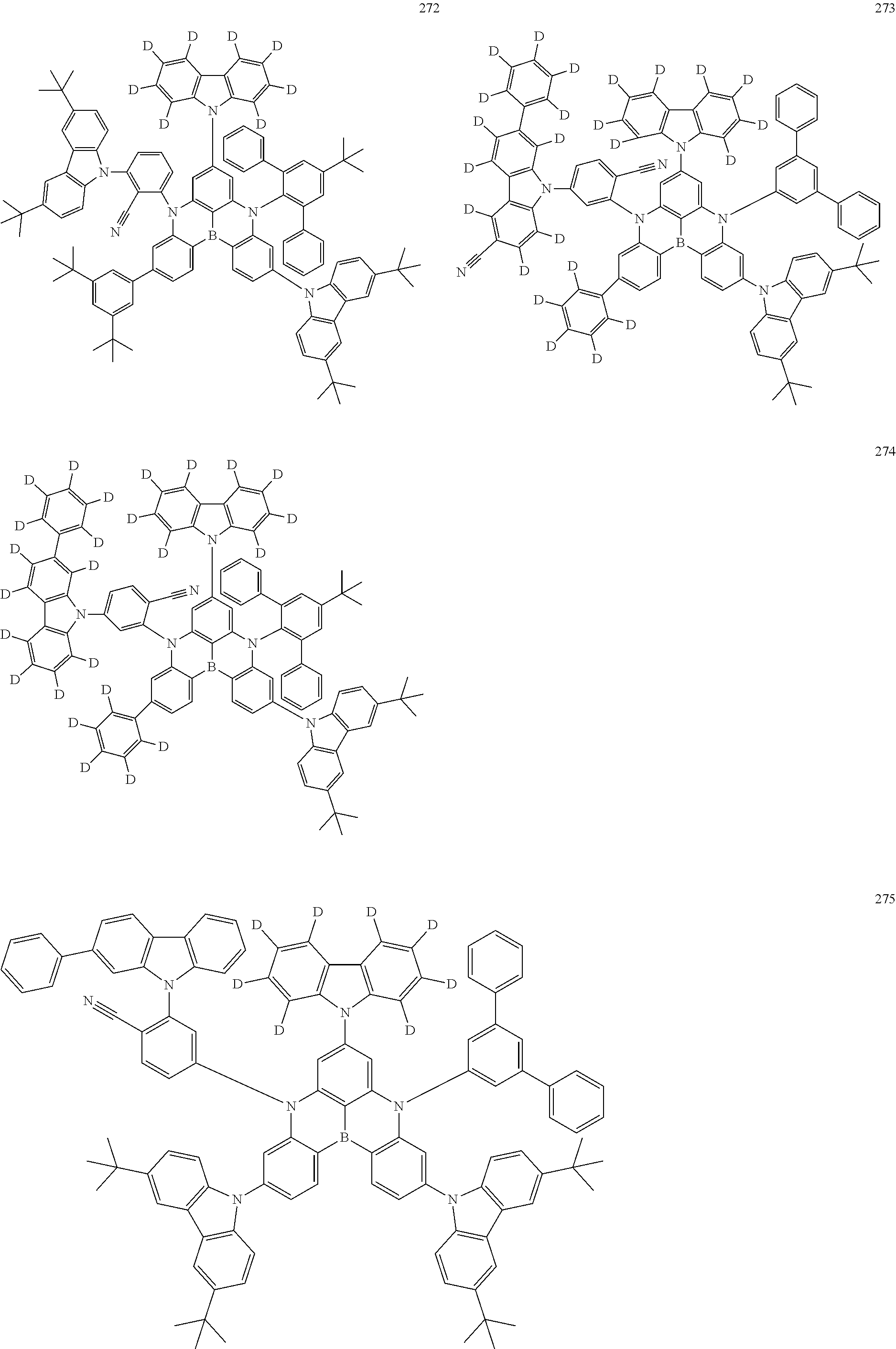

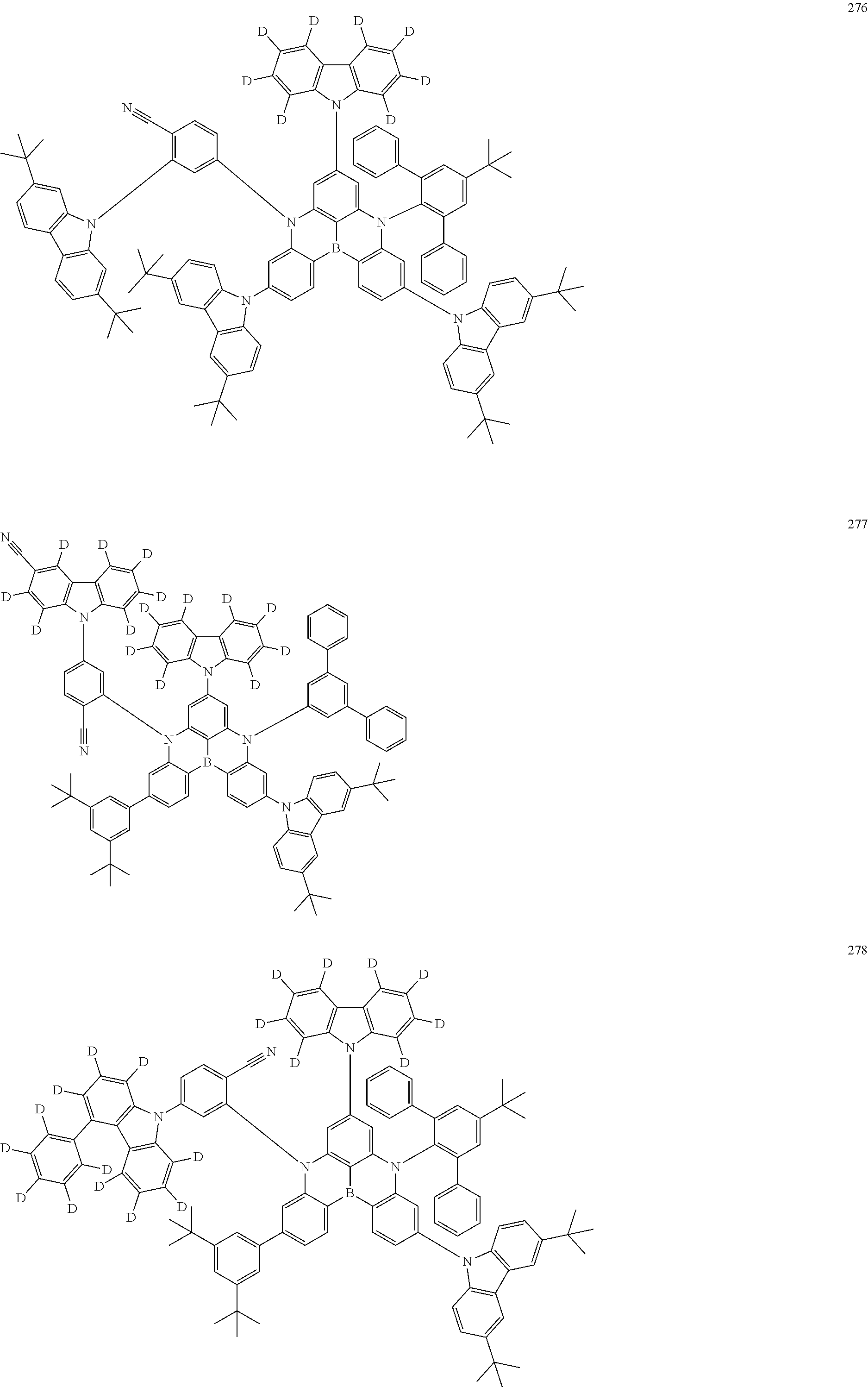

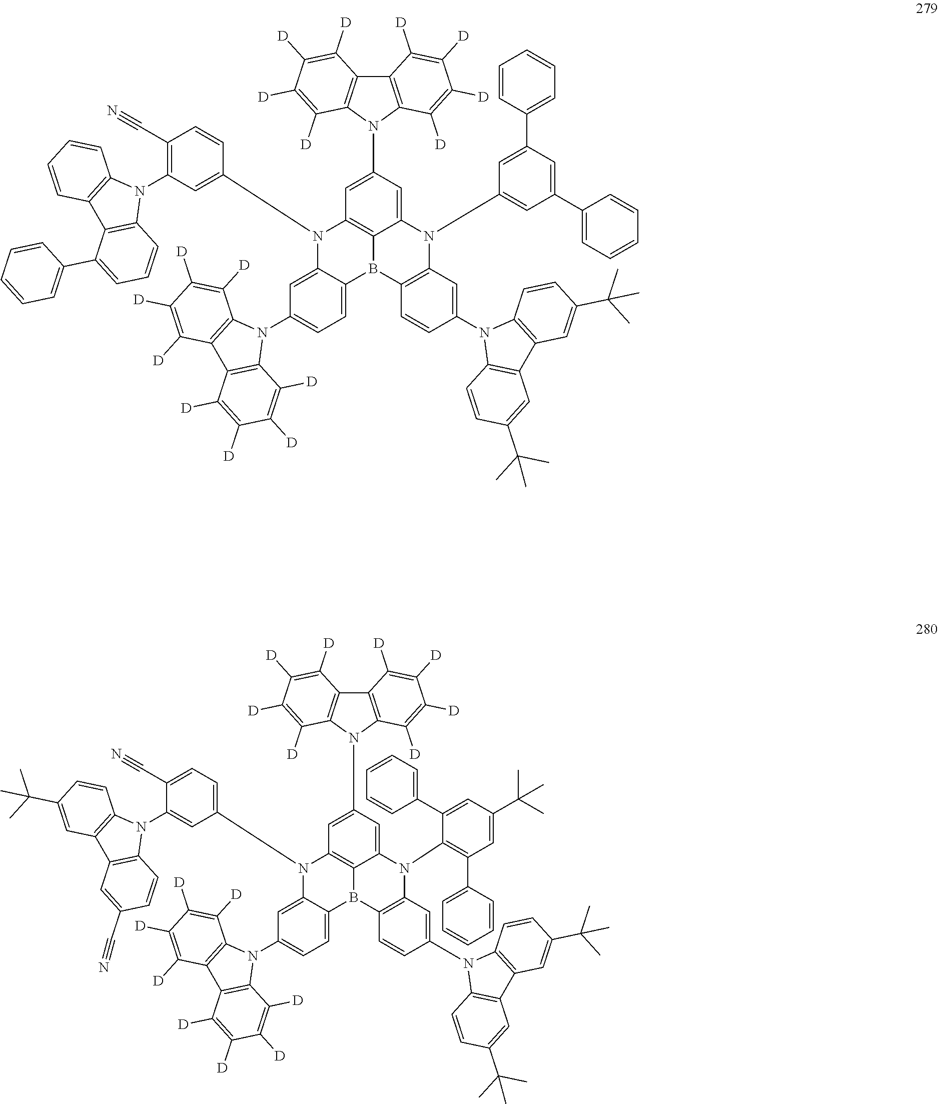

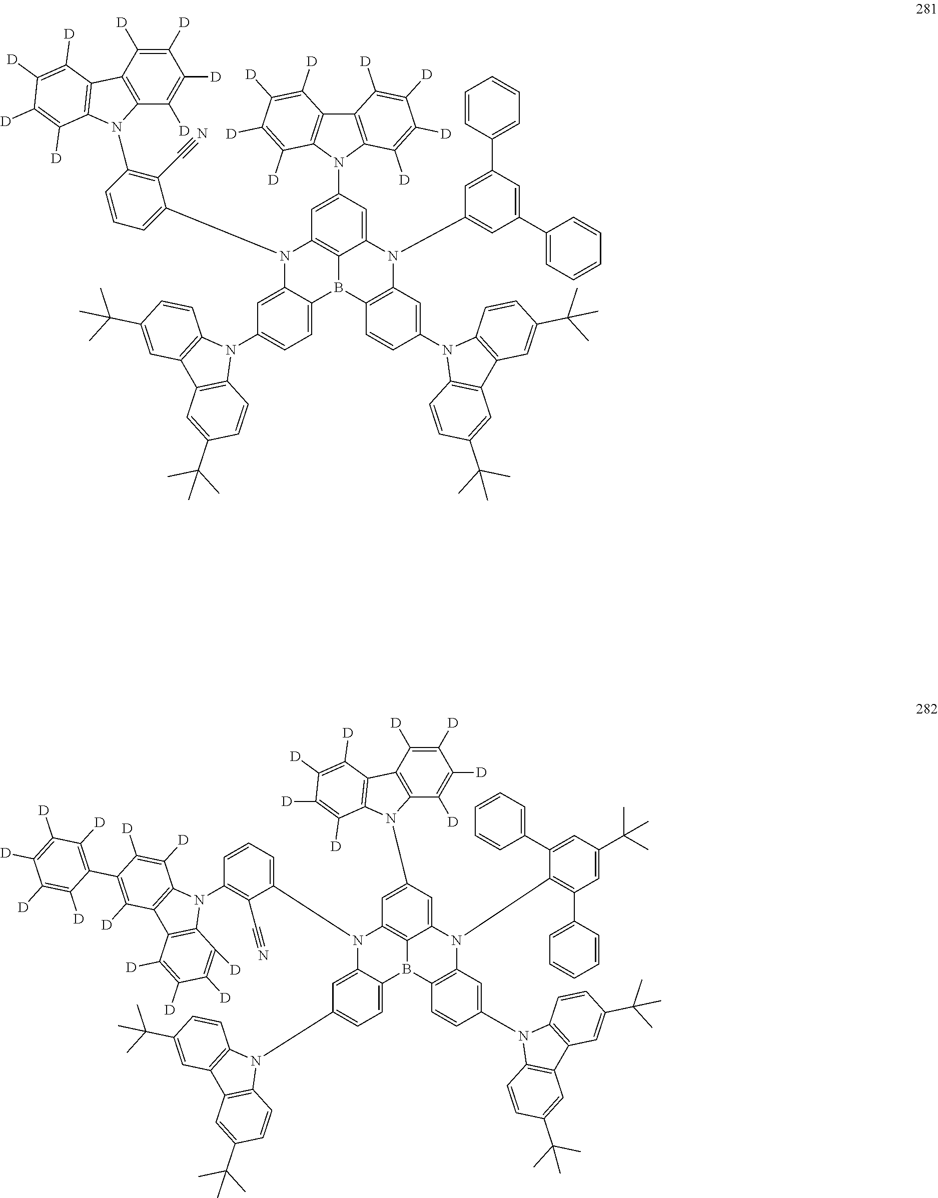

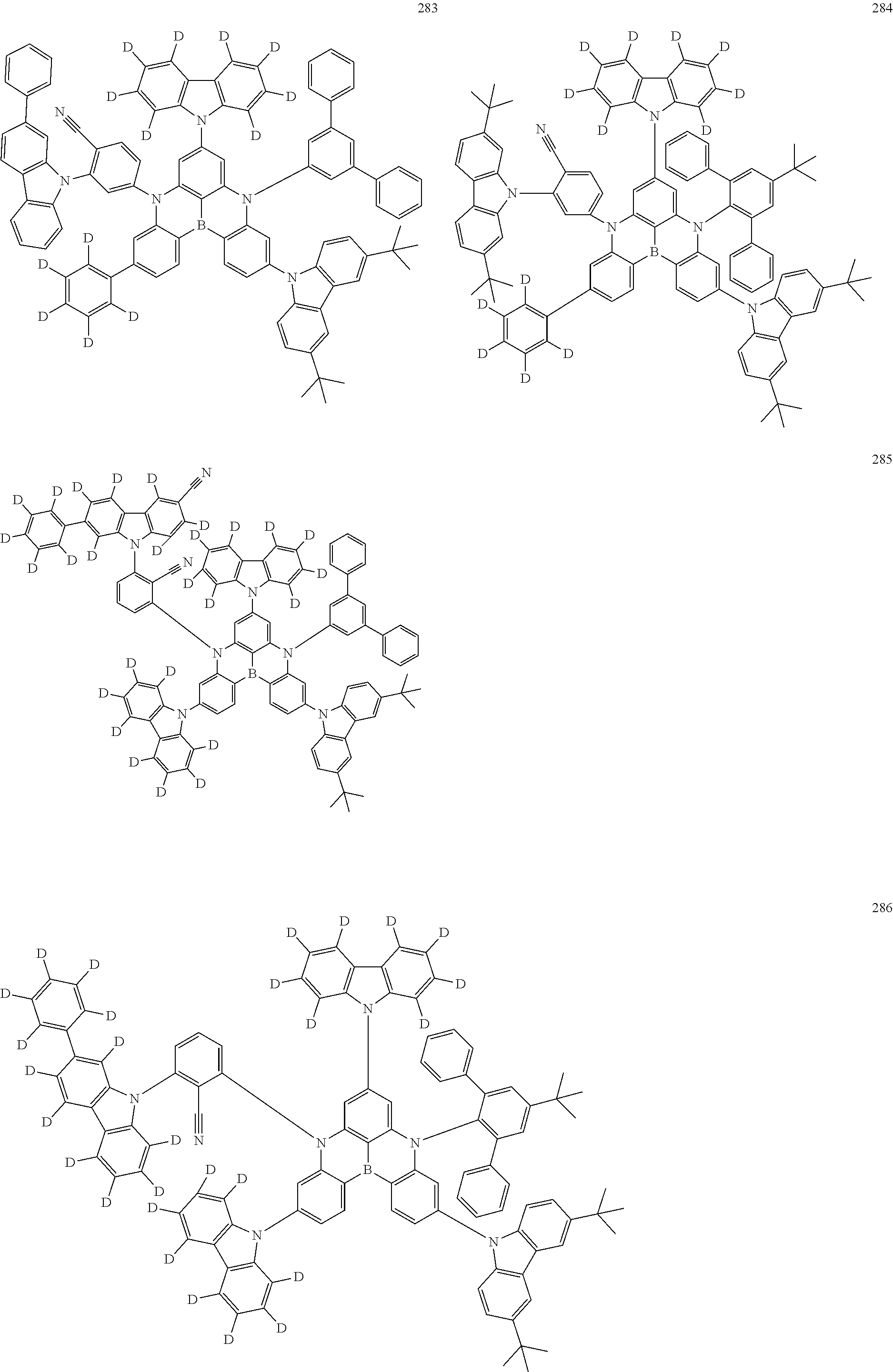

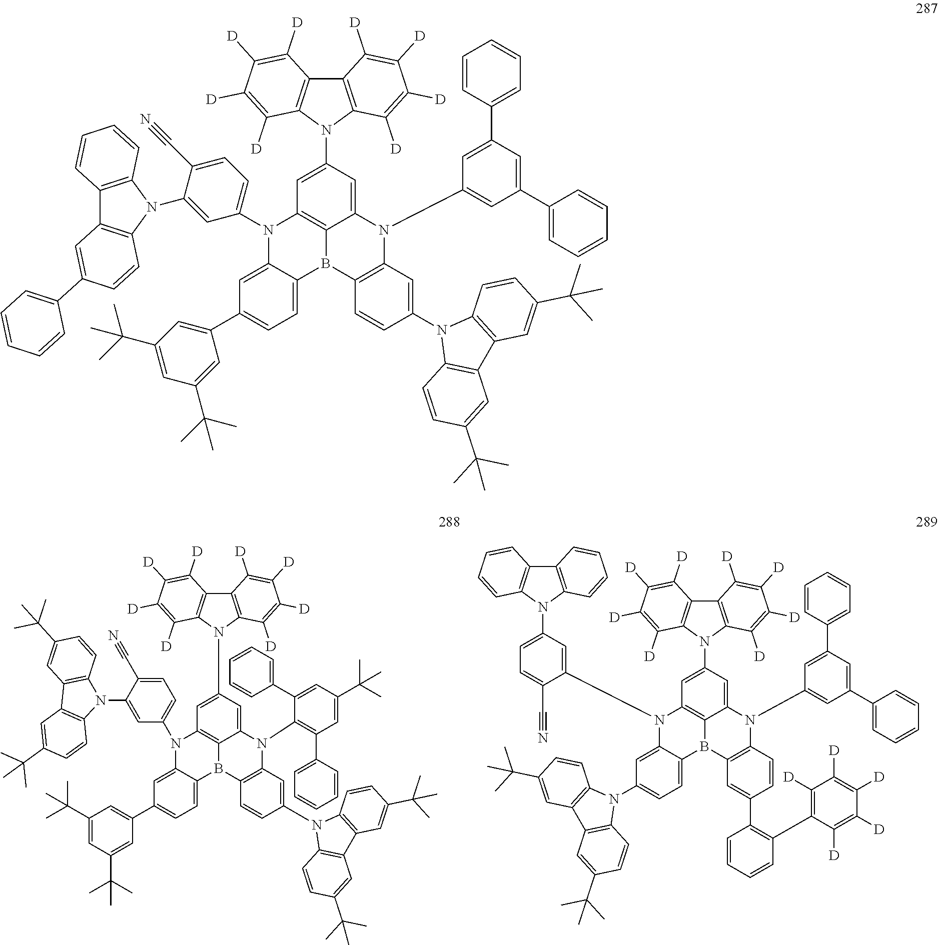

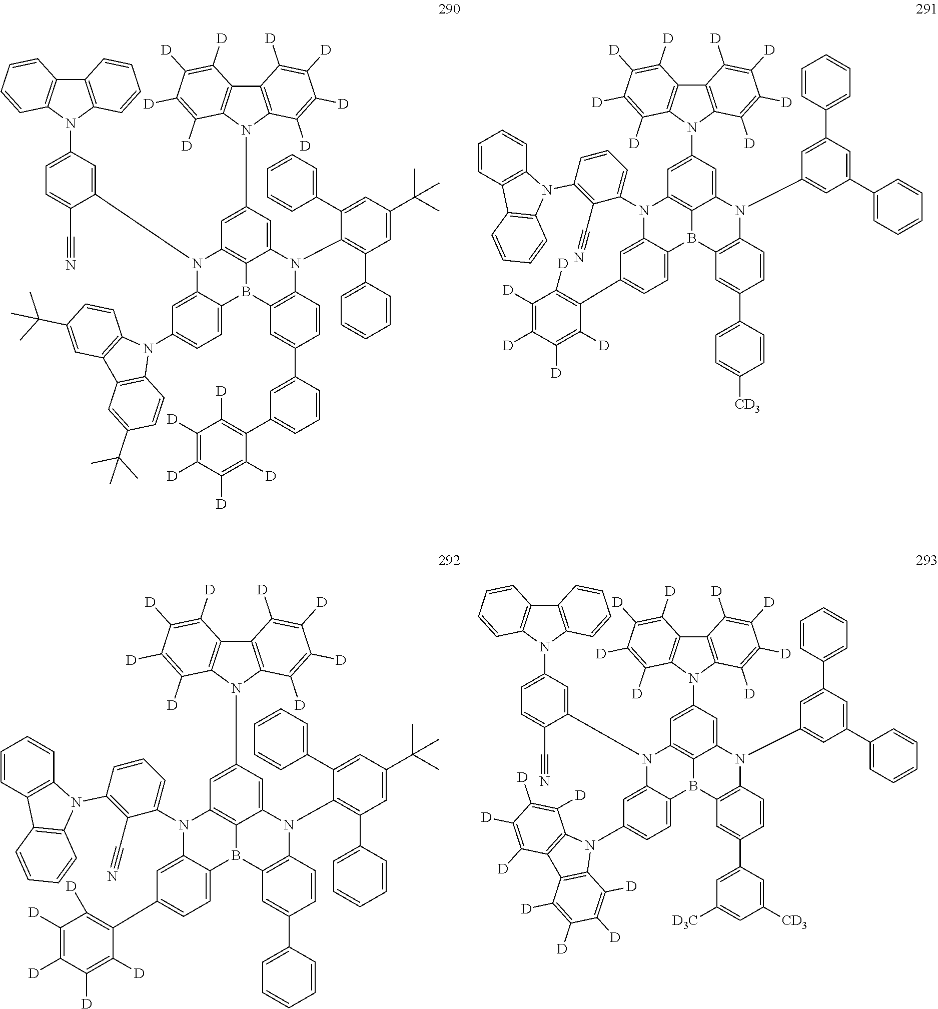

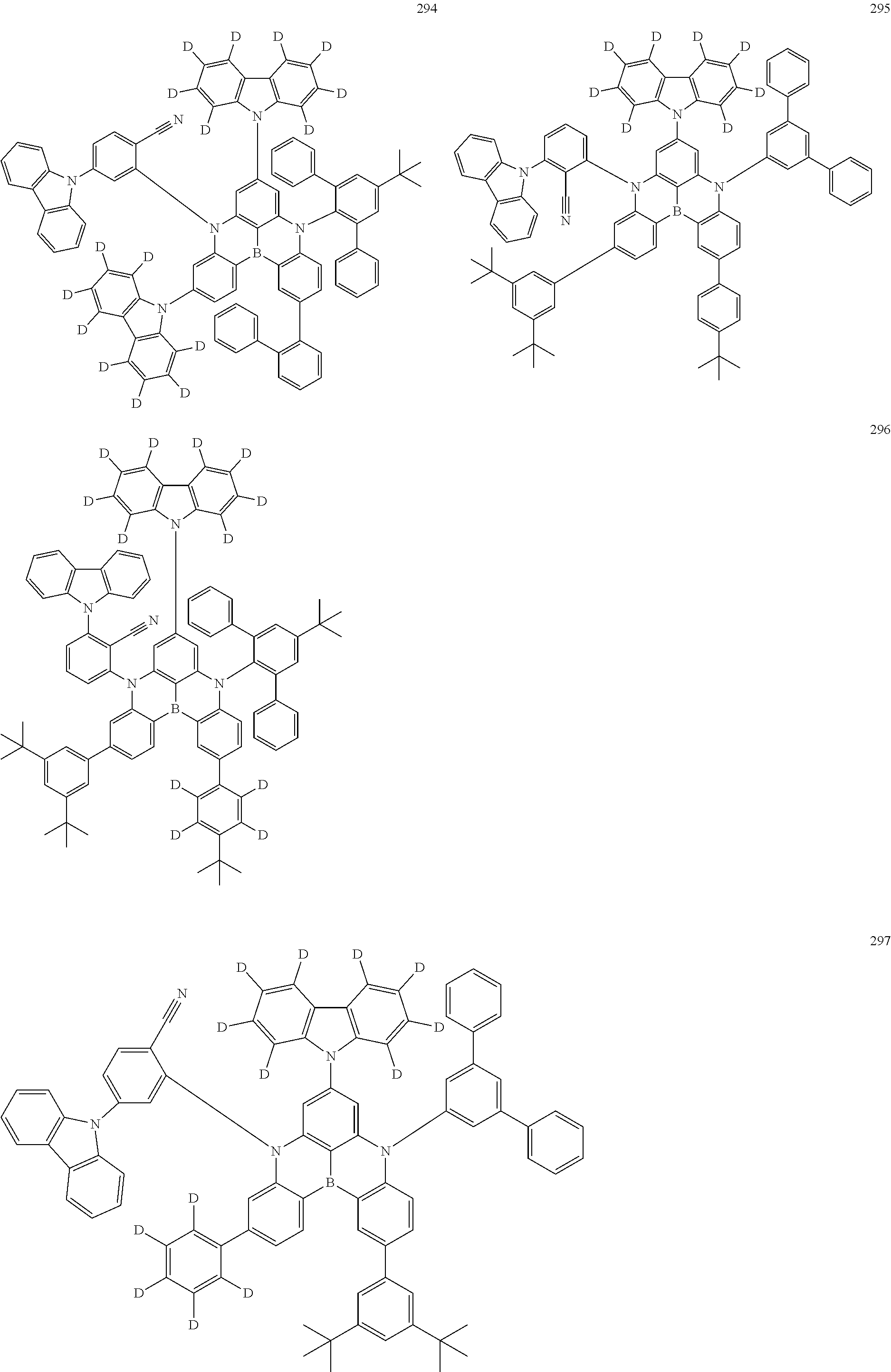

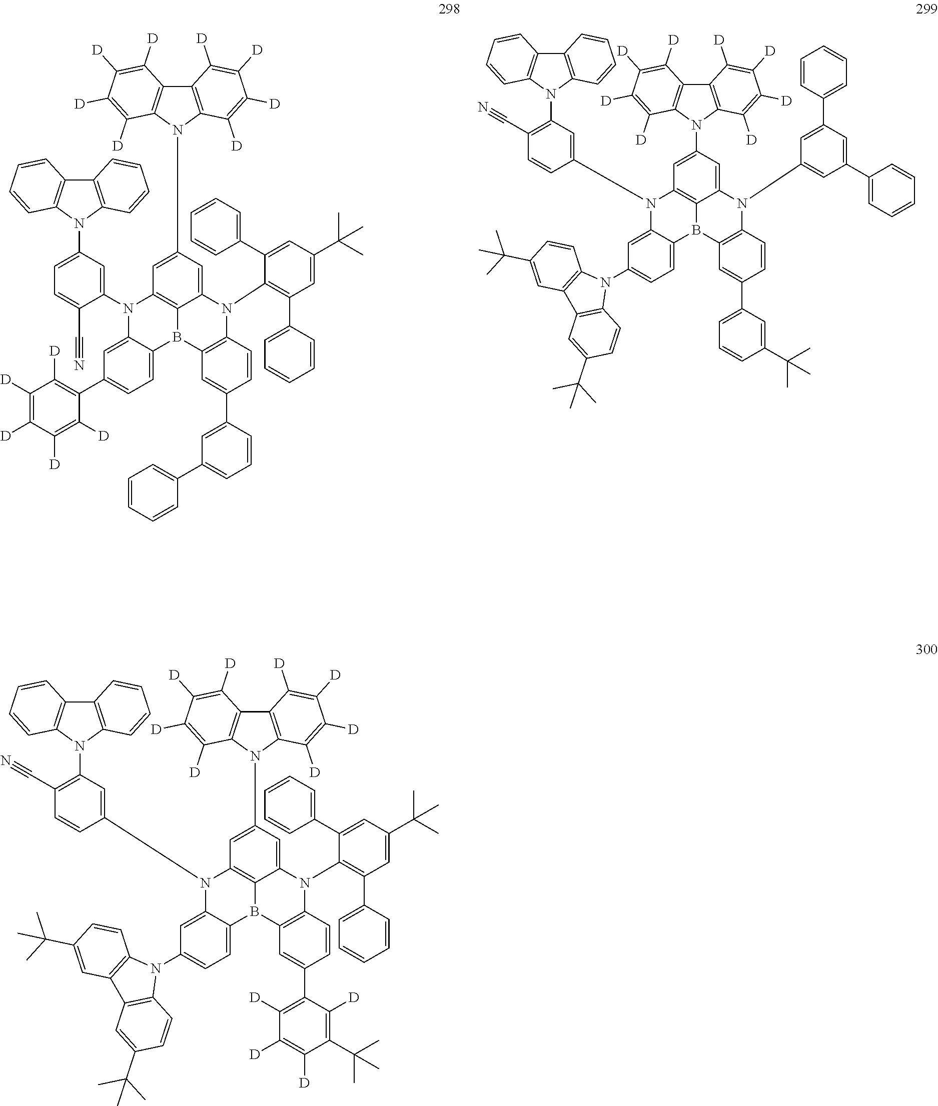

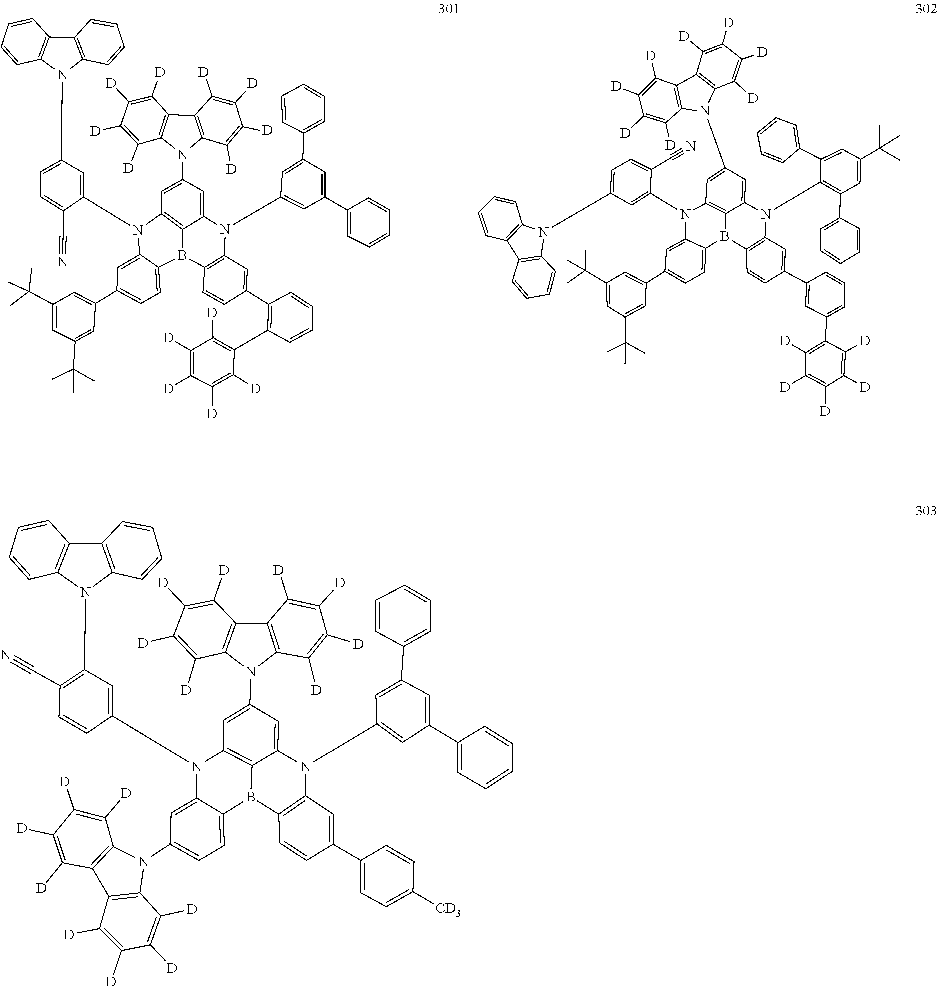

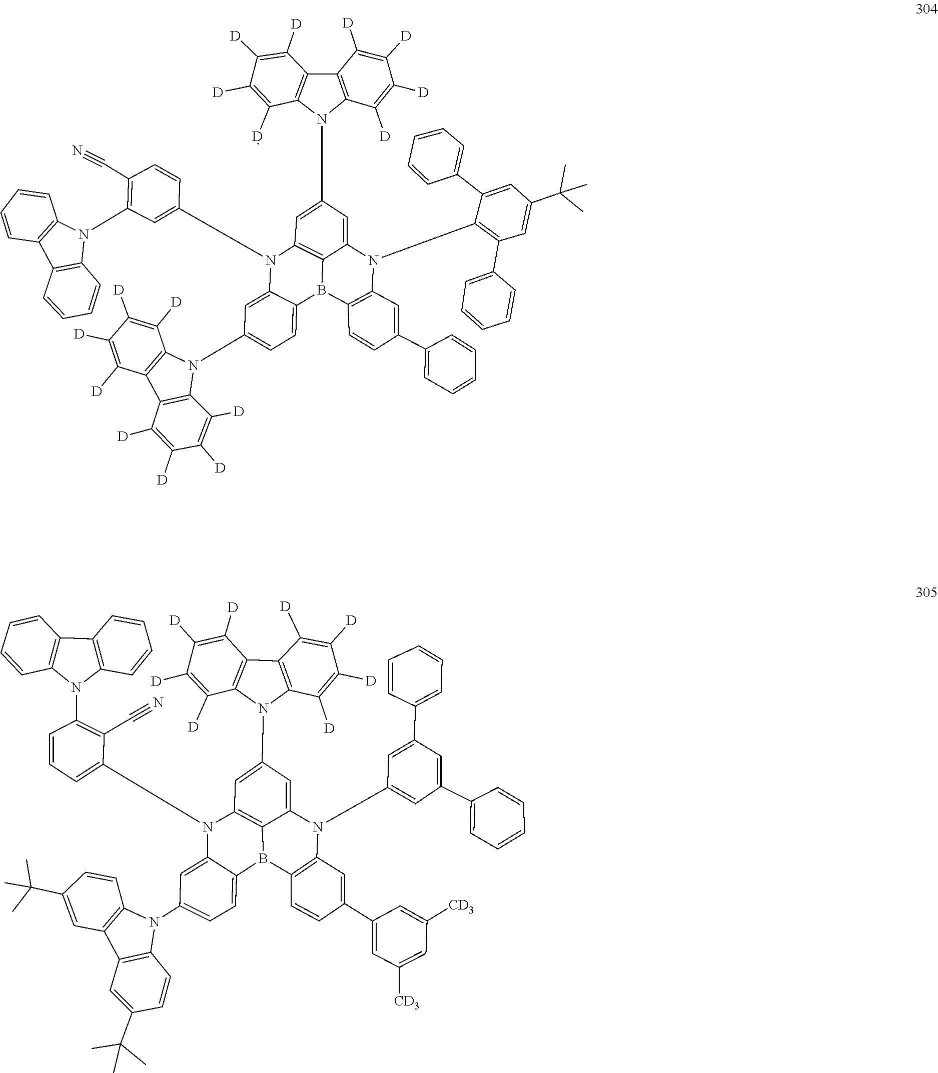

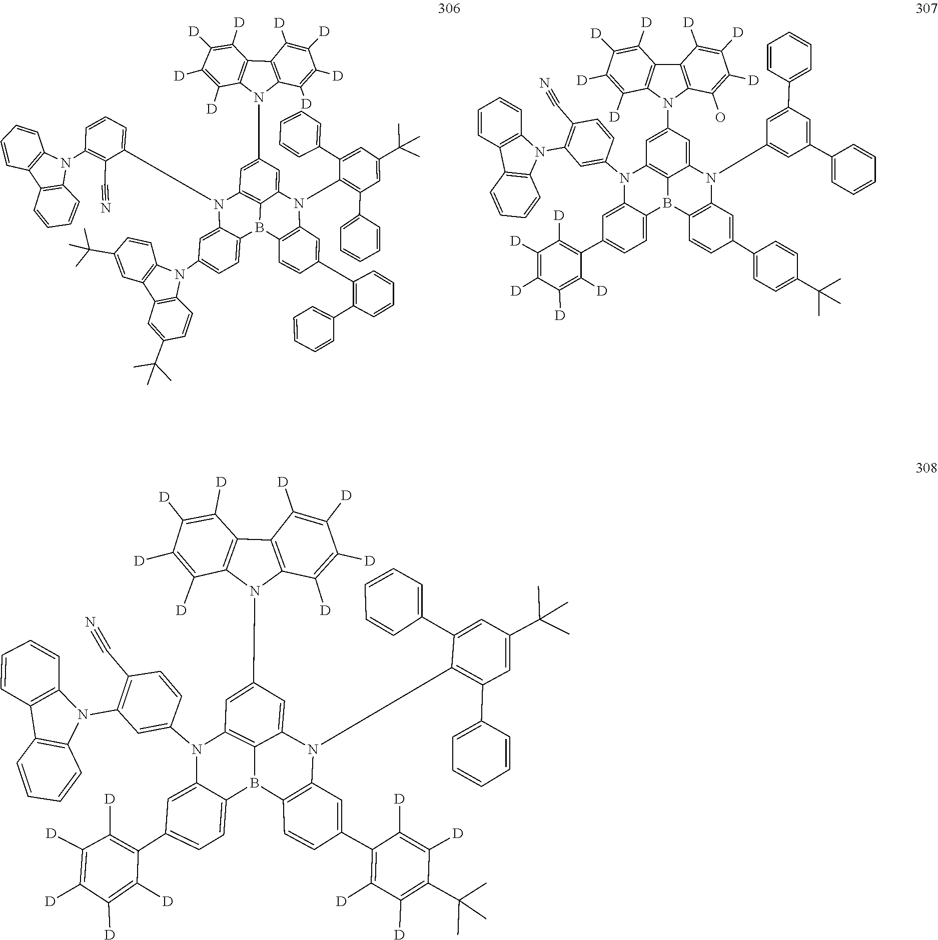

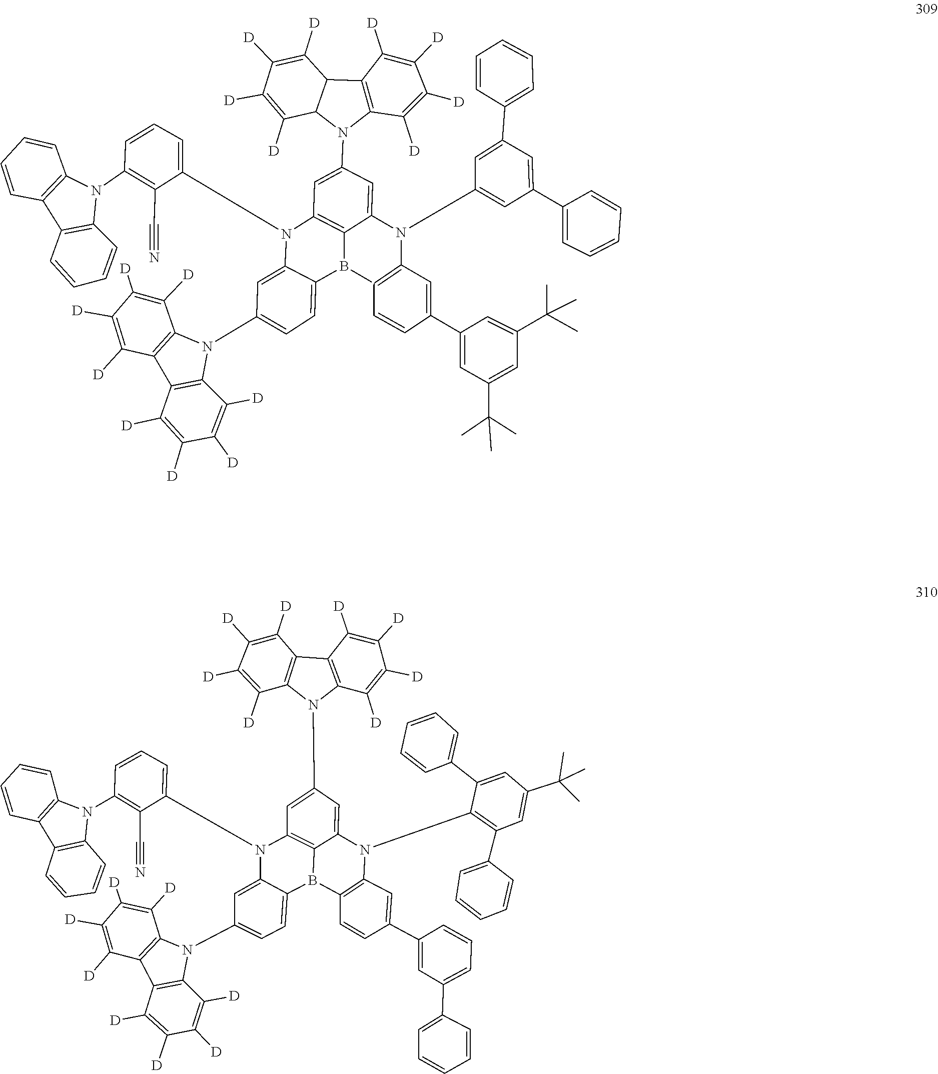

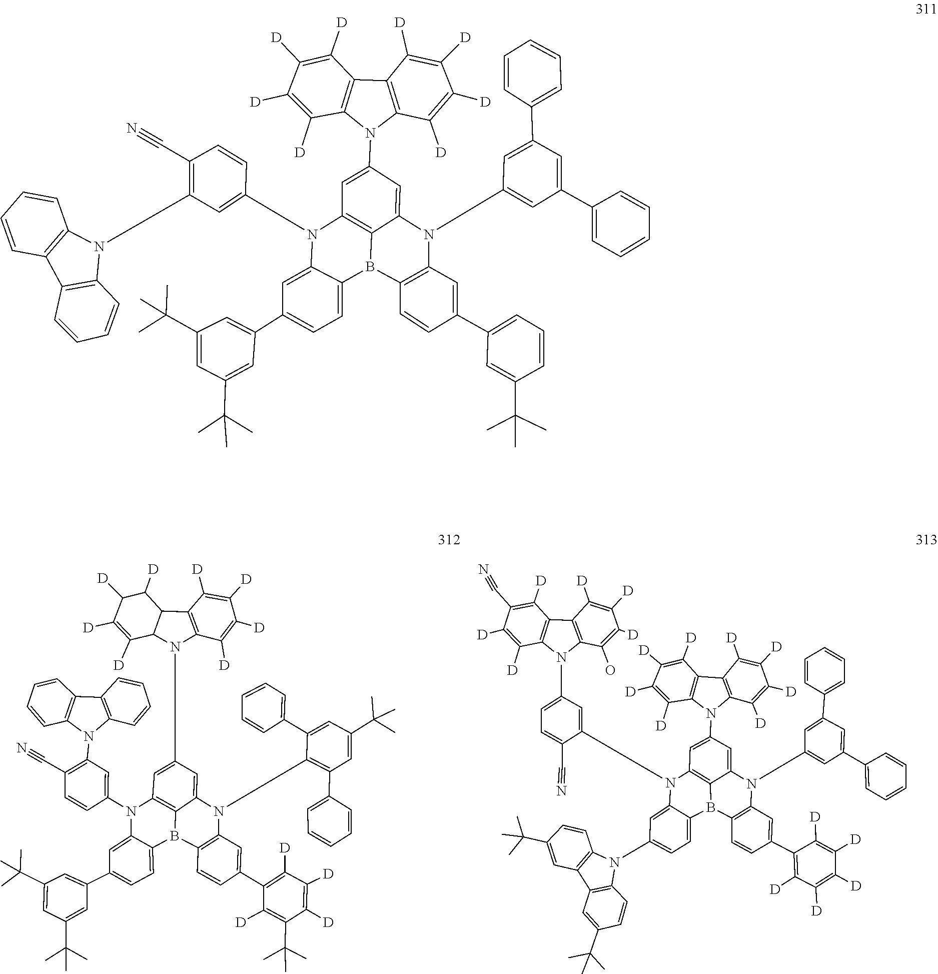

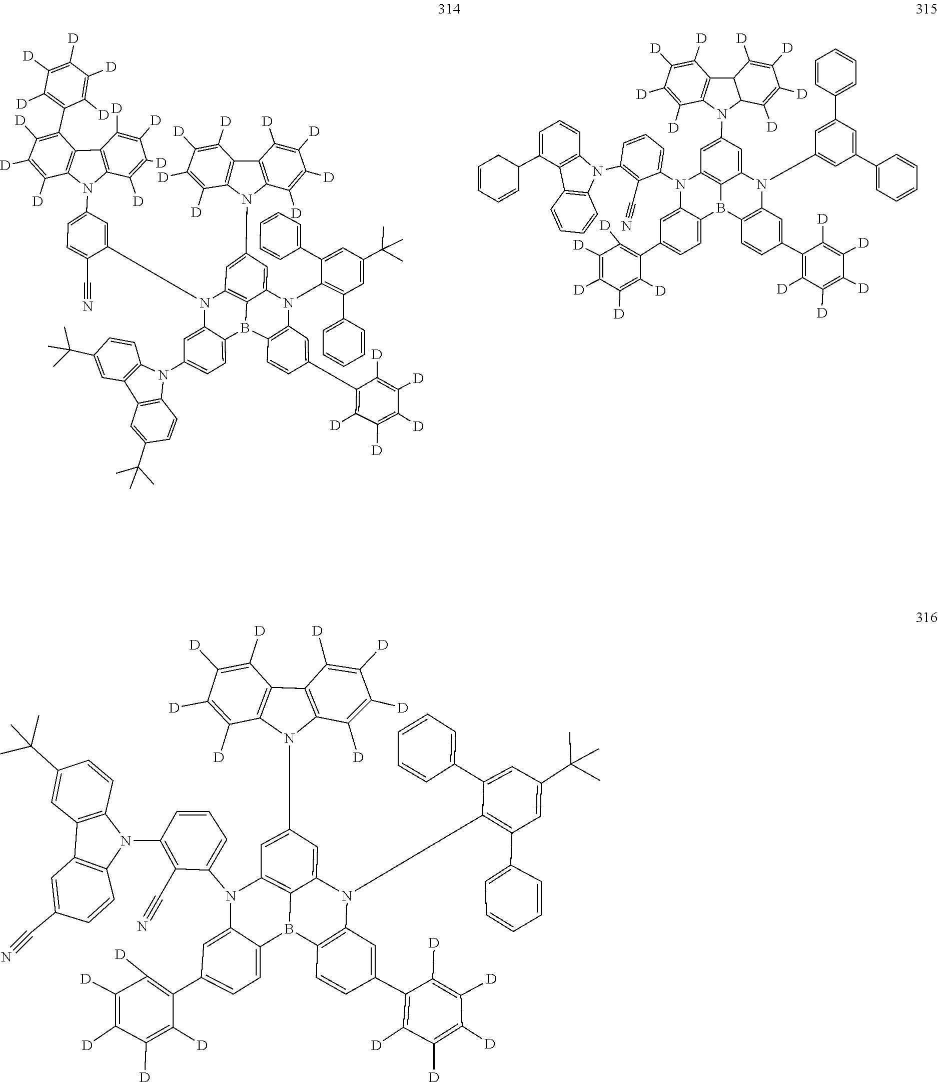

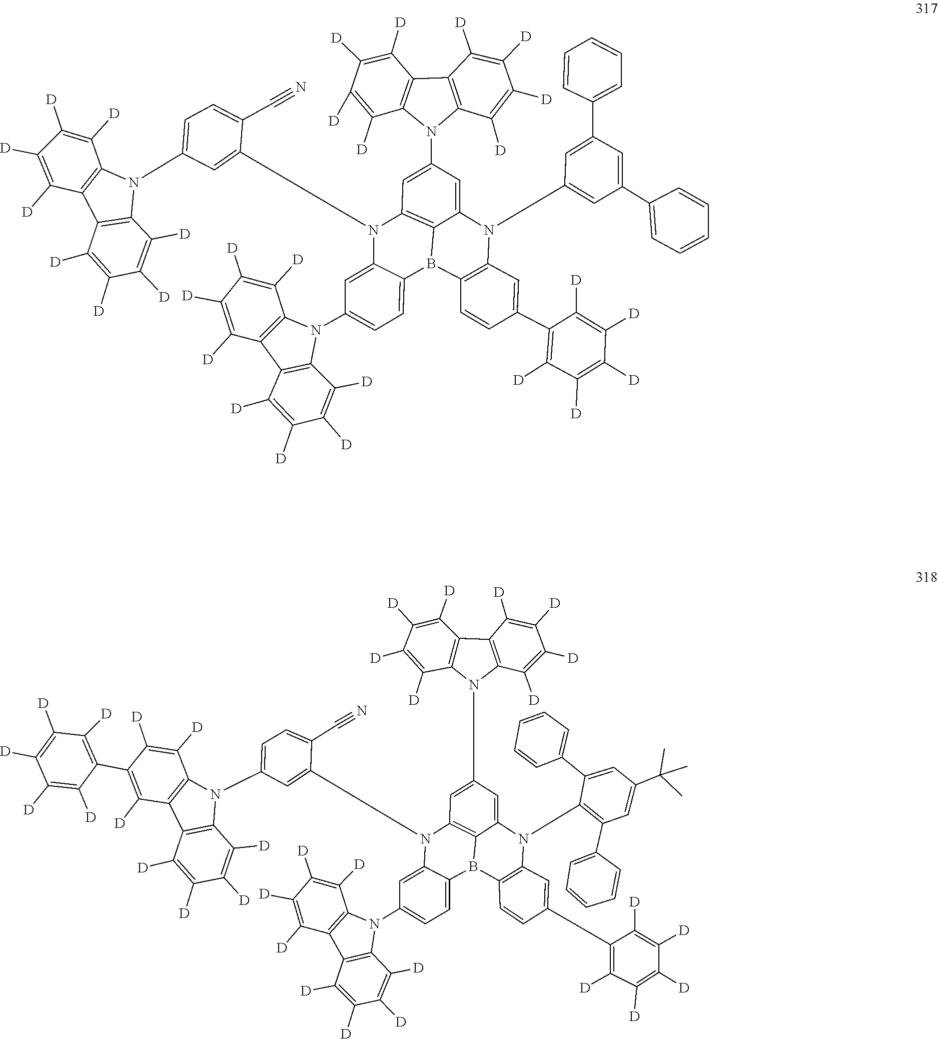

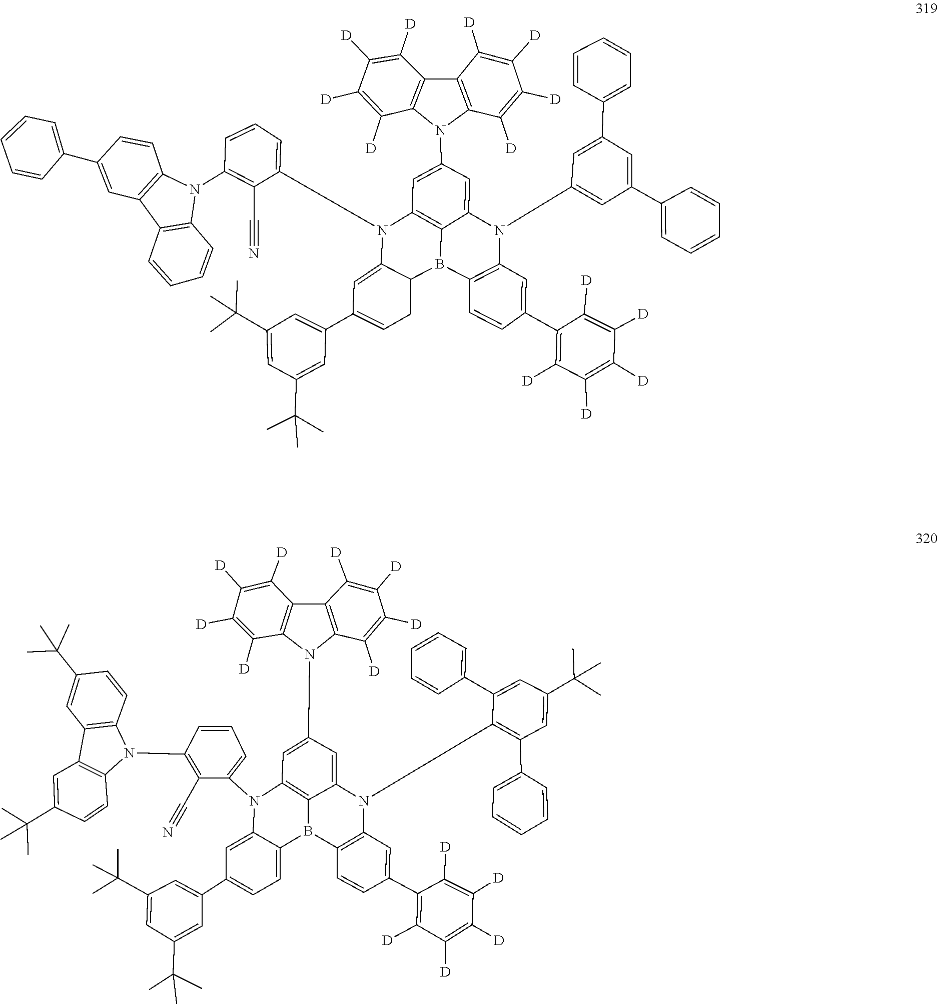

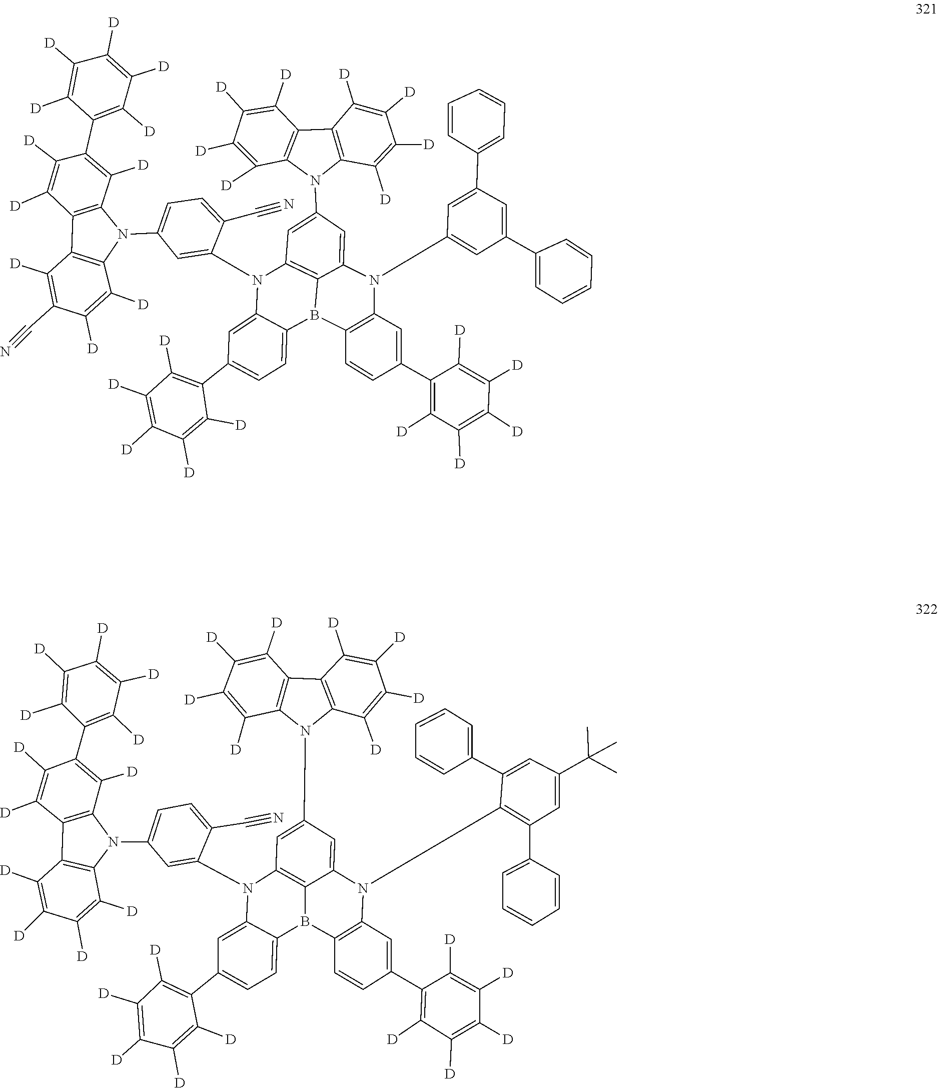

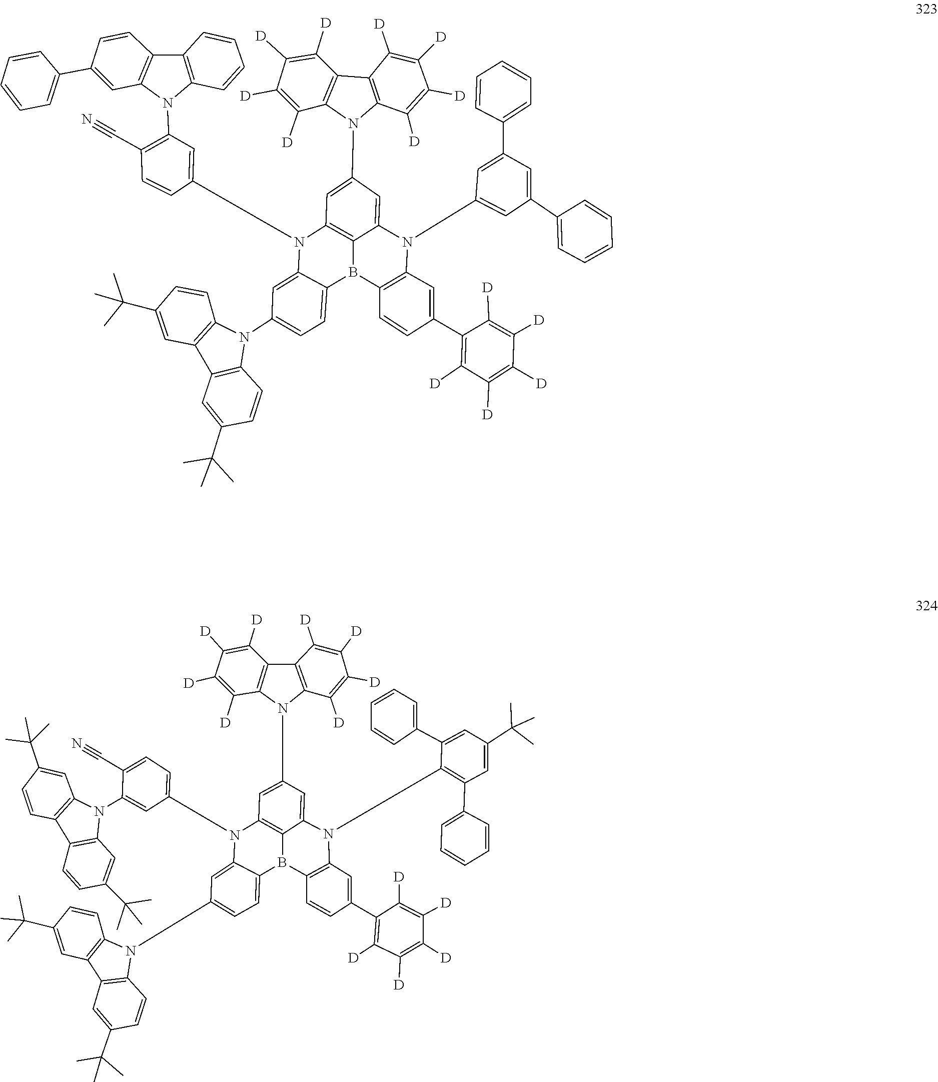

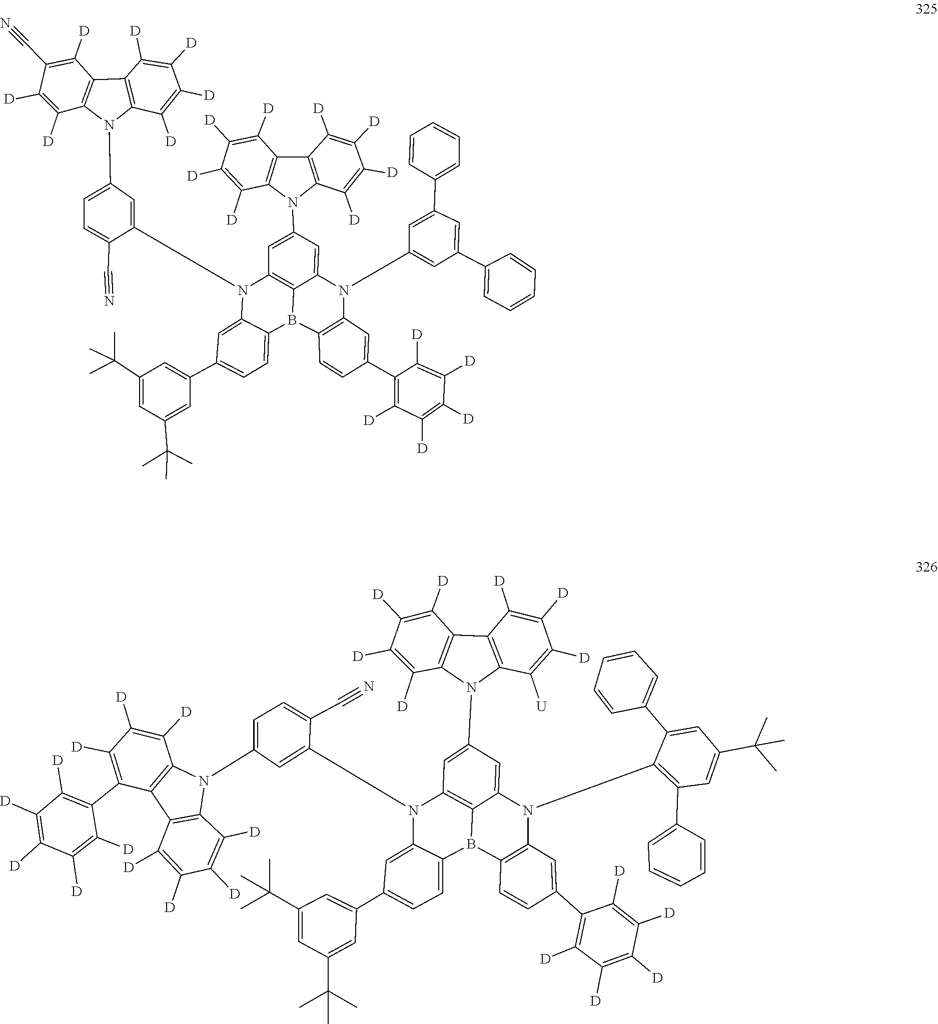

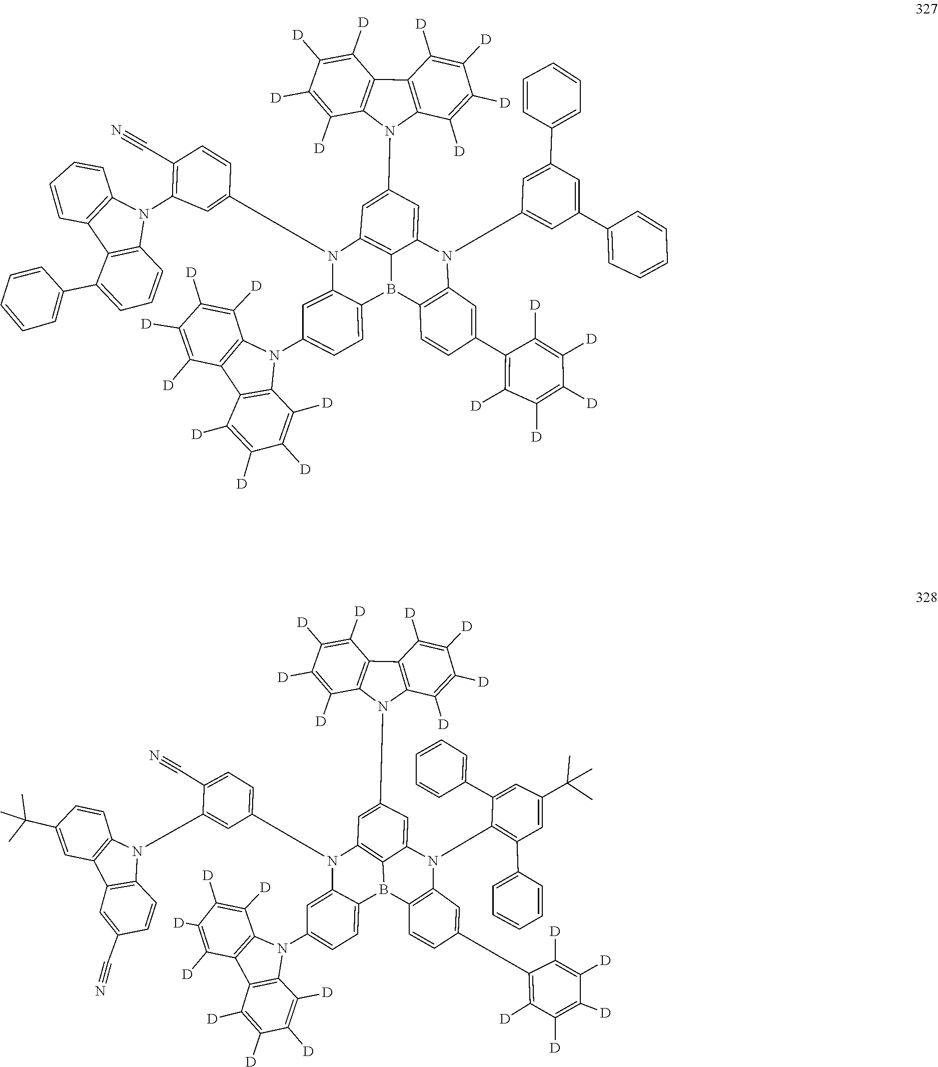

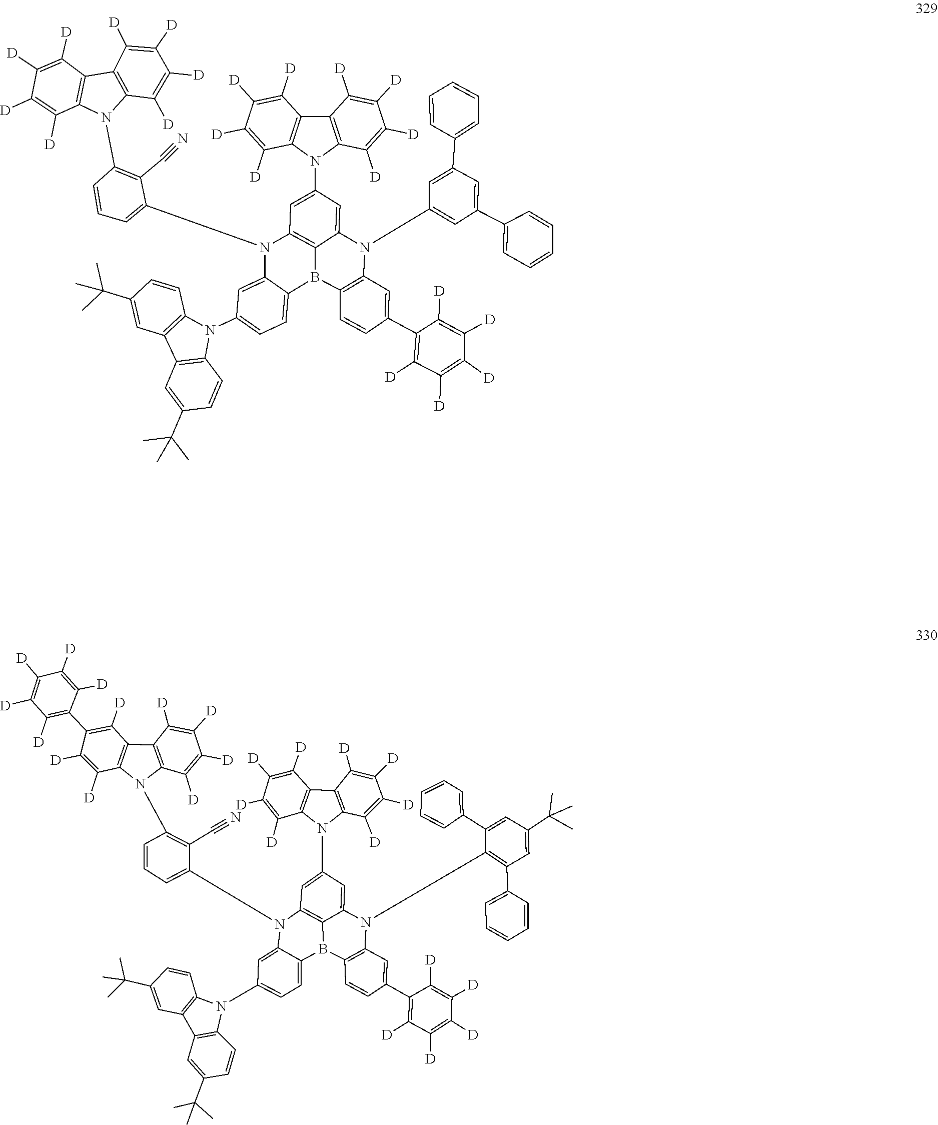

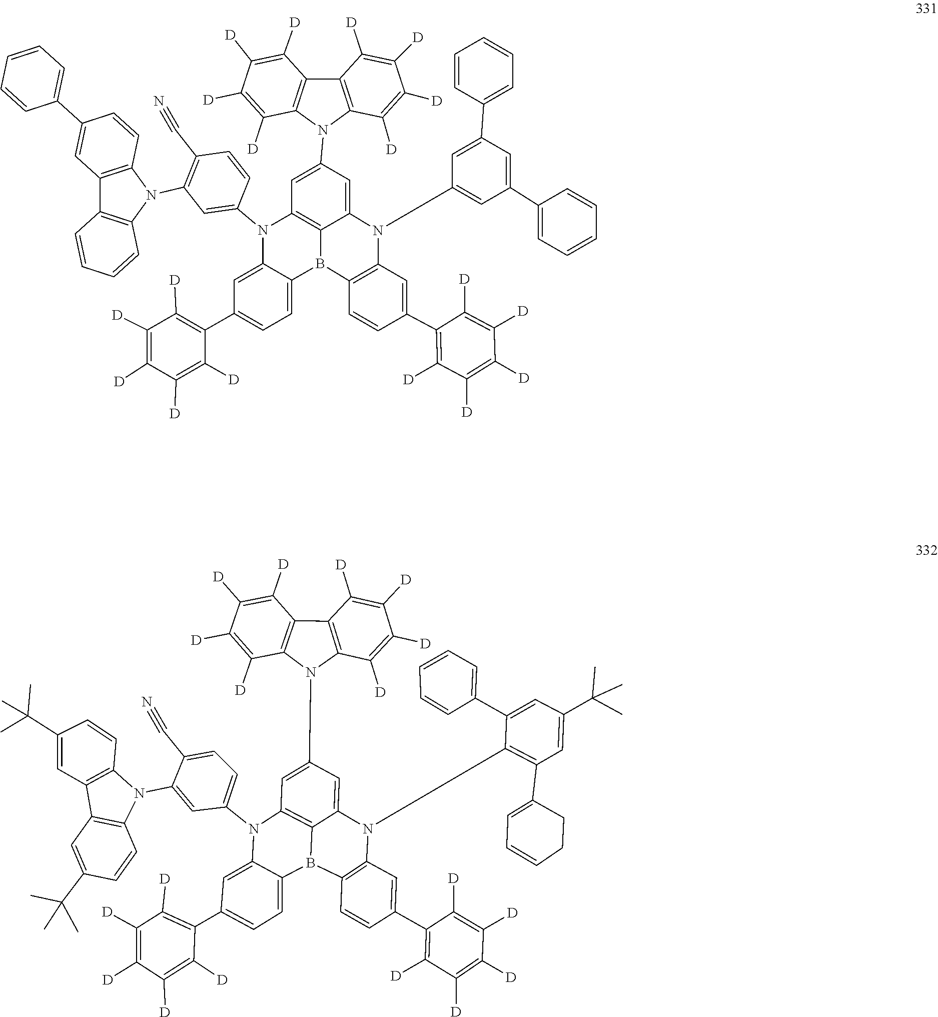

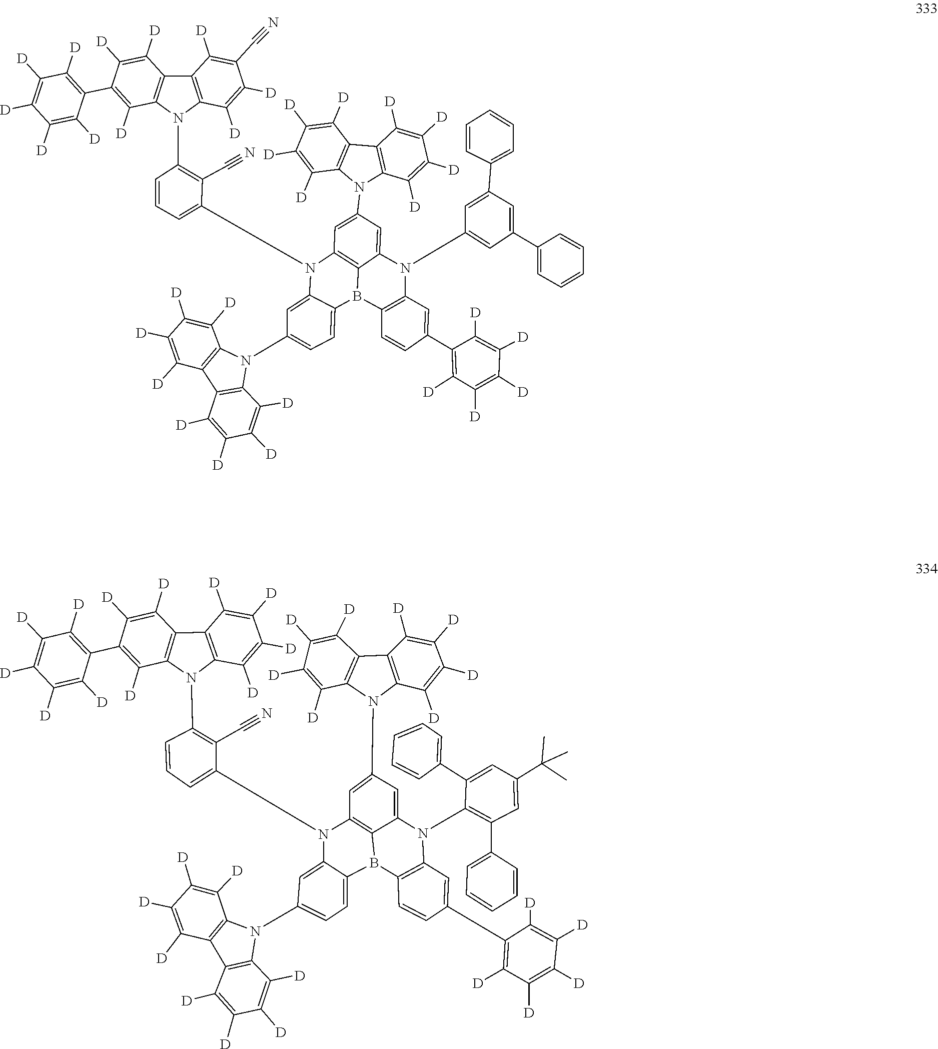

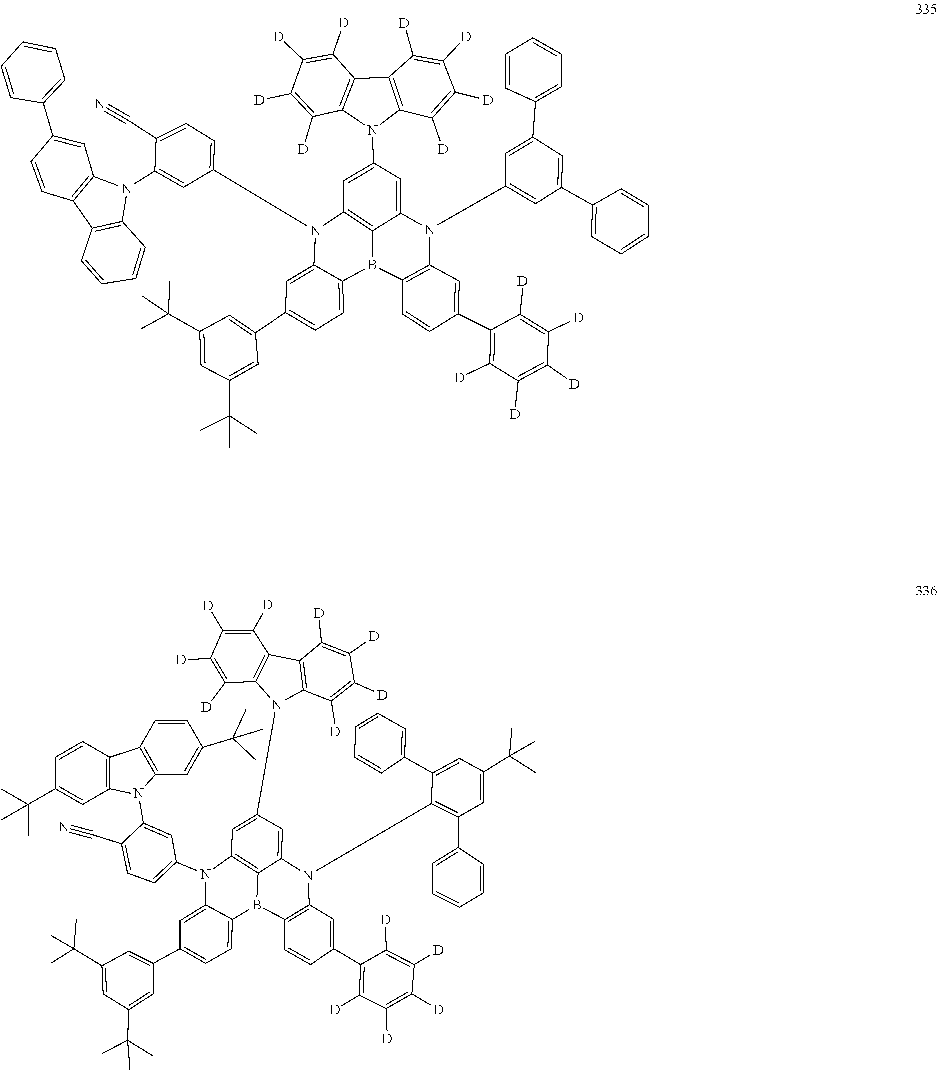

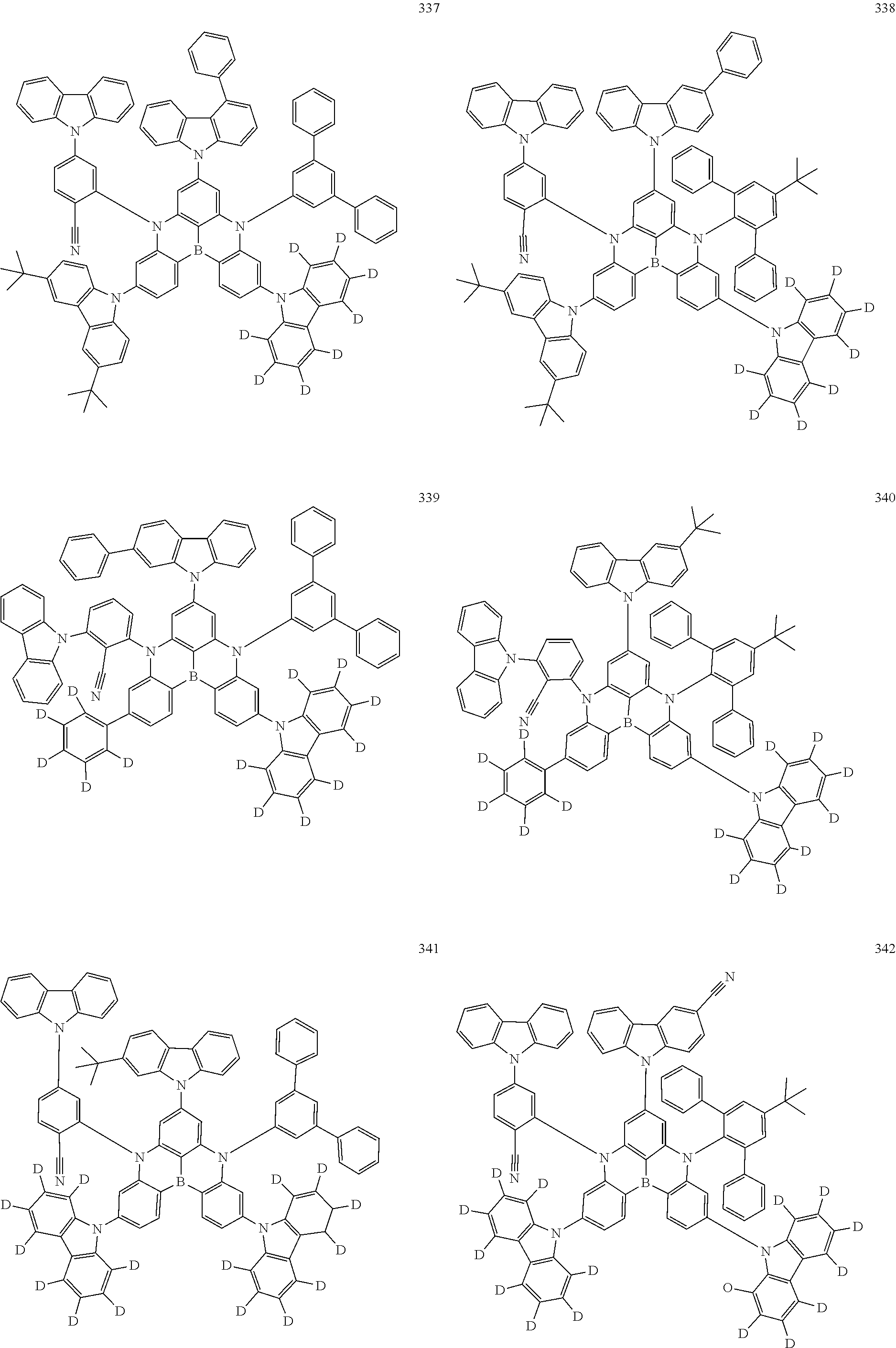

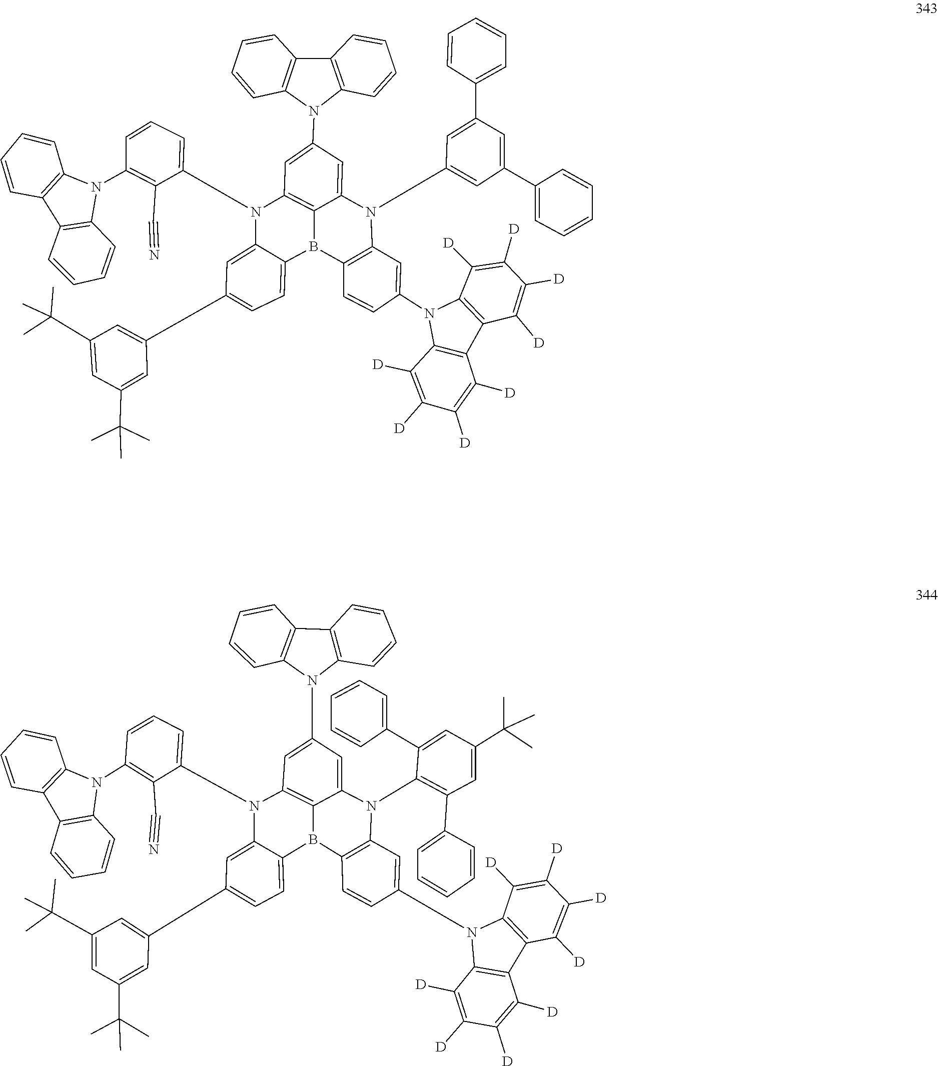 [SMILES: [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1cc(-n3c4ccccc4c4ccccc43)cc3c1B2c1ccc(-c2cc(C(C)(C)C)cc(C(C)(C)C)c2)cc1N3c1cccc(-n2c3ccccc3c3ccccc32)c1C#N ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4ccccc4c4ccccc43)cc3c1B2c1ccc(-c2cc(C(C)(C)C)cc(C(C)(C)C)c2)cc1N3c1cccc(-n2c3ccccc3c3ccccc32)c1C#N]

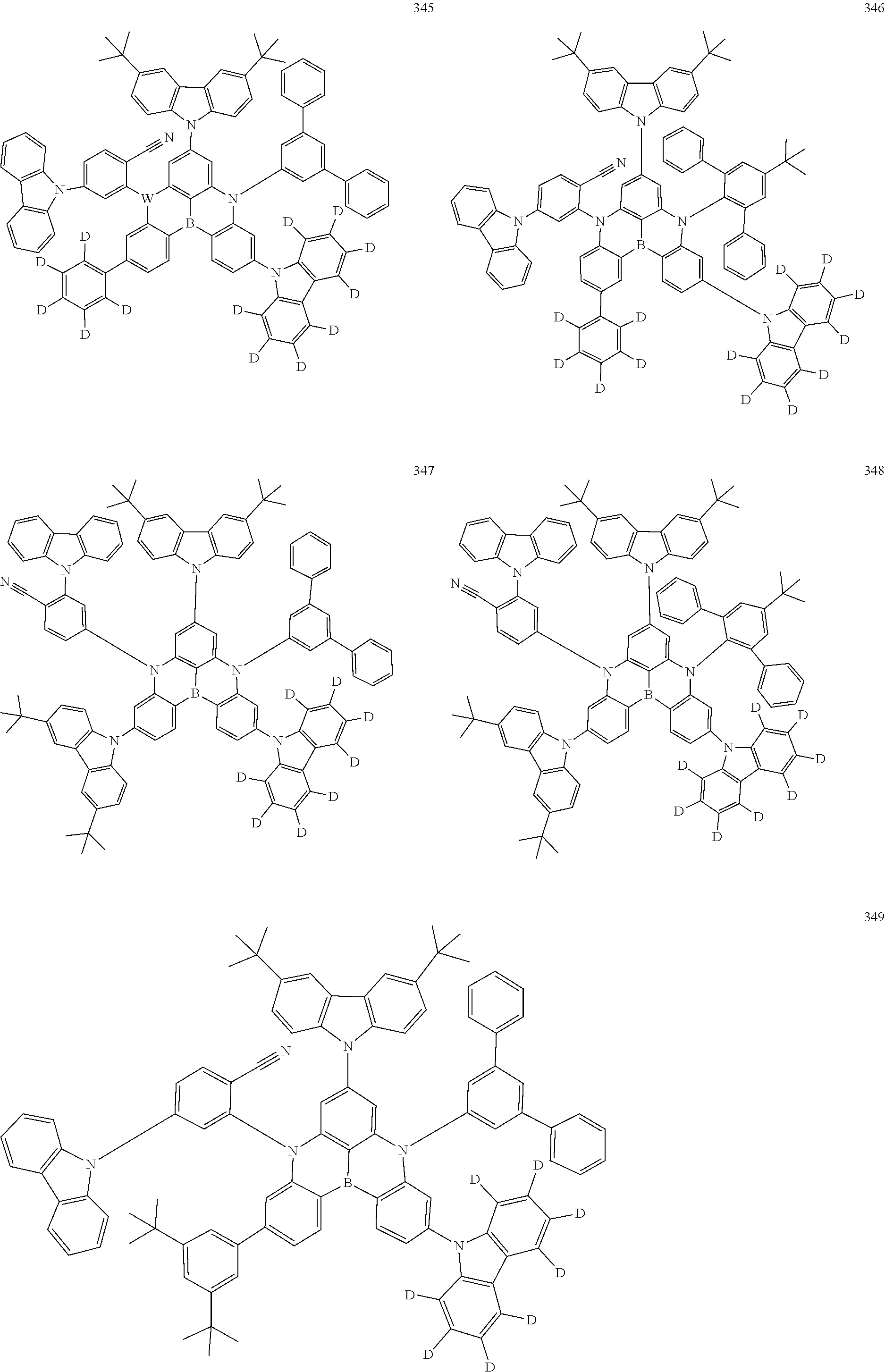

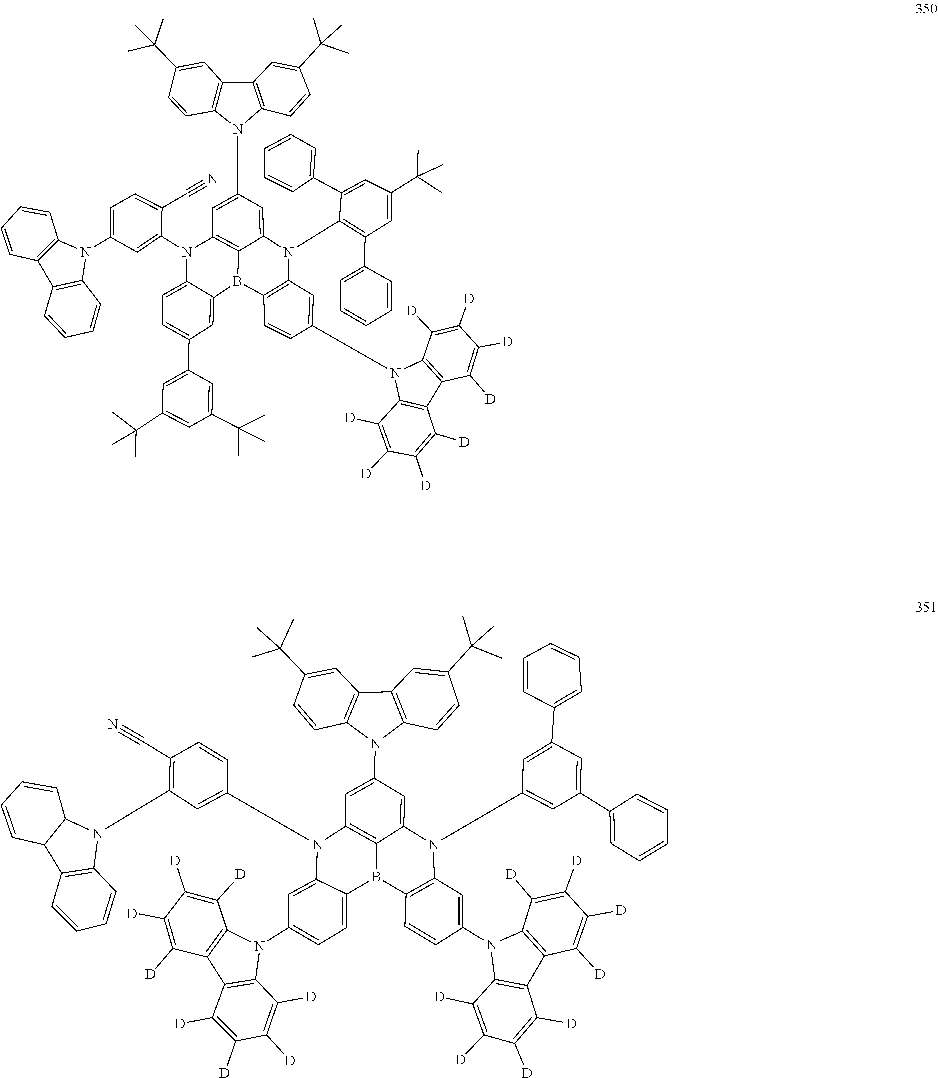

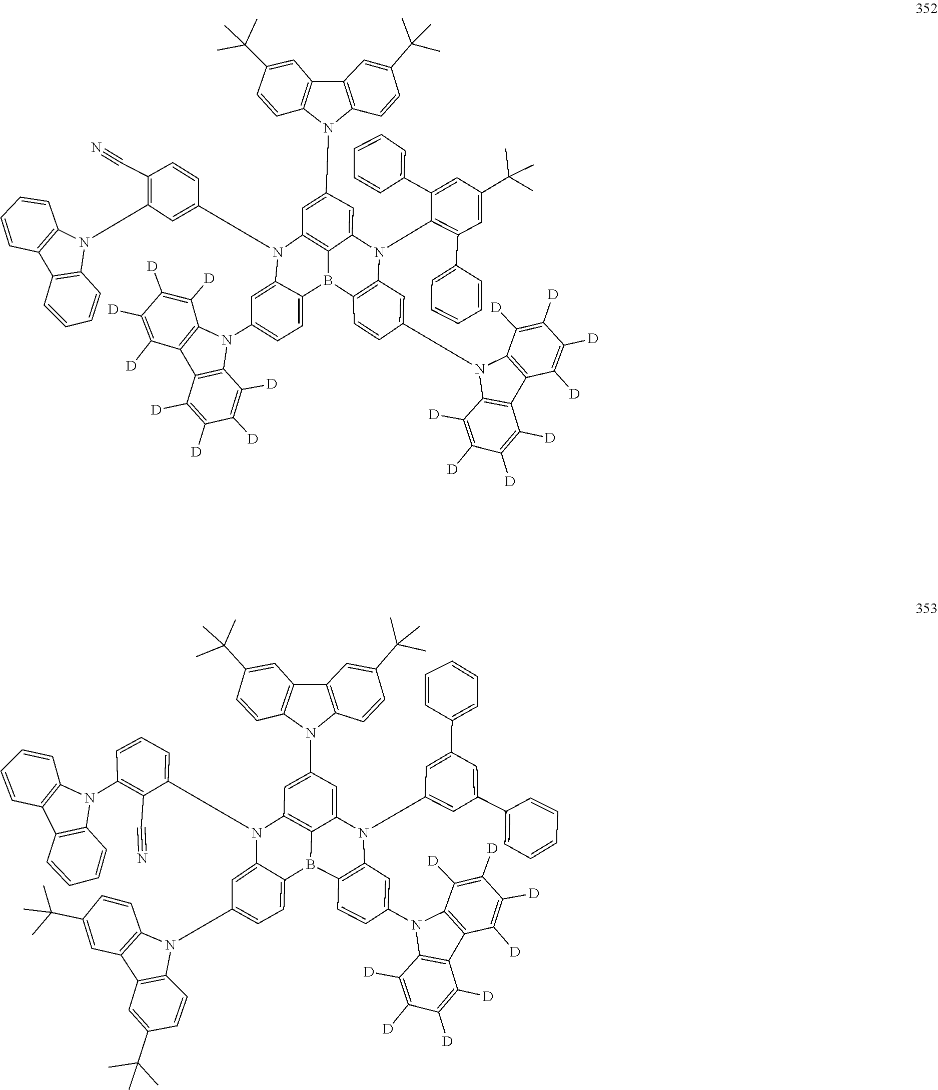

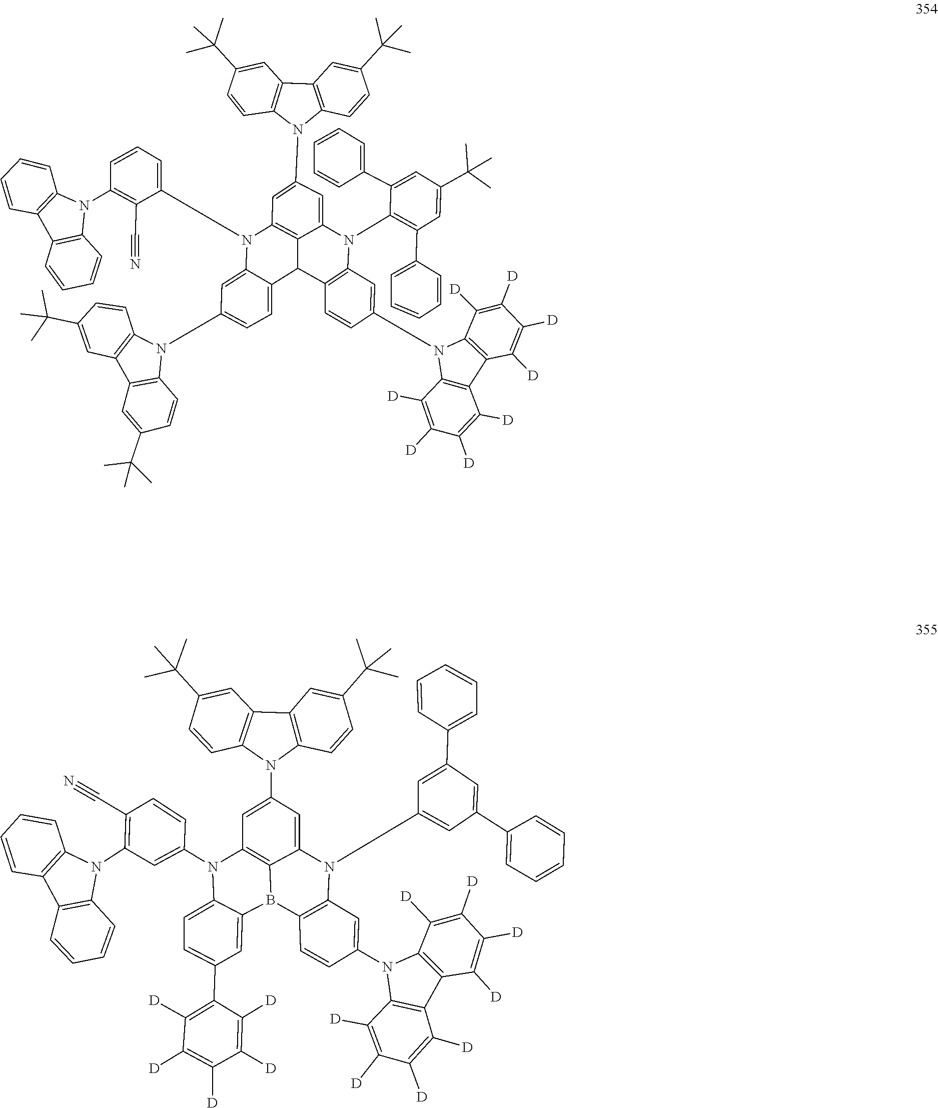

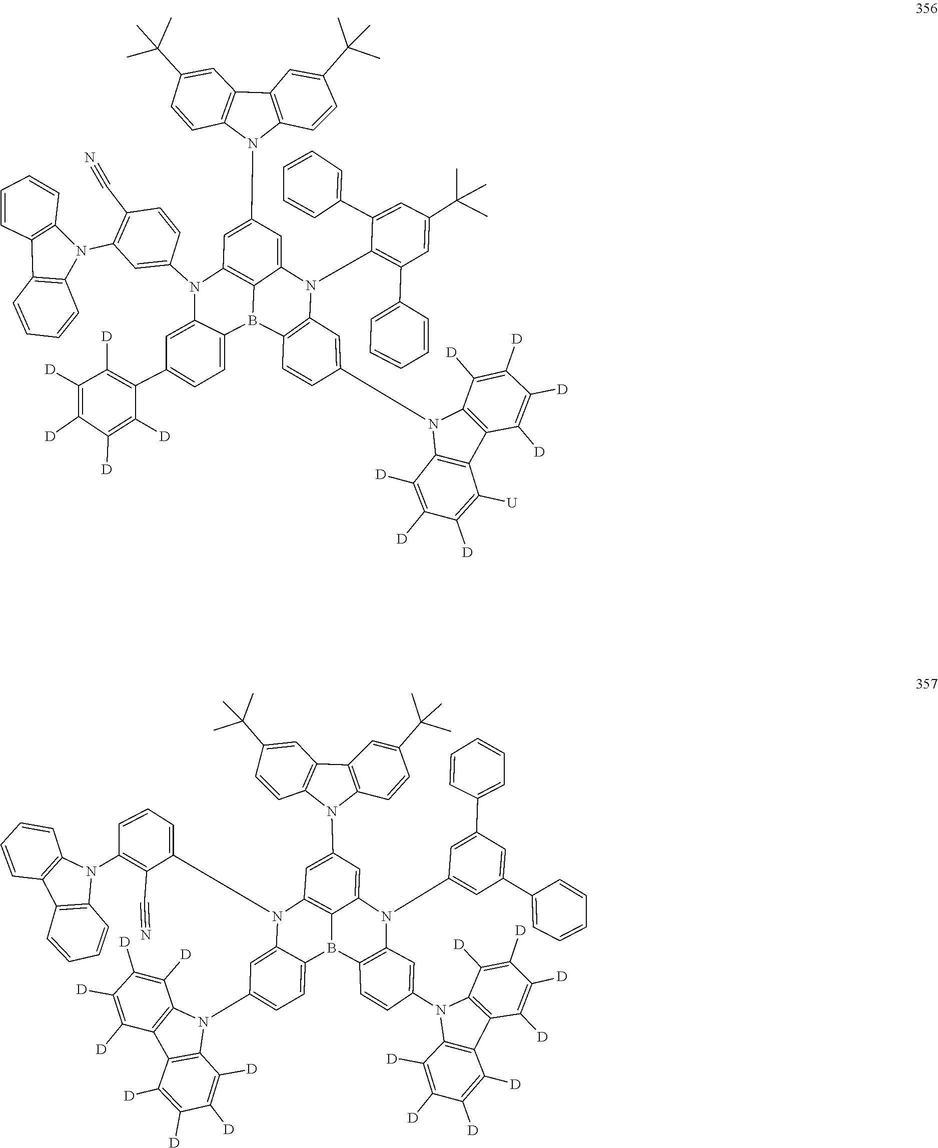

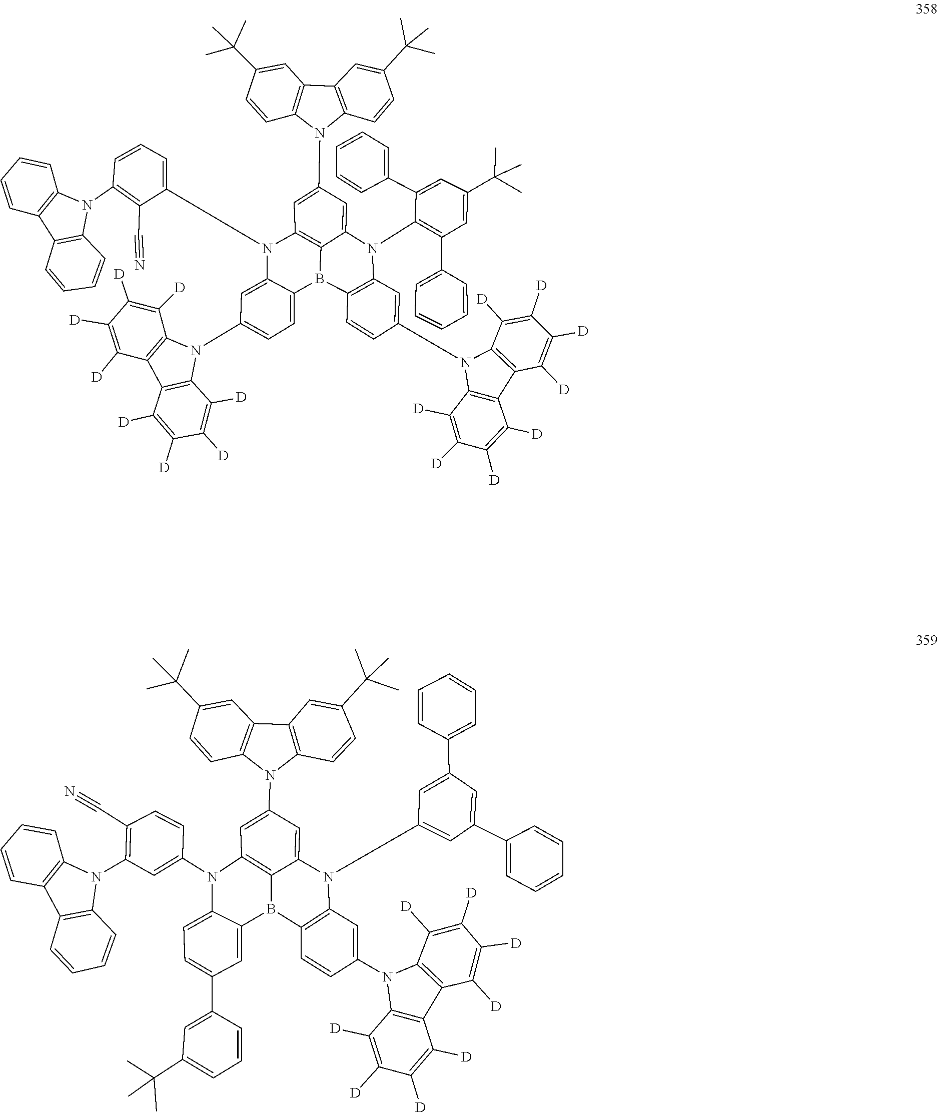

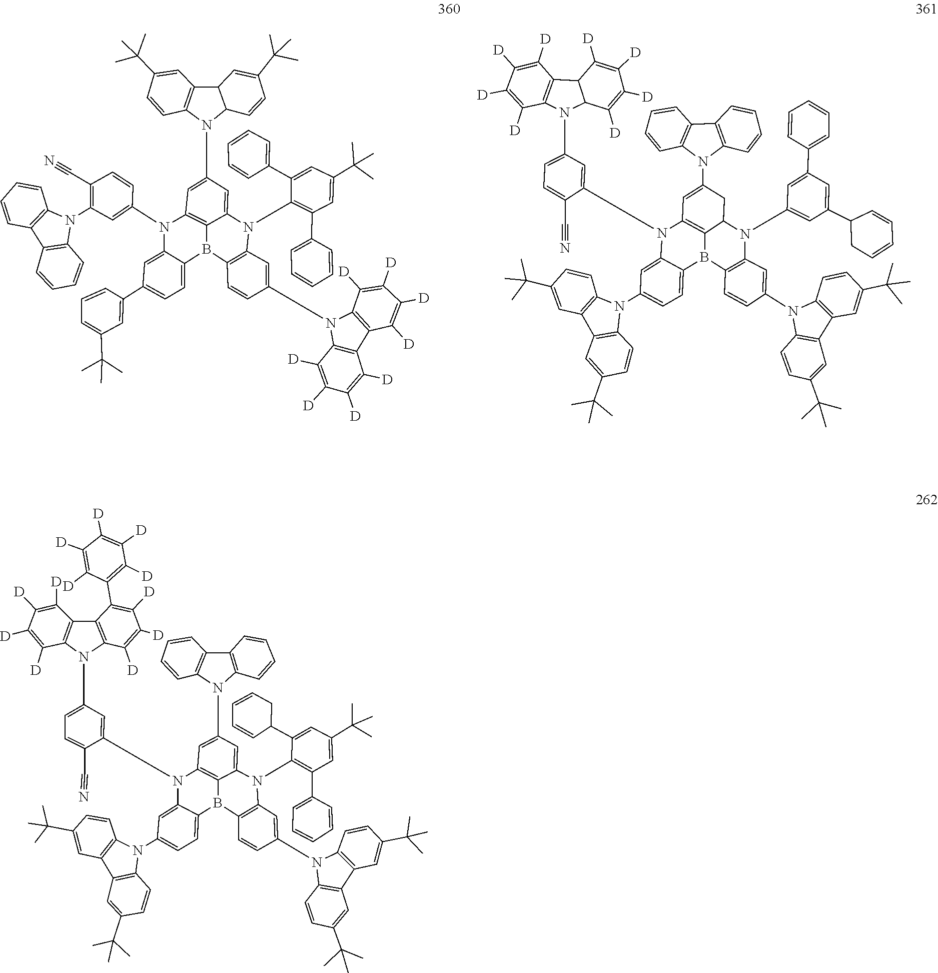

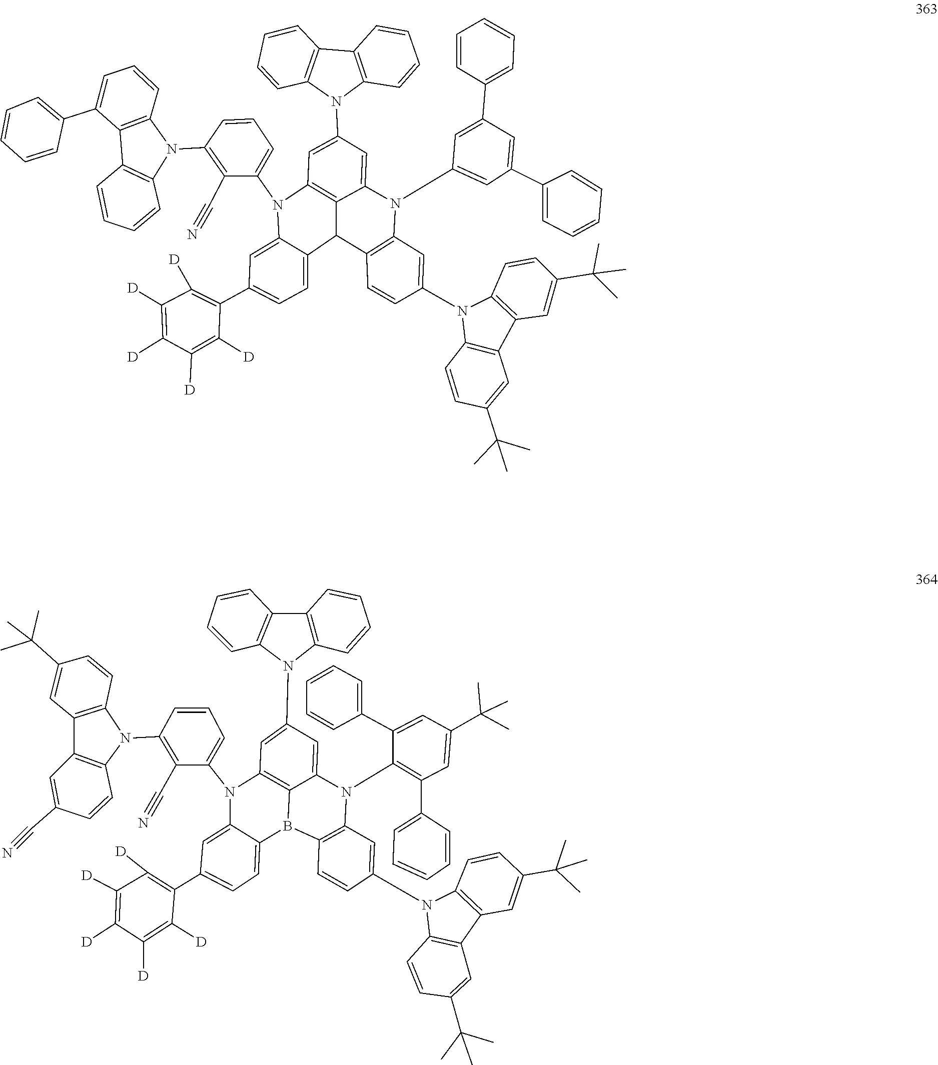

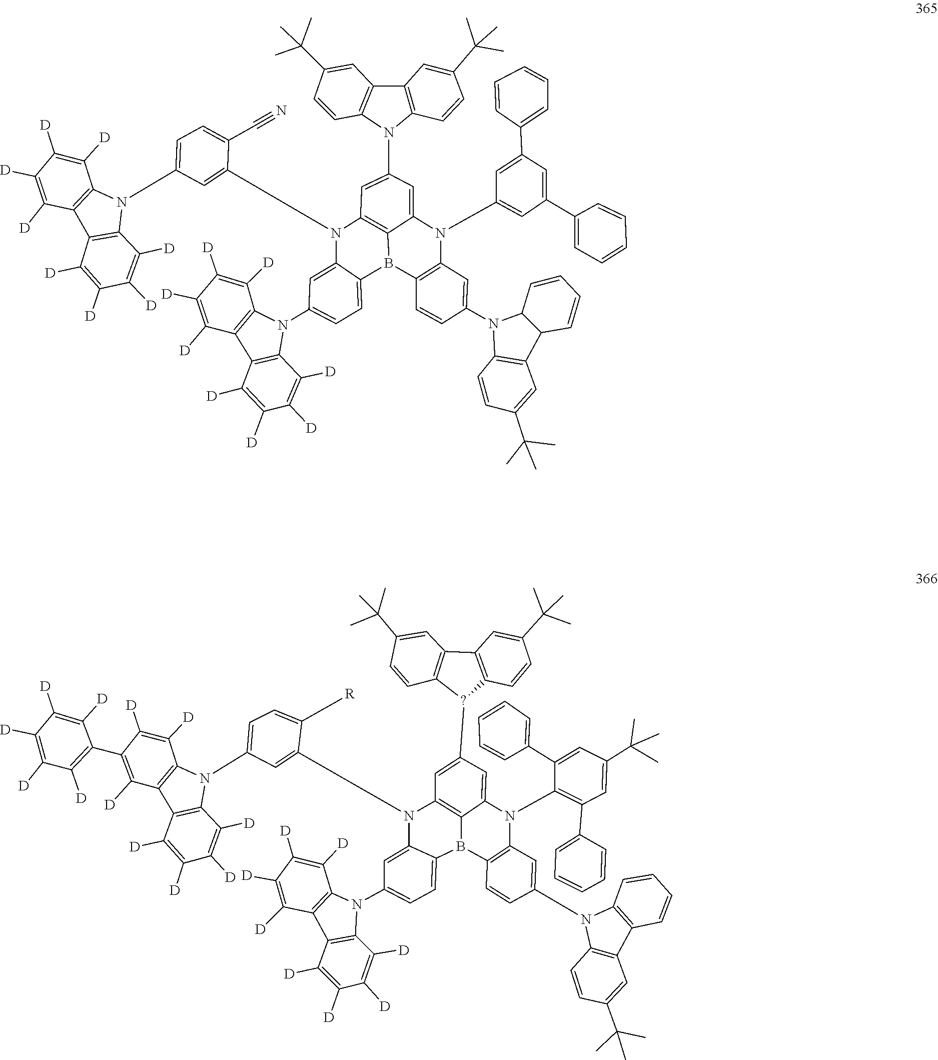

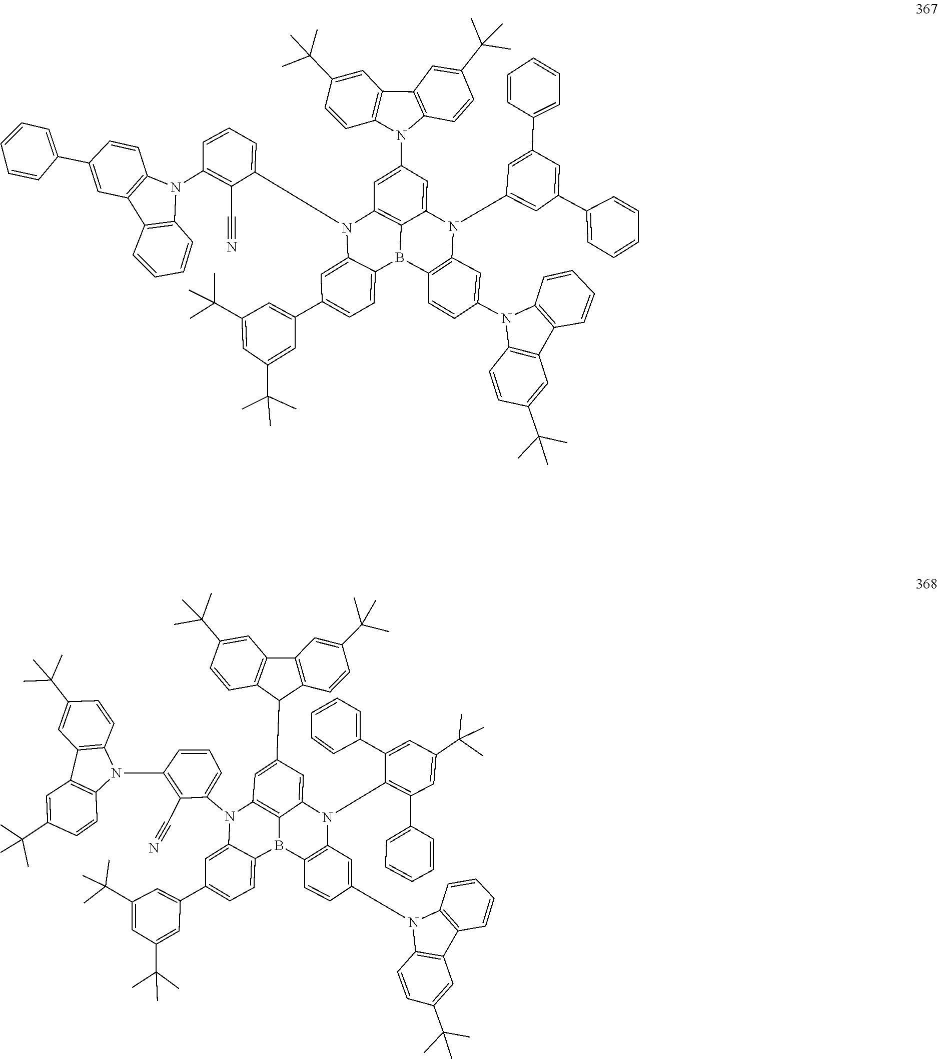 [SMILES: CC(C)(C)c1cc(-c2ccc3c(c2)N(c2cccc(-n4c5ccccc5c5cc(-c6ccccc6)ccc54)c2C#N)c2cc(-n4c5ccc(C(C)(C)C)cc5c5cc(C(C)(C)C)ccc54)cc4c2B3c2ccc(-n3c5ccccc5c5cc(C(C)(C)C)ccc53)cc2N4c2cc(-c3ccccc3)cc(-c3ccccc3)c2)cc(C(C)(C)C)c1 ; CC(C)(C)c1cc(-c2ccc3c(c2)N(c2cccc(-n4c5ccc(C(C)(C)C)cc5c5cc(C(C)(C)C)ccc54)c2C#N)c2cc(C4c5ccc(C(C)(C)C)cc5-c5cc(C(C)(C)C)ccc54)cc4c2B3c2ccc(-n3c5ccccc5c5cc(C(C)(C)C)ccc53)cc2N4c2c(-c3ccccc3)cc(C(C)(C)C)cc2-c2ccccc2)cc(C(C)(C)C)c1]

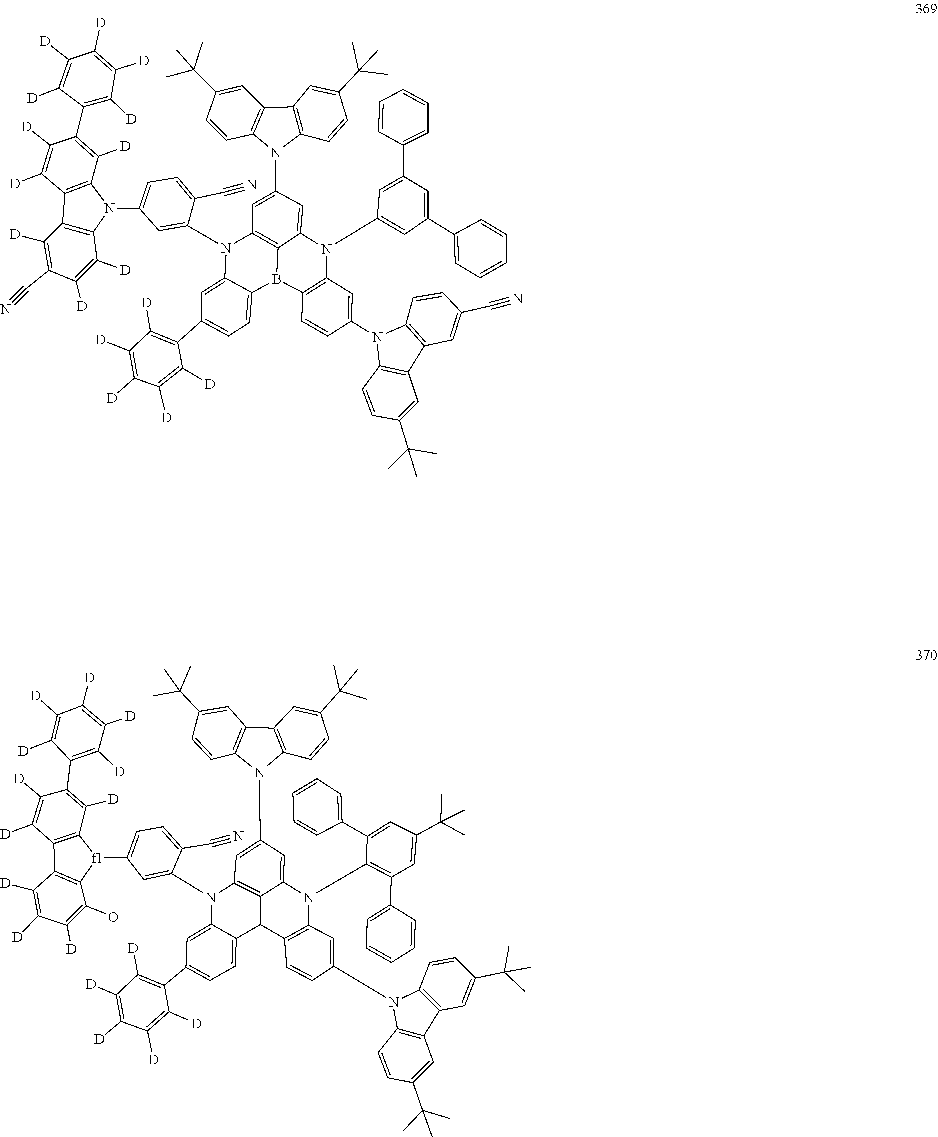

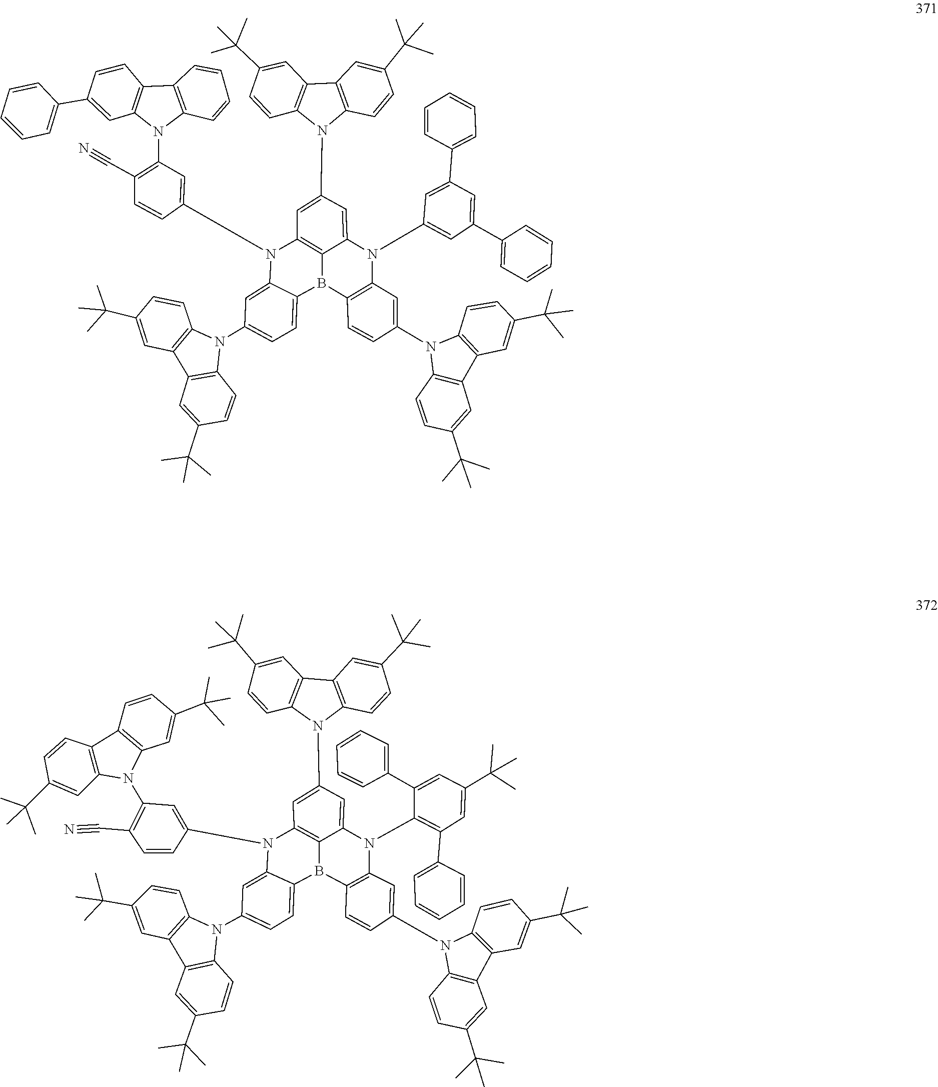

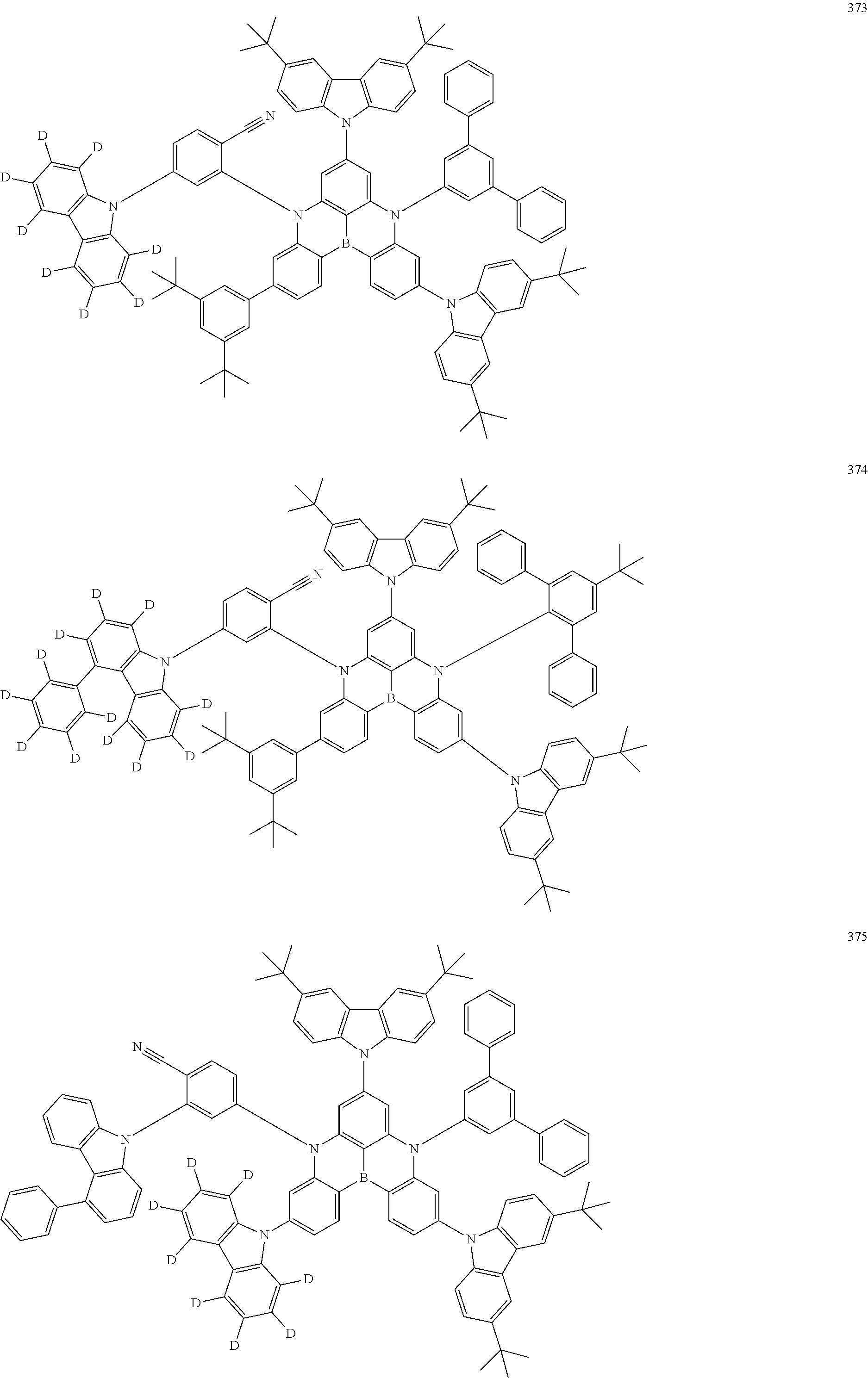

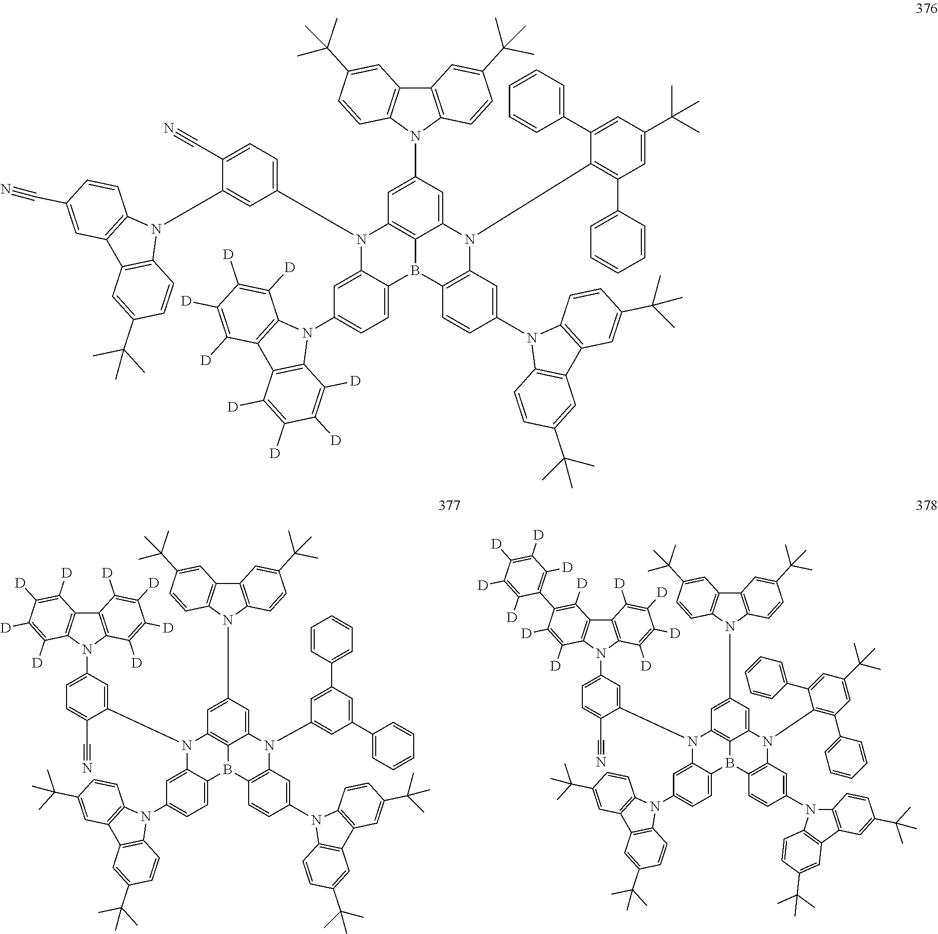

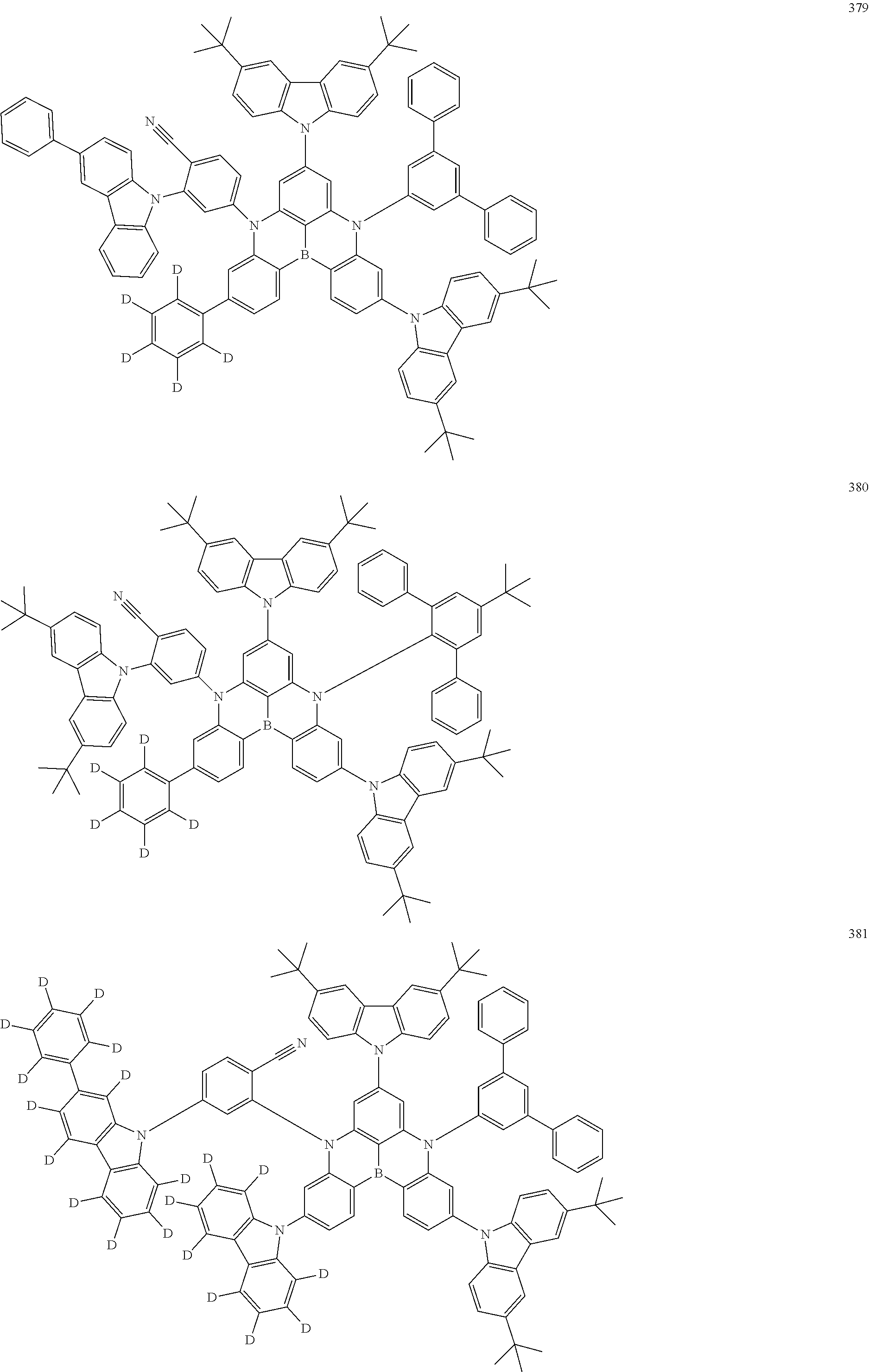

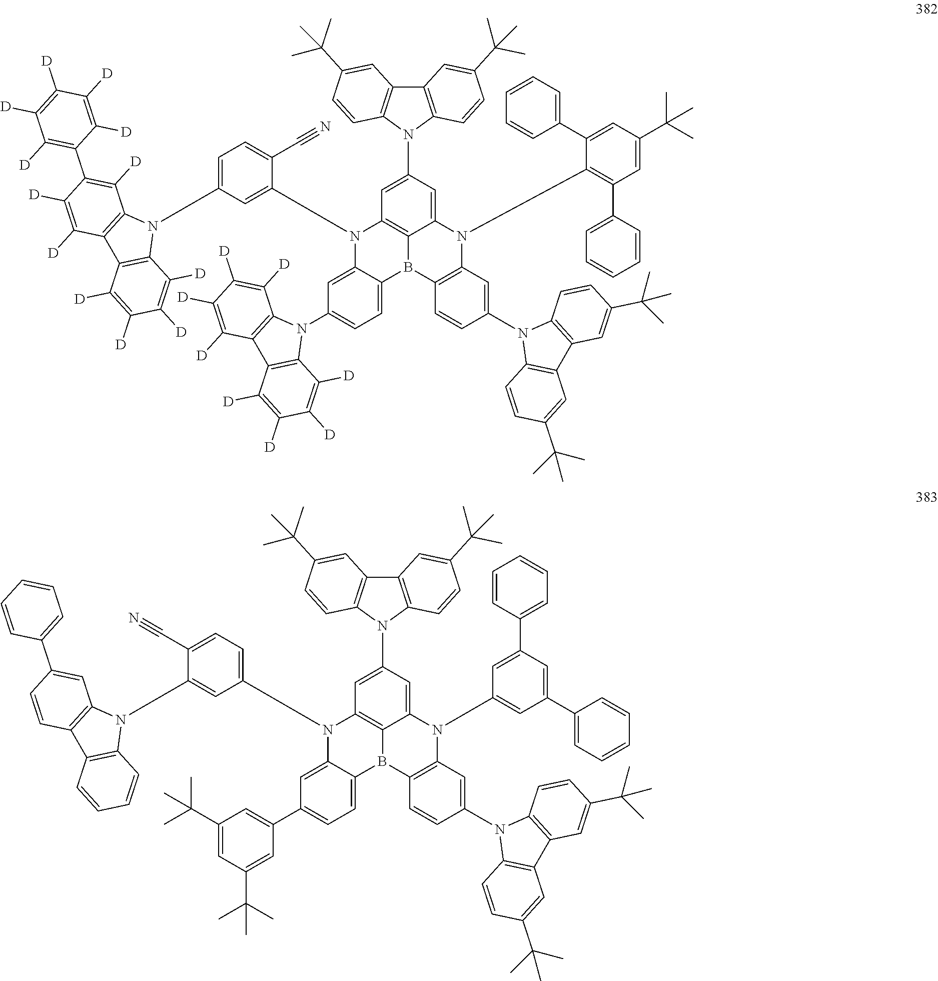

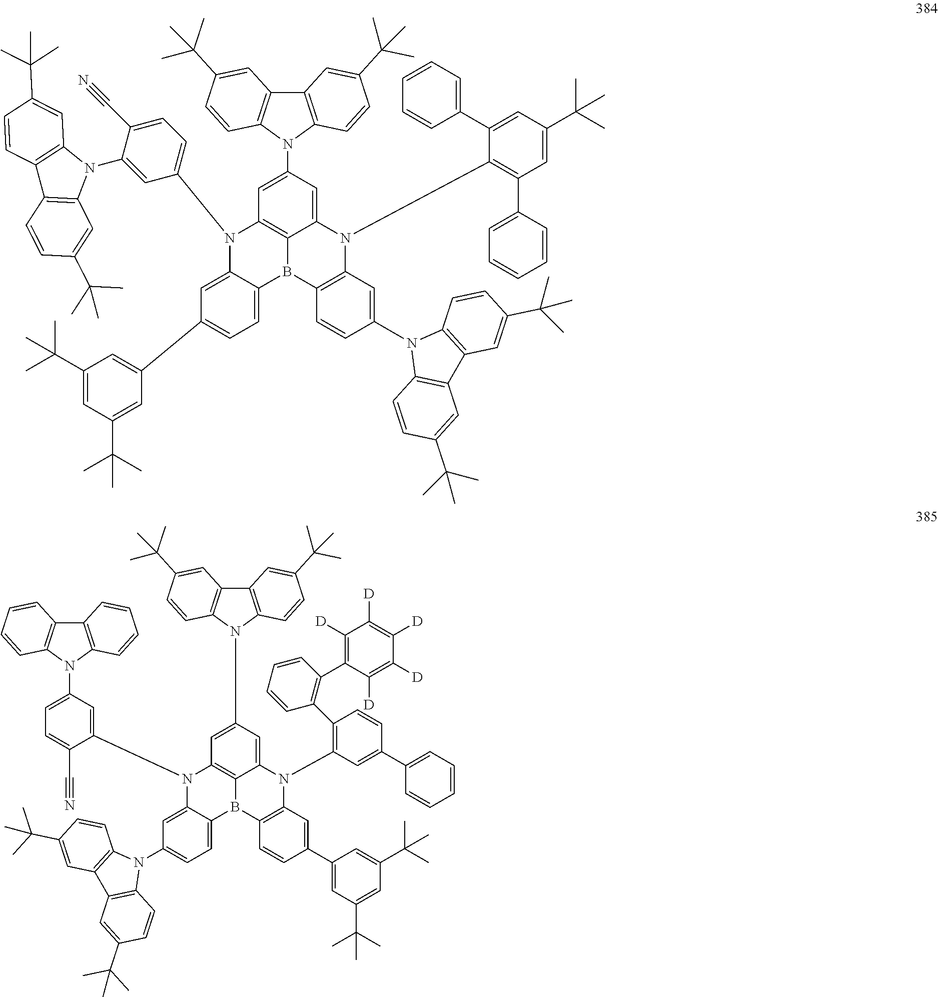 [SMILES: CC(C)(C)c1cc(-c2ccc3c(c2)N(c2ccc(C#N)c(-n4c5cc(C(C)(C)C)ccc5c5ccc(C(C)(C)C)cc54)c2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2ccccc2)cc(C(C)(C)C)c1 ; [2H]c1c([2H])c([2H])c(-c2ccccc2-c2ccc(-c3ccccc3)cc2N2c3cc(-c4cc(C(C)(C)C)cc(C(C)(C)C)c4)ccc3B3c4ccc(-n5c6ccc(C(C)(C)C)cc6c6cc(C(C)(C)C)ccc65)cc4N(c4cc(-n5c6ccccc6c6ccccc65)ccc4C#N)c4cc(-n5c6ccc(C(C)(C)C)cc6c6cc(C(C)(C)C)ccc65)cc2c43)c([2H])c1[2H]]

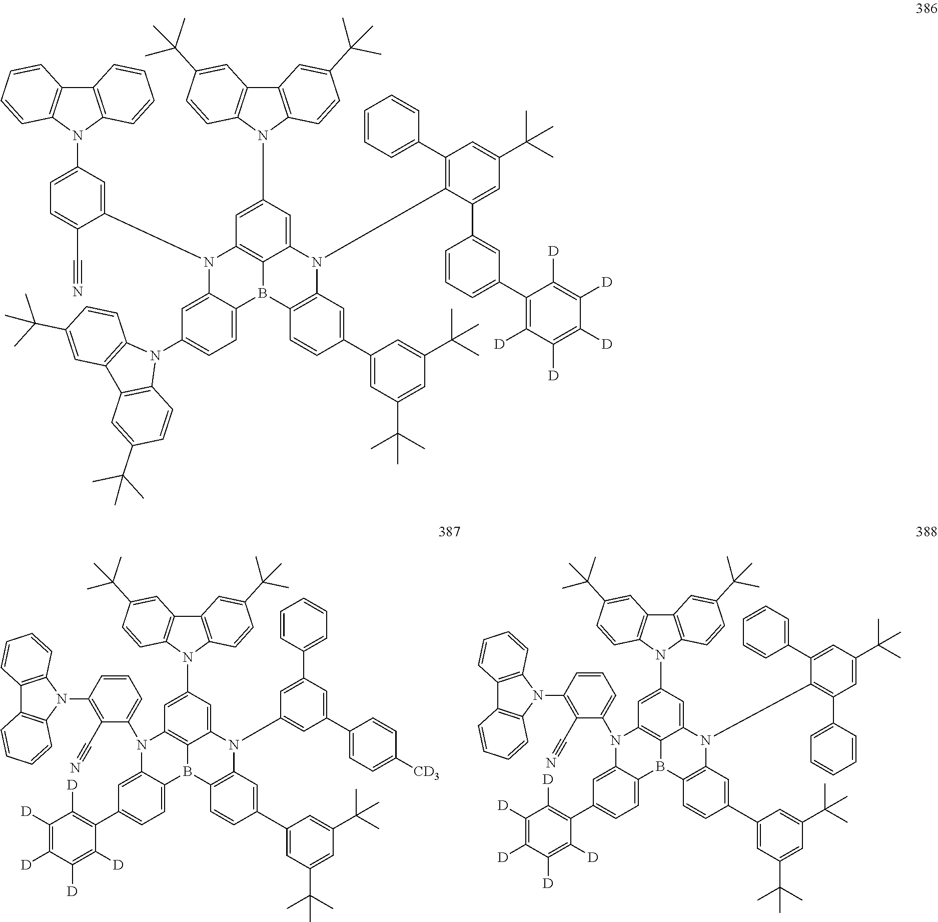

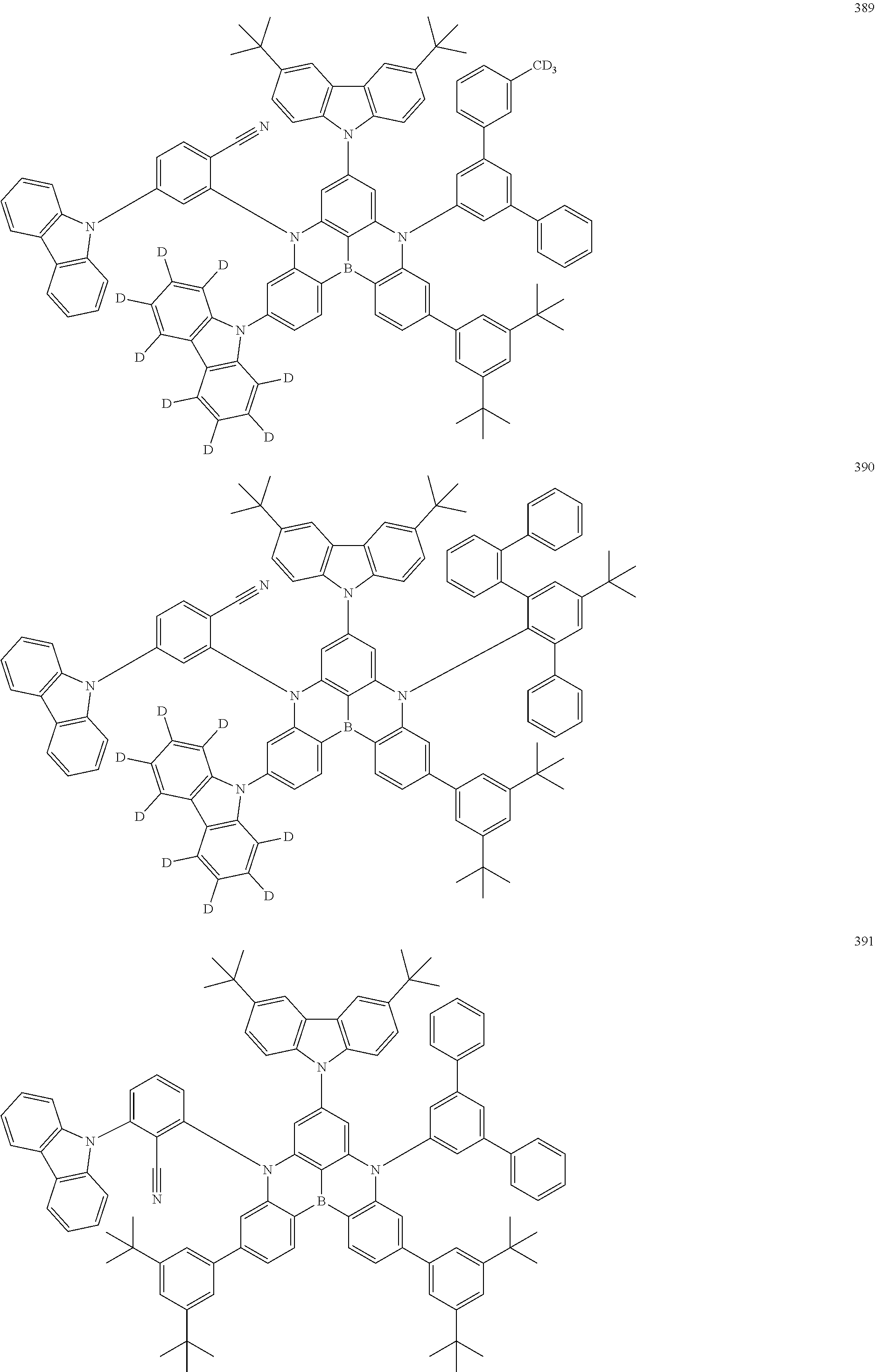

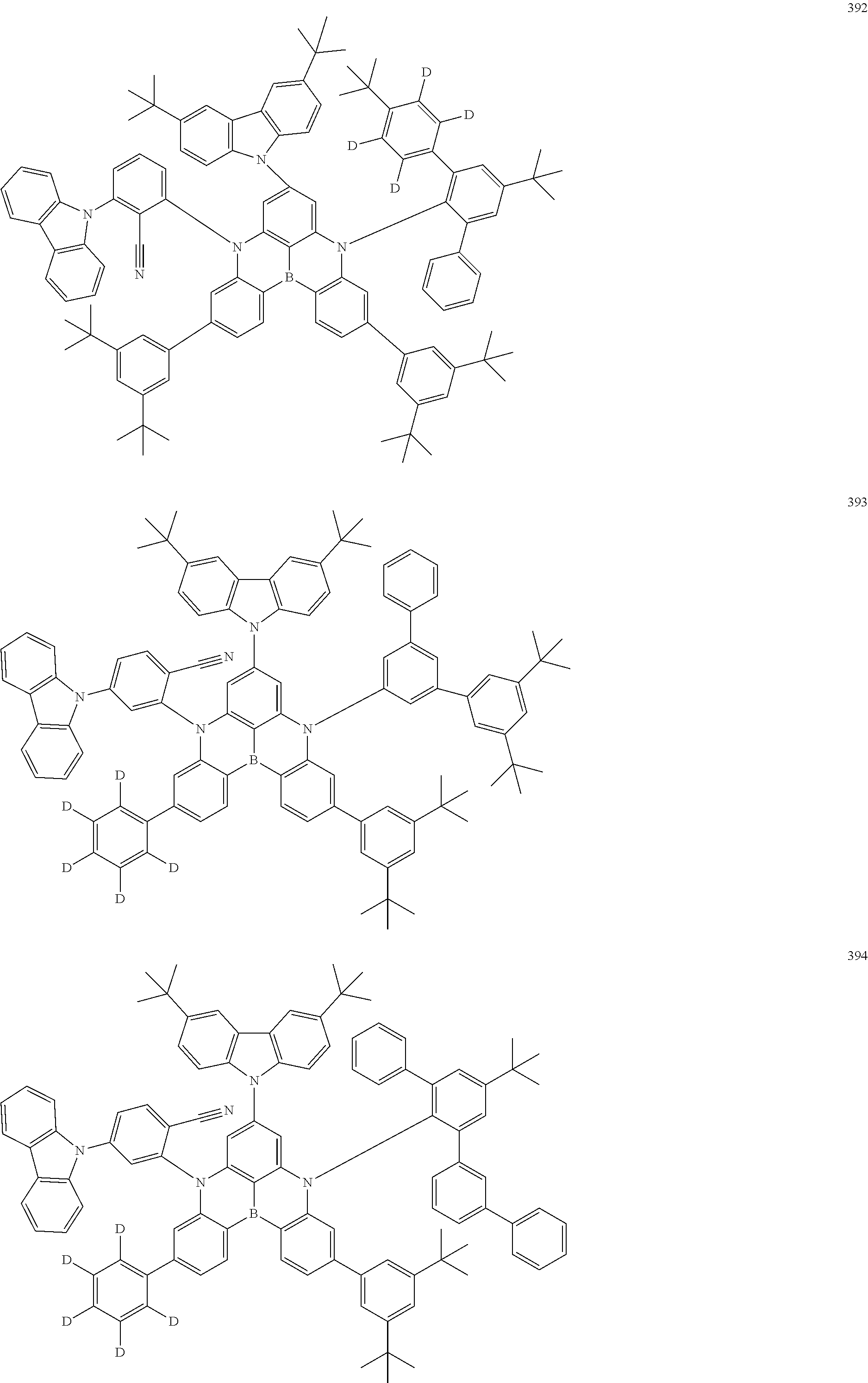

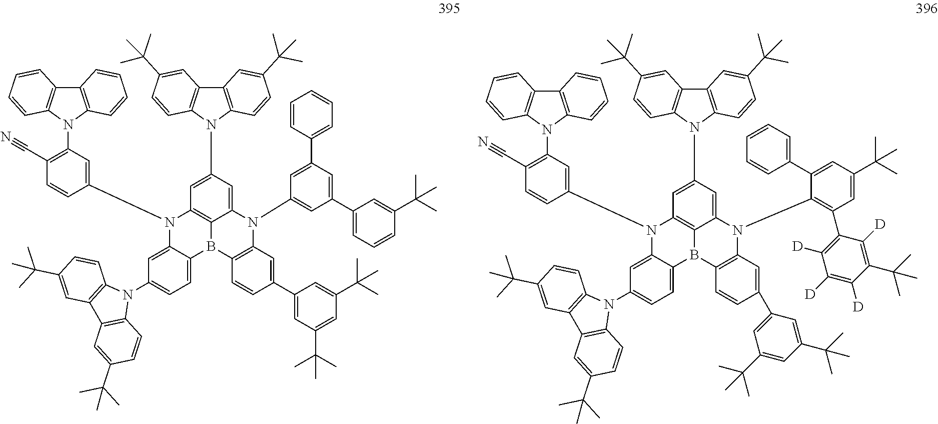

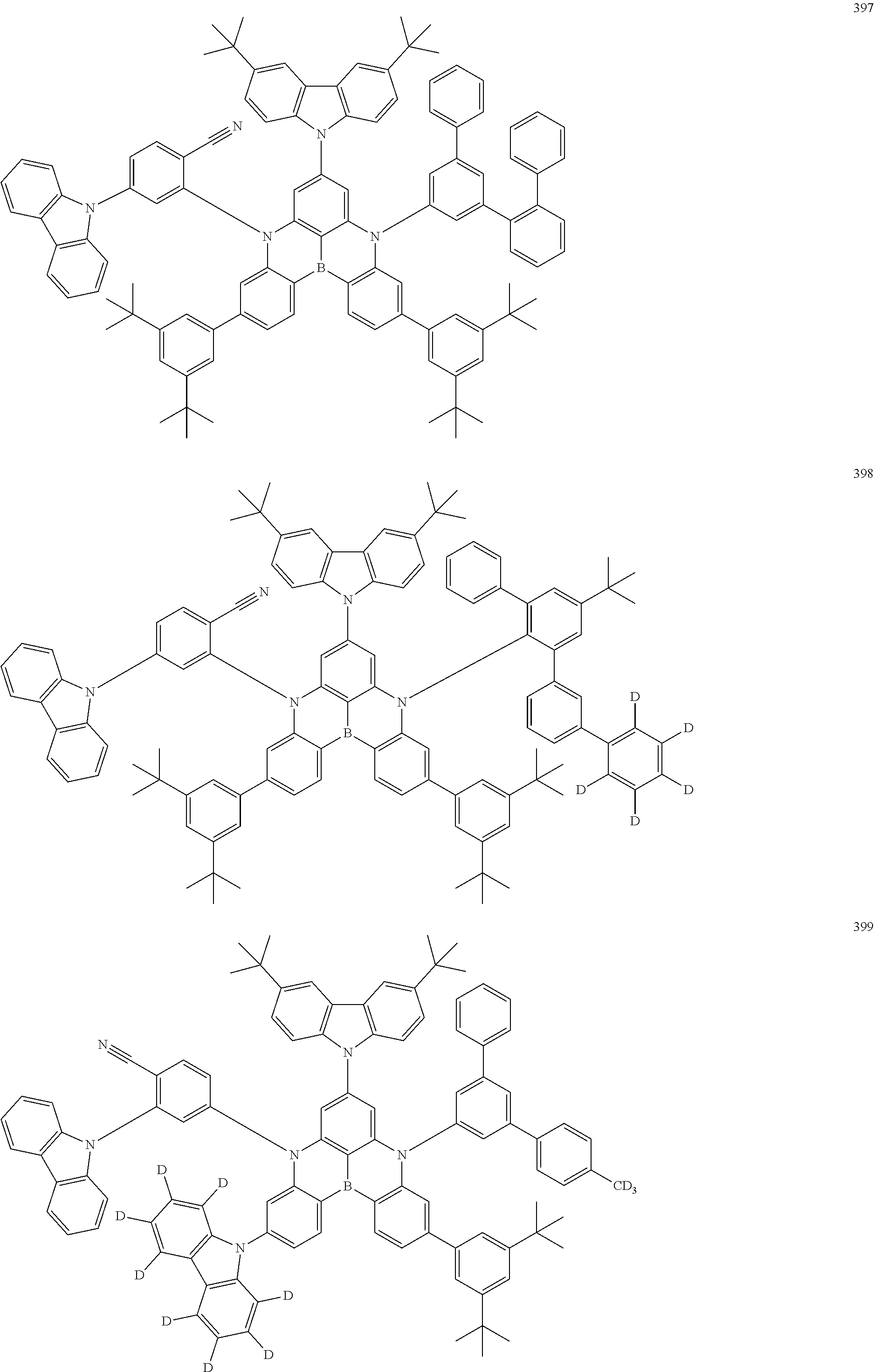

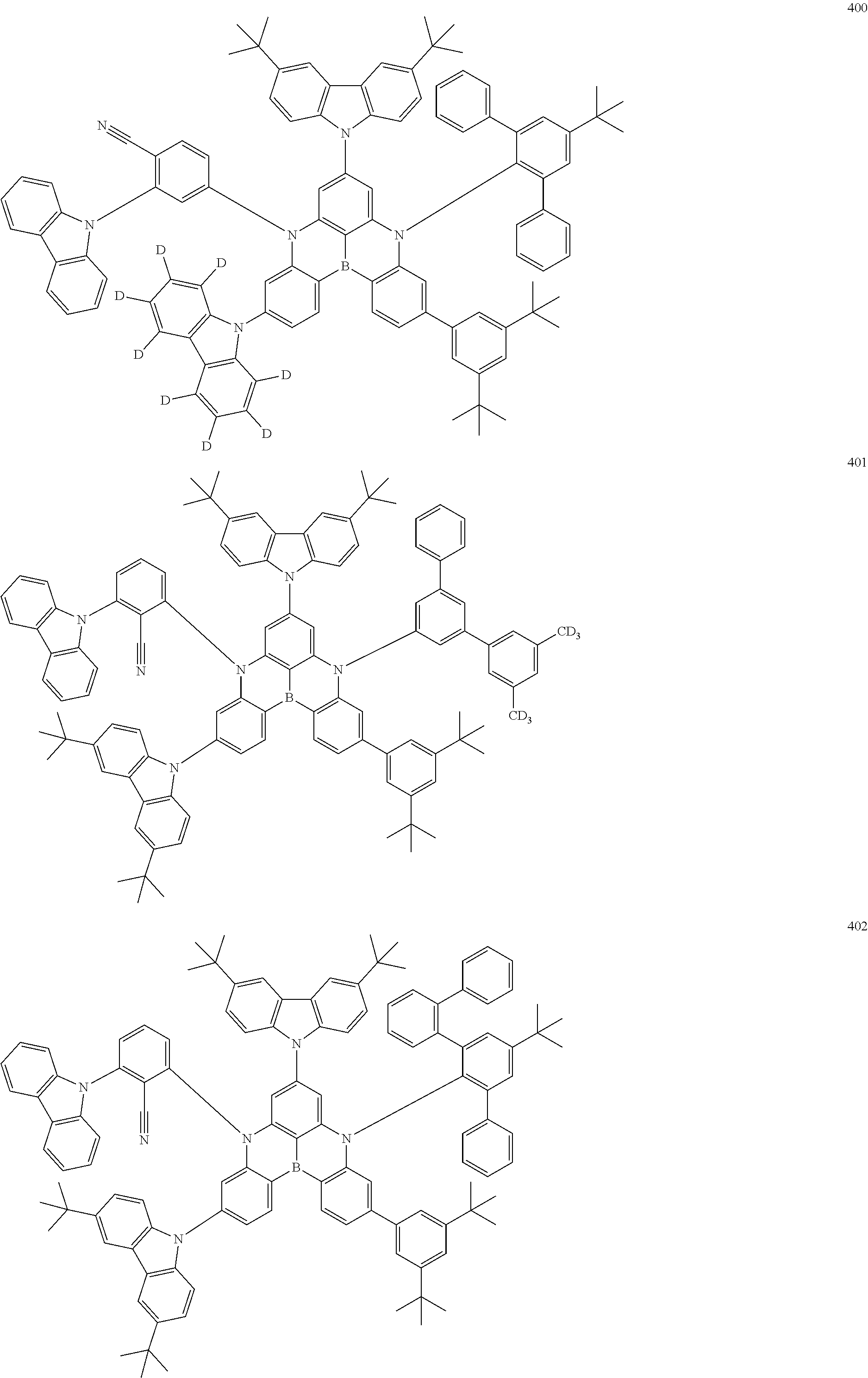

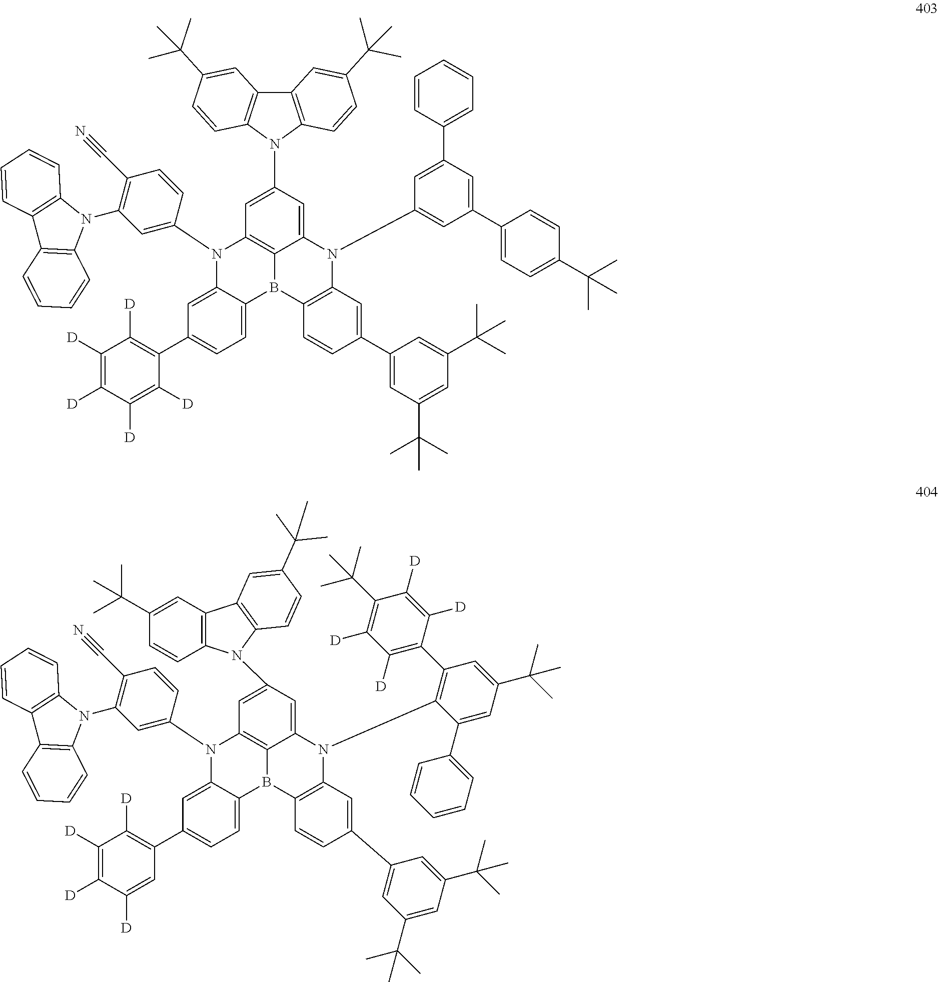 [SMILES: [2H]c1c([2H])c([2H])c(-c2ccc3c(c2)N(c2ccc(C#N)c(-n4c5ccccc5c5ccccc54)c2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2cc(-c3ccccc3)cc(-c3ccc(C(C)(C)C)cc3)c2)c([2H])c1[2H] ; [2H]c1cc(-c2ccc3c(c2)N(c2ccc(C#N)c(-n4c5ccccc5c5ccccc54)c2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2c(-c3ccccc3)cc(C(C)(C)C)cc2-c2c([2H])c([2H])c(C(C)(C)C)c([2H])c2[2H])c([2H])c([2H])c1[2H]]

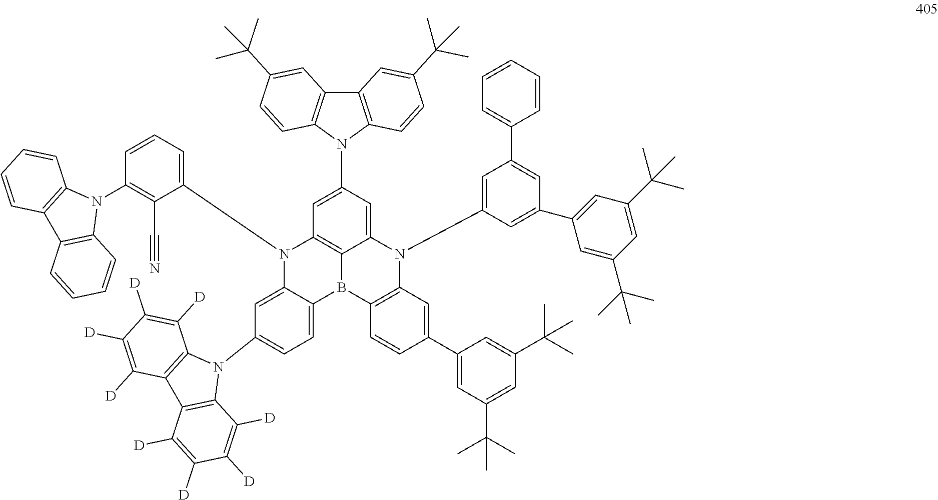 [SMILES: [2H]c1c([2H])c([2H])c2c(c1[2H])c1c([2H])c([2H])c([2H])c([2H])c1n2-c1ccc2c(c1)N(c1cccc(-n3c4ccccc4c4ccccc43)c1C#N)c1cc(-n3c4ccc(C(C)(C)C)cc4c4cc(C(C)(C)C)ccc43)cc3c1B2c1ccc(-c2cc(C(C)(C)C)cc(C(C)(C)C)c2)cc1N3c1cc(-c2ccccc2)cc(-c2cc(C(C)(C)C)cc(C(C)(C)C)c2)c1]

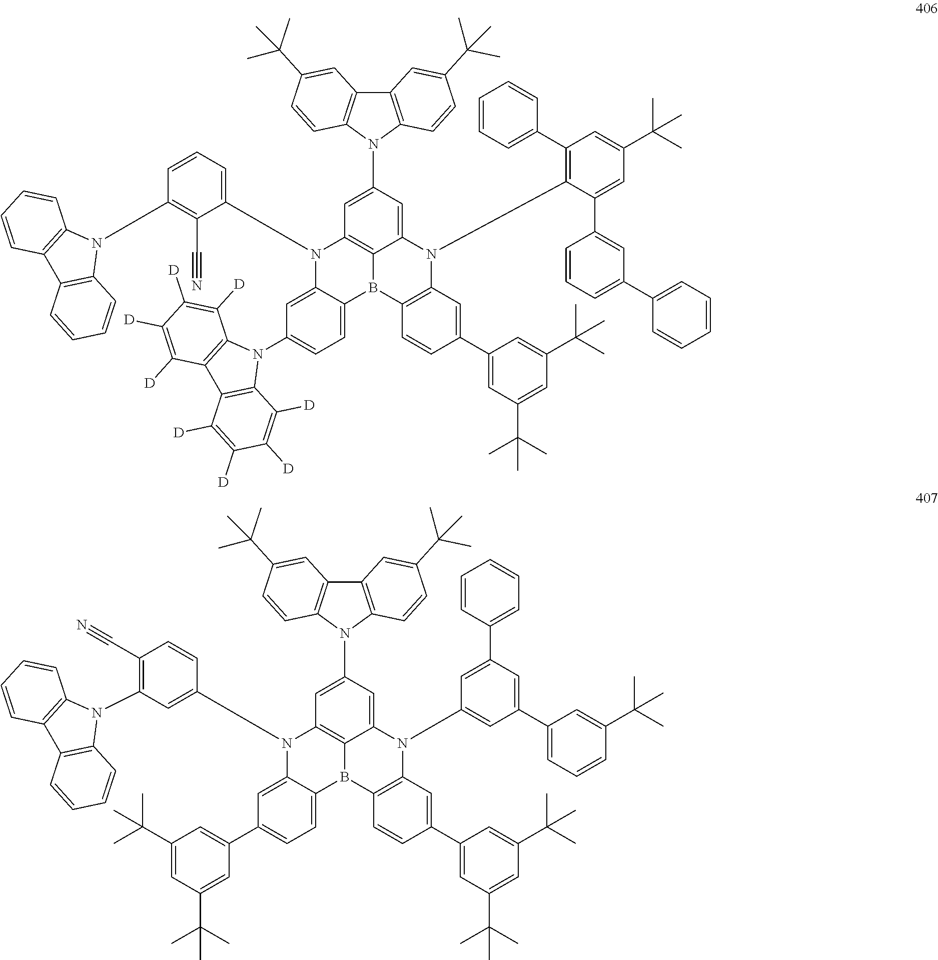

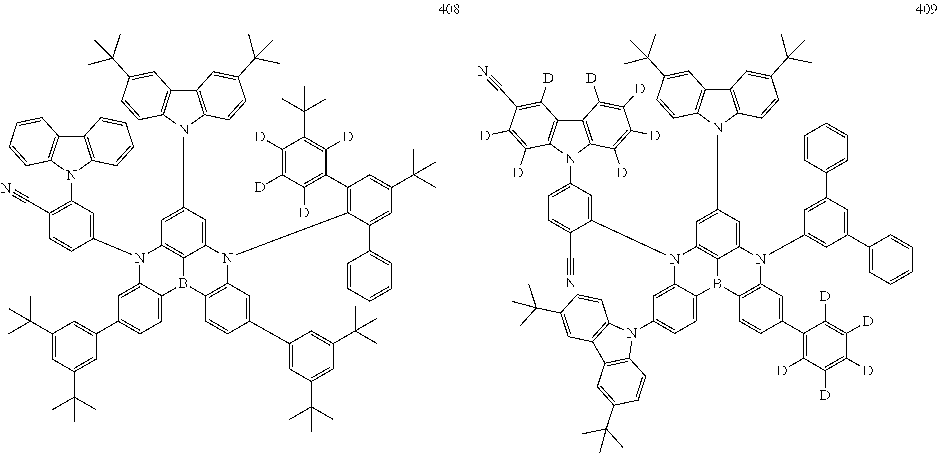

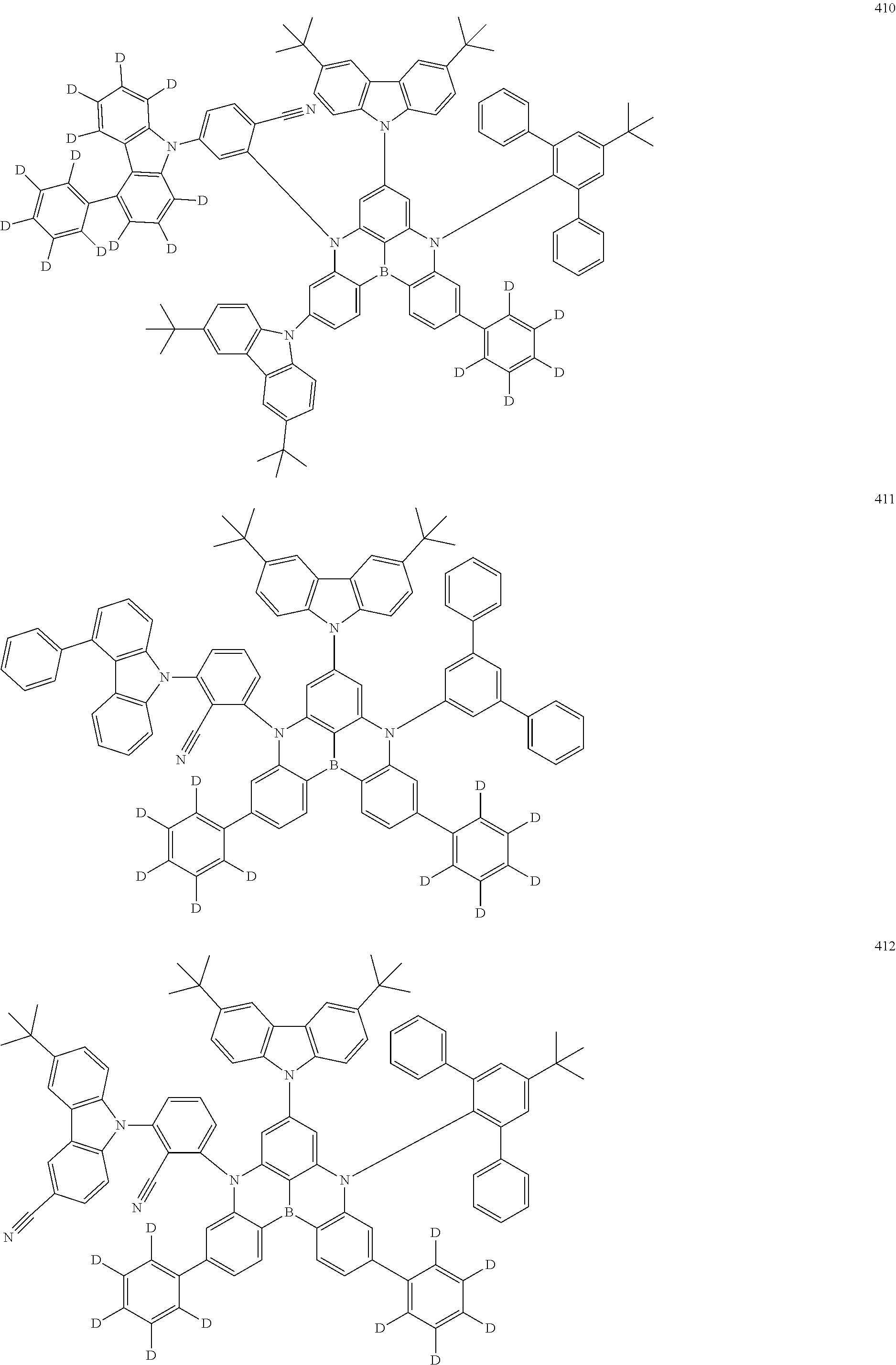

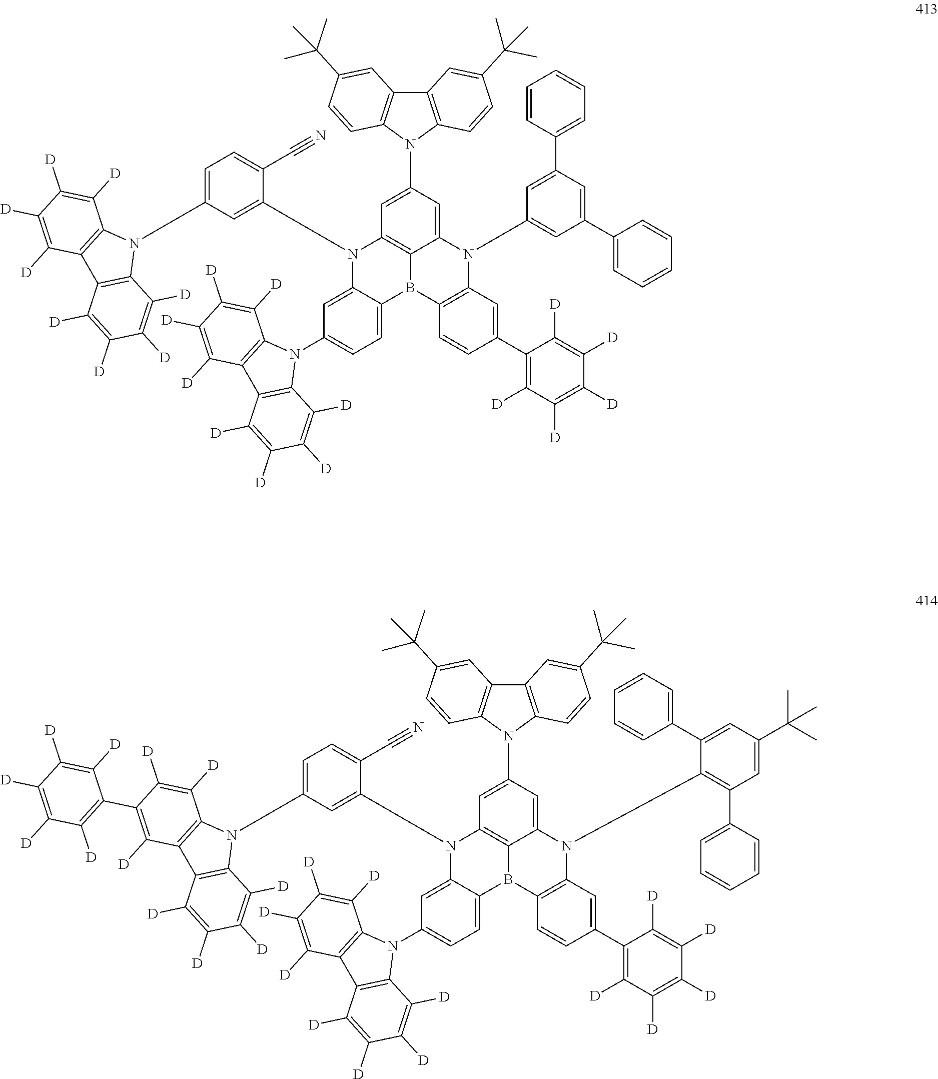

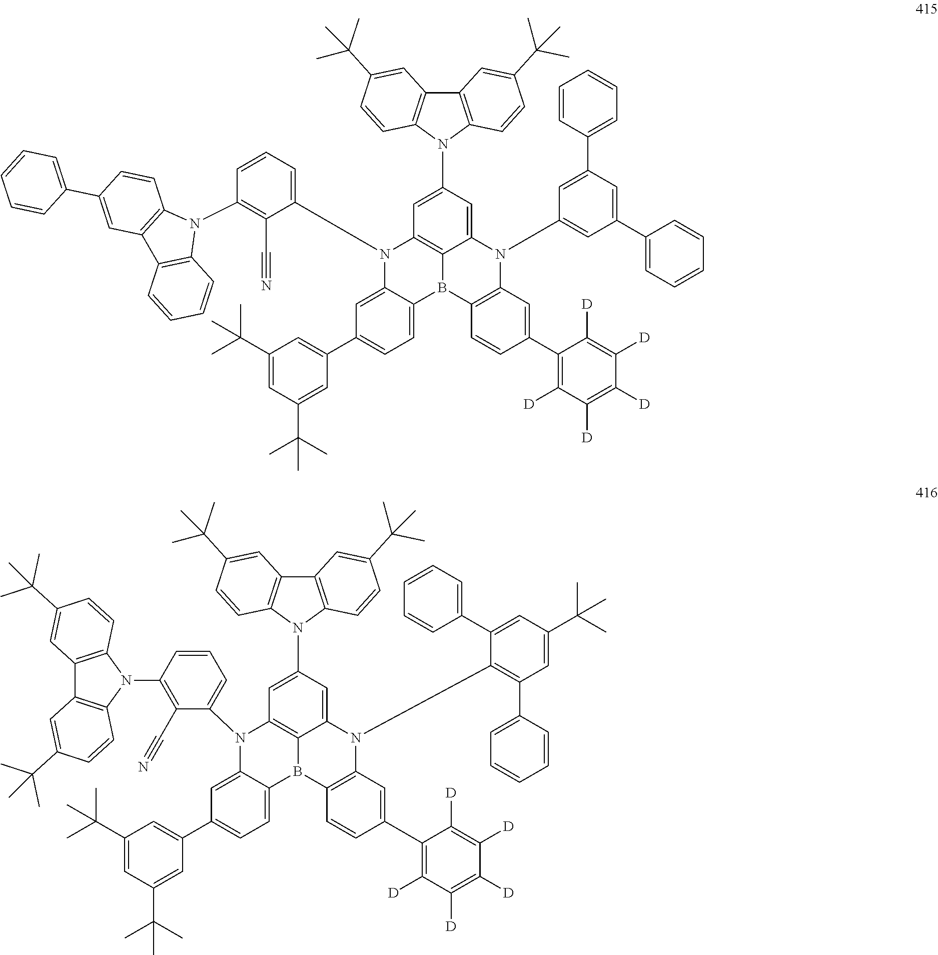 [SMILES: [2H]c1c([2H])c([2H])c(-c2ccc3c(c2)N(c2cc(-c4ccccc4)cc(-c4ccccc4)c2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2cccc(-n3c4ccccc4c4cc(-c5ccccc5)ccc43)c2C#N)c([2H])c1[2H] ; [2H]c1c([2H])c([2H])c(-c2ccc3c(c2)N(c2c(-c4ccccc4)cc(C(C)(C)C)cc2-c2ccccc2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2cccc(-n3c4ccc(C(C)(C)C)cc4c4cc(C(C)(C)C)ccc43)c2C#N)c([2H])c1[2H]]

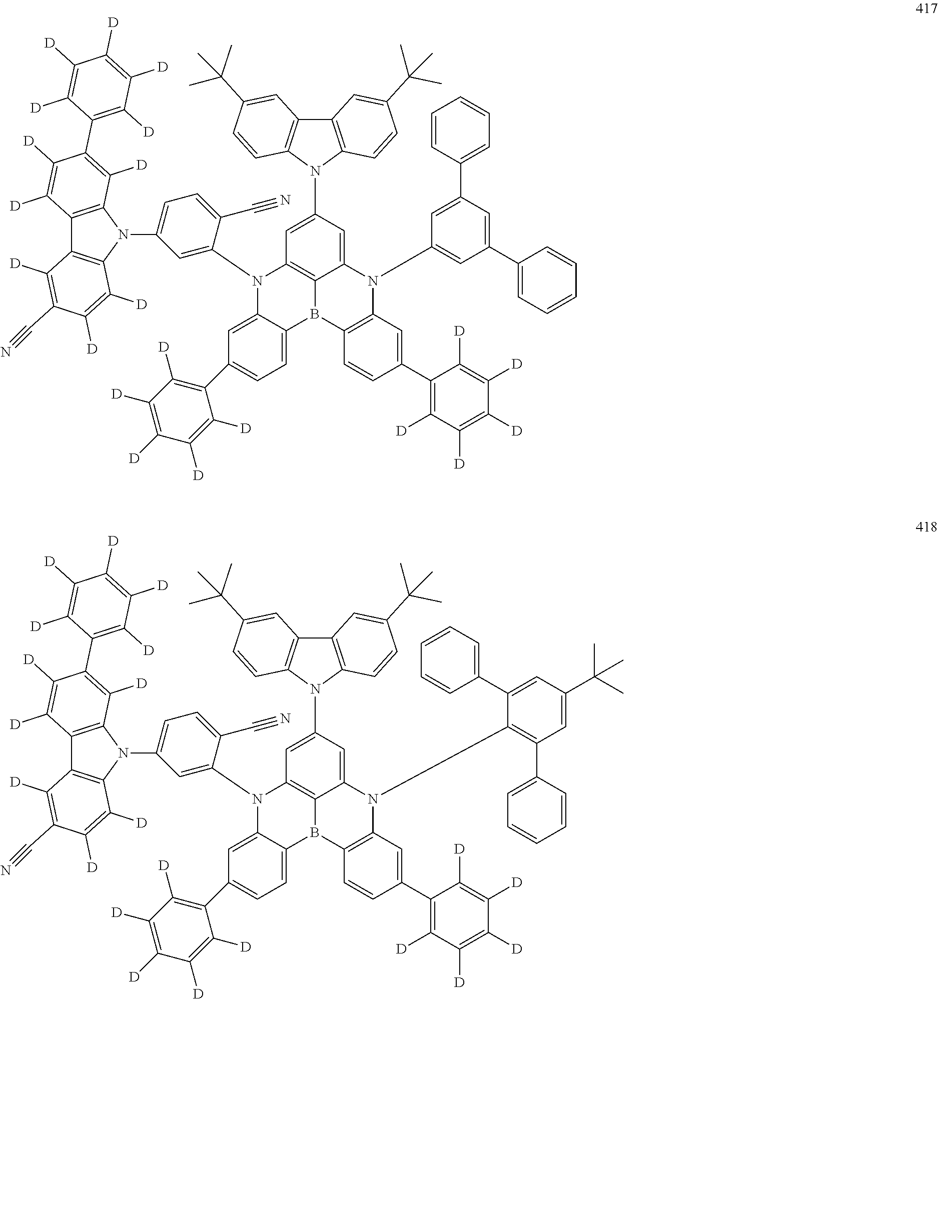

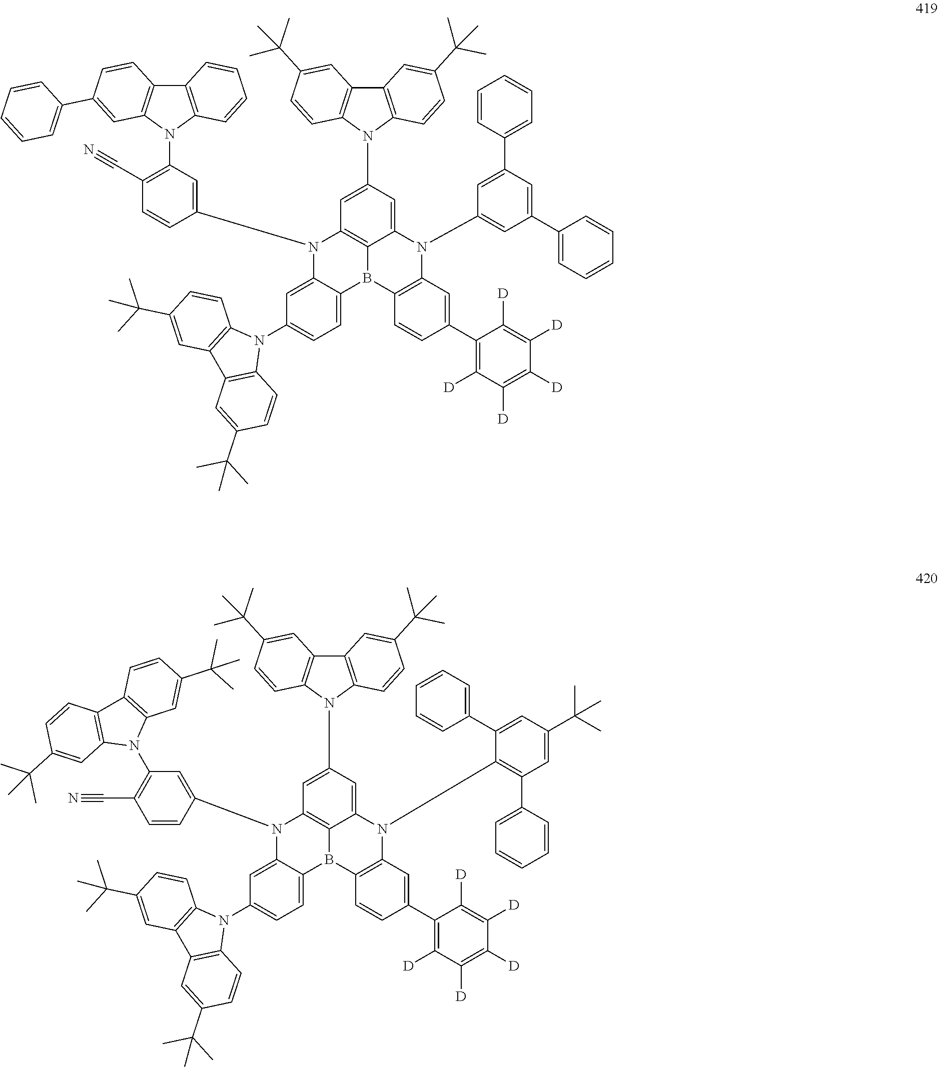 [SMILES: [2H]c1c([2H])c([2H])c(-c2ccc3c(c2)N(c2cc(-c4ccccc4)cc(-c4ccccc4)c2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2ccc(C#N)c(-n3c4ccccc4c4ccc(-c5ccccc5)cc43)c2)c([2H])c1[2H] ; [2H]c1c([2H])c([2H])c(-c2ccc3c(c2)N(c2c(-c4ccccc4)cc(C(C)(C)C)cc2-c2ccccc2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2ccc(C#N)c(-n3c4cc(C(C)(C)C)ccc4c4ccc(C(C)(C)C)cc43)c2)c([2H])c1[2H]]

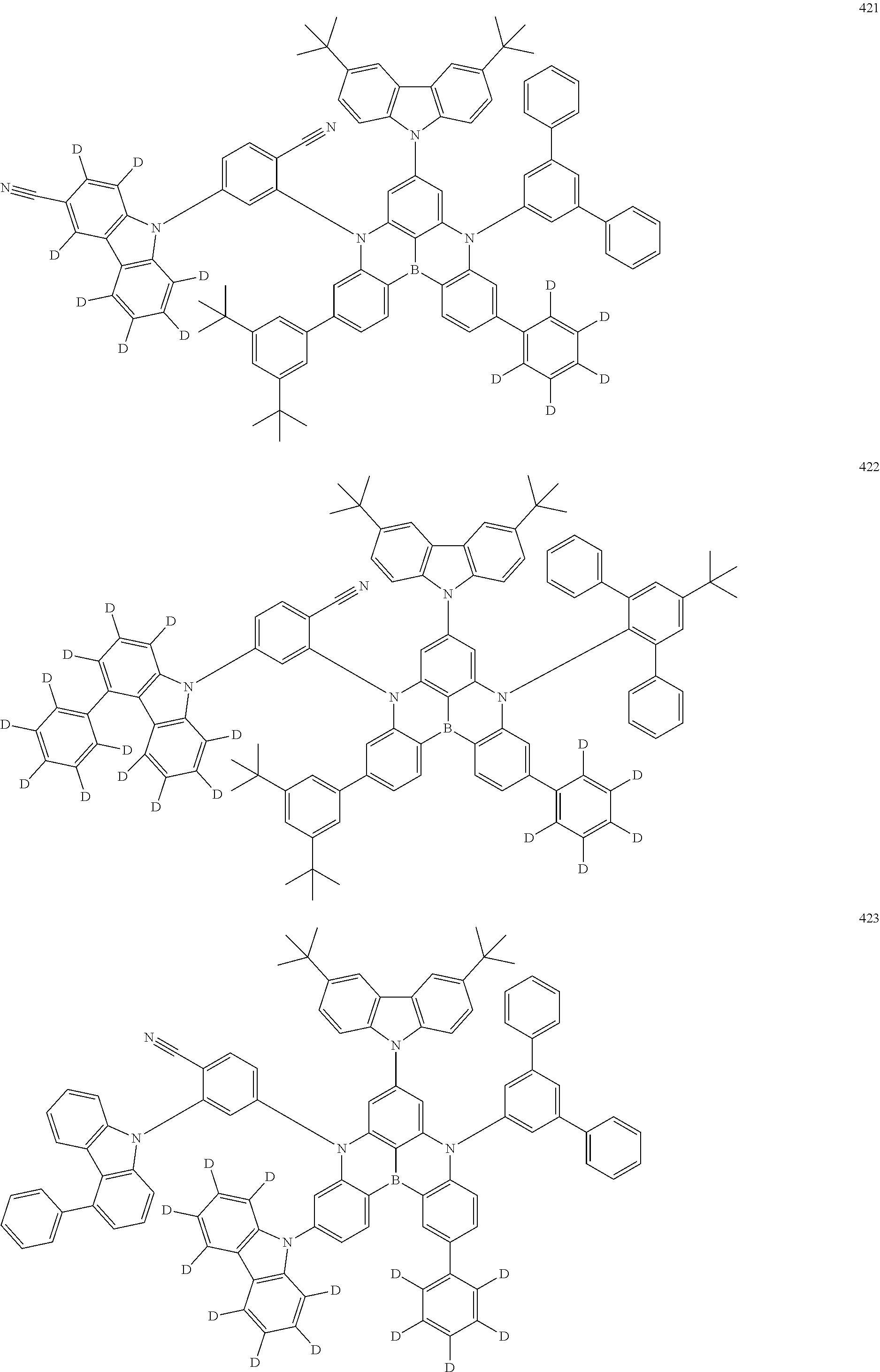

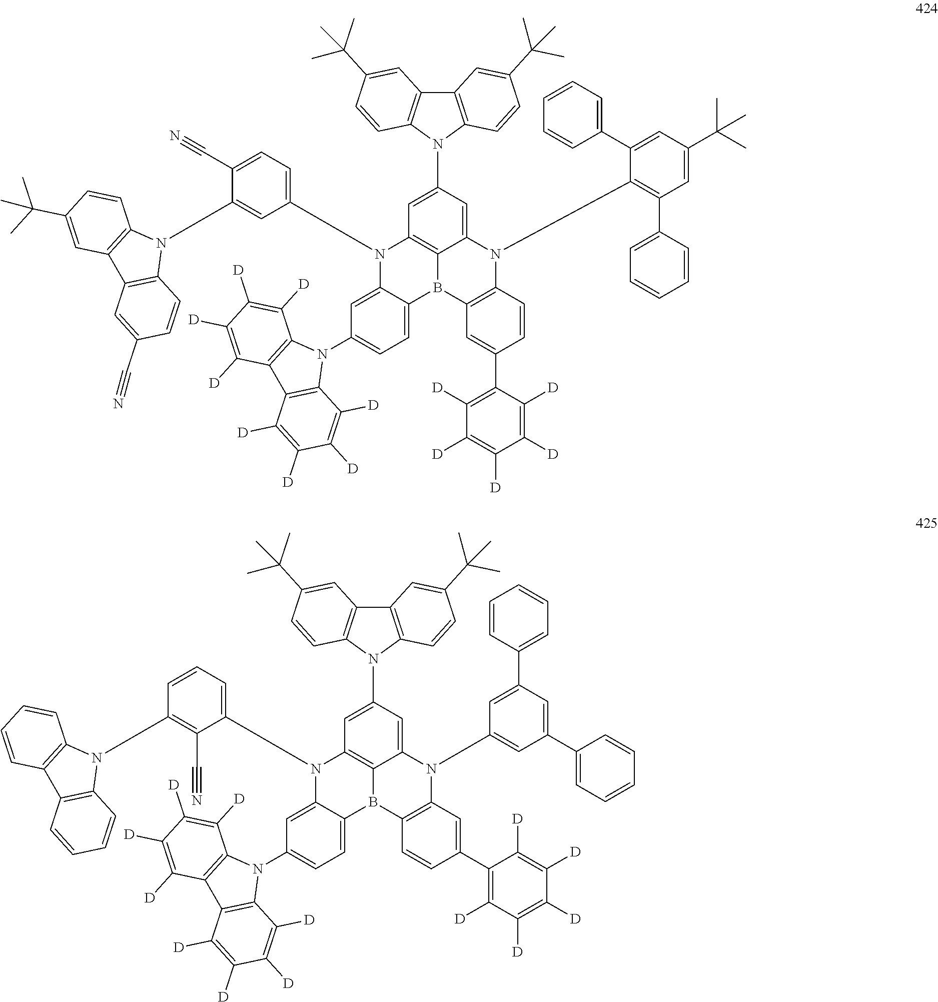

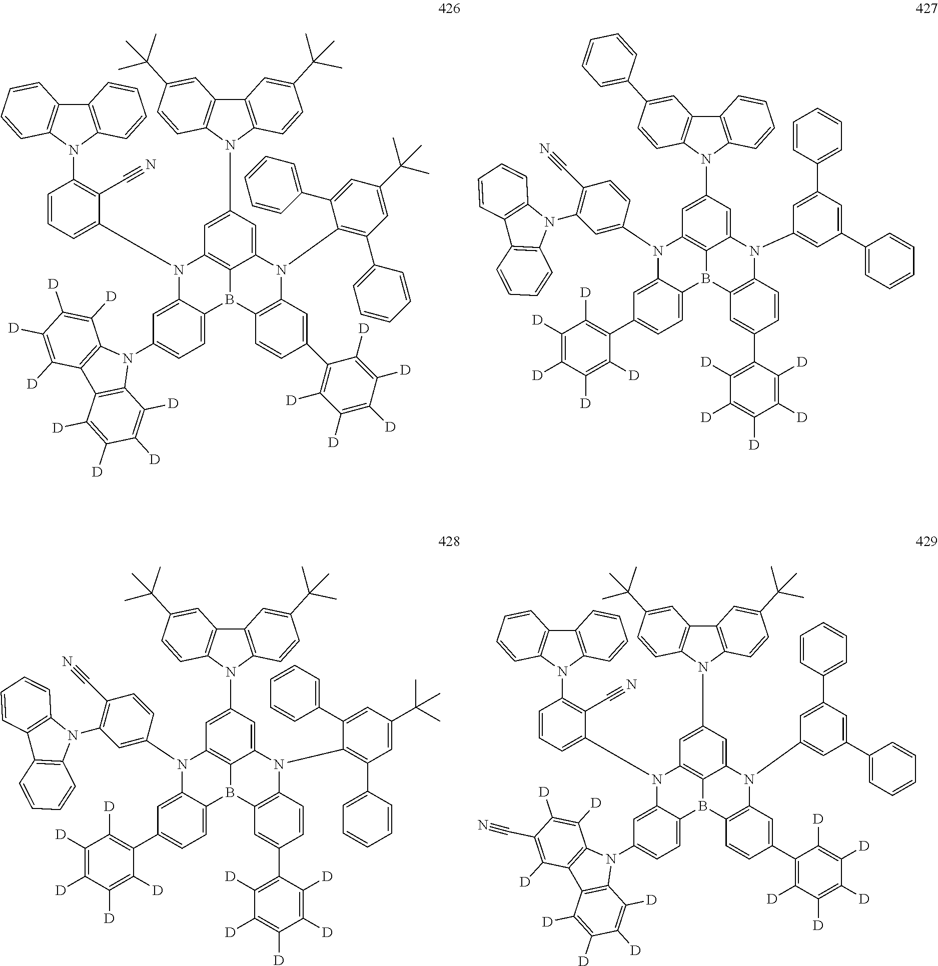

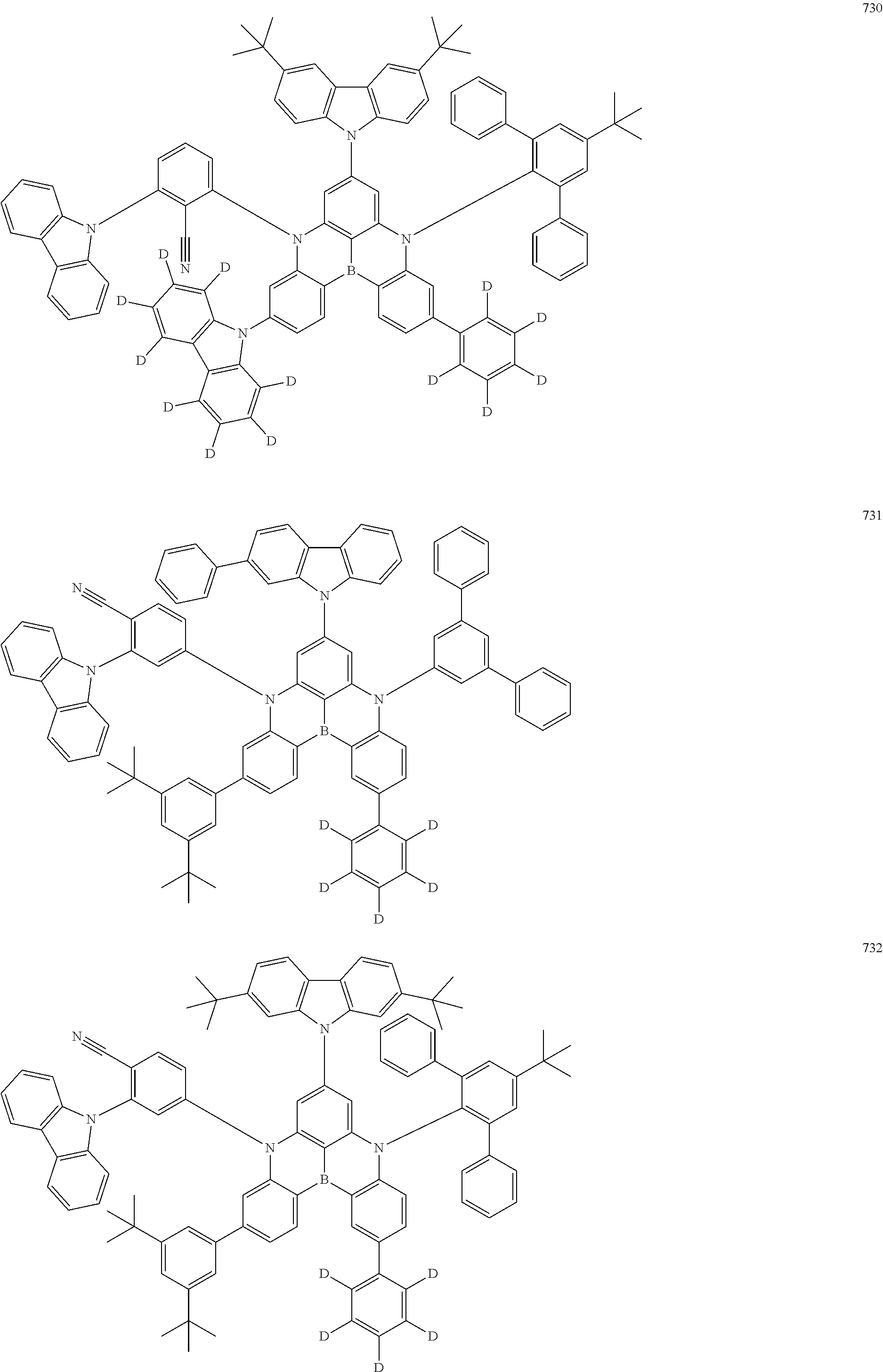

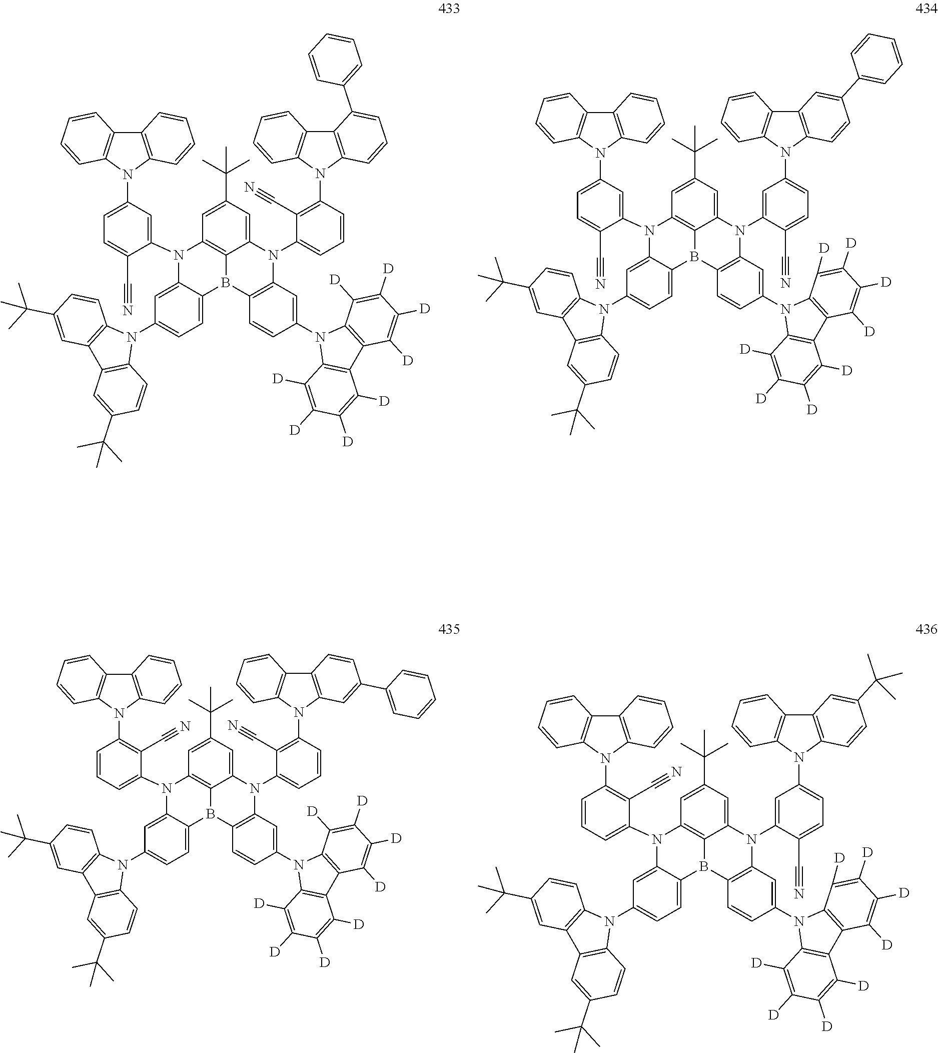

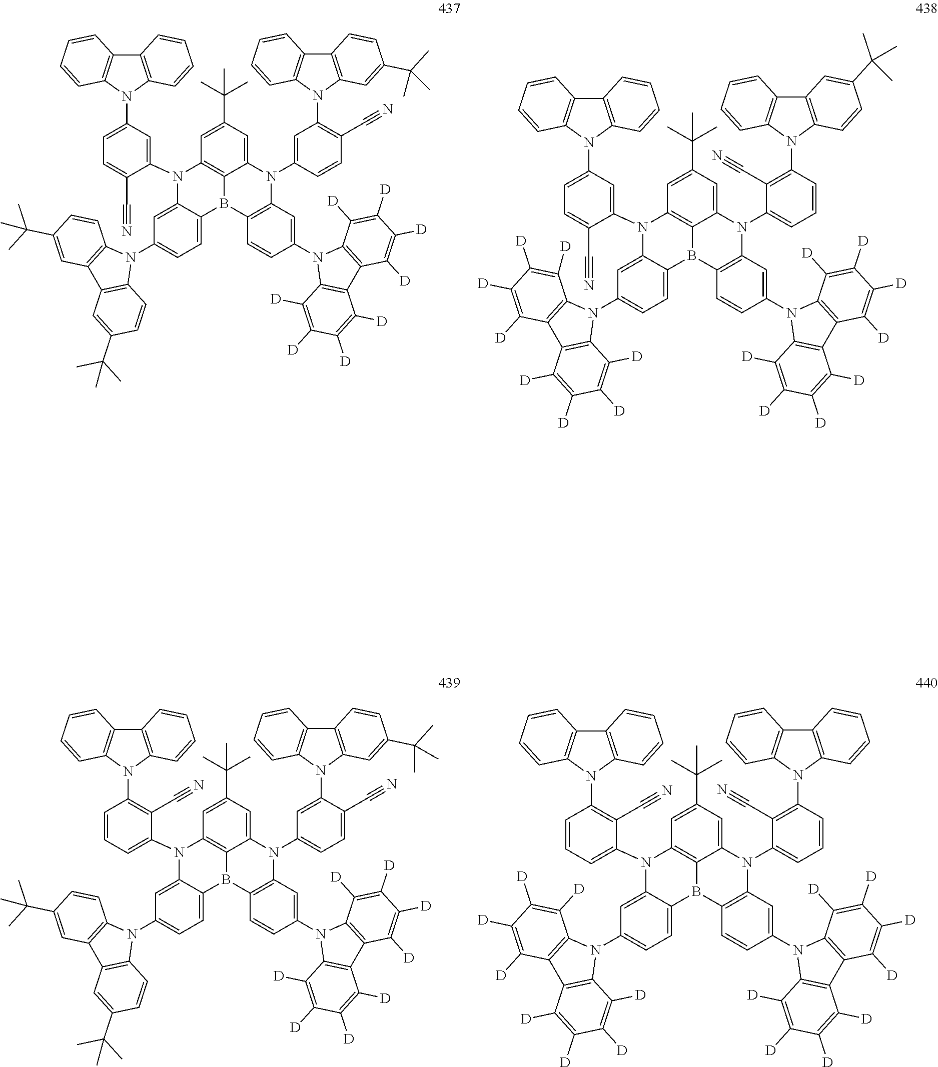

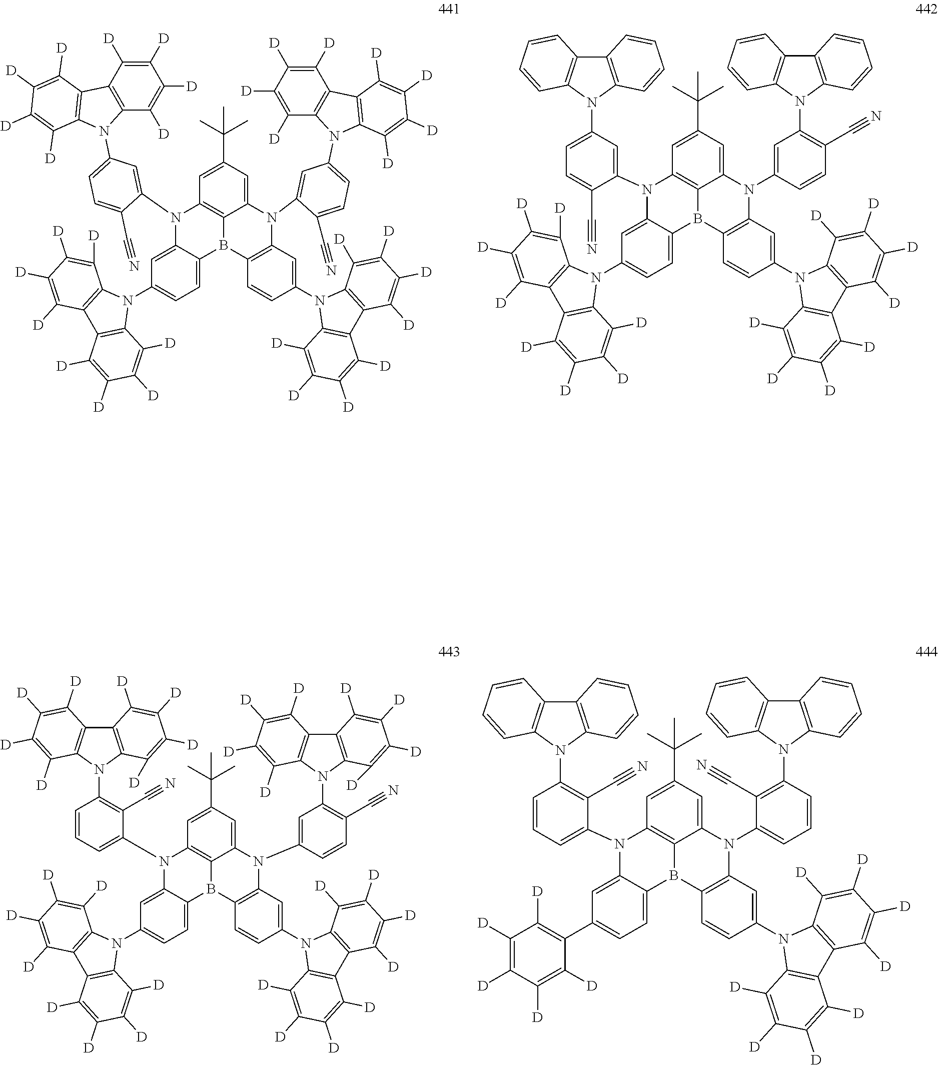

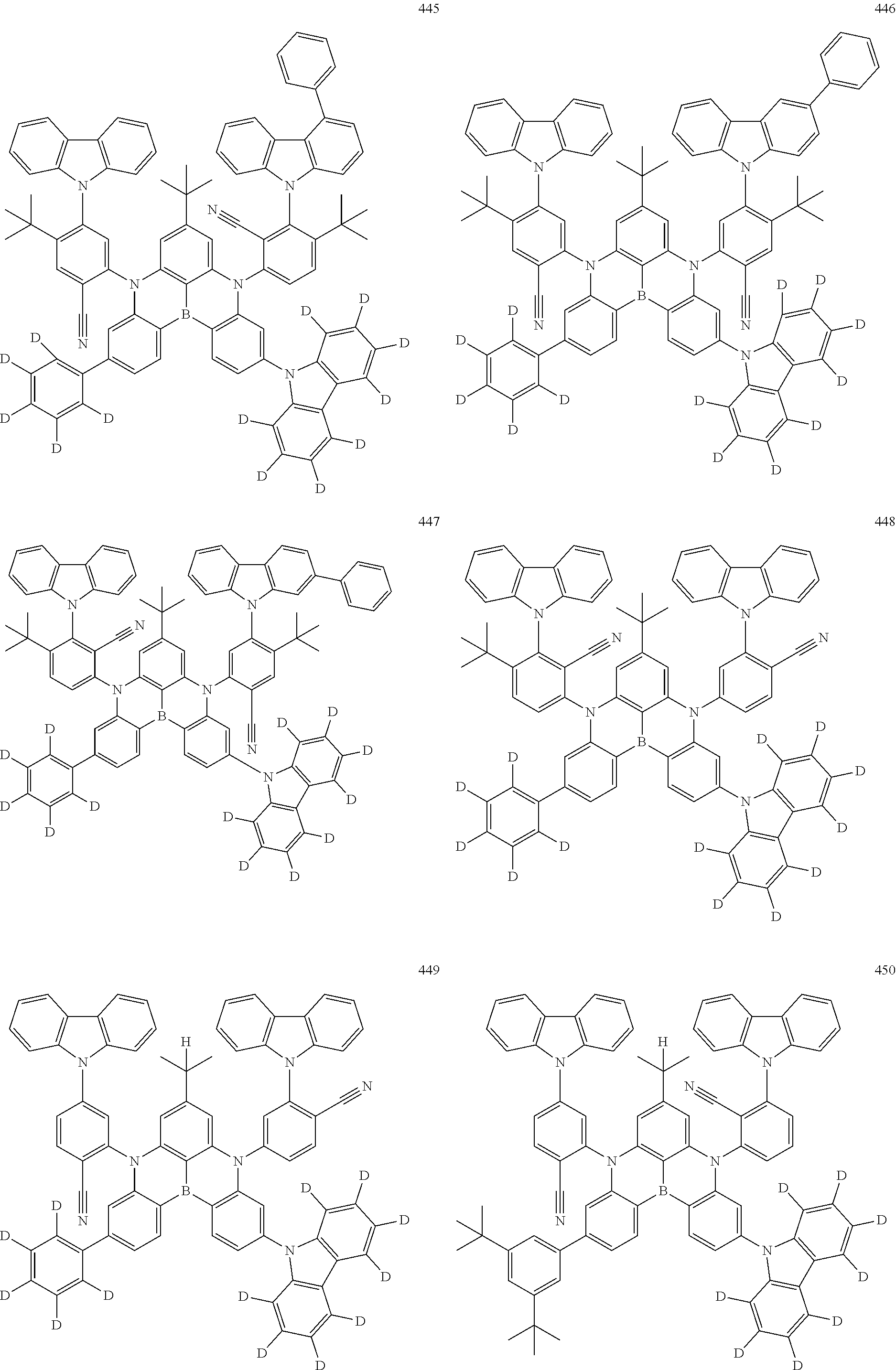

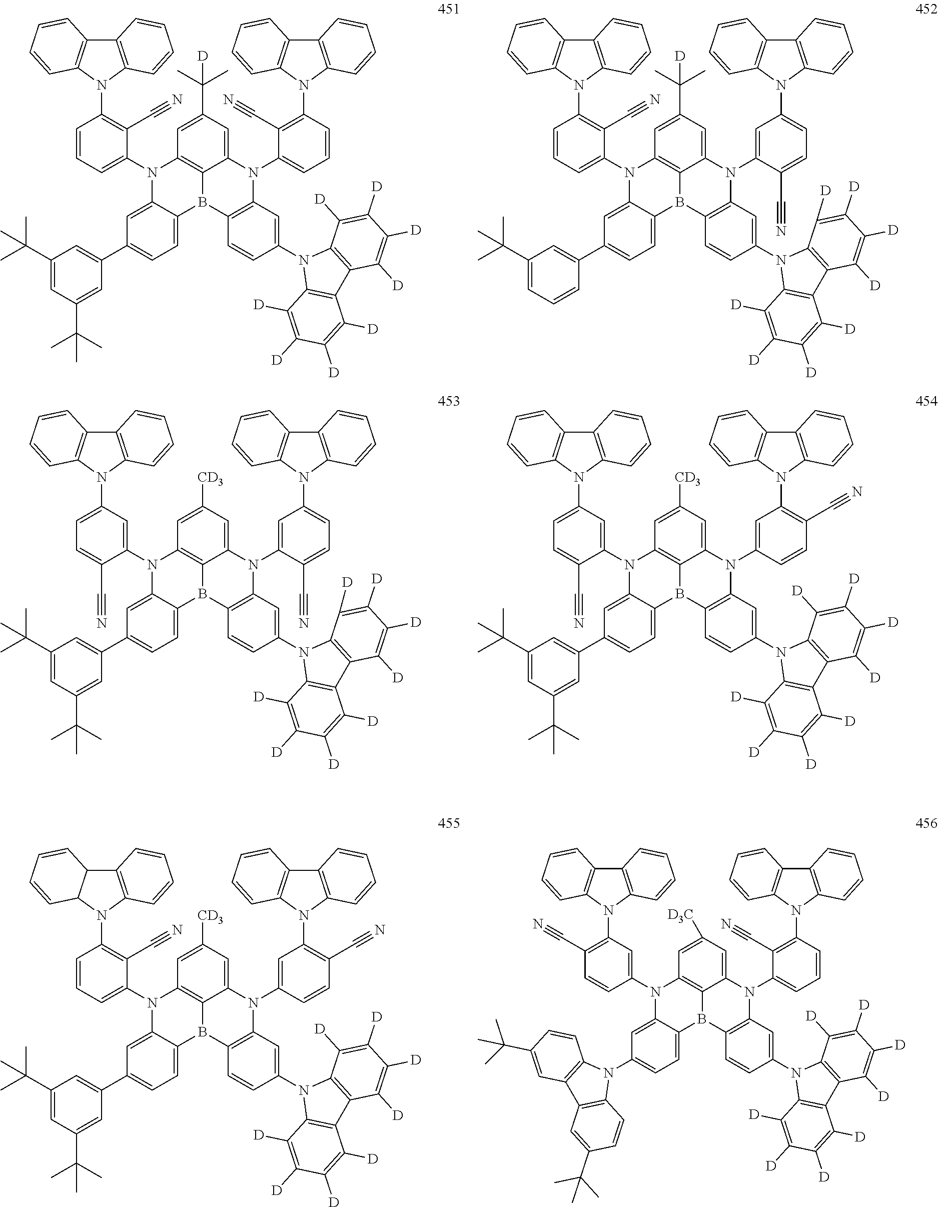

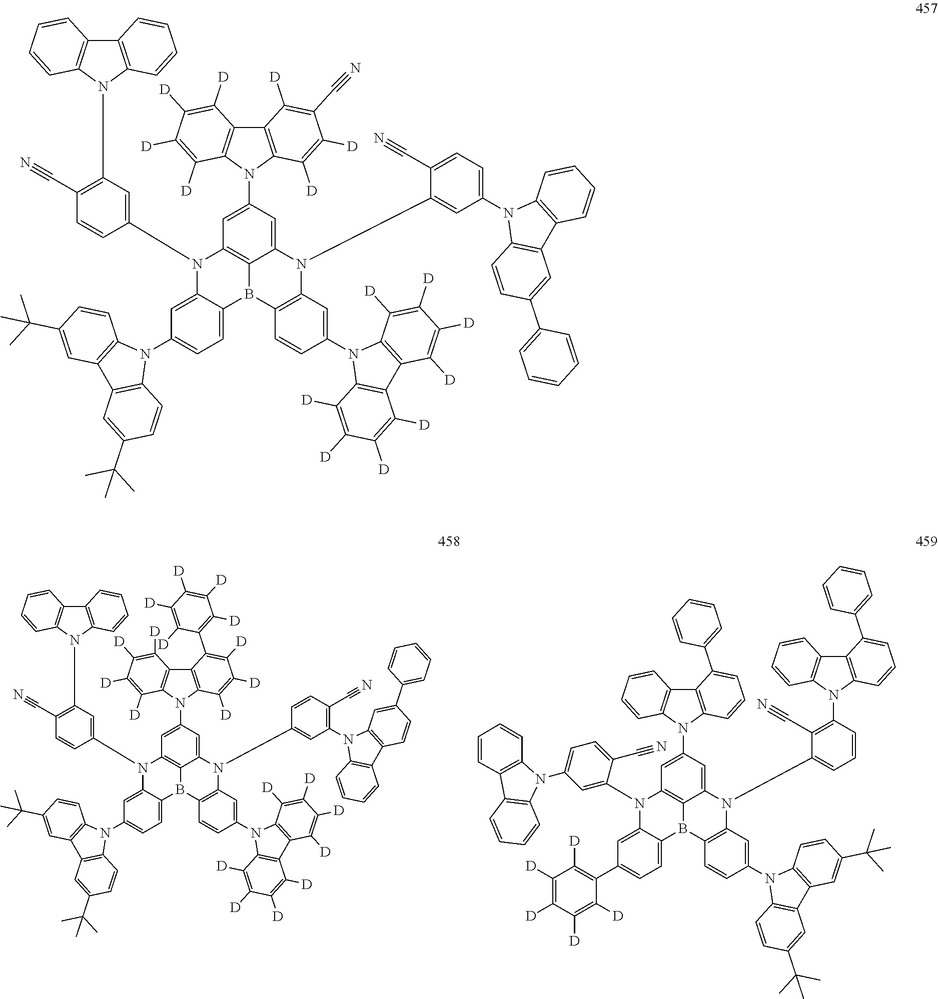

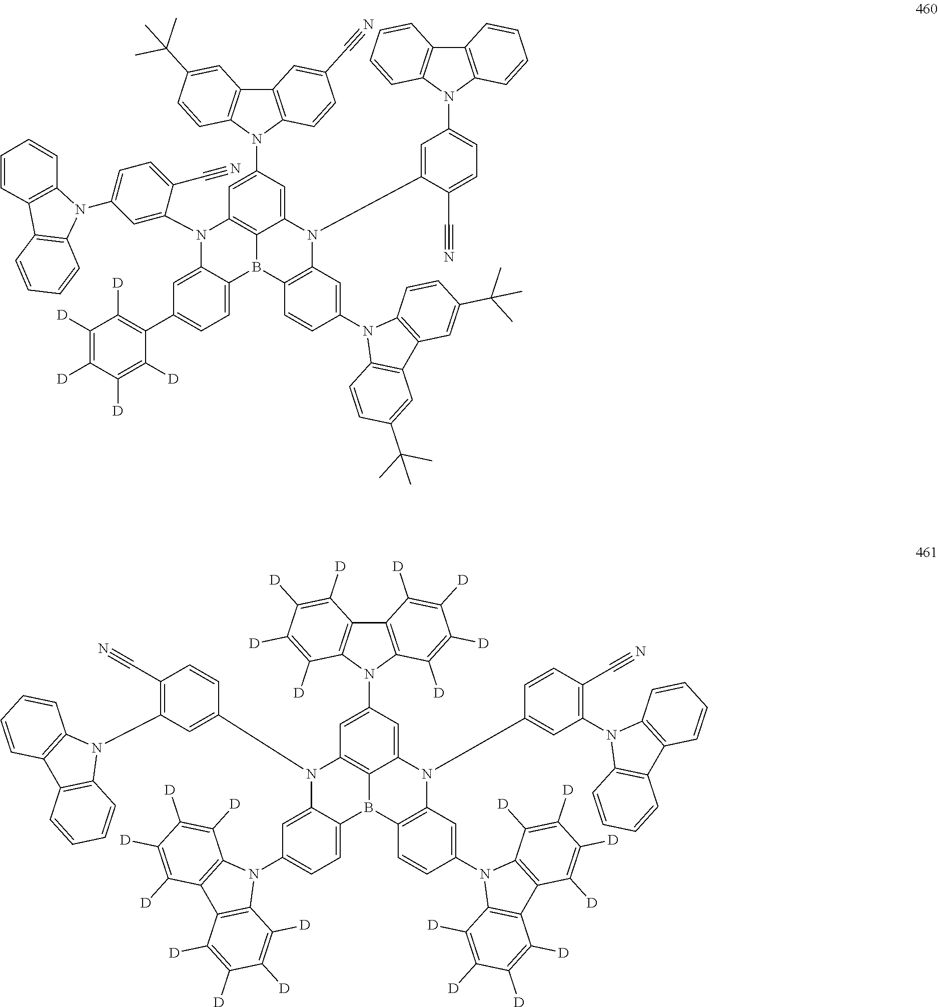

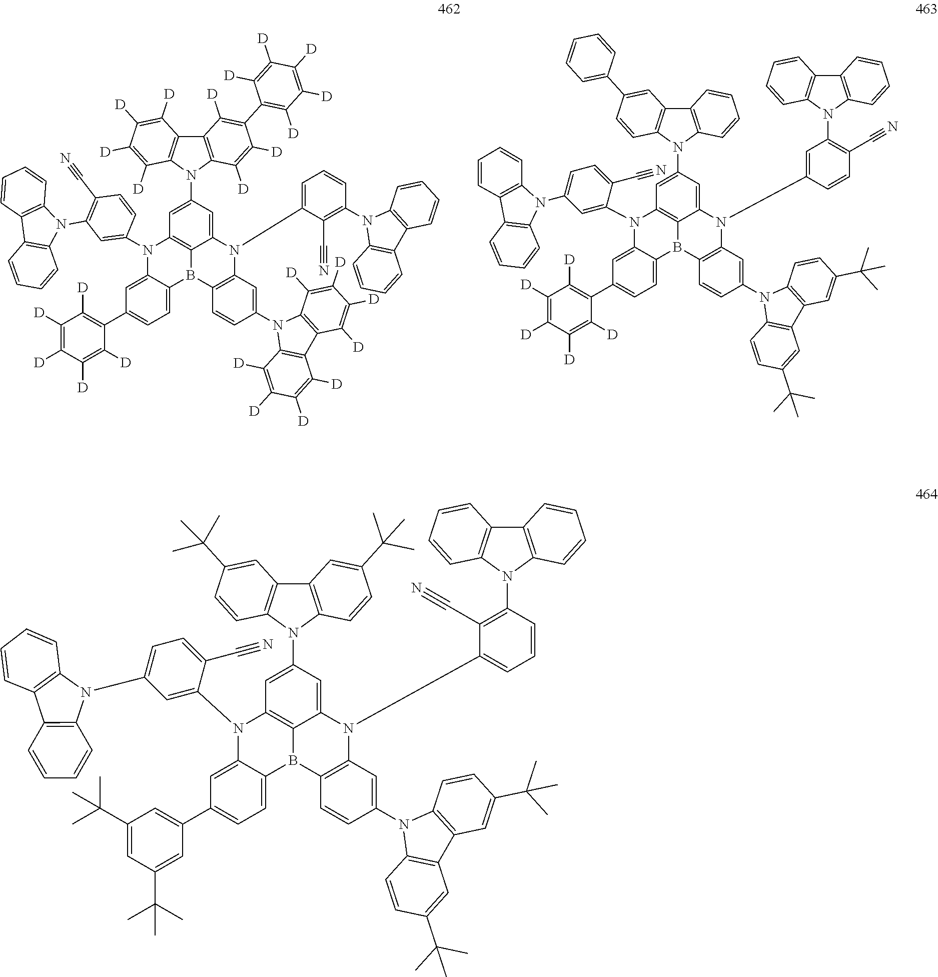

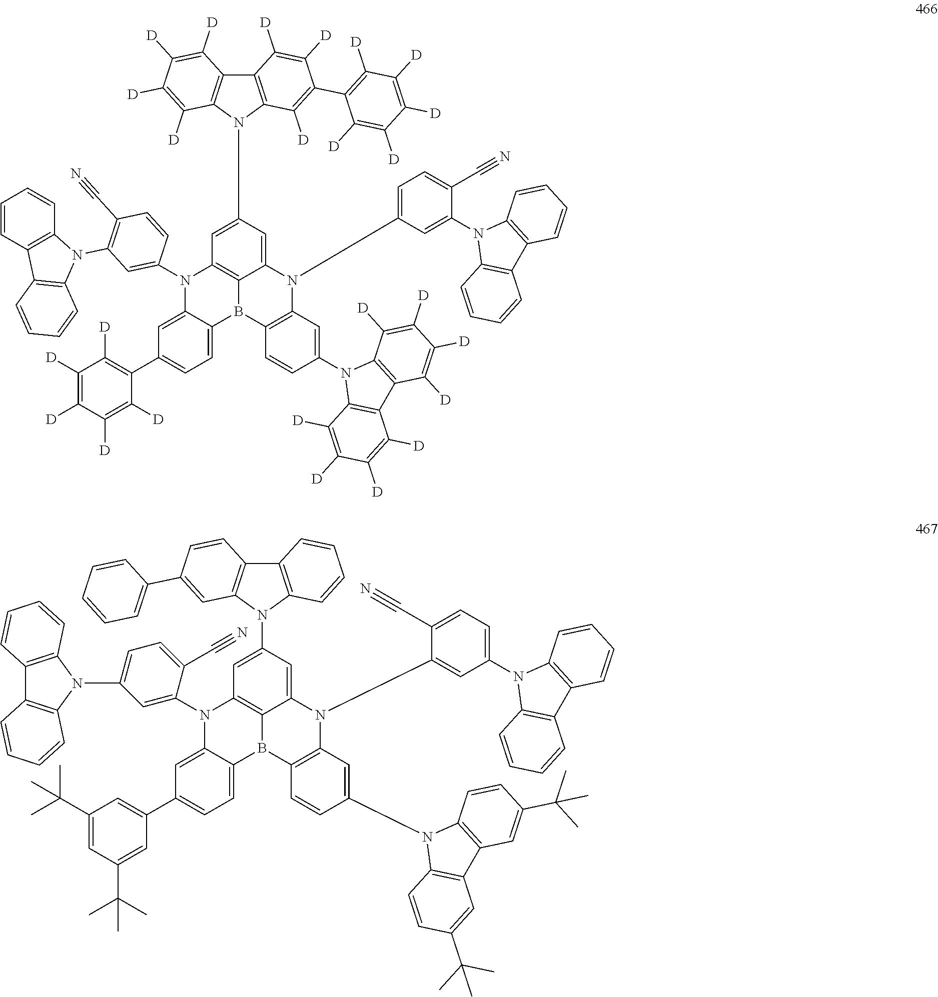

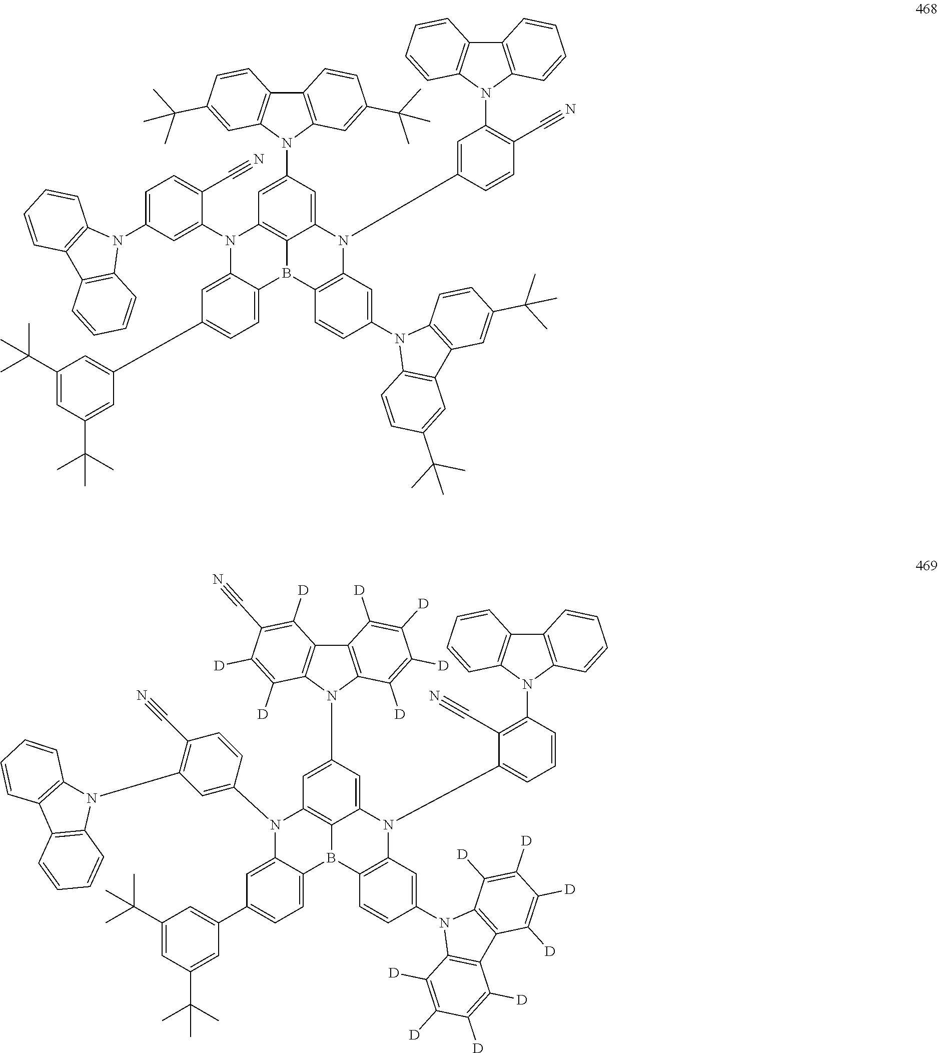 [SMILES: CC(C)(C)c1cc(-c2ccc3c(c2)N(c2cc(-n4c5ccccc5c5ccccc54)ccc2C#N)c2cc(-n4c5cc(C(C)(C)C)ccc5c5ccc(C(C)(C)C)cc54)cc4c2B3c2ccc(-n3c5ccc(C(C)(C)C)cc5c5cc(C(C)(C)C)ccc53)cc2N4c2ccc(C#N)c(-n3c4ccccc4c4ccccc43)c2)cc(C(C)(C)C)c1 ; [2H]c1c([2H])c([2H])c2c(c1[2H])c1c([2H])c([2H])c([2H])c([2H])c1n2-c1ccc2c(c1)N(c1cccc(-n3c4ccccc4c4ccccc43)c1C#N)c1cc(-n3c4c([2H])c([2H])c([2H])c([2H])c4c4c([2H])c(C#N)c([2H])c([2H])c43)cc3c1B2c1ccc(-c2cc(C(C)(C)C)cc(C(C)(C)C)c2)cc1N3c1ccc(C#N)c(-n2c3ccccc3c3ccccc32)c1]

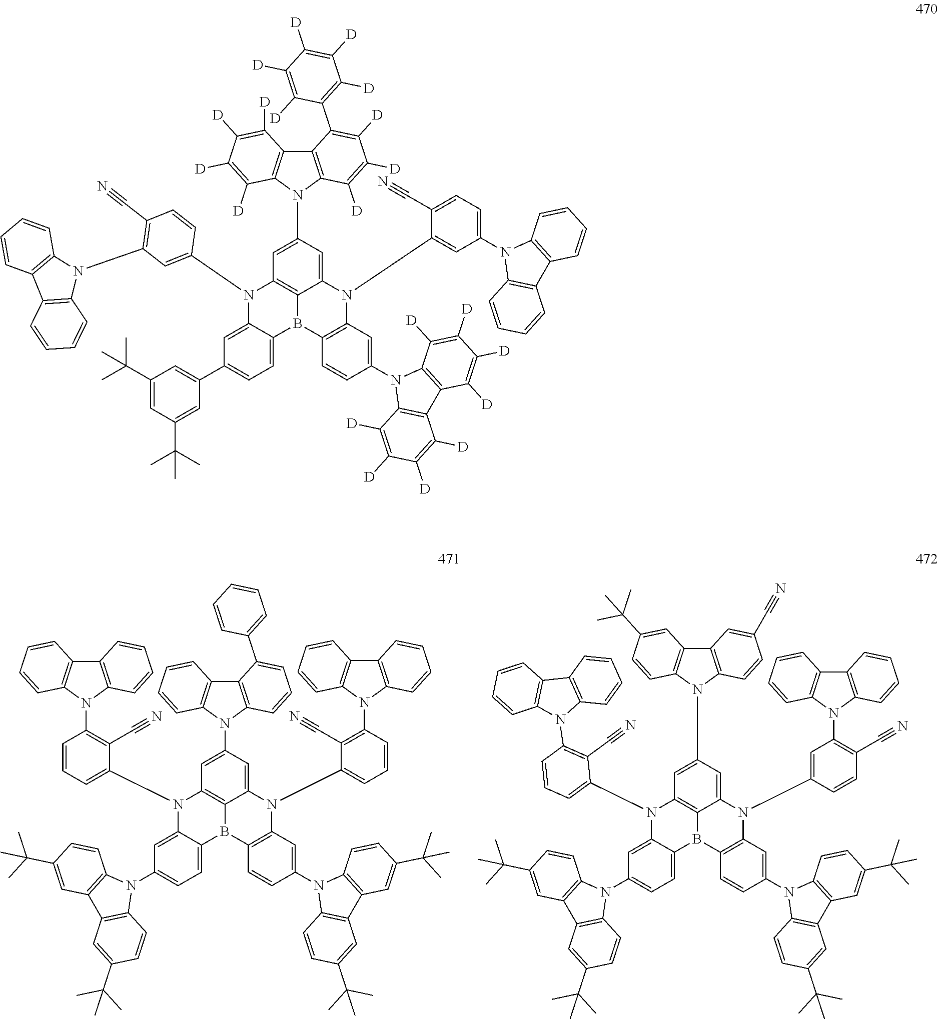

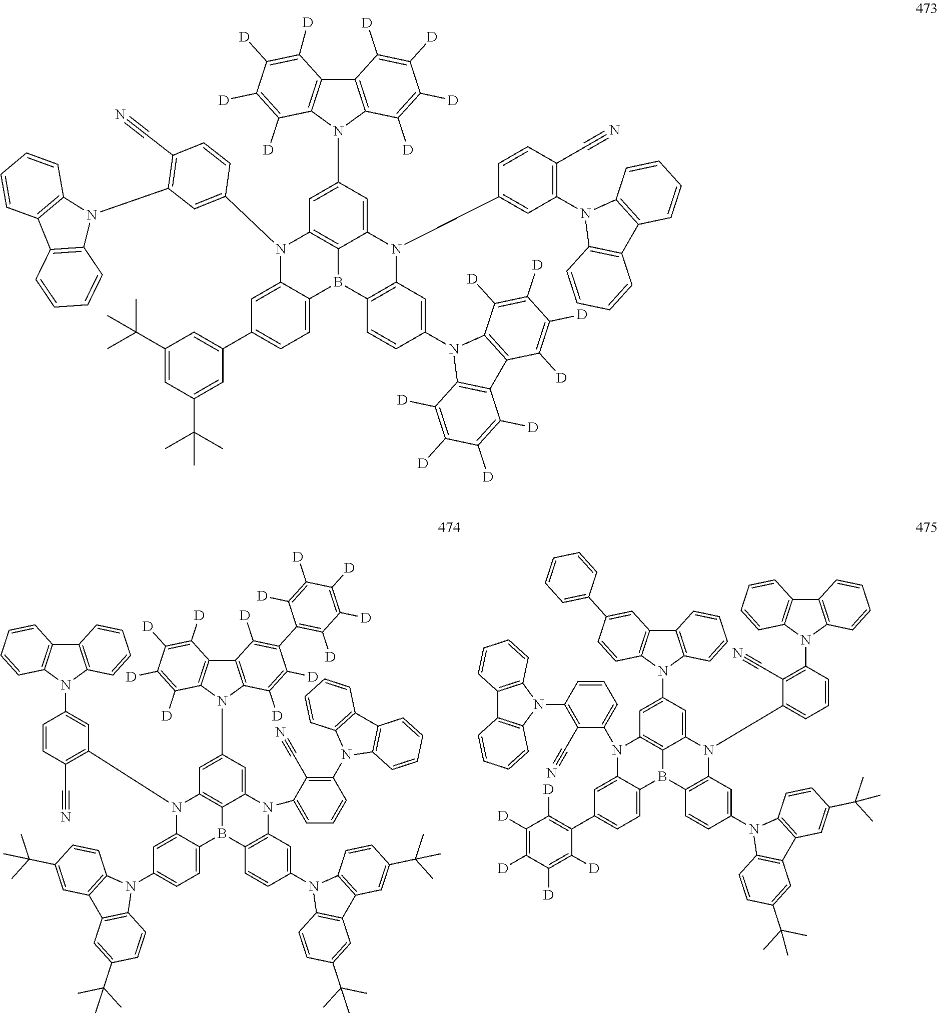

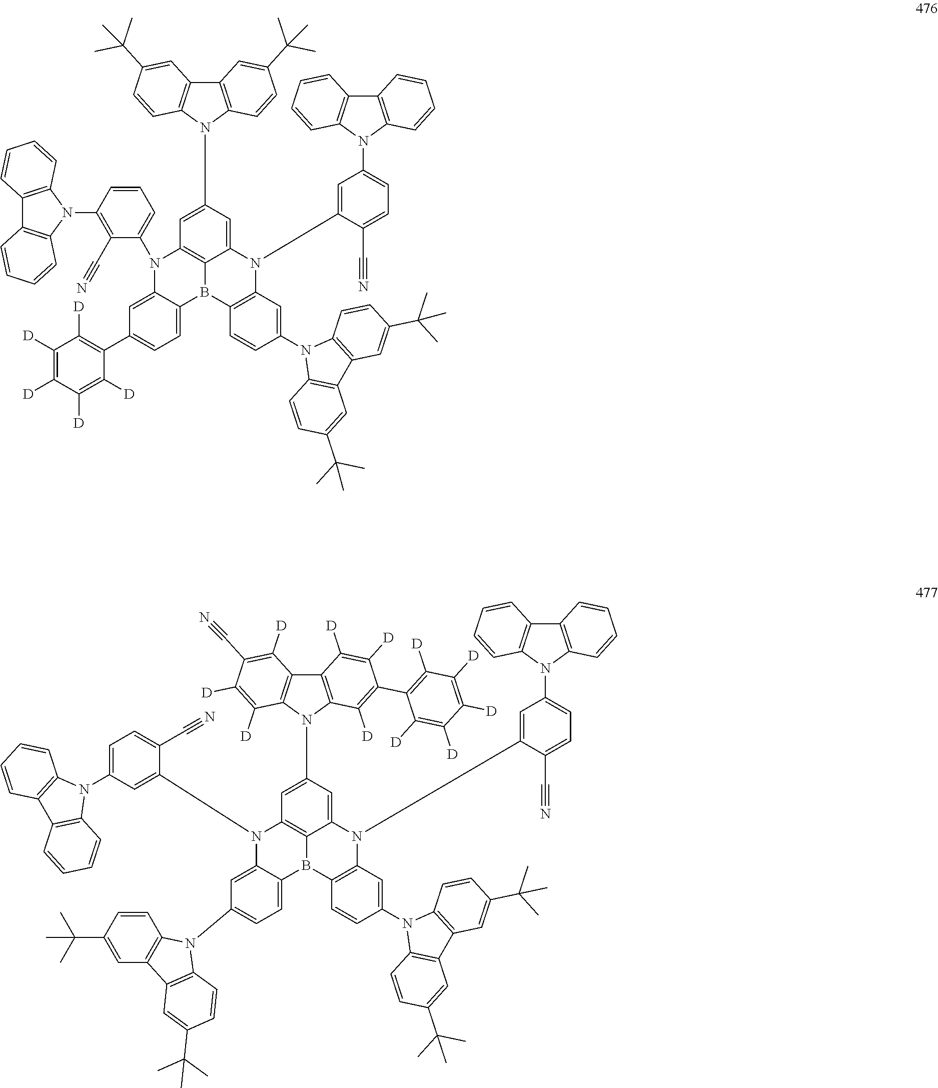

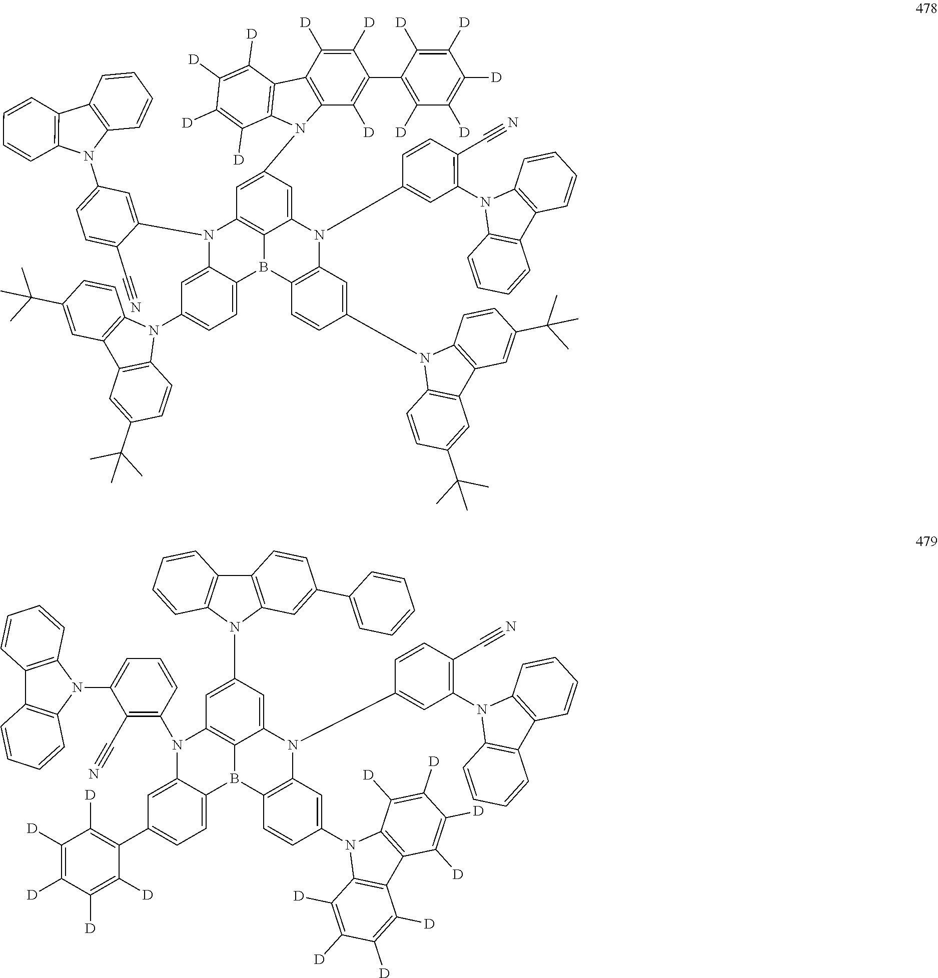

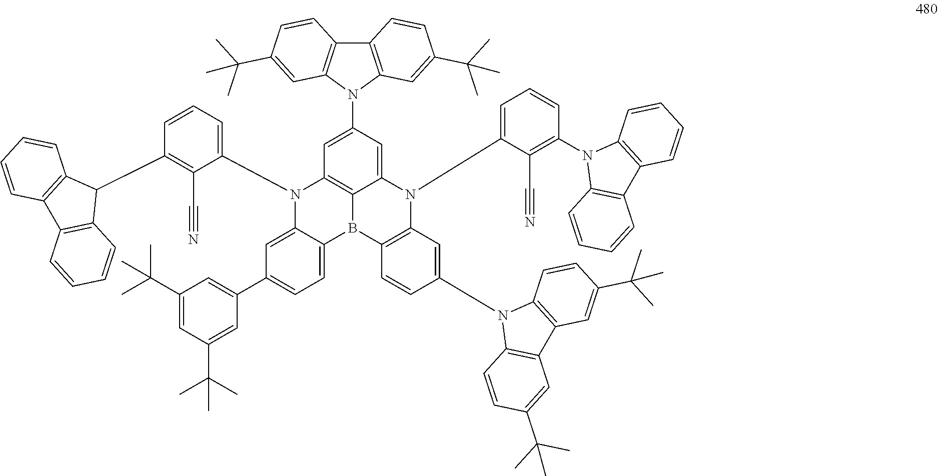 [SMILES: CC(C)(C)c1cc(-c2ccc3c(c2)N(c2cccc(C4c5ccccc5-c5ccccc54)c2C#N)c2cc(-n4c5cc(C(C)(C)C)ccc5c5ccc(C(C)(C)C)cc54)cc4c2B3c2ccc(-n3c5ccc(C(C)(C)C)cc5c5cc(C(C)(C)C)ccc53)cc2N4c2cccc(-n3c4ccccc4c4ccccc43)c2C#N)cc(C(C)(C)C)c1]

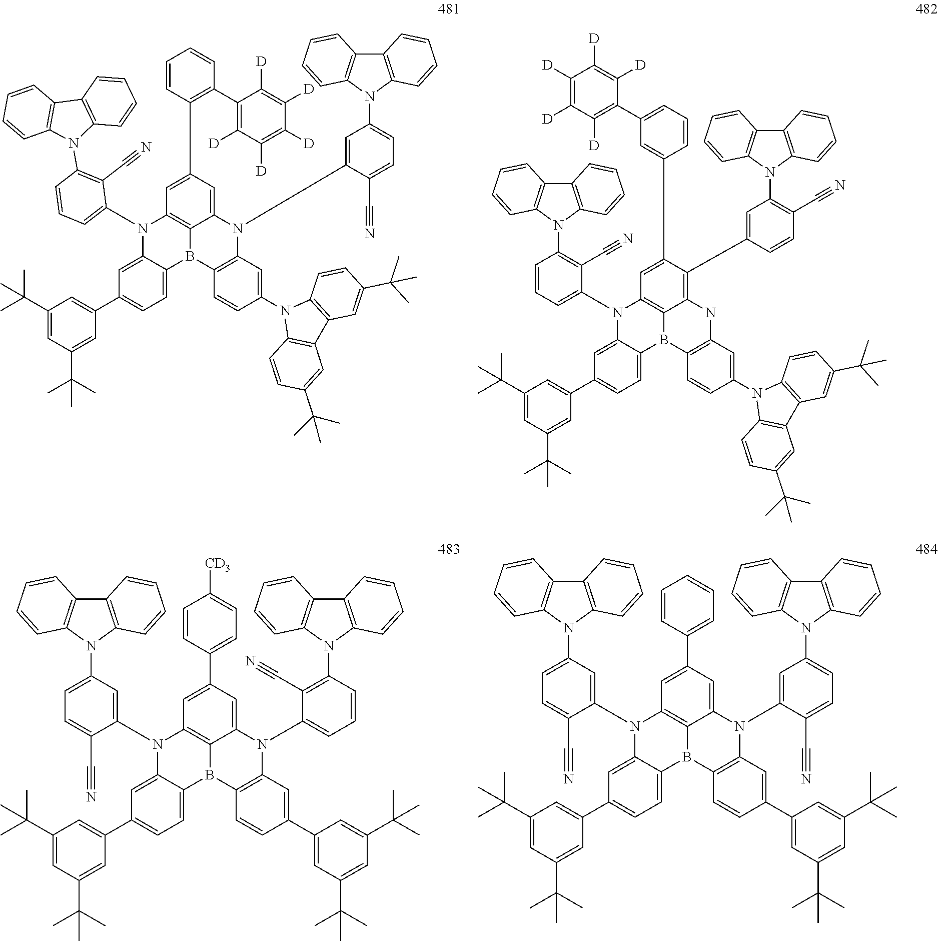

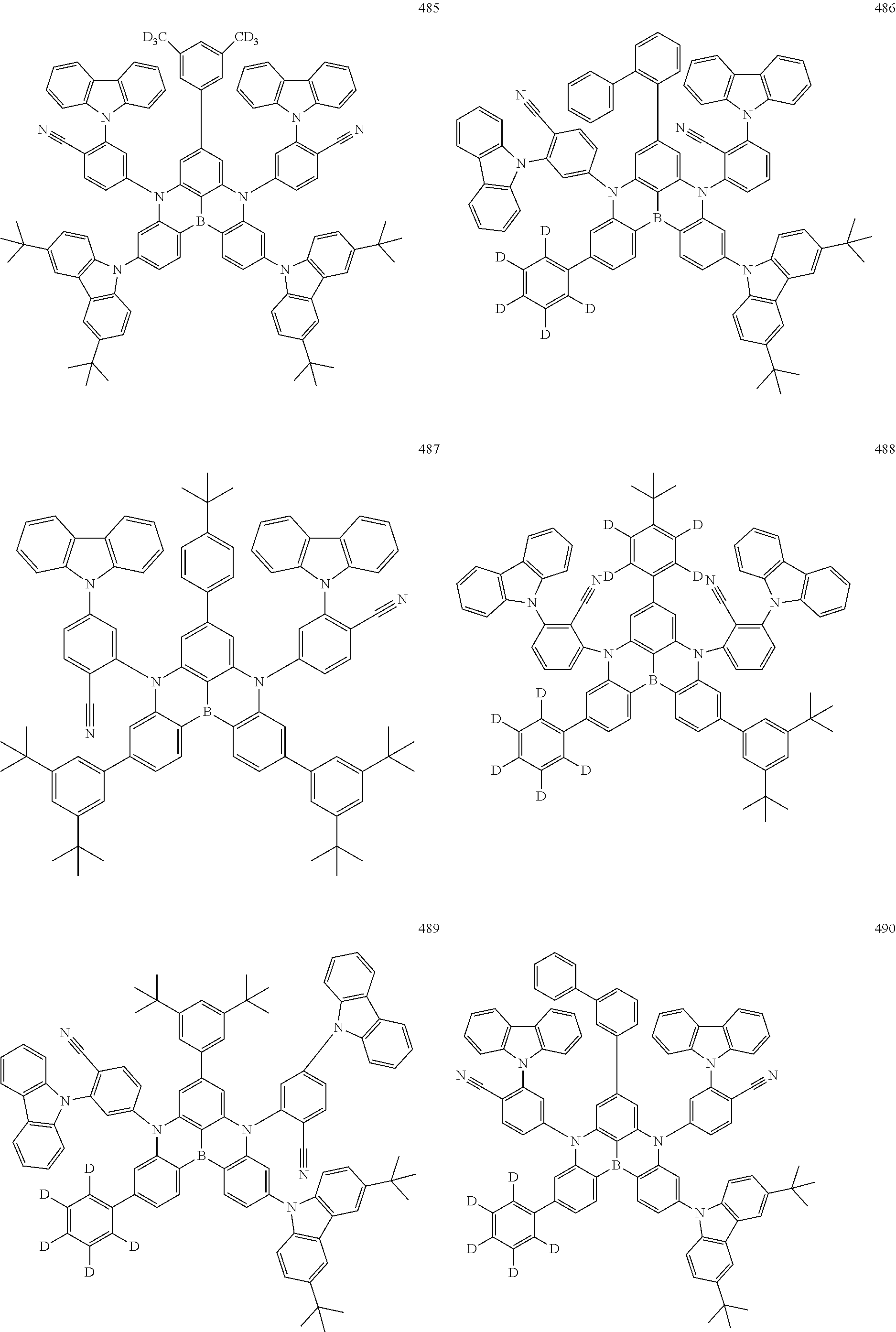

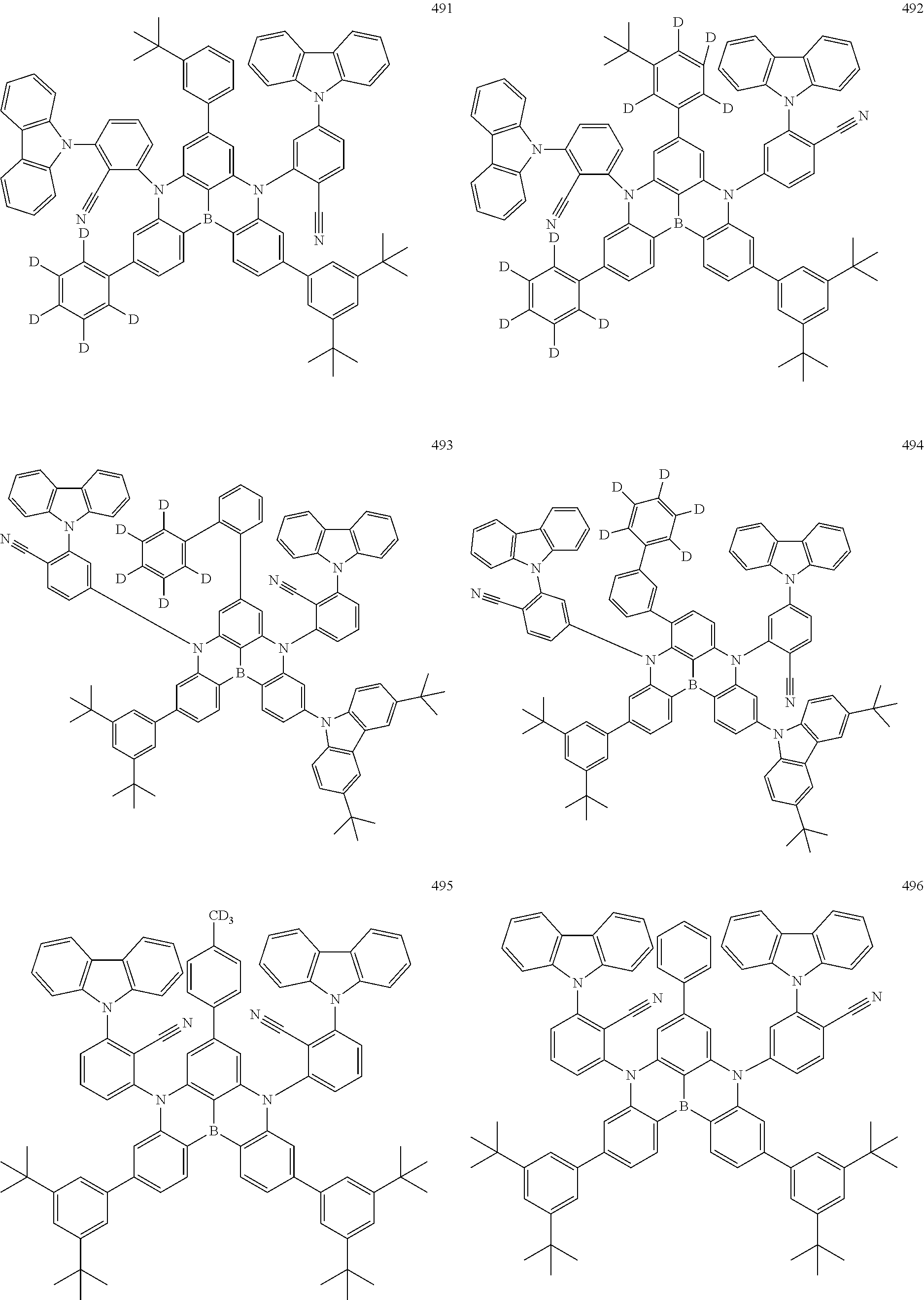

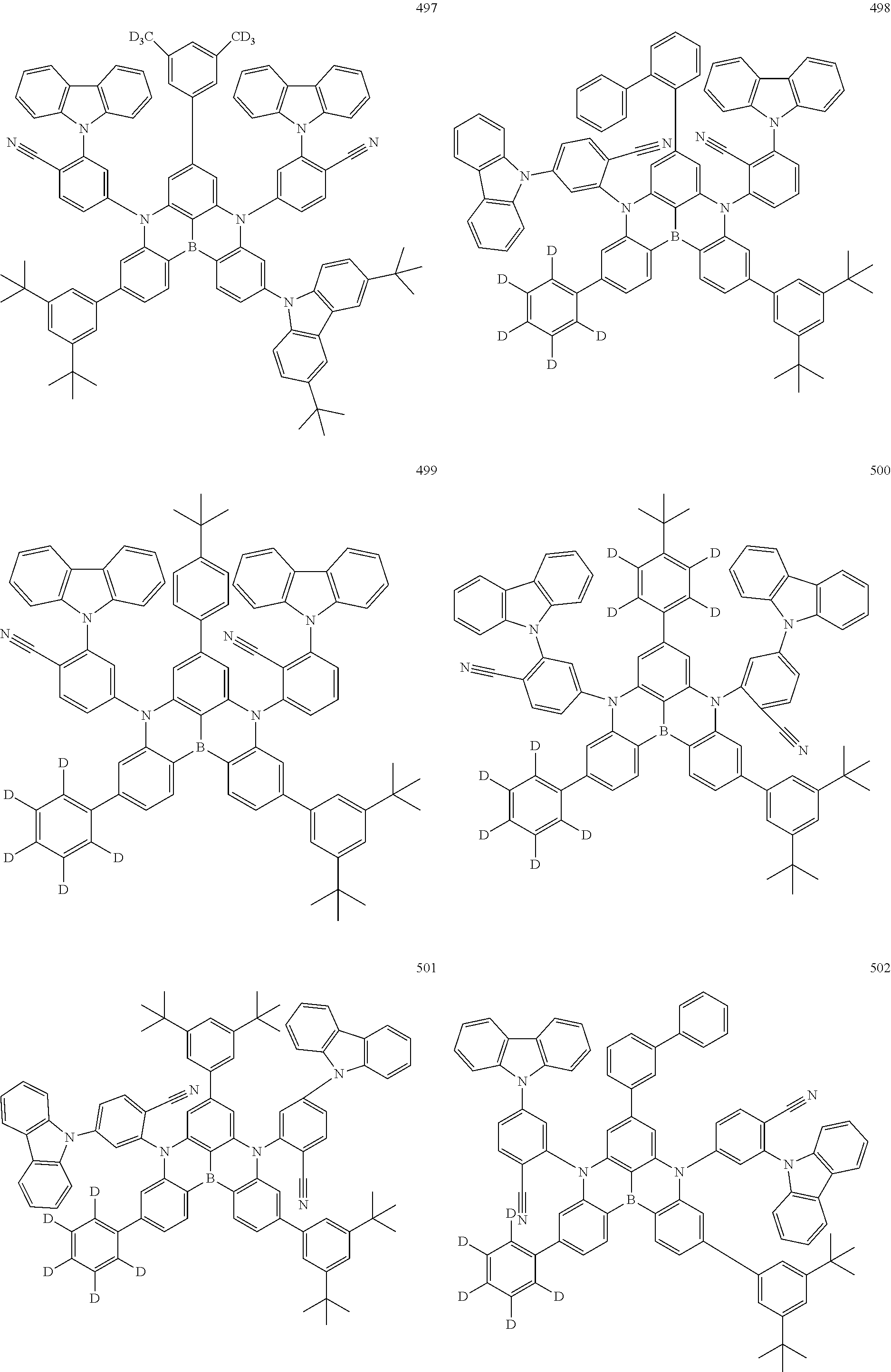

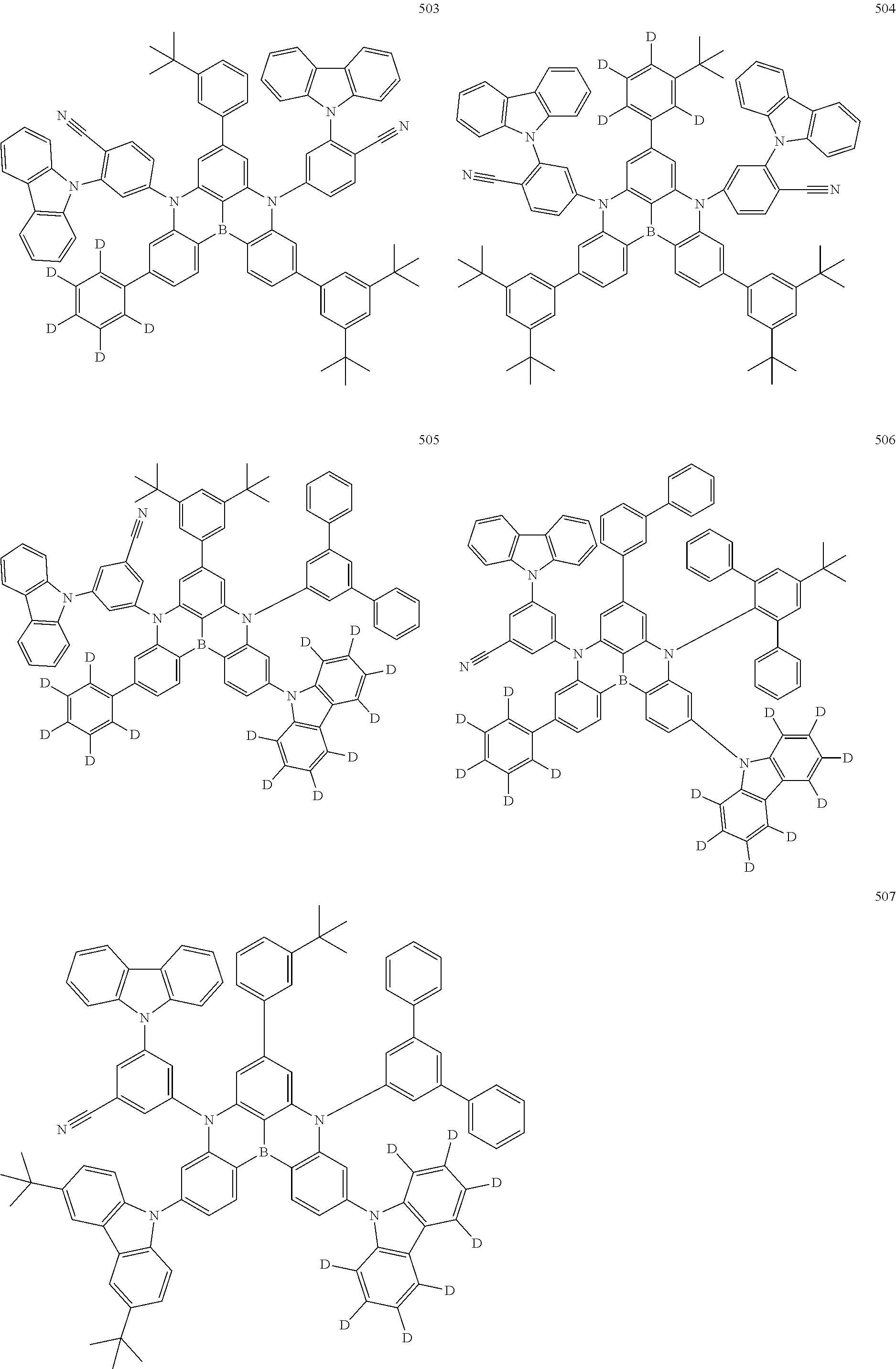

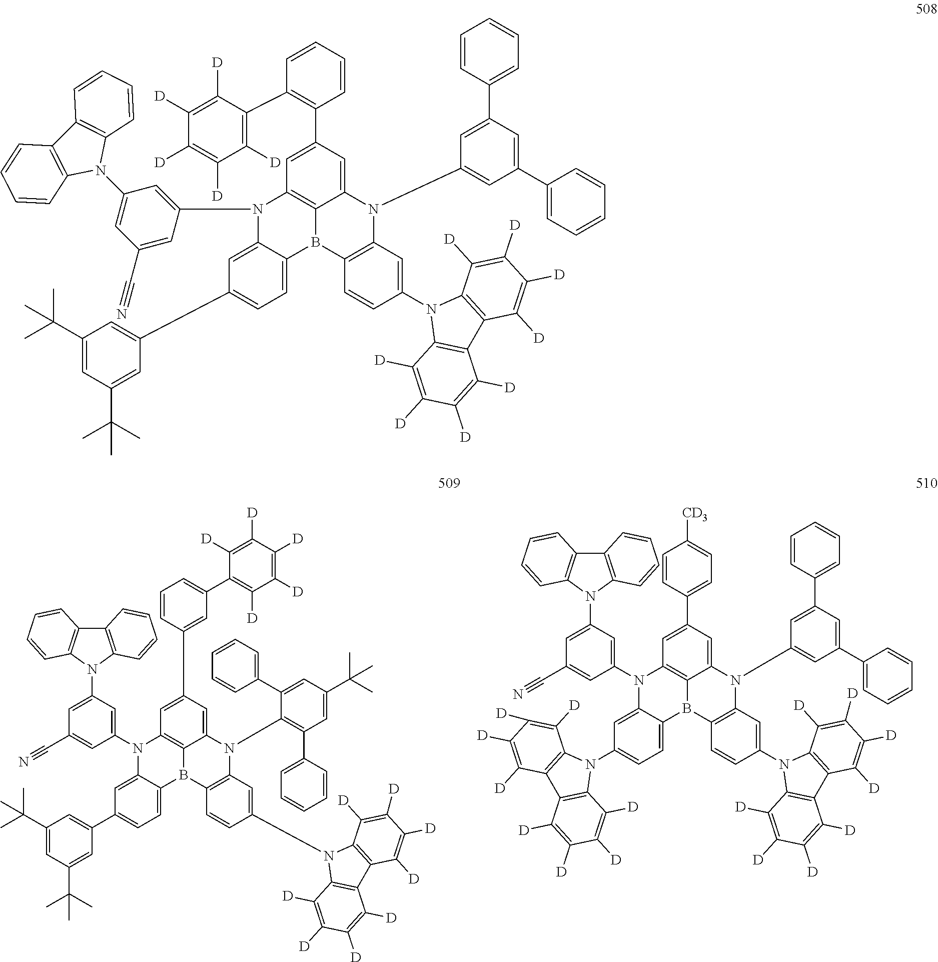

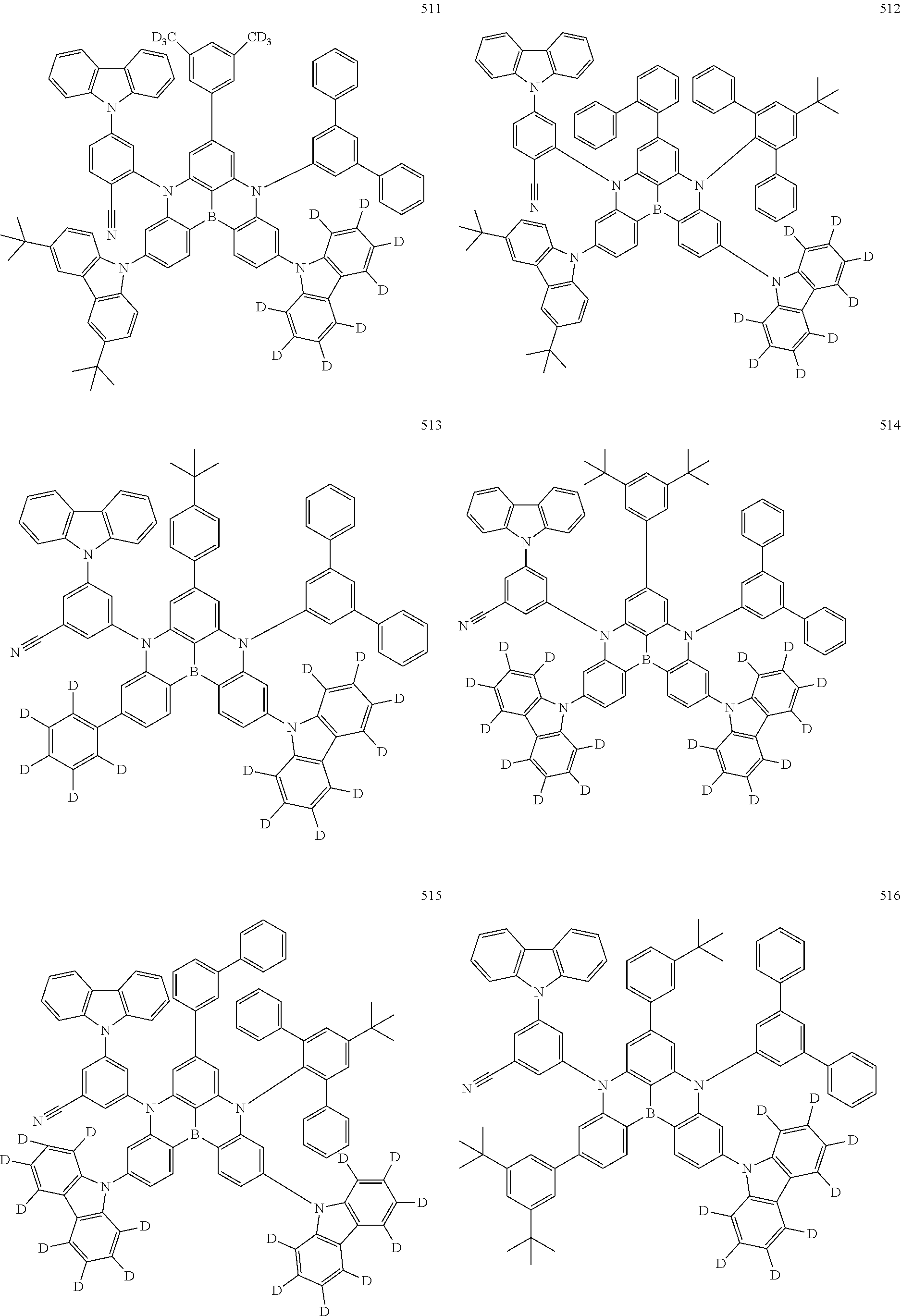

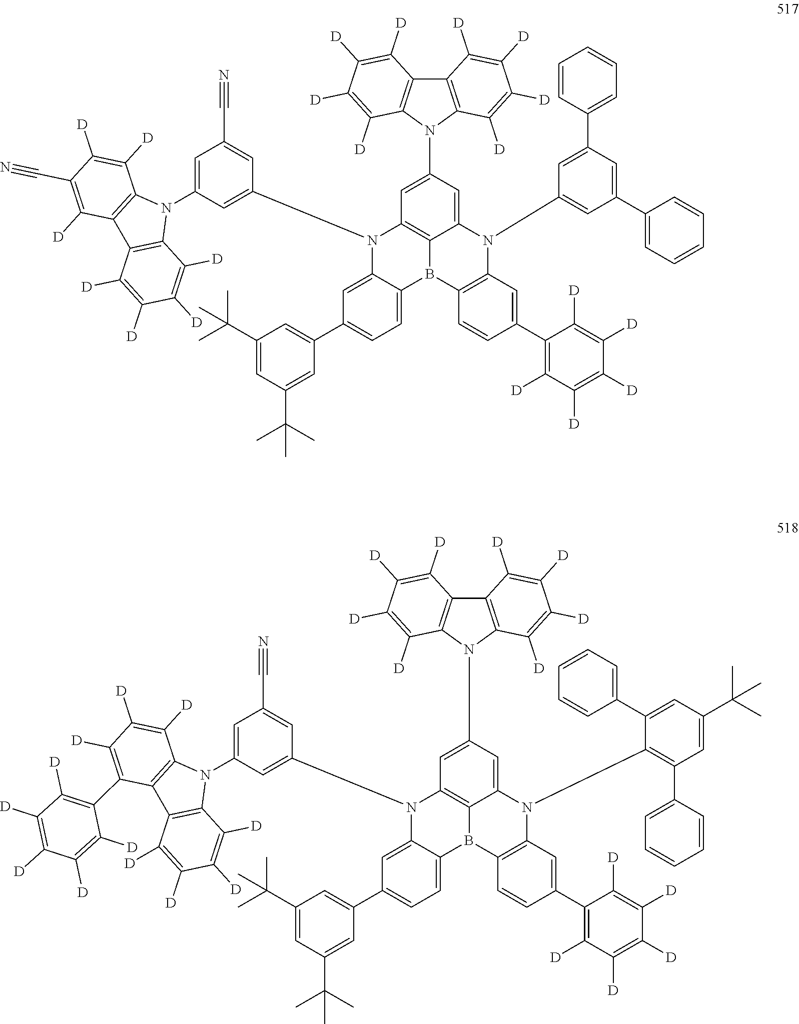

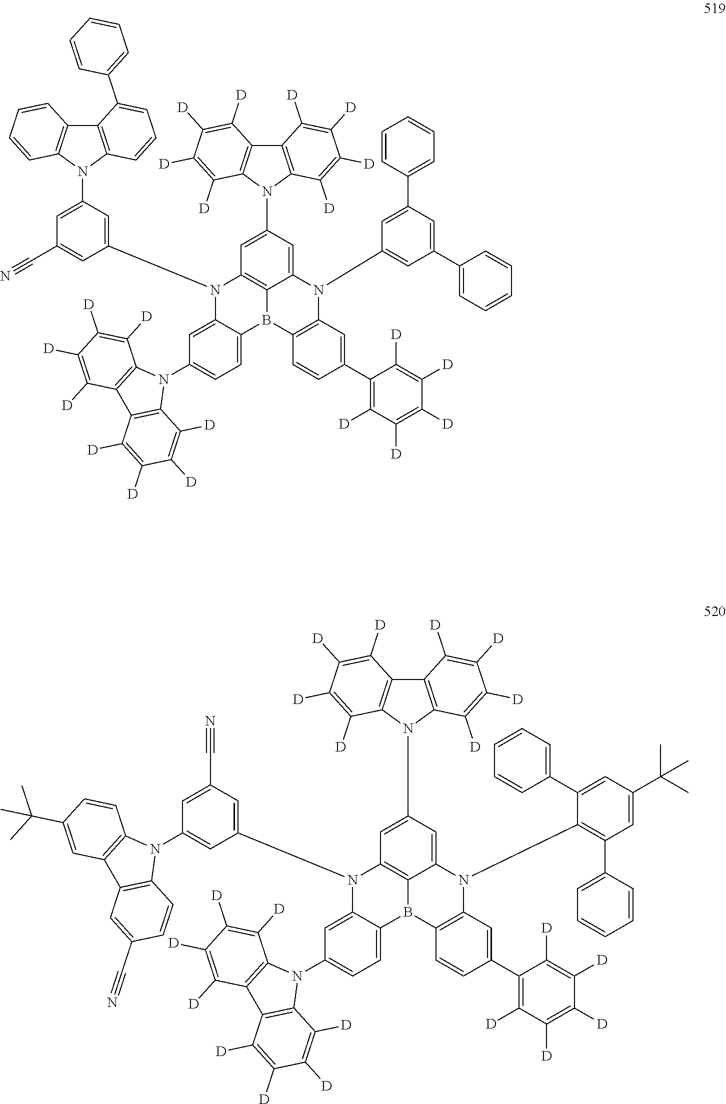

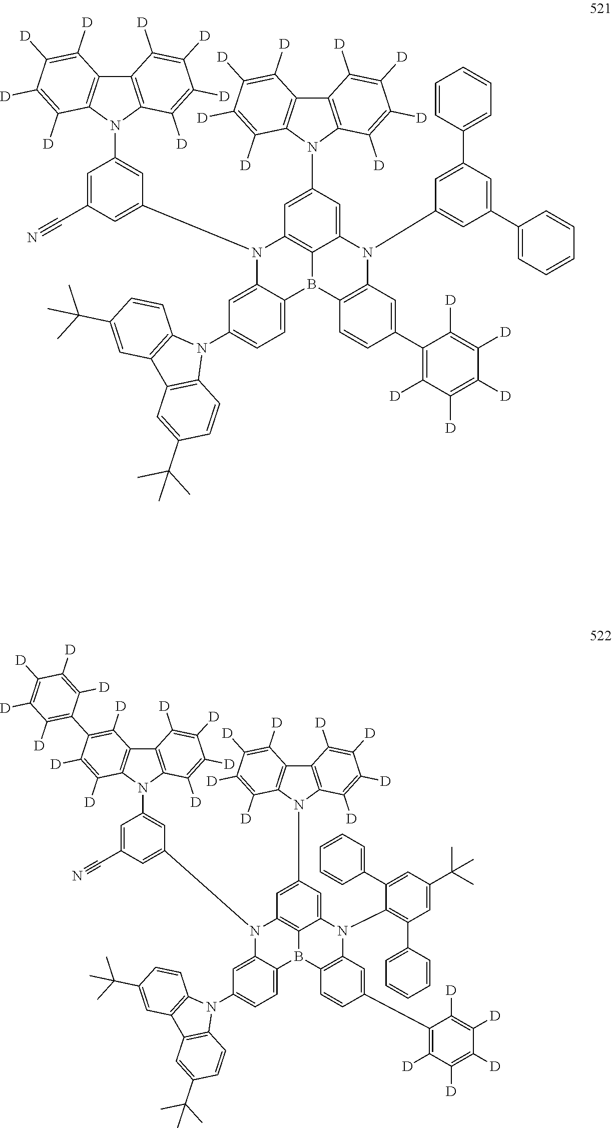

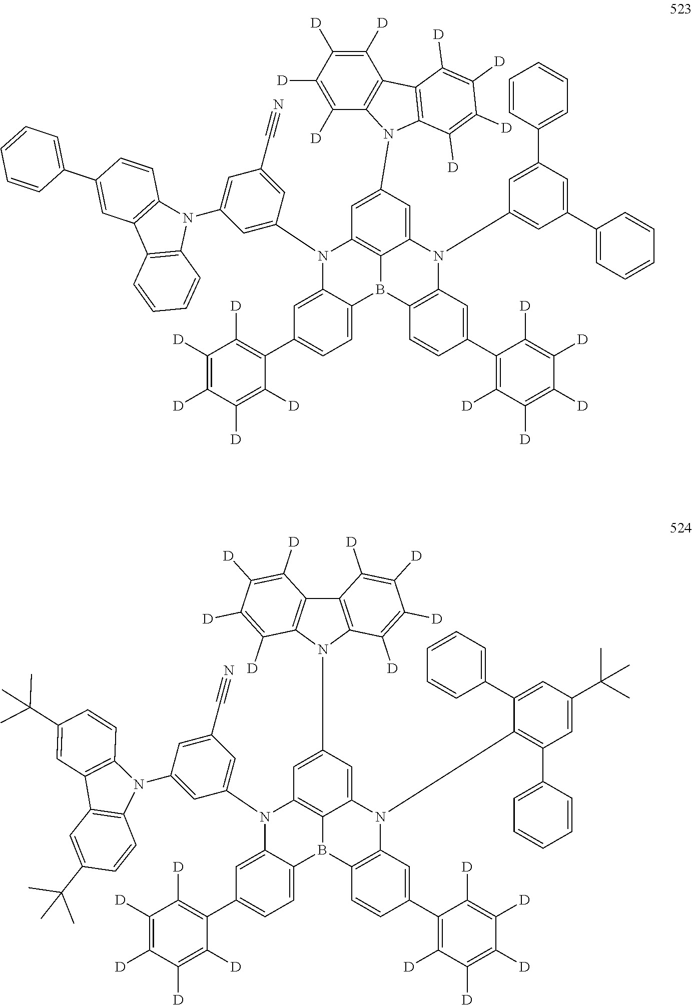

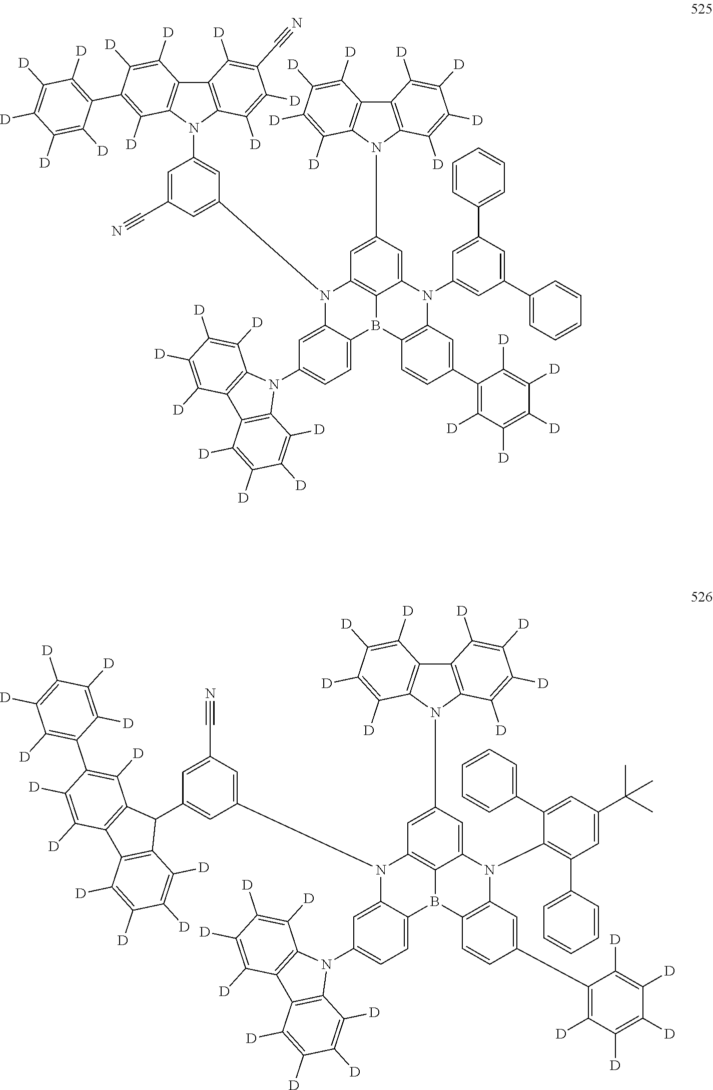

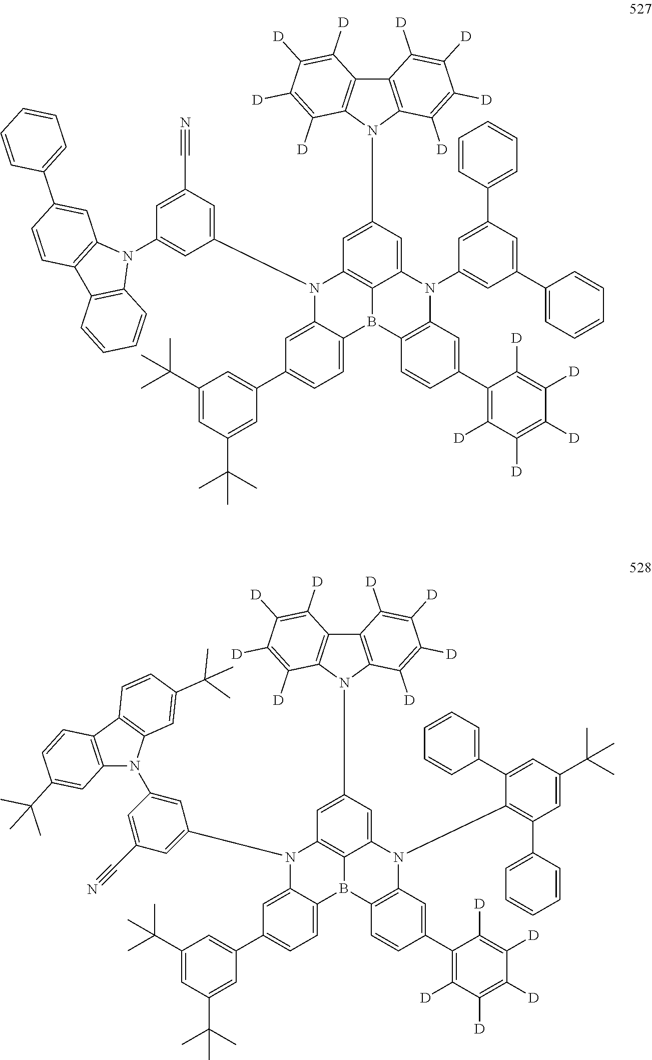

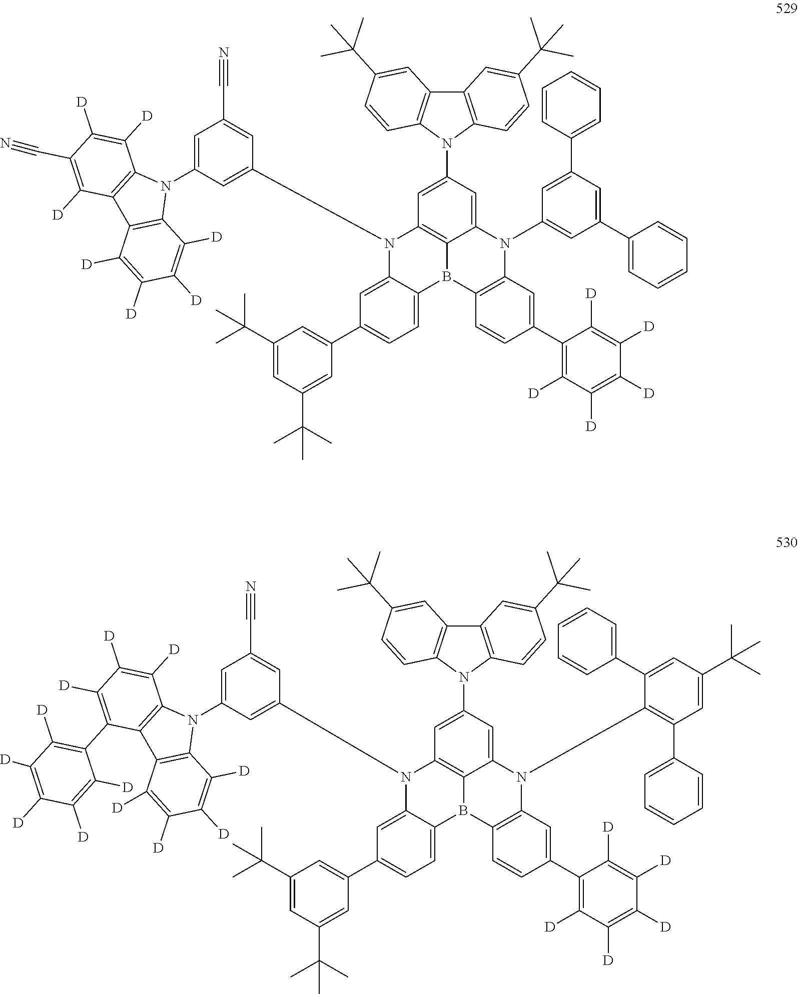

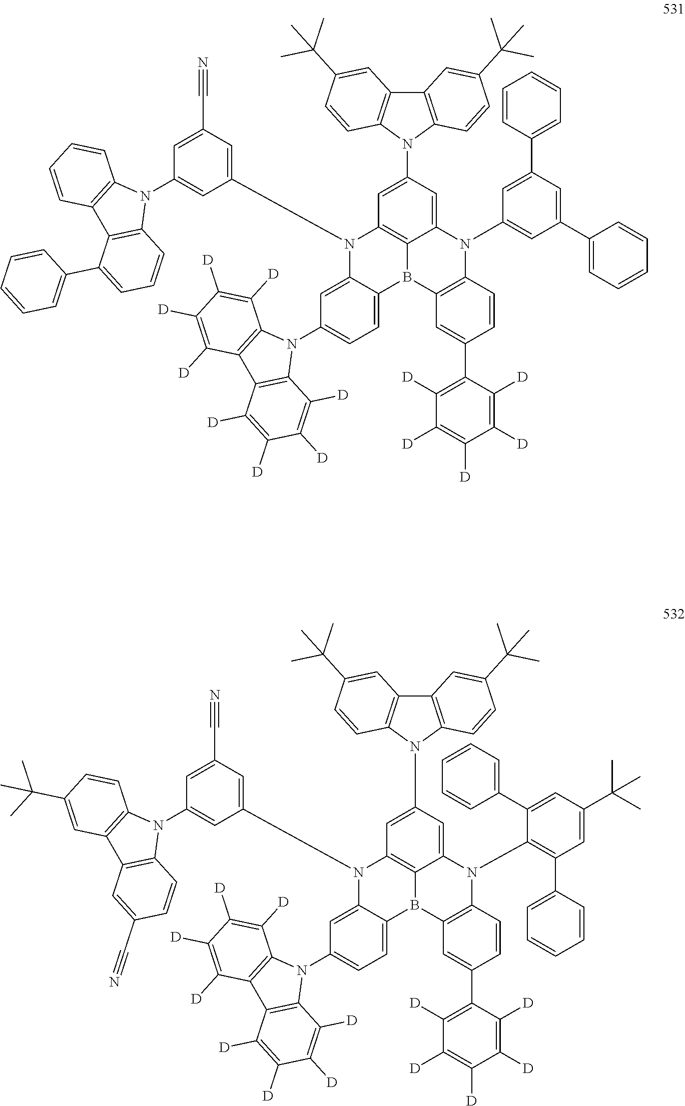

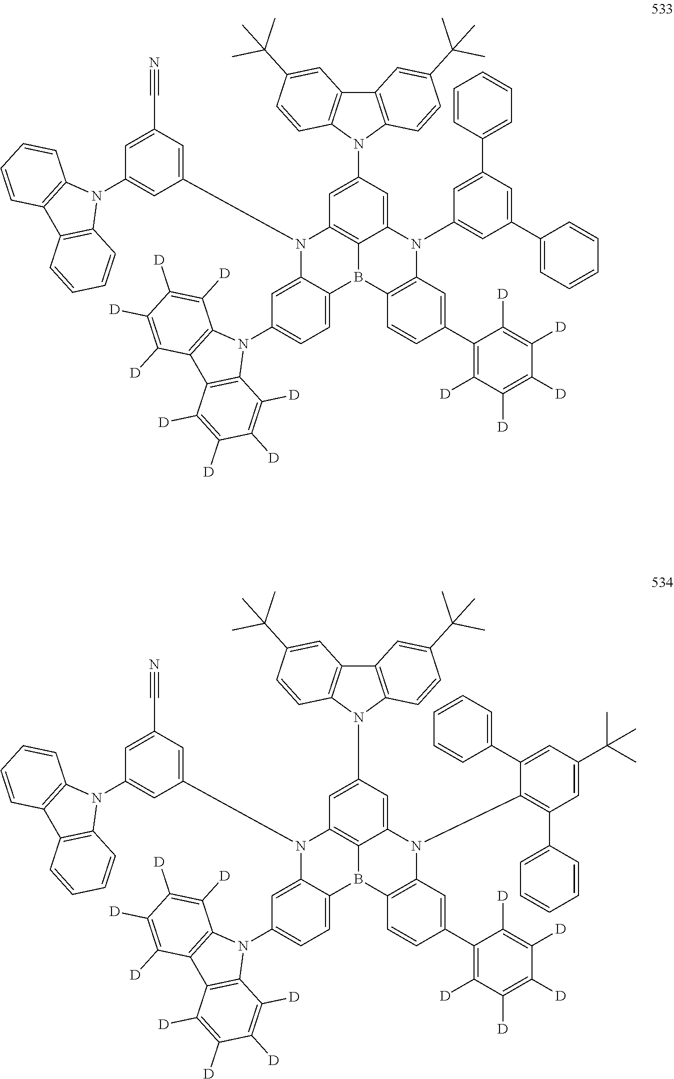

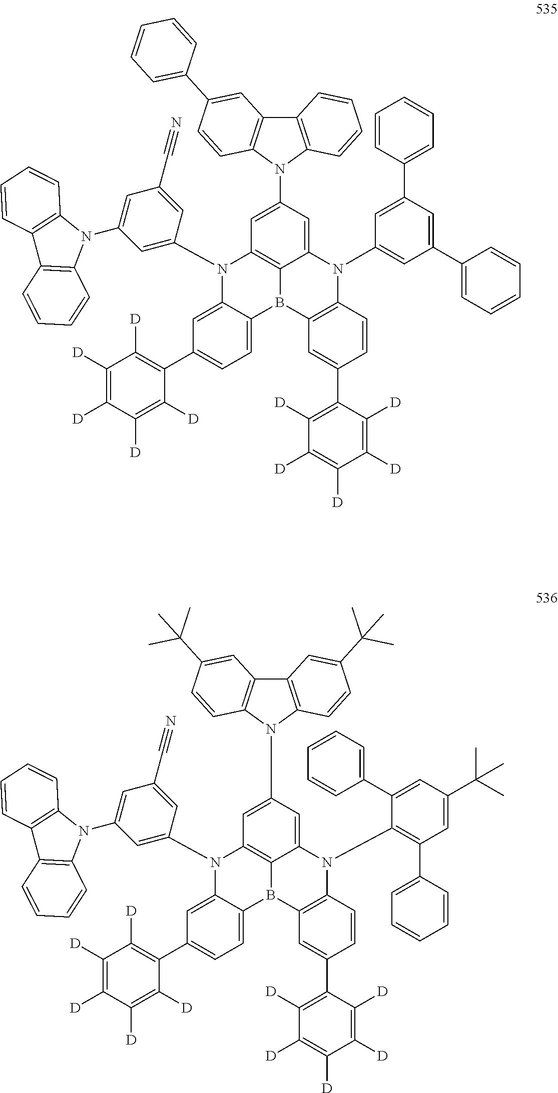 [SMILES: [2H]c1c([2H])c([2H])c(-c2ccc3c(c2)B2c4ccc(-c5c([2H])c([2H])c([2H])c([2H])c5[2H])cc4N(c4cc(C#N)cc(-n5c6ccccc6c6ccccc65)c4)c4cc(-n5c6ccccc6c6cc(-c7ccccc7)ccc65)cc(c42)N3c2cc(-c3ccccc3)cc(-c3ccccc3)c2)c([2H])c1[2H] ; [2H]c1c([2H])c([2H])c(-c2ccc3c(c2)B2c4ccc(-c5c([2H])c([2H])c([2H])c([2H])c5[2H])cc4N(c4cc(C#N)cc(-n5c6ccccc6c6ccccc65)c4)c4cc(-n5c6ccc(C(C)(C)C)cc6c6cc(C(C)(C)C)ccc65)cc(c42)N3c2c(-c3ccccc3)cc(C(C)(C)C)cc2-c2ccccc2)c([2H])c1[2H]]

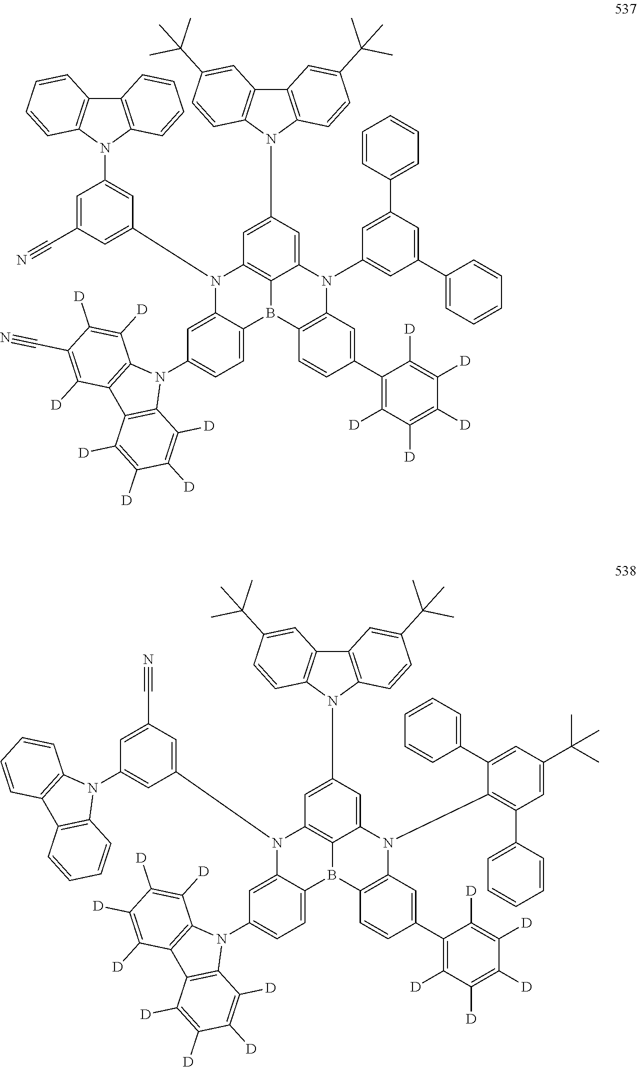

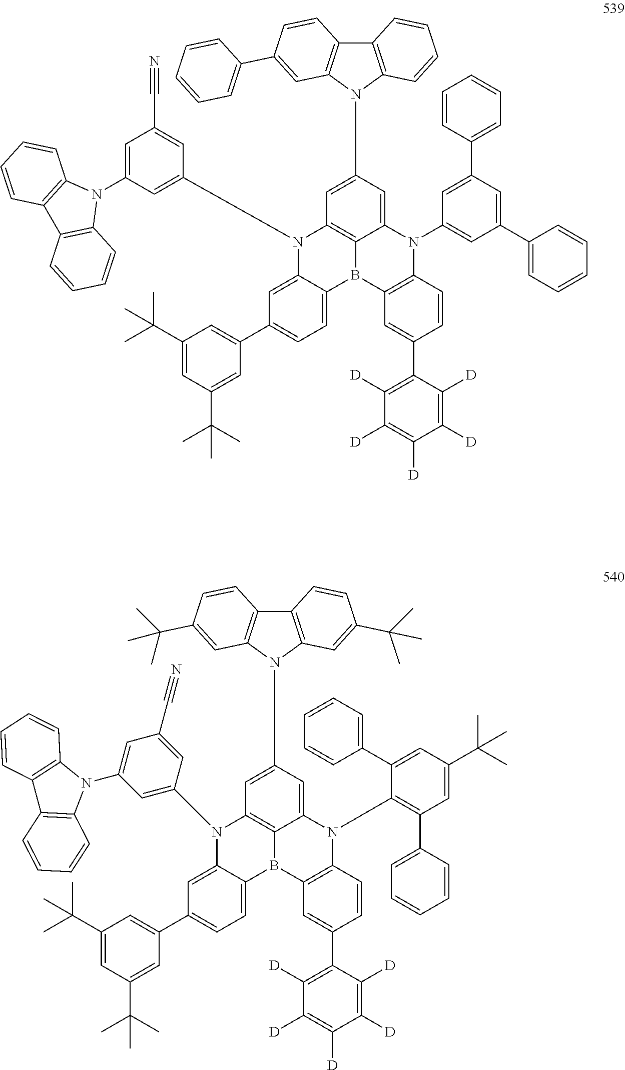 [SMILES: [2H]c1c([2H])c([2H])c(-c2ccc3c(c2)B2c4ccc(-c5cc(C(C)(C)C)cc(C(C)(C)C)c5)cc4N(c4cc(C#N)cc(-n5c6ccccc6c6ccccc65)c4)c4cc(-n5c6ccccc6c6ccc(-c7ccccc7)cc65)cc(c42)N3c2cc(-c3ccccc3)cc(-c3ccccc3)c2)c([2H])c1[2H] ; [2H]c1c([2H])c([2H])c(-c2ccc3c(c2)B2c4ccc(-c5cc(C(C)(C)C)cc(C(C)(C)C)c5)cc4N(c4cc(C#N)cc(-n5c6ccccc6c6ccccc65)c4)c4cc(-n5c6cc(C(C)(C)C)ccc6c6ccc(C(C)(C)C)cc65)cc(c42)N3c2c(-c3ccccc3)cc(C(C)(C)C)cc2-c2ccccc2)c([2H])c1[2H]]

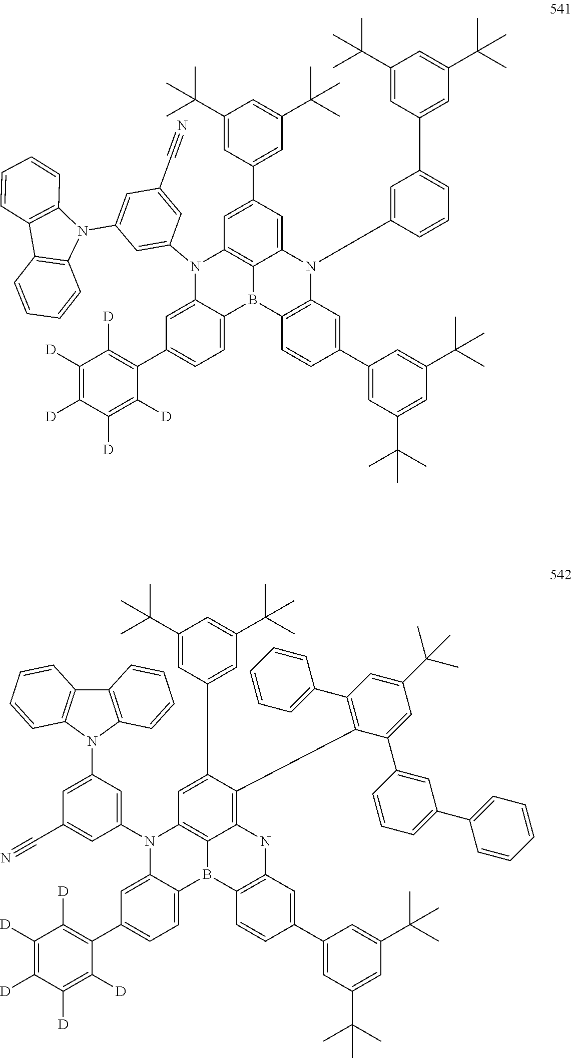 [SMILES: [2H]c1c([2H])c([2H])c(-c2ccc3c(c2)N(c2cc(C#N)cc(-n4c5ccccc5c5ccccc54)c2)c2cc(-c4cc(C(C)(C)C)cc(C(C)(C)C)c4)cc4c2B3c2ccc(-c3cc(C(C)(C)C)cc(C(C)(C)C)c3)cc2N4c2cccc(-c3cc(C(C)(C)C)cc(C(C)(C)C)c3)c2)c([2H])c1[2H] ; [2H]c1c([2H])c([2H])c(-c2ccc3c(c2)N(c2cc(C#N)cc(-n4c5ccccc5c5ccccc54)c2)c2cc(-c4cc(C(C)(C)C)cc(C(C)(C)C)c4)c(-c4c(-c5ccccc5)cc(C(C)(C)C)cc4-c4cccc(-c5ccccc5)c4)c4c2B3c2ccc(-c3cc(C(C)(C)C)cc(C(C)(C)C)c3)cc2N4)c([2H])c1[2H]]

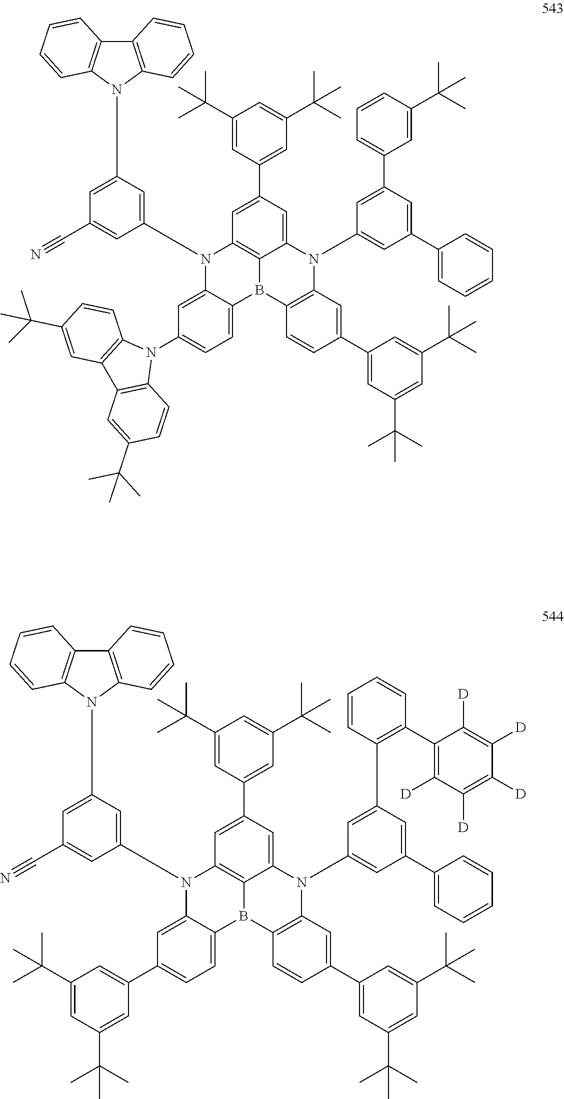 [SMILES: CC(C)(C)c1cccc(-c2cc(-c3ccccc3)cc(N3c4cc(-c5cc(C(C)(C)C)cc(C(C)(C)C)c5)ccc4B4c5ccc(-n6c7ccc(C(C)(C)C)cc7c7cc(C(C)(C)C)ccc76)cc5N(c5cc(C#N)cc(-n6c7ccccc7c7ccccc76)c5)c5cc(-c6cc(C(C)(C)C)cc(C(C)(C)C)c6)cc3c54)c2)c1 ; [2H]c1c([2H])c([2H])c(-c2ccccc2-c2cc(-c3ccccc3)cc(N3c4cc(-c5cc(C(C)(C)C)cc(C(C)(C)C)c5)ccc4B4c5ccc(-c6cc(C(C)(C)C)cc(C(C)(C)C)c6)cc5N(c5cc(C#N)cc(-n6c7ccccc7c7ccccc76)c5)c5cc(-c6cc(C(C)(C)C)cc(C(C)(C)C)c6)cc3c54)c2)c([2H])c1[2H]]

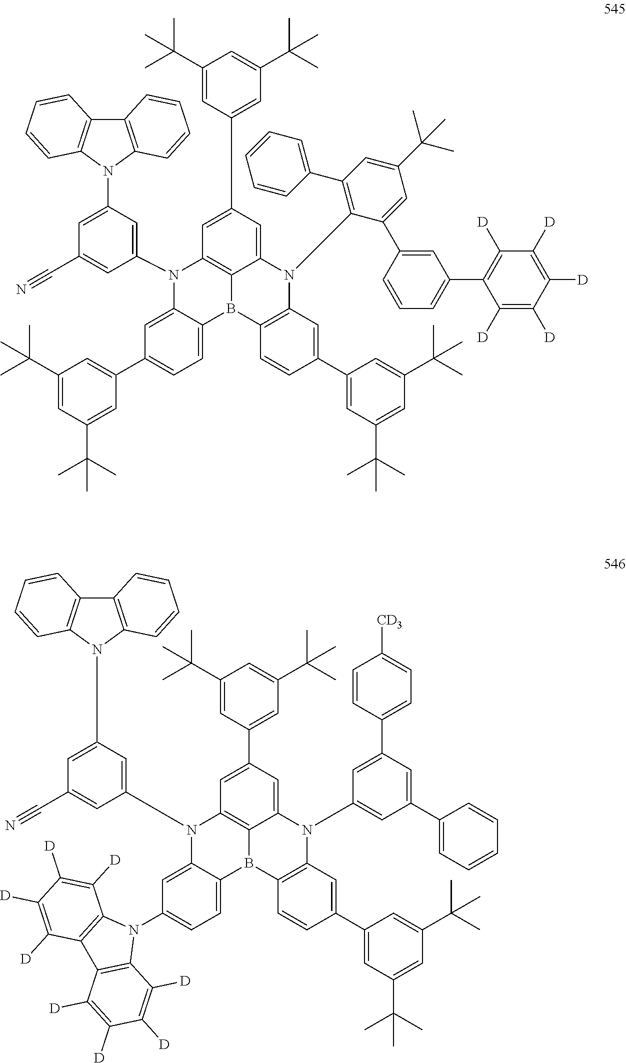 [SMILES: [2H]c1c([2H])c([2H])c(-c2cccc(-c3cc(C(C)(C)C)cc(-c4ccccc4)c3N3c4cc(-c5cc(C(C)(C)C)cc(C(C)(C)C)c5)ccc4B4c5ccc(-c6cc(C(C)(C)C)cc(C(C)(C)C)c6)cc5N(c5cc(C#N)cc(-n6c7ccccc7c7ccccc76)c5)c5cc(-c6cc(C(C)(C)C)cc(C(C)(C)C)c6)cc3c54)c2)c([2H])c1[2H] ; [2H]c1c([2H])c([2H])c2c(c1[2H])c1c([2H])c([2H])c([2H])c([2H])c1n2-c1ccc2c(c1)N(c1cc(C#N)cc(-n3c4ccccc4c4ccccc43)c1)c1cc(-c3cc(C(C)(C)C)cc(C(C)(C)C)c3)cc3c1B2c1ccc(-c2cc(C(C)(C)C)cc(C(C)(C)C)c2)cc1N3c1cc(-c2ccccc2)cc(-c2ccc(C([2H])([2H])[2H])cc2)c1]

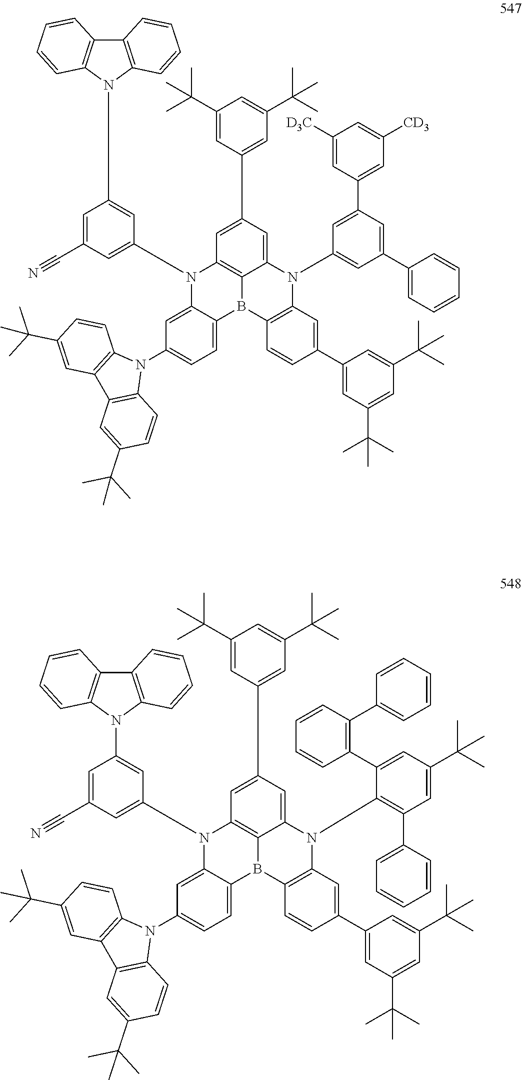 [SMILES: [2H]C([2H])([2H])c1cc(-c2cc(-c3ccccc3)cc(N3c4cc(-c5cc(C(C)(C)C)cc(C(C)(C)C)c5)ccc4B4c5ccc(-n6c7ccc(C(C)(C)C)cc7c7cc(C(C)(C)C)ccc76)cc5N(c5cc(C#N)cc(-n6c7ccccc7c7ccccc76)c5)c5cc(-c6cc(C(C)(C)C)cc(C(C)(C)C)c6)cc3c54)c2)cc(C([2H])([2H])[2H])c1 ; CC(C)(C)c1cc(-c2ccc3c(c2)N(c2c(-c4ccccc4)cc(C(C)(C)C)cc2-c2ccccc2-c2ccccc2)c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2cc(C#N)cc(-n3c4ccccc4c4ccccc43)c2)cc(C(C)(C)C)c1]

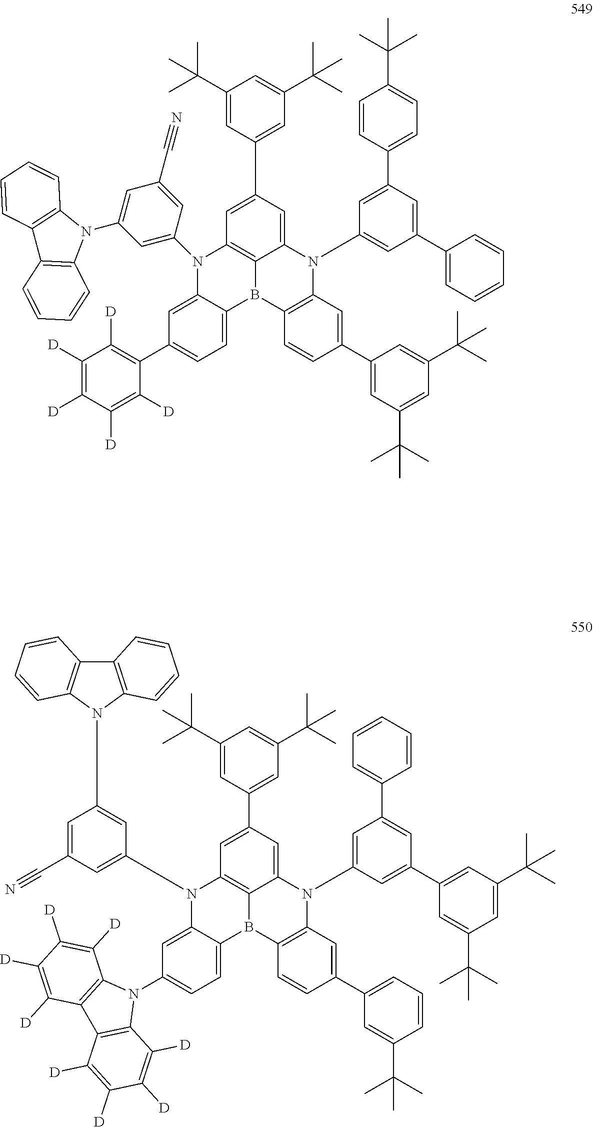 [SMILES: [2H]c1c([2H])c([2H])c(-c2ccc3c(c2)N(c2cc(C#N)cc(-n4c5ccccc5c5ccccc54)c2)c2cc(-c4cc(C(C)(C)C)cc(C(C)(C)C)c4)cc4c2B3c2ccc(-c3cc(C(C)(C)C)cc(C(C)(C)C)c3)cc2N4c2cc(-c3ccccc3)cc(-c3ccc(C(C)(C)C)cc3)c2)c([2H])c1[2H] ; [2H]c1c([2H])c([2H])c2c(c1[2H])c1c([2H])c([2H])c([2H])c([2H])c1n2-c1ccc2c(c1)N(c1cc(C#N)cc(-n3c4ccccc4c4ccccc43)c1)c1cc(-c3cc(C(C)(C)C)cc(C(C)(C)C)c3)cc3c1B2c1ccc(-c2cccc(C(C)(C)C)c2)cc1N3c1cc(-c2ccccc2)cc(-c2cc(C(C)(C)C)cc(C(C)(C)C)c2)c1]

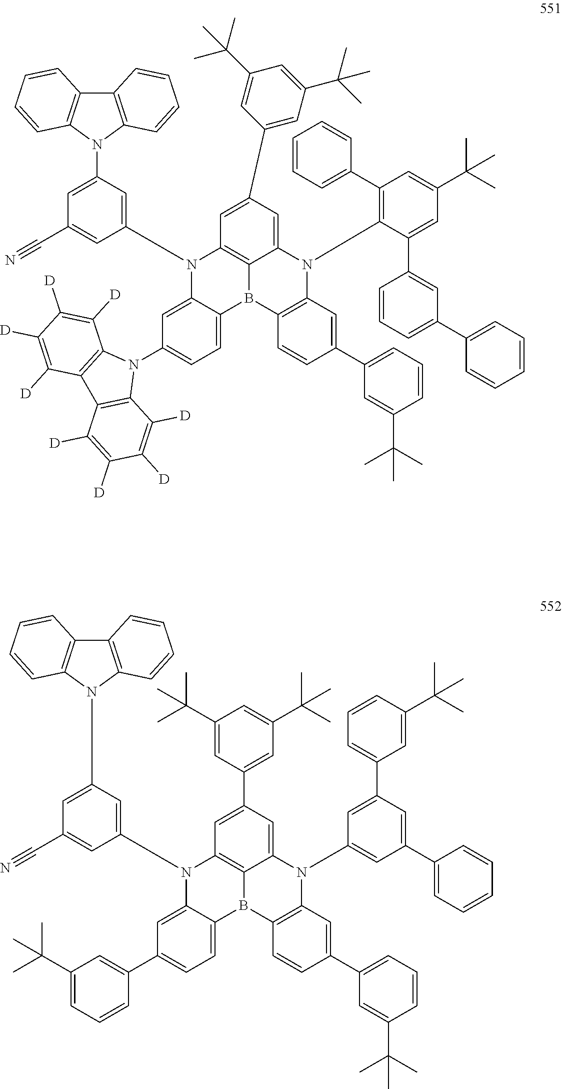 [SMILES: [2H]c1c([2H])c([2H])c2c(c1[2H])c1c([2H])c([2H])c([2H])c([2H])c1n2-c1ccc2c(c1)N(c1cc(C#N)cc(-n3c4ccccc4c4ccccc43)c1)c1cc(-c3cc(C(C)(C)C)cc(C(C)(C)C)c3)cc3c1B2c1ccc(-c2cccc(C(C)(C)C)c2)cc1N3c1c(-c2ccccc2)cc(C(C)(C)C)cc1-c1cccc(-c2ccccc2)c1 ; CC(C)(C)c1cccc(-c2cc(-c3ccccc3)cc(N3c4cc(-c5cccc(C(C)(C)C)c5)ccc4B4c5ccc(-c6cccc(C(C)(C)C)c6)cc5N(c5cc(C#N)cc(-n6c7ccccc7c7ccccc76)c5)c5cc(-c6cc(C(C)(C)C)cc(C(C)(C)C)c6)cc3c54)c2)c1]

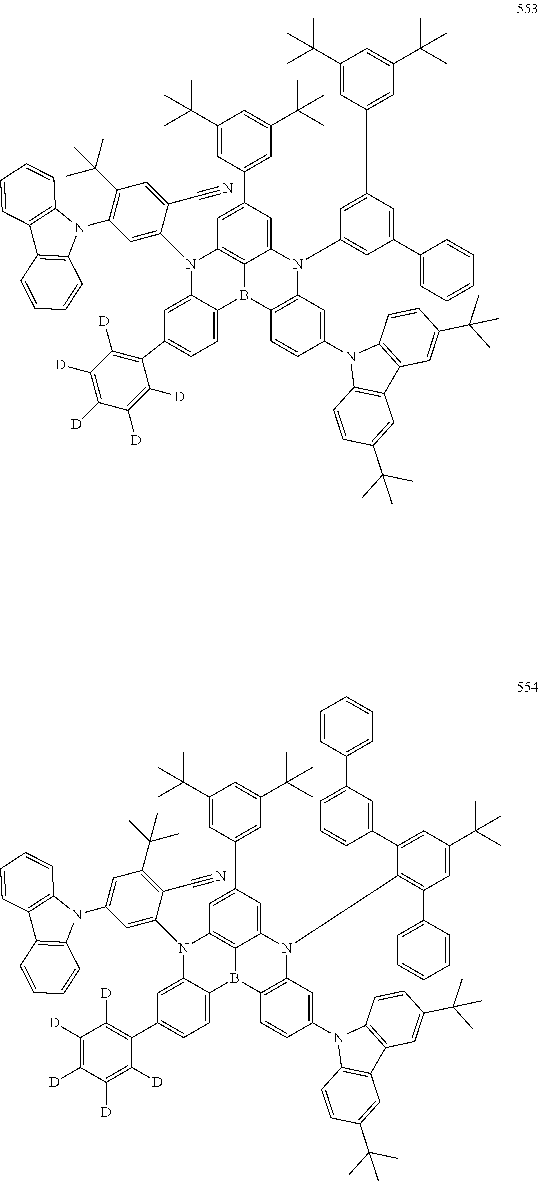 [SMILES: [2H]c1c([2H])c([2H])c(-c2ccc3c(c2)N(c2cc(-n4c5ccccc5c5ccccc54)c(C(C)(C)C)cc2C#N)c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2cc(-c3ccccc3)cc(-c3cc(C(C)(C)C)cc(C(C)(C)C)c3)c2)c([2H])c1[2H] ; [2H]c1c([2H])c([2H])c(-c2ccc3c(c2)N(c2cc(-n4c5ccccc5c5ccccc54)cc(C(C)(C)C)c2C#N)c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2cccc(-c3ccccc3)c2)c([2H])c1[2H]]

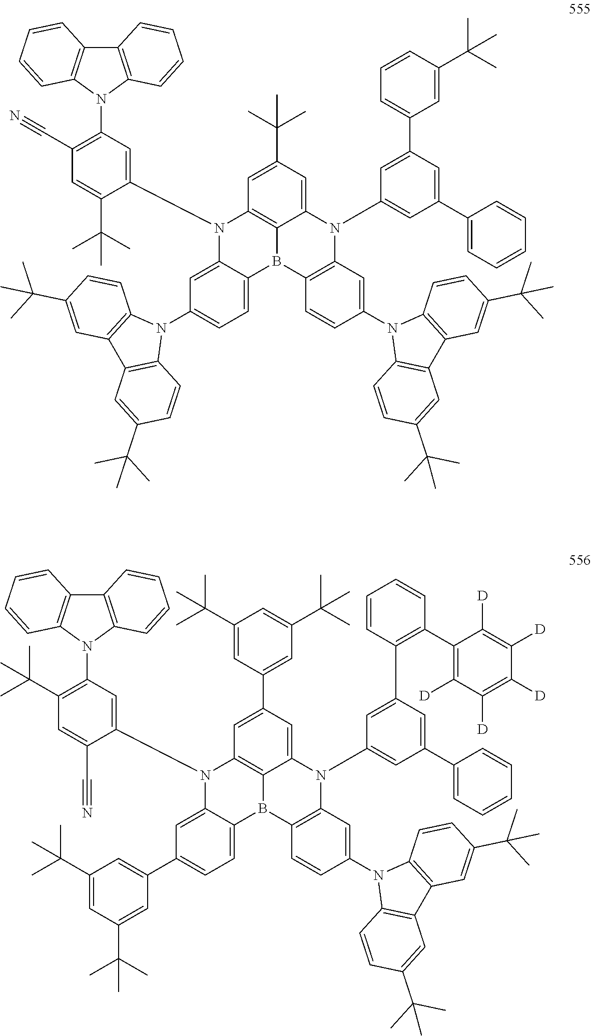

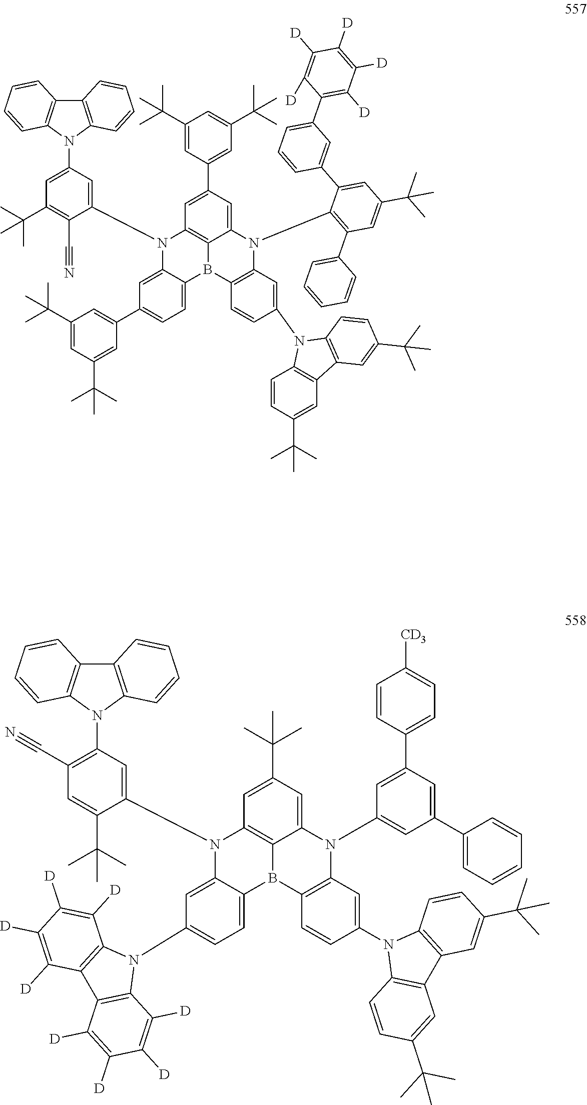

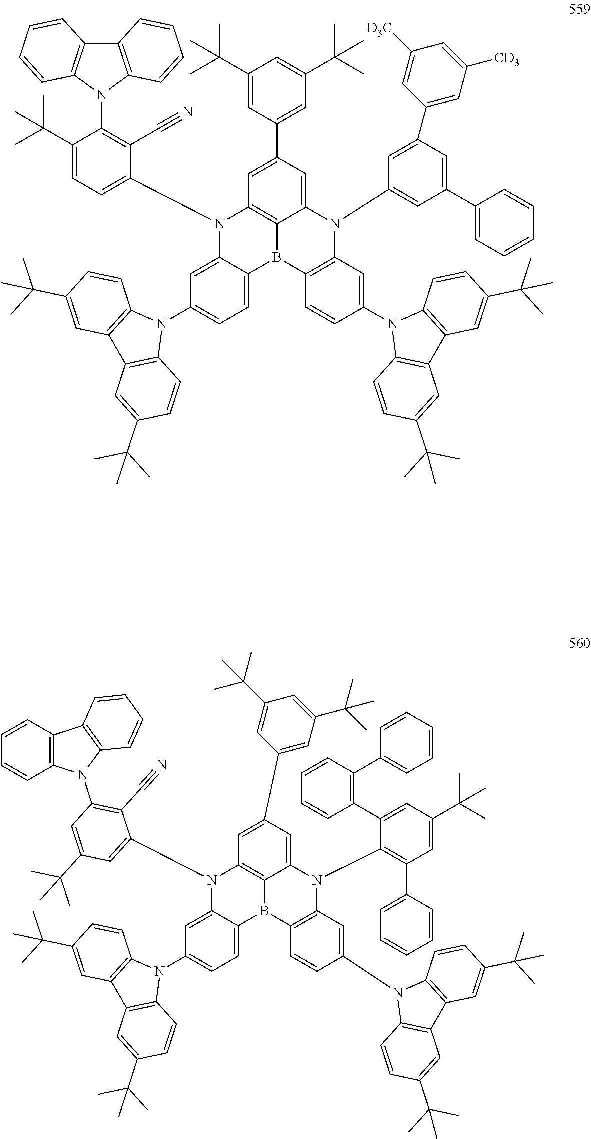 [SMILES: [2H]C([2H])([2H])c1cc(-c2cc(-c3ccccc3)cc(N3c4cc(-n5c6ccc(C(C)(C)C)cc6c6cc(C(C)(C)C)ccc65)ccc4B4c5ccc(-n6c7ccc(C(C)(C)C)cc7c7cc(C(C)(C)C)ccc76)cc5N(c5ccc(C(C)(C)C)c(-n6c7ccccc7c7ccccc76)c5C#N)c5cc(-c6cc(C(C)(C)C)cc(C(C)(C)C)c6)cc3c54)c2)cc(C([2H])([2H])[2H])c1 ; CC(C)(C)c1cc(-c2cc3c4c(c2)N(c2c(-c5ccccc5)cc(C(C)(C)C)cc2-c2ccccc2-c2ccccc2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2cc(C(C)(C)C)cc(-n3c4ccccc4c4ccccc43)c2C#N)cc(C(C)(C)C)c1]

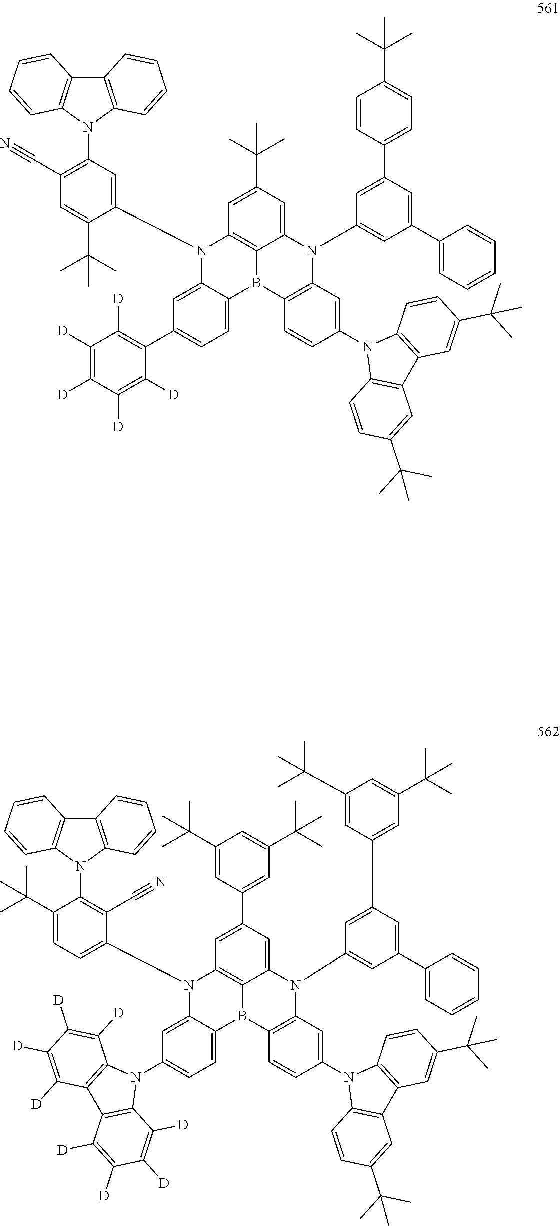

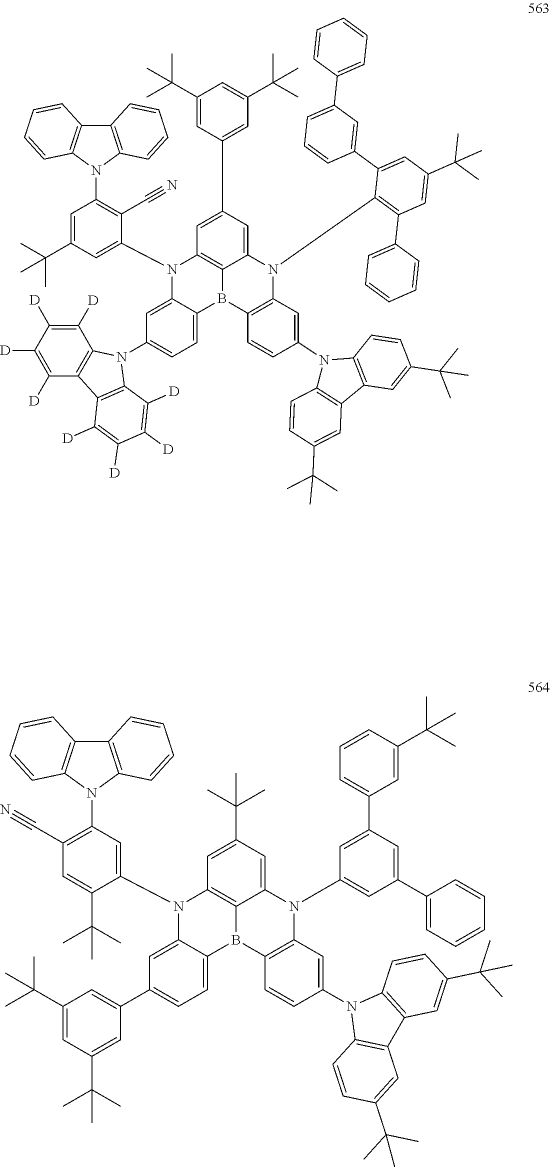 [SMILES: [2H]c1c([2H])c([2H])c2c(c1[2H])c1c([2H])c([2H])c([2H])c([2H])c1n2-c1ccc2c(c1)N(c1cc(C(C)(C)C)cc(-n3c4ccccc4c4ccccc43)c1C#N)c1cc(-c3cc(C(C)(C)C)cc(C(C)(C)C)c3)cc3c1B2c1ccc(-n2c4ccc(C(C)(C)C)cc4c4cc(C(C)(C)C)ccc42)cc1N3c1c(-c2ccccc2)cc(C(C)(C)C)cc1-c1cccc(-c2ccccc2)c1 ; CC(C)(C)c1cccc(-c2cc(-c3ccccc3)cc(N3c4cc(-n5c6ccc(C(C)(C)C)cc6c6cc(C(C)(C)C)ccc65)ccc4B4c5ccc(-c6cc(C(C)(C)C)cc(C(C)(C)C)c6)cc5N(c5cc(-n6c7ccccc7c7ccccc76)c(C#N)cc5C(C)(C)C)c5cc(C(C)(C)C)cc3c54)c2)c1]

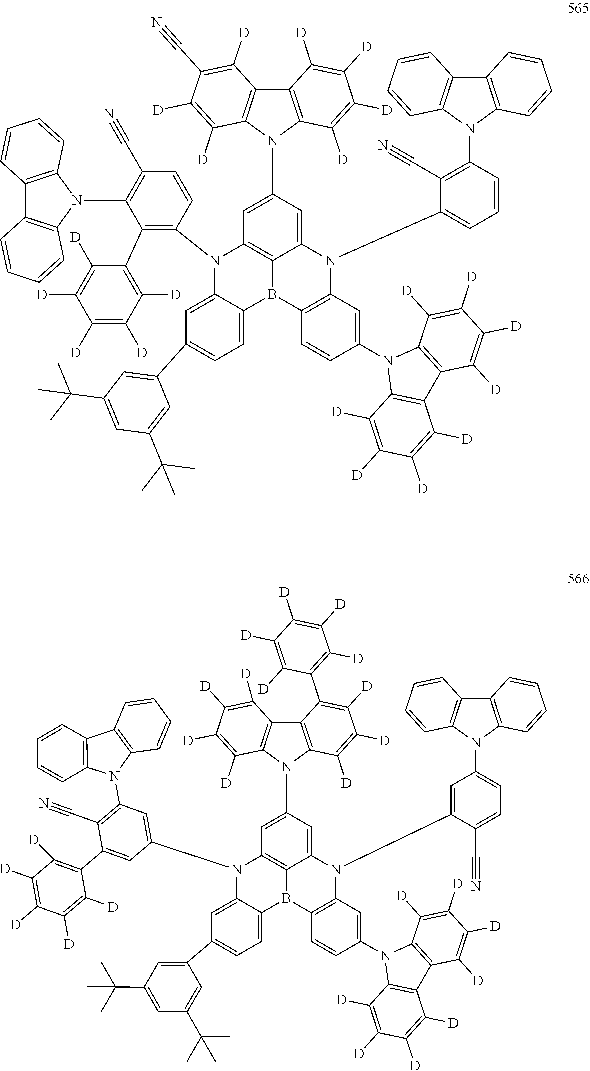

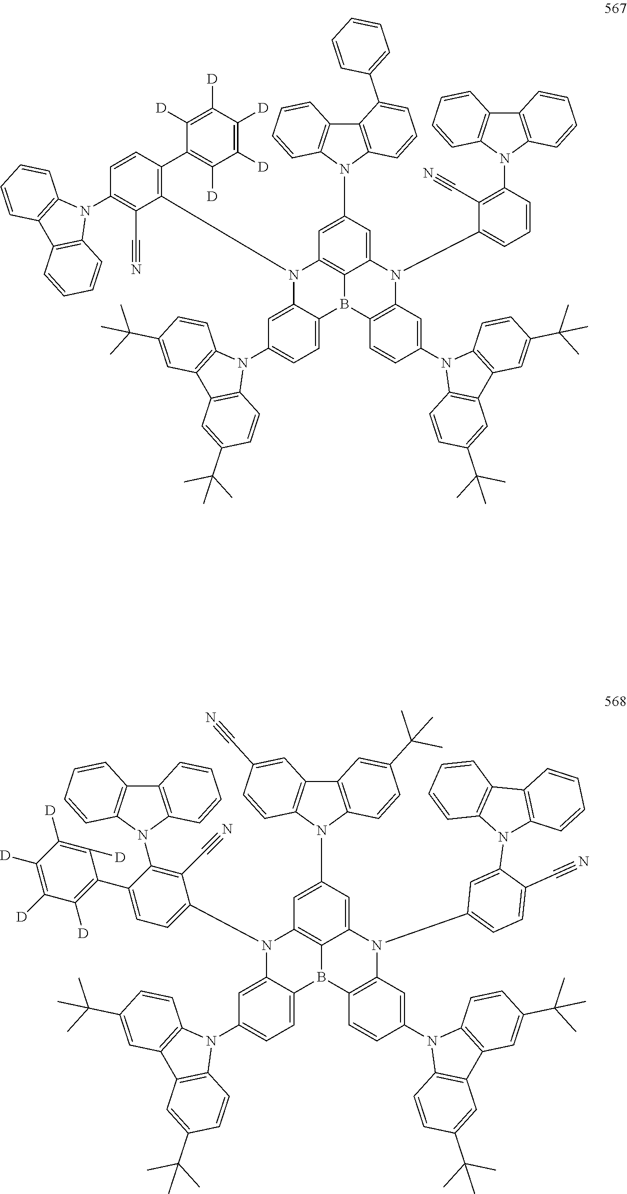

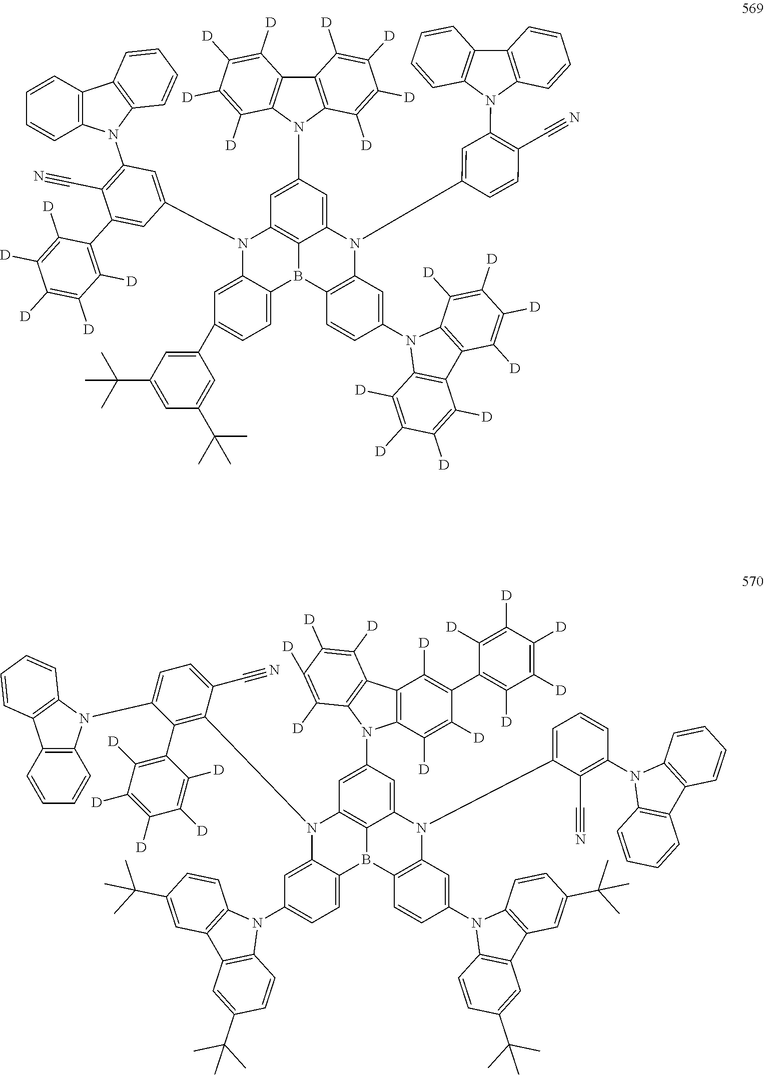

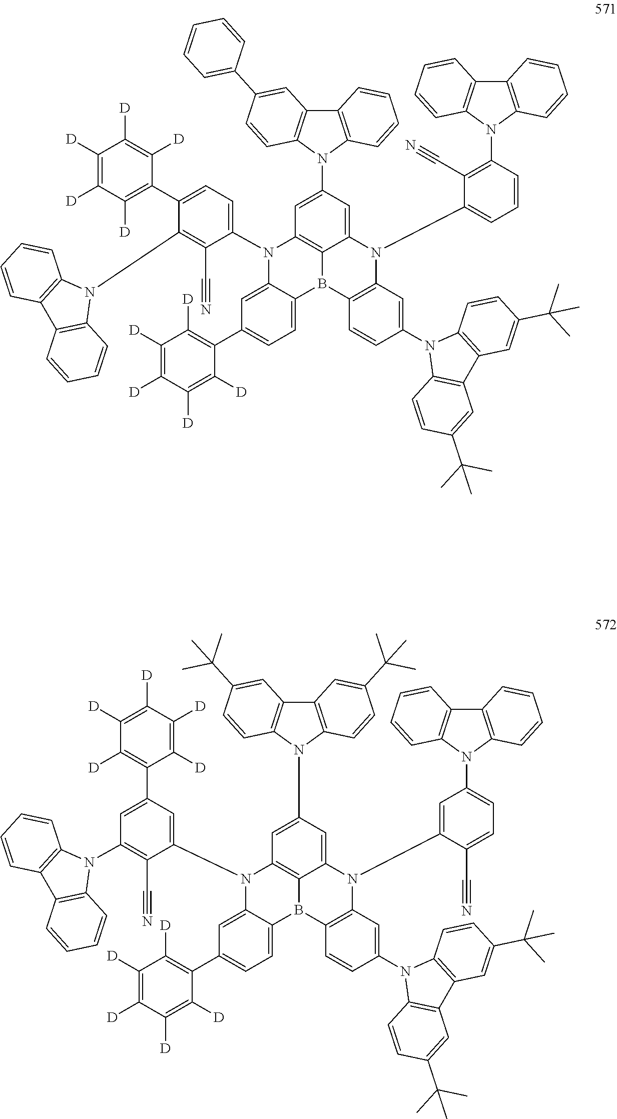

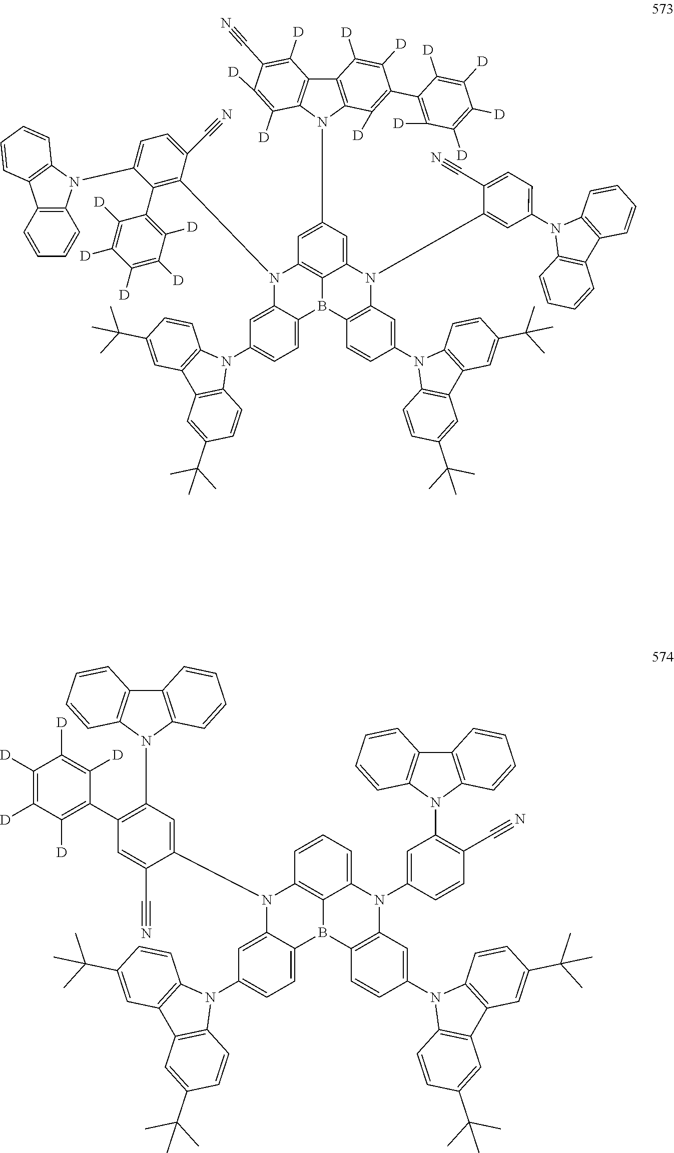

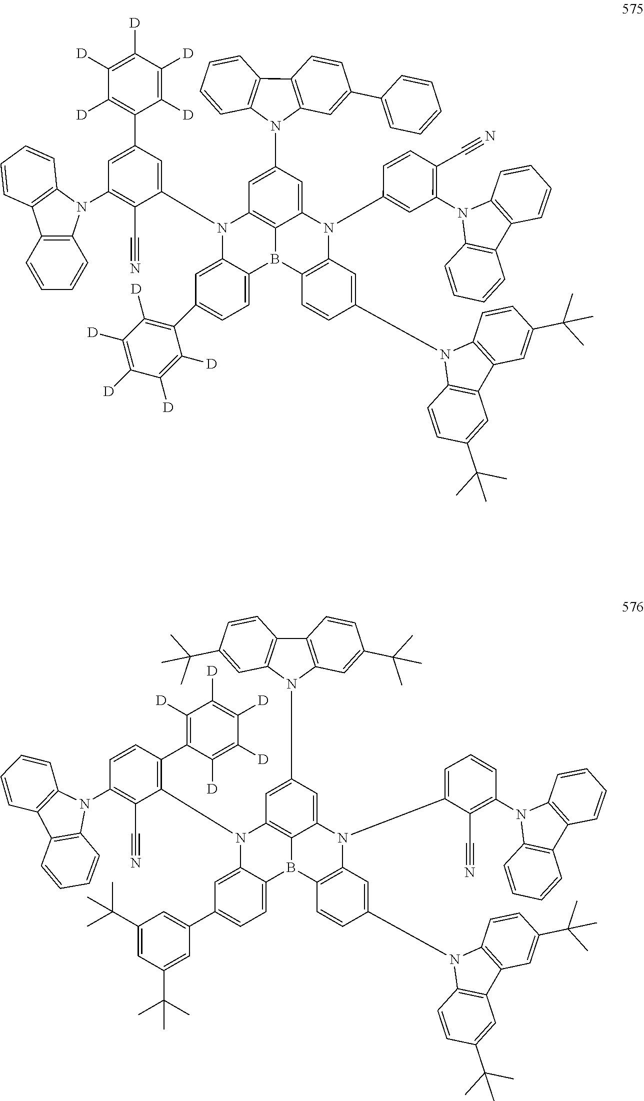

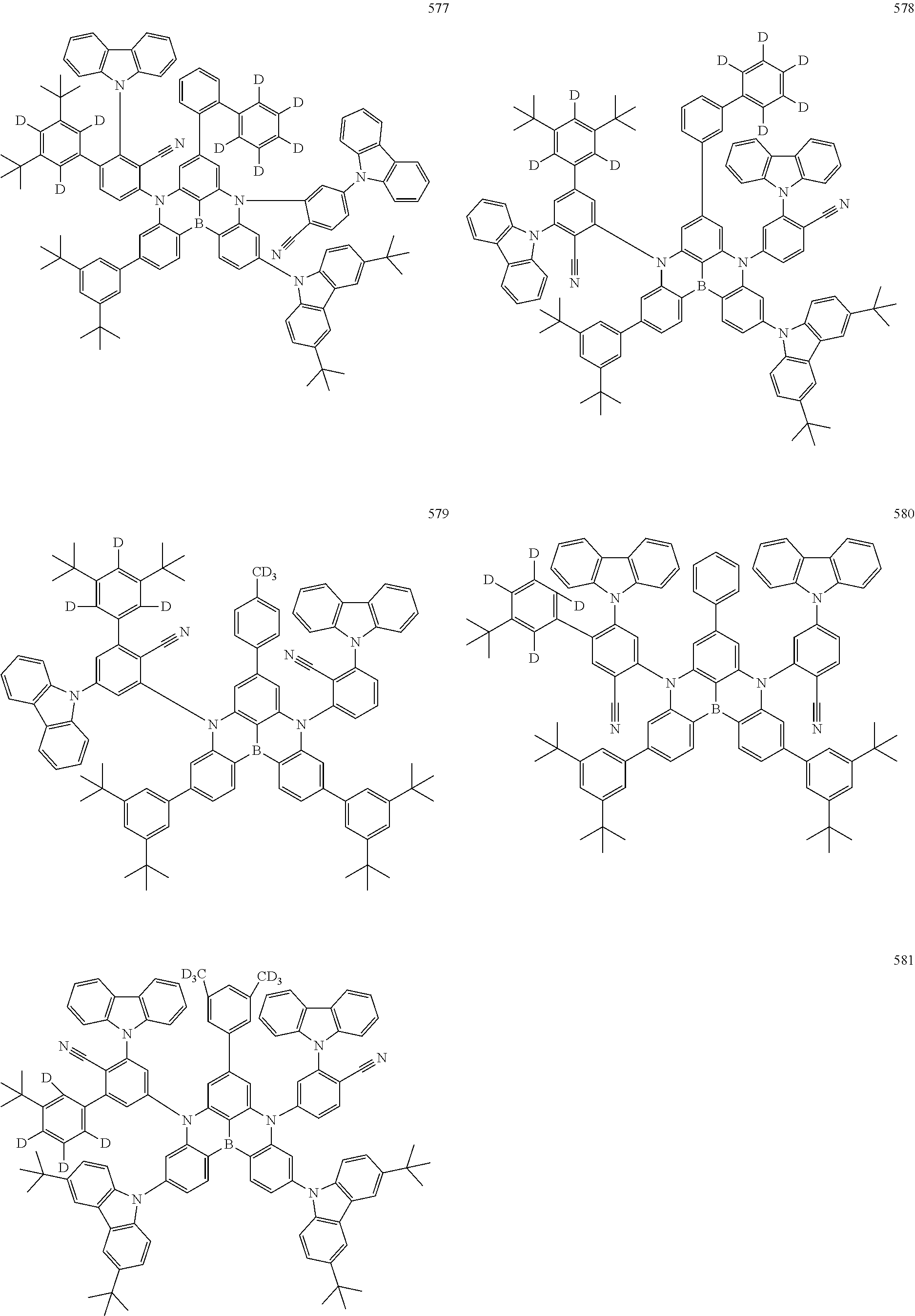

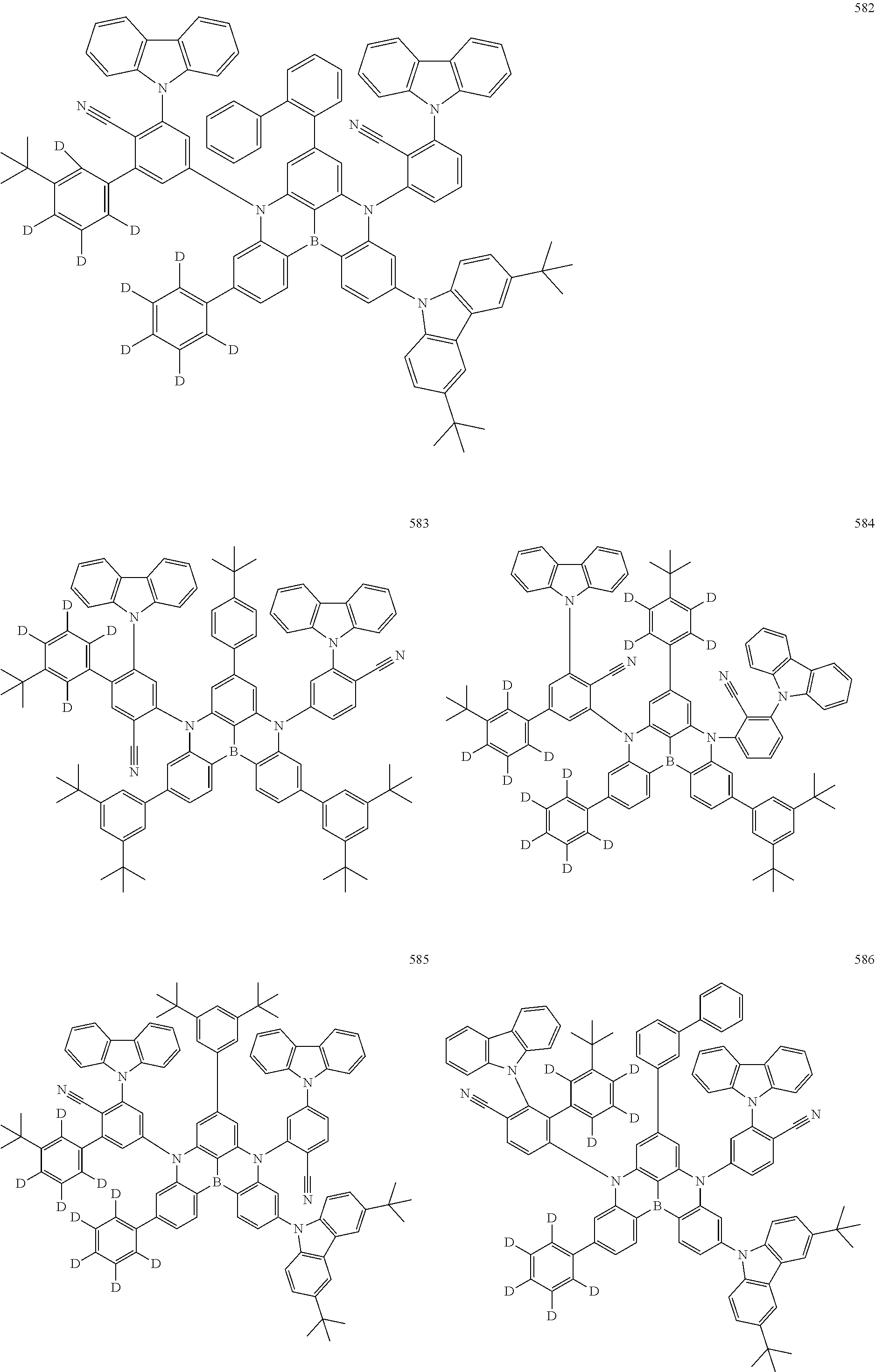

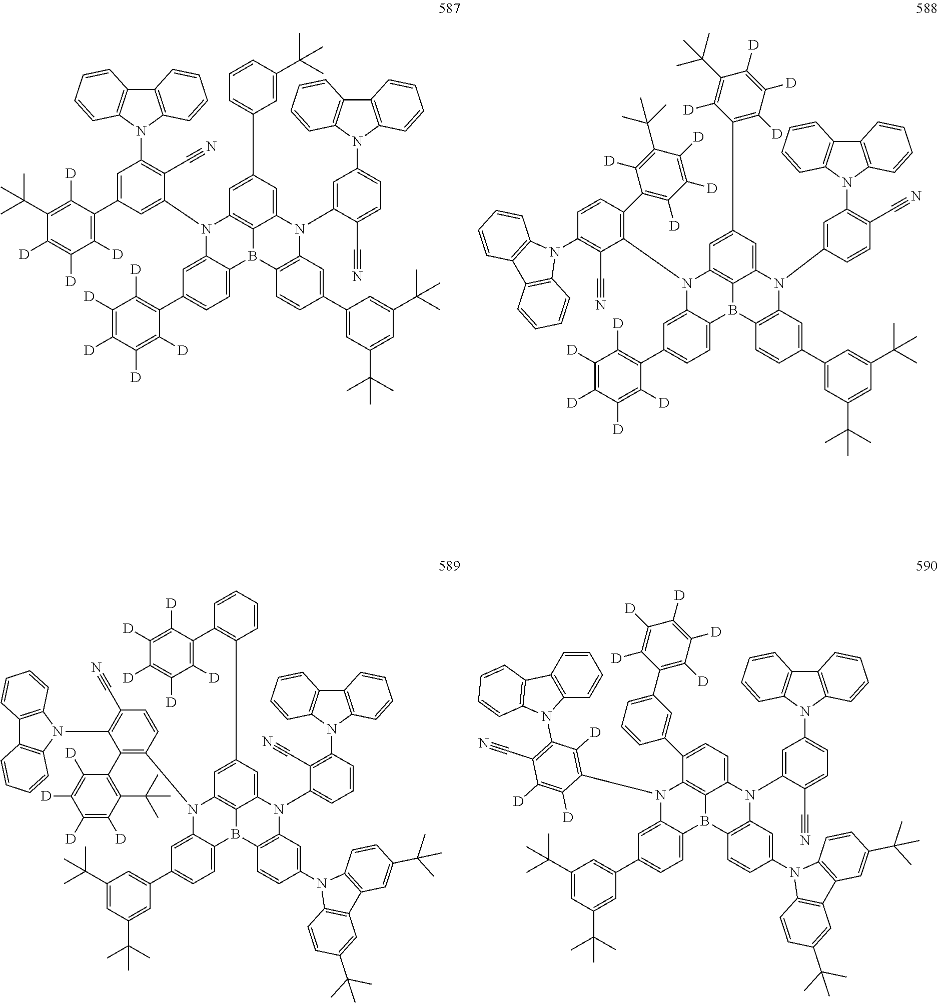

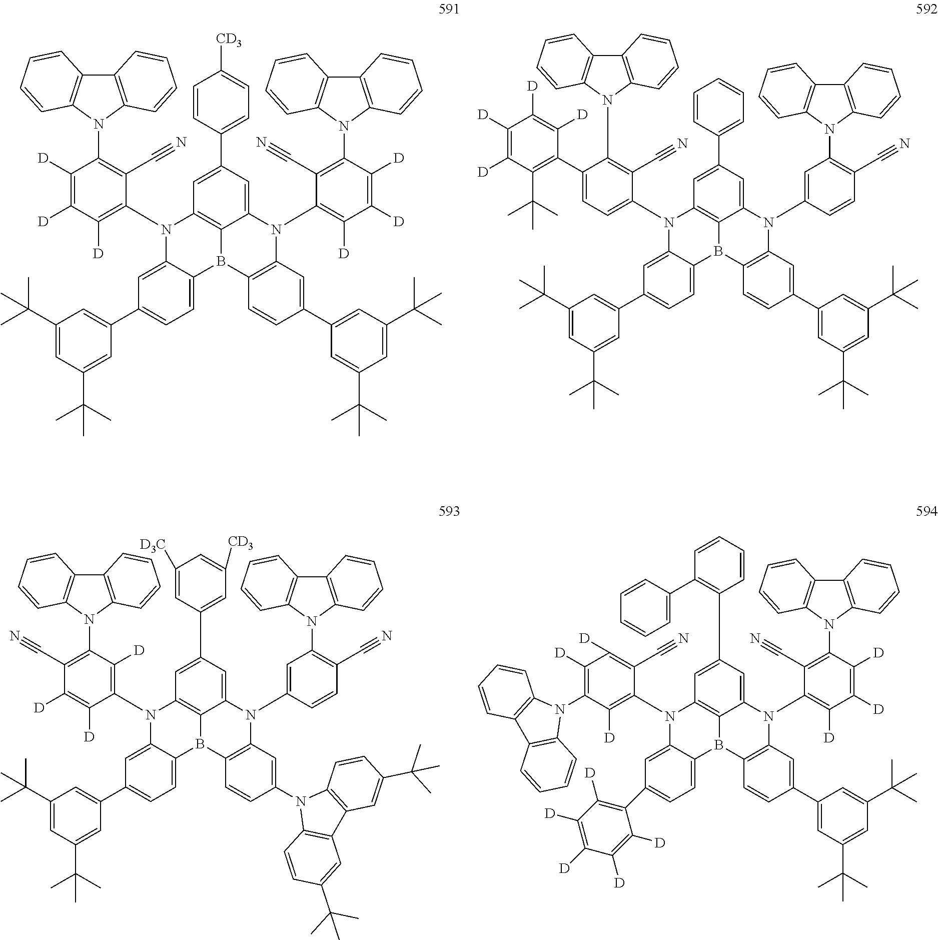

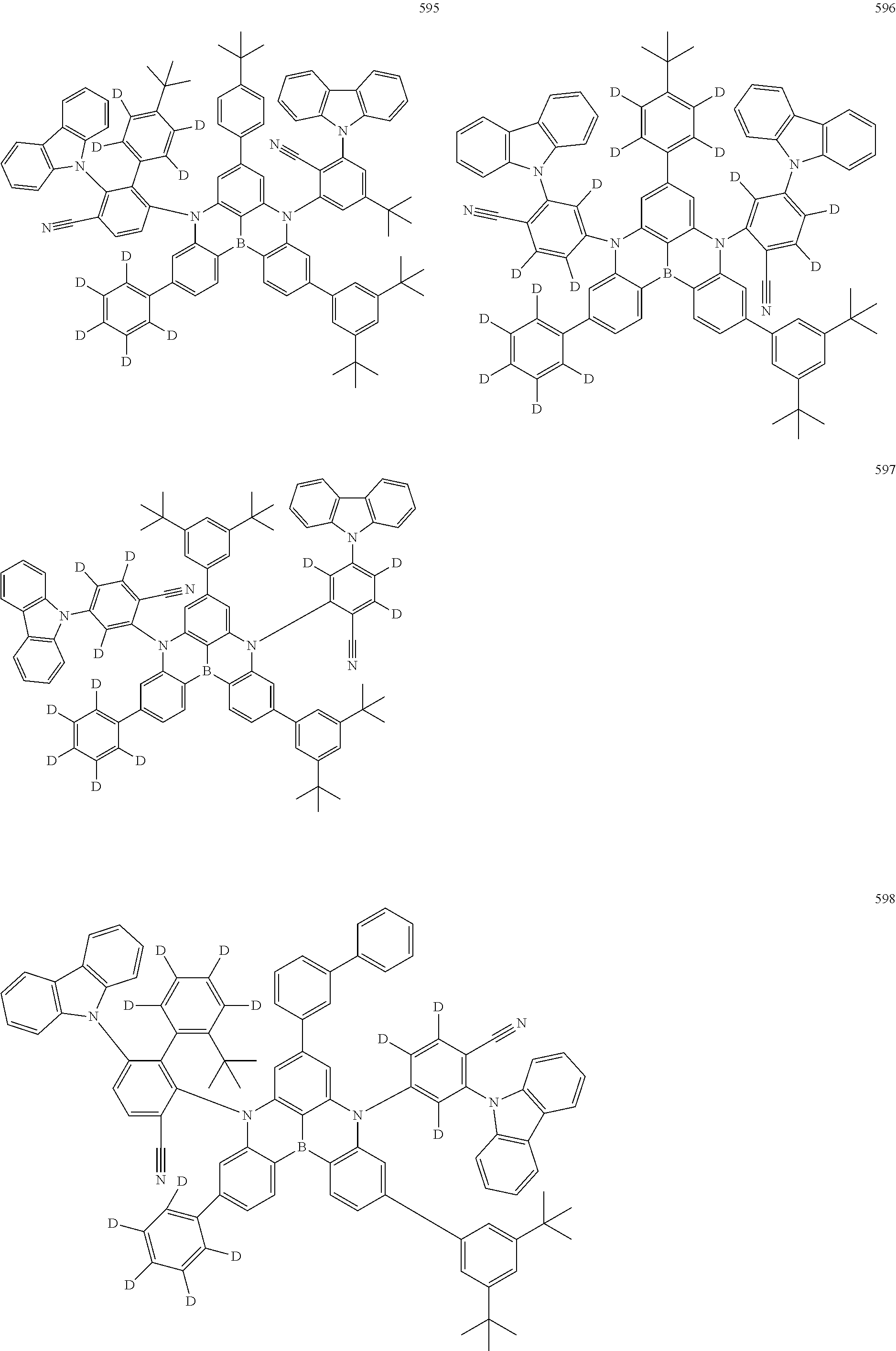

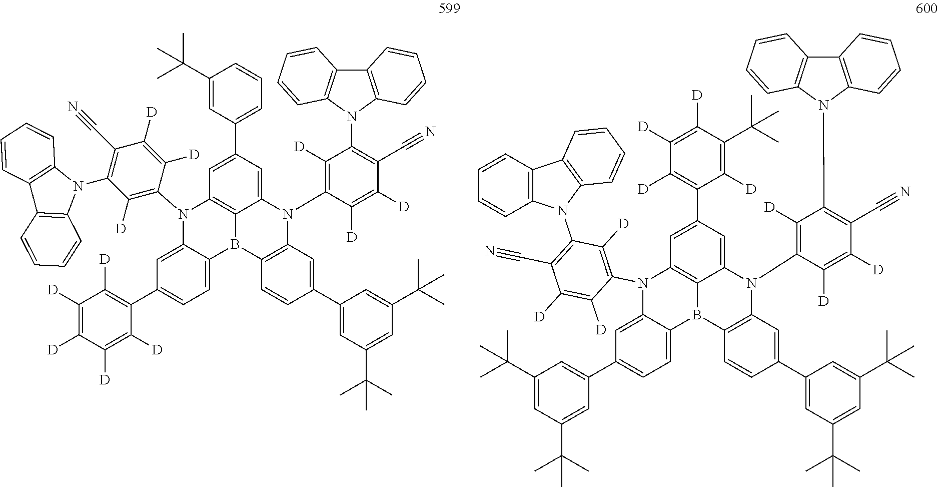 [SMILES: [2H]c1c([2H])c([2H])c(-c2ccc3c(c2)N(c2c([2H])c([2H])c(C#N)c(-n4c5ccccc5c5ccccc54)c2[2H])c2cc(-c4cccc(C(C)(C)C)c4)cc4c2B3c2ccc(-c3cc(C(C)(C)C)cc(C(C)(C)C)c3)cc2N4c2c([2H])c([2H])c(C#N)c(-n3c4ccccc4c4ccccc43)c2[2H])c([2H])c1[2H] ; [2H]c1c([2H])c(-c2cc3c4c(c2)N(c2c([2H])c([2H])c(C#N)c(-n5c6ccccc6c6ccccc65)c2[2H])c2cc(-c5cc(C(C)(C)C)cc(C(C)(C)C)c5)ccc2B4c2ccc(-c4cc(C(C)(C)C)cc(C(C)(C)C)c4)cc2N3c2c([2H])c([2H])c(C#N)c(-n3c4ccccc4c4ccccc43)c2[2H])c([2H])c(C(C)(C)C)c1[2H]]

In Compound Group 1 herein, “D” is a deuterium atom.

The fused polycyclic compound represented by Formula 1 according to one or more embodiments may have a structure in which the first substituent and the second substituent which are linked to the first linker are introduced (e.g., included), and thus may achieve improved luminescence characteristics and a long service life.

The fused polycyclic compound represented by Formula 1 of one or more embodiments may have a structure which includes the fused ring core in which the first to third aromatic rings are fused via the boron atom, the first nitrogen atom, and the second nitrogen atom, and in which the first linker is linked to the first nitrogen atom and the first substituent and the second substituent are linked to the first linker. The first linker includes a benzene moiety linked to the first nitrogen atom. The first substituent includes a carbazole moiety, and the second substituent includes a nitrile moiety.

In the case of the fused polycyclic compound of one or more embodiments, the first substituent and the second substituent are introduced (e.g., included), and thus the steric hindrance effect due to the first substituent and the second substituent may protect the empty p-orbital of the boron atom, and the trigonal planar structure of the boron atom may be effectively maintained. Accordingly, the fused polycyclic compound of one or more embodiments may have improved material stability. The fused polycyclic compound of one or more embodiments may include the first substituent and the second substituent, and thus an intermolecular interaction may be suppressed or reduced. Accordingly, the fused polycyclic compound of one or more embodiments may reduce phenomena such as aggregation, the formation of an excimer between molecules, the formation of an excimer between molecules, and/or the formation of an exciplex between molecules, which are side effects of the intermolecular interaction. Because the first substituent and the second substituent may be introduced to (e.g., included in), the fused polycyclic compound of one or more embodiments, a distance between molecules is relatively increased to suppress or reduce Dexter energy transfer and/or to reduce quenching phenomena such as triplet-triplet annihilation (TTA) according to an increase in triplet concentration. Accordingly, the fused polycyclic compound of one or more embodiments may achieve the effect of improving luminescence and service life characteristics.

In the case of the fused polycyclic compound of one or more embodiments, the first substituent may be linked to the first linker, and thus the spatial overlap of the highest occupied molecular orbital (HOMO) and lowest unoccupied molecular orbital (LUMO) may be minimized or reduced, thereby improving the multiple resonance effect. Accordingly, the fused polycyclic compound of one or more embodiments may have improved material stability. The fused polycyclic compound of one or more embodiments may have improved rigidity in the molecule by linking the second substituent to the first linker. Accordingly, the movement (e.g., intramolecular vibrations) in the molecule may be suppressed or reduced, and Stoke's shift is reduced, so that a photoluminescence quantum yield (PLQY) and fluorescence resonance energy transfer (FRET) between molecules may be increased. The term “Stoke's shift,” as utilized herein may refer to a difference between the maximum wavelength when the energy is absorbed by or in the compound and the maximum wavelength when the energy is emitted by or from the compound. Accordingly, the fused polycyclic compound of one or more embodiments may achieve blue emission with high color purity.

In the fused polycyclic compound of one or more embodiments, the first nitrogen atom of the fused ring core and the first substituent may be linked at the position of a carbon atom having an electron withdrawing characteristic among the carbon atoms included in (e.g., constituting) the first linker. Referring to Formula S1, the carbon at positions “a” in the first linker may have the electron withdrawing characteristic. In some embodiments, a cyano group linked to the first linker in Formula S1 refers to a second substituent.

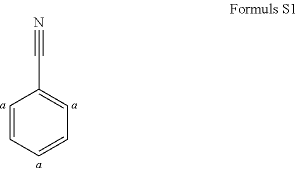

In the fused polycyclic compound of one or more embodiments, the first nitrogen atom of the fused ring core and the first substituent may each be linked at positions “a” of the first linker having the electron withdrawing characteristic. Accordingly, the HOMO and LUMO energy levels may be effectively separated, and thus it may be expected to improve the multiple resonance effect. Thus, the fused polycyclic compound of one or more embodiments in which the first substituent and the second substituent are introduced (e.g., included) may exhibit high luminous efficiency.

The fused polycyclic compound according to one or more embodiments of the present disclosure may include the first substituent and the second substituent, and thus the material stability may be improved and the blue emission with high color purity may be achieved. In the case of introducing (e.g., including) the fused polycyclic compound according to one or more embodiments of the present disclosure as a dopant for the emission layer, the element service life, luminous efficiency, and color purity may be improved.

The emission spectrum of the fused polycyclic compound represented by Formula 1 of one or more embodiments has a full width of half maximum (FWHM) of about 10 nanometer (nm) to about 50 nm, or about 20 nm to about 40 nm. The emission spectrum of the fused polycyclic compound represented by Formula 1 of one or more embodiments has the described FWHM range, thereby improving luminous efficiency when applied to a device. In some embodiments, when the fused polycyclic compound of one or more embodiments is utilized as a blue light emitting element material for the light emitting element, the element service life may be improved.

In some embodiments, the fused polycyclic compound of one or more embodiments may be included in the emission layer EML. The fused polycyclic compound of one or more embodiments may be included as a dopant material in the emission layer EML. The fused polycyclic compound of one or more embodiments may be a thermally activated delayed fluorescence material. The fused polycyclic compound of one or more embodiments may be utilized as a thermally activated delayed fluorescence dopant. For example, in the light emitting element ED of one or more embodiments, the emission layer EML may include, as a thermally activated delayed fluorescence dopant, at least one selected from among the fused polycyclic compounds represented by Compound Group 1 as described herein. However, a utilization of the fused polycyclic compound of one or more embodiments is not limited thereto.

The fused polycyclic compound represented by Formula 1 of one or more embodiments may be a thermally activated delayed fluorescence emitting material. In some embodiments, the fused polycyclic compound represented by Formula 1 of one or more embodiments may be a luminescent material having a luminescence center wavelength in a wavelength region of about 430 nm to about 490 nm. For example, the fused polycyclic compound represented by Formula 1 of one or more embodiments may be a blue thermally activated delayed fluorescence (TADF) dopant. However, the embodiment of the present disclosure is not limited thereto, when the fused polycyclic compound of one or more embodiments is utilized as a luminescent material, the first dopant may be utilized as a dopant material that emits light in one or more suitable wavelength regions, such as a red emitting dopant and a green emitting dopant.

The emission layer EML in the light emitting element ED of one or more embodiments may be to emit delayed fluorescence. For example, the emission layer EML may be to emit thermally activated delayed fluorescence (TADF).

In some embodiments, the emission layer EML of the light emitting element ED may be to emit blue light. For example, the emission layer EML of the organic electroluminescence device ED of one or more embodiments may be to emit blue light in the region of about 490 nm or less. However, the embodiment of the present disclosure is not limited thereto, and the emission layer EML may be to emit green light or red light.

In one or more embodiments, the emission layer EML may include the first compound represented by Formula 1, and may further include at least one selected from among the first compound represented by Formula 1, the second compound represented by Formula HT-1, the third compound represented by Formula ET-1, or the fourth compound represented by Formula D-1, each of which is described in more detail herein.

In one or more embodiments, the second compound may be utilized as a hole transporting host material of the emission layer EML.

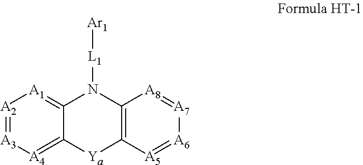

In Formula HT-1, A₁ to A₈ may each independently be N or CR₅₁. For example, all of A₁ to A₈ may be CR₅₁. In some embodiments, at least (e.g., any) one selected from among A₁ to A₈ may be N, and the rest (e.g., any remaining A₁ to A₈) may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, and/or the like, but the embodiment of the present disclosure is not limited thereto.

In Formula HT-1, Yₐ may be a direct linkage, CR₅₂R₅₃, or SiR₅₄R₅₅. For example, it may refer to that the two benzene rings linked to the nitrogen atom in Formula HT-1 are linked via a direct linkage,

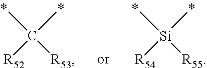

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but the embodiment of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₅₁ to R₅₅ may be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one (e.g., one) selected from among the compounds represented by Compound Group 2. The emission layer EML may include at least one (e.g., one or more) selected from among the compounds represented by Compound Group 2 as a hole transporting host material.

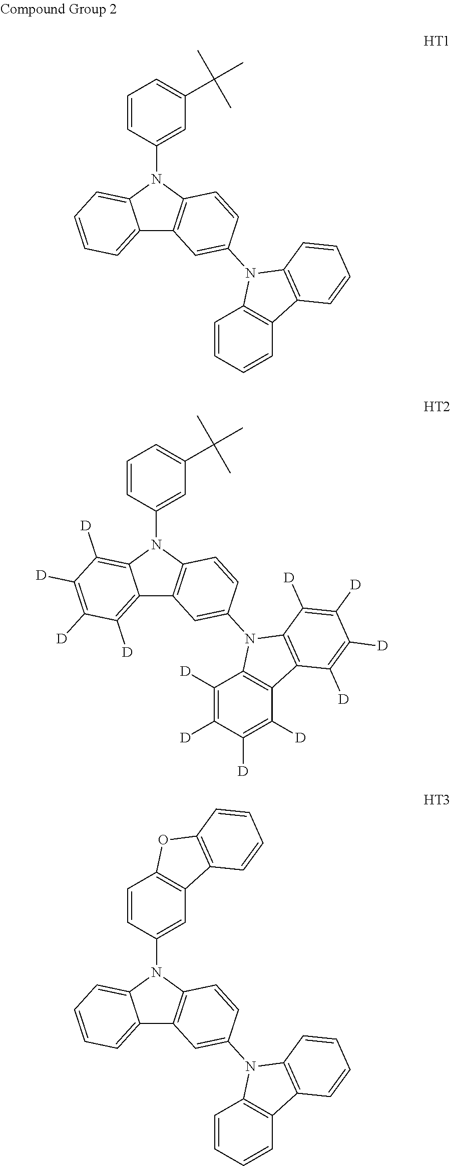

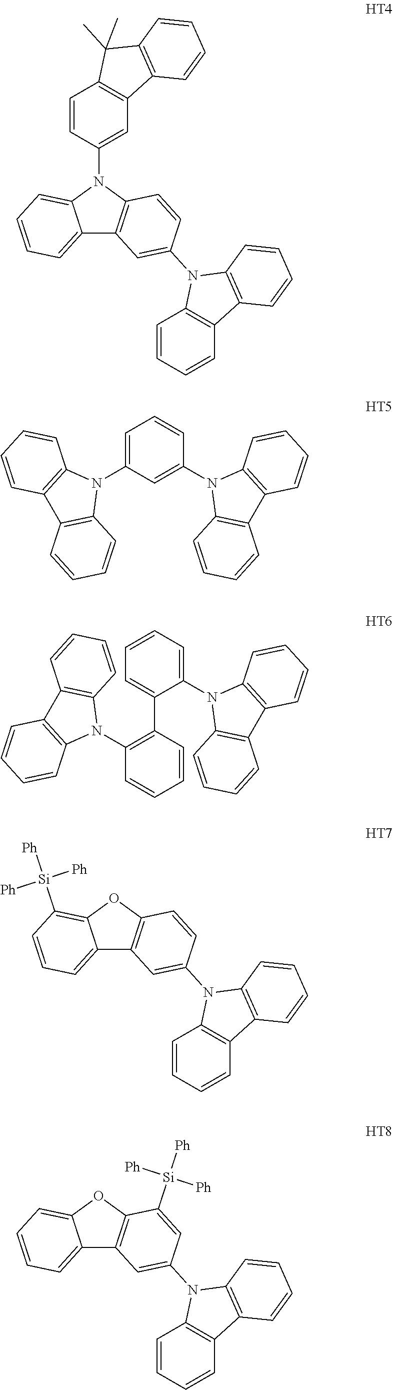 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

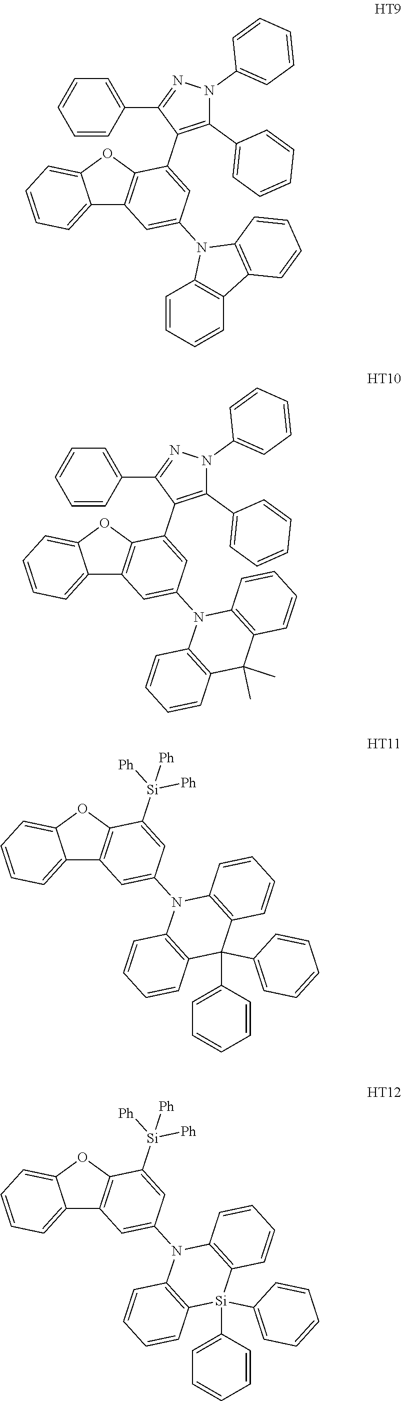

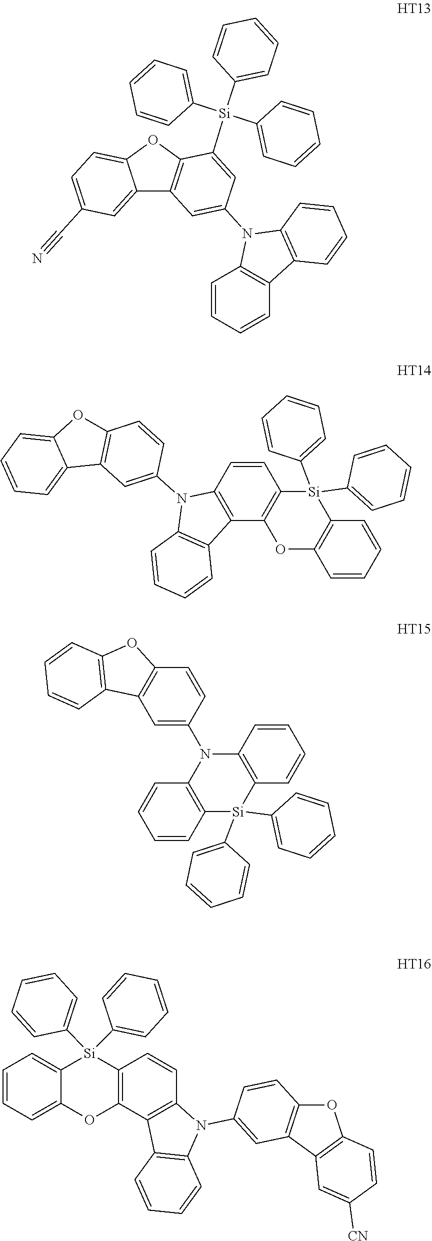 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

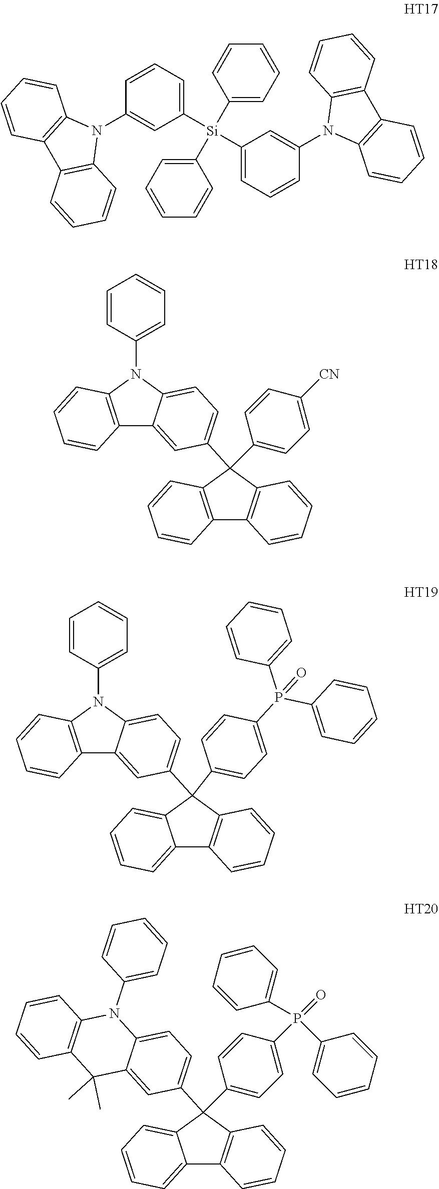 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

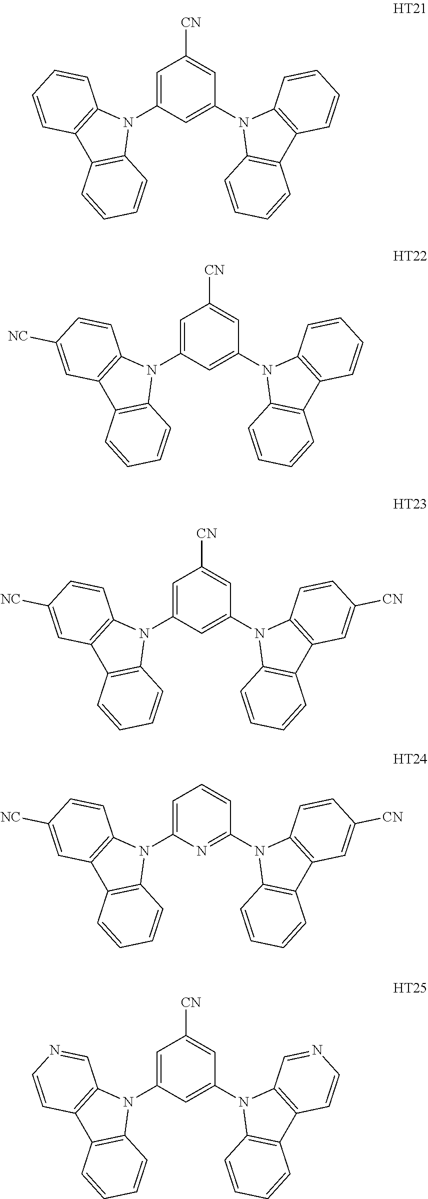 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1]

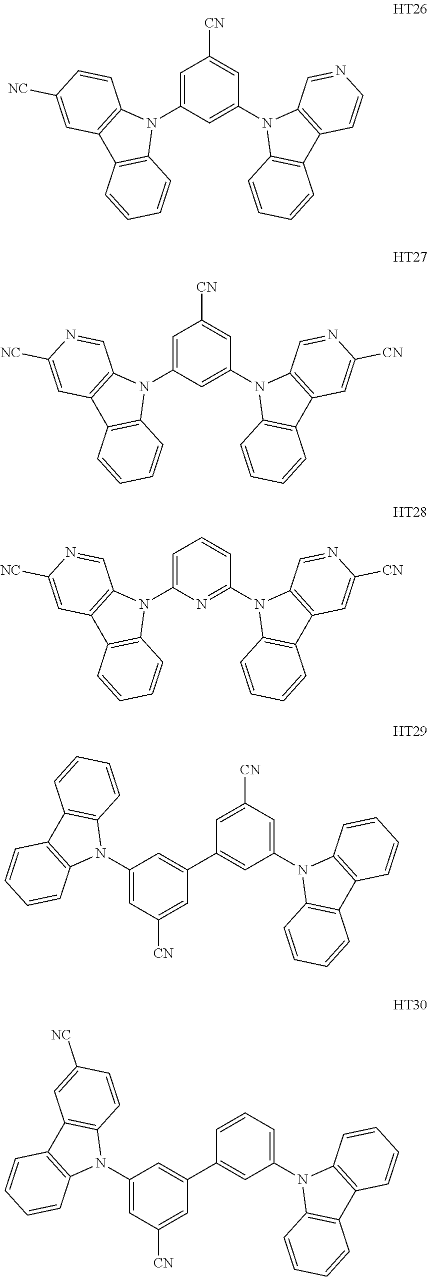 [SMILES: N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

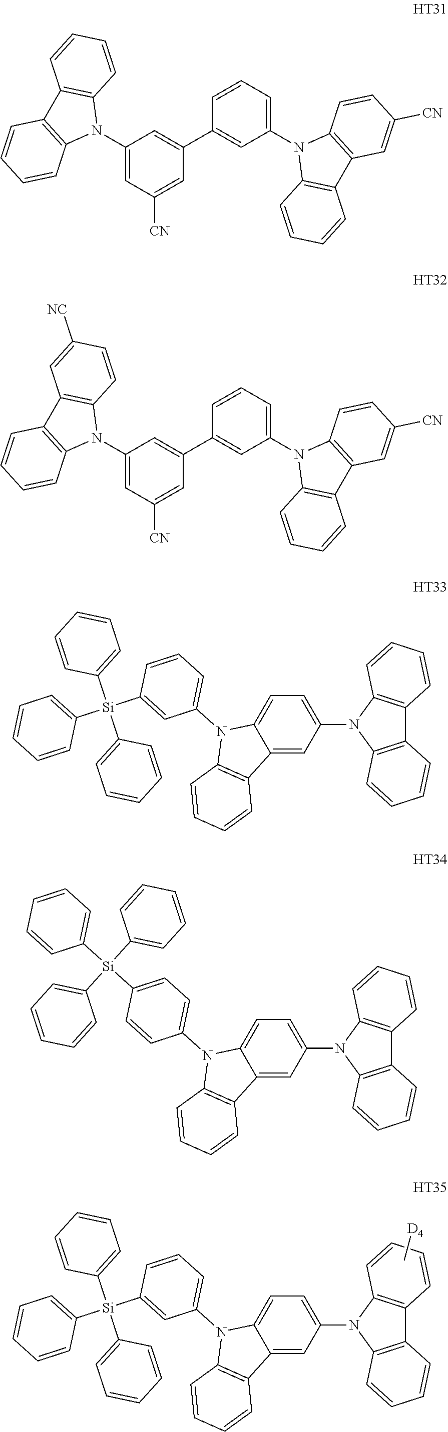

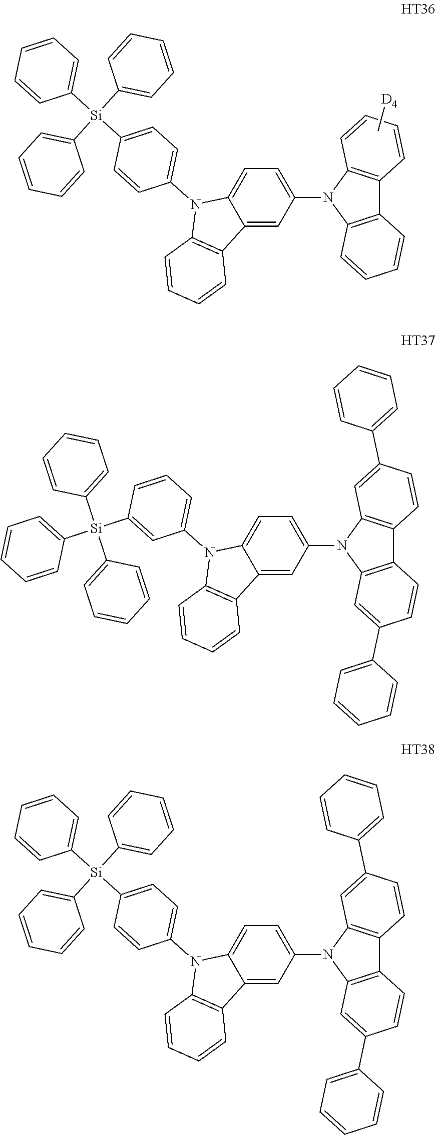

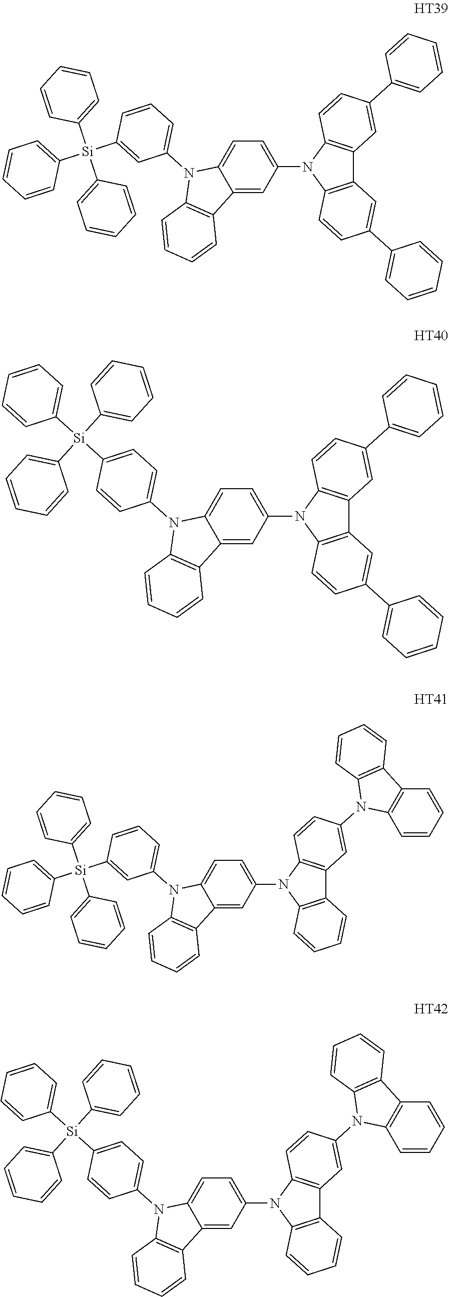 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

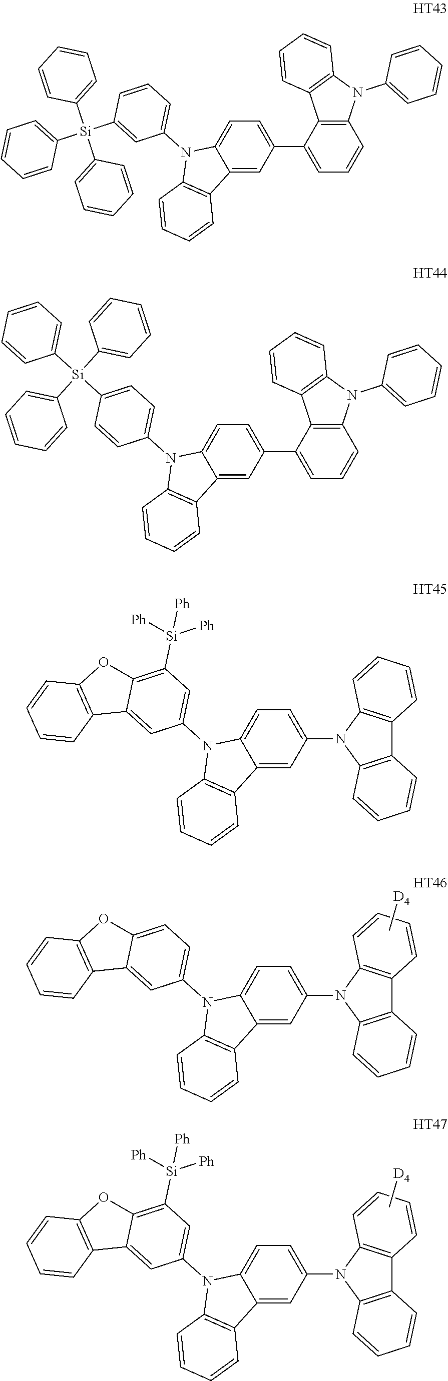

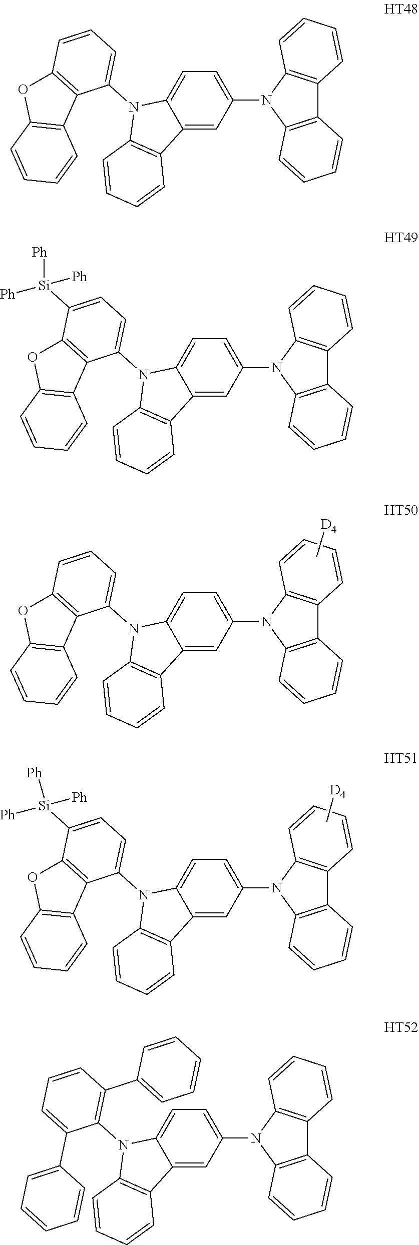

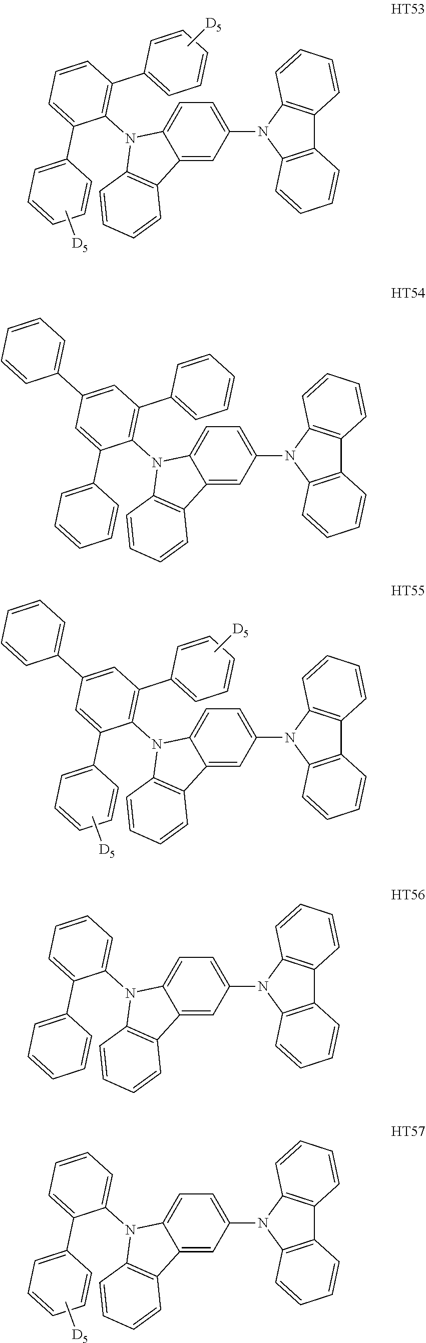

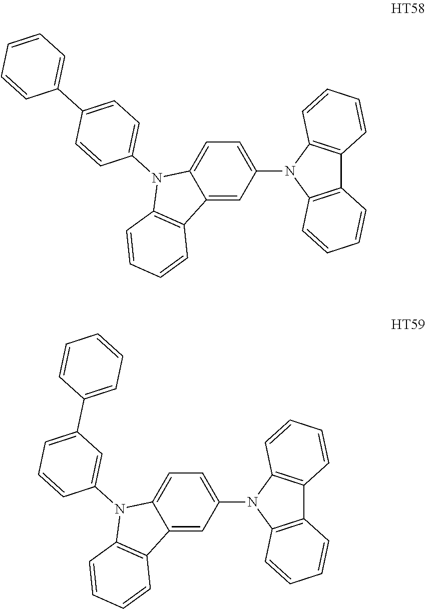 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In embodiment compounds presented in Compound Group 2, “D” may refer to a deuterium atom, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be utilized as an electron transport host material for the emission layer EMIL.

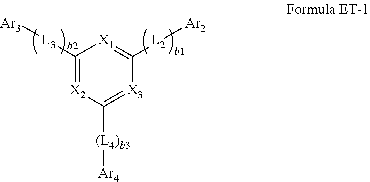

In Formula ET-1, at least one selected from among X₁ to X₂ is N, and the rest are CR₅₆. For example, any one selected from among X₁ to X₃ may be N, and the rest (e.g., any remaining X₁ to X₃) may each independently be CR₅₆. In this case, the third compound represented by Formula ET-1 may include a pyridine moiety. In some embodiments, two selected from among X₁ to X₃ may be N, and the rest (e.g., the remaining (e.g., selected from among) X₁ to X₃) may be CR₅₆. In this case, the third compound represented by Formula ET-1 may include a pyrimidine moiety. In some embodiments, X₁ to X₃ may all be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when b1 to b3 are integers of 2 or greater, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the third compound may be represented by any one (e.g., one) selected from among compounds in Compound Group 3. The light emitting device ED of one or more embodiments may include at least one (e.g., one or more) selected from among the compounds in Compound Group 3.

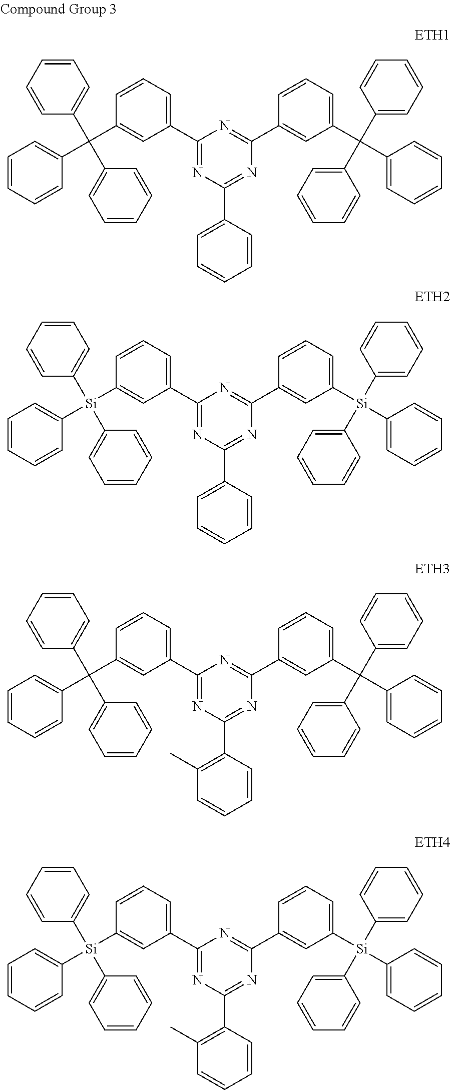 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

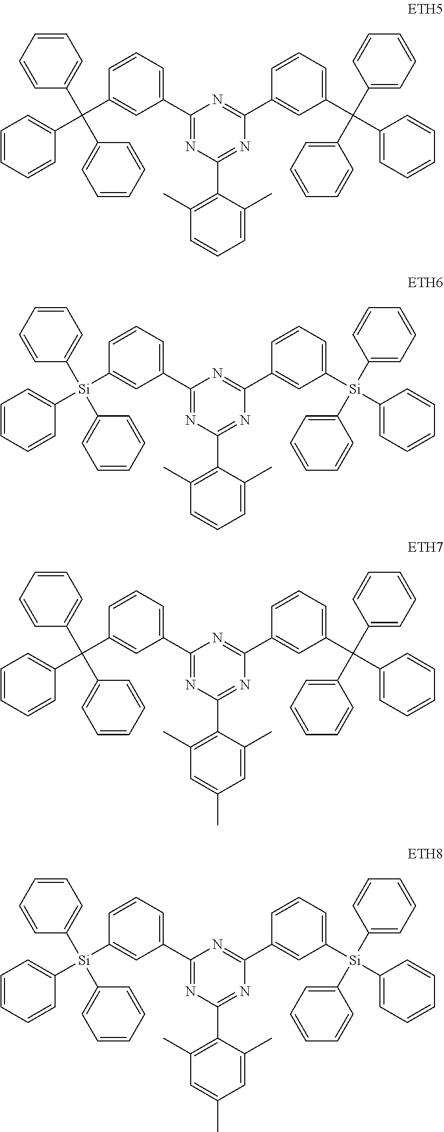 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

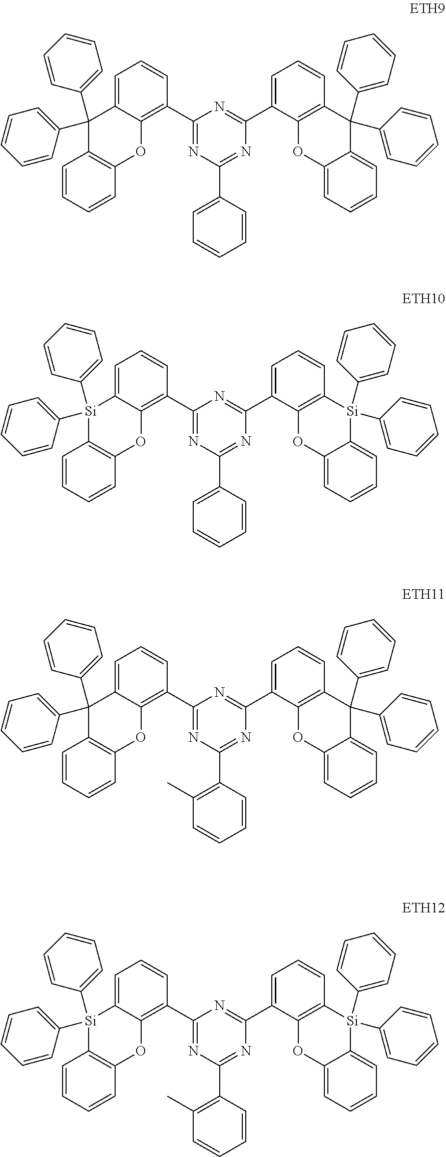 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

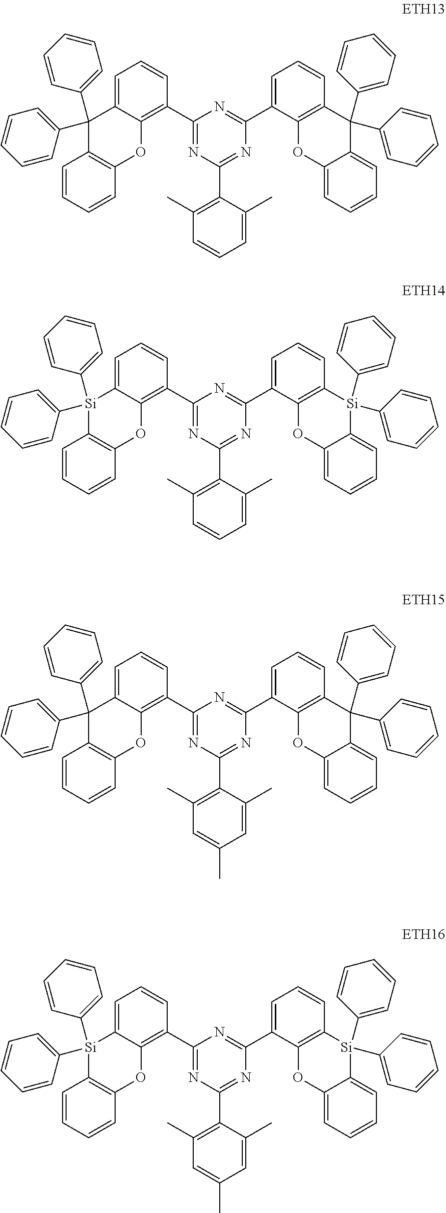 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

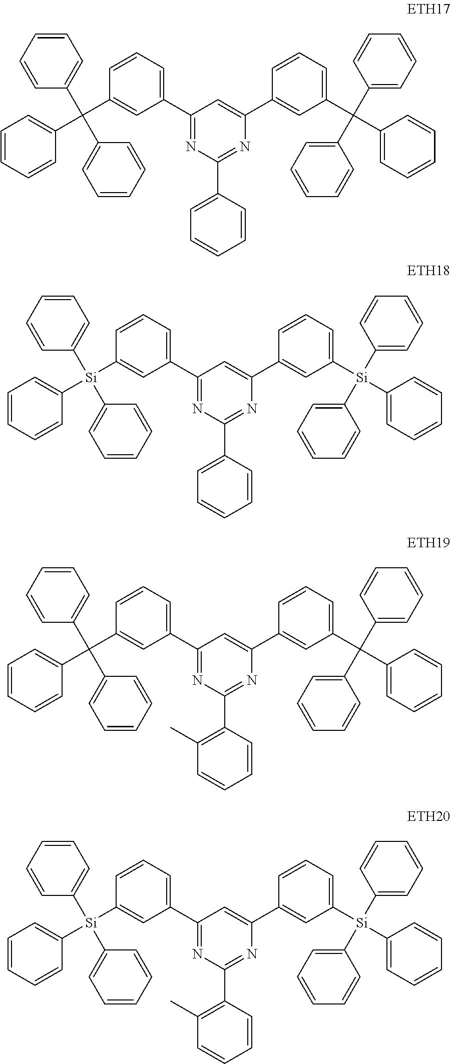 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

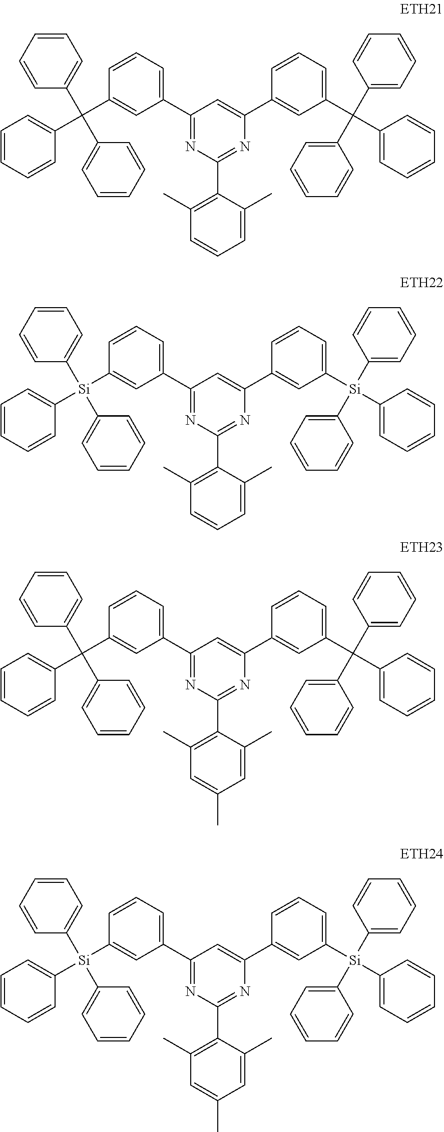 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

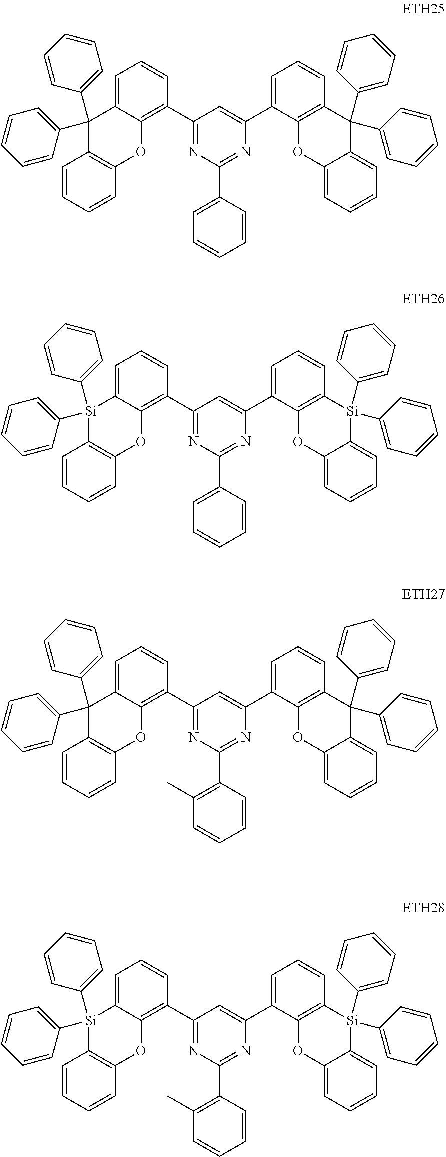 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

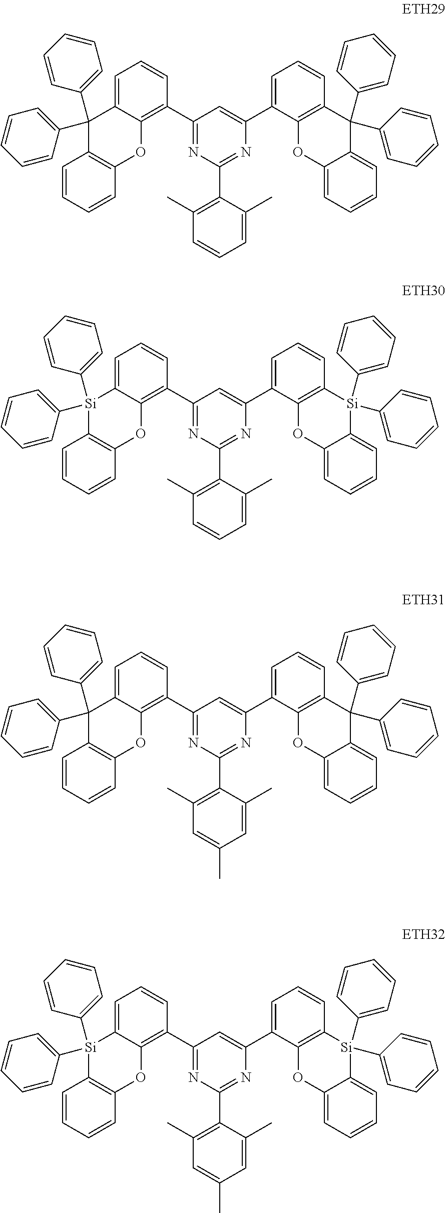 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

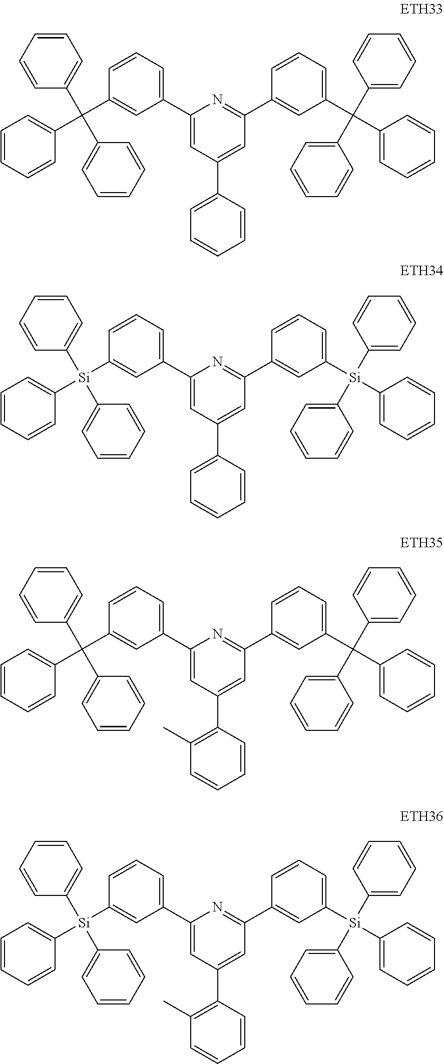 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

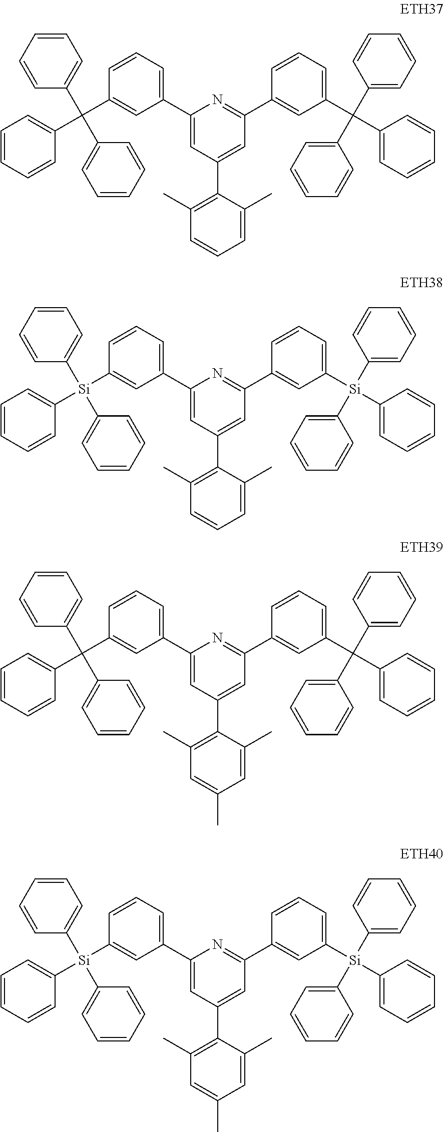 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

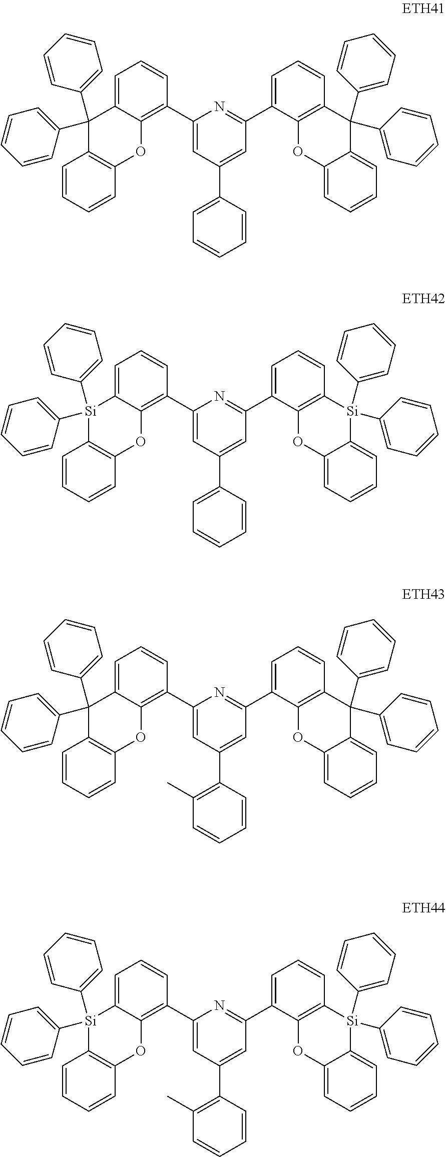 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

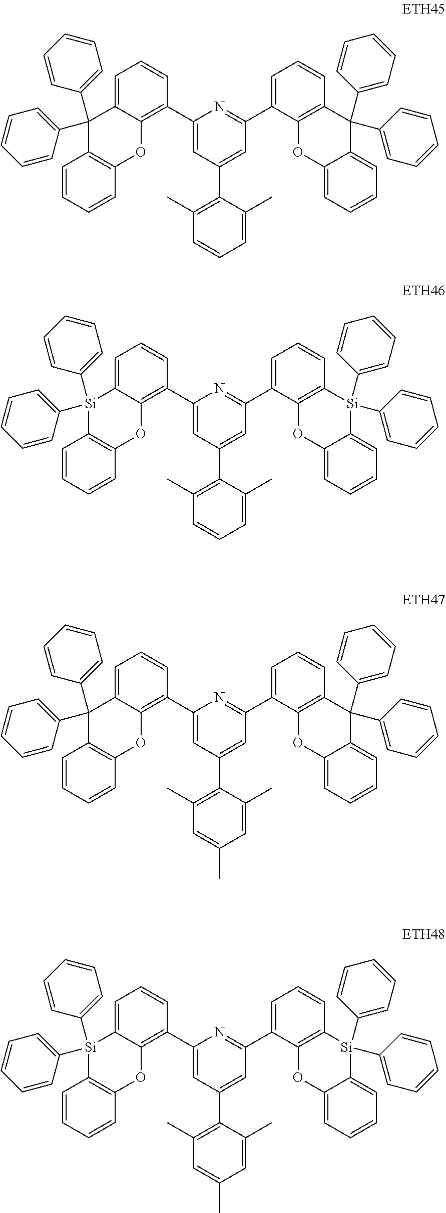 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

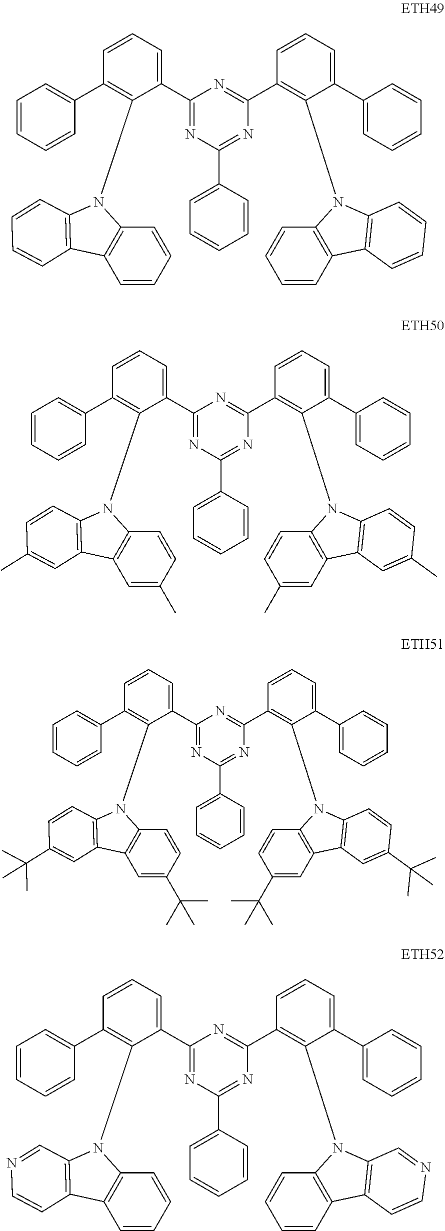

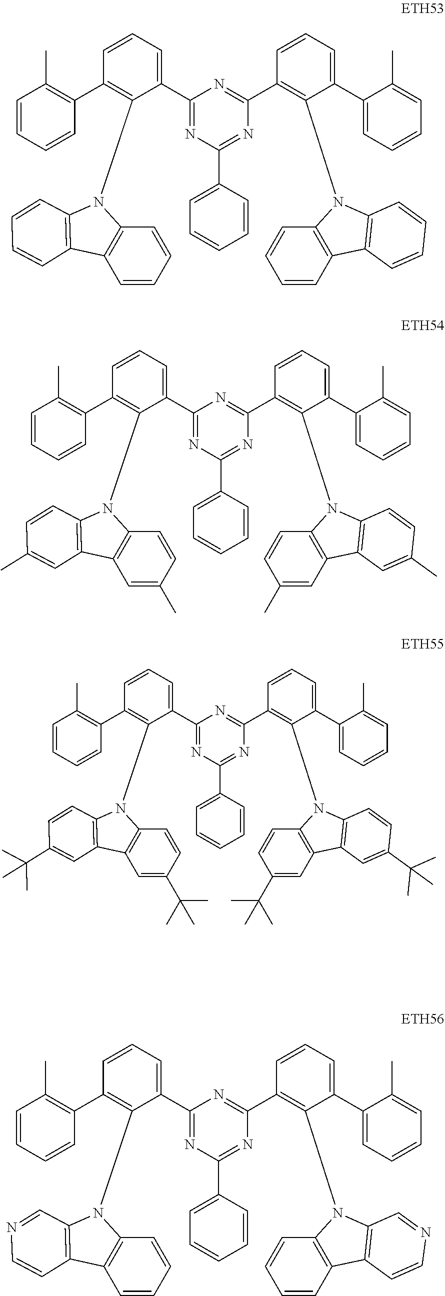

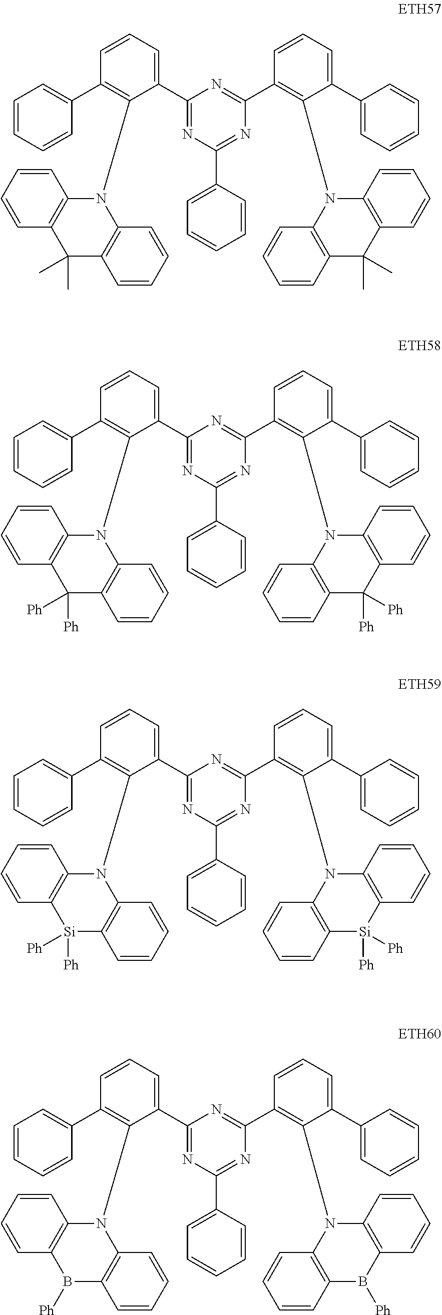

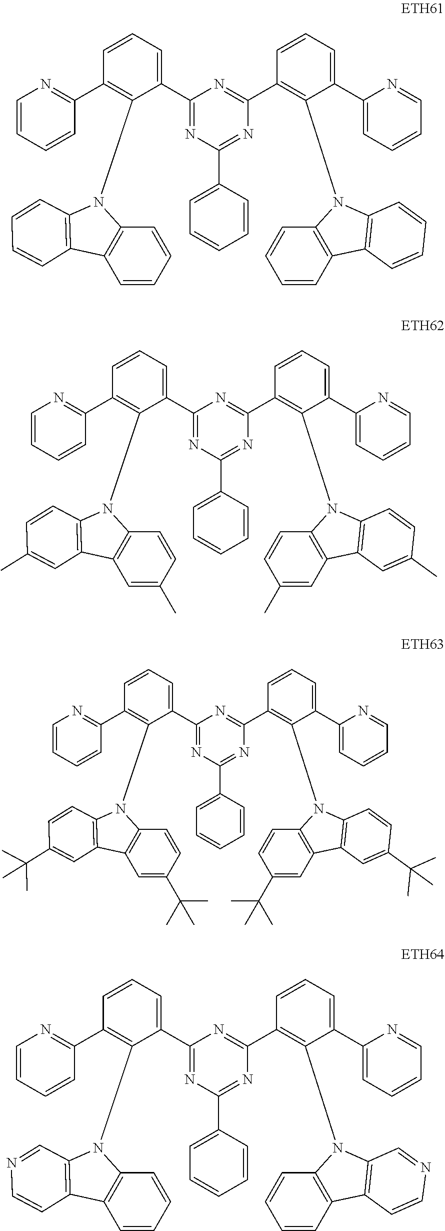

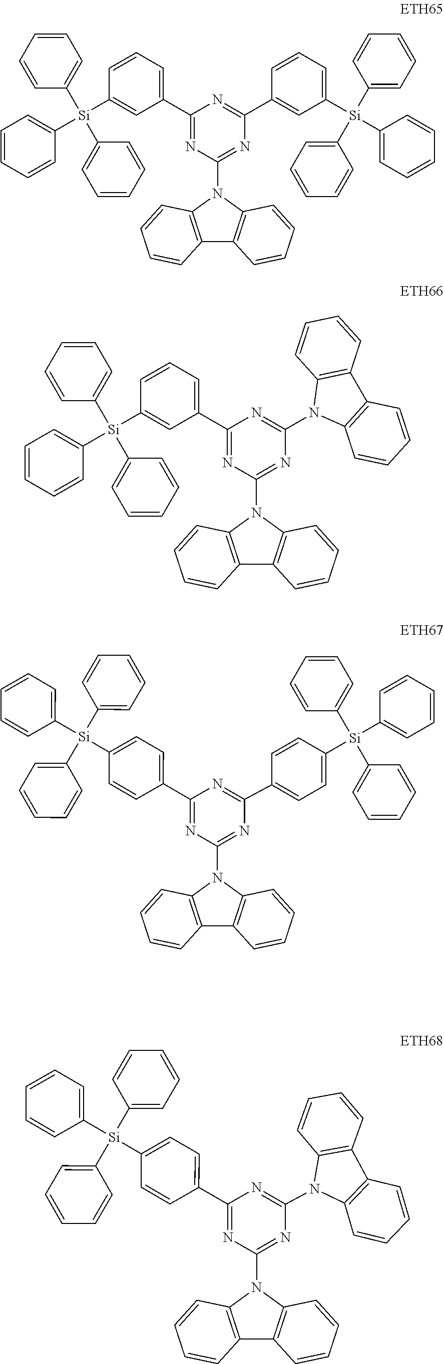 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

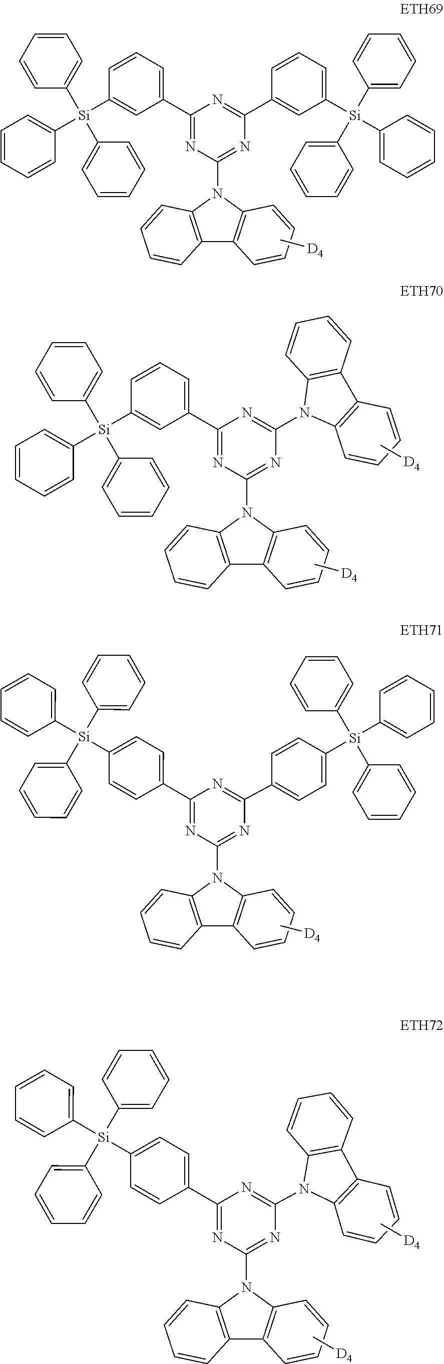

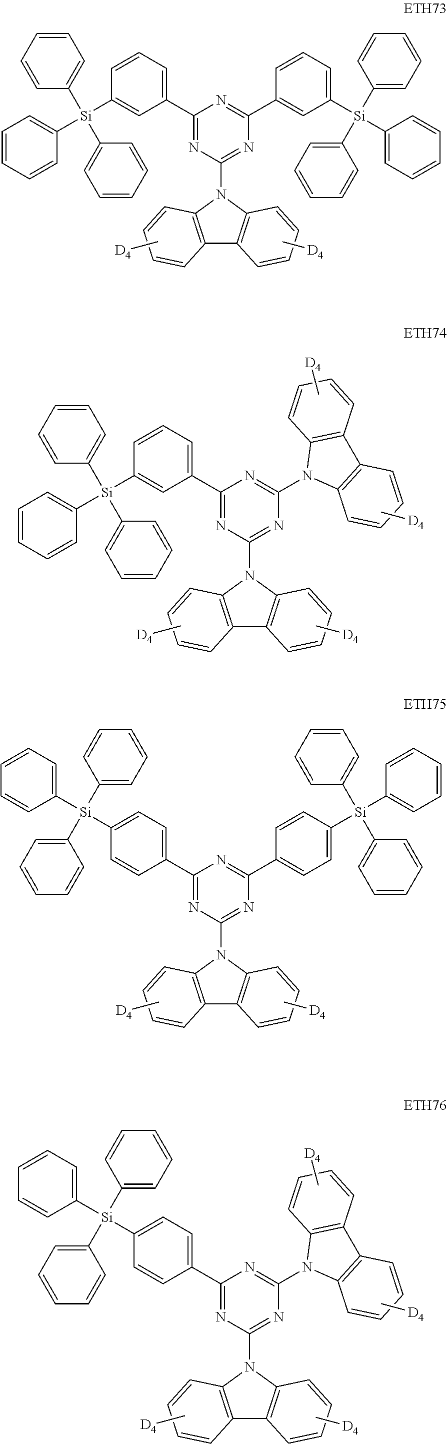

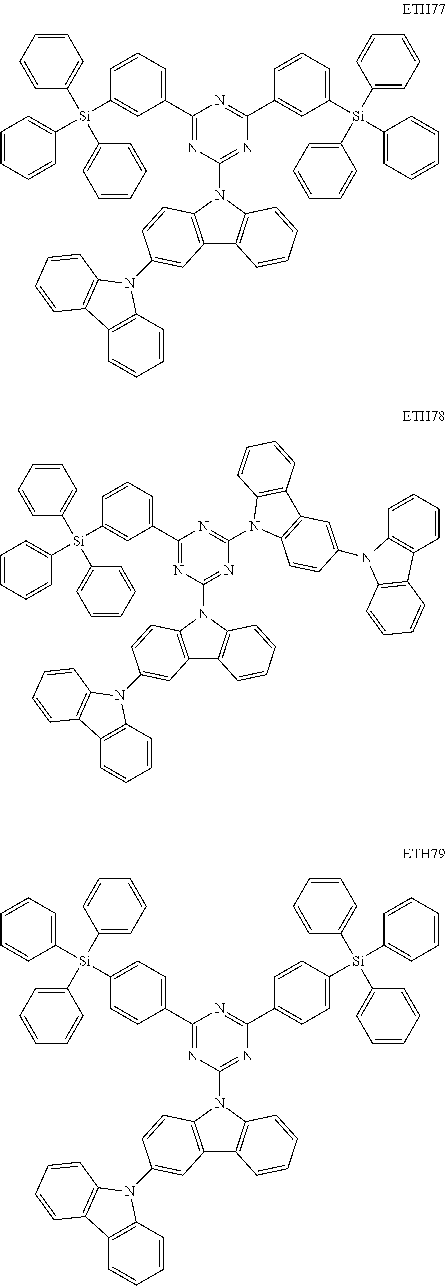 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

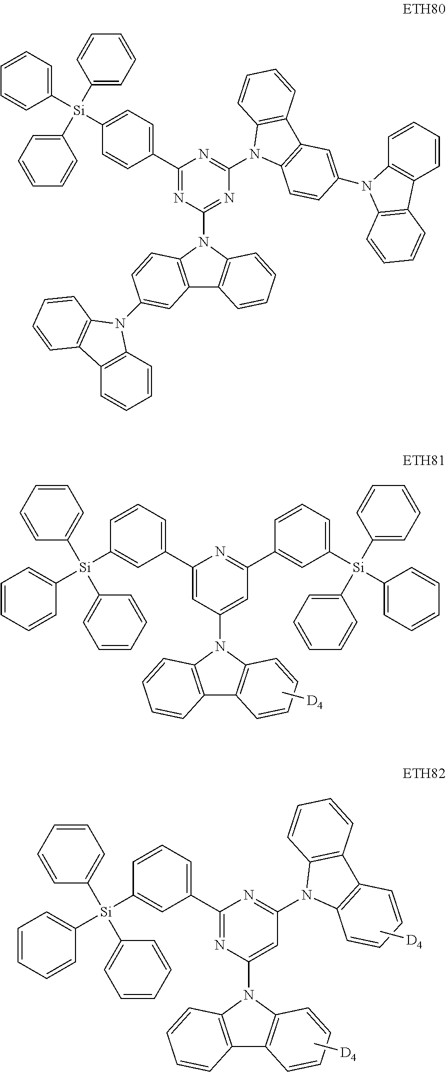

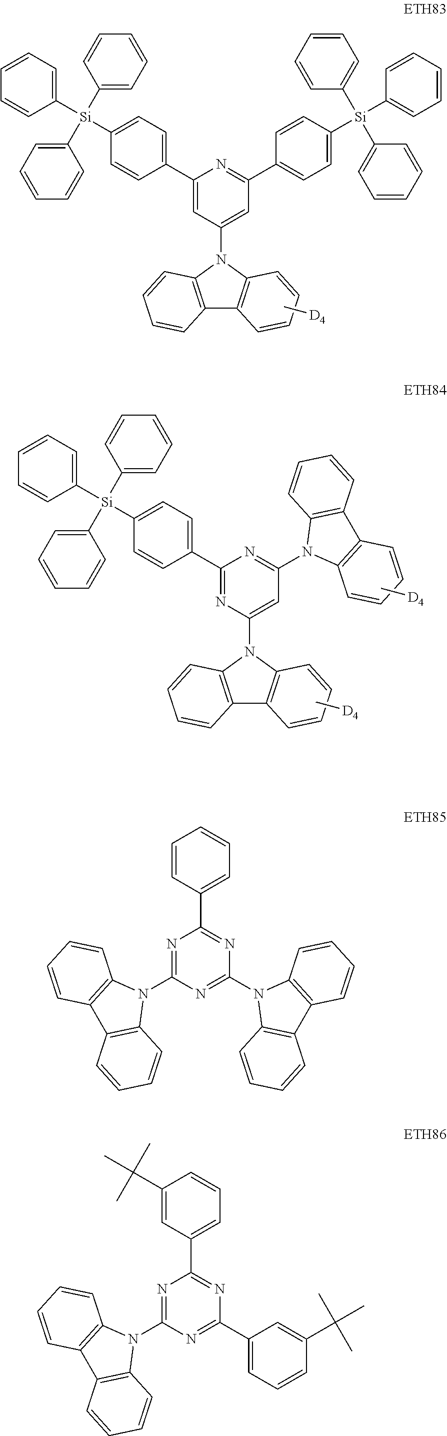

In the embodiment compounds presented in Compound Group 3, “D” refers to a deuterium atom and “Ph” refers to an unsubstituted phenyl group.

The emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 electron volt (eV) to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described herein. The fourth compound may be utilized as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting device ED of one or more embodiments may include, as the fourth compound, a compound represented by Formula D-1:

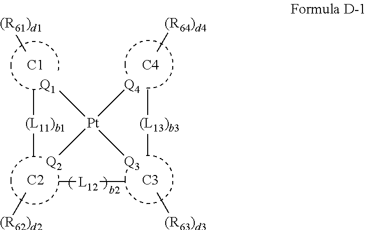

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage, *—O—*, *—S—*,

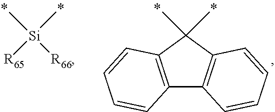

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “-*” refers to a part linked to C1 to C4.

In Formula D-1, b1 to b3 may each independently be 0 or 1. When b1 is 0, C1 and C2 may not be linked to each other. When b2 is 0, C2 and C3 may not be linked to each other. When b3 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₆₁ to R₆₆ may be bonded to an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when each of d1 to d4 is 0, the fourth compound may not be substituted with each of R₆₁ to R_{c4}. The case where each of d1 to d4 is 4 and R₆₁'s to R₆₄' are each hydrogen atoms may be the same as the case where each of d1 to d4 is 0. When each of d1 to d4 is an integer of 2 or more, a plurality of R₆₁'s to R₆₄'s may each be the same or at least one selected from among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one selected from among C-1 to C-4:

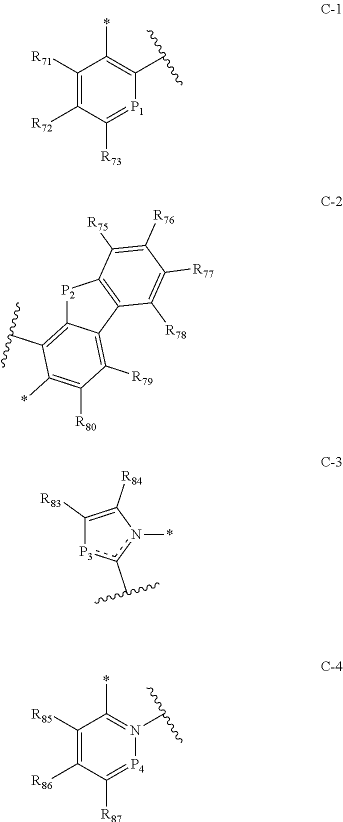

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In some embodiments, in C-1 to C-4,

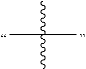

corresponds to a part linked to Pt that is a central metal atom, and “-*” corresponds to a part linked to a neighboring cyclic group (C1 to C4) or a linker (L₁₁ to L₁₃).

The emission layer EML of one or more embodiments may include the first compound, which is a fused polycyclic compound, and at least one of the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light emitting device ED of one or more embodiments may serve as a sensitizer to deliver energy from the host to the first compound that is a light emitting dopant. For example, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. In some embodiments, when the energy delivery to the first compound is increased, an exciton formed in the emission layer EML is not accumulated inside the emission layer EML and emits light rapidly, and thus deterioration of the device may be reduced. Therefore, the service life of the light emitting device ED of one or more embodiments may increase.

The light emitting device ED of one or more embodiments may include (e.g., all of) the first compound, the second compound, the third compound, and the fourth compound, and the emission layer EML may include the combination of two host materials and two dopant materials. In the light emitting device ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may represented any one (e.g., one) selected from among the compounds represented by Compound Group 4. The emission layer EML may include at least one (e.g., one or more) selected from among the compounds represented by Compound Group 4 as a sensitizer material.

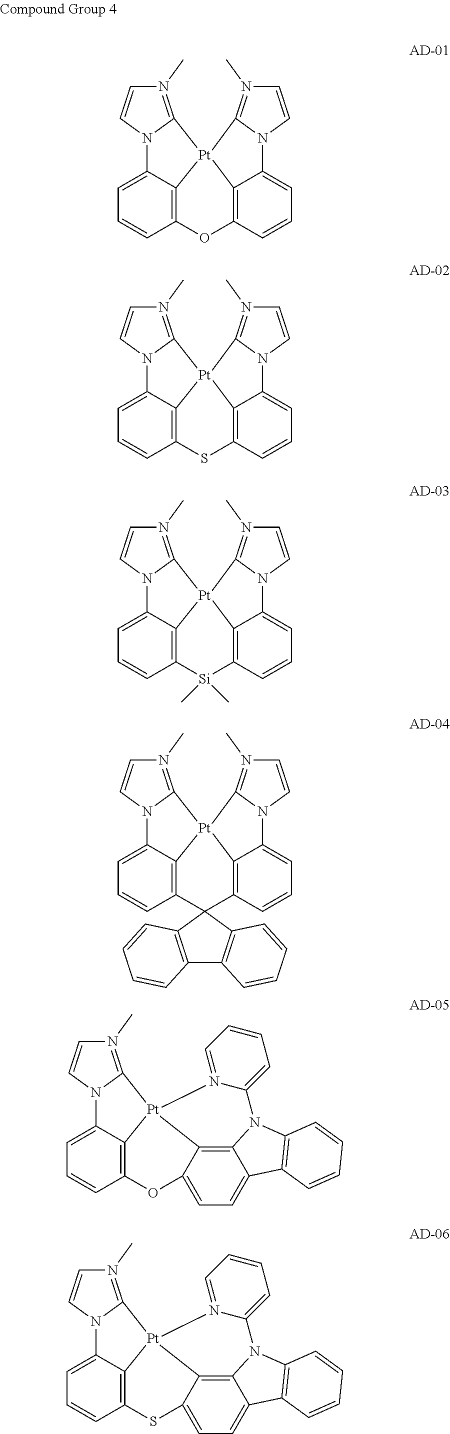

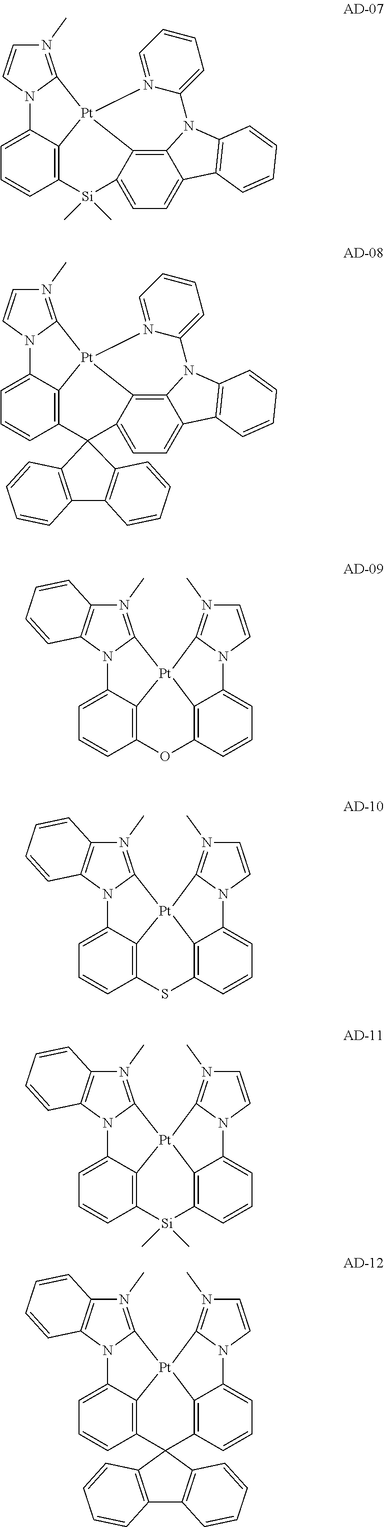

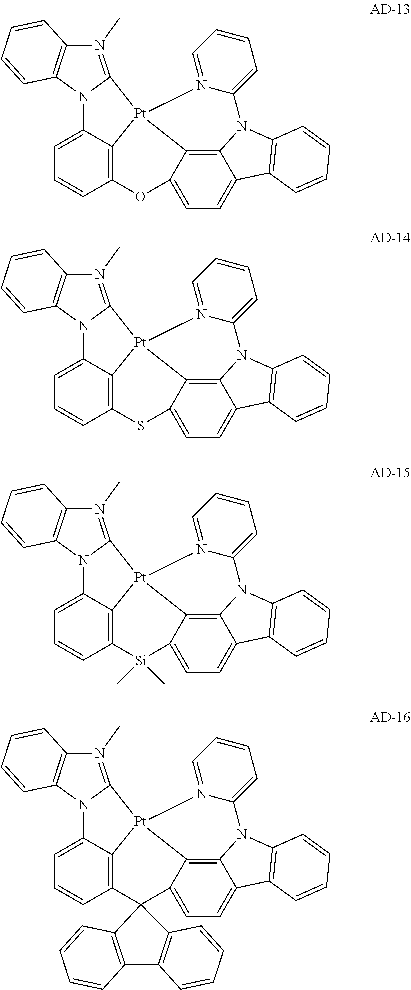

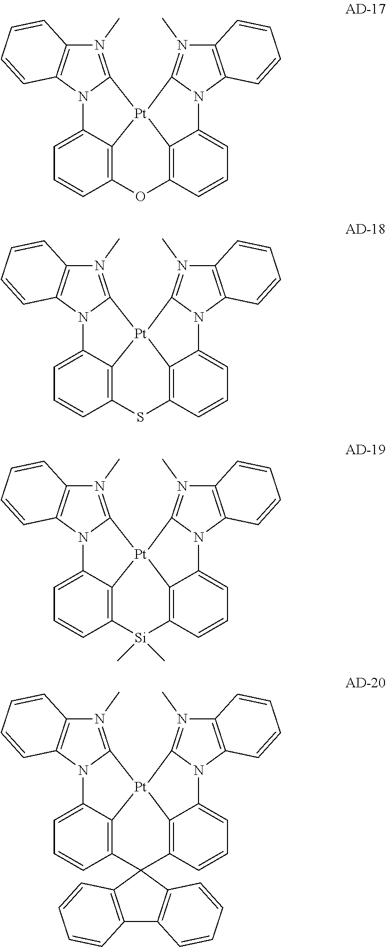

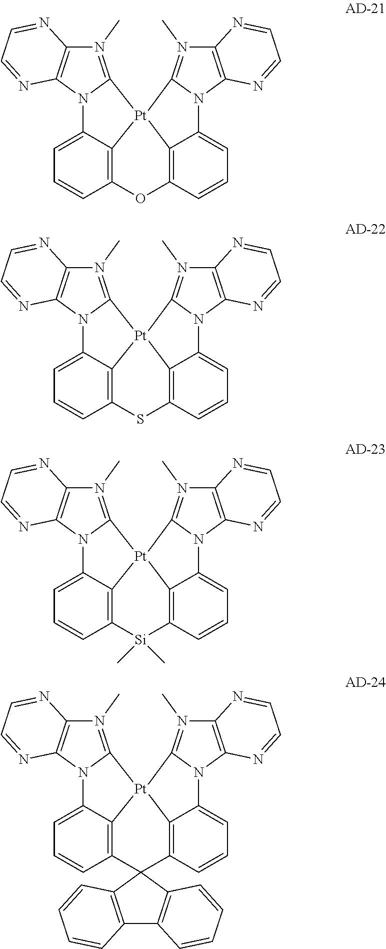

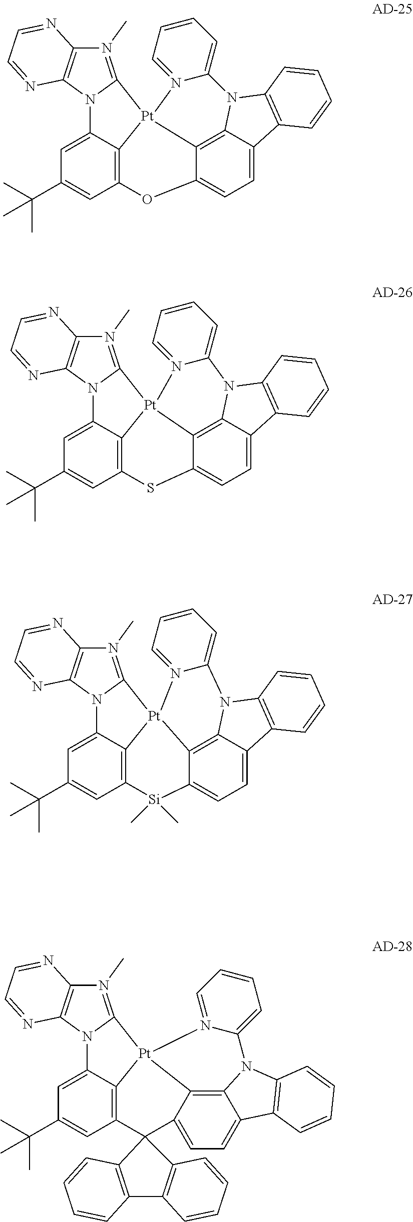

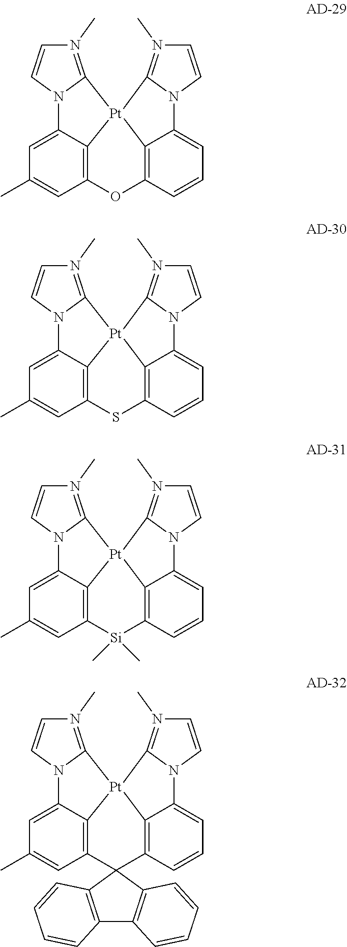

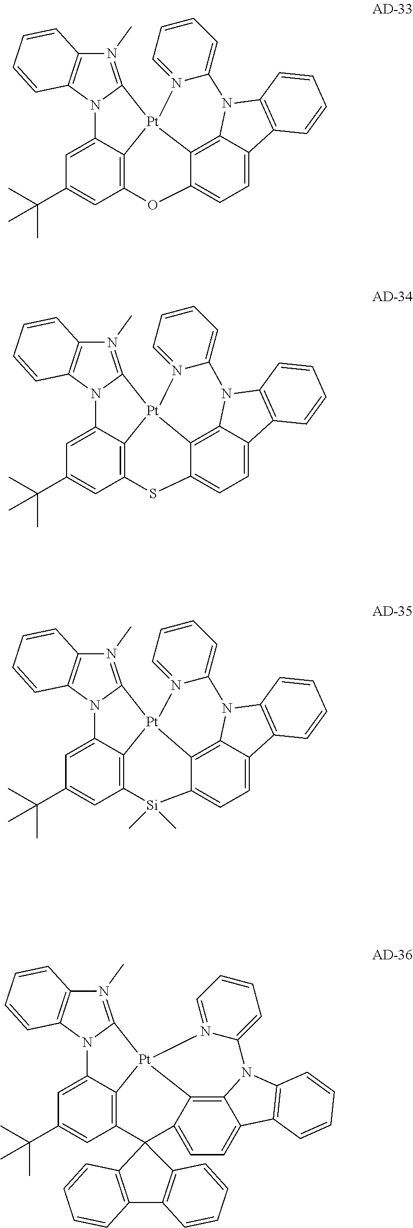

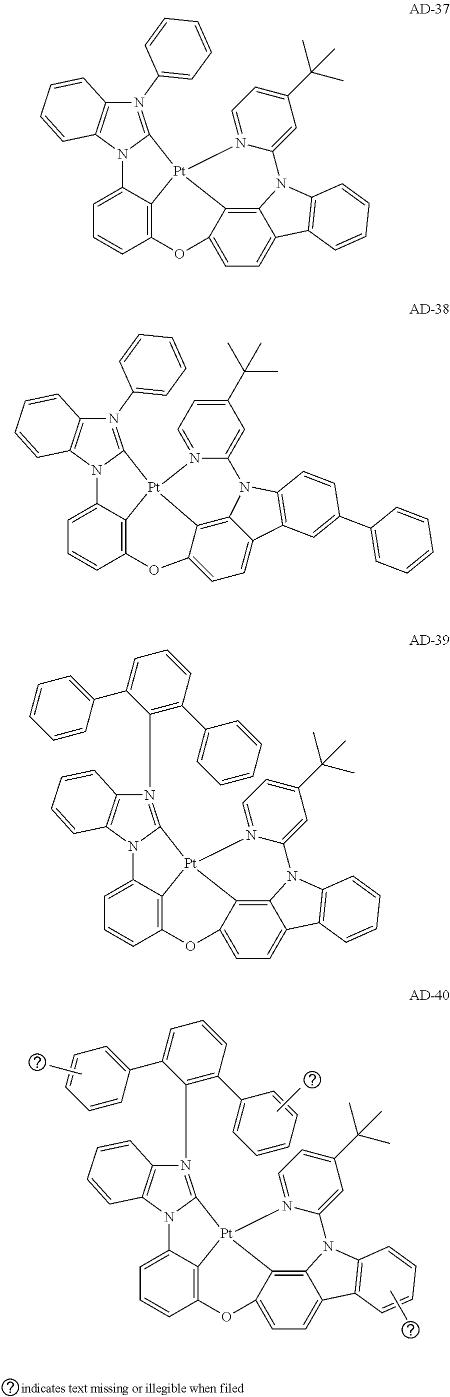

In the embodiment compounds presented in Compound Group 4, “D” refers to a deuterium atom.

In some embodiments, the light emitting element ED of one or more embodiments may include a plurality of emission layers. The plurality of emission layers may be sequentially stacked and provided, and for example, the light emitting element ED including the plurality of emission layers may be to emit white light. The light emitting element including the plurality of emission layers may be a light emitting element having a tandem structure. When the light emitting element ED includes a plurality of emission layers, at least one emission layer EML may include the first compound represented by Formula 1 of one or more embodiments. In some embodiments, when the light emitting element ED includes the plurality of emission layers, at least one emission layer EML may include (e.g., all of) the first compound, the second compound, the third compound, and the fourth compound as described herein.

When the emission layer EML in the light emitting device ED of one or more embodiments includes (e.g., all of) the first compound, the second compound, and the third compound, with respect to the total weight of the first compound, the second compound, and the third compound, the content (e.g., amount) of the first compound may be about 0.1 wt % to about 5 wt %. However, the embodiment of the present disclosure is not limited thereto. When the content (e.g., amount) of the first compound satisfies the herein-described proportion, the energy transfer from the second compound and the third compound to the first compound may increase, and thus the luminous efficiency and device service life may increase.

The contents of the second compound and the third compound in the emission layer EML may be the rest (e.g., the balance of the total weight of the first compound, the second compound, and the third compound), excluding the weight of the first compound. For example, the contents (e.g. amounts) of the second compound and the third compound in the emission layer EML may each independently be about 65 wt % to about 95 wt % with respect to the total weight of the first compound, the second compound, and the third compound.

In the total weight of the second compound and the third compound, the weight ratio of the second compound and the third compound may be about 3:7 to about 7:3.

When the contents (e.g. amounts) of the second compound and/or the third compound satisfy the herein-described ratio, at least one charge balance characteristic in the emission layer EML may be improved, and thus the luminous efficiency and device service life may increase. When the contents (e.g. amounts) of the second compound and/or the third compound deviate from the herein-described ratio range, a charge balance in the emission layer EML may be broken, and thus the luminous efficiency may be reduced and the device may be easily deteriorated.

When the emission layer EML includes the fourth compound, the content (e.g., amount) of the fourth compound in the emission layer EML may be about 10 wt % to about 30 wt % with respect to the total weight of the first compound, the second compound, the third compound, and the fourth compound. However, the embodiment of the present disclosure is not limited thereto. When the content (e.g., amount) of the fourth compound satisfies the herein-described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the herein-described content (e.g., amount) ratio range(s), excellent or suitable luminous efficiency and long service life may be achieved.

In the light emitting device ED of one or more embodiments, the emission layer EML may include an anthracene derivative, a pyrene derivative, a fluoranthene derivative, a chrysene derivative, a dehydrobenzanthracene derivative, and/or a triphenylene derivative. For example, the emission layer EML may include the anthracene derivative or the pyrene derivative.

In each light emitting device ED of one or more embodiments illustrated in FIGS. 3 to 6, the emission layer EML may further include a suitable host and dopant besides (e.g., in addition to) the herein-described host and dopant, and, for example, the emission layer EML may include a compound represented by Formula E-1. The compound represented by Formula E-1 may be utilized as a fluorescent host material.

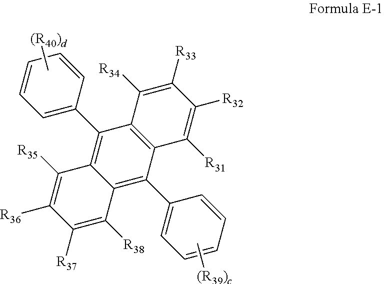

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one (e.g., one) selected from among Compound E1 to Compound E19:

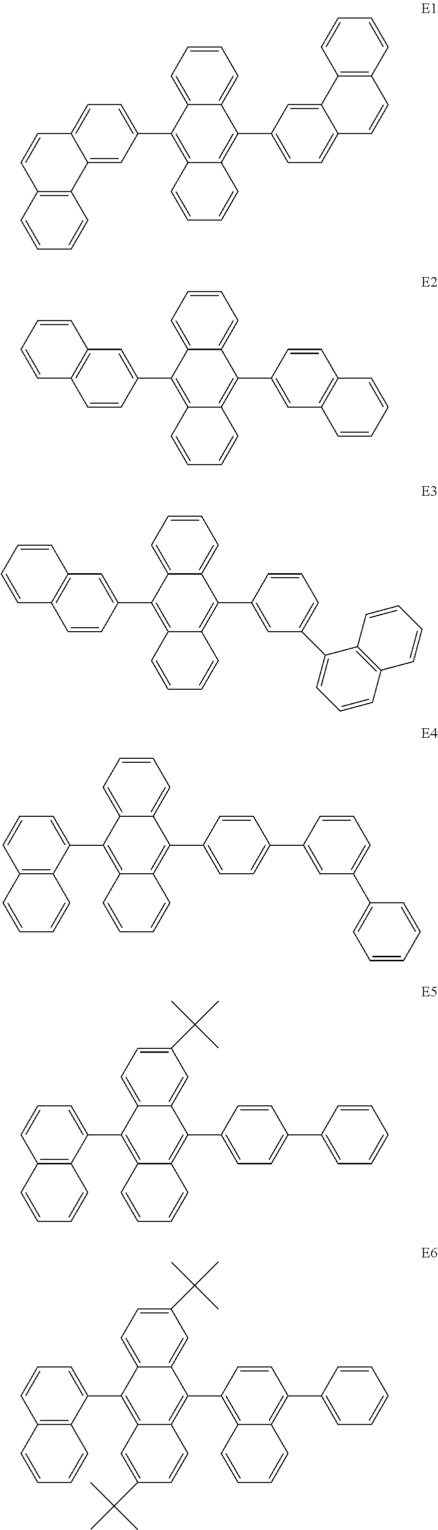

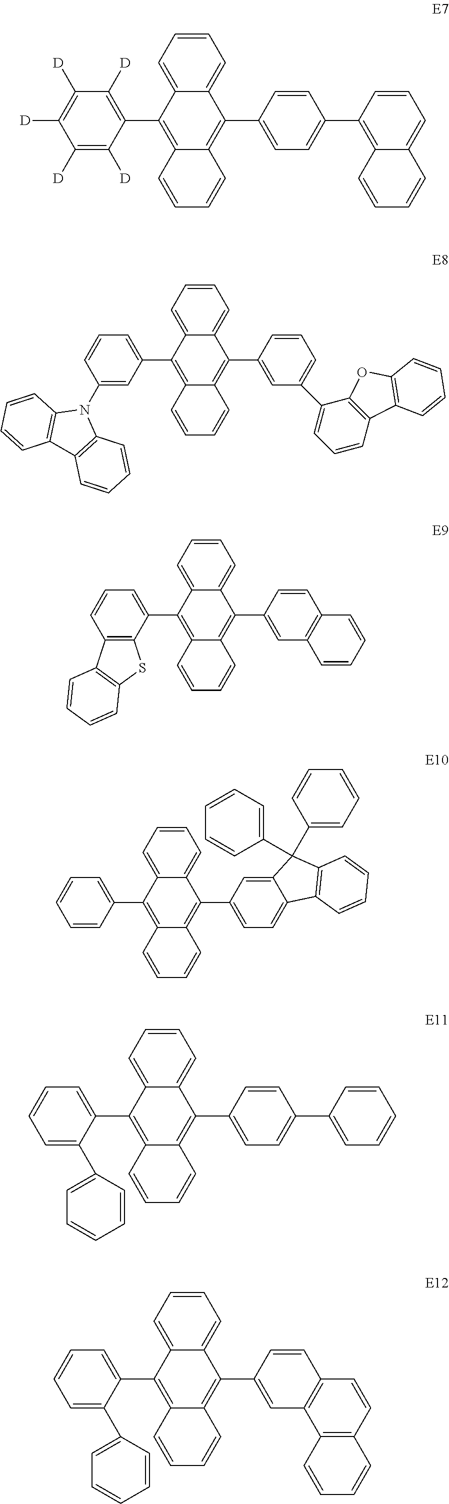

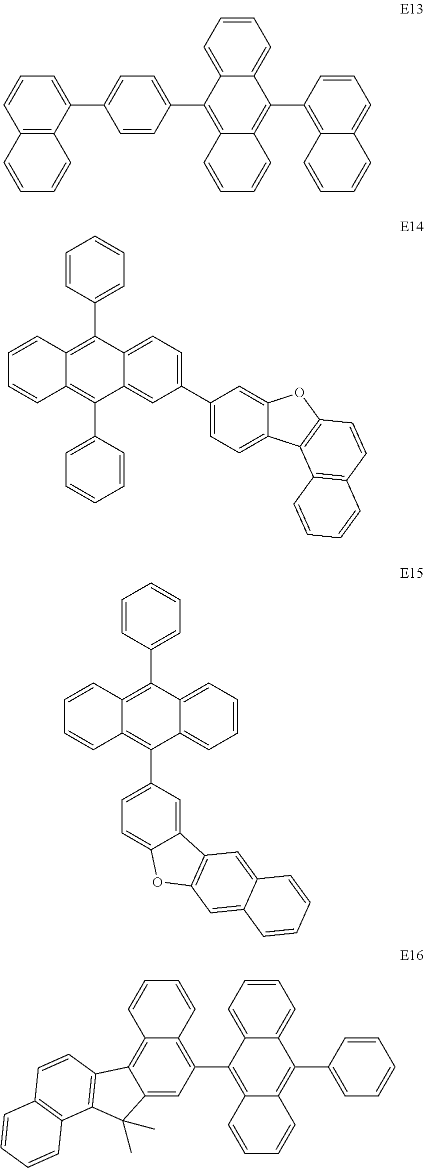

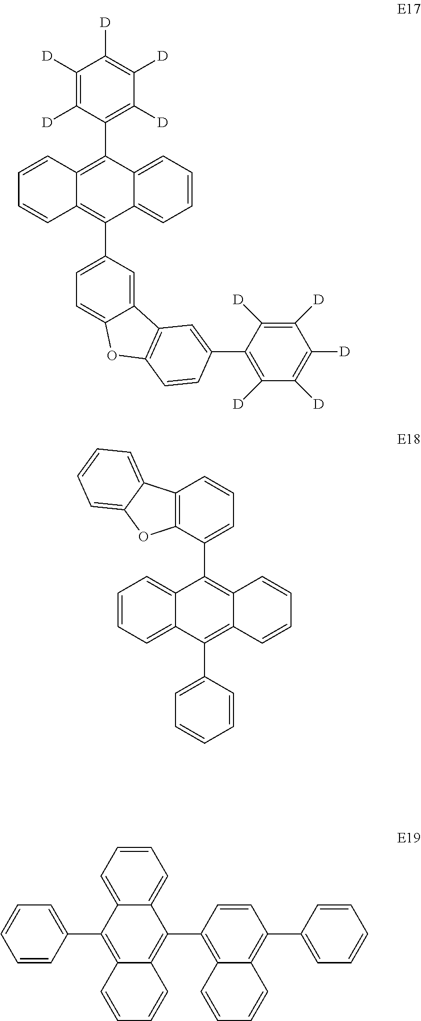

In one or more embodiments, the emission layer EML may include a compound represented by Formula E-2a or Formula E-2b. The compound represented by Formula E-2a or Formula E-2b may be utilized as a phosphorescent host material.

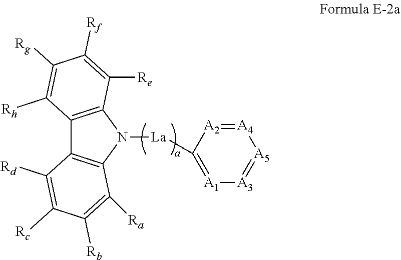

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of Lₐ's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, Rₐ to Rᵢ may be bonded to an adjacent group to form a hydrocarbon ring or a heterocycle including (e.g., containing) N, O, S, and/or the like, as a ring-forming atom.

In some embodiments, in Formula E-2a, two or three selected from among A₁ to A₅ may be N, and the rest (e.g., any remaining A₁ to A₅) may be CRᵢ.

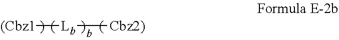

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, b may be an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one (e.g., one) selected from among the compounds of Compound Group E-2. However, the compounds listed in Compound Group E-2 are merely examples, and the compound represented by Formula E-2a or Formula E-2b is not limited to those represented in Compound Group E-2.

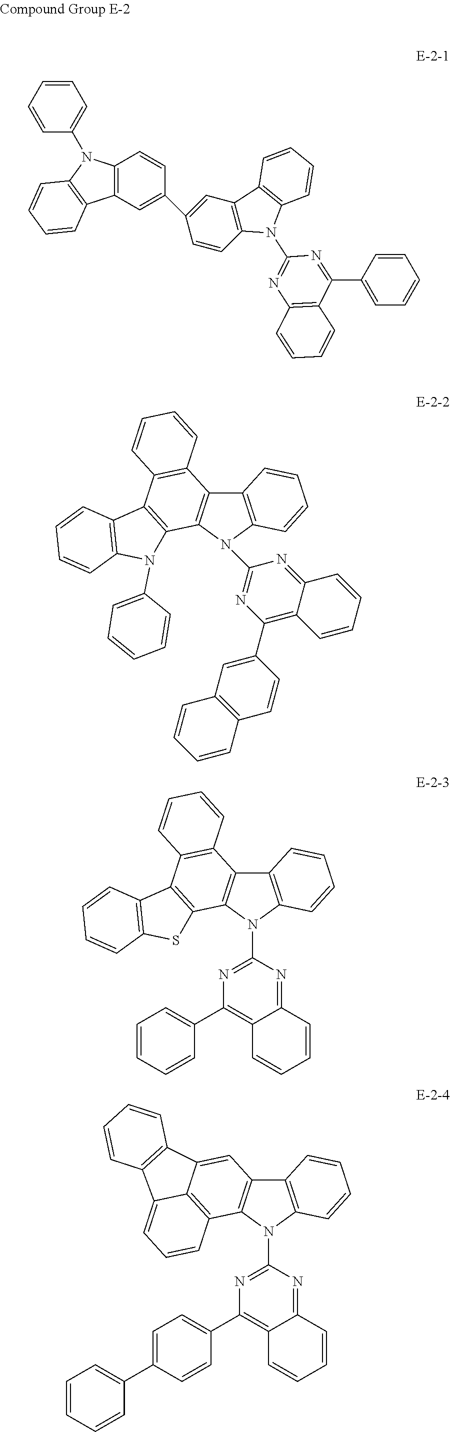

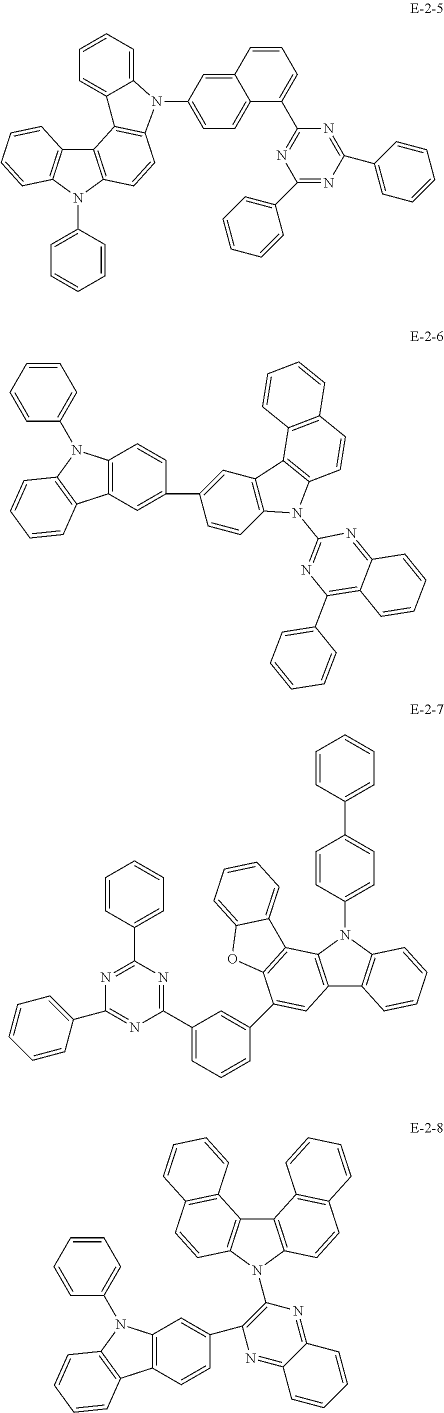 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

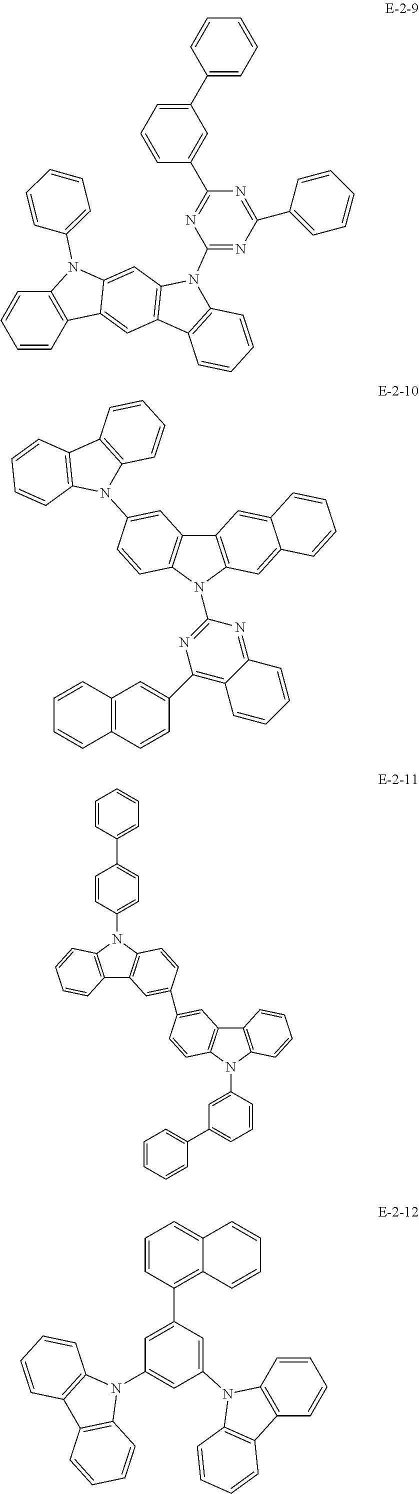

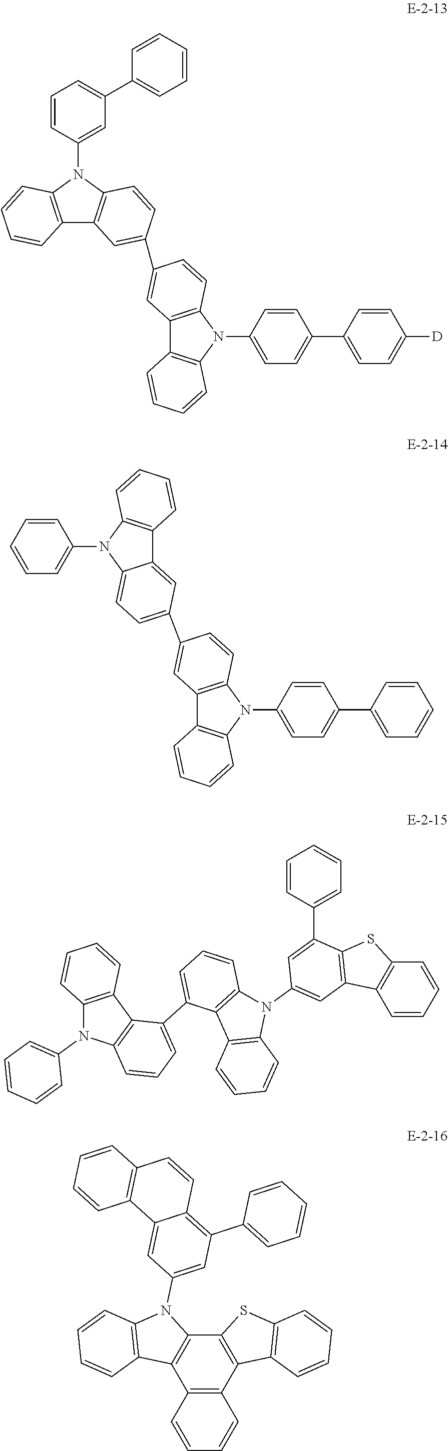 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2cc(-n3c4ccccc4c4c5ccccc5c5c6ccccc6sc5c43)cc3c2ccc2ccccc23)cc1]

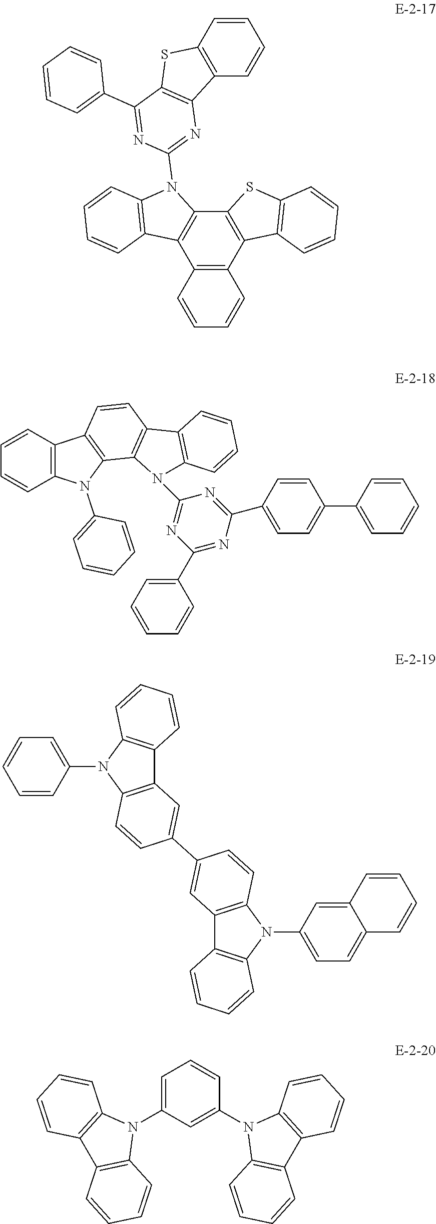 [SMILES: c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

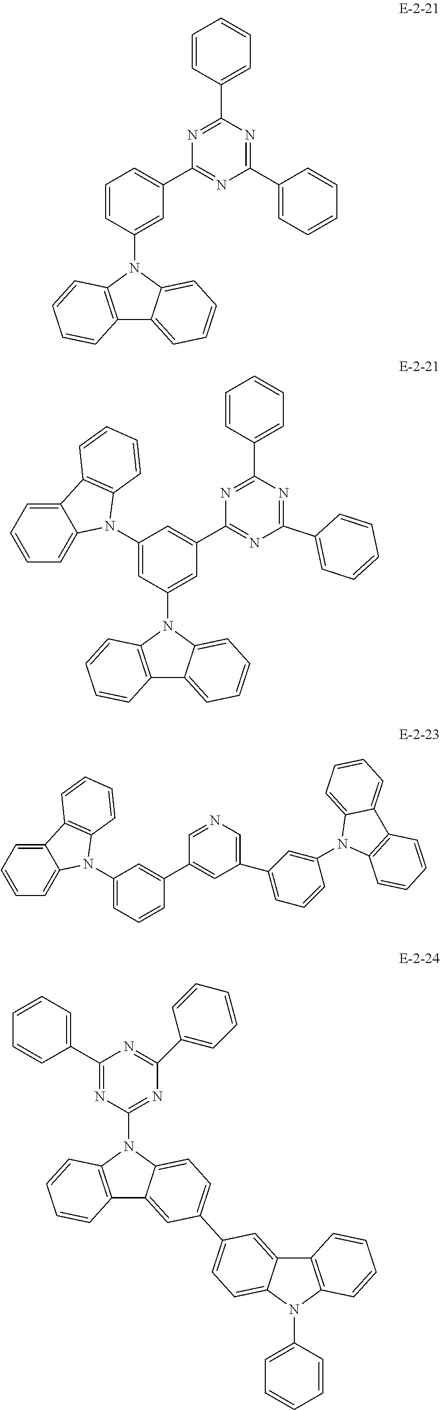 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the present disclosure is not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like may be utilized as a host material.

The emission layer EML may include a compound represented by Formula M-a. The compound represented by Formula M-a may be utilized as a phosphorescent dopant material.

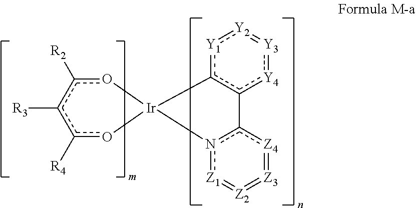

In Formula M-a herein, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be represented by any one (e.g., one) selected from among Compound M-a1 to Compound M-a25. However, Compounds M-a1 to M-a25 are merely examples, and the compound represented by Formula M-a is not limited to those represented by Compounds M-a1 to M-a25.

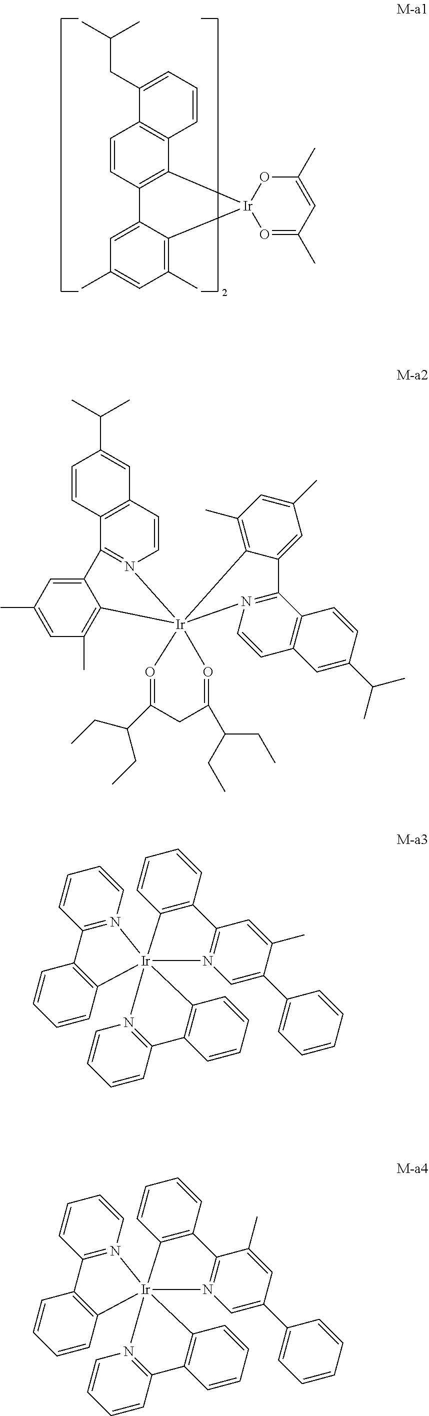

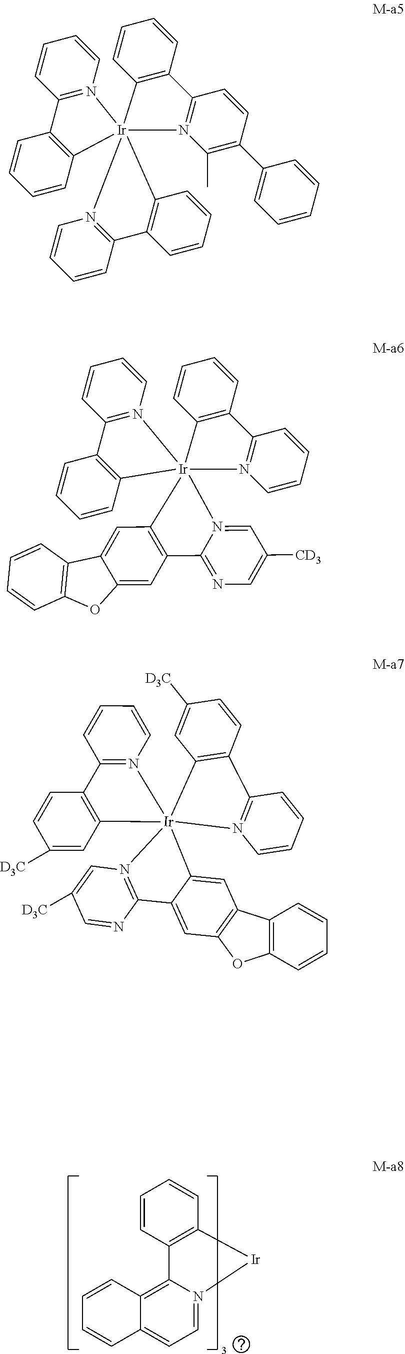

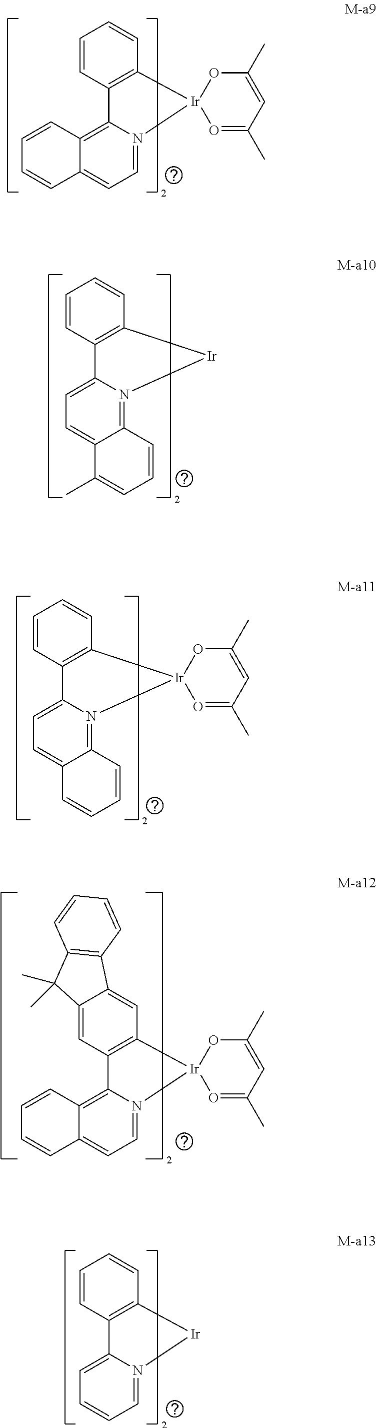

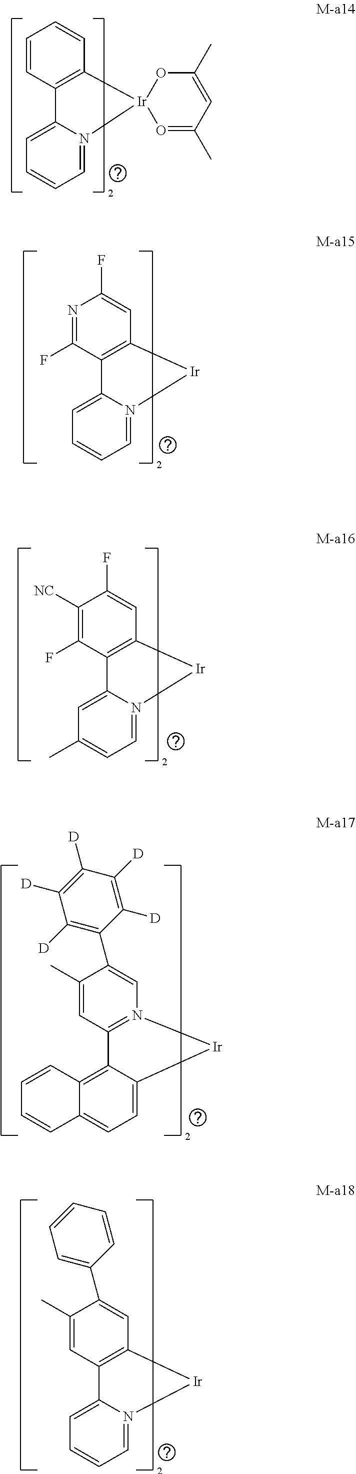

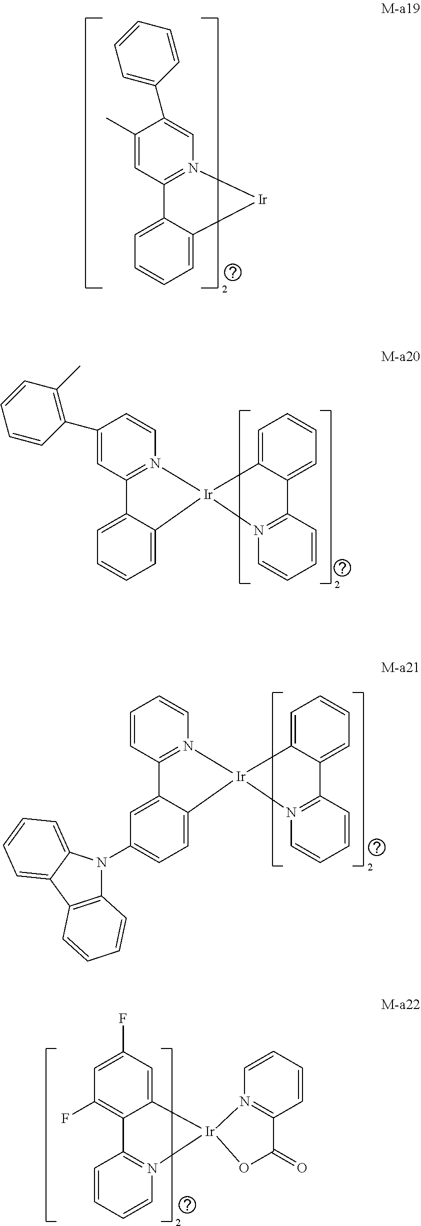

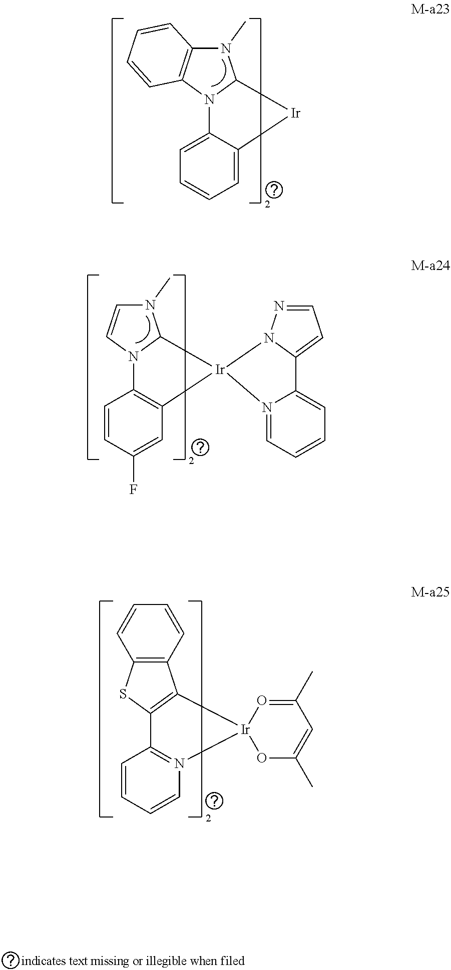

The emission layer EML may include a compound represented by at least (e.g., any) one selected from among Formula F-a to Formula F-c. The compound represented by Formula F-a to Formula F-c may be utilized as a fluorescence dopant material.

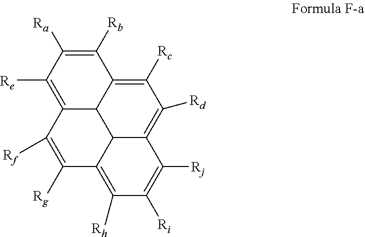

In Formula F-a herein, two selected from among Rₐ to Rⱼ may each independently be substituted with *—NAr₁Ar₂. The others, which are not substituted with *—NAr₁Ar₂ (e.g., remaining among Rₐ to Rⱼ) may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

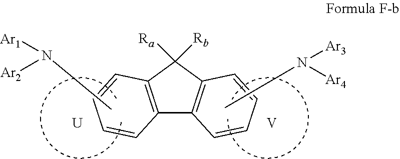

In Formula F-b herein, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one selected from among Ar₁ to Ar₄ may be a heteroaryl group including (e.g., containing) O or S as a ring-forming atom.

In Formula F-b, the number of rings represented by U and V may each independently be 0 or 1. For example, in Formula F-b, it refers to that when the number of U or V is 1, one ring may be (e.g., constitutes) a fused ring at a portion indicated by U or V, and when the number of U or V is 0, a ring indicated by U or V may not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

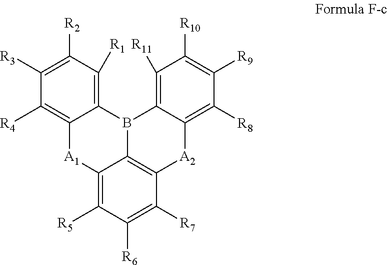

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In Formula F-c, A₁ and A₂ may each independently be bonded to substituents of an adjacent ring to form a fused ring. For example, when A₁ and A₂ are each independently NRₘ, A₁ may be bonded to R₄ or R₅ to form a ring. In some embodiments, A₂ may be bonded to R₇ or R₈ to form a ring.

In one or more embodiments, the emission layer EML may further include, as a suitable dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), and/or the like.

The emission layer EML may further include a suitable phosphorescence dopant material. For example, a metal complex including (e.g., containing) iridium (Ir), platinum (Pt), osmium (Os), aurum (Au), titanium (Ti), zirconium (Zr), hafnium (Hf), europium (Eu), terbium (Tb), and/or thulium (Tm) may be utilized as a phosphorescent dopant. For example, iridium(III) bis(4,6-difluorophenylpyridinato-N,C2) (Flrpic), bis(2,4-difluorophenylpyridinato)-tetrakis(1-pyrazolyl)borate iridium(III) (Fir6), and/or platinum octaethyl porphyrin (PtOEP) may be utilized as a phosphorescent dopant. However, the embodiment of the present disclosure is not limited thereto.

The emission layer EML may include a quantum dot material. The core of the quantum dot may be selected from among a Group II-VI compound, a Group III-VI compound, a Group I-III-IV compound, a Group III-V compound, a Group III-II-V compound, a Group IV-VI compound, a Group IV element, a Group IV compound, and/or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ or In₂Se₃, a ternary compound such as InGaS₃ or InGaSe₃, or any combination thereof.

The Group I-III-VI compound may be selected from among a ternary compound selected from the group consisting of AgInS, AgInS₂, CuInS, CuInS₂, AgGaS₂, CuGaS₂ CuGaO₂, AgGaO₂, AgAlO₂, and a mixture thereof, and/or a quaternary compound such as AgInGaS₂ or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary (e.g., multi-element) compound such as the binary compound, the ternary compound, or the quaternary compound may be present in a particle with a substantially uniform or non-substantially uniform concentration distribution. For example, the formula(e) may refer to the types (kinds) of elements included in the compounds, and the elemental ratio(s) in the compound may be similar or different. For example, AgInGaS₂ may refer to AgInₓGa₁₋ₓS₂ (where x is a real number of 0 to 1).

In some embodiments, the quantum dot may have a single structure or a double structure of (e.g., a core-shell structure) in which the concentration of each element included in the quantum dot is substantially uniform. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or may include multiple layers. An interface between the core and the shell may have a concentration gradient in which the concentration of an element present in the shell becomes lower towards the center.

In some embodiments, the quantum dot may have the herein-described core-shell structure including a core containing nanocrystals and a shell around (e.g., surrounding) the core. An example of the shell of the quantum dots may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, or NiO, or a ternary compound such as MgAl₂O₄, CoFe₂O₄, NiFe₂O₄, or CoMn₂O₄, but the embodiment of the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the embodiment of the present disclosure is not limited thereto.

Each element included in a polynary compound such as the binary compound, or the ternary compound may be present in a particle with a substantially uniform or non-substantially uniform concentration distribution. For example, the formula(e) may refer to the types (kinds) of elements included in the compounds, and the elemental ratio in the compound may be different.

The quantum dot may have a full width of half maximum (FWHM) of a light emitting wavelength spectrum of about 45 nm or less, about 40 nm or less, or about 30 nm or less, and color purity or color reproducibility may be improved in the described range(s). In some embodiments, light emitted through such a quantum dot is emitted in all directions so that a wide viewing angle may be improved.

In some embodiments, although the form of the quantum dot is not particularly limited as long as it is a form commonly utilized in the art. For example, the quantum dot in the form of spherical, pyramidal, multi-arm, or cubic nanoparticles, nanotubes, nanowires, nanofibers, nanoplate particles, and/or the like may be utilized.

As the size of the quantum dot is adjusted and/or the elemental ratio in the quantum dot compound is adjusted, it is possible to control the energy band gap, and thus light in one or more suitable wavelength ranges may be obtained in the quantum dot emission layer. Therefore, the quantum dot as described (utilizing different sizes of quantum dots or different elemental ratios in the quantum dot compound) is utilized, and thus the light emitting device, which emits light in one or more suitable wavelengths, may be implemented. For example, the adjustment of the size of the quantum dot or the elemental ratio in the quantum dot compound may be selected to emit red, green, and/or blue light. In some embodiments, the quantum dots may be configured to emit white light by combining one or more suitable colors of light.

In each of the light emitting devices ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer including (e.g., formed of) a single material, a single layer including (e.g., formed of) a plurality of different materials, or a multilayer structure including a plurality of layers including (e.g., formed of) a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure including (e.g., formed of) a plurality of different materials, or may have a structure in which an electron transport layer ETL/electron injection layer EIL, a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2:

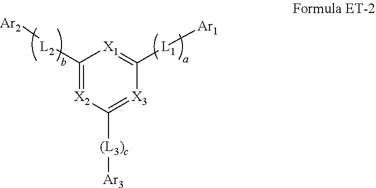

In Formula ET-2, at least one selected from among X₁ to X₃ is N, and the rest (e.g., any remaining X₁ to X₃) are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, one or more embodiments of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-1 yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and/or mixture(s) thereof.

The electron transport region ETR may include at least one selected from among Compound ET1 to Compound ET36:

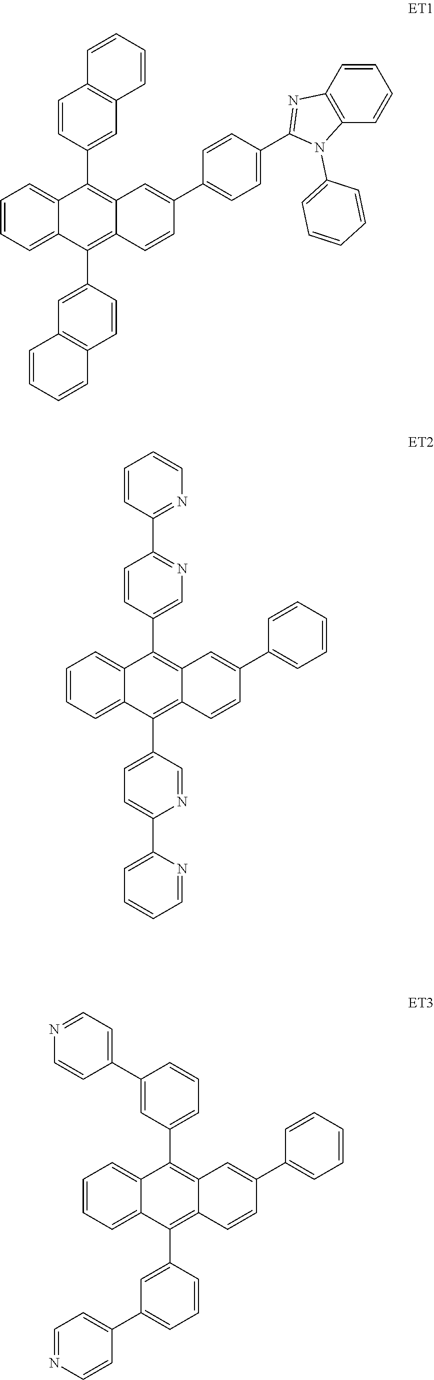 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

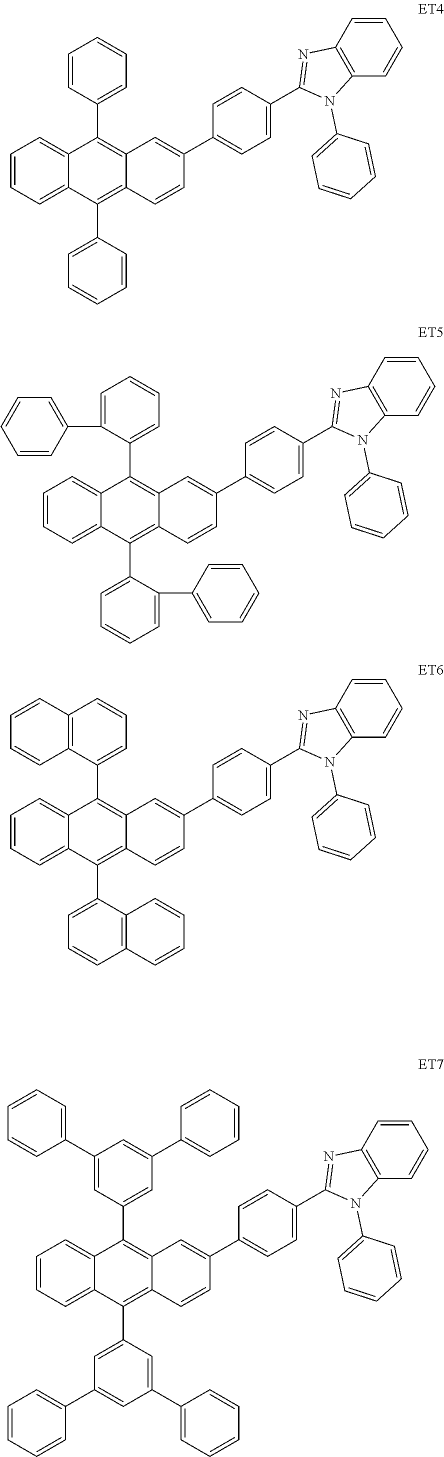 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

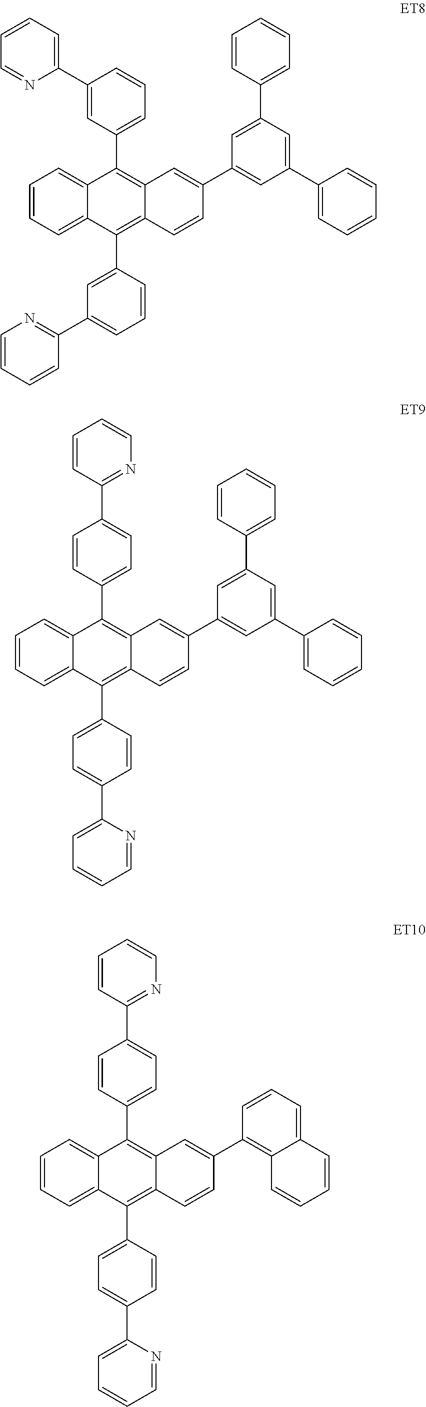 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

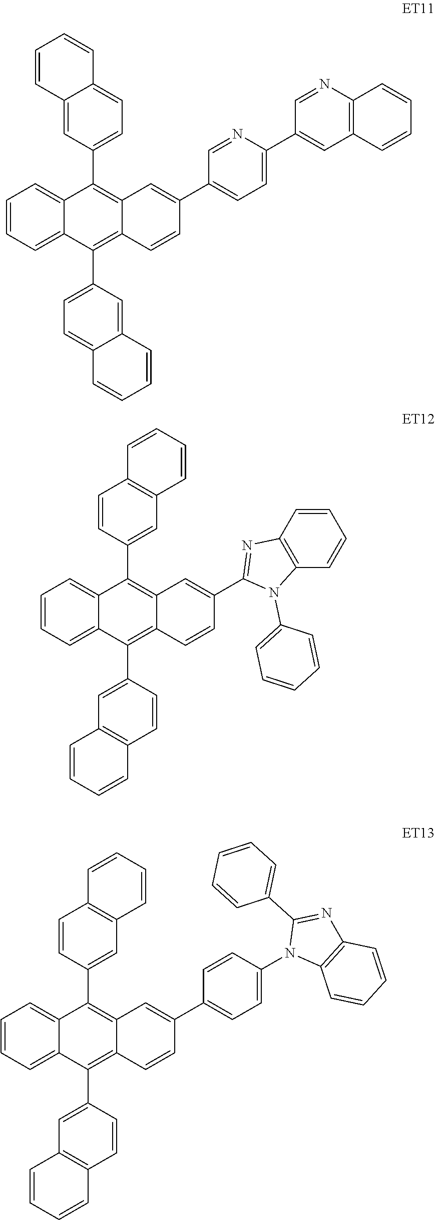

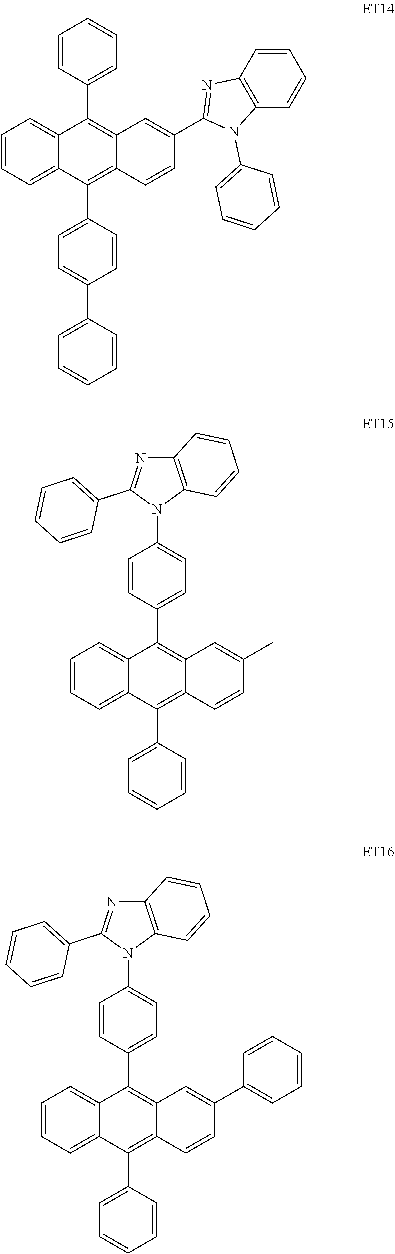 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

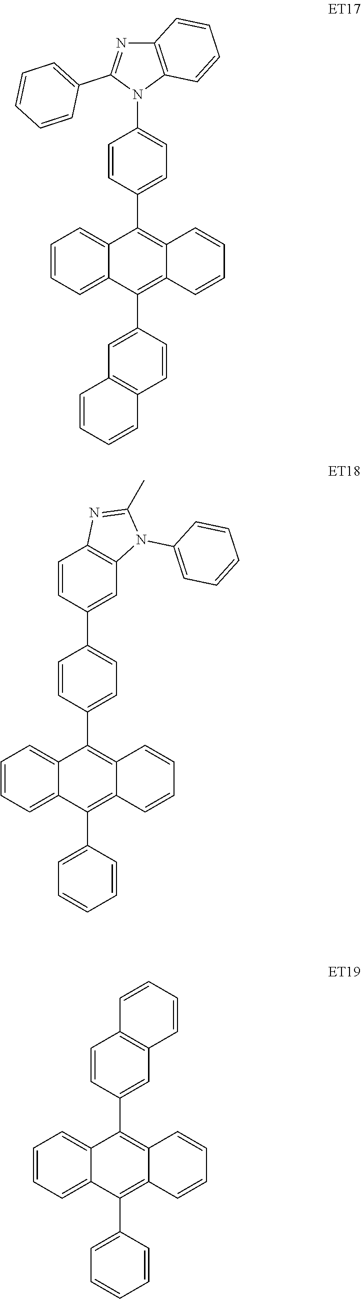

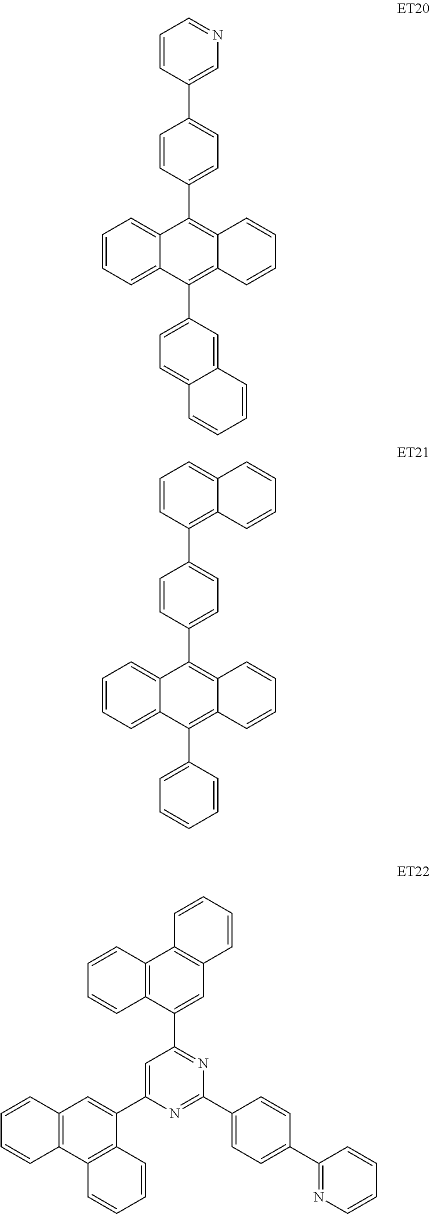

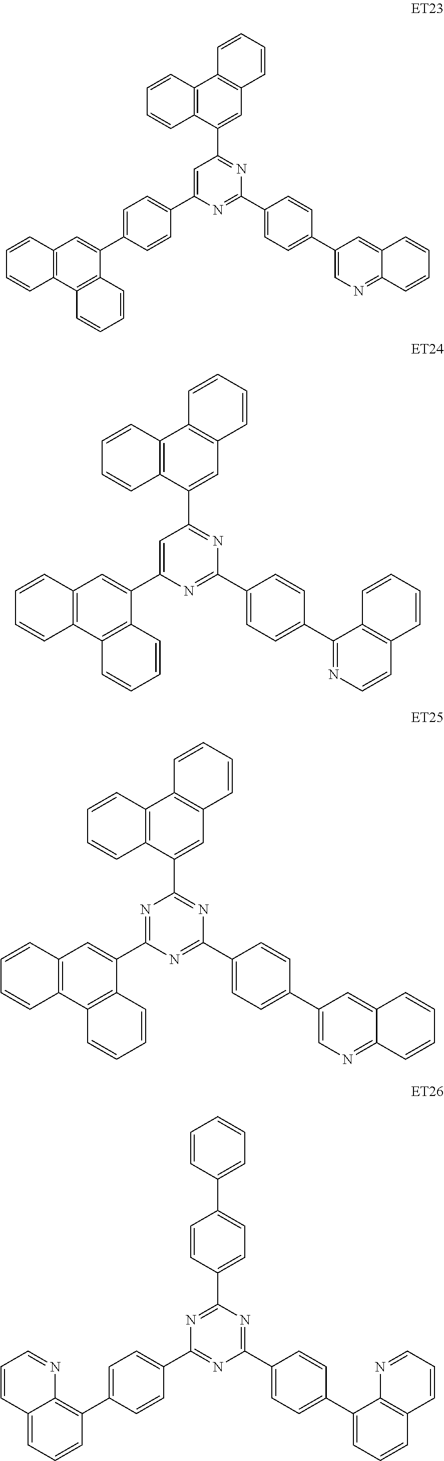 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

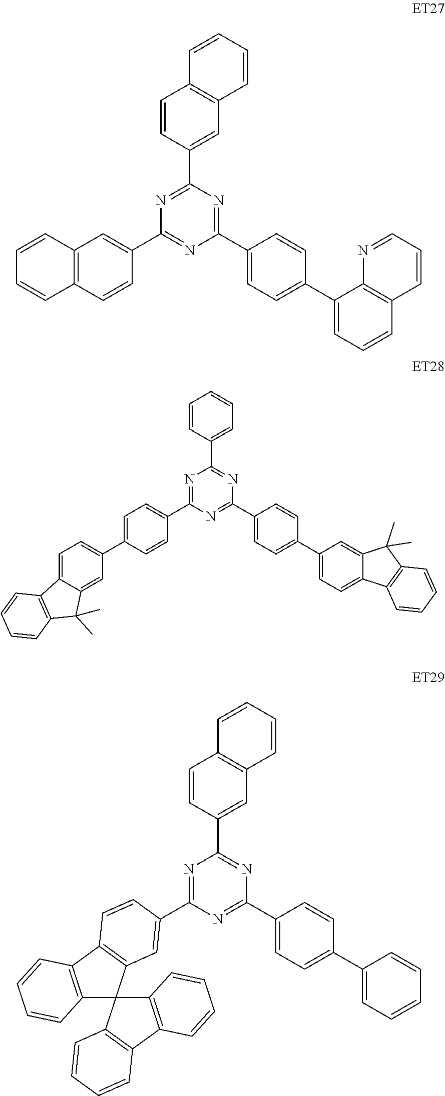 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc5c(c4)C4(c6ccccc6-c6ccccc64)c4ccccc4-5)nc(-c4ccc5ccccc5c4)n3)cc2)cc1]

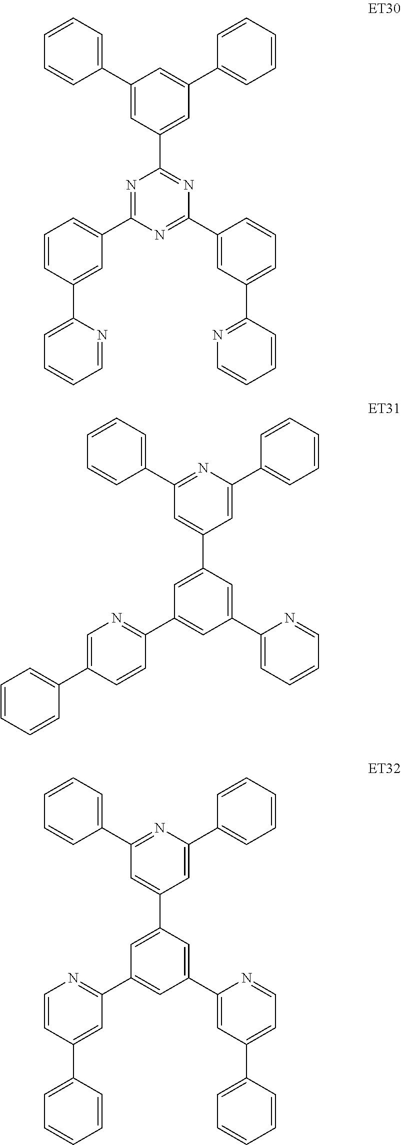 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

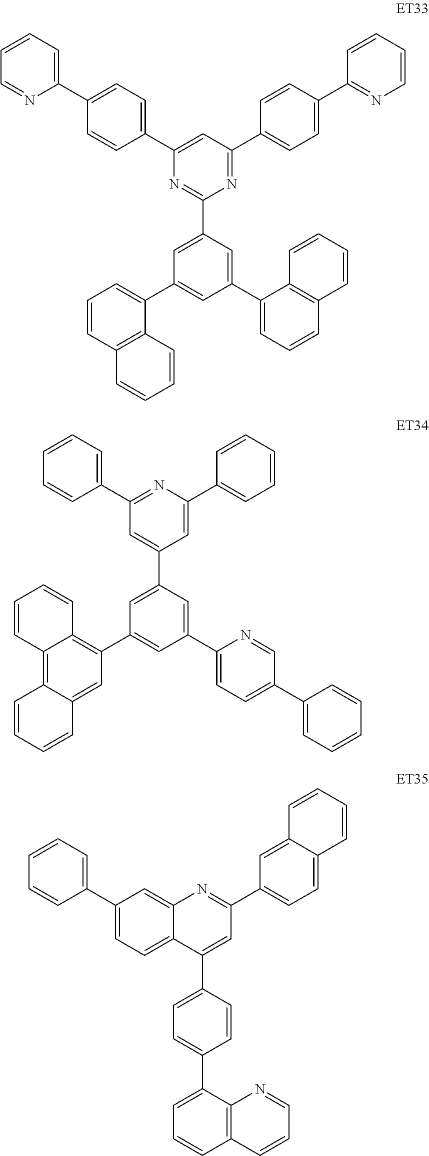

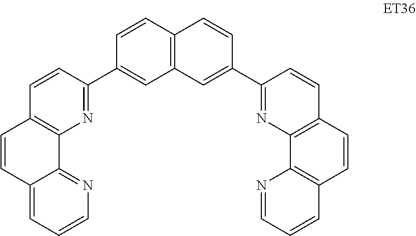 [SMILES: c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI, and KI, a lanthanide metal such as Yb, and/or a co-deposited material of the metal halide and the lanthanide metal. For example, the electron transport region ETR may include KI:Yb, RbI:Yb, LiF:Yb, and/or the like, as a co-deposited material. In some embodiments, the electron transport region ETR may be formed utilizing a metal oxide such as Li₂O or BaO, or 8-hydroxyl-lithium quinolate (Liq), and/or the like, but one or more embodiments of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the herein-described materials, but the embodiment of the present disclosure is not limited thereto.

The electron transport region ETR may include the herein-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for 1 example, about 3 Å to about 90 Å. When the thickness of the electron injection layer EIL satisfies the herein-described range(s), satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may include (e.g., be formed of) a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgYb). In some embodiments, the second electrode EL2 may have a multilayer structure including a reflective film or a transflective film formed of the herein-described materials, and a transparent conductive film formed of ITO, IZO, ZnO, ITZO, and/or the like. For example, the second electrode EL2 may include the herein-described metal materials, combinations of at least two metal materials of the herein-described metal materials, oxides of the herein-described metal materials, and/or the like.

In some embodiments, the second electrode EL2 may be connected with an auxiliary electrode. When the second electrode EL2 is connected with the auxiliary electrode, the resistance of the second electrode EL2 may be decreased.

In some embodiments, a capping layer CPL may further be provided on the second electrode EL2 of the light emitting device ED of one or more embodiments. The capping layer CPL may include a multilayer or a single layer.

In one or more embodiments, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, and/or the like.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, the embodiment of the present disclosure is not limited thereto, and the capping layer CPL may include at least one selected from among Compounds P1 to P5:

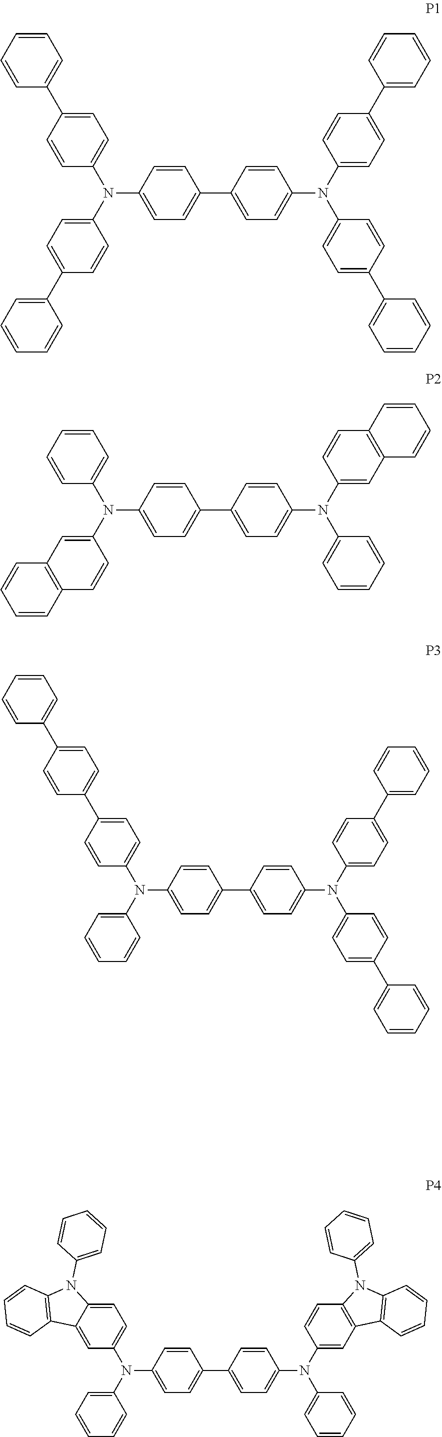 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

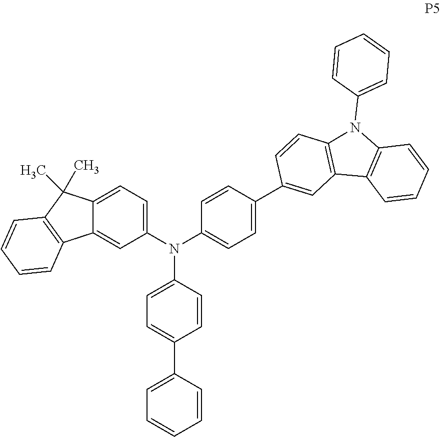 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be 1 about 1.6 or more with respect to light in a wavelength range of about 550 nm to about 660 nm.

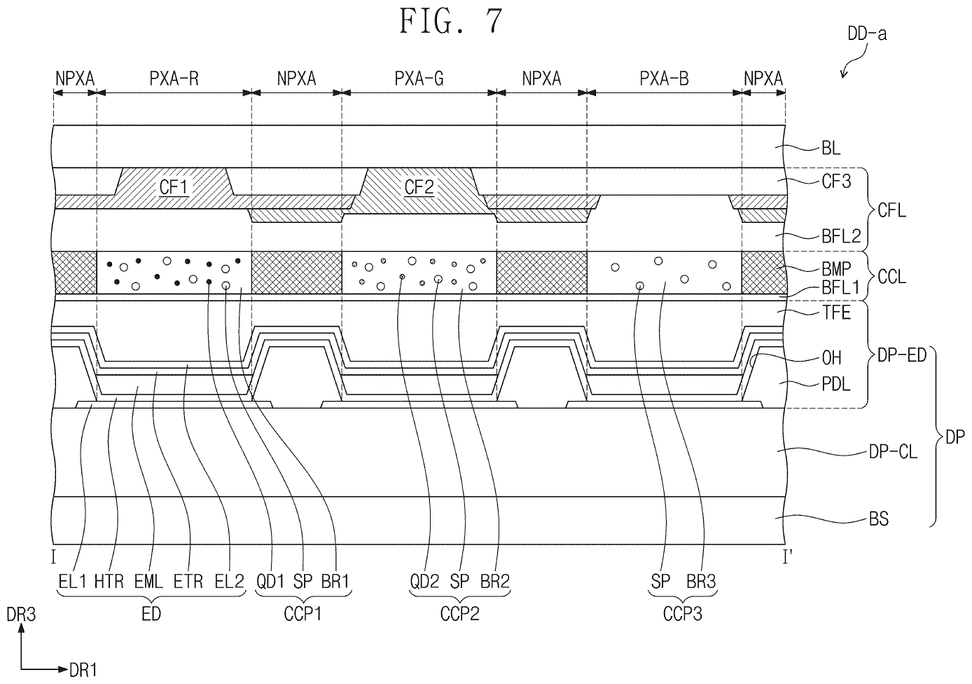

Each of FIGS. 7 to 10 is a cross-sectional view of a display apparatus according to one or more embodiments of the present disclosure. Hereinafter, in describing the display apparatuses of embodiments with reference to FIGS. 7 to 10, the duplicated features which have been described in FIGS. 1 to 6 are not described again, but their differences will be mainly described.

Referring to FIG. 7, the display apparatus DD-a according to one or more embodiments may include a display panel DP including a display device layer DP-ED, a light control layer CCL provided on the display panel DP, and a color filter layer CFL. In one or more embodiments illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. In some embodiments, the structures of the light emitting devices of FIGS. 3 to 6 as described herein may be equally applied to the structure of the light emitting device ED illustrated in FIG. 7.

The emission layer EML of the light emitting element ED included in the display device DD according to one or more embodiments may include the herein-described fused polycyclic compound of one or more embodiments.

Referring to FIG. 7, the emission layer EML may be provided in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display apparatus DD-a of one or more embodiments, the emission layer EML may be to emit blue light. In some embodiments, unlike the configuration illustrated, in one or more embodiments, the emission layer EML may be provided as a common layer in the entire light emitting regions PXA-R, PXA-G, and PXA-B.

The light control layer CCL may be provided on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced and/or apart from each other.

Referring to FIG. 7, divided patterns BMP may be provided between the light control parts CCP1, CCP2 and CCP3 which are spaced and/or apart from each other, but the embodiment of the present disclosure is not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting device ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described herein may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include at least (e.g., any) one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3, respectively, in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may include (e.g., be formed of) one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In some embodiments, the barrier layers BFL1 and BFL2 may further include an organic film. The barrier layers BFL1 and BFL2 may be formed of a single layer or a plurality of layers.

In the display apparatus DD-a of one or more embodiments, the color filter layer CFL may be provided on the light control layer CCL. For example, the color filter layer CFL may be directly provided on the light control layer CCL. In this case, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In some embodiments, the embodiment of the present disclosure is not limited thereto, and the third filter CF3 may not include (e.g., may exclude) a pigment or dye. The third filter CF3 may include a polymeric photosensitive resin and may not include (e.g., may exclude) a pigment or dye. The third filter CF3 may be transparent. The third filter CF3 may be formed of a transparent photosensitive resin.

Furthermore, in one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3.

The first to third filters CF1, CF2, and CF3 may be provided corresponding to the red light emitting region PXA-R, the green light emitting region PXA-G, and the blue light emitting region PXA-B, respectively.

A base substrate BL may be provided on the color filter layer CFL. The base substrate BL may be a member which provides a base surface in which the color filter layer CFL, the light control layer CCL, and/or the like are provided. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be provided.

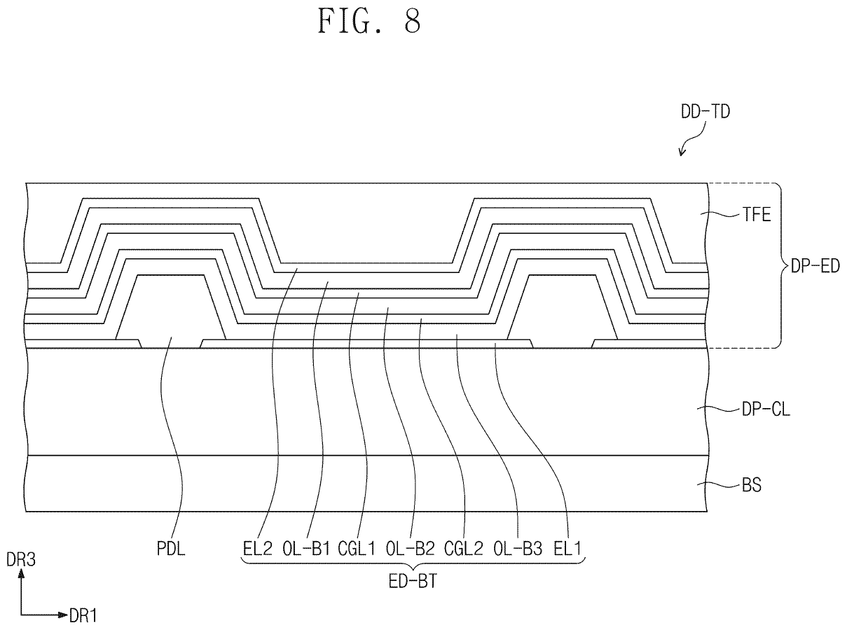

FIG. 8 is a cross-sectional view illustrating a portion of a display apparatus according to one or more embodiments. In the display apparatus DD-TD of one or more embodiments, the light emitting device ED-BT may include a plurality of light emitting structures OL-B1, OL-B2, and OL-B3. The light emitting device ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR provided with the emission layer EML (FIG. 7) located therebetween.

For example, the light emitting device ED-BT included in the display apparatus DD-TD of one or more embodiments may be a light emitting device having a tandem structure and including a plurality of emission layers.

In one or more embodiments illustrated in FIG. 8, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light beams having wavelength ranges different from each other may be to emit white light.

Charge generation layers CGL1 and CGL2 may be respectively provided between two of the neighboring light emitting structures OL-B1, OL-B2, and OL-B3. The charge generation layers CGL1 and CGL2 may include a p-type or kind charge generation layer and/or an n-type or kind charge generation layer.

At least one selected from among the light emitting structures OL-B1, OL-B2, and OL-B3 included in the display device DD-TD of one or more embodiments may contain the herein-described fused polycyclic compound of one or more embodiments. For example, at least one selected from among the plurality of emission layers included in the light emitting element ED-BT may include the fused polycyclic compound of one or more embodiments.

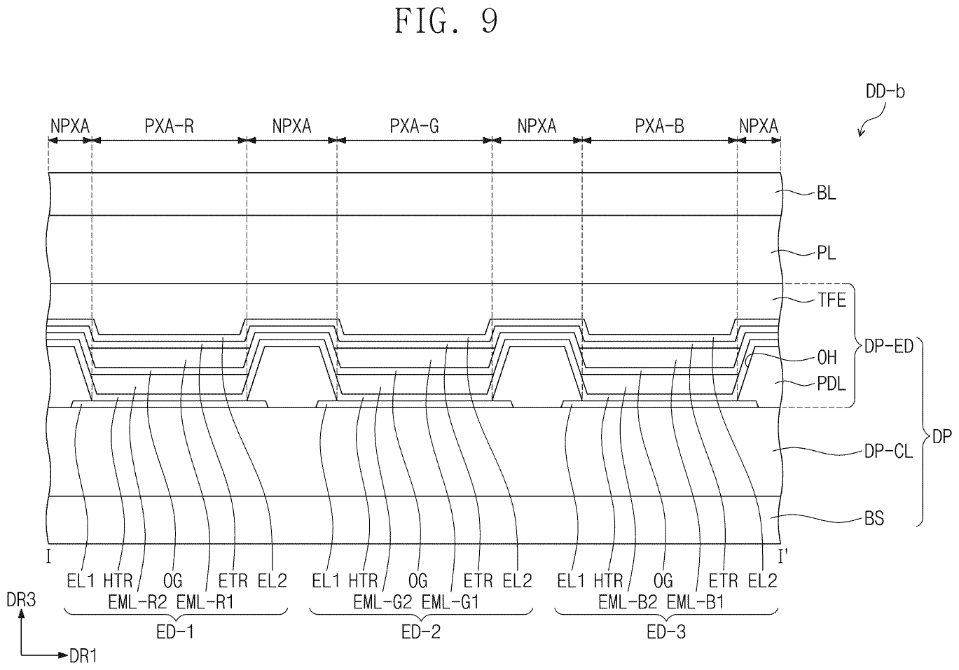

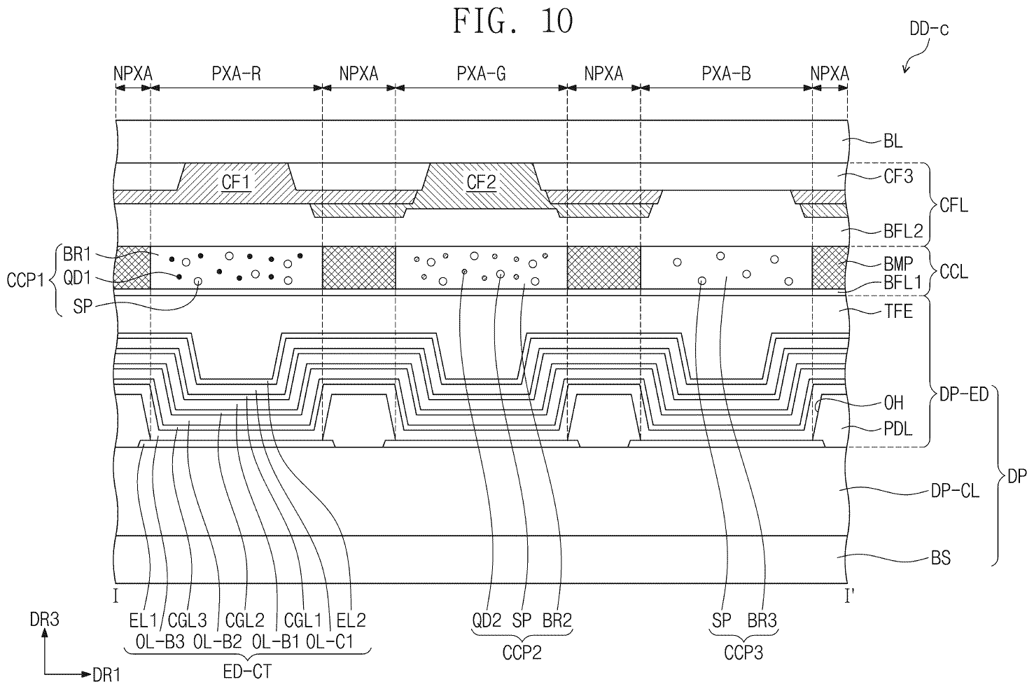

FIG. 9 is a cross-sectional view illustrating a display device according to one or more embodiments of the present disclosure. FIG. 10 is a cross-sectional view illustrating a display device according to one or more embodiments of the present disclosure.

Referring to FIG. 9, the display apparatus DD-b according to one or more embodiments may include light emitting devices ED-1, ED-2, and ED-3 in which two emission layers are stacked. Compared with the display apparatus DD of one or more embodiments illustrated in FIG. 2, one or more embodiments illustrated in FIG. 9 has a difference in that the first to third light emitting devices ED-1, ED-2, and ED-3 each include two emission layers stacked in the thickness direction. In each of the first to third light emitting devices ED-1, ED-2, and ED-3, the two emission layers may be to emit light in substantially the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. An emission auxiliary part OG may be provided between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting devices ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be provided between the emission auxiliary part OG and the electron transport region ETR. The second red emission layer EML-R2, the second green emission layer EML-G2, and the second blue emission layer EML-B2 may be provided between the hole transport region HTR and the emission auxiliary part OG.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be provided on the display device layer DP-ED. The optical auxiliary layer PL may include a polarizing layer. The optical auxiliary layer PL may be provided on the display panel DP and control reflected light in the display panel DP due to external light. Unlike the configuration illustrated, the optical auxiliary layer PL in the display apparatus according to one or more embodiments may not be provided.

At least one emission layer included in the display device DD-b of one or more embodiments illustrated in FIG. 9 may include the herein-described fused polycyclic compound of one or more embodiments. For example, in one or more embodiments, at least one of the first blue emission layer EML-B1 or the second blue emission layer may include the fused polycyclic compound of one or more embodiments.

Unlike FIGS. 8 and 9, FIG. 10 illustrates that a display apparatus DD-c includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be provided between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light beams in different wavelength regions.

The charge generation layers CGL1, CGL2, and CGL3 provided between adjacent light emitting structures OL-B1, OL-B2, OL-B3, and OL-C1 may include a p-type or kind charge generation layer (p-charge generation layer) and/or an n-type or kind charge generation layer (n-charge generation layer).

At least one selected from among the light emitting structures OL-B1, OL-B2, OL-B3, and OL-C1 included in the display device DD-c of one or more embodiments may include (e.g., contain) the herein-described fused polycyclic compound of one or more embodiments. For example, in one or more embodiments, at least one selected from among the first to third light emitting structures OL-B1, OL-B2, and OL-B3 may include the described fused polycyclic compound of one or more embodiments.

The light emitting element ED according to one or more embodiments of the present disclosure may include the described polycyclic compound represented by Formula 1 of one or more embodiments in at least one functional layer provided between the first electrode EL1 and the second electrode EL2, thereby exhibiting excellent or suitable luminous efficiency and improved service life characteristics. For example, the polycyclic compound according to one or more embodiments may be included in the emission layer EML of the light emitting element ED of one or more embodiments, and the light emitting element of one or more embodiments may exhibit a long service life characteristic.

In one or more embodiments, the electronic apparatus may include a display apparatus including a plurality of light emitting devices, and a control part which controls the display apparatus. The electronic apparatus of one or more embodiments may be a device that is activated according to an electrical signal. The electronic apparatus may include display apparatuses of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display apparatus for a vehicle, a game console, a portable electronic device, and/or a camera.

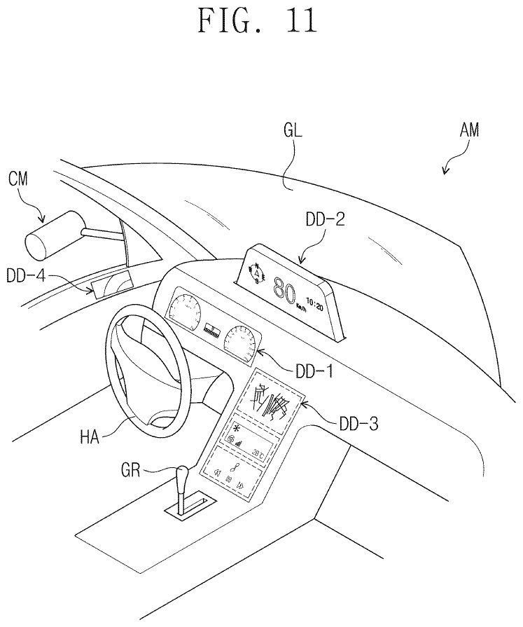

FIG. 11 is a view illustrating a vehicle AM in which first to fourth display apparatuses DD-1, DD-2, DD-3, and DD-4 are provided. At least one selected from among the first to fourth display apparatuses DD-1, DD-2, DD-3, and DD-4 may include the same configuration as the display apparatuses DD, DD-TD, DD-a, DD-b, and DD-c as described with reference to FIGS. 1, and 2, and 7 to 10.

FIG. 11 illustrates a vehicle AM, but this is merely an example, and the first to fourth display apparatuses DD-1, DD-2, DD-3, and DD-4 may be provided in another transportation vehicle such as bicycles, motorcycles, trains, ships, and/or airplanes. In some embodiments, at least one selected from among the first to fourth display apparatuses DD-1, DD-2, DD-3, and DD-4 including the same configuration as the display apparatuses DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. In some embodiments, these are merely provided as example embodiments, and thus may be employed in other electronic apparatuses unless departing from the present disclosure.

At least one selected from among the first to fourth display devices DD-1, DD-2, DD-3, and DD-4 may include the light emitting element ED of one or more embodiments as described with reference to FIGS. 3 to 6. The light emitting element ED of one or more embodiments may include a fused polycyclic compound of one or more embodiments. At least one selected from among the first to fourth display devices DD-1, DD-2, DD-3, and DD-4 may include the light emitting element ED including the fused polycyclic compound of one or more embodiments, thereby improving a display service life.

Referring to FIG. 11, the vehicle AM may include a steering wheel HA and a gear GR for driving the vehicle AM. In some embodiments, the vehicle AM may include a front window GL provided so as to face the driver.

The first display apparatus DD-1 may be provided in a first region overlapping the steering wheel HA. For example, the first display apparatus DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. A first scale and a second scale may be indicated as a digital image.

The second display apparatus DD-2 may be provided in a second region facing the driver's seat and overlapping the front window GL. The driver's seat may be a seat in which the steering wheel HA is provided. For example, the second display apparatus DD-2 may be a head up display (HUD) which displays second information of the vehicle AM. The second display apparatus DD-2 may be optically transparent. The second information may include digital numbers which indicate a driving speed, and may further include information such as the current time. Unlike the configuration illustrated, the second information of the second display apparatus DD-2 may be projected to the front window GL to be displayed.

The third display apparatus DD-3 may be provided in a third region adjacent to the gear GR. For example, the third display apparatus DD-3 may be provided between the driver's seat and the passenger seat and may be a center information display (CID) for a vehicle for displaying third information. The passenger seat may be a seat spaced and/or apart from the driver's seat with the gear GR provided therebetween. The third information may include information about traffic (e.g., navigation information), playing music or radio or a video (or an image), temperatures inside the vehicle AM, and/or the like.

The fourth display apparatus DD-4 may be spaced and/or apart from the steering wheel HA and the gear GR, and may be provided in a fourth region adjacent to the side of the vehicle AM. For example, the fourth display apparatus DD-4 may be a digital side-view mirror which displays fourth information. The fourth display apparatus DD-4 may display an image outside the vehicle AM taken by a camera module CM provided outside the vehicle AM. The fourth information may include an image outside the vehicle AM.

The herein-described first to fourth information may be examples, and the first to fourth display apparatuses DD-1, DD-2, DD-3, and DD-4 may further display information about the inside and outside of the vehicle AM. The first to fourth information may include information different than as described herein. However, the embodiment of the present disclosure is not limited thereto, and a part of the first to fourth information may include the same information as one another.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display device, light emitting element, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the display device and/or light emitting element may be formed on one integrated circuit (IC) chip or on separate IC chips. Further, the various components of the display device and/or light emitting element may be implemented on a flexible printed circuit film, a tape carrier package (TCP), a printed circuit board (PCB), or formed on one substrate. Further, the various components of the device and/or element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hereinafter, with reference to Examples and Comparative Examples, a fused polycyclic according to one or more embodiments of the present disclosure and a luminescence device of one or more embodiments of the present disclosure will be described in more detail. In some embodiments, Examples described are only illustrations to assist the understanding of the present disclosure, and the scope of the present disclosure is not limited thereto.

### EXAMPLES

### 1. Synthesis of Fused Polycyclic Compound

First, the synthetic method of the fused polycyclic compound according to one or more embodiments will be explained in detail by referring to the synthetic methods of Compounds 40, 156, 242, 324, 443, and 489. It will be understood that the synthetic methods of the fused polycyclic compounds as described are only examples, and the synthetic method of the fused polycyclic compound according to one or more embodiments of the present disclosure is not limited to the following examples.

### (1) Synthesis of Compound 40

### Synthesis of Intermediate 40-1

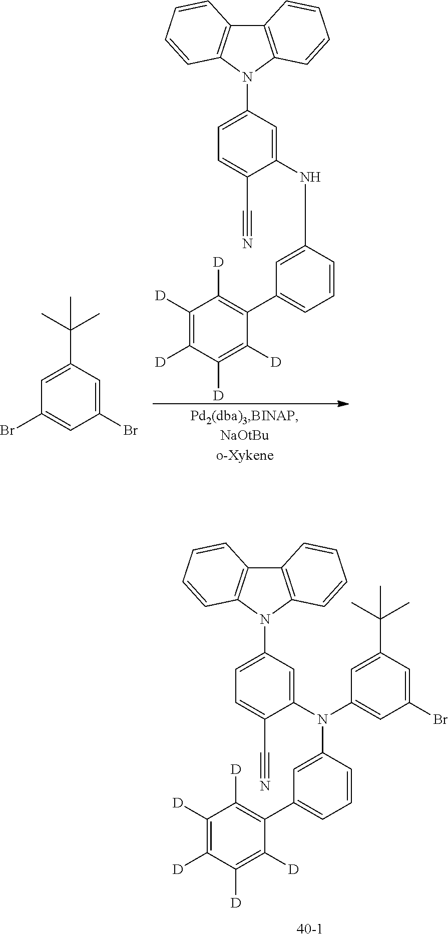 [SMILES: CC(C)(C)c1cc(Br)cc(Br)c1 ; [2H]c1c([2H])c([2H])c(-c2cccc(Nc3cc(-n4c5ccccc5c5ccccc54)ccc3C#N)c2)c([2H])c1[2H] ; [2H]c1c([2H])c([2H])c(-c2cccc(N(c3cc(Br)cc(C(C)(C)C)c3)c3cc(-n4c5ccccc5c5ccccc54)ccc3C#N)c2)c([2H])c1[2H]]

1,3-dibromo-5-(tert-butyl)benzene (1 eq), 2-(([1,1′-biphenyl]-3-yl-2′,3′,4′,5′,6′-d5)amino)-4-(9H-carbazol-9-yl)benzonitrile (1 eq), tris(dibenzylideneacetone)dipalladium(0) (0.05 eq), 2,2′-binaphthalene (BINAP, 0.10 eq), and sodium tert-butoxide (3 eq) were dissolved in o-xylene, and then the resultant mixture was stirred in a nitrogen atmosphere at about 100° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 40-1. (yield: 69%) 1

### Synthesis of Intermediate 40-2

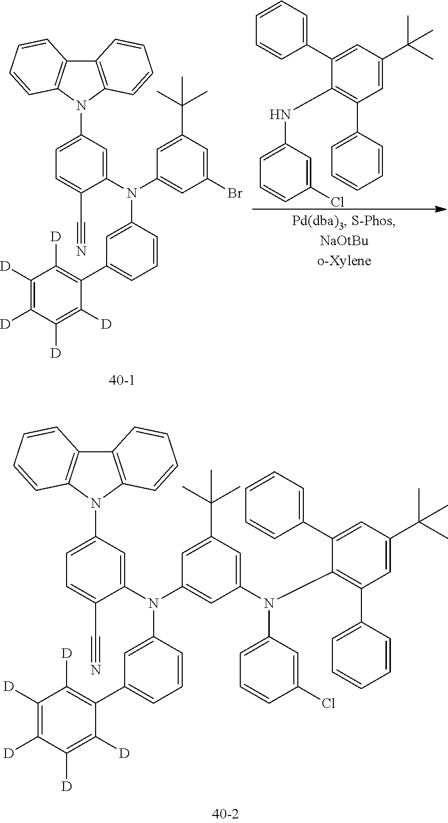

Intermediate 40-1 (1 eq), 5′-(tert-butyl)-N-(3-chlorophenyl)-[1,1′:3′,1″-terphenyl]-2′-amine (1.2 eq), tris(dibenzylideneacetone)dipalladium(0) (0.05 eq), 2-dicyclohexylphosphino-2′,6′-dimethoxybiphenyl (S-phos, 0.10 eq), and sodium tert-butoxide (3 eq) were dissolved in o-xylene, and then the resultant mixture was stirred in a high pressure reactor at about 150° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 40-2. (yield: 62%)

### Synthesis of Intermediate 40-3

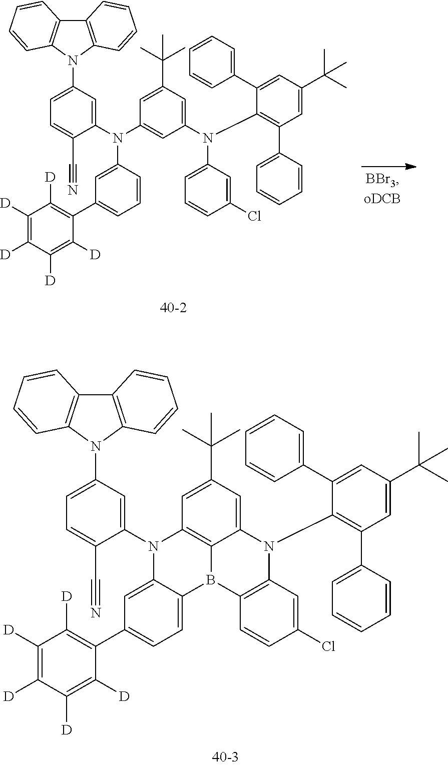 [SMILES: [2H]c1c([2H])c([2H])c(-c2cccc(N(c3cc(N(c4cccc(Cl)c4)c4c(-c5ccccc5)cc(C(C)(C)C)cc4-c4ccccc4)cc(C(C)(C)C)c3)c3cc(-n4c5ccccc5c5ccccc54)ccc3C#N)c2)c([2H])c1[2H] ; [2H]c1c([2H])c([2H])c(-c2ccc3c(c2)N(c2cc(-n4c5ccccc5c5ccccc54)ccc2C#N)c2cc(C(C)(C)C)cc4c2B3c2ccc(Cl)cc2N4c2c(-c3ccccc3)cc(C(C)(C)C)cc2-c2ccccc2)c([2H])c1[2H]]

Intermediate 40-2 (1 eq) was dissolved in ortho dichlorobenzene, and the flask was cooled to about 0° C. in a nitrogen atmosphere, and then BBr₃ (5 eq) dissolved in ortho dichlorobenzene was slowly injected thereto. After dropping was completed, the temperature was elevated to about 190° C., and the mixture was stirred for 24 hours. After the resultant mixture was cooled to about 0° C., triethylamine was slowly dropped to the flask until heating stopped to terminate the reaction, and then n-hexane and methanol were added to the flask to precipitate solids. The precipitated solids were obtained by filtration. The obtained solids were purified with silica filtration, and then purified again through recrystallization in dichloromethane:n-hexane (MC/Hex) to obtain Intermediate 40-3. Thereafter, Intermediate 40-3 was finally purified by column chromatography (dichloromethane:n-hexane). (yield: 8%)

### Synthesis of Compound 40

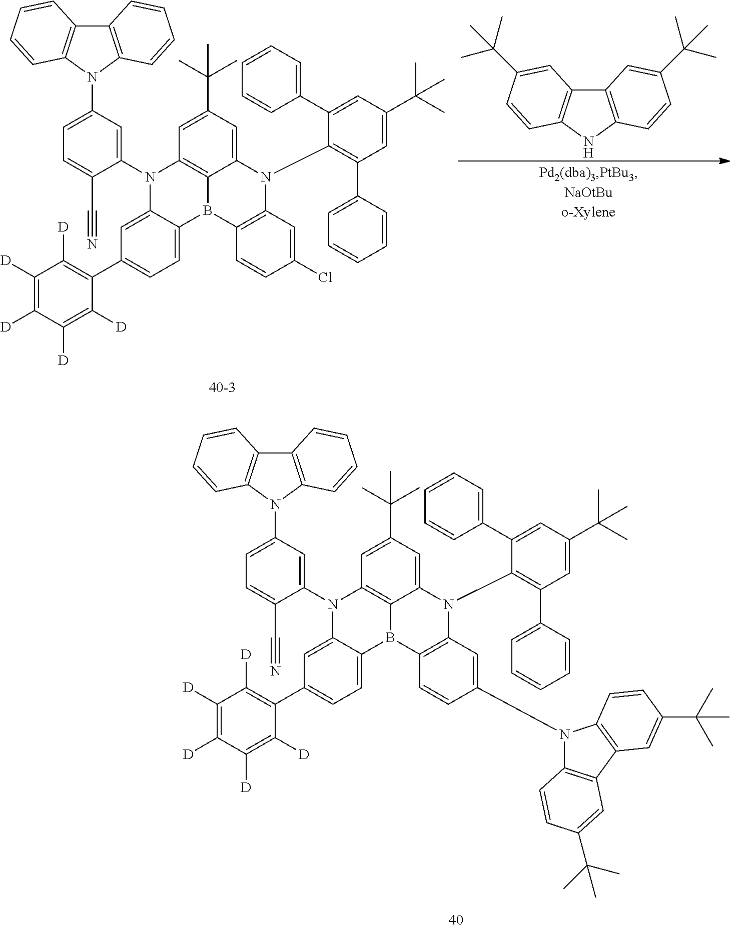

Intermediate 40-3 (1 eq), 3,6-di-tert-butyl-9H-carbazole (1.2 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 150° C. for about 24 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Compound 40 (yield: 72%). Then, the resulting product was further purified by sublimation purification to obtain final purity. The obtained compound was identified as Compound 40 through ESI-LCMS (liquid chromatography-mass spectrometry). ESI-LCMS: [M]+: C89H73D5BN5, 1233.9

### Synthesis of Intermediate 156-1

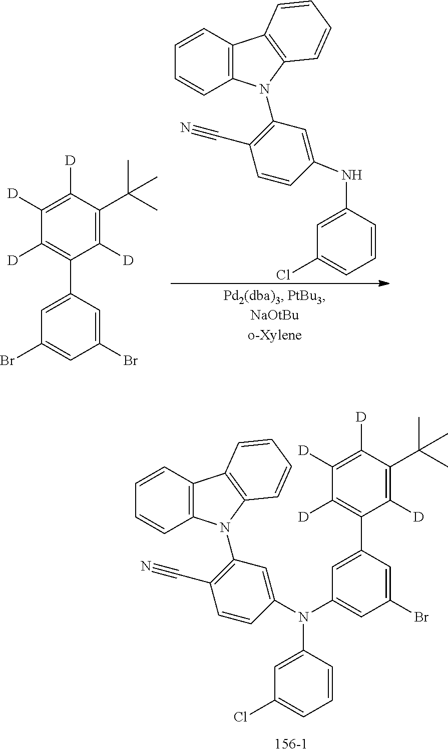 [SMILES: [2H]c1c([2H])c(-c2cc(Br)cc(Br)c2)c([2H])c(C(C)(C)C)c1[2H] ; N#Cc1ccc(Nc2cccc(Cl)c2)cc1-n1c2ccccc2c2ccccc21 ; [2H]c1c([2H])c(-c2cc(Br)cc(N(c3cccc(Cl)c3)c3ccc(C#N)c(-n4c5ccccc5c5ccccc54)c3)c2)c([2H])c(C(C)(C)C)c1[2H]]

3,5-dibromo-3′-(tert-butyl)-1,1′-biphenyl-2′,4′,5′,6′-d4 (1 eq), 2-(9H-carbazol-9-yl)-4-((3-chlorophenyl)amino)benzonitrile (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 90° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 156-1. (yield: 71%)

### Synthesis of Intermediate 156-2

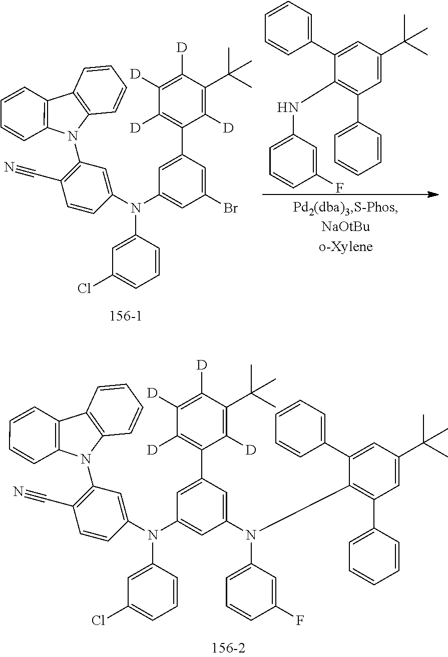

Intermediate 156-1 (1 eq), 5′-(tert-butyl)-N-(3-fluorophenyl)-[1,1′:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-phos, 0.10 eq), and sodium tert-butoxide (3 eq) were dissolved in o-xylene, and then the resultant mixture was stirred in a high pressure reactor in a nitrogen atmosphere at about 120° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 156-2. (yield: 60%)

### Synthesis of Intermediate 156-3

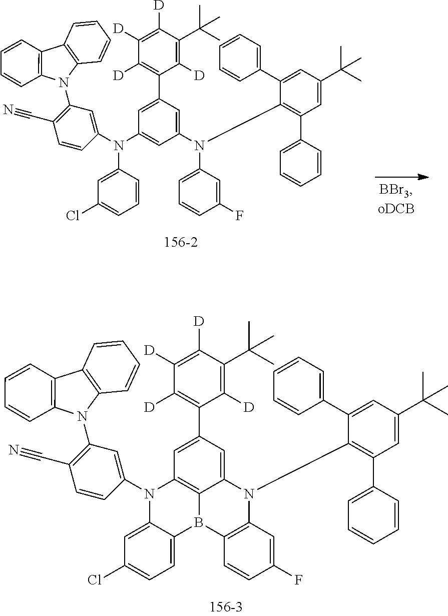 [SMILES: [2H]c1c([2H])c(-c2cc(N(c3cccc(Cl)c3)c3ccc(C#N)c(-n4c5ccccc5c5ccccc54)c3)cc(N(c3cccc(F)c3)c3c(-c4ccccc4)cc(C(C)(C)C)cc3-c3ccccc3)c2)c([2H])c(C(C)(C)C)c1[2H] ; [2H]c1c([2H])c(-c2cc3c4c(c2)N(c2c(-c5ccccc5)cc(C(C)(C)C)cc2-c2ccccc2)c2cc(F)ccc2B4c2ccc(Cl)cc2N3c2ccc(C#N)c(-n3c4ccccc4c4ccccc43)c2)c([2H])c(C(C)(C)C)c1[2H]]

Intermediate 156-2 (1 eq) was dissolved in ortho dichlorobenzene, and the flask was cooled to about 0° C. in a nitrogen atmosphere, and then BBr₃ (5 eq) dissolved in ortho dichlorobenzene was slowly injected thereto. After dropping was completed, the temperature was elevated to about 190° C., and the mixture was stirred for 24 hours. After the resultant mixture was cooled to about 0° C., triethylamine was slowly dropped to the flask until heating stopped to terminate the reaction, and then n-hexane and methanol were added to the flask to precipitate solids. The precipitated solids were obtained by filtration. The obtained solids were purified with silica filtration, and then purified again through recrystallization in MC/Hex to obtain Intermediate 156-3. Thereafter, Intermediate 156-3 was finally purified by column chromatography (dichloromethane:n-hexane). (yield: 9%)

### Synthesis of Intermediate 156-4

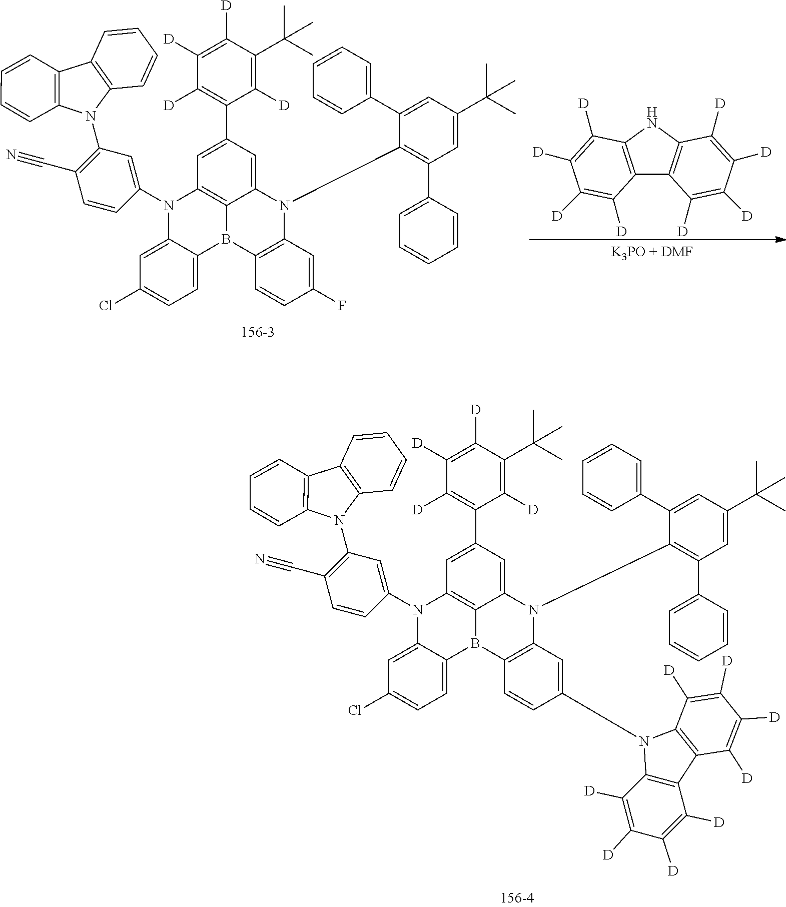

Intermediate 156-3 (1 eq), 9H-carbazole-1,2,3,4,5,6,7,8-d₈ (1.2 eq), and potassium phosphate tribasic (K₃PO₄, 3 eq) were dissolved in N,N-dimethylformamide (DMF), and then the resultant mixture was stirred for 24 hours after elevating the temperature to about 150° C. After cooled, the resultant mixture was dried under reduced pressure and the DMF was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 156-4. (yield: 56%)

### Synthesis of Compound 156

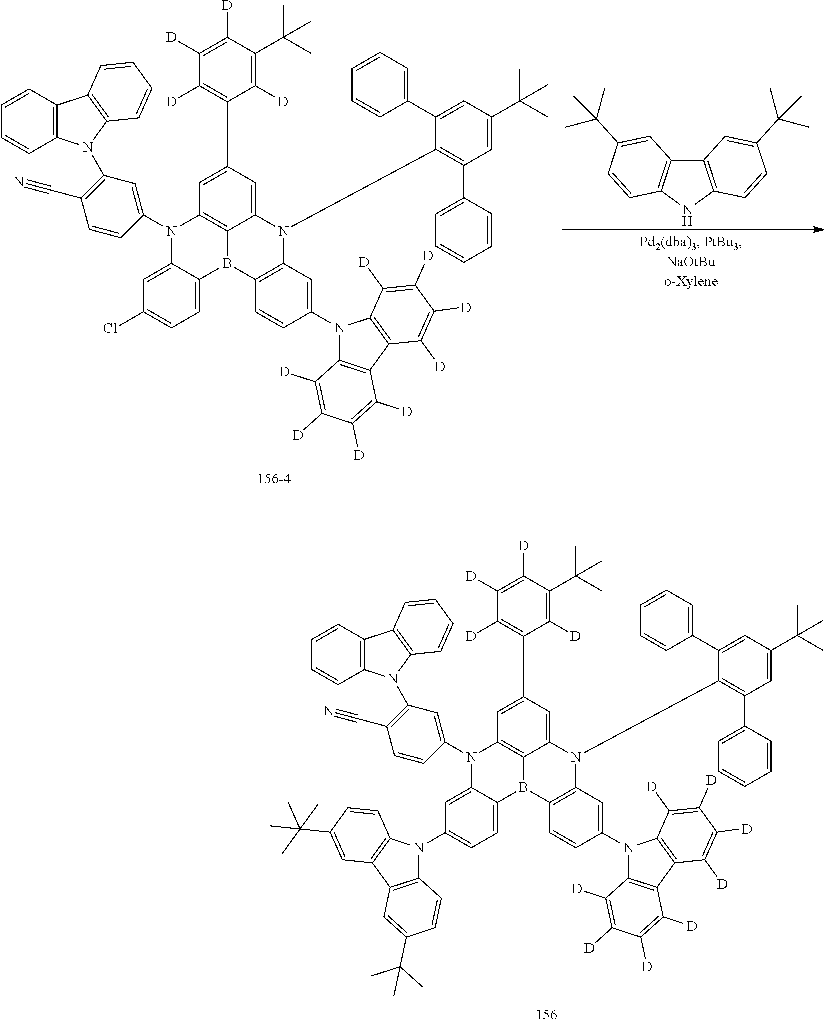

Intermediate 156-4 (1 eq), 3,6-di-tert-butyl-9H-carbazole (1.2 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 150° C. for about 24 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Compound 156 (yield: 70%). Then, the resulting product was further purified by sublimation purification to obtain final purity. The obtained compound was identified as Compound 156 through ESI-LCMS. ESI-LCMS: [M]+: C101H73D12BN6, 1406.1

### (3) Synthesis of Compound 171

### Synthesis of Intermediate 171-1

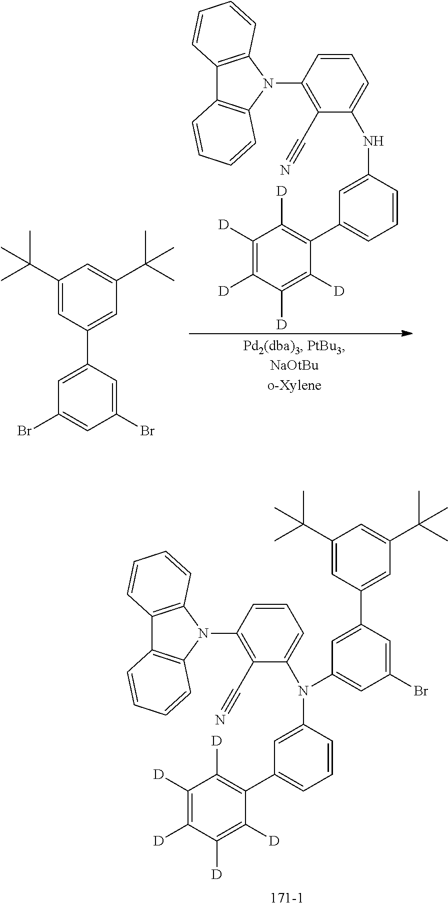 [SMILES: CC(C)(C)c1cc(-c2cc(Br)cc(Br)c2)cc(C(C)(C)C)c1 ; [2H]c1c([2H])c([2H])c(-c2cccc(Nc3cccc(-n4c5ccccc5c5ccccc54)c3C#N)c2)c([2H])c1[2H] ; [2H]c1c([2H])c([2H])c(-c2cccc(N(c3cc(Br)cc(-c4cc(C(C)(C)C)cc(C(C)(C)C)c4)c3)c3cccc(-n4c5ccccc5c5ccccc54)c3C#N)c2)c([2H])c1[2H]]

3,5-dibromo-3′,5′-di-tert-butyl-1,1′-biphenyl (1 eq), 2-(([1,1′-biphenyl]-3-yl-2′,3′,4′,5′,6′-d5)amino)-6-(9H-carbazol-9-yl)benzonitrile (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 90° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 171-1. (yield: 76%)

### Synthesis of Intermediate 171-2

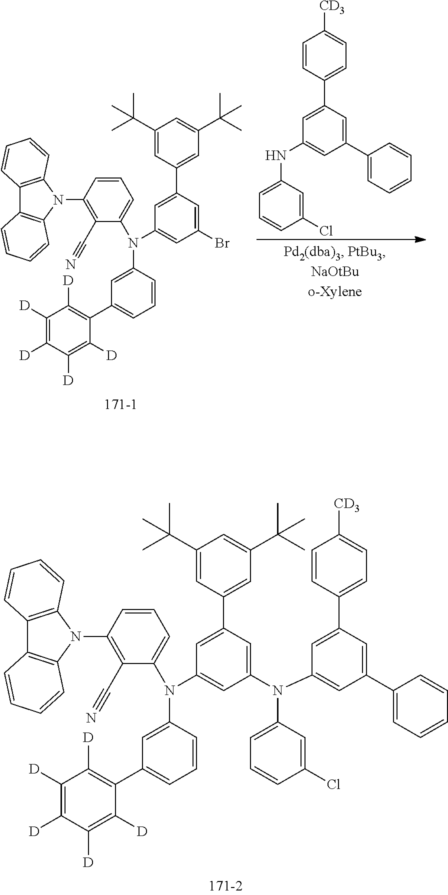 [SMILES: [2H]c1c([2H])c([2H])c(-c2cccc(N(c3cc(Br)cc(-c4cc(C(C)(C)C)cc(C(C)(C)C)c4)c3)c3cccc(-n4c5ccccc5c5ccccc54)c3C#N)c2)c([2H])c1[2H] ; [2H]C([2H])([2H])c1ccc(-c2cc(Nc3cccc(Cl)c3)cc(-c3ccccc3)c2)cc1 ; [2H]c1c([2H])c([2H])c(-c2cccc(N(c3cc(-c4cc(C(C)(C)C)cc(C(C)(C)C)c4)cc(N(c4cccc(Cl)c4)c4cc(-c5ccccc5)cc(-c5ccc(C([2H])([2H])[2H])cc5)c4)c3)c3cccc(-n4c5ccccc5c5ccccc54)c3C#N)c2)c([2H])c1[2H]]

Intermediate 171-1 (1 eq), N-(3-chlorophenyl)-4-(methyl-d3)-[1,1′:3′,1″-terphenyl]-5′-amine (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 100° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 171-2. (yield: 68%)

### Synthesis of Intermediate 171-3

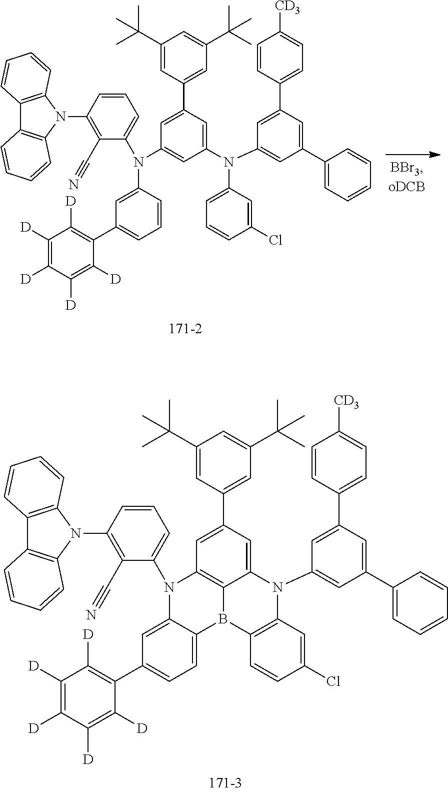 [SMILES: [2H]c1c([2H])c([2H])c(-c2cccc(N(c3cc(-c4cc(C(C)(C)C)cc(C(C)(C)C)c4)cc(N(c4cccc(Cl)c4)c4cc(-c5ccccc5)cc(-c5ccc(C([2H])([2H])[2H])cc5)c4)c3)c3cccc(-n4c5ccccc5c5ccccc54)c3C#N)c2)c([2H])c1[2H] ; [2H]c1c([2H])c([2H])c(-c2ccc3c(c2)N(c2cccc(-n4c5ccccc5c5ccccc54)c2C#N)c2cc(-c4cc(C(C)(C)C)cc(C(C)(C)C)c4)cc4c2B3c2ccc(Cl)cc2N4c2cc(-c3ccccc3)cc(-c3ccc(C([2H])([2H])[2H])cc3)c2)c([2H])c1[2H]]

Intermediate 171-3 (1 eq) was dissolved in ortho dichlorobenzene, and the flask was cooled to about 0° C. in a nitrogen atmosphere, and then BBr₃ (5 eq) dissolved in ortho dichlorobenzene was slowly injected thereto. After dropping was completed, the temperature was elevated to about 190° C., and the mixture was stirred for 24 hours. After the resultant mixture was cooled to about 0° C., triethylamine was slowly dropped to the flask until heating stopped to terminate the reaction, and then n-hexane and methanol were added to the flask to precipitate solids. The precipitated solids were obtained by filtration. The obtained solids were purified with silica filtration, and then purified again through recrystallization in MC/Hex to obtain Intermediate 171-3. Thereafter, Intermediate 171-3 was finally purified by column chromatography (dichloromethane:n-hexane). (yield: 13%)

### Synthesis of Compound 171

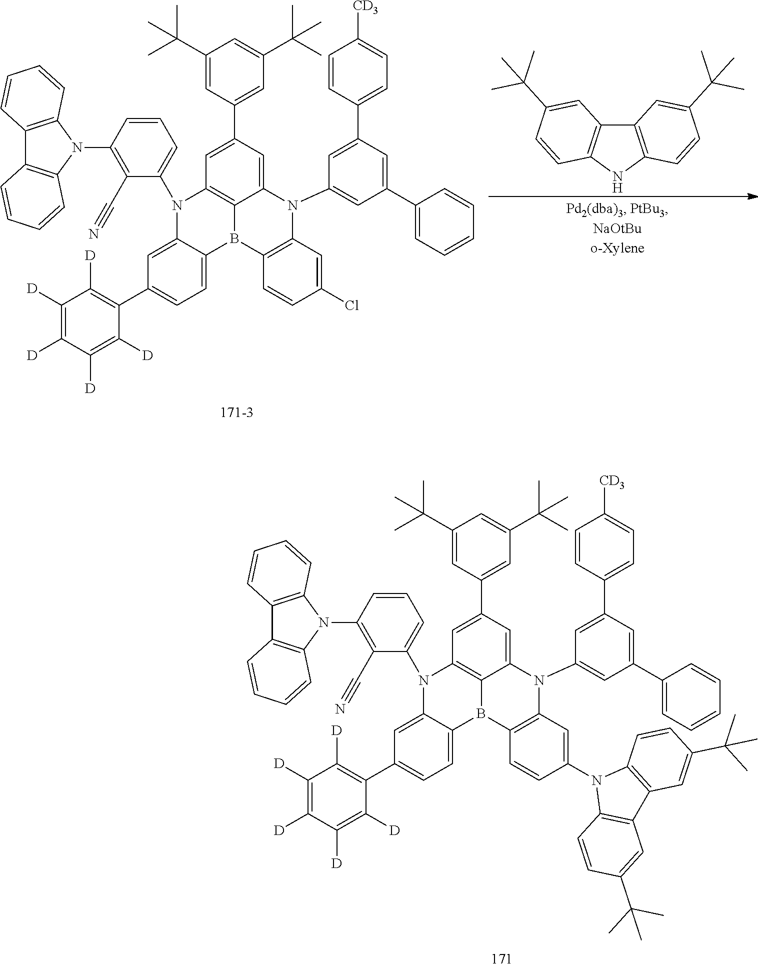 [SMILES: [2H]c1c([2H])c([2H])c(-c2ccc3c(c2)N(c2cccc(-n4c5ccccc5c5ccccc54)c2C#N)c2cc(-c4cc(C(C)(C)C)cc(C(C)(C)C)c4)cc4c2B3c2ccc(Cl)cc2N4c2cc(-c3ccccc3)cc(-c3ccc(C([2H])([2H])[2H])cc3)c2)c([2H])c1[2H] ; CC(C)(C)c1ccc2[nH]c3ccc(C(C)(C)C)cc3c2c1 ; [2H]c1c([2H])c([2H])c(-c2ccc3c(c2)N(c2cccc(-n4c5ccccc5c5ccccc54)c2C#N)c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2cc(-c3ccccc3)cc(-c3ccc(C([2H])([2H])[2H])cc3)c2)c([2H])c1[2H]]

Intermediate 171-3 (1 eq), 3,6-di-tert-butyl-9H-carbazole (1.2 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 150° C. for about 24 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Compound 171 (yield: 70%). Then, the resulting product was further purified by sublimation purification to obtain final purity. The obtained compound was identified as Compound 171 through ESI-LCMS. ESI-LCMS: [M]+: C96H76D8BN5, 1327.0

### (4) Synthesis of Compound 242

### Synthesis of Intermediate 242-1

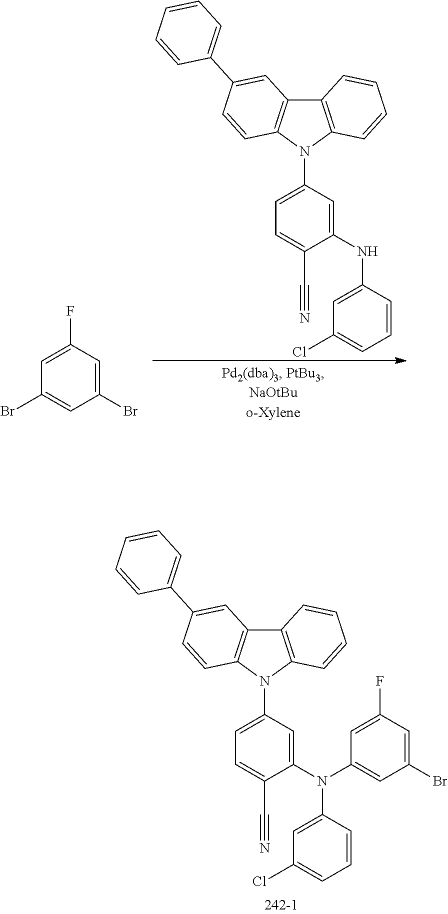 [SMILES: Fc1cc(Br)cc(Br)c1 ; N#Cc1ccc(-n2c3ccccc3c3cc(-c4ccccc4)ccc32)cc1Nc1cccc(Cl)c1 ; N#Cc1ccc(-n2c3ccccc3c3cc(-c4ccccc4)ccc32)cc1N(c1cccc(Cl)c1)c1cc(F)cc(Br)c1]

1,3-dibromo-5-fluorobenzene (1 eq), 2-((3-chlorophenyl)amino)-4-(3-phenyl-9H-carbazol-9-yl)benzonitrile (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 100° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 242-1. (yield: 73%)

### Synthesis of Intermediate 242-2

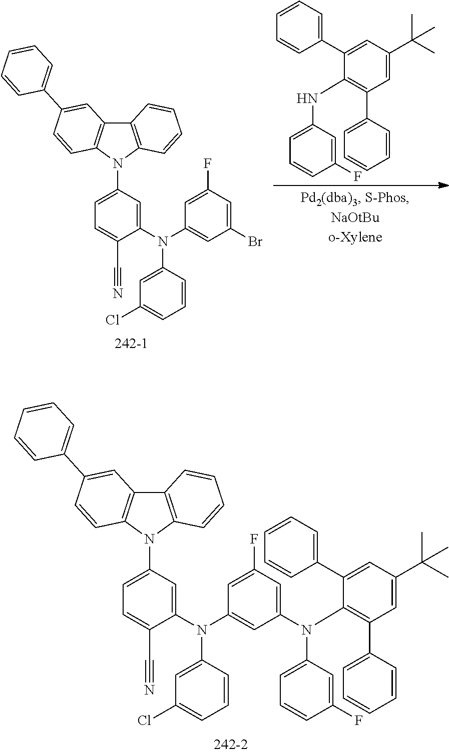 [SMILES: N#Cc1ccc(-n2c3ccccc3c3cc(-c4ccccc4)ccc32)cc1N(c1cccc(Cl)c1)c1cc(F)cc(Br)c1 ; CC(C)(C)c1cc(-c2ccccc2)c(Nc2cccc(F)c2)c(-c2ccccc2)c1 ; CC(C)(C)c1cc(-c2ccccc2)c(N(c2cccc(F)c2)c2cc(F)cc(N(c3cccc(Cl)c3)c3cc(-n4c5ccccc5c5cc(-c6ccccc6)ccc54)ccc3C#N)c2)c(-c2ccccc2)c1]

Intermediate 242-1 (1 eq), 5′-(tert-butyl)-N-(3-fluorophenyl)-[1, 1:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-phos, 0.10 eq), and sodium tert-butoxide (3 eq) were dissolved in o-xylene, and then the resultant mixture was stirred in a high pressure reactor in a nitrogen atmosphere at about 120° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 242-2. (yield: 58%)

### Synthesis of Intermediate 242-3

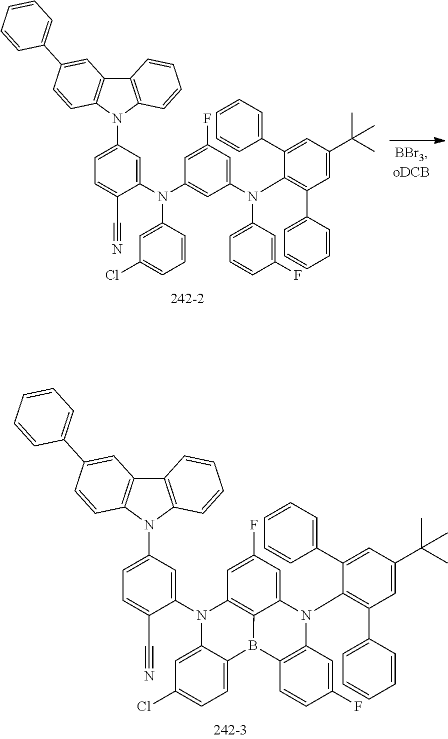 [SMILES: CC(C)(C)c1cc(-c2ccccc2)c(N(c2cccc(F)c2)c2cc(F)cc(N(c3cccc(Cl)c3)c3cc(-n4c5ccccc5c5cc(-c6ccccc6)ccc54)ccc3C#N)c2)c(-c2ccccc2)c1 ; CC(C)(C)c1cc(-c2ccccc2)c(N2c3cc(F)ccc3B3c4ccc(Cl)cc4N(c4cc(-n5c6ccccc6c6cc(-c7ccccc7)ccc65)ccc4C#N)c4cc(F)cc2c43)c(-c2ccccc2)c1]

Intermediate 242-2 (1 eq) was dissolved in ortho dichlorobenzene, and the flask was cooled to about 0° C. in a nitrogen atmosphere, and then BBr₃ (5 eq) dissolved in ortho dichlorobenzene was slowly injected thereto. After dropping was completed, the temperature was elevated to about 190° C., and the mixture was stirred for 24 hours. After the resultant mixture was cooled to about 0° C., triethylamine was slowly dropped to the flask until heating stopped to terminate the reaction, and then n-hexane and methanol were added to the flask to precipitate solids. The precipitated solids were obtained by filtration. The obtained solids were purified with silica filtration, and then purified again through recrystallization in MC/Hex to obtain Intermediate 242-3. Thereafter, Intermediate 242-3 was finally purified by column chromatography (dichloromethane:n-hexane). (yield: 10%)

### Synthesis of Intermediate 242-4

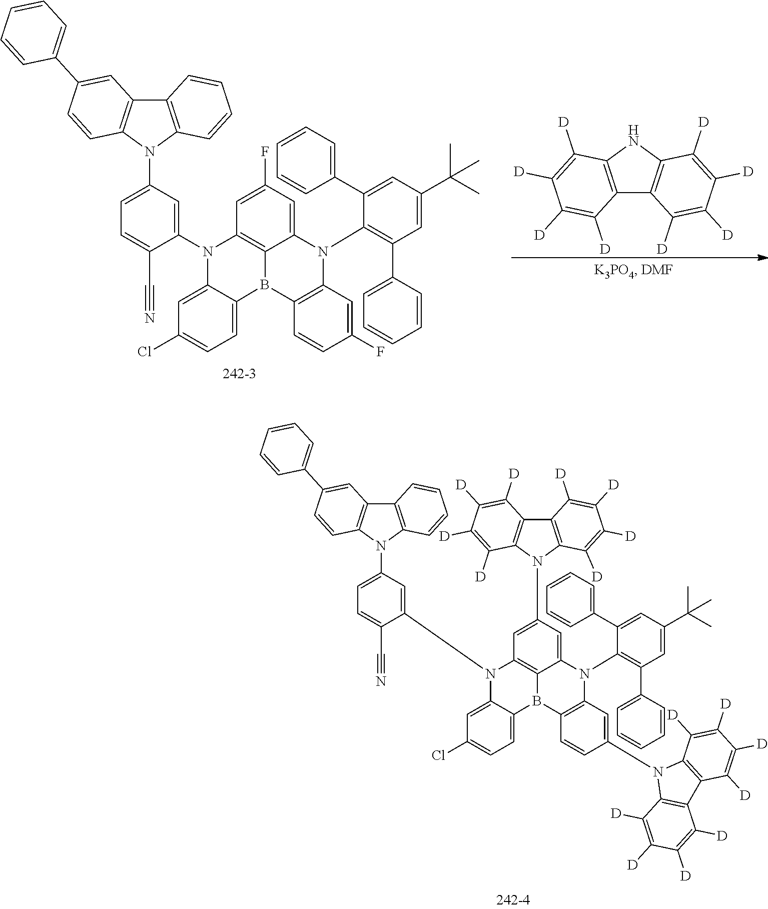 [SMILES: CC(C)(C)c1cc(-c2ccccc2)c(N2c3cc(F)ccc3B3c4ccc(Cl)cc4N(c4cc(-n5c6ccccc6c6cc(-c7ccccc7)ccc65)ccc4C#N)c4cc(F)cc2c43)c(-c2ccccc2)c1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c([2H])c([2H])c([2H])c43)cc3c1B2c1ccc(Cl)cc1N3c1cc(-n2c3ccccc3c3cc(-c4ccccc4)ccc32)ccc1C#N]

Intermediate 242-3 (1 eq), 9H-carbazole-1,2,3,4,5,6,7,8-de (1.2 eq), and potassium phosphate tribasic (K₃PO₄, 3 eq) were dissolved in N,N-dimethylformamide (DMF), and then the resultant mixture was stirred for 24 hours after elevating the temperature to about 150° C. After cooled, the resultant mixture was dried under reduced pressure and the DMF was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 242-4. (yield: 55%)

### Synthesis of Compound 242

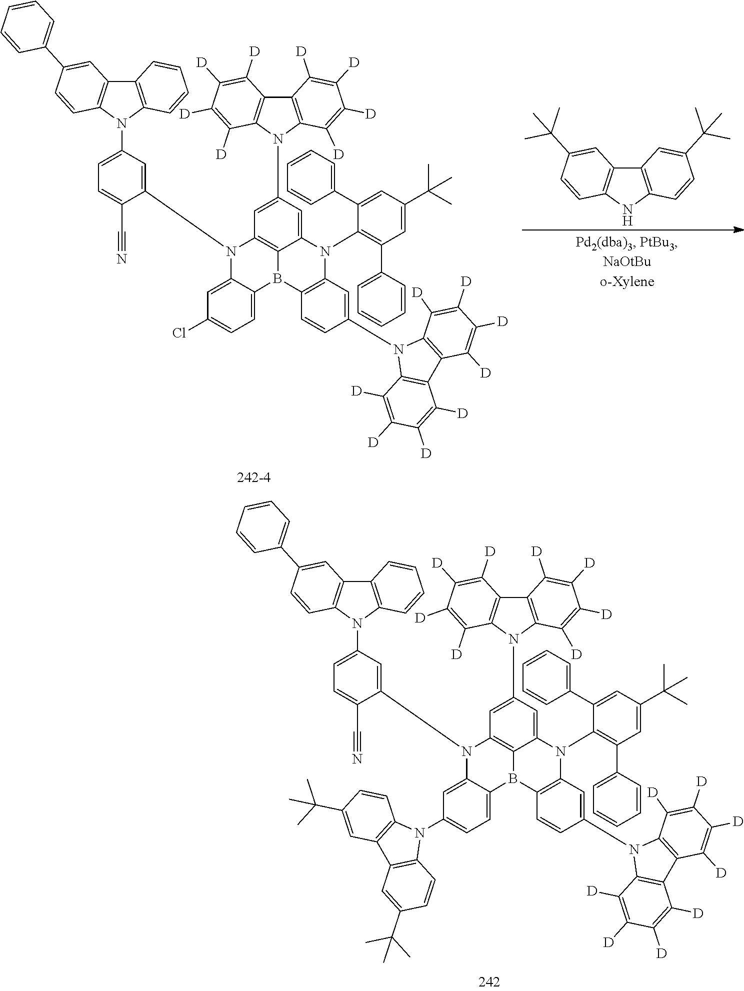

Intermediate 242-4 (1 eq), 3,6-di-tert-butyl-9H-carbazole (1.2 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 150° C. for about 24 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized (dichloromethane:n-hexane) by column chromatography to obtain Compound 242 (yield: 61%). Then, the resulting product was further purified by sublimation purification to obtain final purity. The obtained compound was identified as Compound 242 through ESI-LCMS. ESI-LCMS: [M]+: C109H68D16BN7, 1519.2

### (5) Synthesis of Compound 248

### Synthesis of Intermediate 248-1

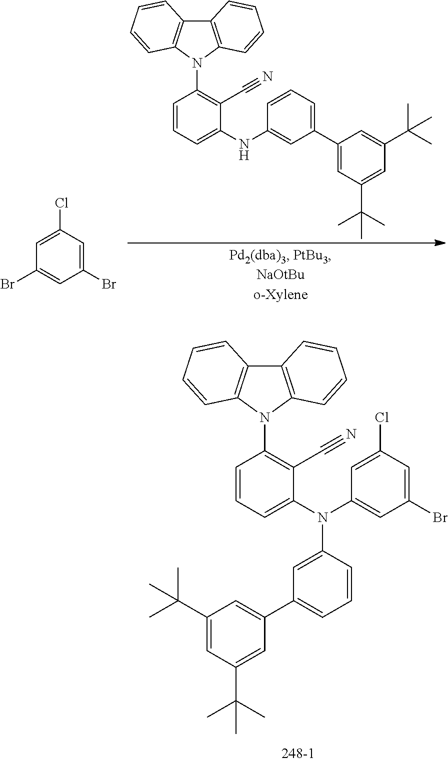

1,3-dibromo-5-chlorobenzene (1 eq), 2-(9H-carbazol-9-yl)-6-((3′,5′-di-tert-butyl-[1,1′-biphenyl]-3-yl)amino)benzonitrile (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 100° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 248-1. (yield: 77%)

### Synthesis of Intermediate 248-2

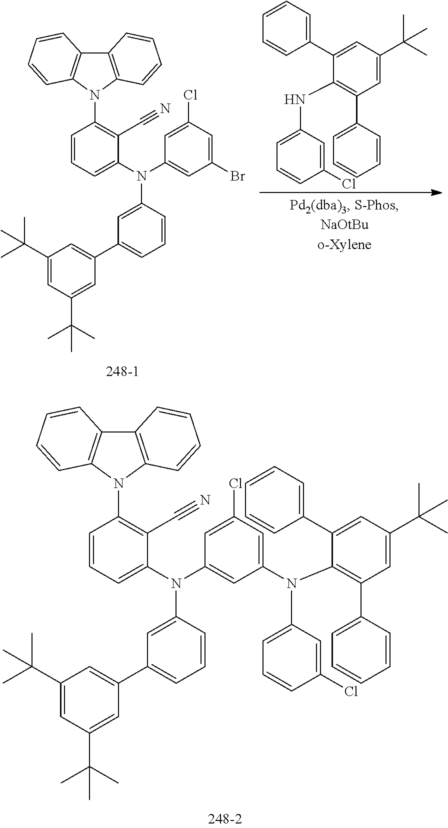

Intermediate 248-1 (1 eq), 5′-(tert-butyl)-N-(3-chlorophenyl)-[1,1′:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-phos, 0.10 eq), and sodium tert-butoxide (3 eq) were dissolved in o-xylene, and then the resultant mixture was stirred in a high pressure reactor in a nitrogen atmosphere at about 120° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 248-2. (yield: 61%)

### Synthesis of Intermediate 248-3

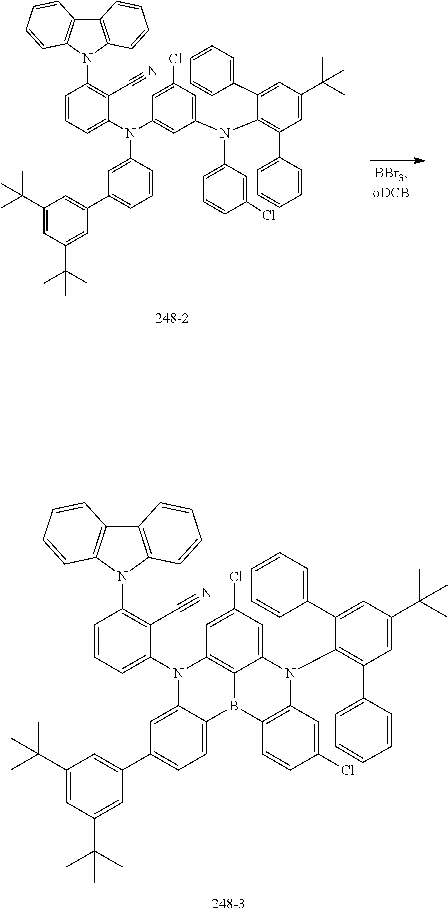

Intermediate 248-2 (1 eq) was dissolved in ortho dichlorobenzene, and the flask was cooled to about 0° C. in a nitrogen atmosphere, and then BBr₃ (5 eq) dissolved in ortho dichlorobenzene was slowly injected thereto. After dropping was completed, the temperature was elevated to about 190° C., and the mixture was stirred for 24 hours. After the resultant mixture was cooled to about 0° C., triethylamine was slowly dropped to the flask until heating stopped to terminate the reaction, and then n-hexane and methanol were added to the flask to precipitate solids. The precipitated solids were obtained by filtration. The obtained solids were purified with silica filtration, and then purified again through recrystallization in MC/Hex to obtain Intermediate 248-3. Thereafter, Intermediate 248-3 was finally purified by column chromatography (dichloromethane:n-hexane). (yield: 11%)

### Synthesis of Compound 248

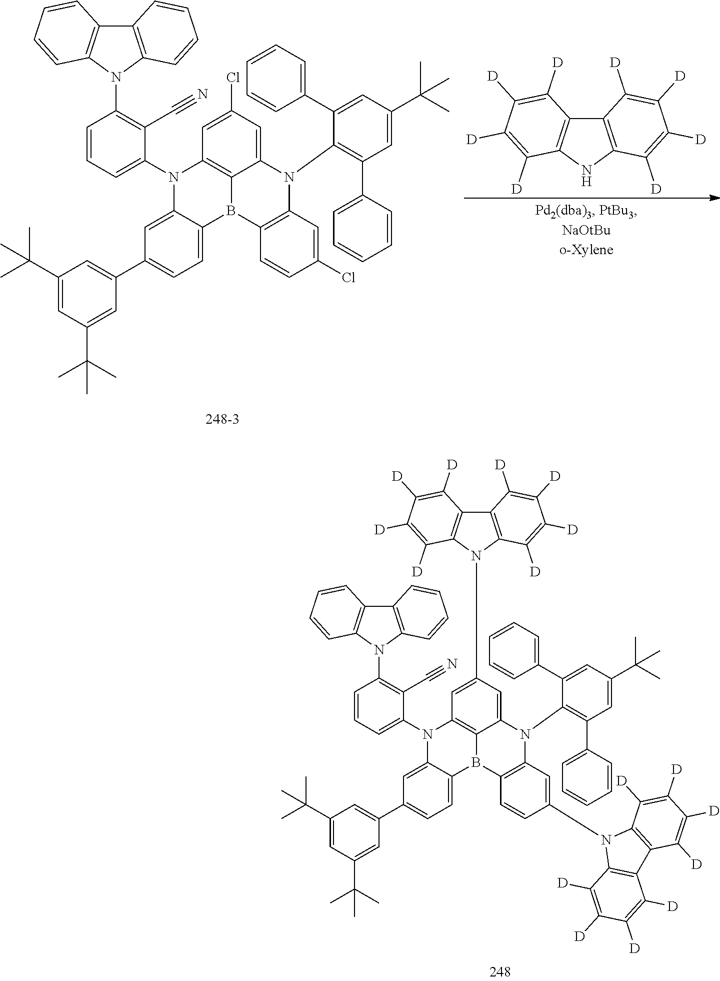

Intermediate 248-3 (1 eq), 9H-carbazole-1,2,3,4,5,6,7,8-d (2.4 eq), tris(dibenzylideneacetone)dipalladium(0) (0.1 eq), tri-tert-butylphosphine (PtBu₃, 0.2 eq), and sodium tert-butoxide (3 eq) were dissolved in o-xylene, and then the resultant mixture was stirred in a nitrogen atmosphere at about 150° C. for about 24 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized (dichloromethane:n-hexane) by column chromatography to obtain Compound 248 (yield: 57%). Then, the resulting product was further purified by sublimation purification to obtain final purity. The obtained compound was identified as Compound 248 through ESI-LCMS. ESI-LCMS: [M]+: C97H61D16BN6, 1354.0

### (6) Synthesis of Compound 324

### Synthesis of Intermediate 324-1

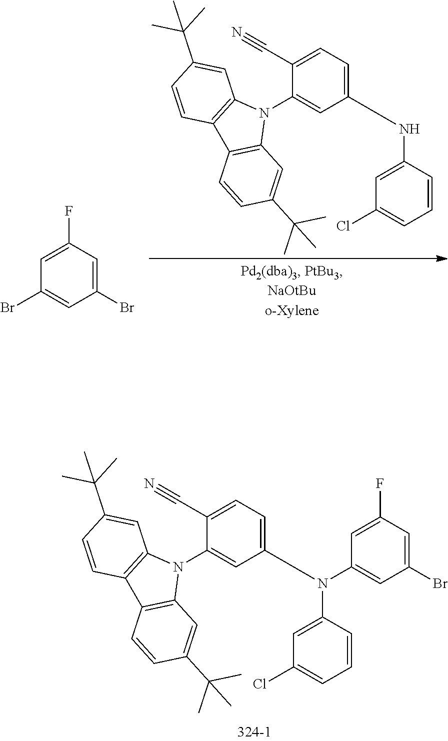 [SMILES: Fc1cc(Br)cc(Br)c1 ; CC(C)(C)c1ccc2c3ccc(C(C)(C)C)cc3n(-c3cc(Nc4cccc(Cl)c4)ccc3C#N)c2c1 ; CC(C)(C)c1ccc2c3ccc(C(C)(C)C)cc3n(-c3cc(N(c4cccc(Cl)c4)c4cc(F)cc(Br)c4)ccc3C#N)c2c1]

1,3-dibromo-5-fluorobenzene (1 eq), 4-((3-bromo-5-fluorophenyl)(3-chlorophenyl)amino)-2-(2,7-di-tert-butyl-9H-carbazol-9-yl)benzonitrile (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 100° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 324-1. (yield: 75%)

### Synthesis of Intermediate 324-2

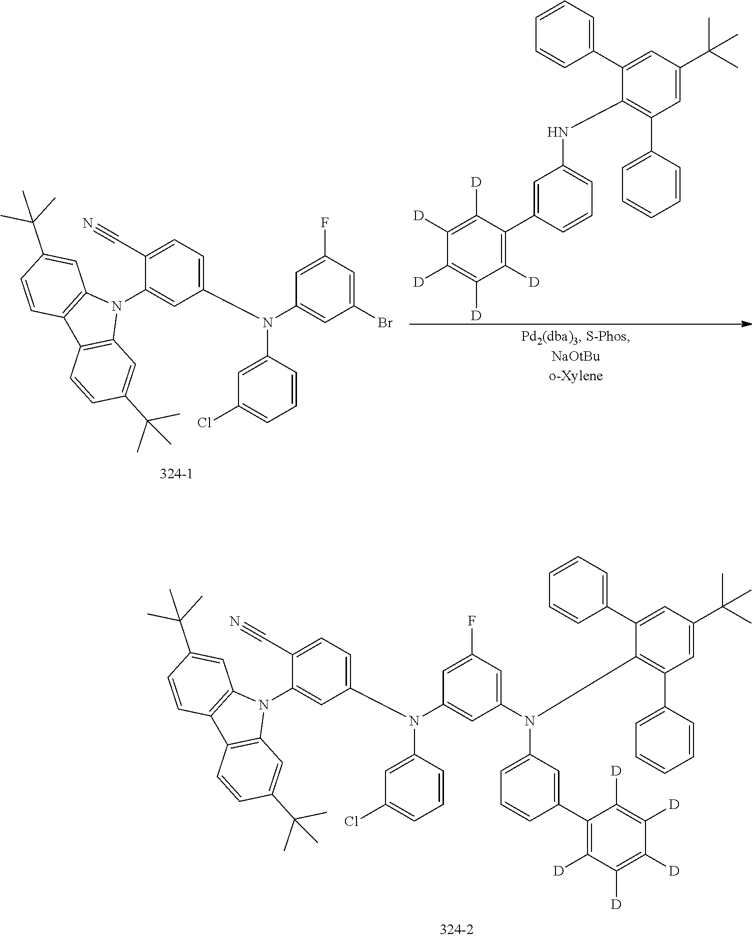 [SMILES: CC(C)(C)c1ccc2c3ccc(C(C)(C)C)cc3n(-c3cc(N(c4cccc(Cl)c4)c4cc(F)cc(Br)c4)ccc3C#N)c2c1 ; [2H]c1c([2H])c([2H])c(-c2cccc(Nc3c(-c4ccccc4)cc(C(C)(C)C)cc3-c3ccccc3)c2)c([2H])c1[2H] ; [2H]c1c([2H])c([2H])c(-c2cccc(N(c3cc(F)cc(N(c4cccc(Cl)c4)c4ccc(C#N)c(-n5c6cc(C(C)(C)C)ccc6c6ccc(C(C)(C)C)cc65)c4)c3)c3c(-c4ccccc4)cc(C(C)(C)C)cc3-c3ccccc3)c2)c([2H])c1[2H]]

Intermediate 324-1 (1 eq), 5′-(tert-butyl)-N-(3-fluorophenyl)-[1,1′:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-phos, 0.10 eq), and sodium tert-butoxide (3 eq) were dissolved in o-xylene, and then the resultant mixture was stirred in a high pressure reactor in a nitrogen atmosphere at about 120° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 324-2. (yield: 58%)

### Synthesis of Intermediate 324-3

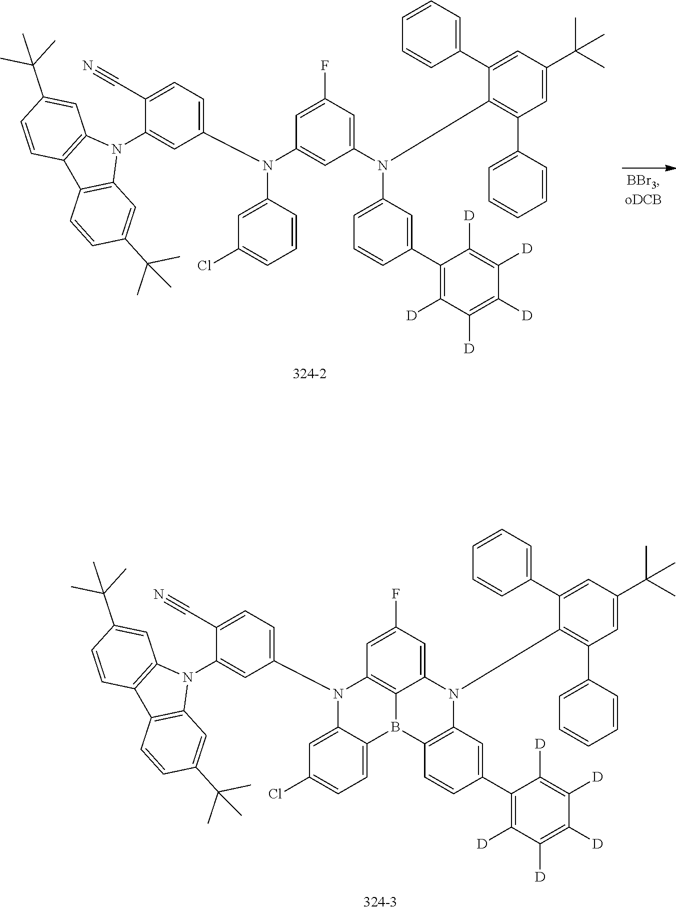

Intermediate 324-2 (1 eq) was dissolved in ortho dichlorobenzene, and the flask was cooled to about 0° C. in a nitrogen atmosphere, and then BBr₃ (5 eq) dissolved in ortho dichlorobenzene was slowly injected thereto. After dropping was completed, the temperature was elevated to about 190° C., and the mixture was stirred for 24 hours. After the resultant mixture was cooled to about 0° C., triethylamine was slowly dropped to the flask until heating stopped to terminate the reaction, and then n-hexane and methanol were added to the flask to precipitate solids. The precipitated solids were obtained by filtration. The obtained solids were purified with silica filtration, and then purified again through recrystallization in MC/Hex to obtain Intermediate 324-3. Thereafter, Intermediate 324-3 was finally purified by column chromatography (dichloromethane:n-hexane). (yield: 12%)

### Synthesis of Intermediate 324-4

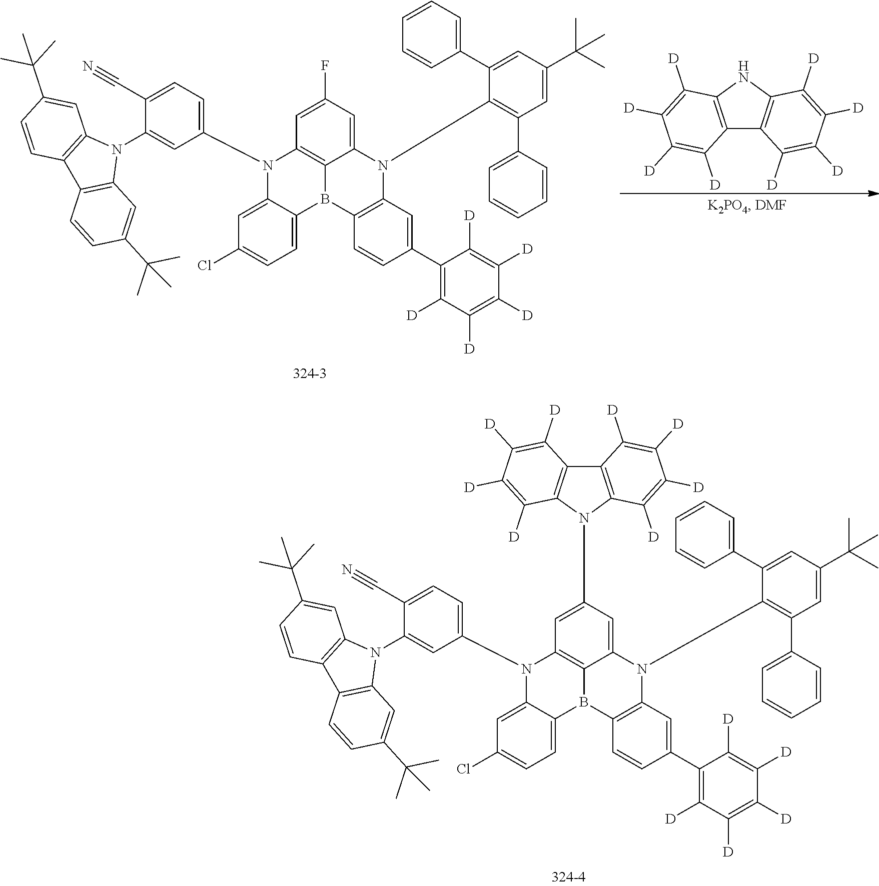

Intermediate 324-3 (1 eq), 9H-carbazole-1,2,3,4,5,6,7,8-de (1.2 eq), and potassium phosphate tribasic (K₃PO₄, 3 eq) were dissolved in N,N-dimethylformamide (DMF), and then the resultant mixture was stirred for 24 hours after elevating the temperature to about 150° C. After cooled, the resultant mixture was dried under reduced pressure and the DMF was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 324-4. (yield: 57%)

### Synthesis of Compound 324

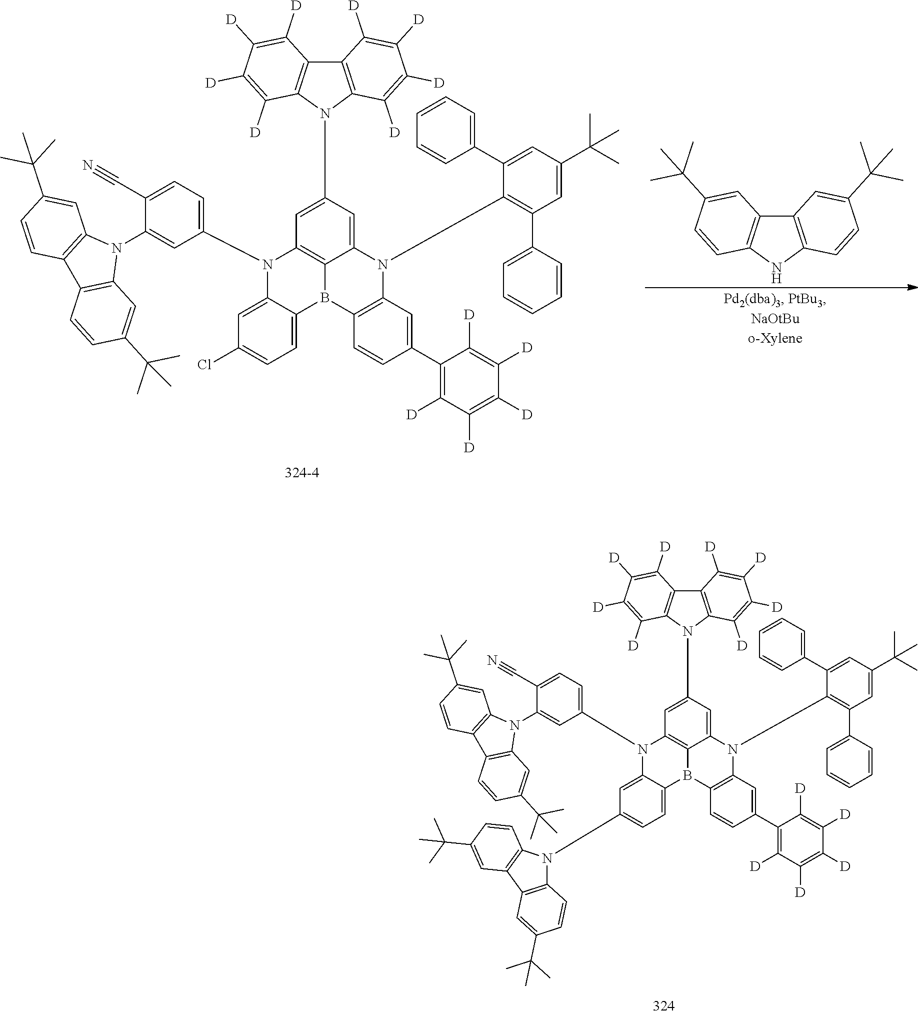

Intermediate 324-4 (1 eq), 3,6-di-tert-butyl-9H-carbazole (1.2 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 150° C. for about 24 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized (dichloromethane:n-hexane) by column chromatography to obtain Compound 324 (yield: 64%). Then, the resulting product was further purified by sublimation purification to obtain final purity. The obtained compound was identified as Compound 324 through ESI-LCMS. ESI-LCMS: [M]+: C105H80D13BN6, 1463.2

### (7) Synthesis of Compound 397

### Synthesis of Intermediate 397-1

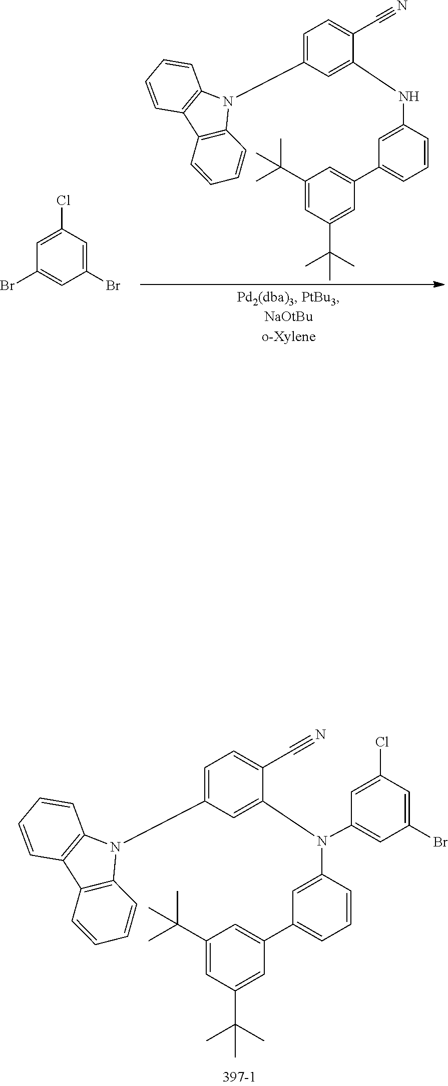 [SMILES: Clc1cc(Br)cc(Br)c1 ; CC(C)(C)c1cc(-c2cccc(Nc3cc(-n4c5ccccc5c5ccccc54)ccc3C#N)c2)cc(C(C)(C)C)c1 ; CC(C)(C)c1cc(-c2cccc(N(c3cc(Cl)cc(Br)c3)c3cc(-n4c5ccccc5c5ccccc54)ccc3C#N)c2)cc(C(C)(C)C)c1]

1,3-dibromo-5-chlorobenzene (1 eq), 4-(9H-carbazol-9-yl)-2-((3′,5′-di-tert-butyl-[1,1′-biphenyl]-3-yl)amino)benzonitrile (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 90° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 397-1. (yield: 70%)

### Synthesis of Intermediate 397-2

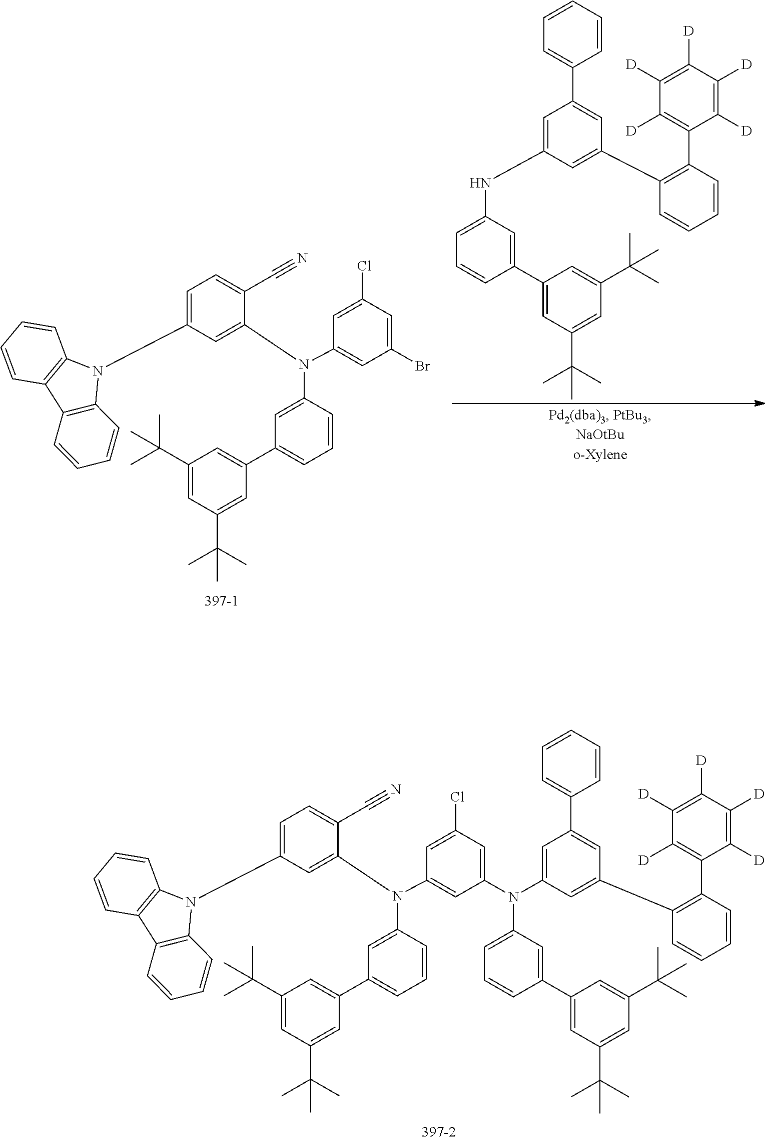 [SMILES: CC(C)(C)c1cc(-c2cccc(N(c3cc(Cl)cc(Br)c3)c3cc(-n4c5ccccc5c5ccccc54)ccc3C#N)c2)cc(C(C)(C)C)c1 ; [2H]c1c([2H])c([2H])c(-c2ccccc2-c2cc(Nc3cccc(-c4cc(C(C)(C)C)cc(C(C)(C)C)c4)c3)cc(-c3ccccc3)c2)c([2H])c1[2H] ; [2H]c1c([2H])c([2H])c(-c2ccccc2-c2cc(-c3ccccc3)cc(N(c3cccc(-c4cc(C(C)(C)C)cc(C(C)(C)C)c4)c3)c3cc(Cl)cc(N(c4cccc(-c5cc(C(C)(C)C)cc(C(C)(C)C)c5)c4)c4cc(-n5c6ccccc6c6ccccc65)ccc4C#N)c3)c2)c([2H])c1[2H]]

Intermediate 397-1 (1 eq), N-(3′,5′-di-tert-butyl-[1,1′-biphenyl]-3-yl)-[1,1′:2′,1″:3″,1′″-quaterphenyl]-2,3,4,5,6-d5-5″-amine (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 90° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 397-2. (yield: 68%)

### Synthesis of Intermediate 397-3

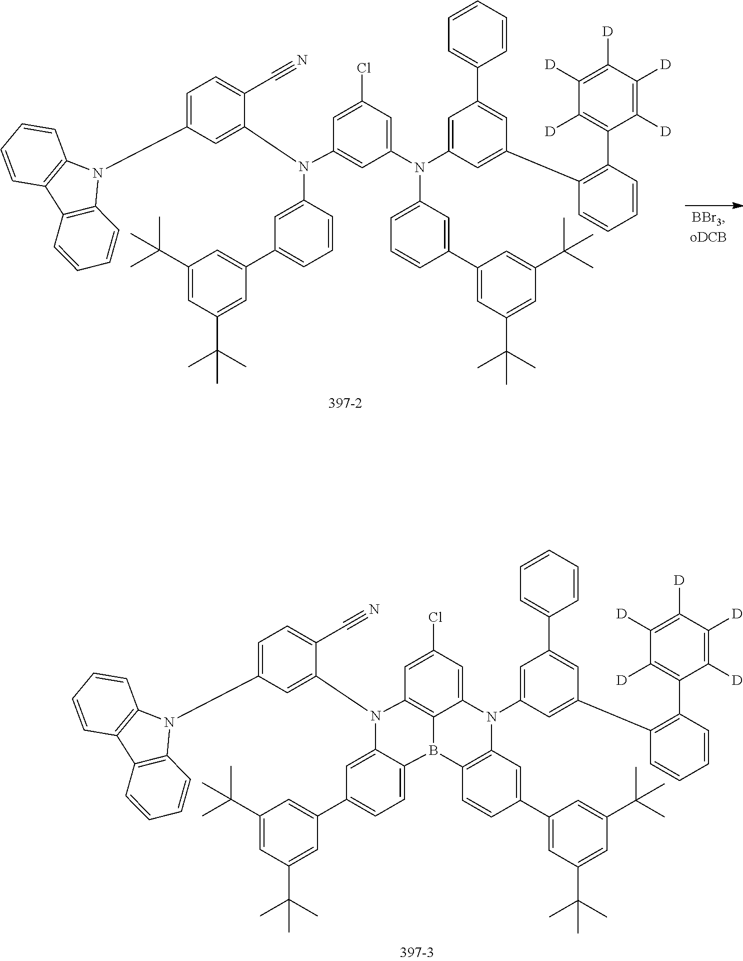 [SMILES: [2H]c1c([2H])c([2H])c(-c2ccccc2-c2cc(-c3ccccc3)cc(N(c3cccc(-c4cc(C(C)(C)C)cc(C(C)(C)C)c4)c3)c3cc(Cl)cc(N(c4cccc(-c5cc(C(C)(C)C)cc(C(C)(C)C)c5)c4)c4cc(-n5c6ccccc6c6ccccc65)ccc4C#N)c3)c2)c([2H])c1[2H] ; [2H]c1c([2H])c([2H])c(-c2ccccc2-c2cc(-c3ccccc3)cc(N3c4cc(-c5cc(C(C)(C)C)cc(C(C)(C)C)c5)ccc4B4c5ccc(-c6cc(C(C)(C)C)cc(C(C)(C)C)c6)cc5N(c5cc(-n6c7ccccc7c7ccccc76)ccc5C#N)c5cc(Cl)cc3c54)c2)c([2H])c1[2H]]

Intermediate 397-2 (1 eq) was dissolved in ortho dichlorobenzene, and the flask was cooled to about 0° C. in a nitrogen atmosphere, and then BBr₃ (5 eq) dissolved in ortho dichlorobenzene was slowly injected thereto. After dropping was completed, the temperature was elevated to about 190° C., and the mixture was stirred for 24 hours. After the resultant mixture was cooled to about 0° C., triethylamine was slowly dropped to the flask until heating stopped to terminate the reaction, and then n-hexane and methanol were added to the flask to precipitate solids. The precipitated solids were obtained by filtration. The obtained solids were purified with silica filtration, and then purified again through recrystallization in MC/Hex to obtain Intermediate 397-3. Thereafter, Intermediate 397-3 was finally purified by column chromatography (dichloromethane:n-hexane). (yield: 10%)

### Synthesis of Compound 397

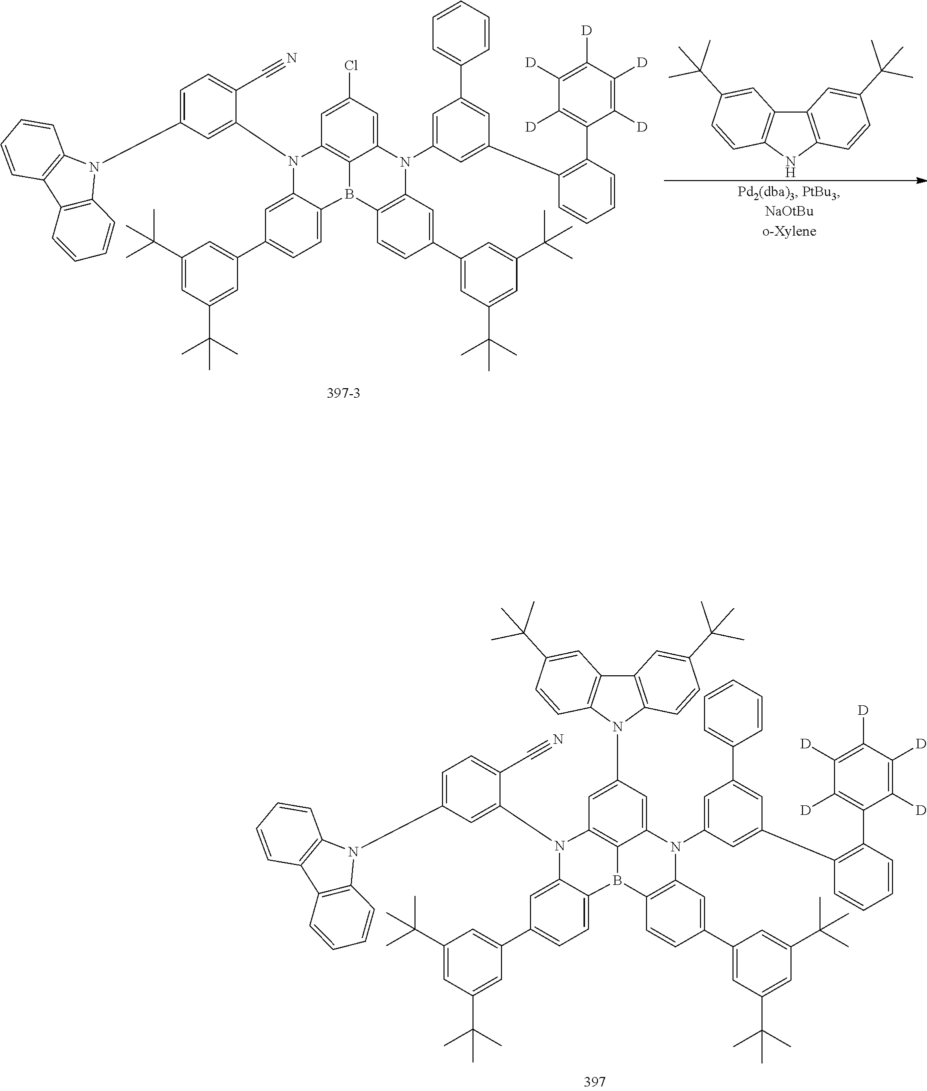

Intermediate 397-3 (1 eq), 3,6-di-tert-butyl-9H-carbazole (1.2 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 150° C. for about 24 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized (dichloromethane:n-hexane) by column chromatography to obtain Compound 397 (yield: 62%). Then, the resulting product was further purified by sublimation purification to obtain final purity. The obtained compound was identified as Compound 397 through ESI-LCMS. ESI-LCMS: [M]+: C109H97D5BN5, 1498.3

### (8) Synthesis of Compound 443

### Synthesis of Intermediate 443-1

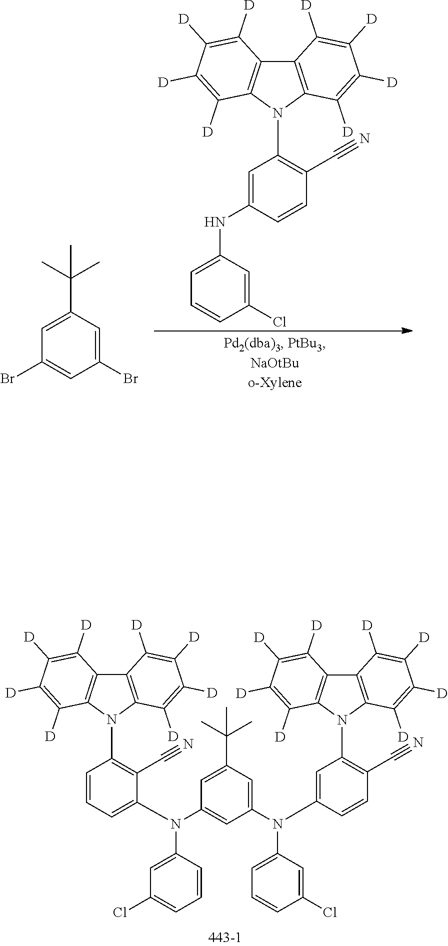 [SMILES: CC(C)(C)c1cc(Br)cc(Br)c1 ; [2H]c1c([2H])c([2H])c2c(c1[2H])c1c([2H])c([2H])c([2H])c([2H])c1n2-c1cc(Nc2cccc(Cl)c2)ccc1C#N ; [2H]c1c([2H])c([2H])c2c(c1[2H])c1c([2H])c([2H])c([2H])c([2H])c1n2-c1cc(N(c2cccc(Cl)c2)c2cc(N(c3cccc(Cl)c3)c3cccc(-n4c5c([2H])c([2H])c([2H])c([2H])c5c5c([2H])c([2H])c([2H])c([2H])c54)c3C#N)cc(C(C)(C)C)c2)ccc1C#N]

1,3-dibromo-5-(tert-butyl)benzene (1 eq), 2-(9H-carbazol-9-yl-d8)-4-((3-chlorophenyl)amino)benzonitrile (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 100° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 443-1. (yield: 69%)

### Synthesis of Intermediate 443-2

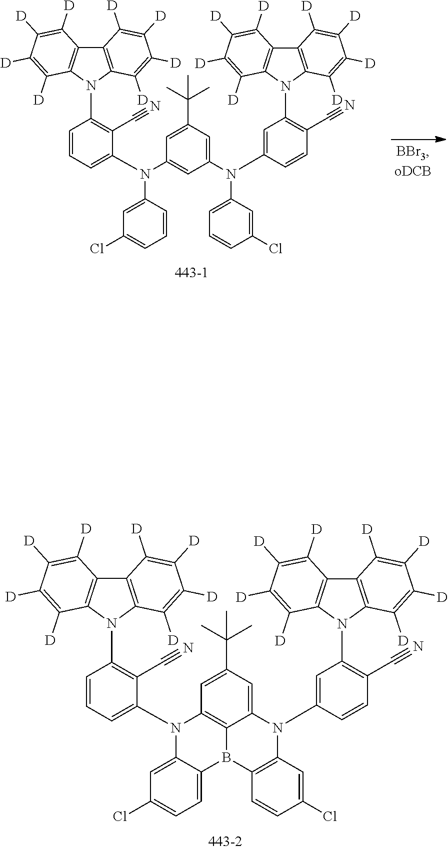 [SMILES: [2H]c1c([2H])c([2H])c2c(c1[2H])c1c([2H])c([2H])c([2H])c([2H])c1n2-c1cc(N(c2cccc(Cl)c2)c2cc(N(c3cccc(Cl)c3)c3cccc(-n4c5c([2H])c([2H])c([2H])c([2H])c5c5c([2H])c([2H])c([2H])c([2H])c54)c3C#N)cc(C(C)(C)C)c2)ccc1C#N ; [2H]c1c([2H])c([2H])c2c(c1[2H])c1c([2H])c([2H])c([2H])c([2H])c1n2-c1cc(N2c3cc(Cl)ccc3B3c4ccc(Cl)cc4N(c4cccc(-n5c6c([2H])c([2H])c([2H])c([2H])c6c6c([2H])c([2H])c([2H])c([2H])c65)c4C#N)c4cc(C(C)(C)C)cc2c43)ccc1C#N]

Intermediate 443-1 (1 eq) was dissolved in ortho dichlorobenzene, and the flask was cooled to about 0° C. in a nitrogen atmosphere, and then BBr₃ (5 eq) dissolved in ortho dichlorobenzene was slowly injected thereto. After dropping was completed, the temperature was elevated to about 190° C., and the mixture was stirred for 24 hours. After the resultant mixture was cooled to about 0° C., triethylamine was slowly dropped to the flask until heating stopped to terminate the reaction, and then n-hexane and methanol were added to the flask to precipitate solids. The precipitated solids were obtained by filtration. The obtained solids were purified with silica filtration, and then purified again through recrystallization in MC/Hex to obtain Intermediate 443-(dichloromethane:n-hexane). (yield: 12%)

### Synthesis of Compound 443

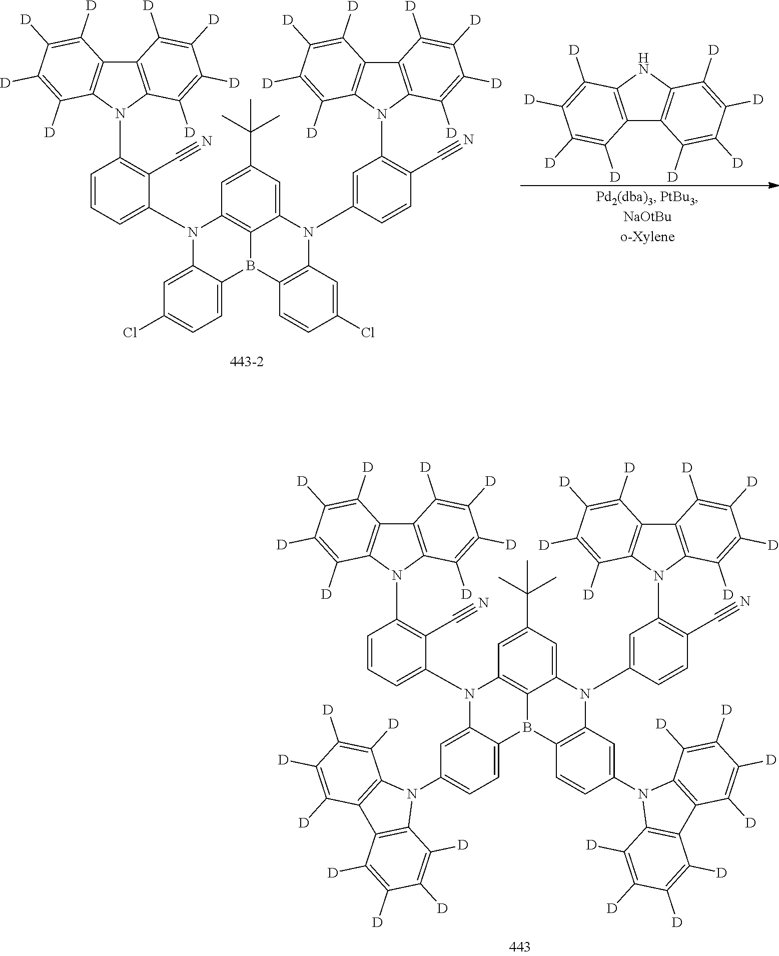

Intermediate 443-3 (1 eq), 9H-carbazole-1,2,3,4,5,6,7,8-de (1.2 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 150° C. for about 24 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Compound 443 (yield: 66%). Then, the resulting product was further purified by sublimation purification to obtain final purity. The obtained compound was identified as Compound 242 through ESI-LCMS. ESI-LCMS: [M]+: C84H23D32BN8, 1219.8 (9) Synthesis of Compound 489

### Synthesis of Intermediate 489-1

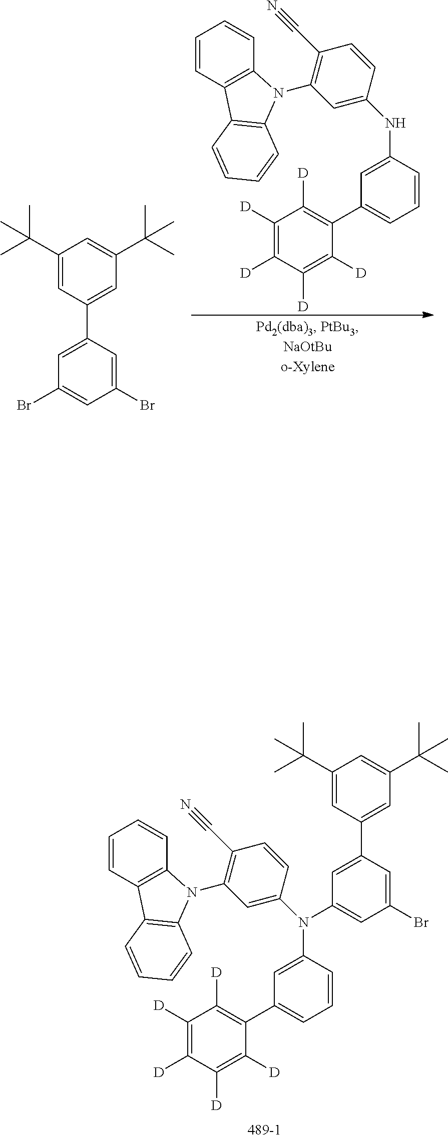 [SMILES: CC(C)(C)c1cc(-c2cc(Br)cc(Br)c2)cc(C(C)(C)C)c1 ; [2H]c1c([2H])c([2H])c(-c2cccc(Nc3ccc(C#N)c(-n4c5ccccc5c5ccccc54)c3)c2)c([2H])c1[2H] ; [2H]c1c([2H])c([2H])c(-c2cccc(N(c3cc(Br)cc(-c4cc(C(C)(C)C)cc(C(C)(C)C)c4)c3)c3ccc(C#N)c(-n4c5ccccc5c5ccccc54)c3)c2)c([2H])c1[2H]]

3,5-dibromo-3′,5′-di-tert-butyl-1,1′-biphenyl (1 eq), 4-(([1,1′-biphenyl]-3-yl-2′,3′,4′,5′,6′-d₅)amino)-2-(9H-carbazol-9-yl)benzonitrile (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 100° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 489-1. (yield: 74%)

### Synthesis of Intermediate 489-2

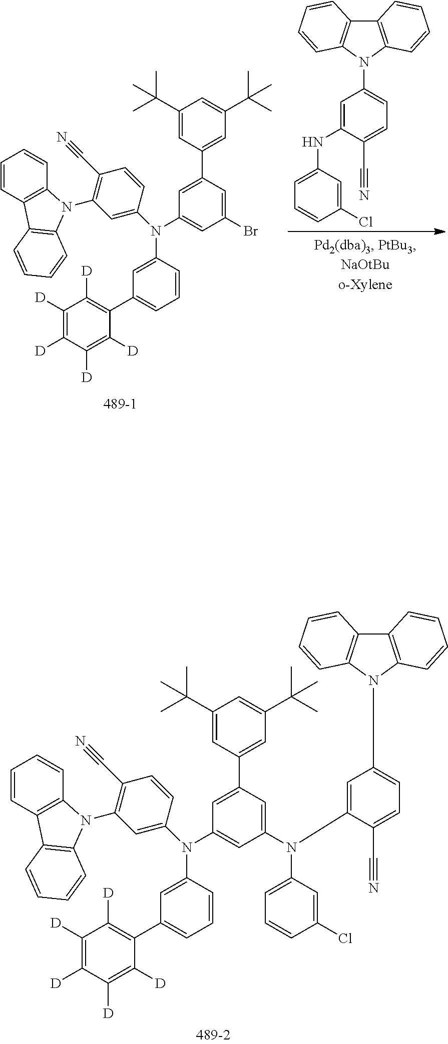 [SMILES: [2H]c1c([2H])c([2H])c(-c2cccc(N(c3cc(Br)cc(-c4cc(C(C)(C)C)cc(C(C)(C)C)c4)c3)c3ccc(C#N)c(-n4c5ccccc5c5ccccc54)c3)c2)c([2H])c1[2H] ; N#Cc1ccc(-n2c3ccccc3c3ccccc32)cc1Nc1cccc(Cl)c1 ; [2H]c1c([2H])c([2H])c(-c2cccc(N(c3cc(-c4cc(C(C)(C)C)cc(C(C)(C)C)c4)cc(N(c4cccc(Cl)c4)c4cc(-n5c6ccccc6c6ccccc65)ccc4C#N)c3)c3ccc(C#N)c(-n4c5ccccc5c5ccccc54)c3)c2)c([2H])c1[2H]]

Intermediate 489-1 (1 eq), 4-(9H-carbazol-9-yl)-2-((3-chlorophenyl)amino)benzonitrile (1 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 100° C. for about 20 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized by column chromatography (dichloromethane:n-hexane) to obtain Intermediate 489-2. (yield: 76%)

### Synthesis of Intermediate 489-3

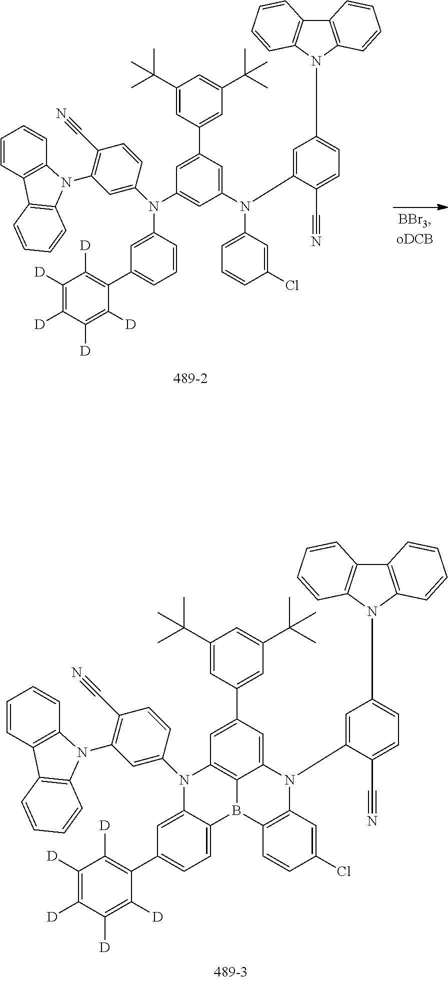 [SMILES: [2H]c1c([2H])c([2H])c(-c2cccc(N(c3cc(-c4cc(C(C)(C)C)cc(C(C)(C)C)c4)cc(N(c4cccc(Cl)c4)c4cc(-n5c6ccccc6c6ccccc65)ccc4C#N)c3)c3ccc(C#N)c(-n4c5ccccc5c5ccccc54)c3)c2)c([2H])c1[2H] ; [2H]c1c([2H])c([2H])c(-c2ccc3c(c2)N(c2ccc(C#N)c(-n4c5ccccc5c5ccccc54)c2)c2cc(-c4cc(C(C)(C)C)cc(C(C)(C)C)c4)cc4c2B3c2ccc(Cl)cc2N4c2cc(-n3c4ccccc4c4ccccc43)ccc2C#N)c([2H])c1[2H]]

Intermediate 489-2 (1 eq) was dissolved in ortho dichlorobenzene, and the flask was cooled to about 0° C. in a nitrogen atmosphere, and then BBr₃ (5 eq) dissolved in ortho dichlorobenzene was slowly injected thereto. After dropping was completed, the temperature was elevated to about 190° C., and the mixture was stirred for 24 hours. After the resultant mixture was cooled to about 0° C., triethylamine was slowly dropped to the flask until heating stopped to terminate the reaction, and then n-hexane and methanol were added to the flask to precipitate solids. The precipitated solids were obtained by filtration. The obtained solids were purified with silica filtration, and then purified again through recrystallization in MC/Hex to obtain Intermediate 489-3. Thereafter, Intermediate 489-3 was finally purified by column chromatography (dichloromethane:n-hexane). (yield: 11%)

### Synthesis of Compound 489

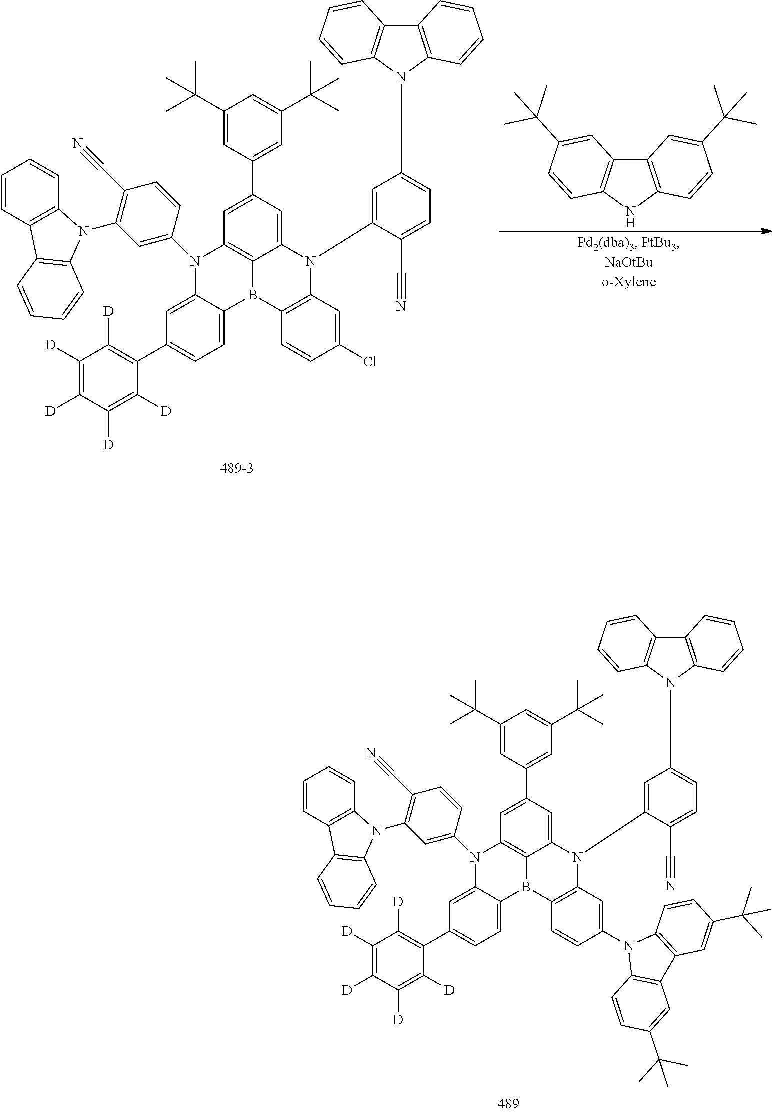 [SMILES: [2H]c1c([2H])c([2H])c(-c2ccc3c(c2)N(c2ccc(C#N)c(-n4c5ccccc5c5ccccc54)c2)c2cc(-c4cc(C(C)(C)C)cc(C(C)(C)C)c4)cc4c2B3c2ccc(Cl)cc2N4c2cc(-n3c4ccccc4c4ccccc43)ccc2C#N)c([2H])c1[2H] ; CC(C)(C)c1ccc2[nH]c3ccc(C(C)(C)C)cc3c2c1 ; [2H]c1c([2H])c([2H])c(-c2ccc3c(c2)N(c2ccc(C#N)c(-n4c5ccccc5c5ccccc54)c2)c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2cc(-n3c4ccccc4c4ccccc43)ccc2C#N)c([2H])c1[2H]]

Intermediate 489-3 (1 eq), 3,6-di-tert-butyl-9H-carbazole (1.2 eq), tris(dibenzylideneacetone)dipalladium(0) (0.05 eq), tri-tert-butylphosphine (PtBu₃, 0.10 eq), and sodium tert-butoxide (3 eq) were dissolved in o-xylene, and then the resultant mixture was stirred in a nitrogen atmosphere at about 150° C. for about 24 hours. After cooled, the resultant mixture was dried under reduced pressure, and the o-xylene was removed. Then, the resulting product was washed three times with water and ethyl acetate to obtain organic layers. The obtained organic layers were dried over MgSO₄, and then dried under reduced pressure. The resulting product was purified and recrystallized (dichloromethane:n-hexane) by column chromatography to obtain Compound 489 (yield: 65%). Then, the resulting product was further purified by sublimation purification to obtain final purity. The obtained compound was identified as Compound 489 through ESI-LCMS. ESI-LCMS: [M]+: C96H75D5BN7, 1348.0

### 1. Manufacture and Evaluation of Light Emitting Elements

The light emitting element of an example including the fused polycyclic compound of an example in an emission layer was manufactured as follows. Fused polycyclic compounds of Compounds 40, 156, 171, 242, 248, 324, 397, 443, and 489, which are Example Compounds as described herein, were utilized as dopant materials for the emission layers to manufacture the light emitting elements of Examples 1 to 7, respectively. Comparative Examples 1 to 4 correspond to the light emitting elements manufactured by utilizing Comparative Example Compounds C1 to C4 as dopant materials for the emission layers, respectively.

### Example Compounds

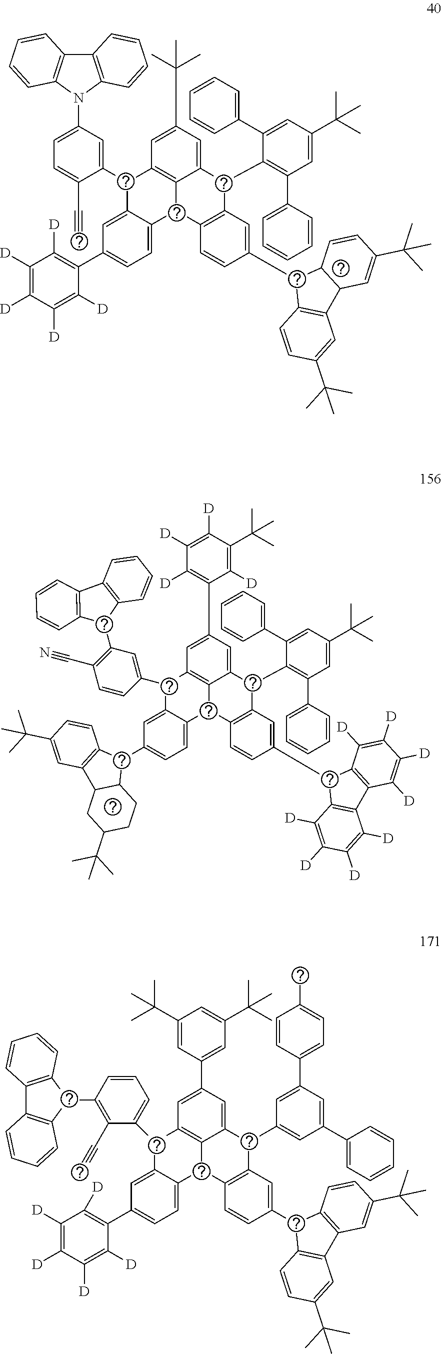

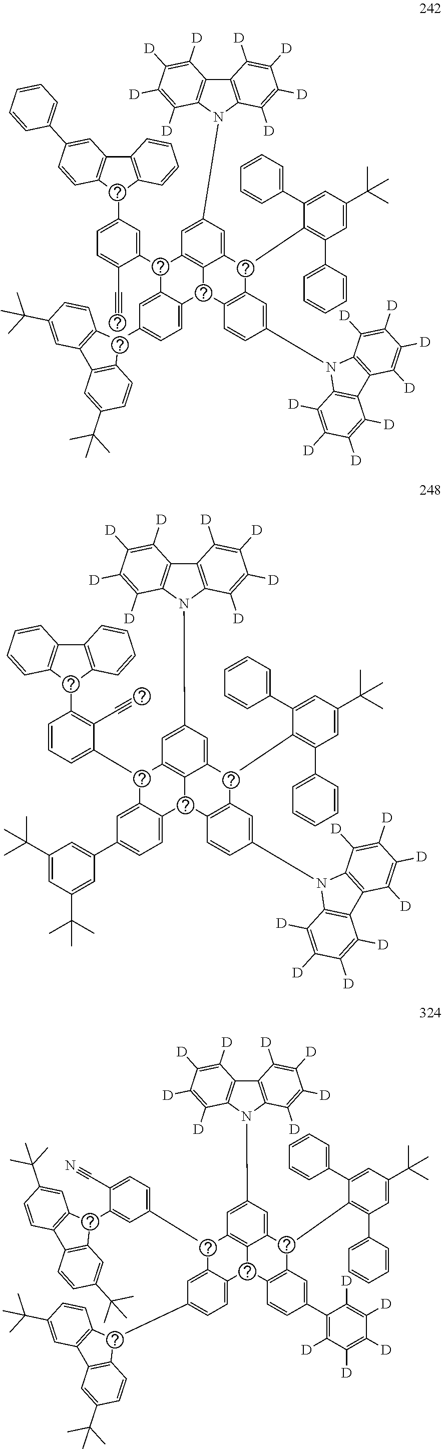

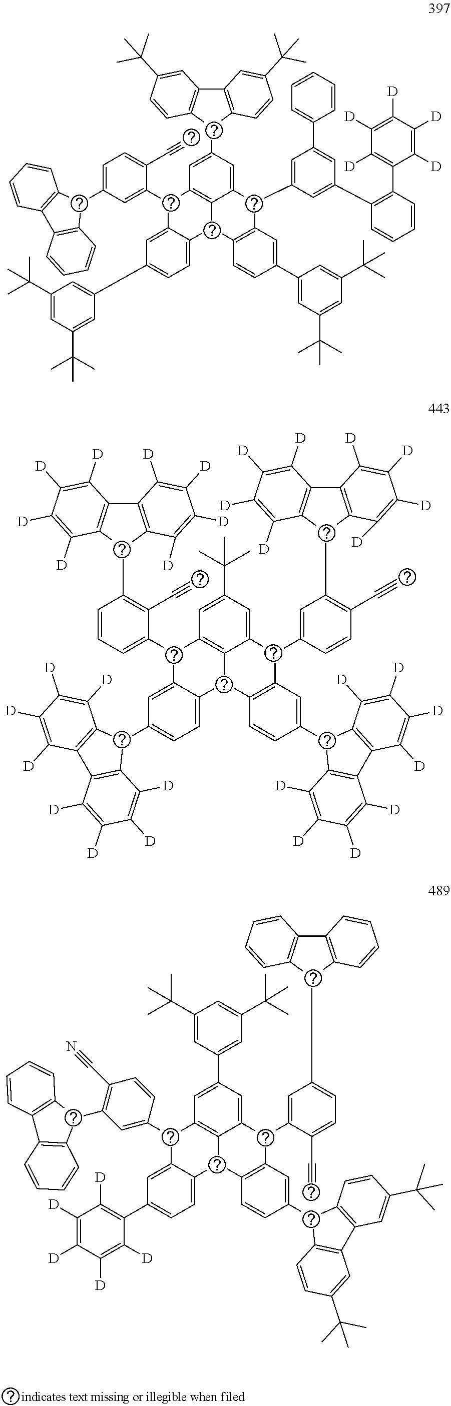

### Comparative Example Compounds

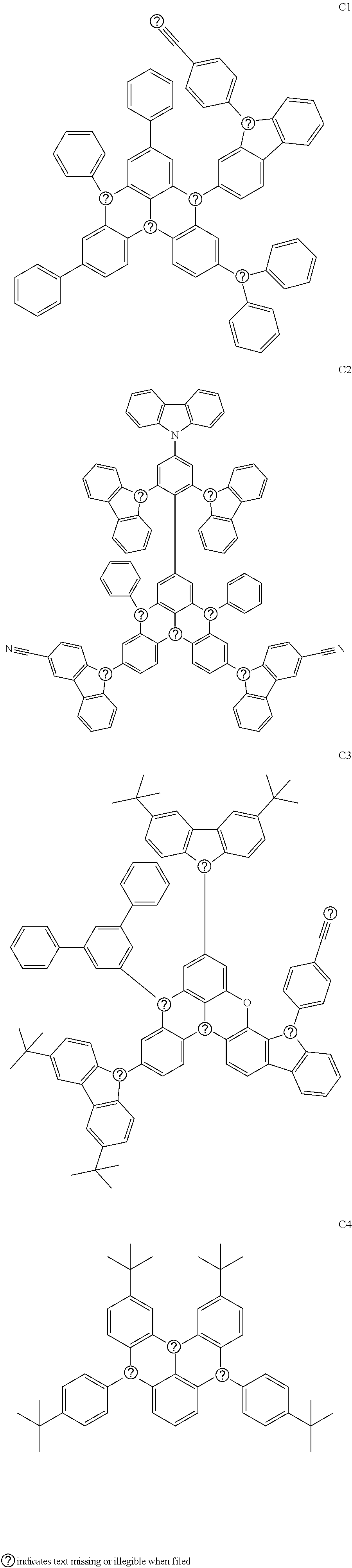

### Manufacture of Light Emitting Elements

In the light emitting elements of Examples and Comparative Examples, a glass substrate (made by Corning Co.), on which an ITO electrode of about 15 ohm per square centimeter (Ω/cm²) (about 1200 angstrom (A)) had been formed as an anode, was cut to a size of about 50 millimeter (mm)×50 mm×0.7 mm, cleansed by ultrasonic waves utilizing isopropyl alcohol and pure water for about five minutes each, and then irradiated with ultraviolet rays for about 30 minutes and exposed to ozone and cleansed. The glass substrate was installed on a vacuum deposition apparatus.

NPD was deposited on the upper portion of the anode to form a 300 Å-thick hole injection layer, H-1-1 was then deposited on the upper portion of the hole injection layer to form a 200 Å-thick hole transport layer, and CzSi was then deposited on the upper portion of the hole transport layer to form a 100 Å-thick emission-auxiliary layer.

Then, a host mixture in which the second compound and the third compound according to one or more embodiments were mixed in a weight ratio of about 6:4, the fourth compound, and Example Compound or Comparative Example Compound were co-deposited in a weight ratio of about 85:14:1 to form a 200 Å-thick emission layer, and on the upper portion of the emission layer, TSPO1 was deposited to form a 200 Å-thick hole blocking layer. Then, on the upper portion of the hole blocking layer, TPBi was deposited to form a 300 Å-thick electron transport layer, and then on the upper portion of the electron transport layer, LiF was deposited to form a 10 Å-thick electron injection layer. Next, on the electron injection layer, Al was deposited to form a 3,000 Å-thick cathode, thereby manufacturing a light emitting element. Each layer was formed by a vacuum deposition method. HT2 among the compounds in Compound Group 2 as described herein was utilized as the second compound, and ETH66 among the compounds in Compound Group 3 as described herein was utilized as the third compound, and AD-37 among the compounds in Compound Group 4 as described herein was utilized as the fourth compound.

Compounds utilized for manufacturing the light emitting elements of Examples and Comparative Examples are disclosed herein. The materials as shown were utilized to manufacture the elements by subjecting commercial products to sublimation purification.

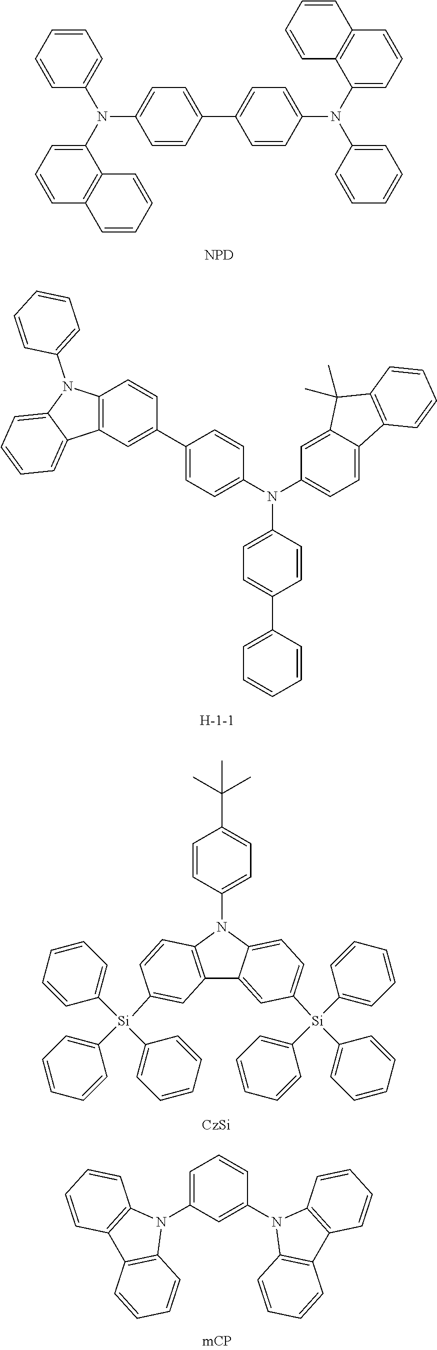 [SMILES: c1ccc(N(c2ccc(-c3ccc(N(c4ccccc4)c4cccc5ccccc45)cc3)cc2)c2cccc3ccccc23)cc1 ; "NPD" ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; c1cc(-n2c3ccccc3c3ccccc32)cc(-n2c3ccccc3c3ccccc32)c1]

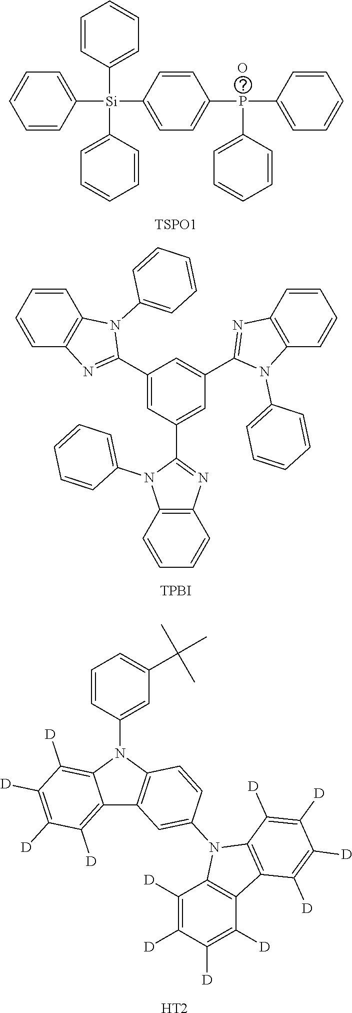

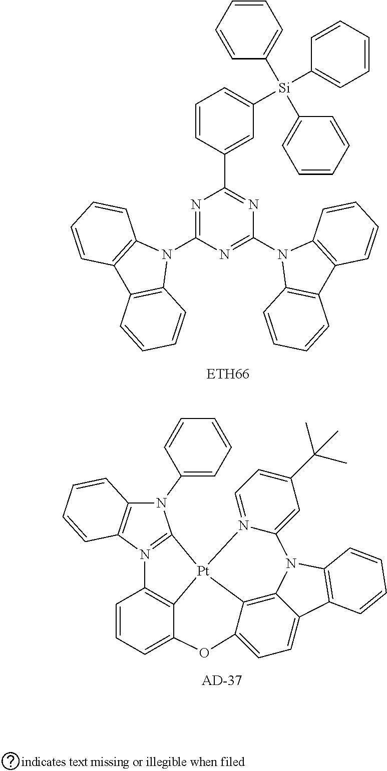

### Evaluation of Light Emitting Element Characteristics

The element efficiency and element service life of each of the light emitting elements manufactured with Example Compounds 40, 156, 171, 242, 248, 324, 397, 443, and 489 and Comparative Example Compounds C1 to C4 as described herein were evaluated. Evaluation results of the light emitting elements of Examples 1 to 9 and Comparative Examples 1 to 4 are listed in Table 3. To evaluate the characteristics of the light emitting elements manufactured in Examples 1 to 9 and Comparative Examples 1 to 4, each of driving voltage (V), top luminous efficiency (candela per ampere (Cd/A/y)), and emission color at a current density of 10 milliampere per square centimeter (mA/cm²) was measured by utilizing a Keithley MU 236 and a luminance meter PR650, and the time taken to reach 95% brightness relative to an initial brightness was measured as a service life (T95), and a relative service life was calculated on the basis of the element of Comparative Example 4, and the results are listed in Table 1.

TABLE 1

| | | | | | Top | | |
|---|---|---|---|---|---|---|---|
| | Host (second | | | Driving | luminous | | Relative |
| | compound:third | Fourth | First | voltage | efficiency | Emission | service life |
| | compound = 6:4) | compound | compound | (V) | (cd/A/y) | color | (T95) |
| Example 1 | HT2/ETH66 | AD-37 | Compound | 4.4 | 25.2 | Blue | 470 |
| | | | 40 | | | | |
| Example 2 | HT2/ETH66 | AD-37 | Compound | 4.3 | 26.4 | Blue | 455 |
| | | | 156 | | | | |
| Example 3 | HT2/ETH66 | AD-37 | Compound | 4.4 | 24.9 | Blue | 390 |
| | | | 171 | | | | |
| Example 4 | HT2/ETH66 | AD-37 | Compound | 4.2 | 25.5 | Blue | 430 |
| | | | 242 | | | | |
| Example 5 | HT2/ETH66 | AD-37 | Compound | 4.3 | 25.7 | Blue | 440 |
| | | | 248 | | | | |
| Example 6 | HT2/ETH66 | AD-37 | Compound | 4.4 | 24.6 | Blue | 465 |
| | | | 324 | | | | |
| Example 7 | HT2/ETH66 | AD-37 | Compound | 4.4 | 25.4 | Blue | 425 |
| | | | 397 | | | | |
| Example 8 | HT2/ETH66 | AD-37 | Compound | 4.2 | 26.7 | Blue | 445 |
| | | | 443 | | | | |
| Example 9 | HT2/ETH66 | AD-37 | Compound | 4.3 | 24.5 | Blue | 420 |
| | | | 489 | | | | |
| Comparative | HT2/ETH66 | AD-37 | Comparative | 5.0 | 19.5 | Blue | 245 |
| Example 1 | | | Example | | | | |
| | | | Compound | | | | |
| | | | C1 | | | | |
| Comparative | HT2/ETH66 | AD-37 | Comparative | 4.6 | 23.2 | Blue | 360 |
| Example 2 | | | Example | | | | |
| | | | Compound | | | | |
| | | | C2 | | | | |
| Comparative | HT2/ETH66 | AD-37 | Comparative | 4.9 | 21.4 | Blue | 295 |
| Example 3 | | | Example | | | | |
| | | | Compound | | | | |
| | | | C3 | | | | |
| Comparative | HT2/ETH66 | AD-37 | Comparative | 5.2 | 17.7 | Blue | (ref) |
| Example 4 | | | Example | | | | 100 |
| | | | Compound | | | | |
| | | | C4 | | | | |

Referring to the results of Table 1, it may be confirmed that the light emitting elements of Examples in which the fused polycyclic compounds according to examples of the present disclosure were utilized as a luminescent material had relatively high luminous efficiency and low driving voltage, and improved service life characteristics as compared to the light emitting elements of Comparative Examples. Example Compounds include the fused ring core in which a plurality of fused polycyclic compounds are fused via the boron atom, the first nitrogen atom, and the second nitrogen atom, and have a structure in which the first substituent and the second substituent are substituted via the first linker linked to the first nitrogen atom of the fused ring core, and thus may achieve high luminous efficiency and a long service life. Example Compounds include the fused ring core in which the first to third aromatic rings are fused about the boron atom, the first nitrogen atom, and the second nitrogen atom, and the first substituent and the second substituent are linked to the first nitrogen atom via the first linker. The first linker includes a benzene moiety linked to the first nitrogen atom. The first substituent and the second substituent are linked to the first linker, the first substituent includes a carbazole moiety, and the second substituent includes a nitrile moiety. By utilizing Example Compounds including the first substituent and second substituent as a dopant for the thermally activated delayed fluorescence (TADF) light emitting element, it is possible to achieve high element efficiency of increasing luminous efficiency and long service life in a short wavelength region, particularly, a blue light wavelength region.

It may be confirmed that Comparative Example Compound C1, Comparative Example Compound C2, and Comparative Example Compound C4 include a planar skeleton structure centered on one boron atom and two nitrogen atoms, but do not include the first substituent and the second substituent proposed by the present disclosure, and thus Comparative Example 1, Comparative Example 2, and Comparative Example 4 including Comparative Example Compound C1, Comparative Example Compound C2, and Comparative Example Compound C4, respectively may have relatively high driving voltage values and the deterioration in the luminous efficiency and element service life as compared with Examples. Each of Comparative Example Compound C1 and Comparative Example Compound C2 includes a carbazole moiety and a nitrile moiety. However, the described moieties are not linked to the first nitrogen atom of the fused ring core via the first linker proposed by the present disclosure. Accordingly, it is considered that the light emitting elements of Comparative Example 1 and Comparative Example 2 have the deterioration in the luminous efficiency and element service life. Because Comparative Example Compound C4 does not include a substituent such as a carbazole moiety proposed by the present disclosure, it is considered that the light emitting element of Comparative Example 4 has the deterioration in the luminous efficiency and element service life.

It may be confirmed that Comparative Example Compound C3 includes a planar skeleton structure centered on one boron atom and the N atom and O atom, but does not include the first substituent and the second substituent proposed by the present disclosure, and thus Comparative Example 3 including Comparative Example Compound C3 has a relatively high driving voltage value and the deterioration in the luminous efficiency and element service life as compared with Examples. Comparative Compound C3 includes a carbazole moiety and a nitrile moiety, but the described moieties are not linked to the nitrogen atom of the fused ring core via the first linker proposed by the present disclosure. Accordingly, it is considered that the light emitting element of Comparative Example 3 has the deterioration in the luminous efficiency and element service life.

The light emitting element of one or more embodiments may exhibit improved element characteristics with high efficiency and a long service life.

The fused polycyclic compound of one or more embodiments may be included in the emission layer of the light emitting element to contribute to high efficiency and a long service life of the light emitting element.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims and equivalents thereof.

What is claimed is:

1. A light emitting element comprising:
a first electrode;
a second electrode on the first electrode; and
at least one functional layer which is between the first electrode and the second electrode and comprises a first compound represented by Formula 1 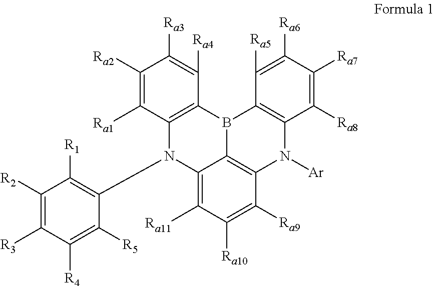
in Formula 1,
Rₐ₁ to Rₐ₁₁ and R₁ to R₅ being each independently a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one selected from among R₁ to R₅ being a cyano group and at least one remaining selected from among R₁ to R₅ being a substituent represented by Formula 2, and
Ar being a substituted or unsubstituted aryl group having 6 to 30 ring-forming carbon atoms, or a substituted or unsubstituted heteroaryl group having 2 to 30 ring-forming carbon atoms, 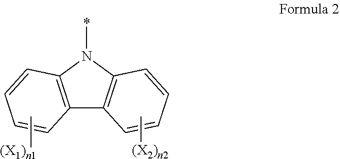
in Formula 2,
X₁ and X₂ being each independently a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1 and n2 being each independently an integer of 0 to 4, and 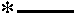 [SMILES: *C]
being a position linked to Formula 1.

2. The light emitting element of claim 1, wherein the at least one functional layer comprises an emission layer, a hole transport region between the first electrode and the emission layer, and an electron transport region between the emission layer and the second electrode, and
the emission layer comprises the first compound.

3. The light emitting element of claim 2, wherein the emission layer is configured to emit delayed fluorescence having a luminescence center wavelength of about 430 nanometer (nm) to about 490 nm.

4. The light emitting element of claim 1, wherein the first compound represented by Formula 1 is represented by Formula 1-1 or Formula 1-2: 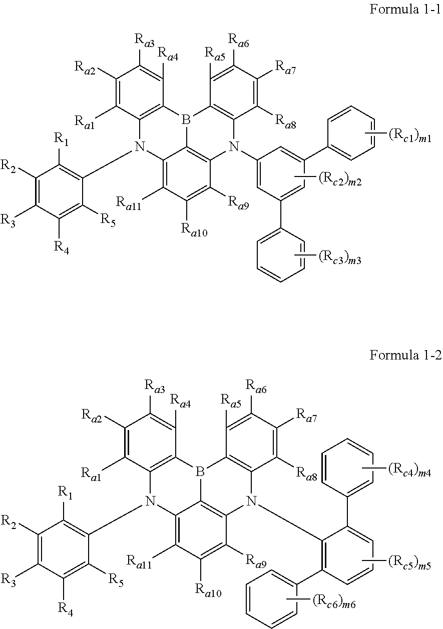
in Formula 1-1 and Formula 1-2,
R_{c1} to R_{c6} being each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m1, m3, m4, and m6 being each independently an integer of 0 to 4,
m2 and m5 being each independently an integer of 0 to 3, and
Rₐ₁ to Rₐ₁₁ and R₁ to R₅ being each as defined in Formula 1.

5. The light emitting element of claim 4, wherein R_{c1} to R_{c6} are each independently a hydrogen atom, a deuterium atom, a substituted or unsubstituted t-butyl group, or a substituted or unsubstituted phenyl group.

6. The light emitting element of claim 1, wherein the first compound represented by Formula 1 is represented by Formula 1-3: 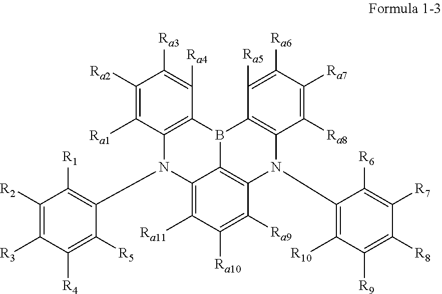
in Formula 1-3,
R₆ to R₁₀ being each independently a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one selected from among R₆ to R₁₀ being a cyano group and at least one remaining selected from among R₆ to R₁₀ being a substituent represented by Formula 2, and
Rₐ₁ to Rₐ₁₁ and R₁ to R₅ being each as defined in Formula 1.

7. The light emitting element of claim 1, wherein the first compound represented by Formula 1 is represented by any one selected from among Formula 1-4 to Formula 1-6: 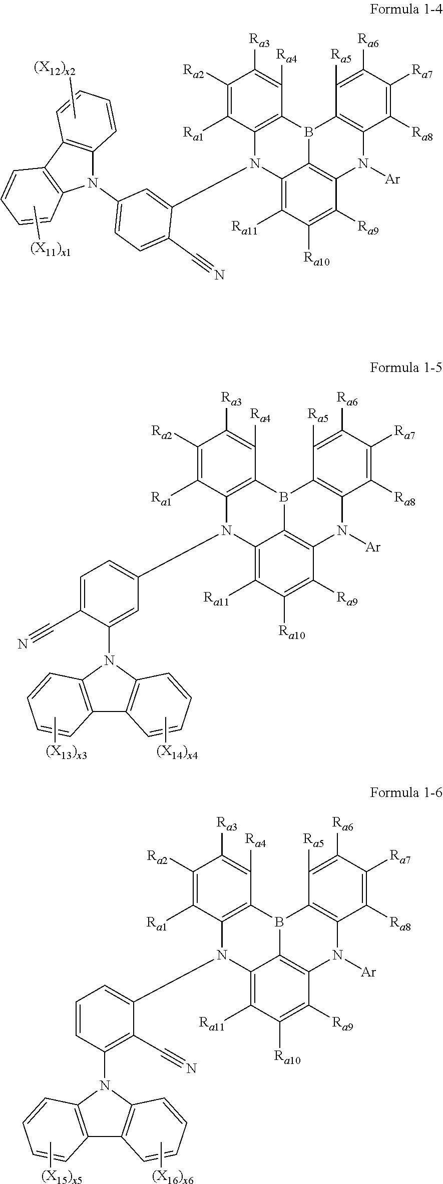
in Formula 1-4 to Formula 1-6,
X₁₁ to X₁₆ being each independently a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
x1 to x6 being each independently an integer of 0 to 4, and
Rₐ₁ to Rₐ₁₁ and Ar being each as defined in Formula 1.

8. The light emitting element of claim 7, wherein X₁₁ to X₁₆ are each independently a hydrogen atom, a deuterium atom, a cyano group, a substituted or unsubstituted t-butyl group, or a substituted or unsubstituted phenyl group.

9. The light emitting element of claim 1, wherein the first compound represented by Formula 1 is represented by any one selected from among Formula 1-7 to Formula 1-9: 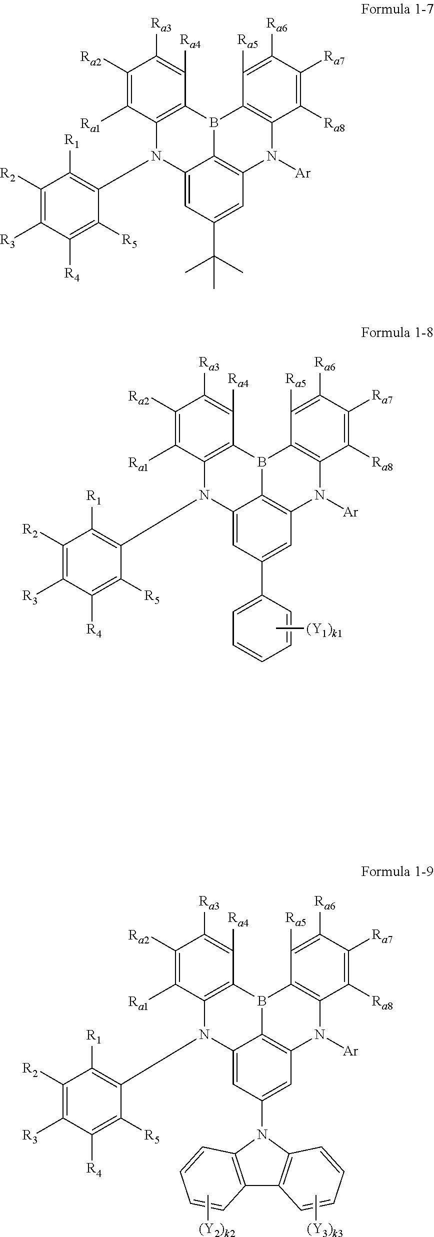
in Formula 1-7 to Formula 1-9,
Y₁ to Y₃ being each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
k1 being an integer of 0 to 5,
k2 and k3 being each independently an integer of 0 to 4, and
Rₐ₁ to Rₐ₈, R₁ to R₅, and Ar being each as defined in Formula 1.

10. The light emitting element of claim 1, wherein Rₐ₂, Rₐ₃, Rₐ₆, and Rₐ₇ are each independently a hydrogen atom, a deuterium atom, or a substituent represented by any one selected from among Formula 3-1 to Formula 3-7: 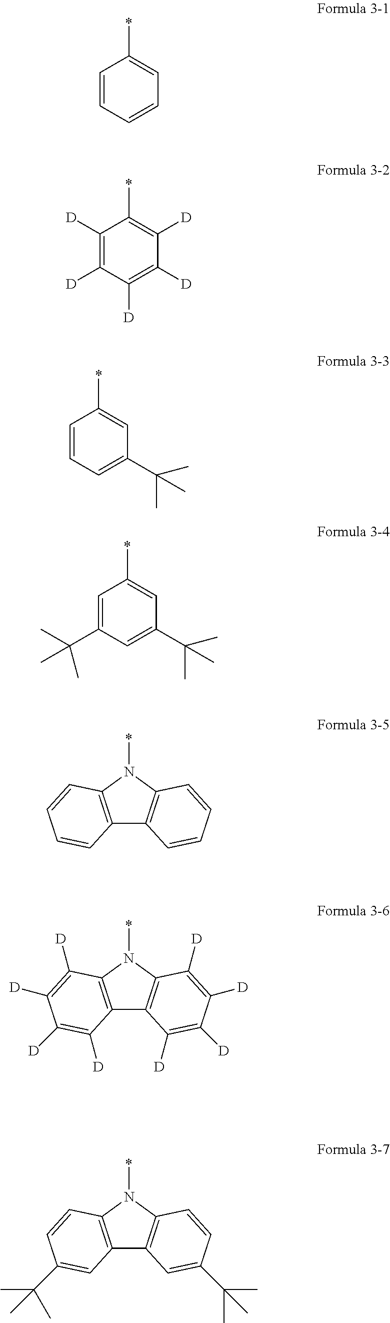
in Formula 3-1 to Formula 3-7, 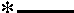 [SMILES: *C]
being a position linked to Formula 1.

11. The light emitting element of claim 1, wherein the functional layer comprises at least one selected from among compounds in Compound Group 1: 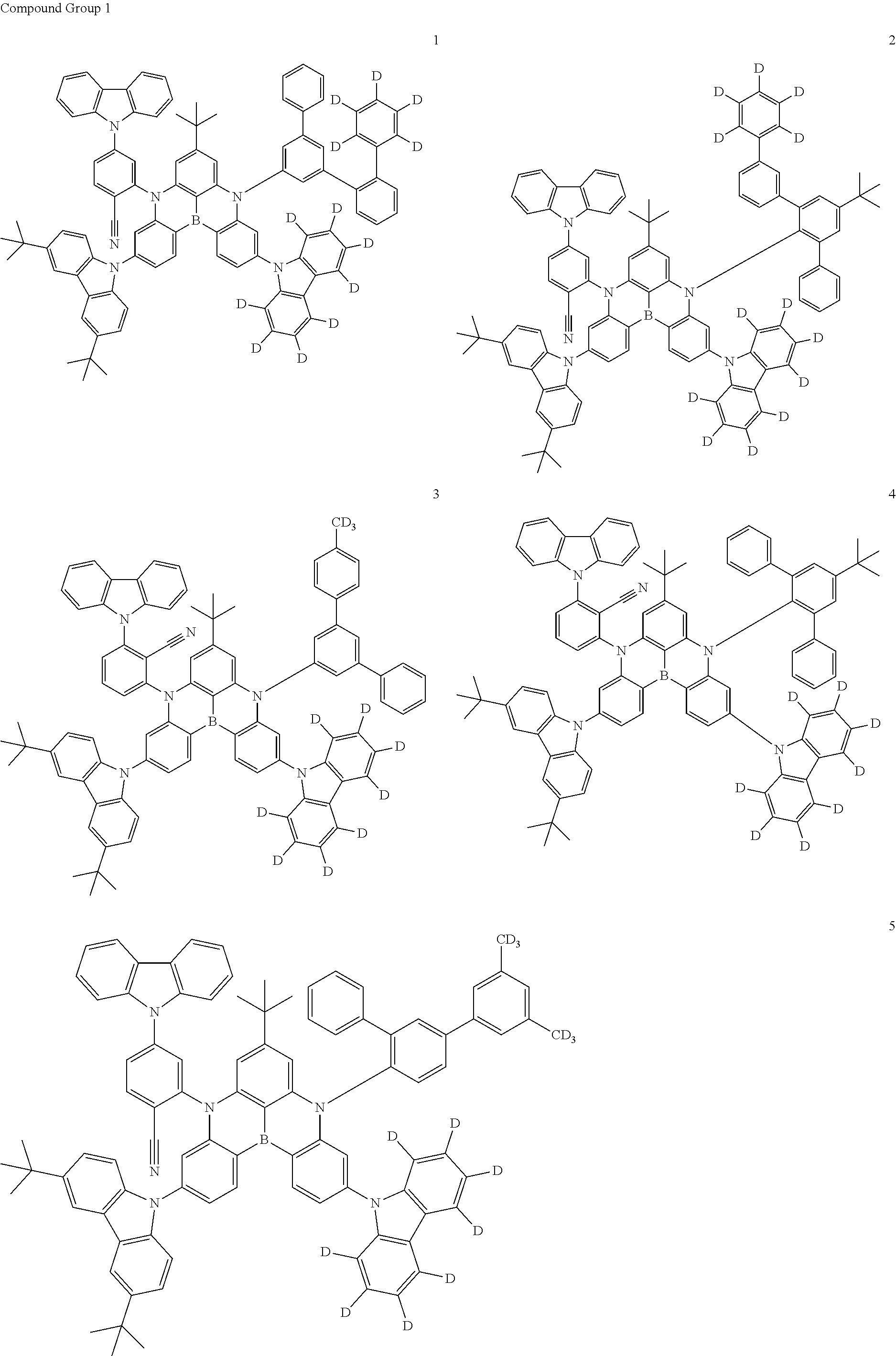 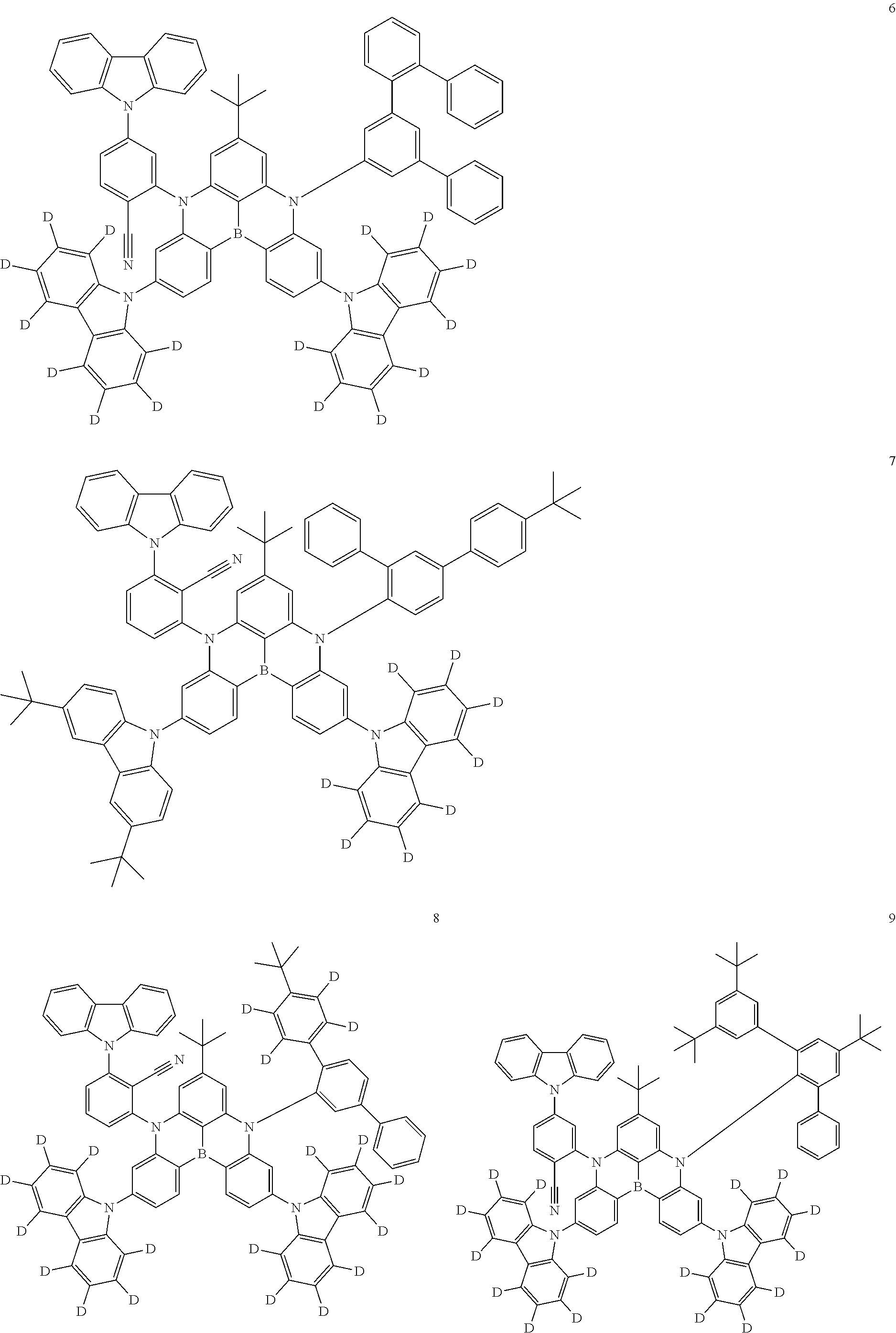 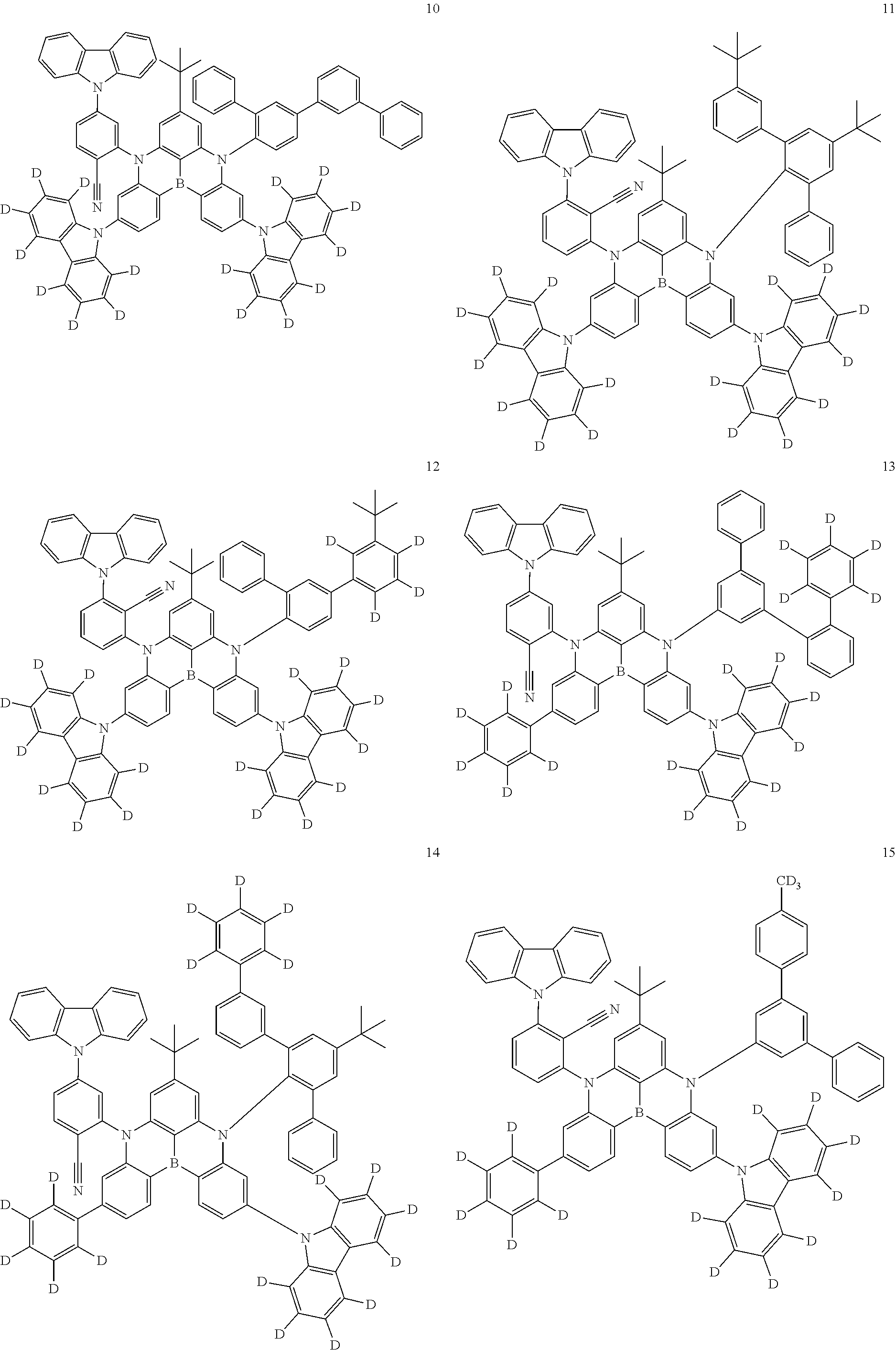 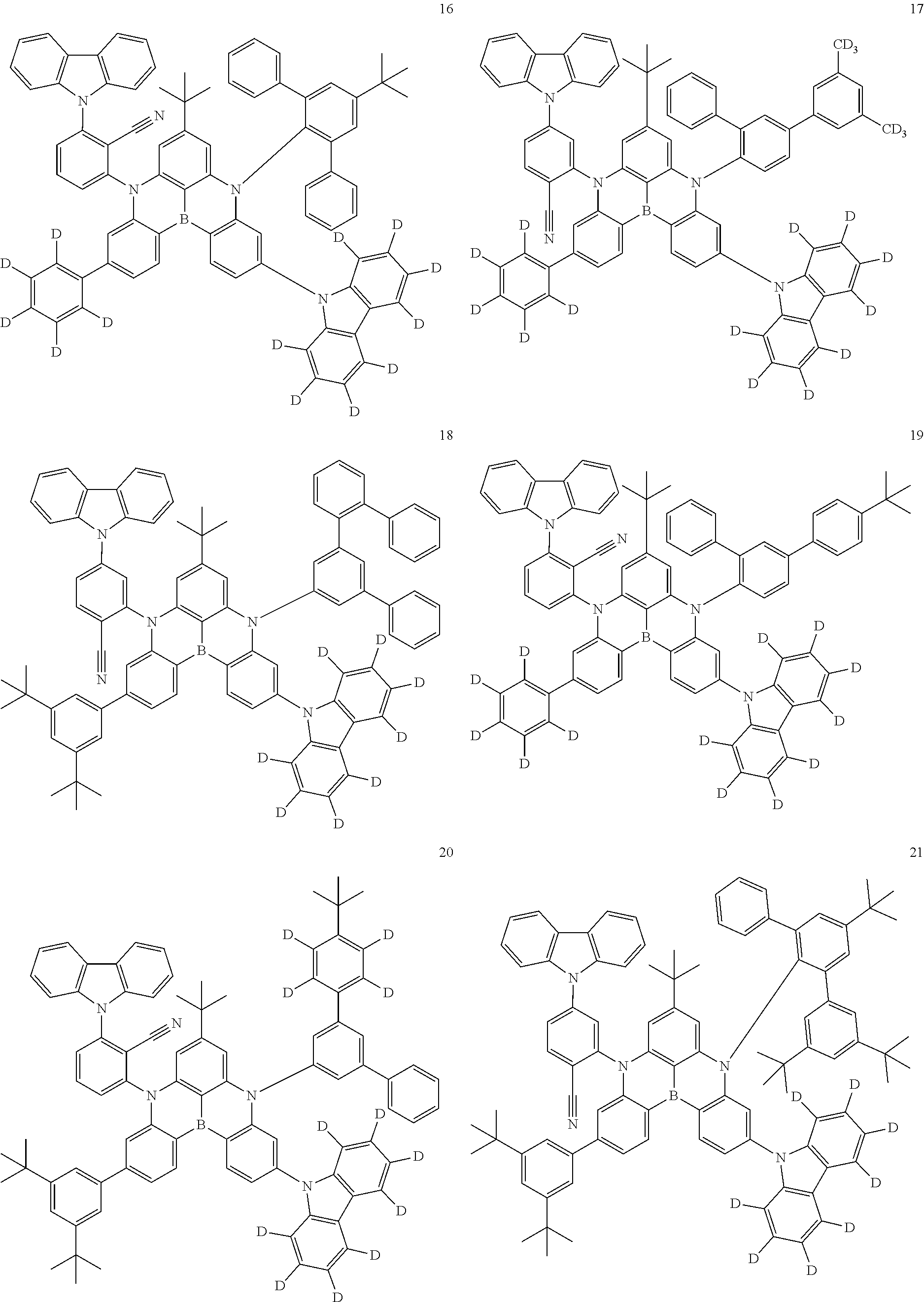 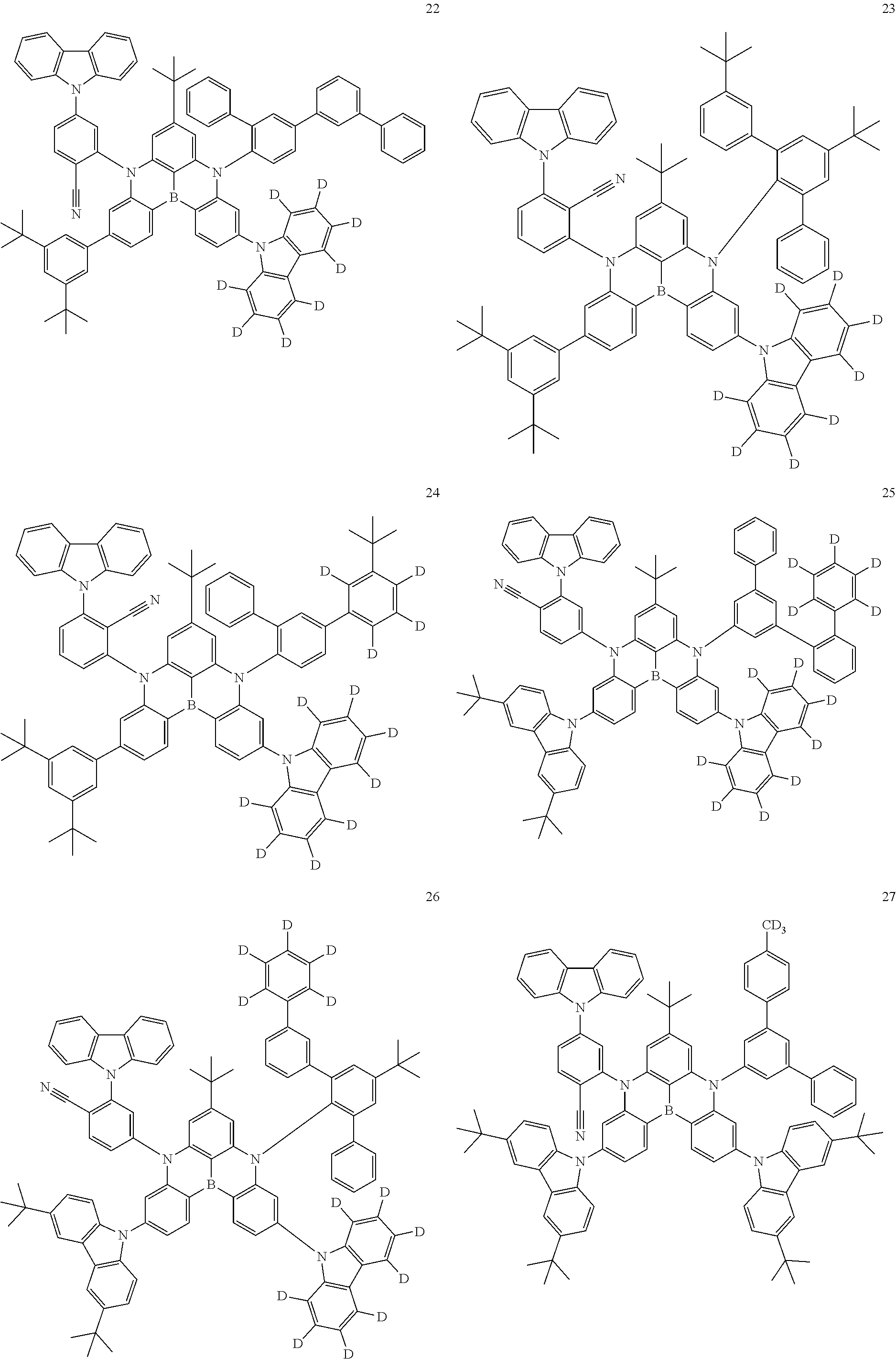 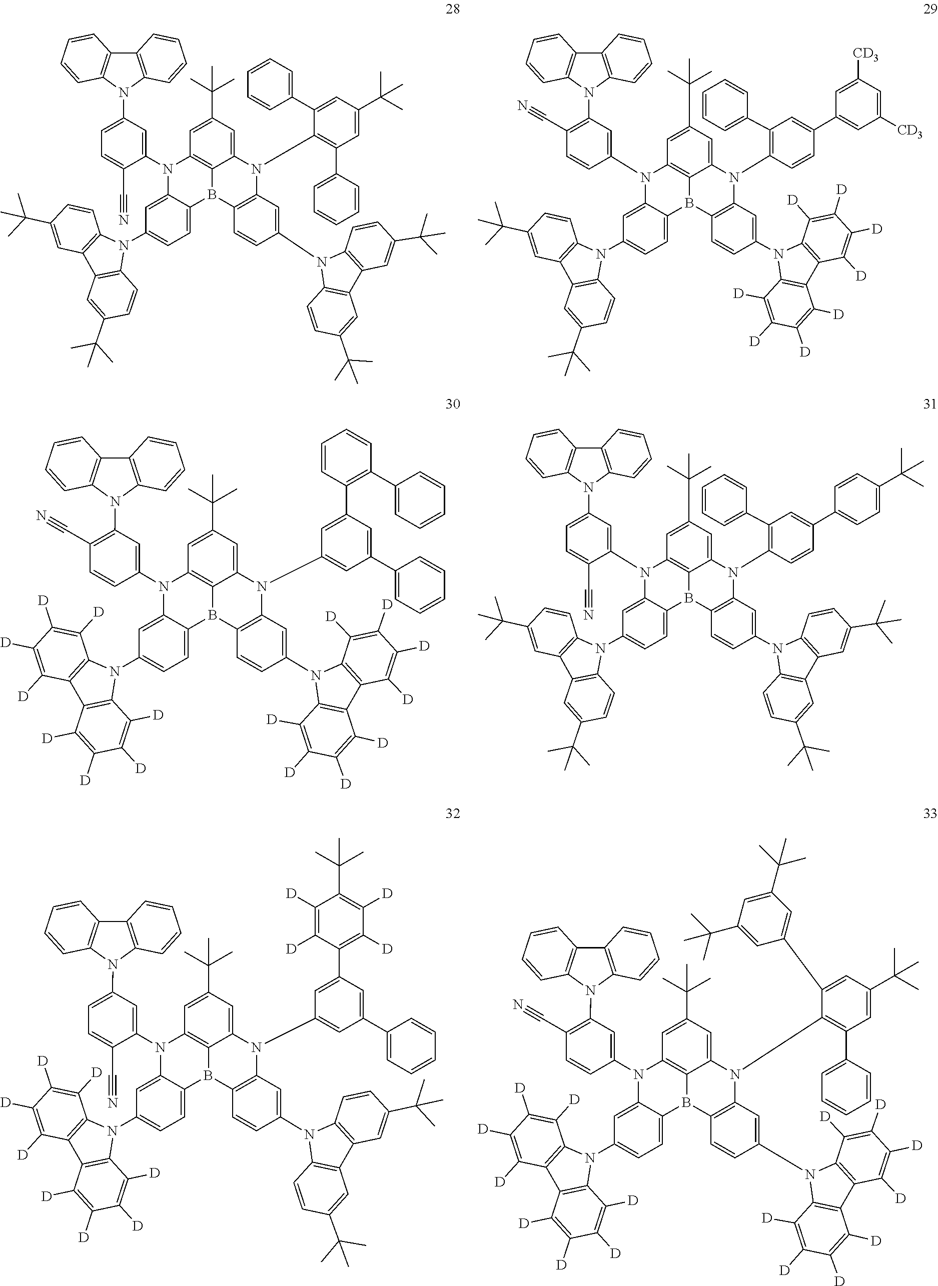 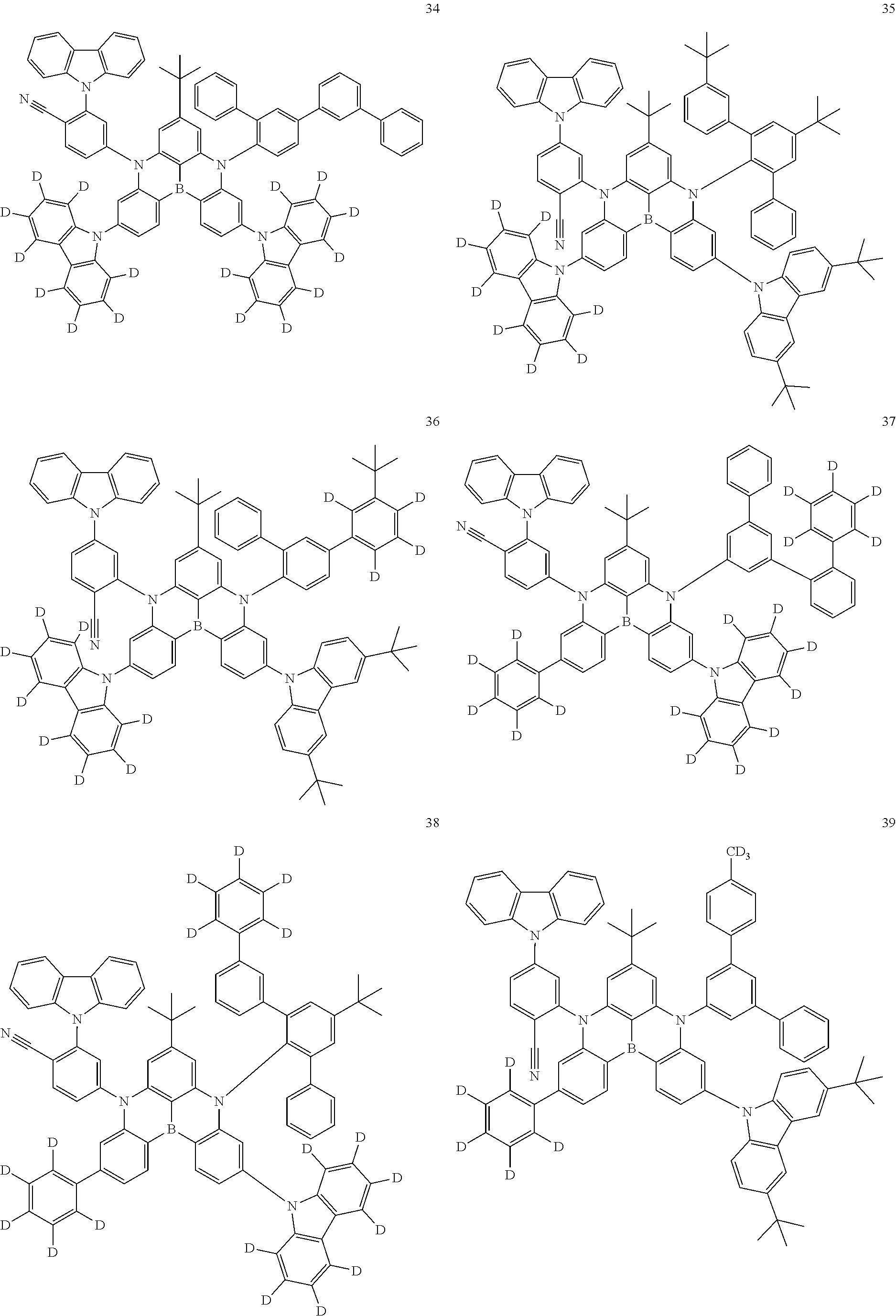 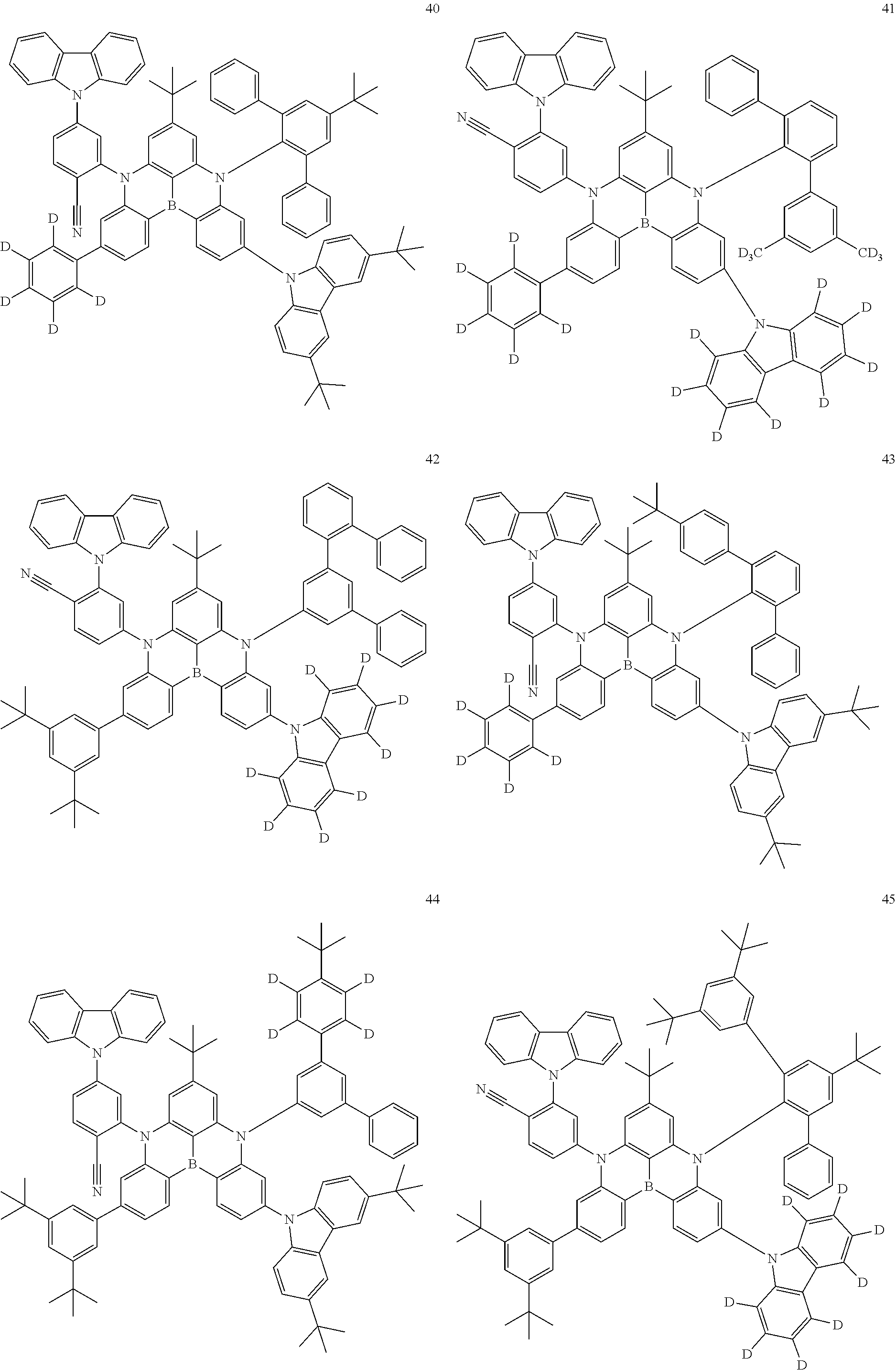 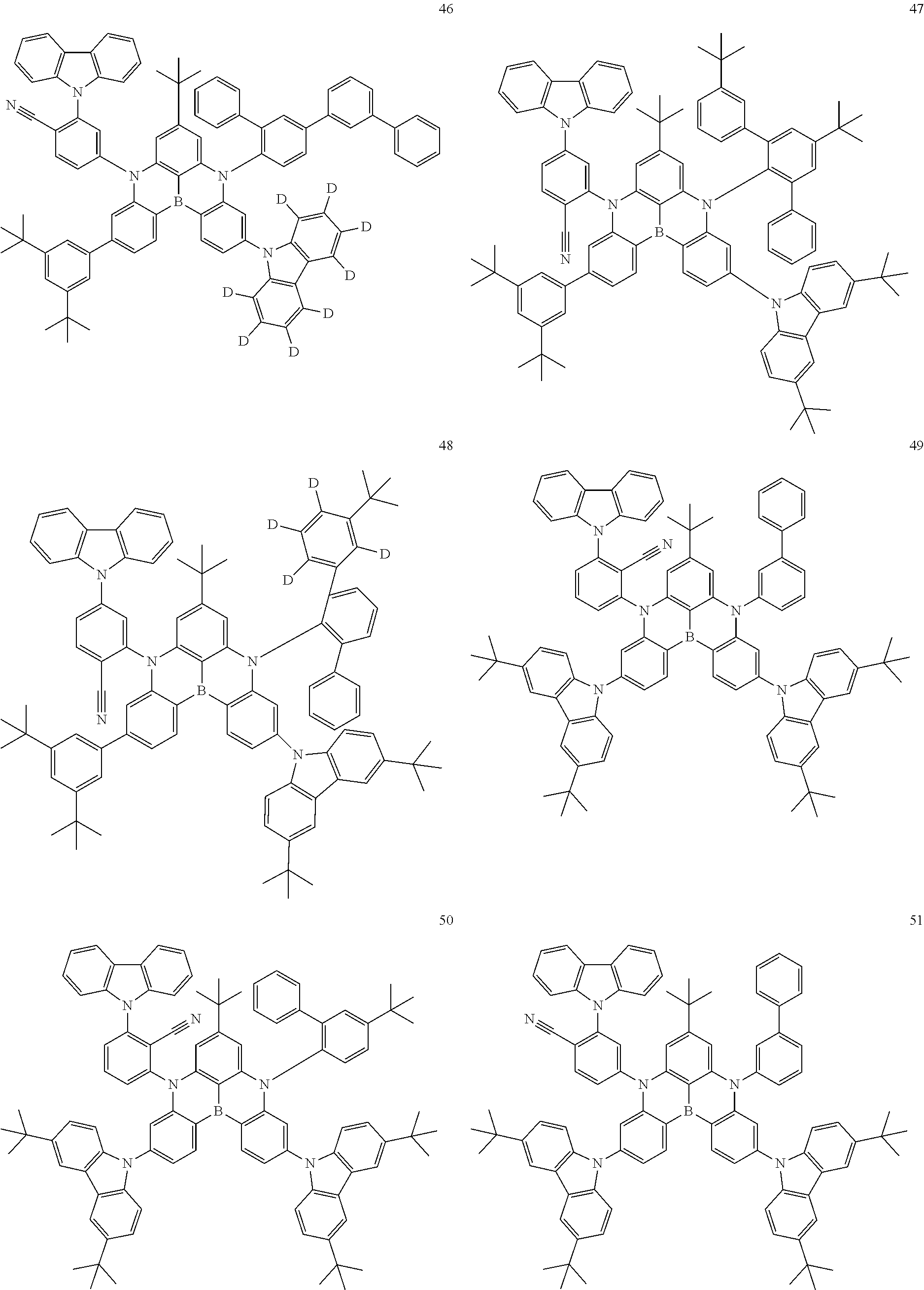 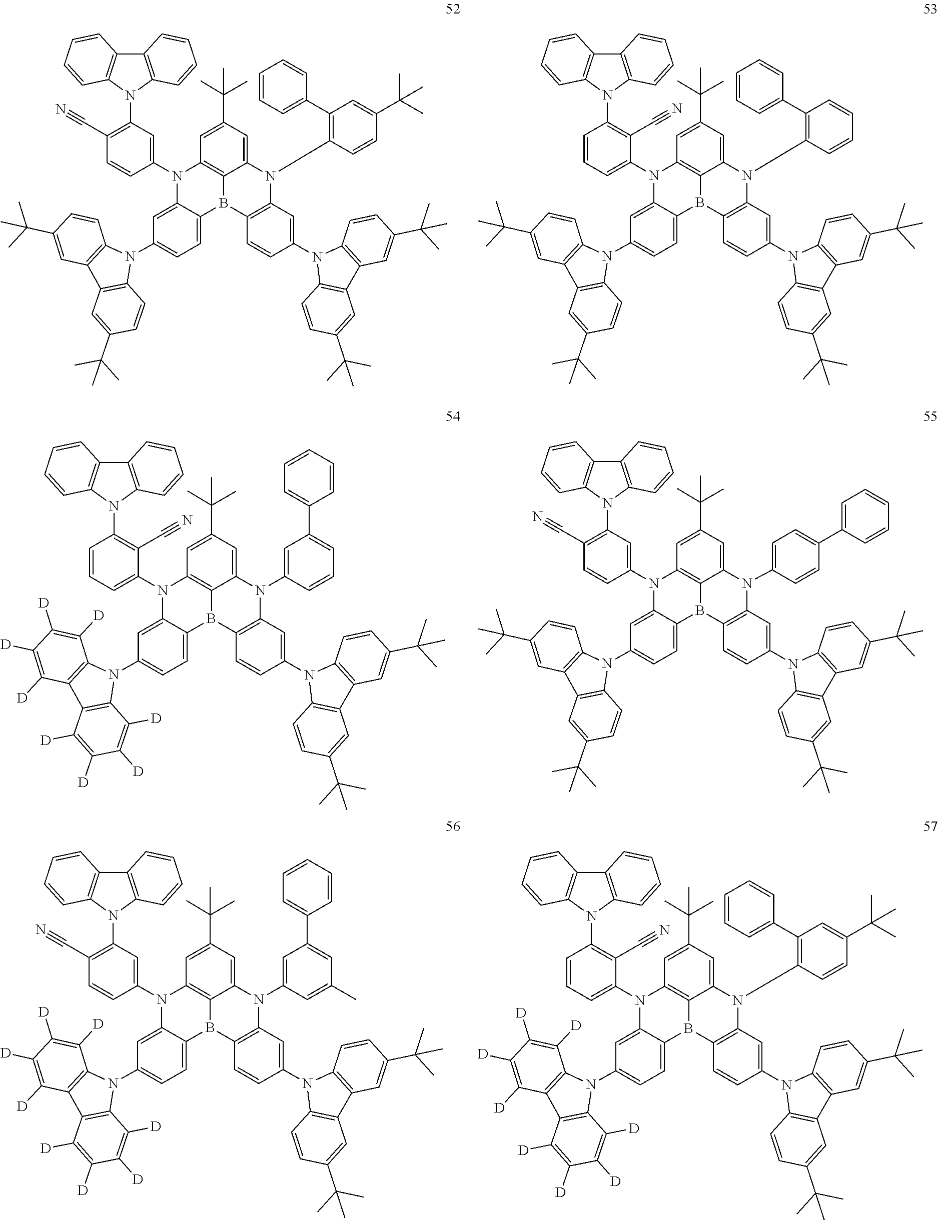 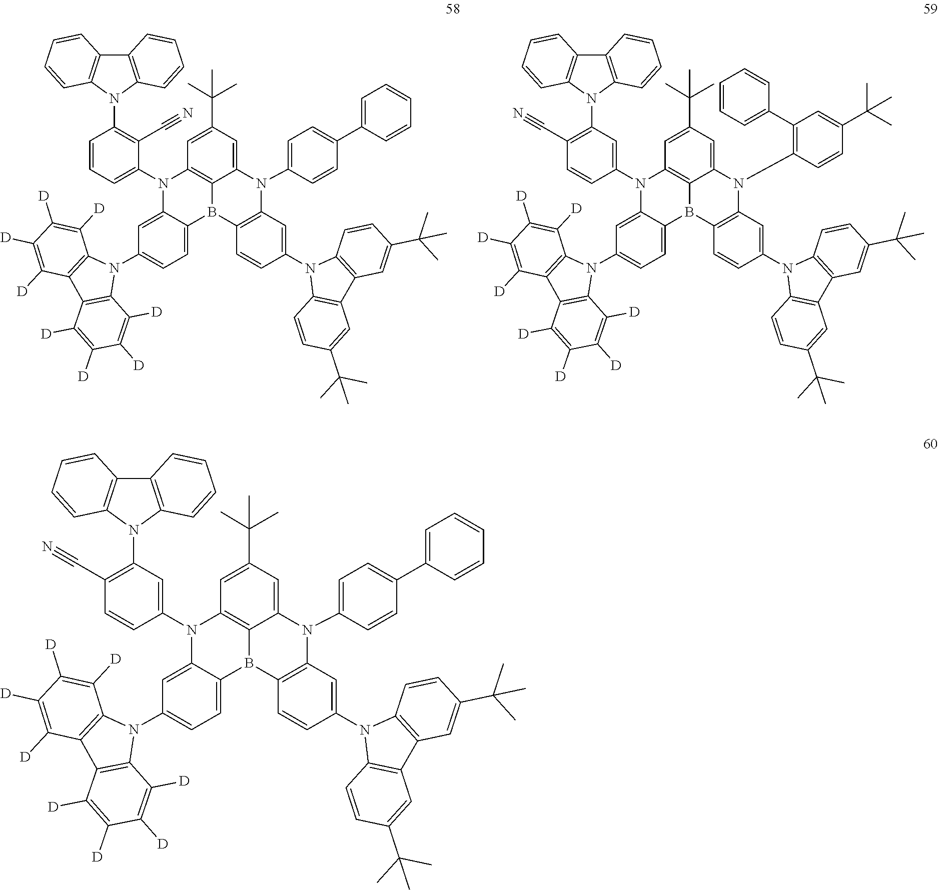 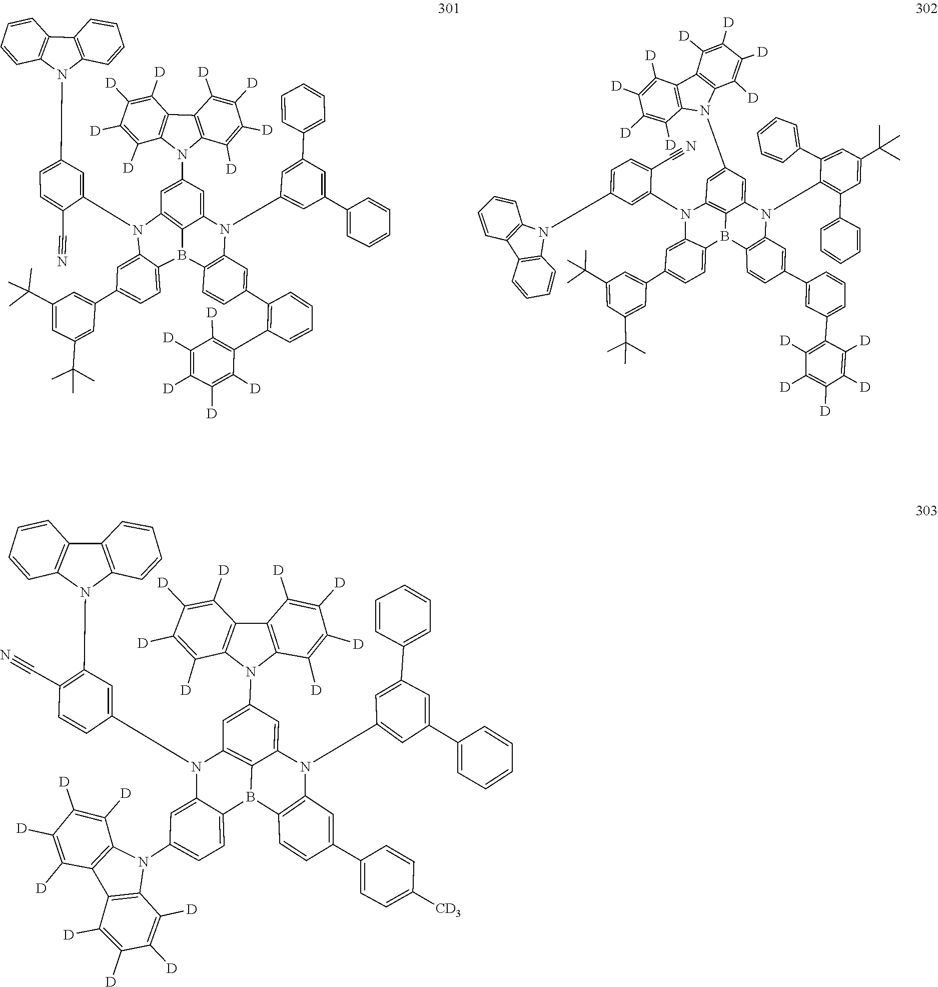 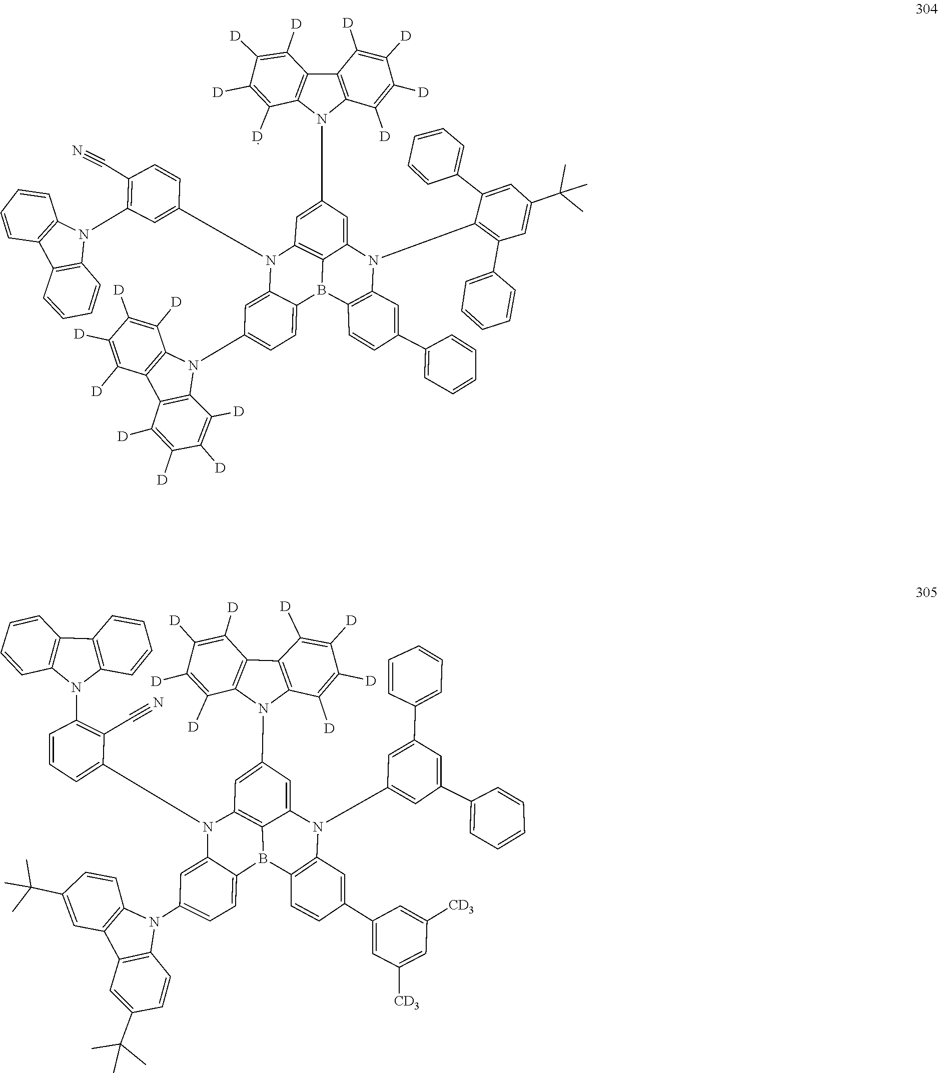 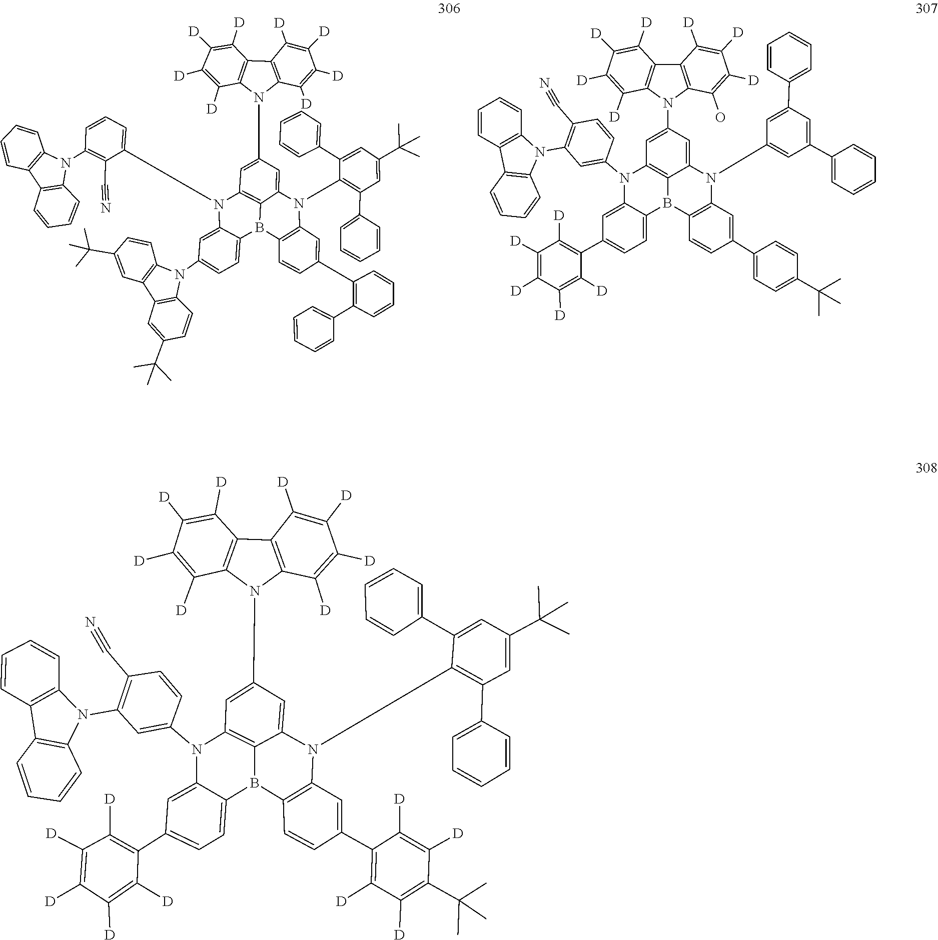 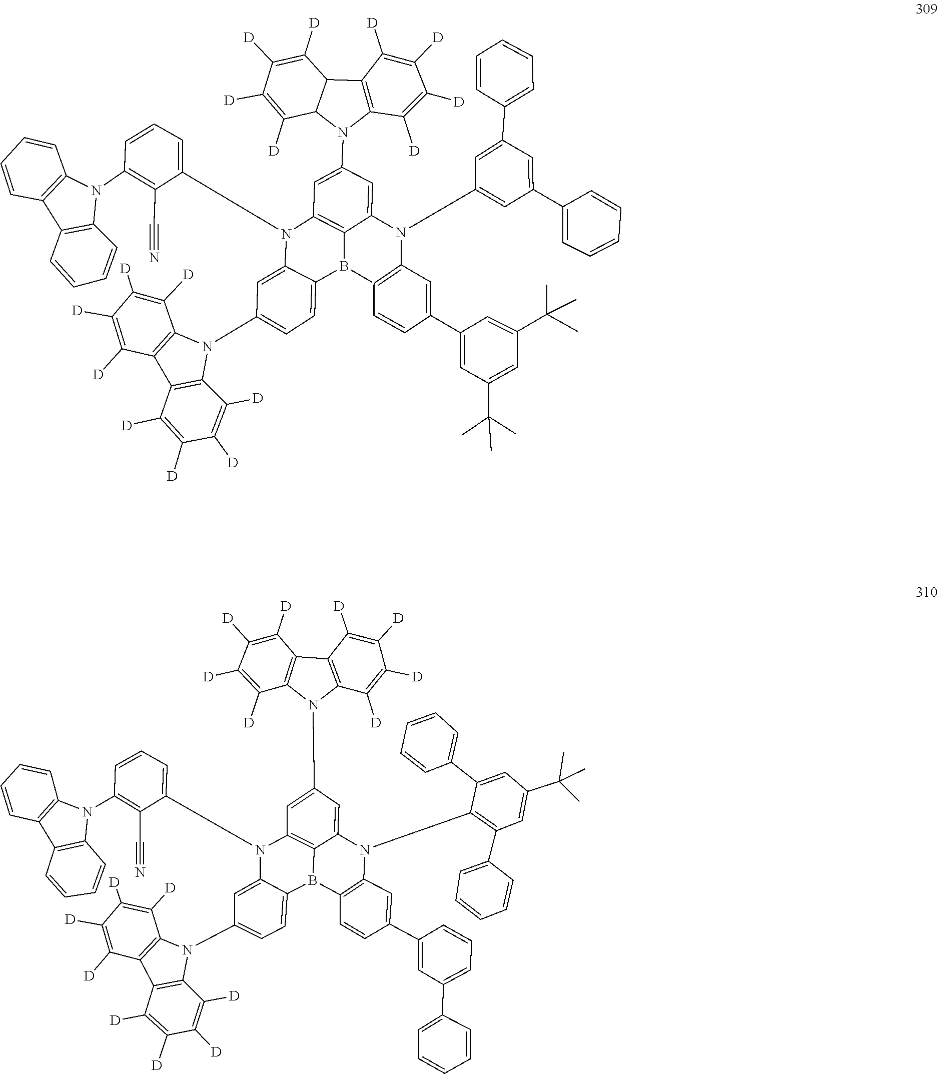 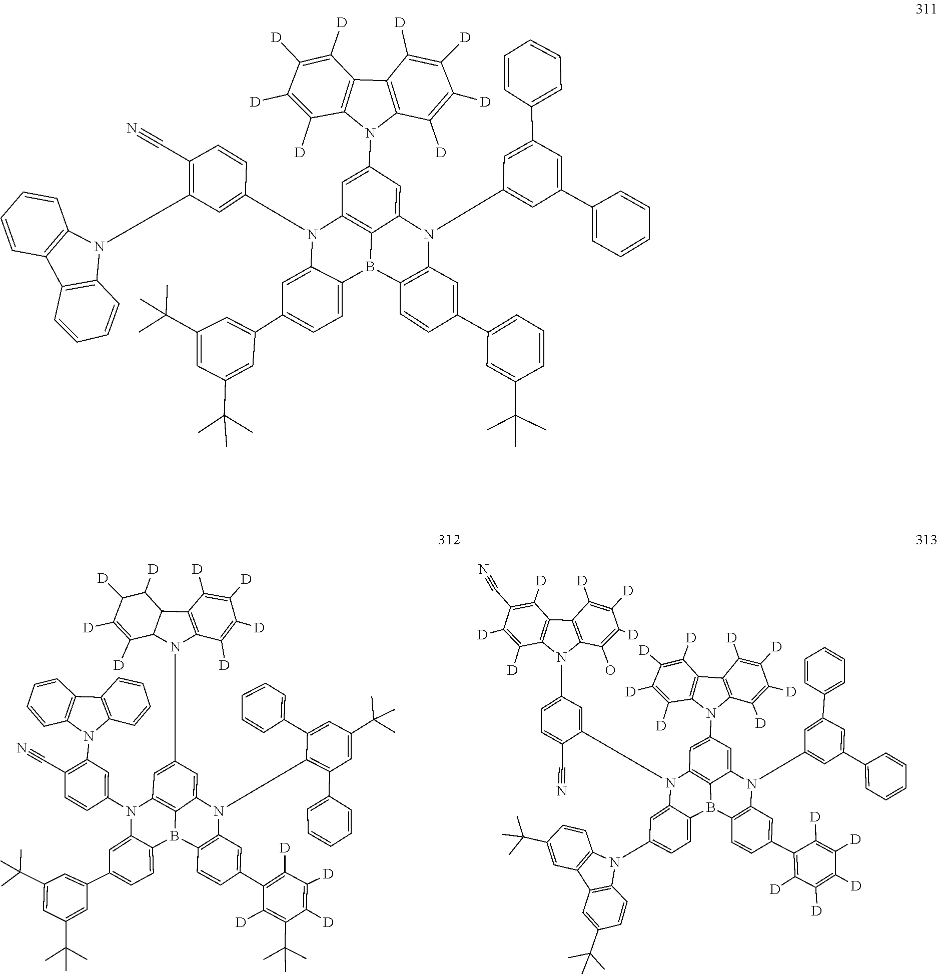 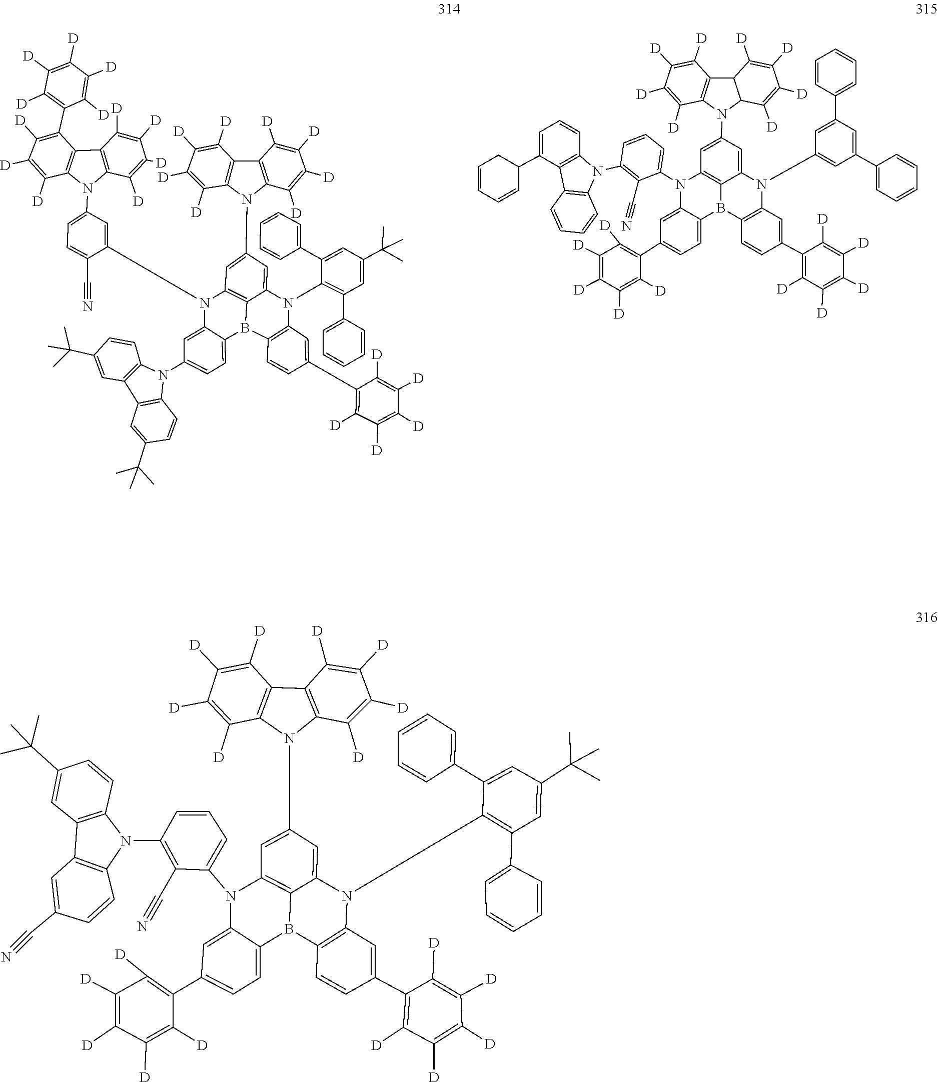 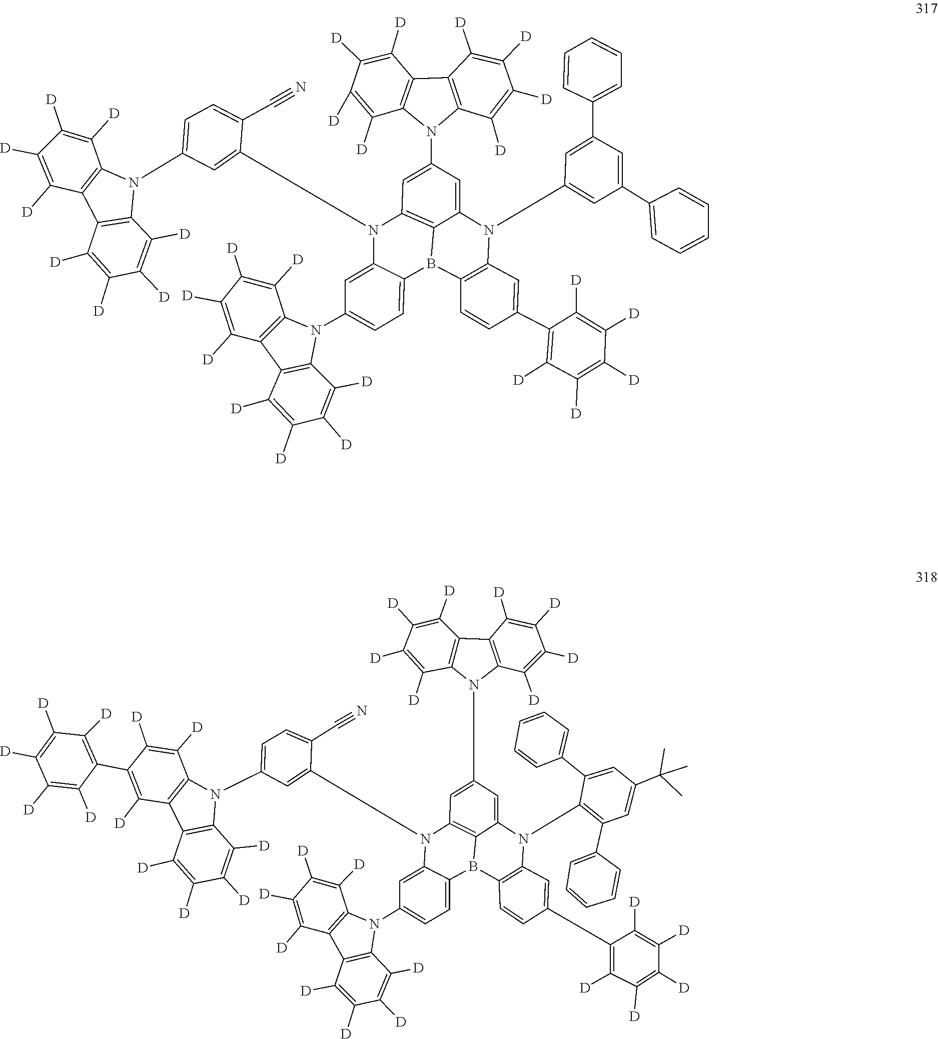 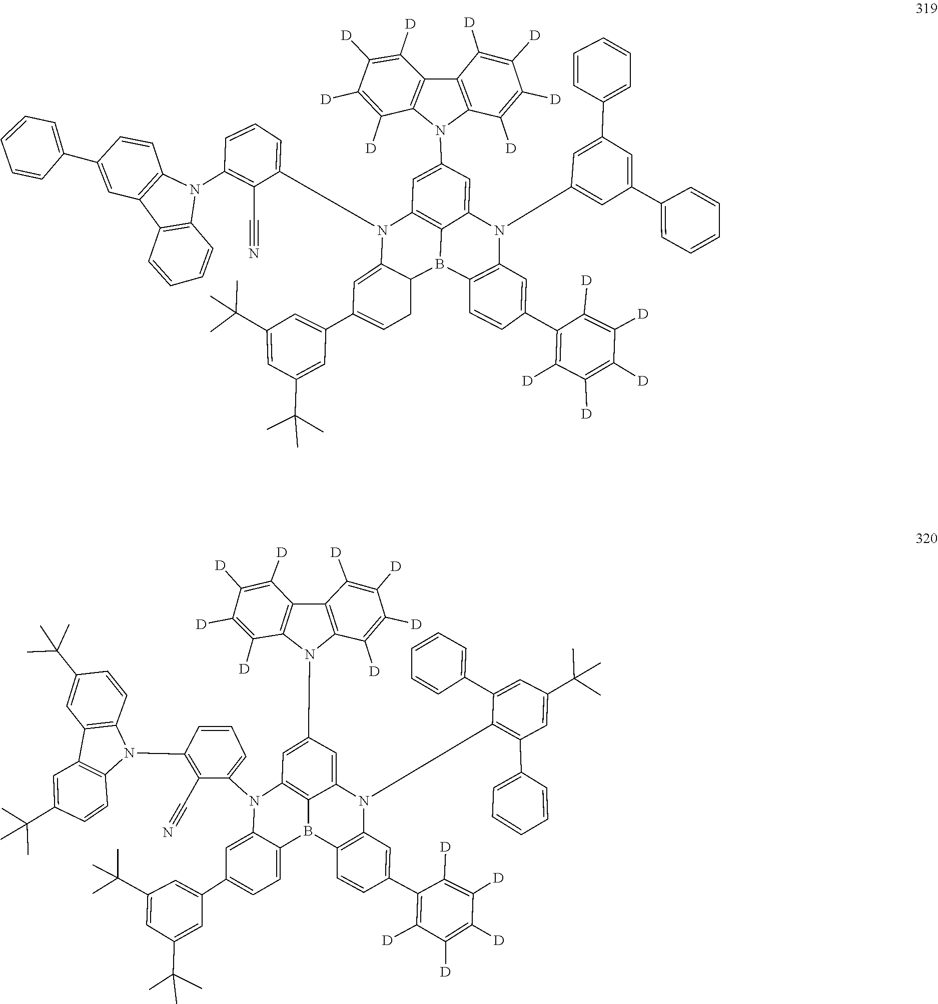 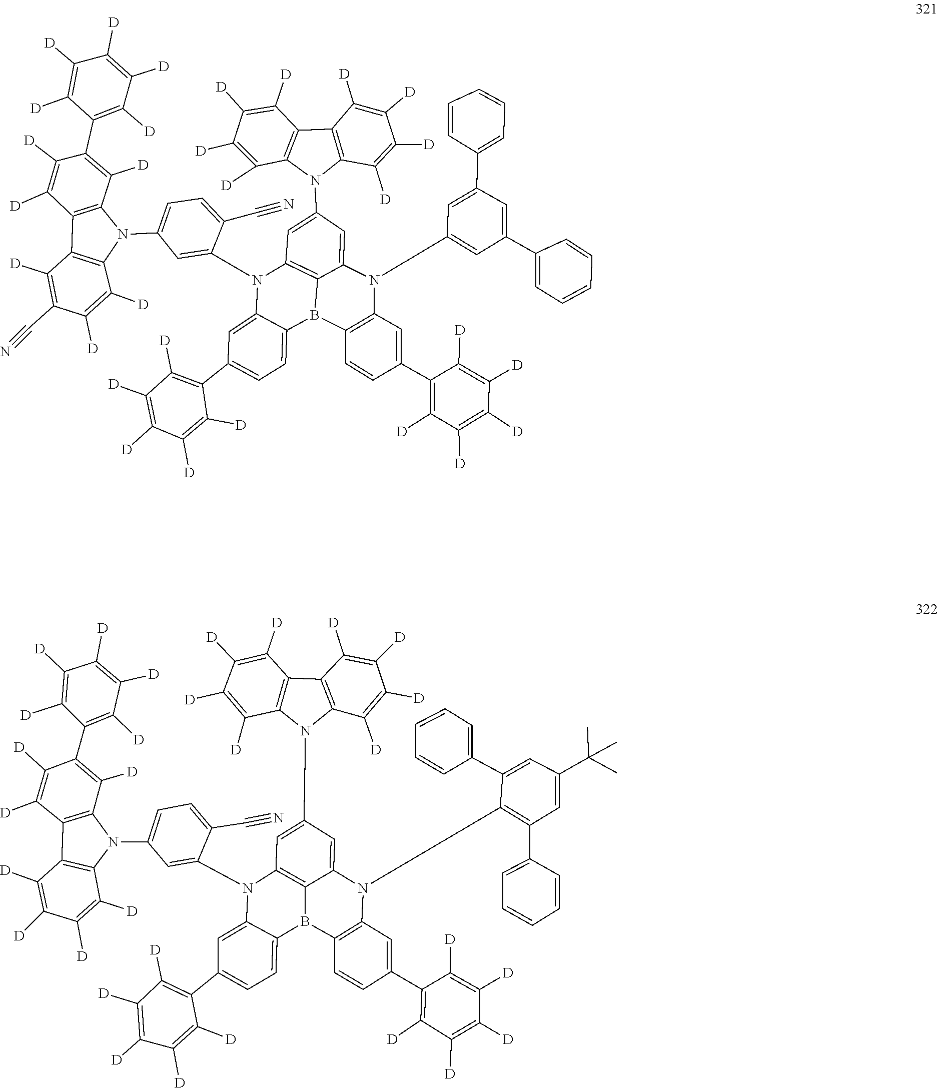 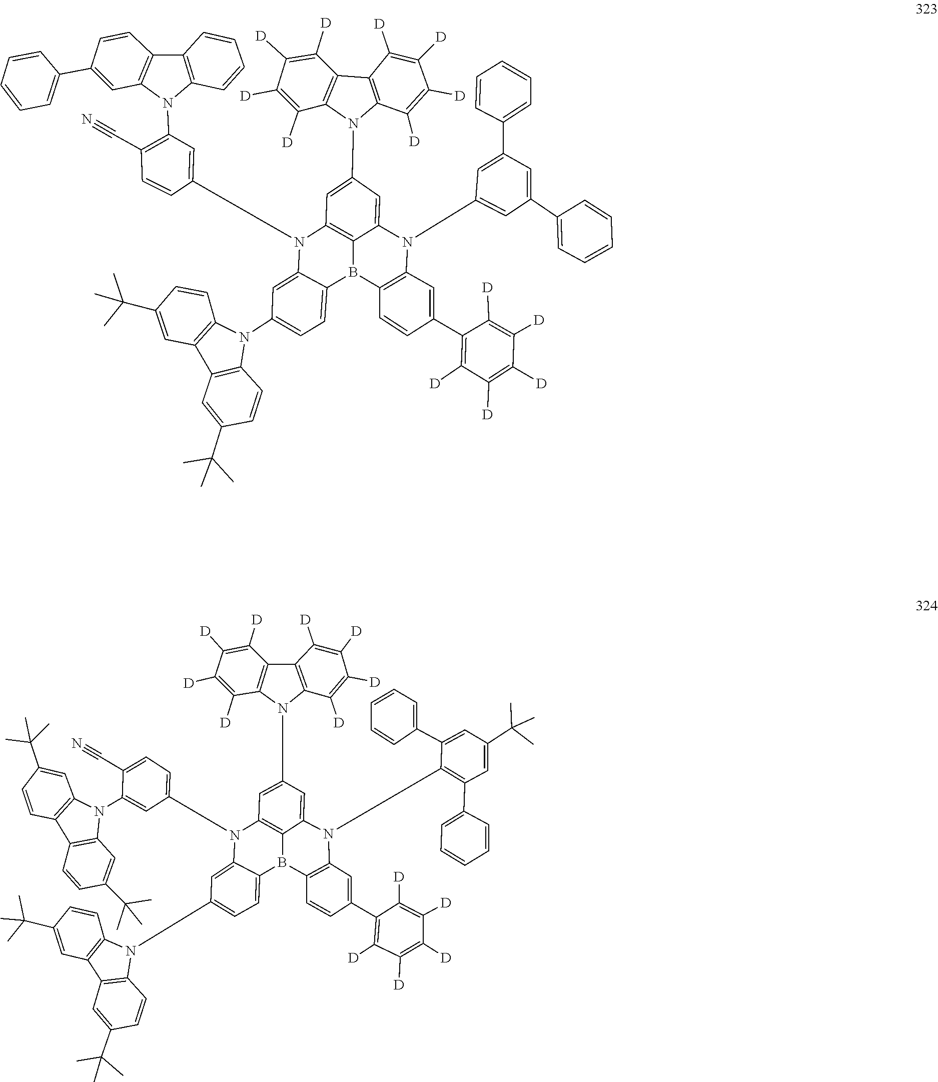 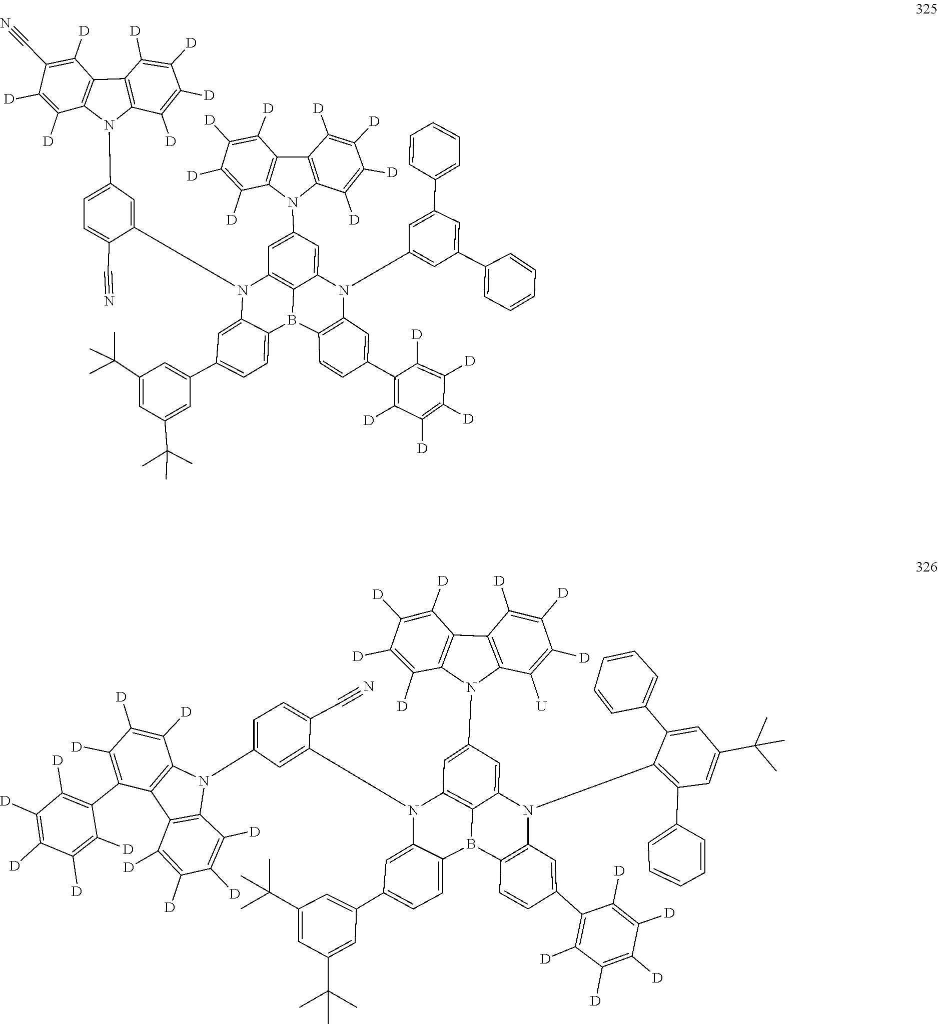 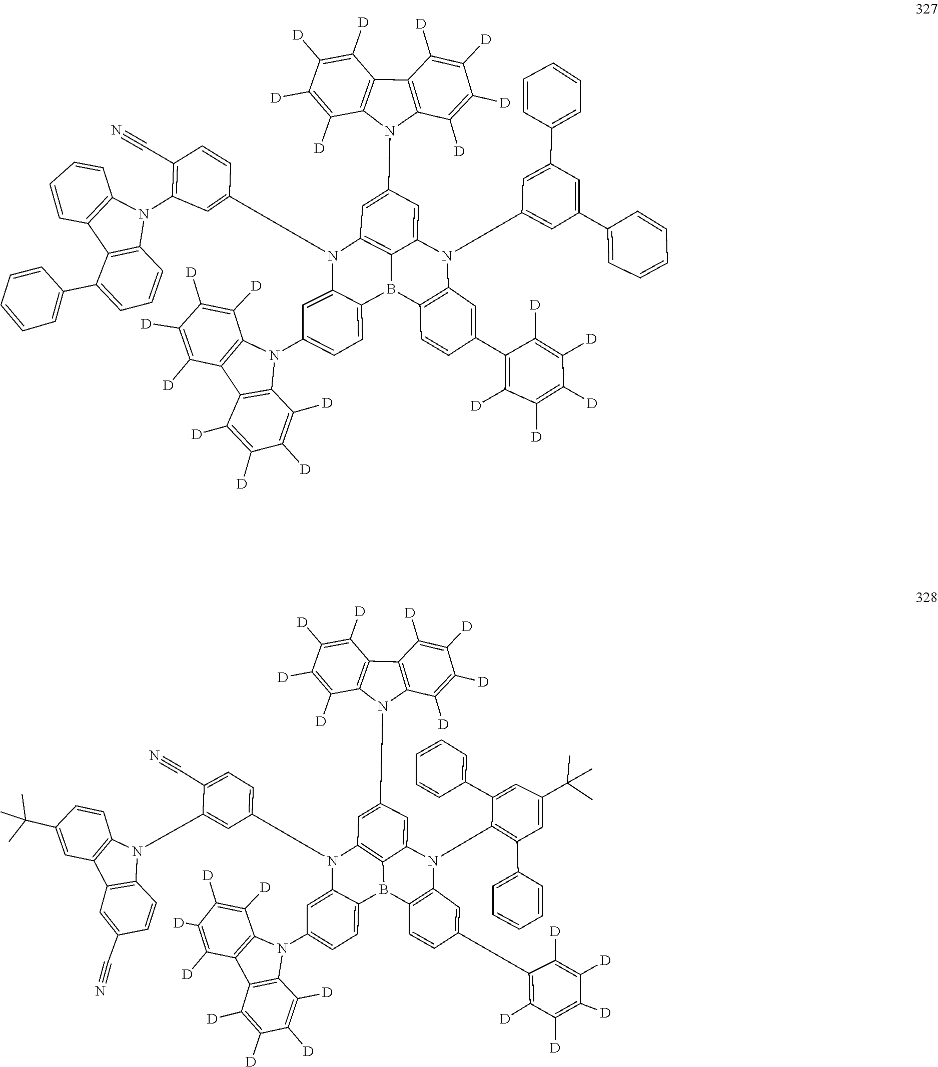 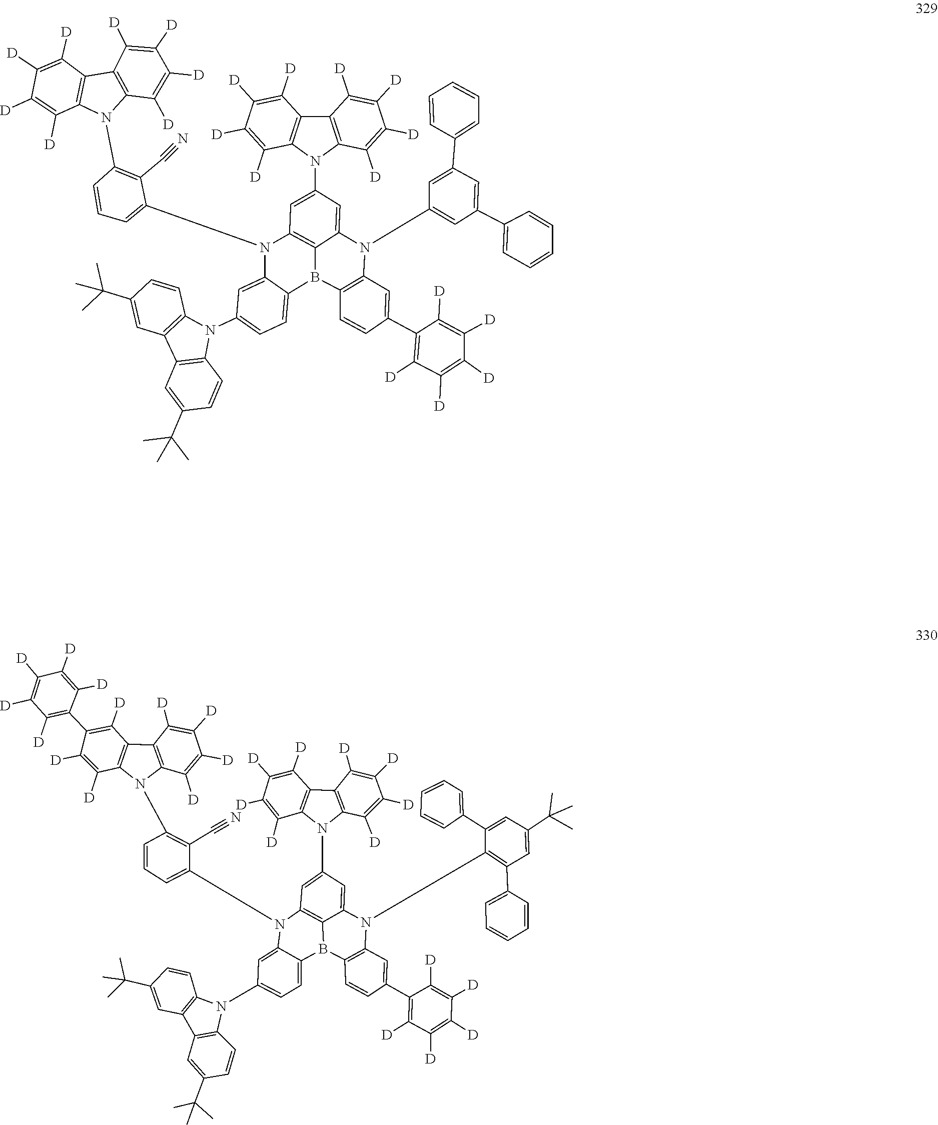 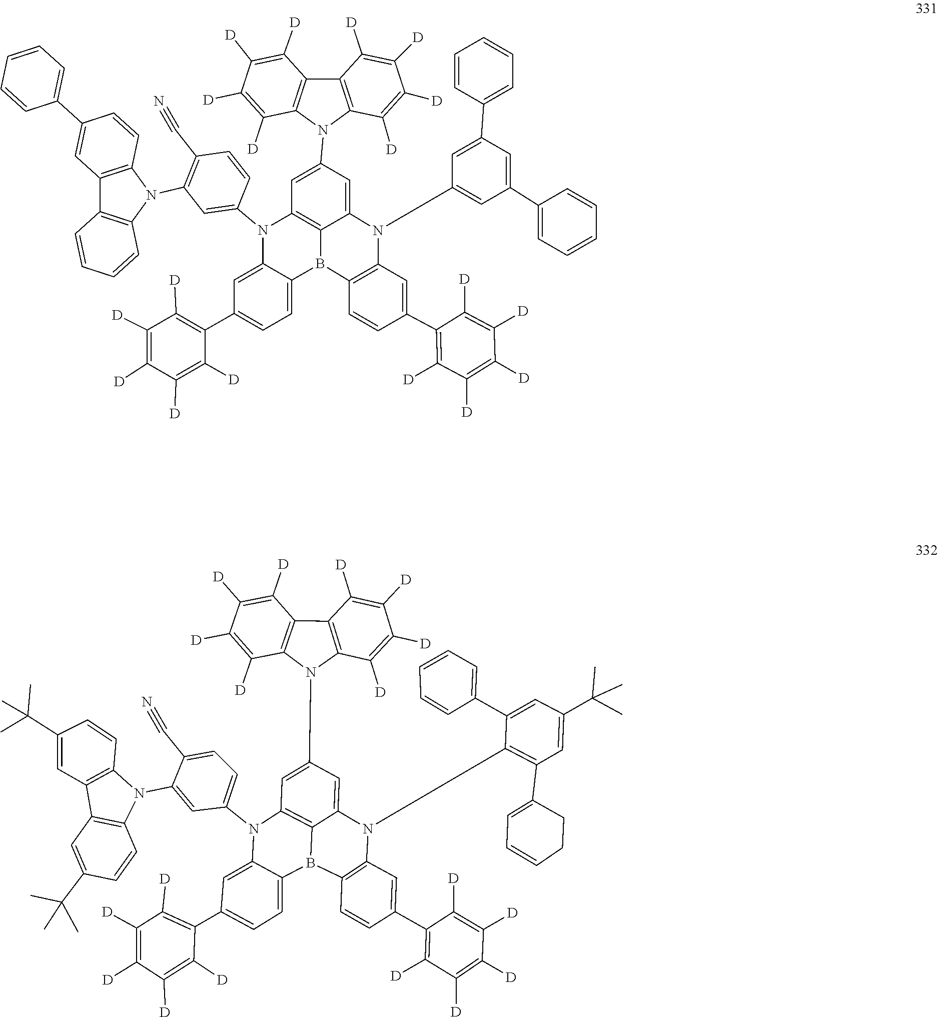 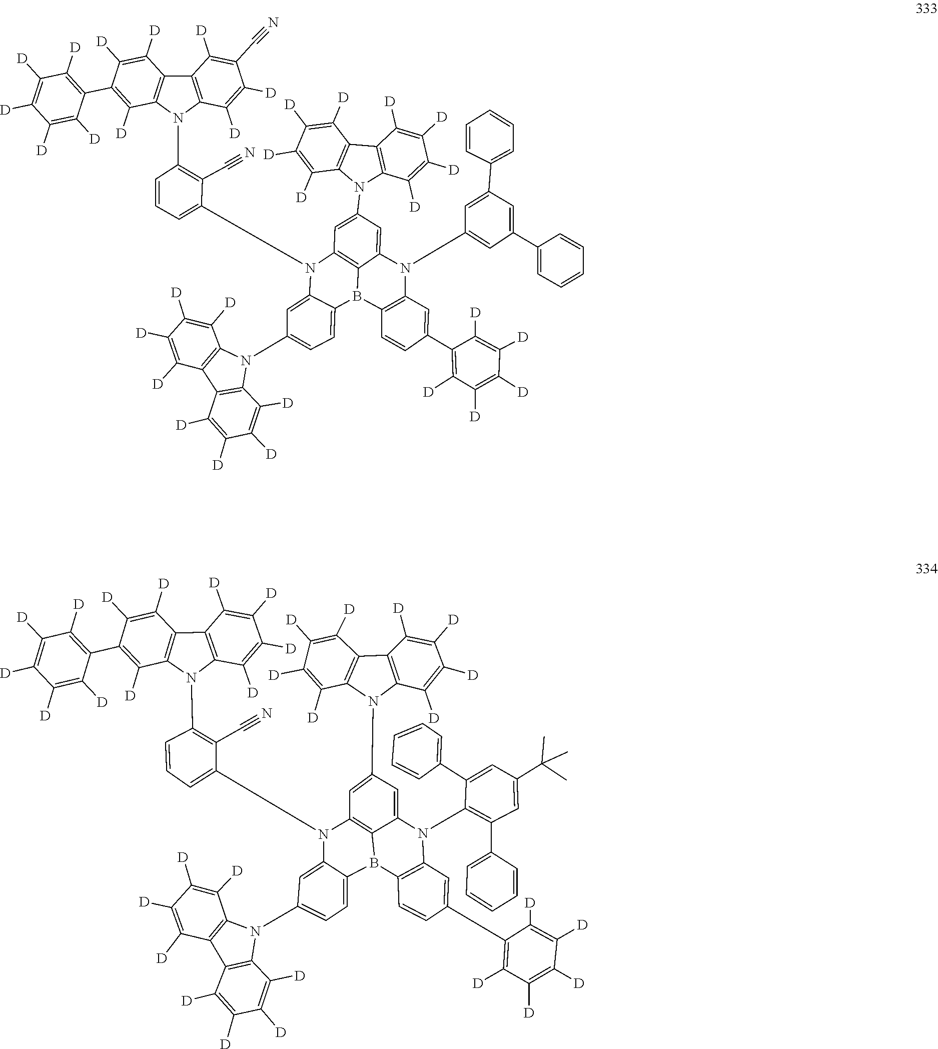 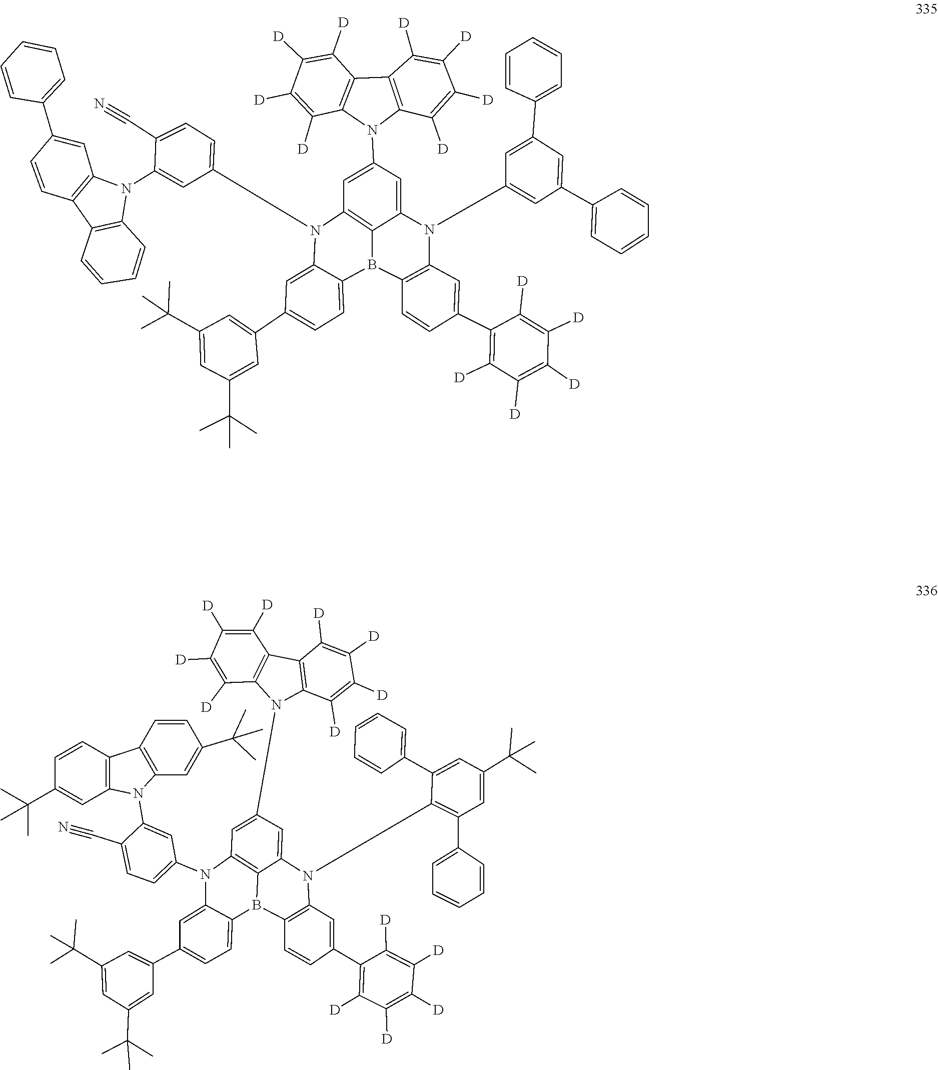 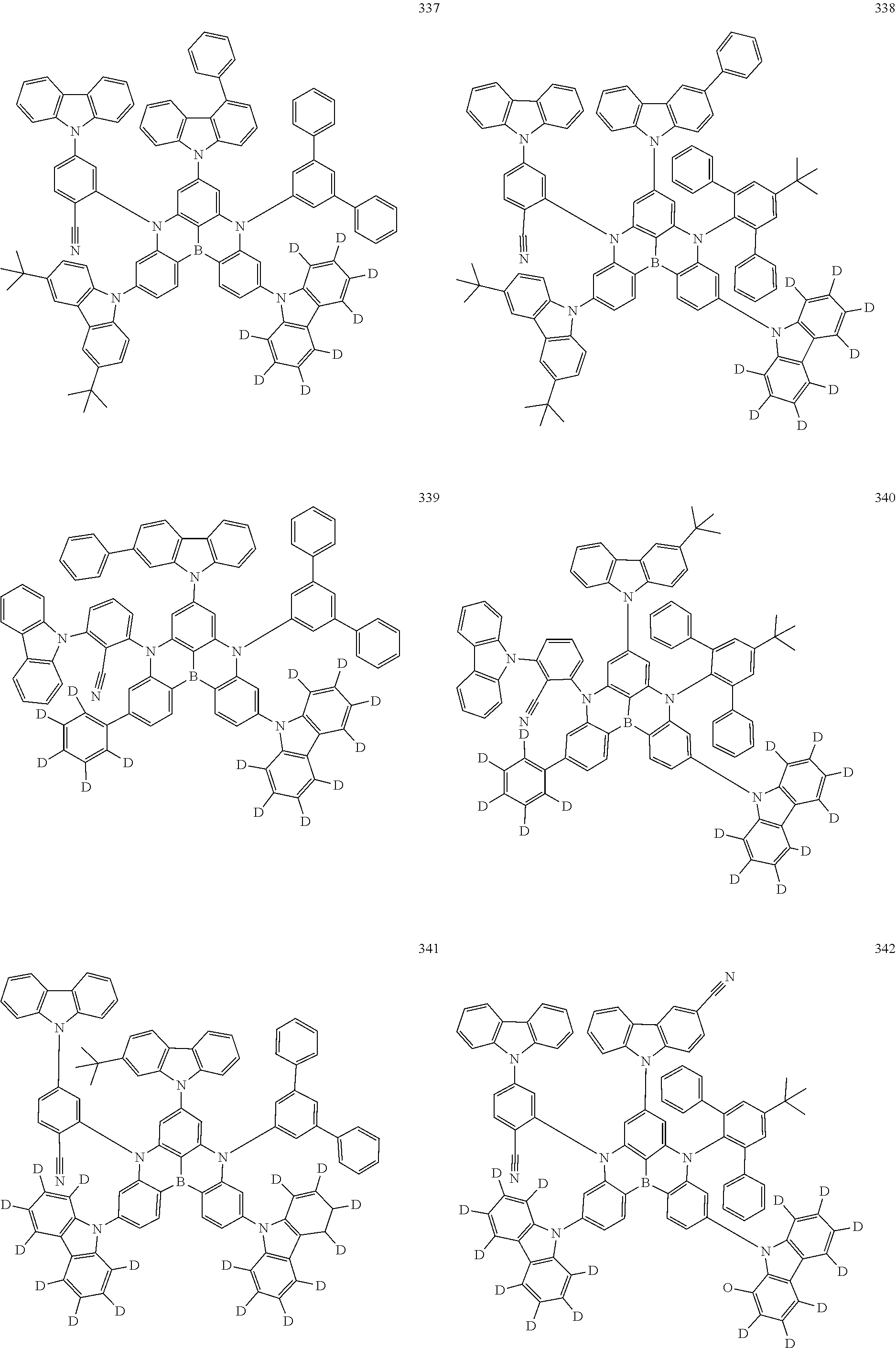 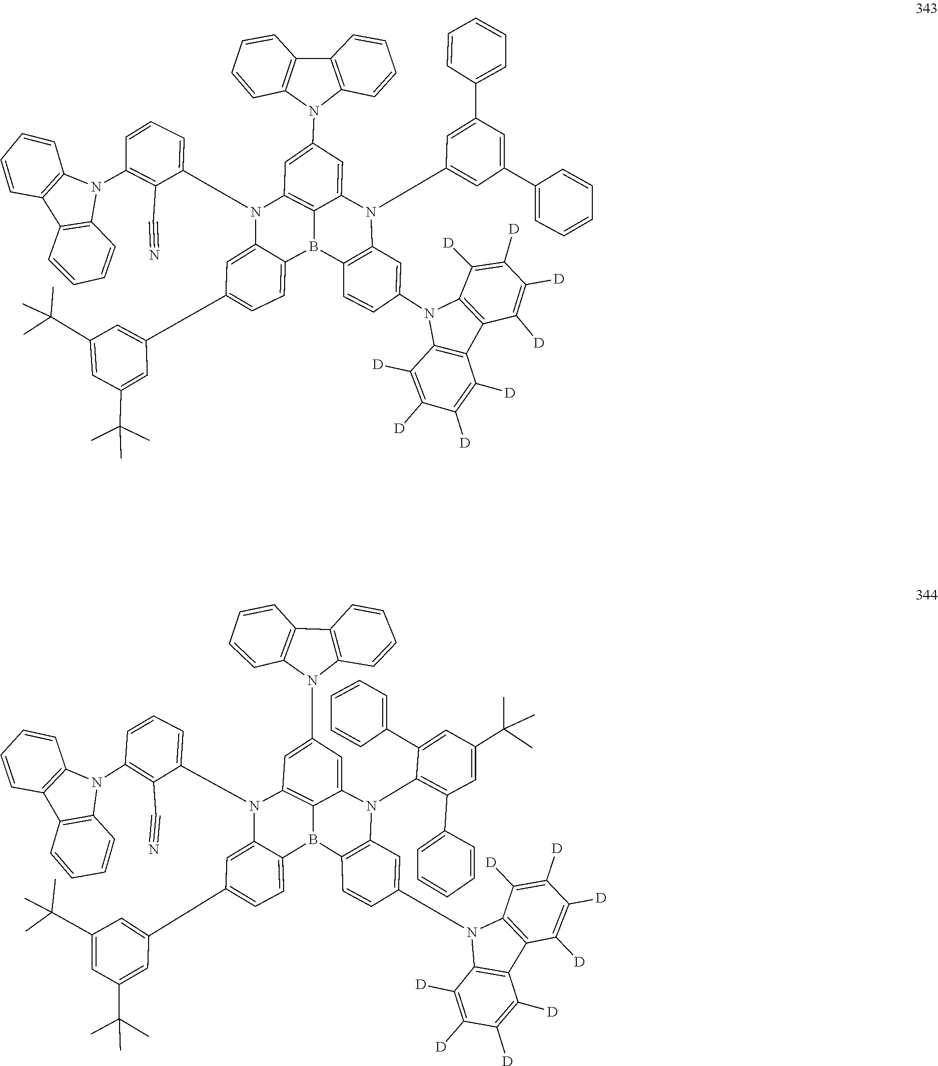 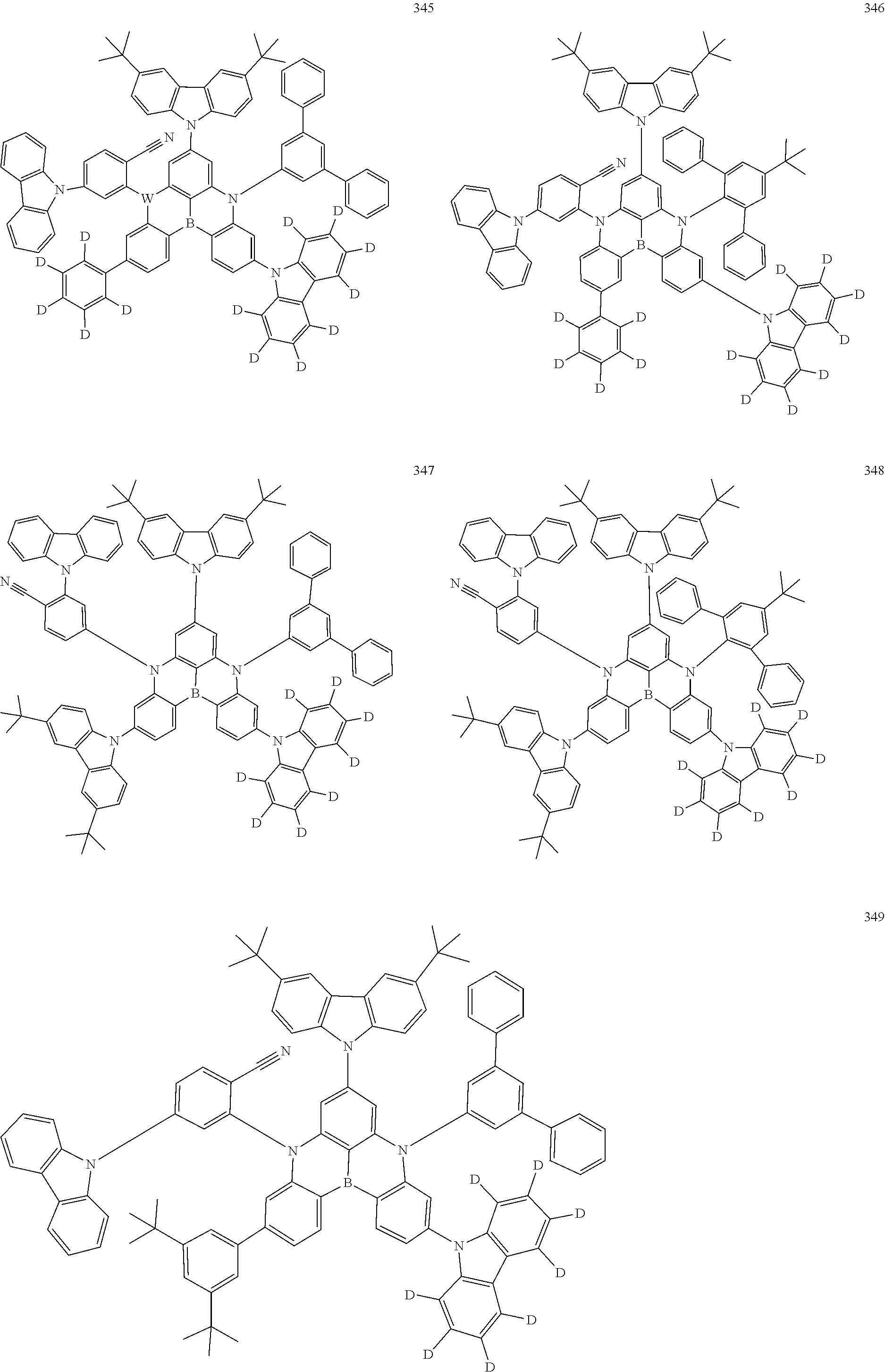 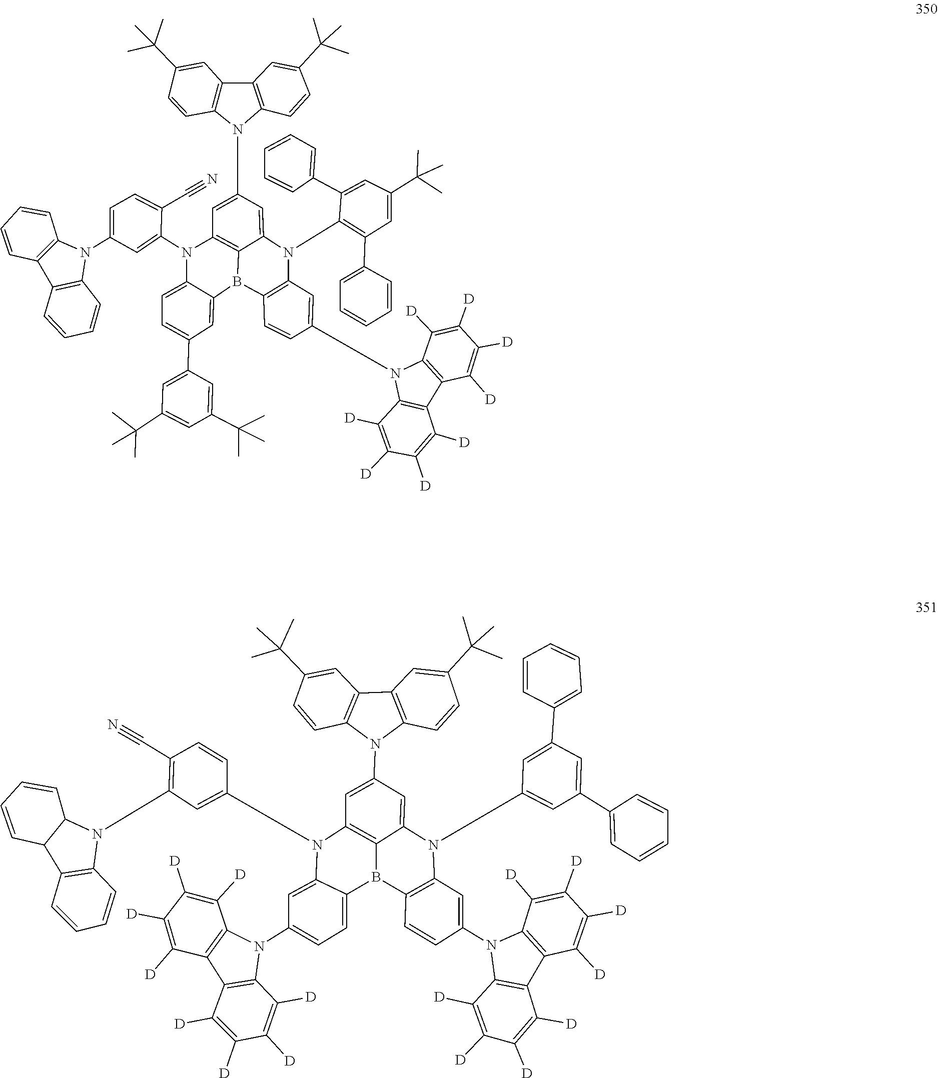 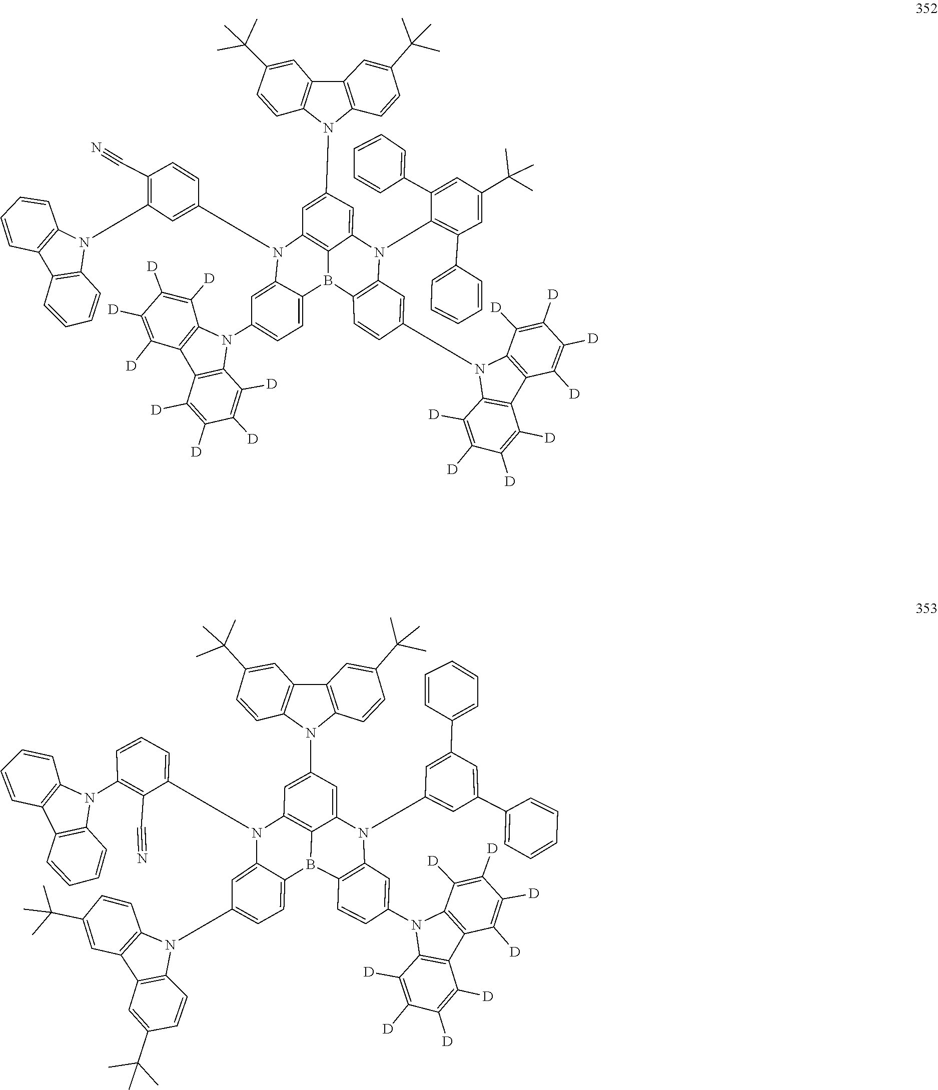 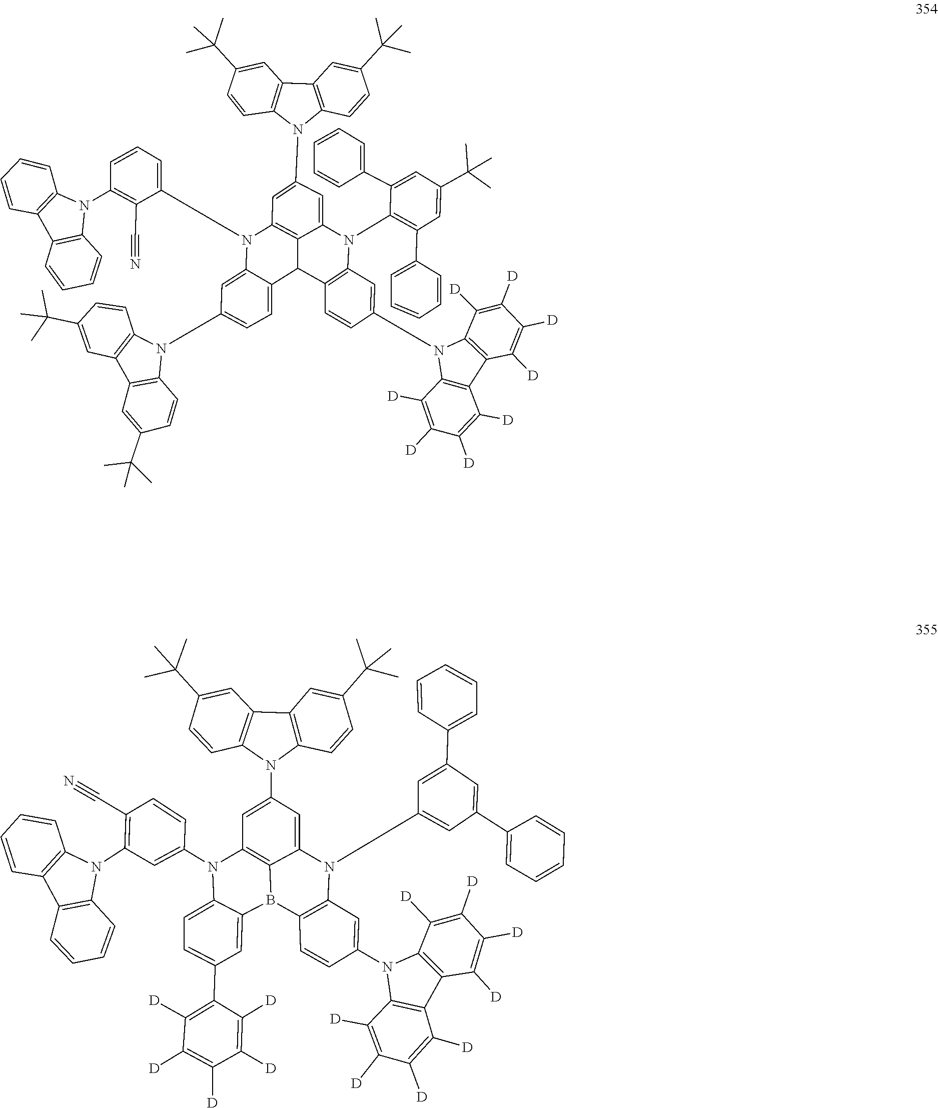 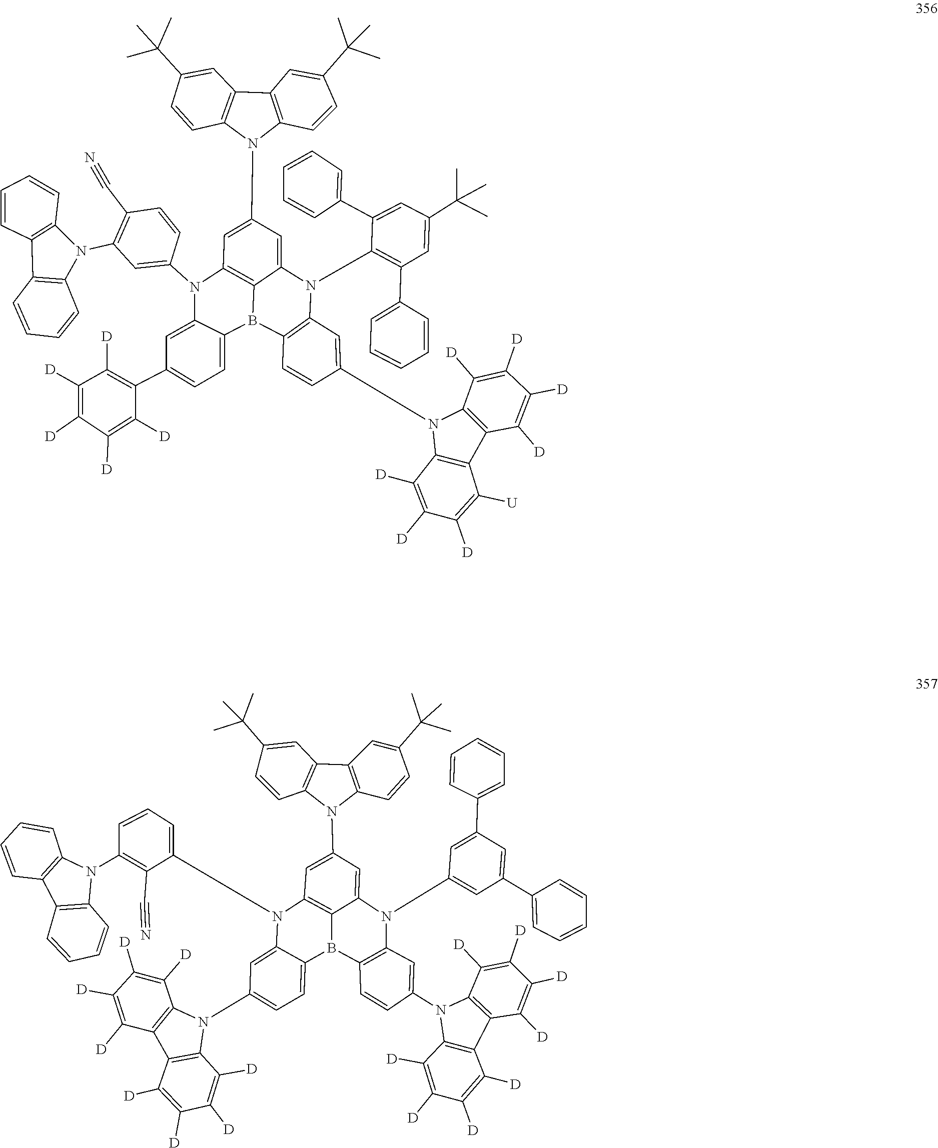 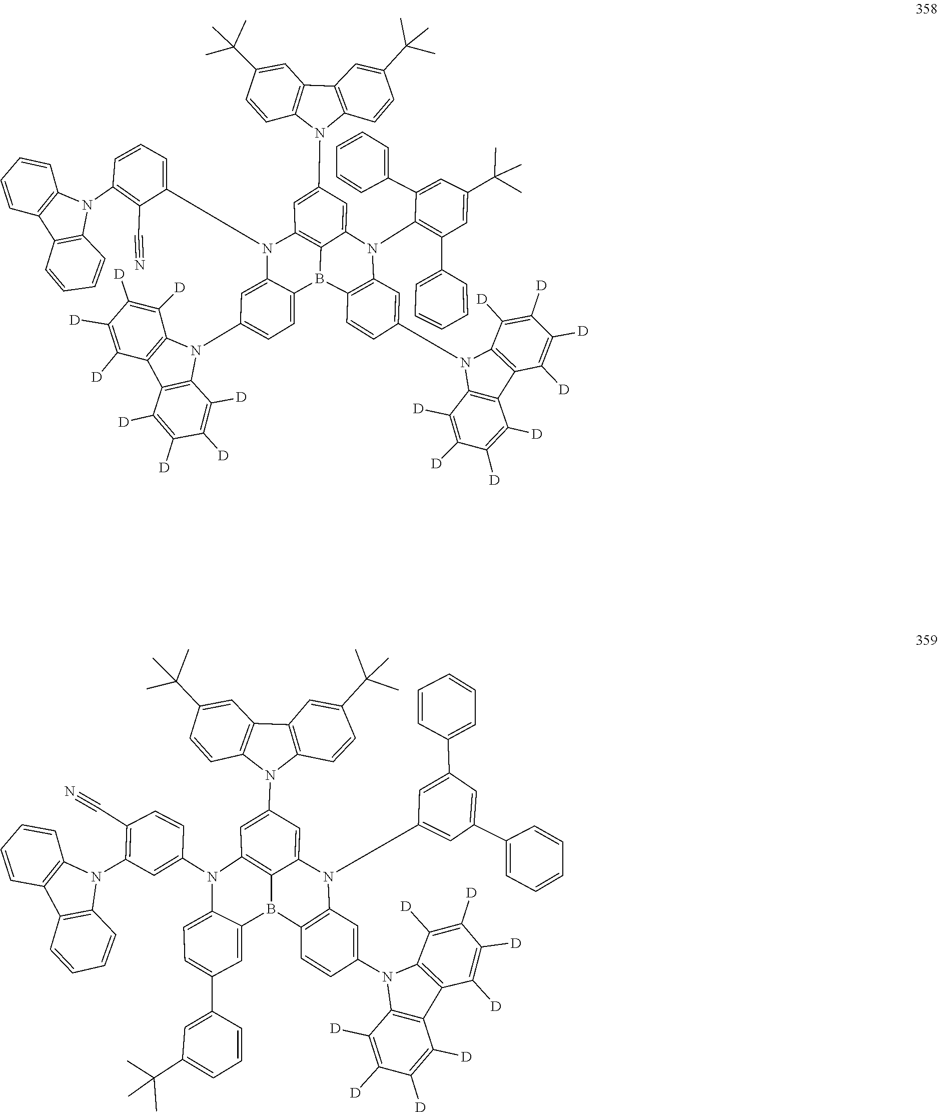 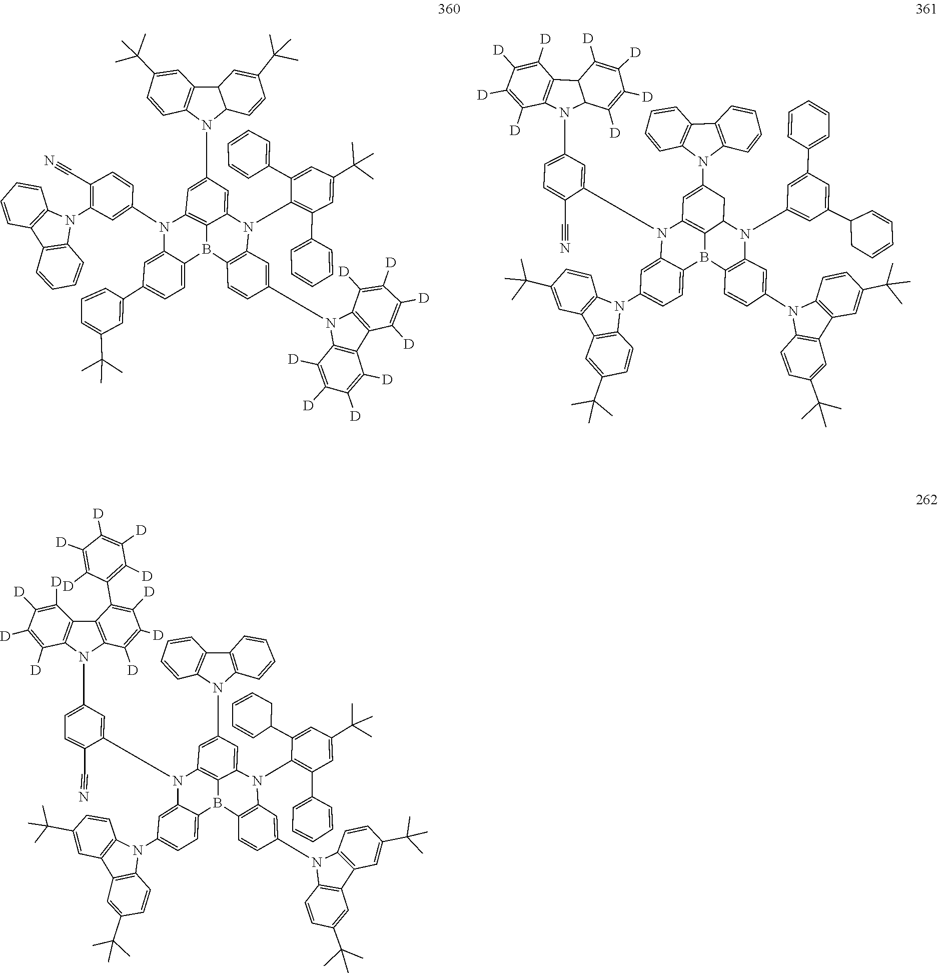 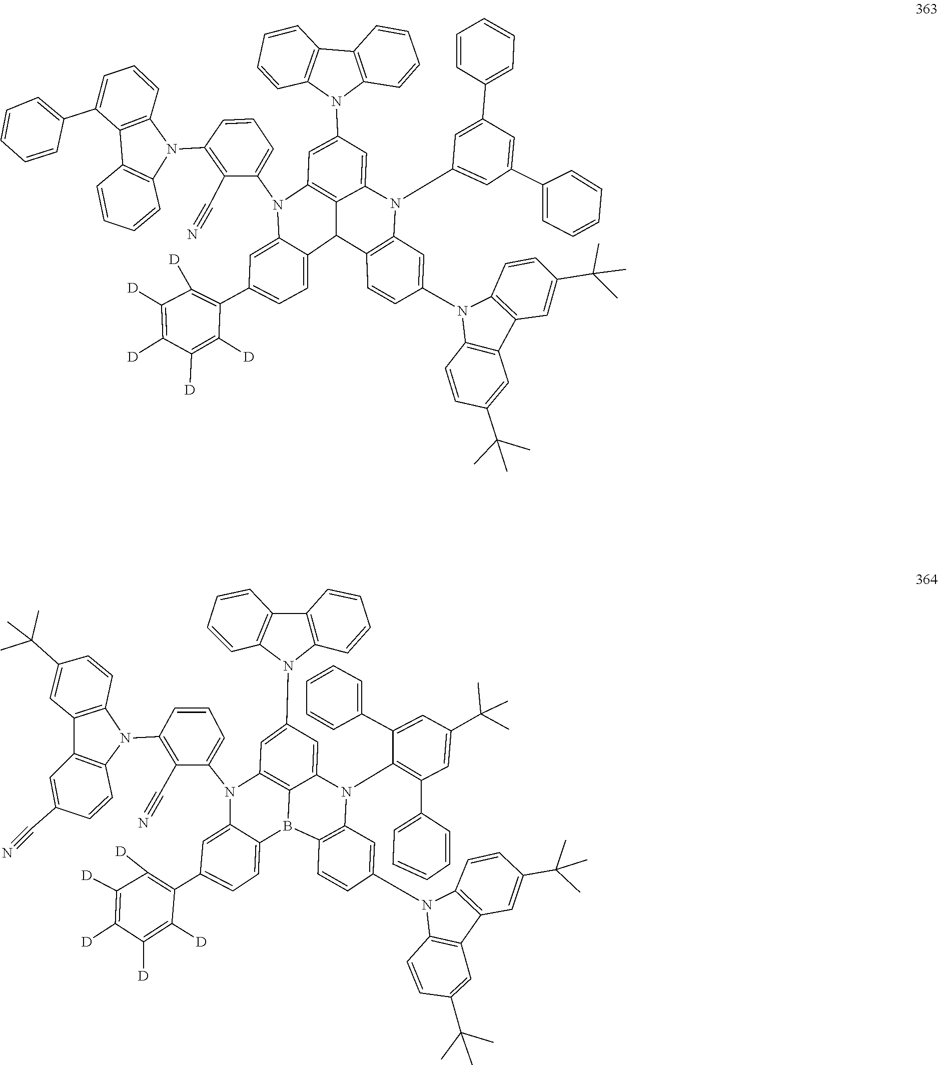 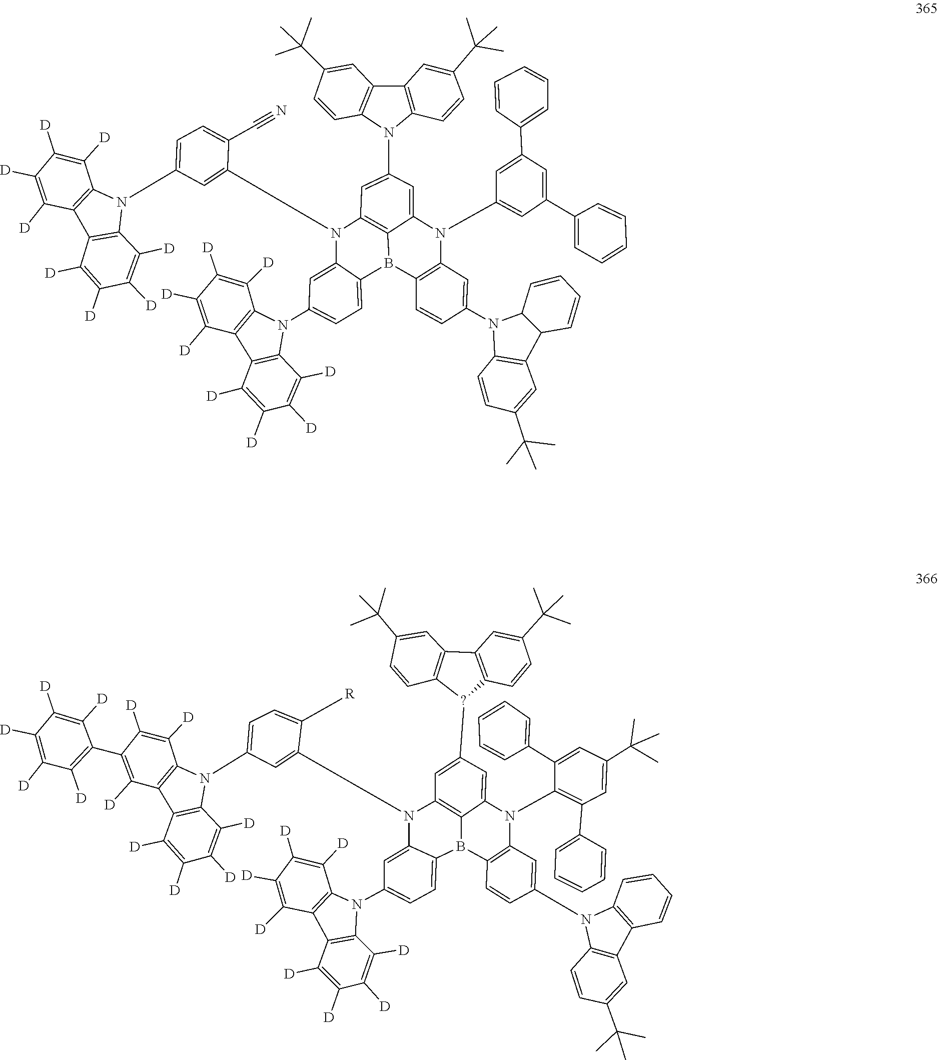 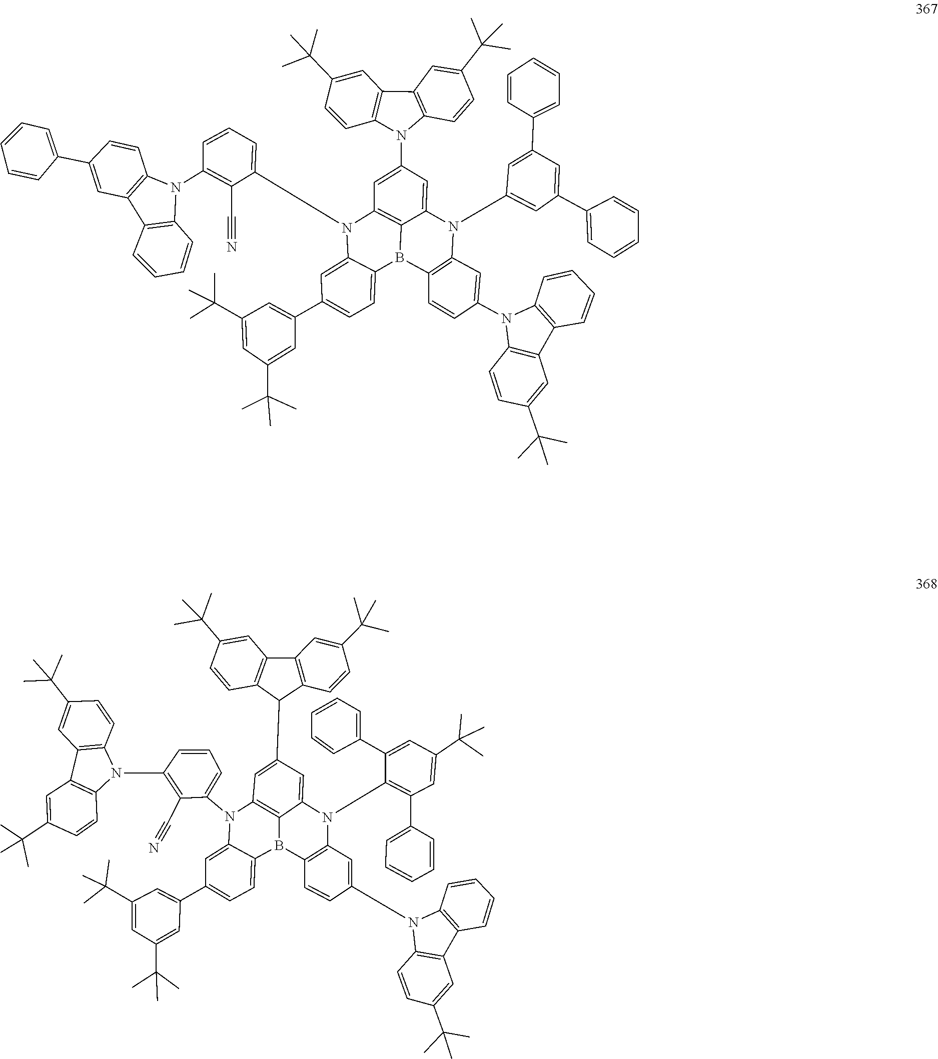 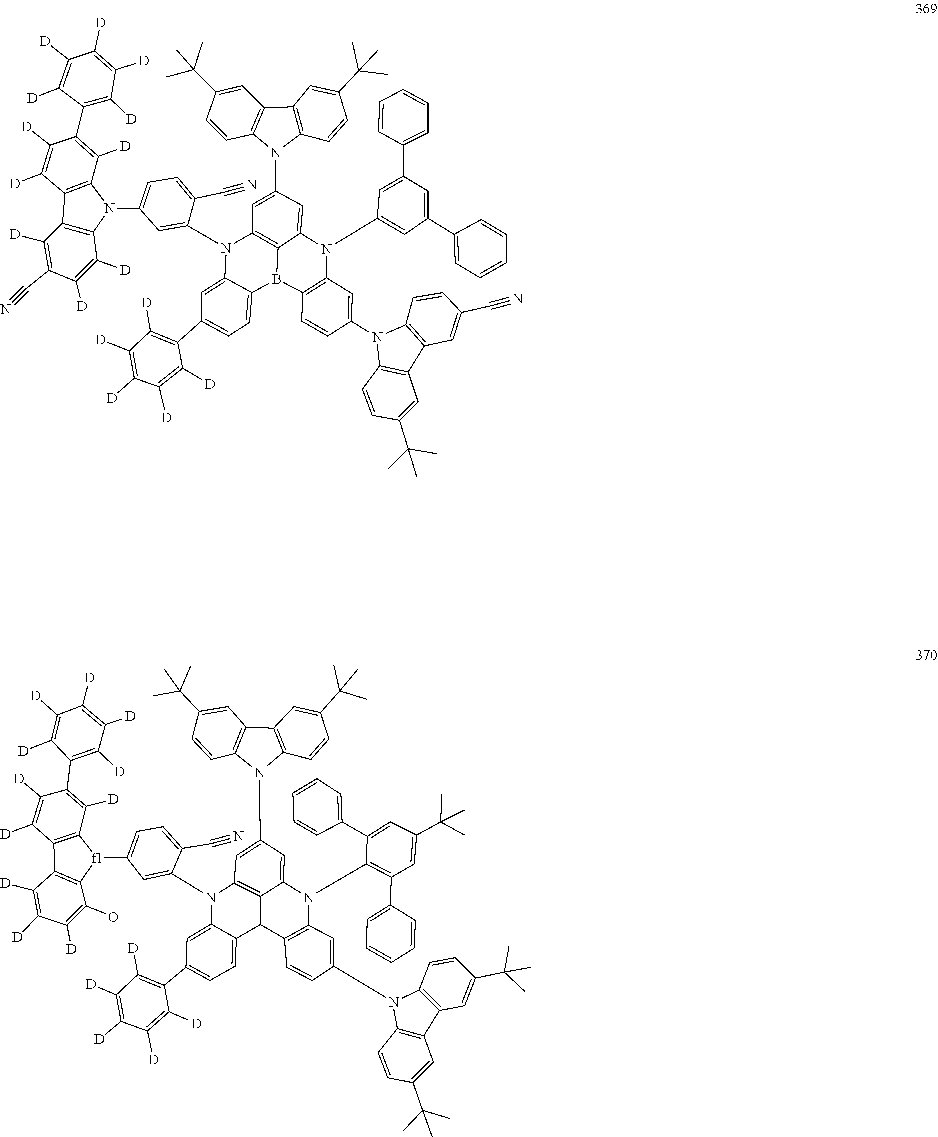 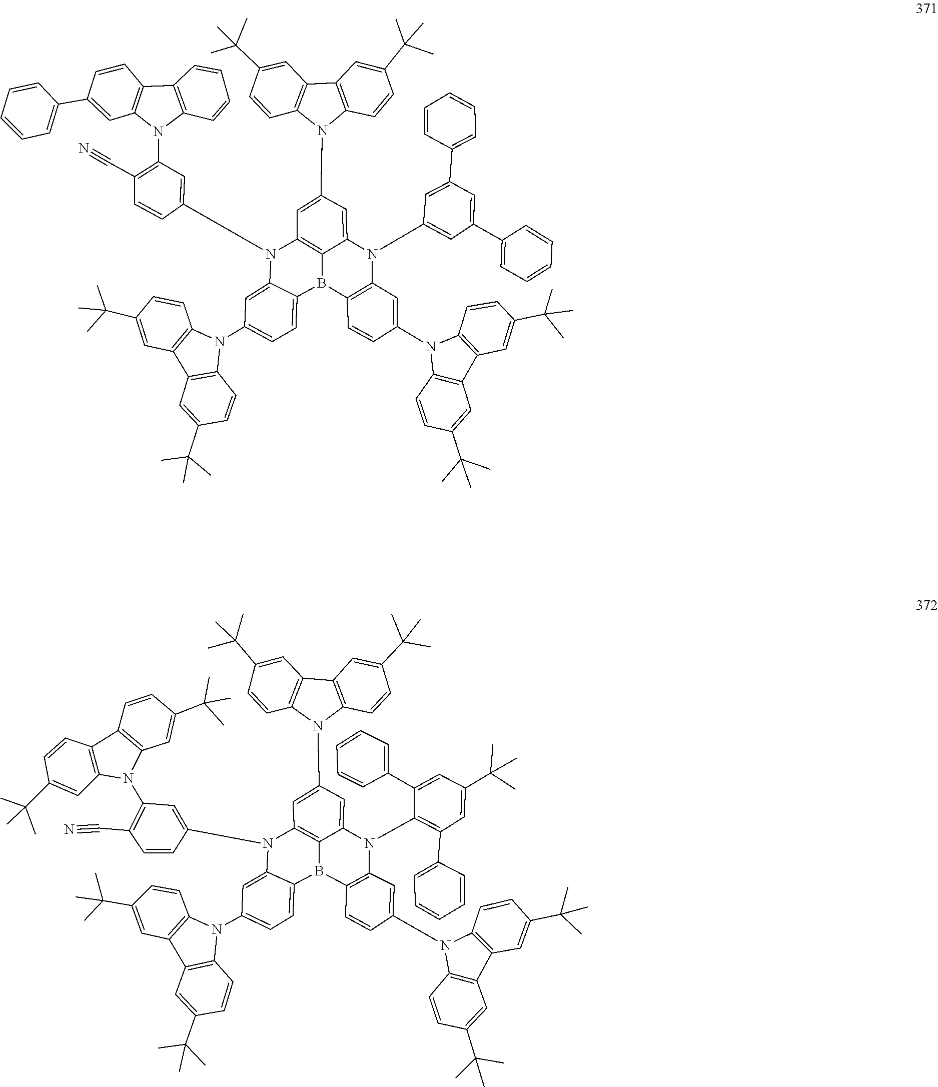
wherein, in Compound Group 1, “D” is a deuterium atom.

12. A fused polycyclic compound represented by Formula 1: 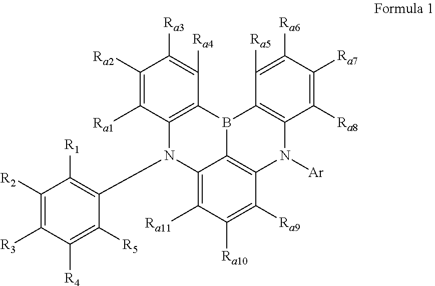
in Formula 1,
Rₐ₁ to Rₐ₁₁ and R₁ to R₅ being each independently a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one selected from among R₁ to R₅ being a cyano group and at least one remaining selected from among R₁ to R₅ being a substituent represented by Formula 2, and
Ar being a substituted or unsubstituted aryl group having 6 to 30 ring-forming carbon atoms, or a substituted or unsubstituted heteroaryl group having 2 to 30 ring-forming carbon atoms, 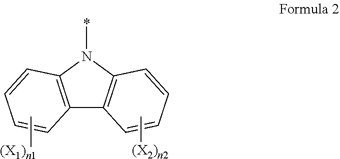
in Formula 2,
X₁ and X₂ being each independently a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1 and n2 being each independently an integer of 0 to 4, and 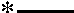 [SMILES: *C]
being a position linked to Formula 1.

13. The fused polycyclic compound of claim 12, wherein the fused polycyclic compound represented by Formula 1 is represented by Formula 1-1 or Formula 1-2: 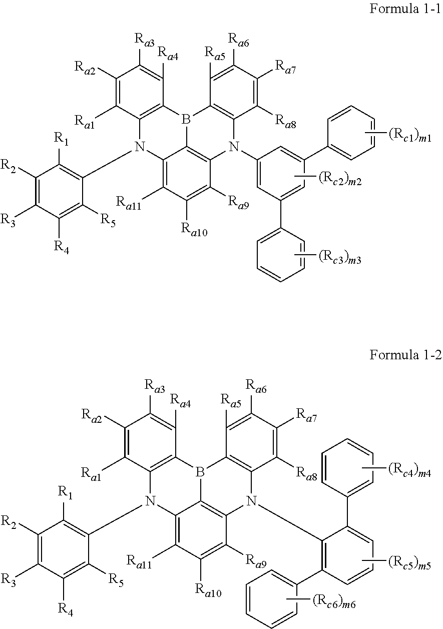
in Formula 1-1 and Formula 1-2,
R_{c1} to R_{c6} being each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m1, m3, m4, and m6 being each independently an integer of 0 to 4,
m2 and m5 being each independently an integer of 0 to 3, and
Rₐ₁ to Rₐ₁₁ and R₁ to R₅ being each as defined in Formula 1.

14. The fused polycyclic compound of claim 12, wherein the fused polycyclic compound represented by Formula 1 is represented by Formula 1-3: 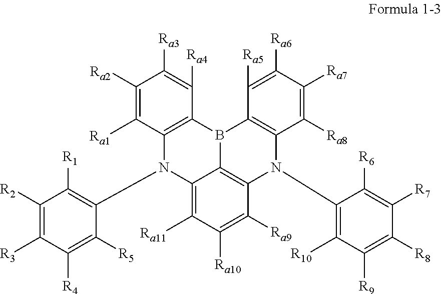
in Formula 1-3,
R₆ to R₁₀ being each independently a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one selected from among R₆ to R₁₀ being a cyano group and at least one remaining selected from among R₆ to R₁₀ being a substituent represented by Formula 2, and
Rₐ₁ to Rₐ₁₁ and R₁ to R₅ being each as defined in Formula 1.

15. The fused polycyclic compound of claim 12, wherein the fused polycyclic compound represented by Formula 1 is represented by any one selected from among Formula 1-4 to Formula 1-6: 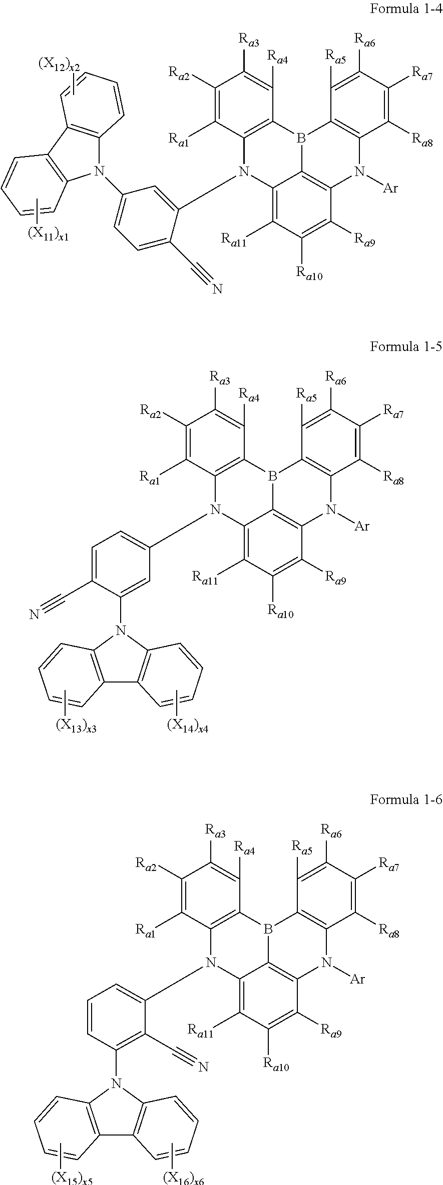
in Formula 1-4 to Formula 1-6,
X₁₁ to X₁₆ being each independently a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
x1 to x6 being each independently an integer of 0 to 4, and
Rₐ₁ to Rₐ₁₁ and Ar being each as defined in Formula 1.

16. The fused polycyclic compound of claim 15, wherein X₁₁ to X₁₆ are each independently a hydrogen atom, a deuterium atom, a cyano group, a substituted or unsubstituted t-butyl group, or a substituted or unsubstituted phenyl group.

17. The fused polycyclic compound of claim 12, wherein the fused polycyclic compound represented by Formula 1 is represented by any one selected from among Formula 1-7 to Formula 1-9: 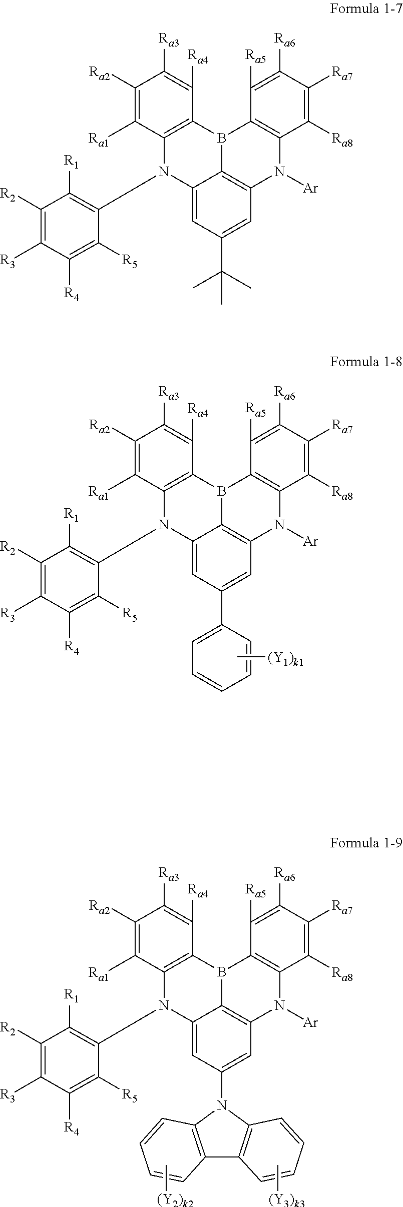
in Formula 1-7 to Formula 1-9,
Y₁ to Y₃ being each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
k1 being an integer of 0 to 5,
k2 and k3 being each independently an integer of 0 to 4, and
Rₐ₁ to Rₐ₈, R₁ to R₅, and Ar being each as defined in Formula 1.

18. The fused polycyclic compound of claim 12, wherein Rₐ₂, Rₐ₃, Rₐ₆, and Rₐ₇ are each independently a hydrogen atom, a deuterium atom, or a substituent represented by any one selected from among Formula 3-1 to Formula 3-7: 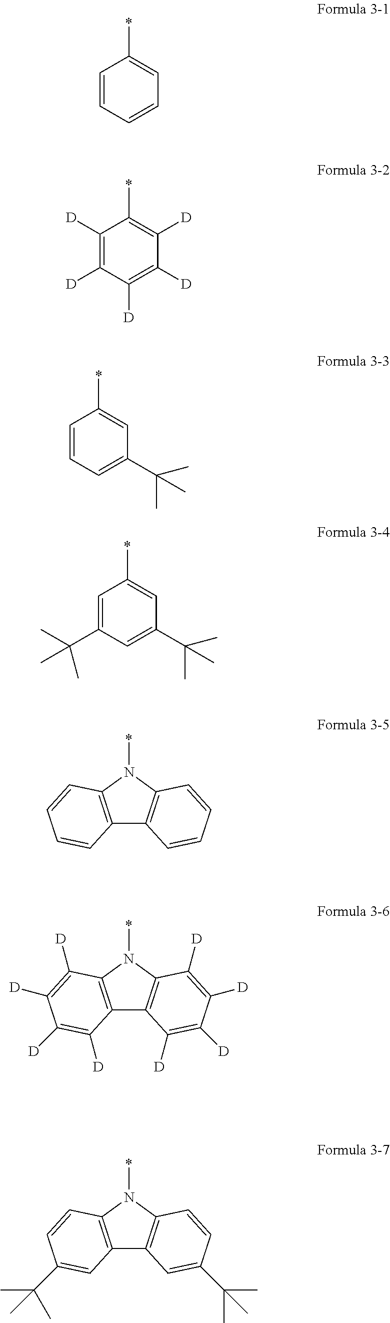
in Formula 3-1 to Formula 3-7, 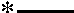 [SMILES: *C]
being a position linked to Formula 1.

19. The fused polycyclic compound of claim 12, wherein the fused polycyclic compound represented by Formula 1 is any one selected from among compounds represented by Compound Group 1: 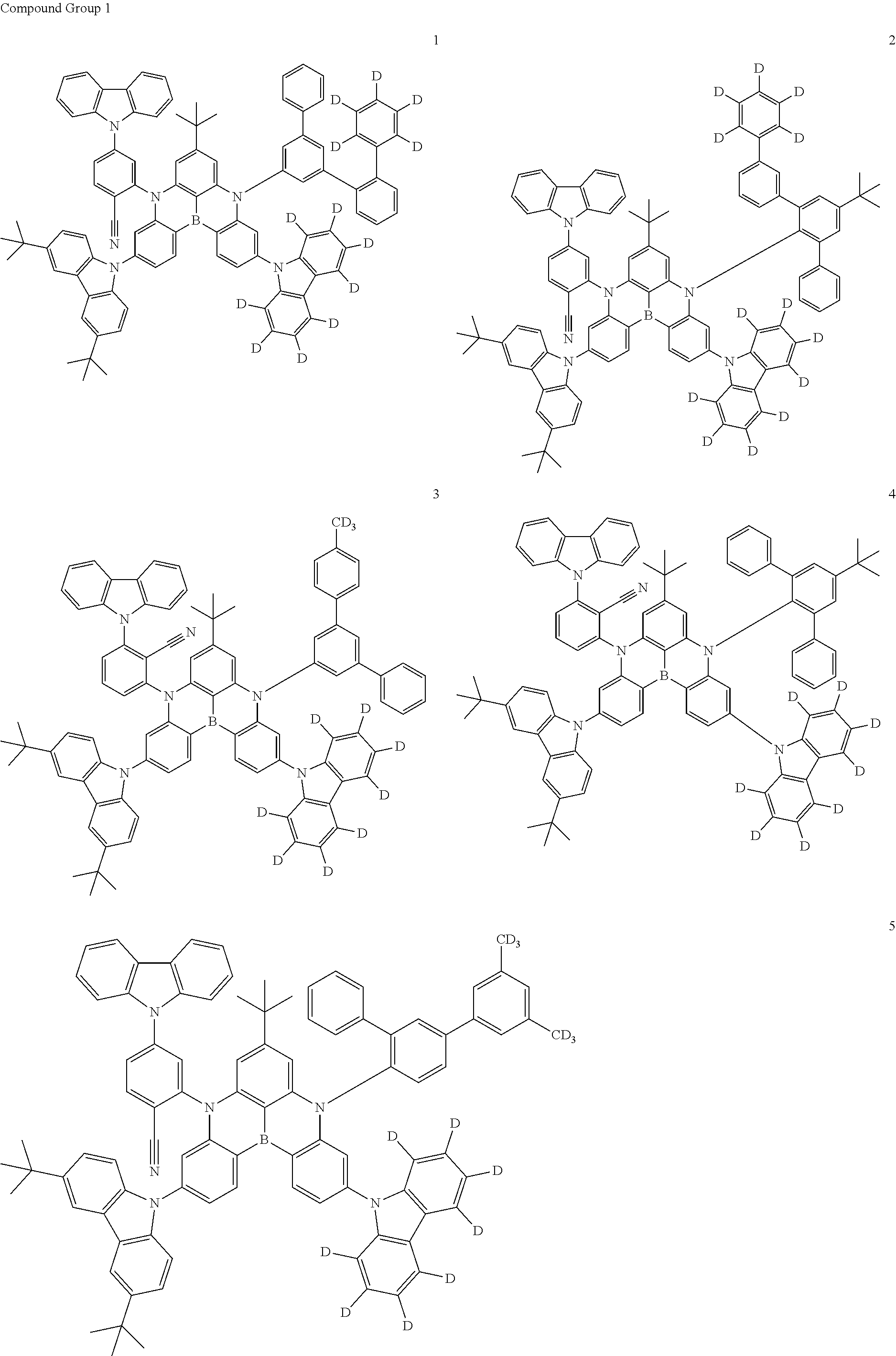 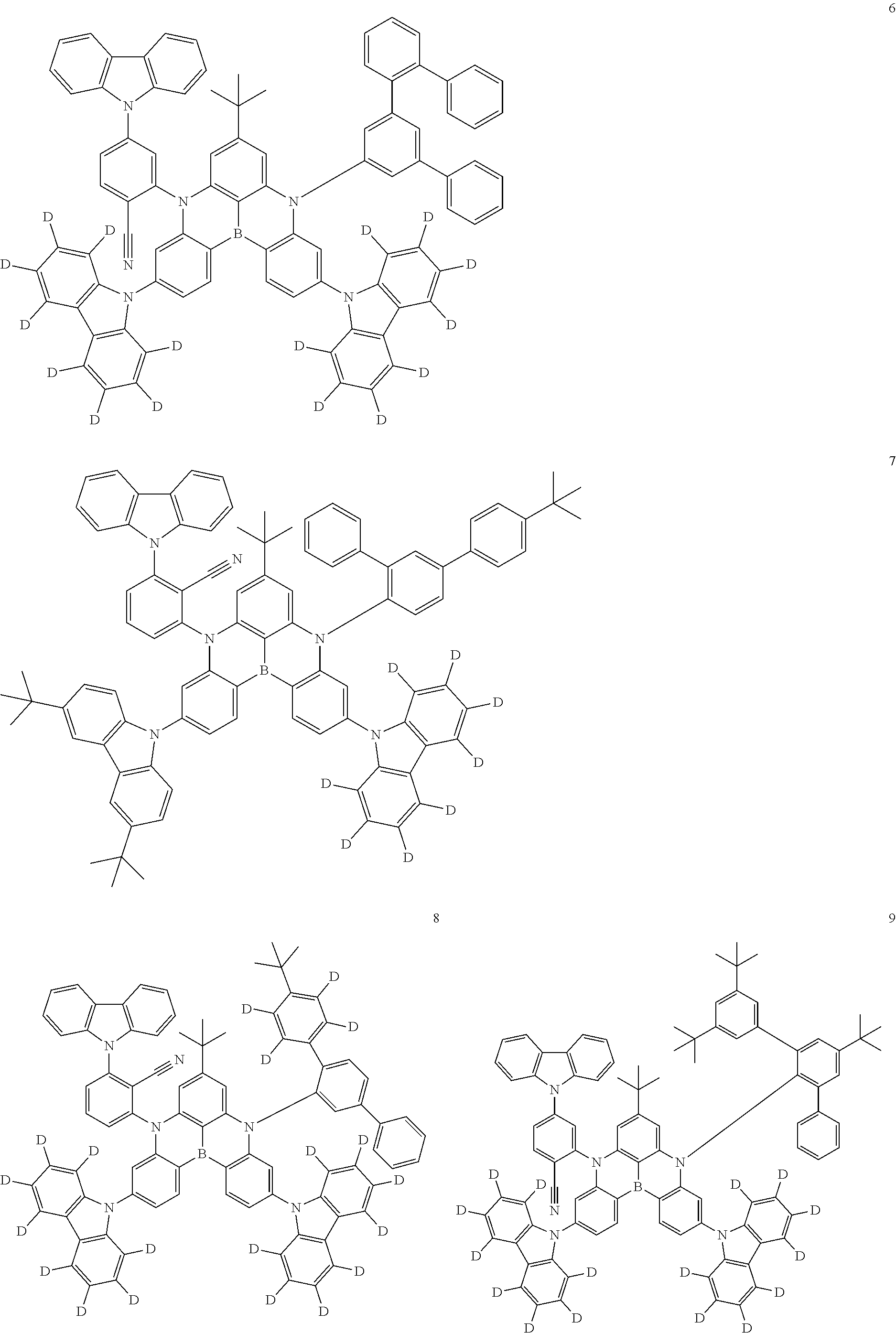 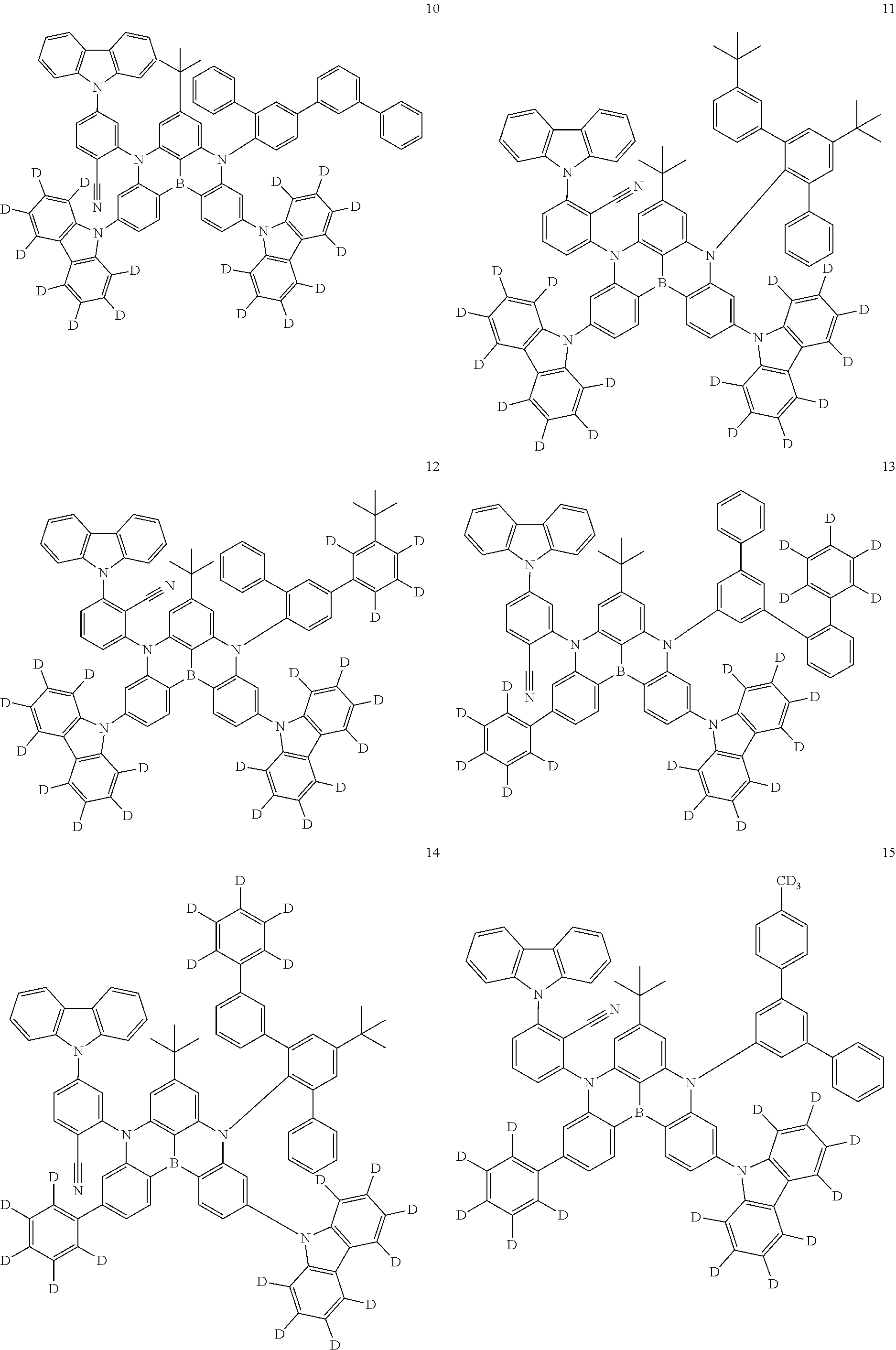 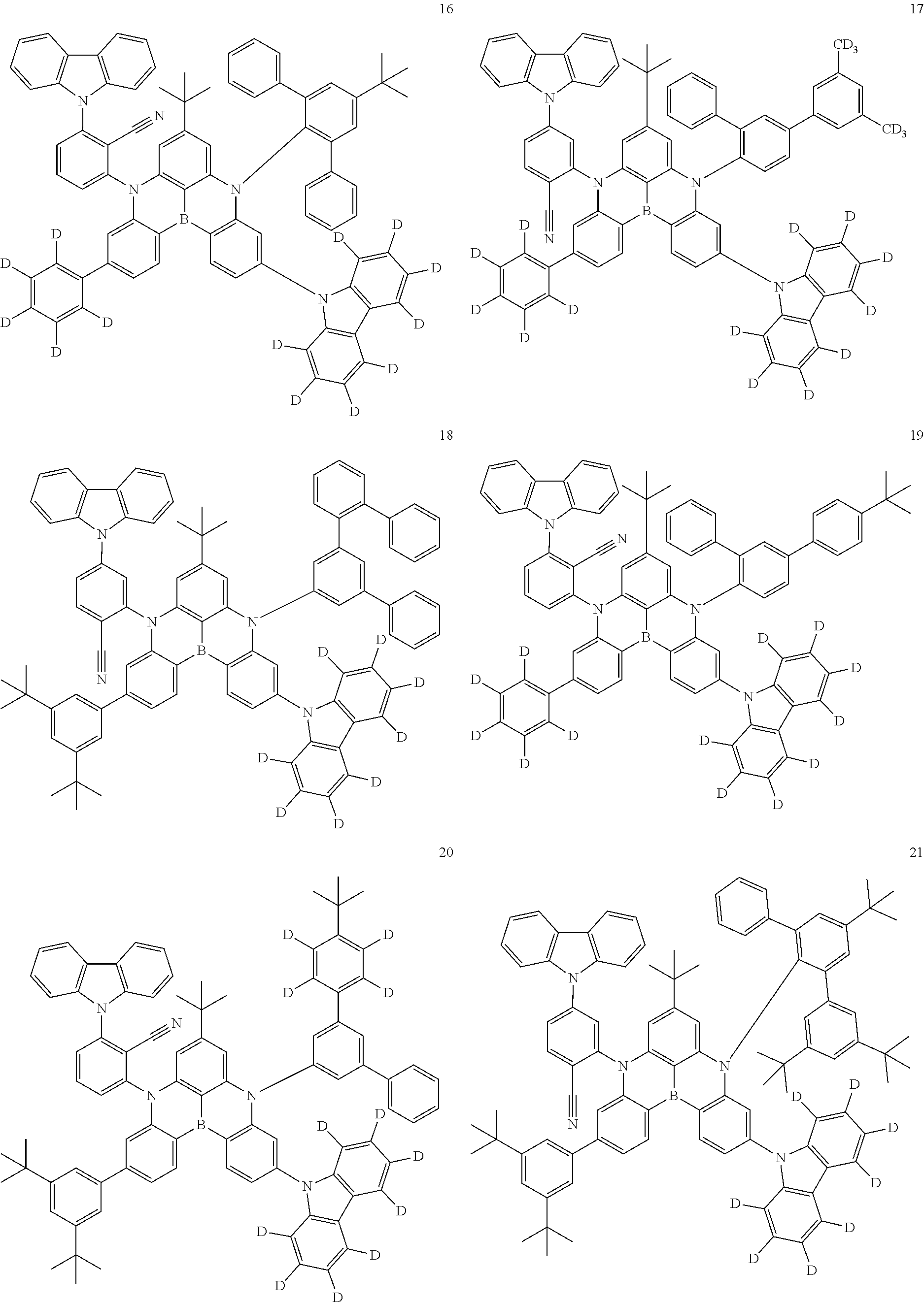 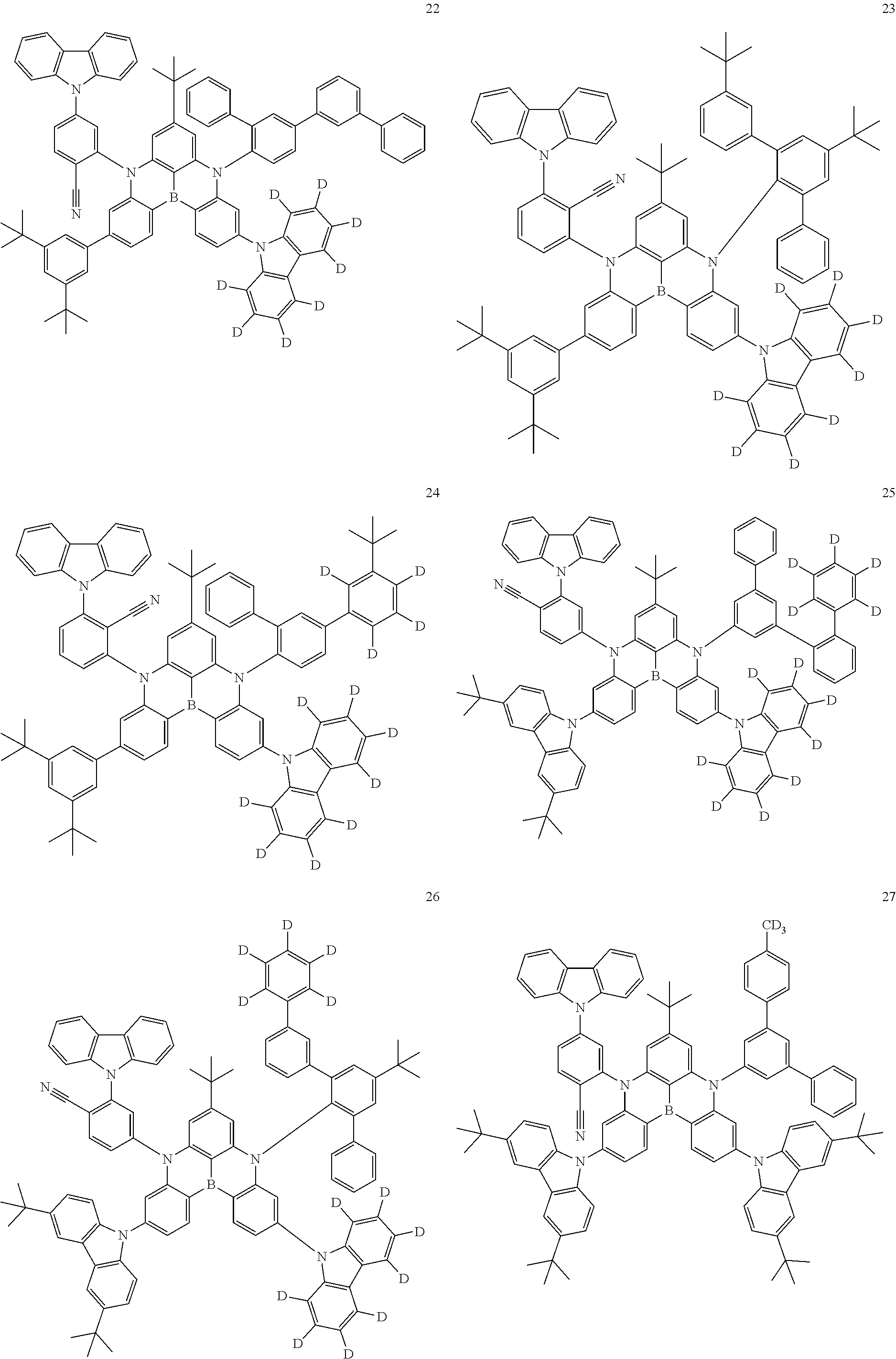 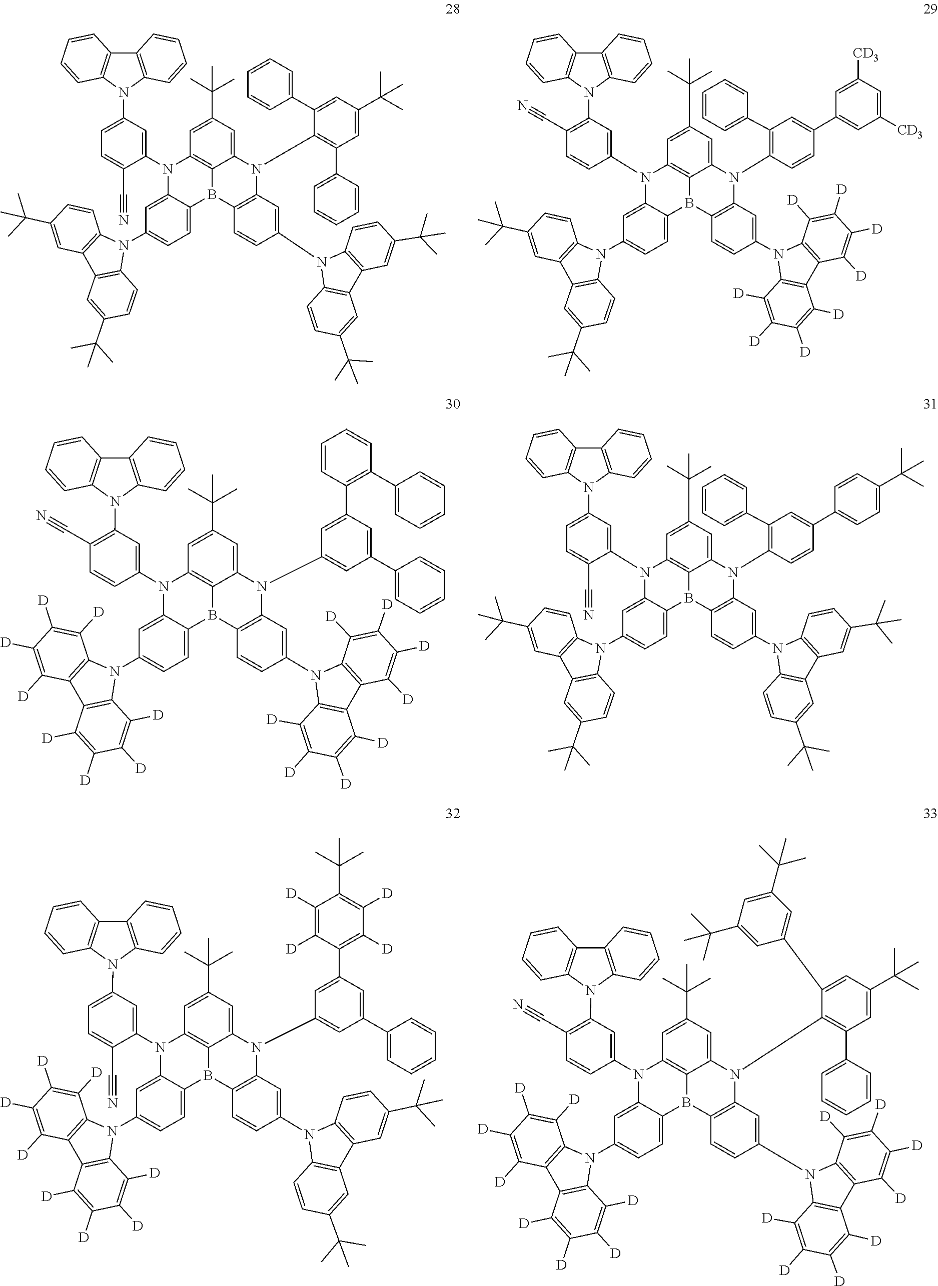 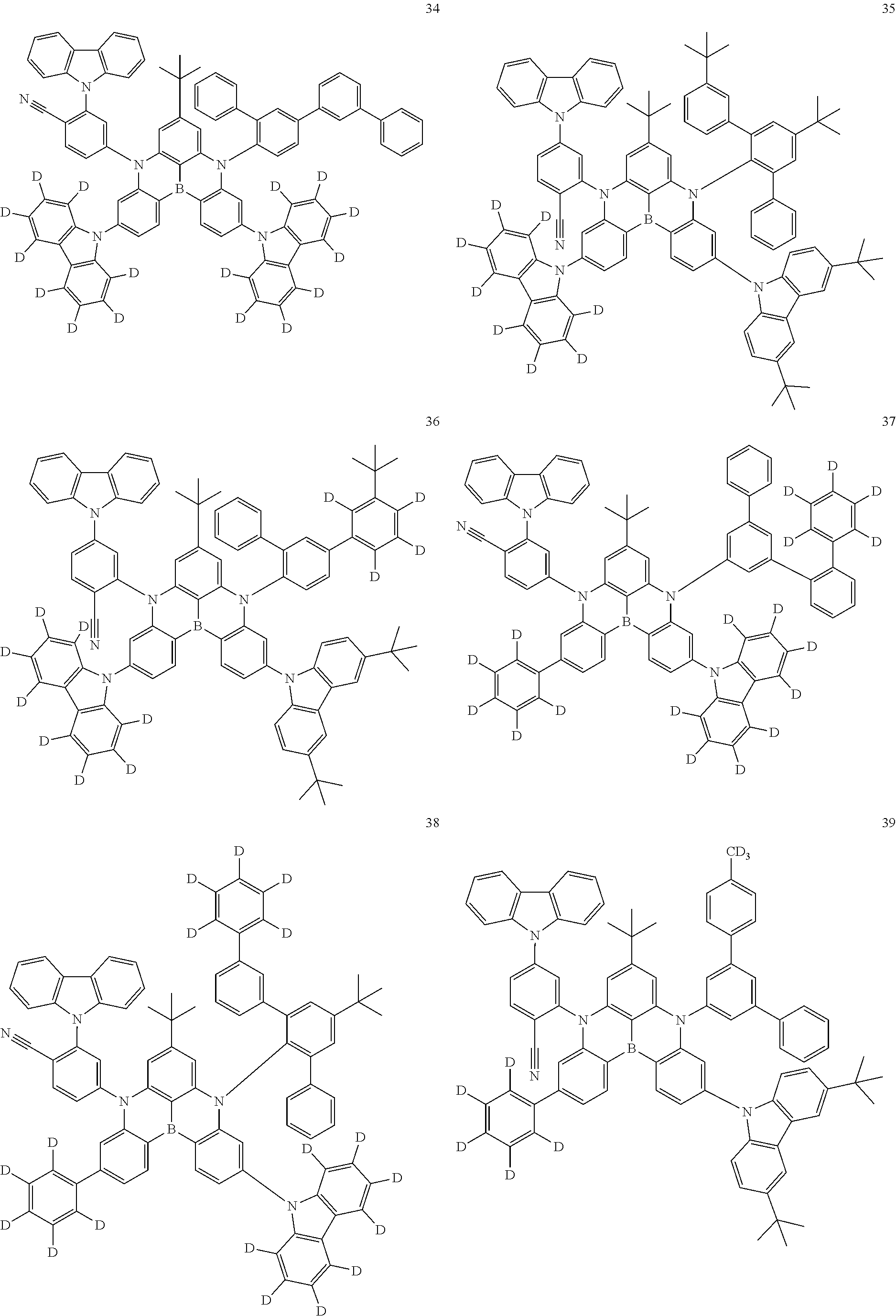 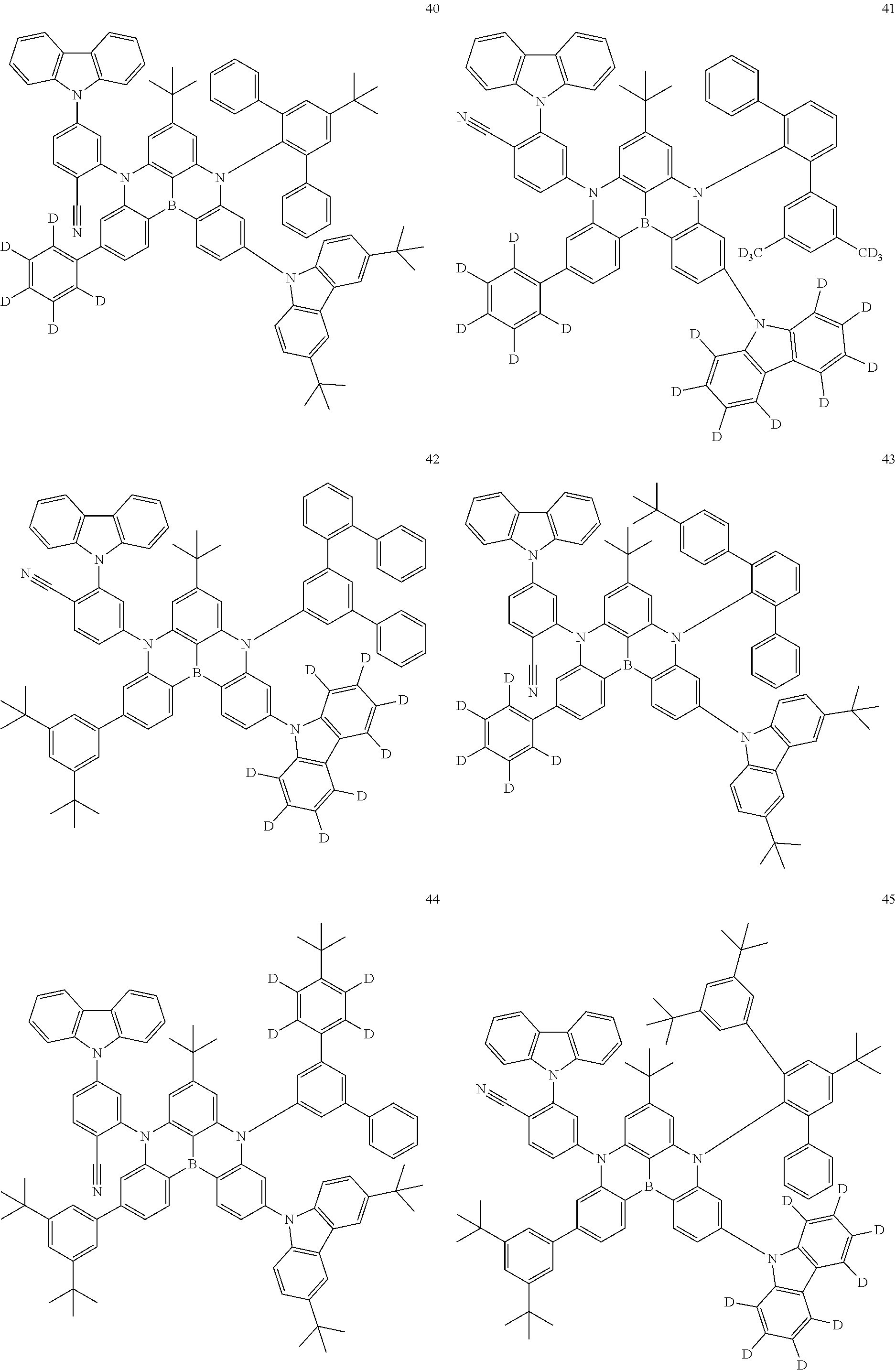 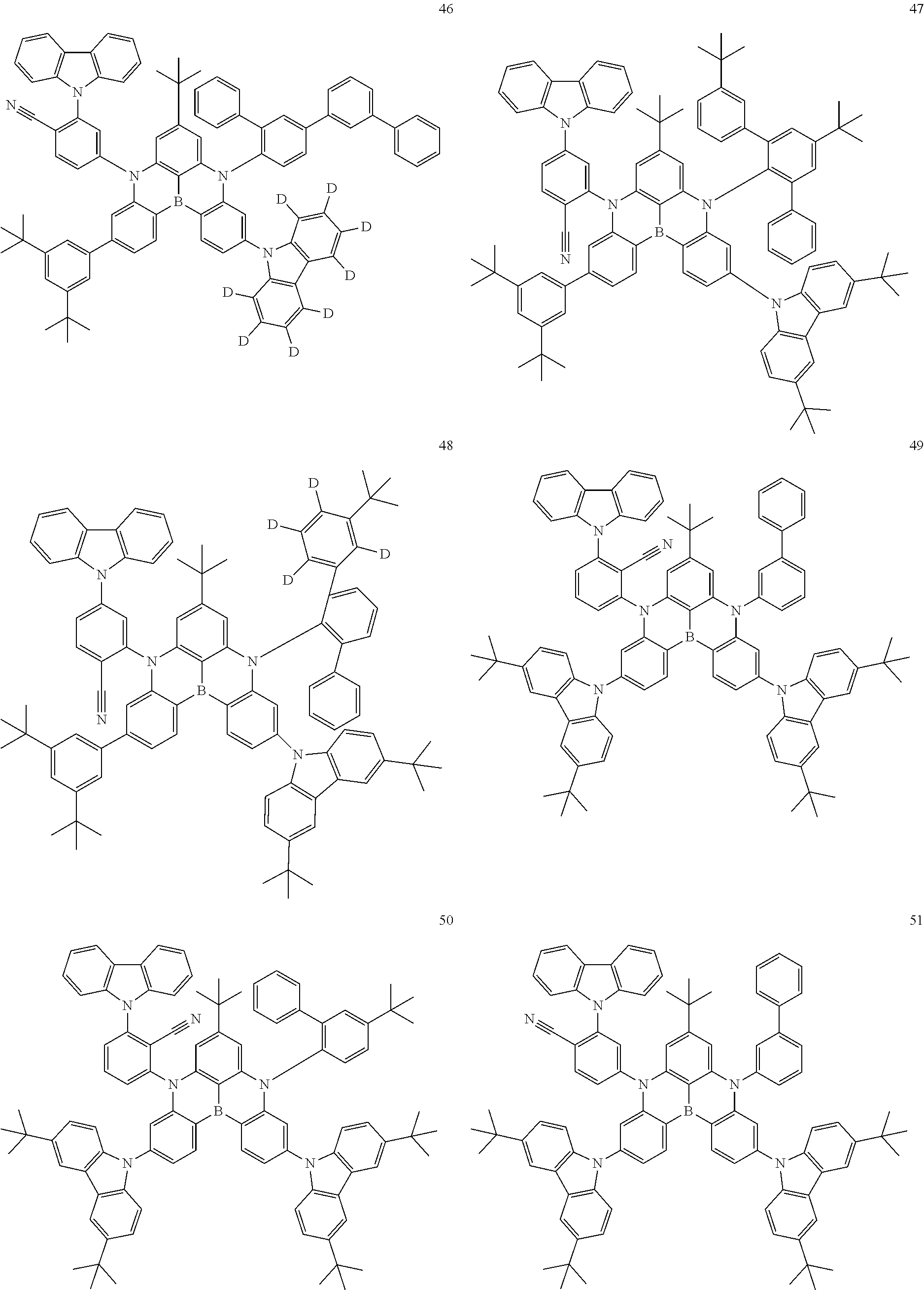 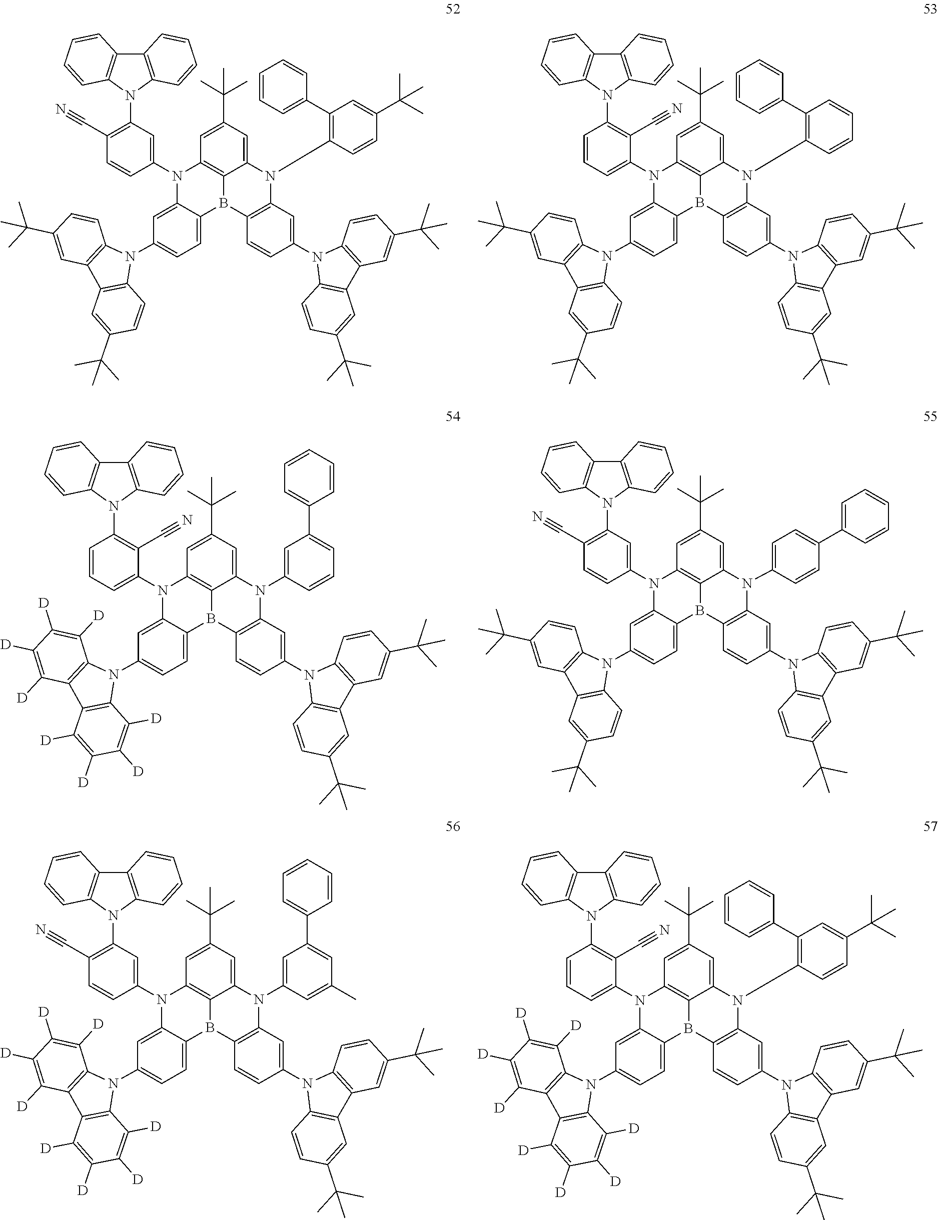 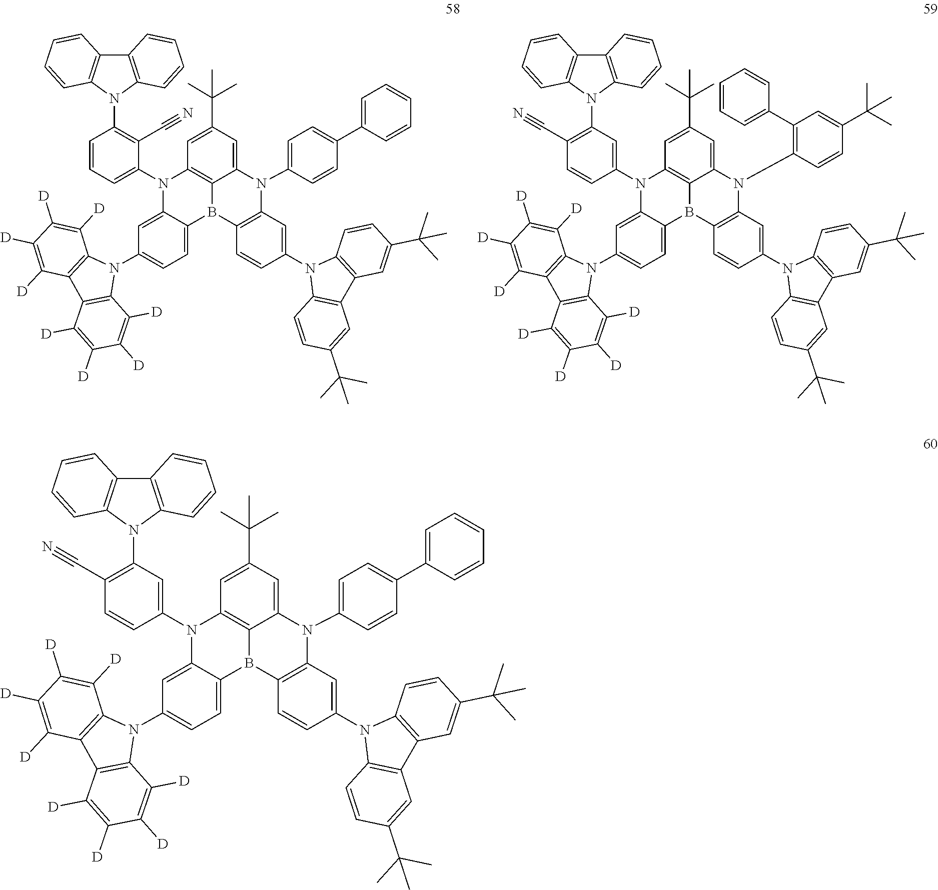 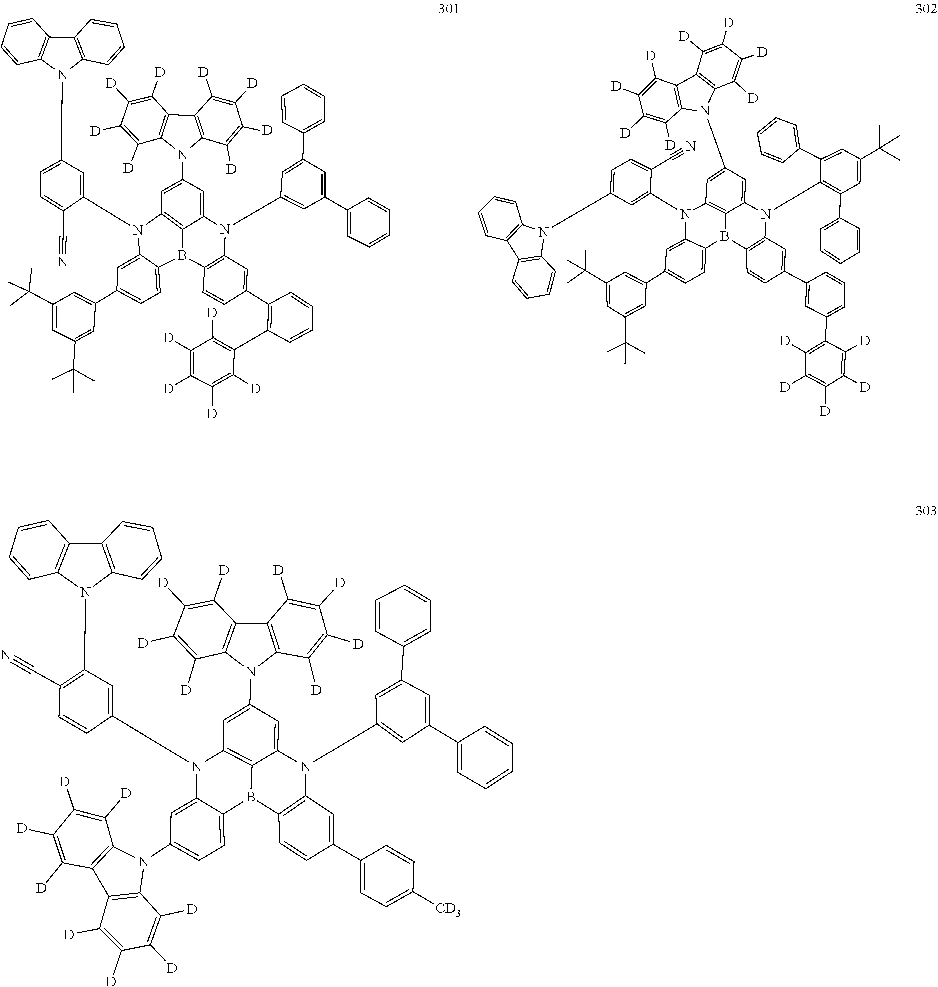 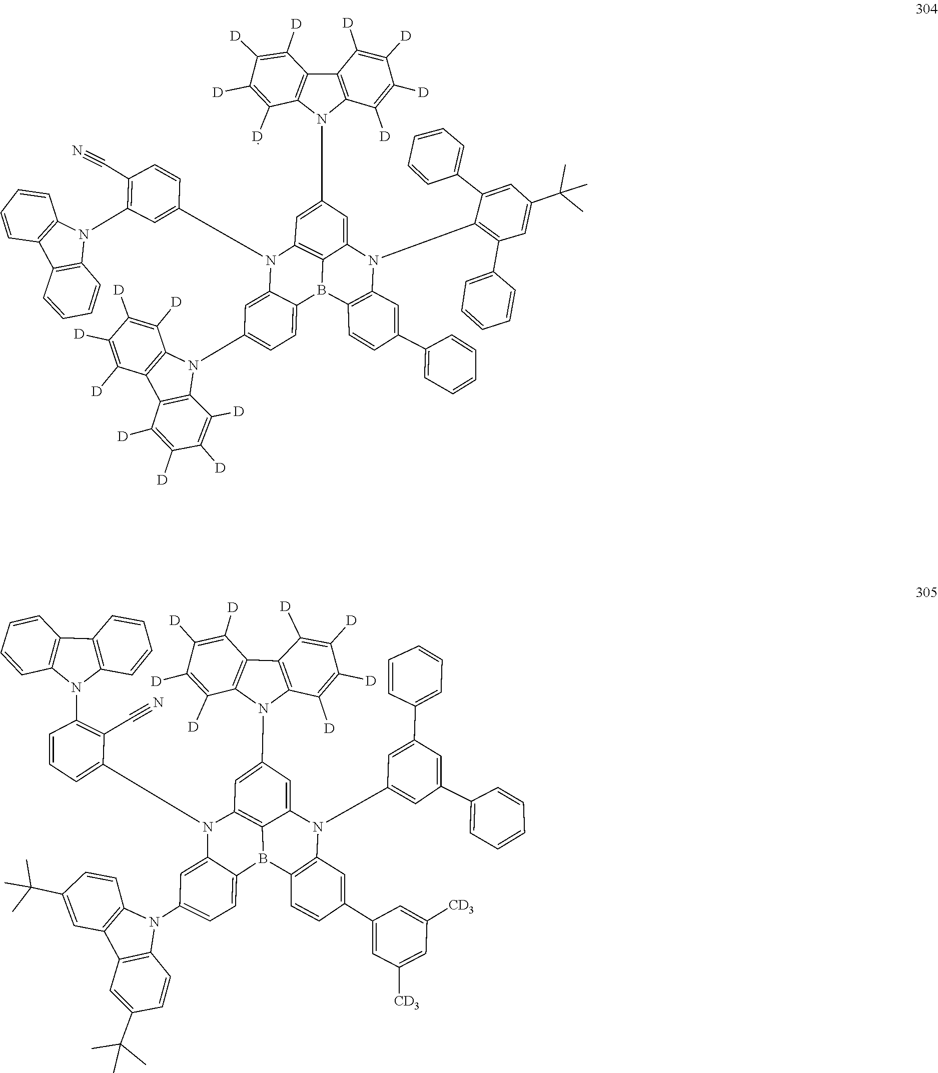 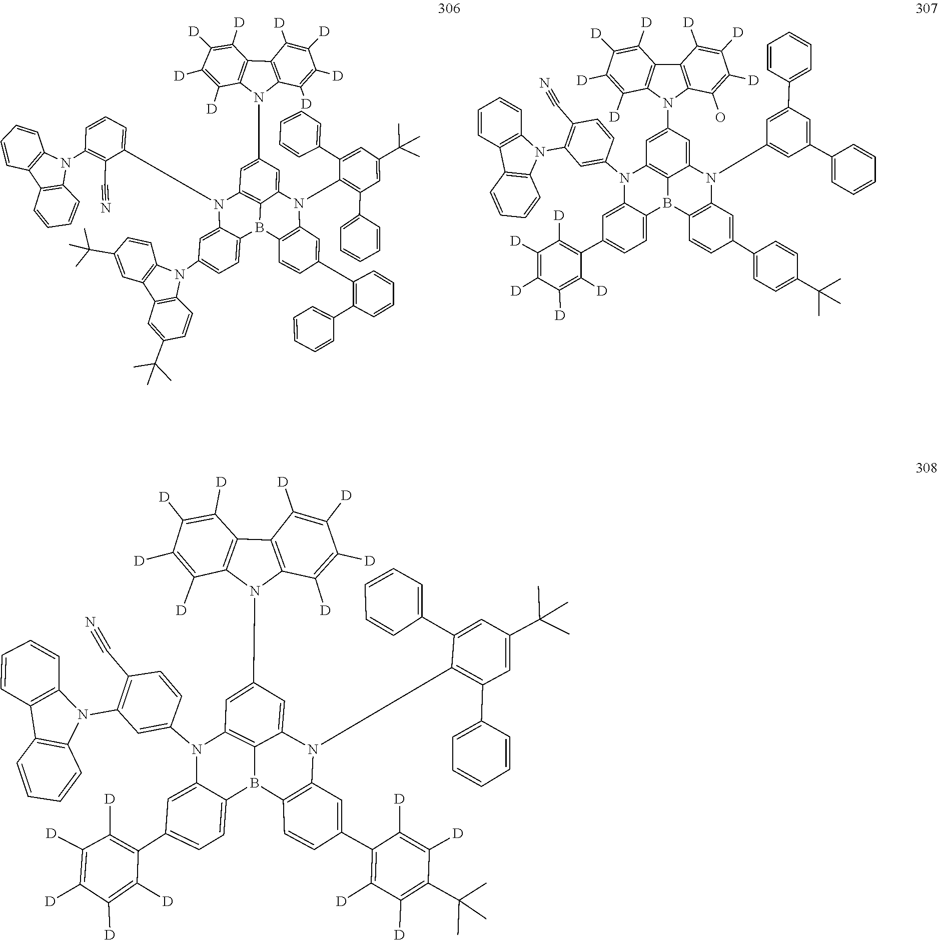 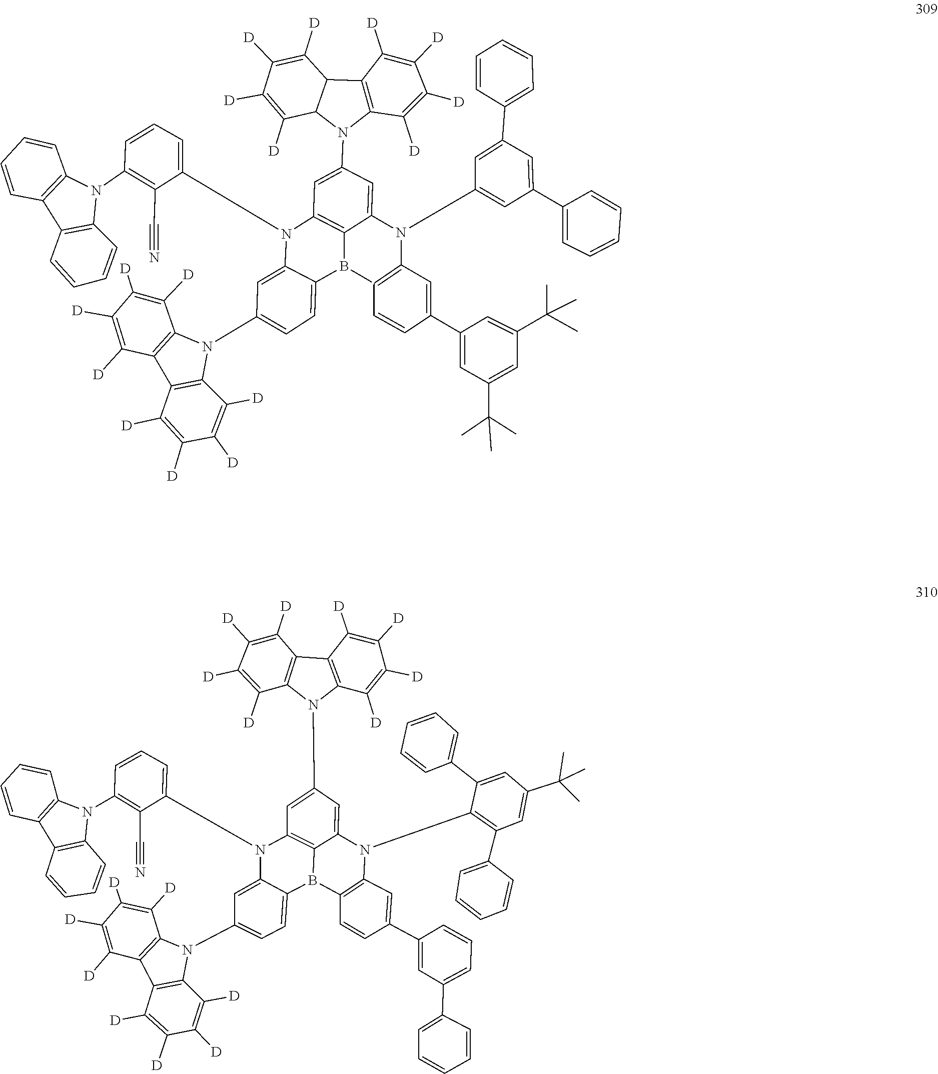 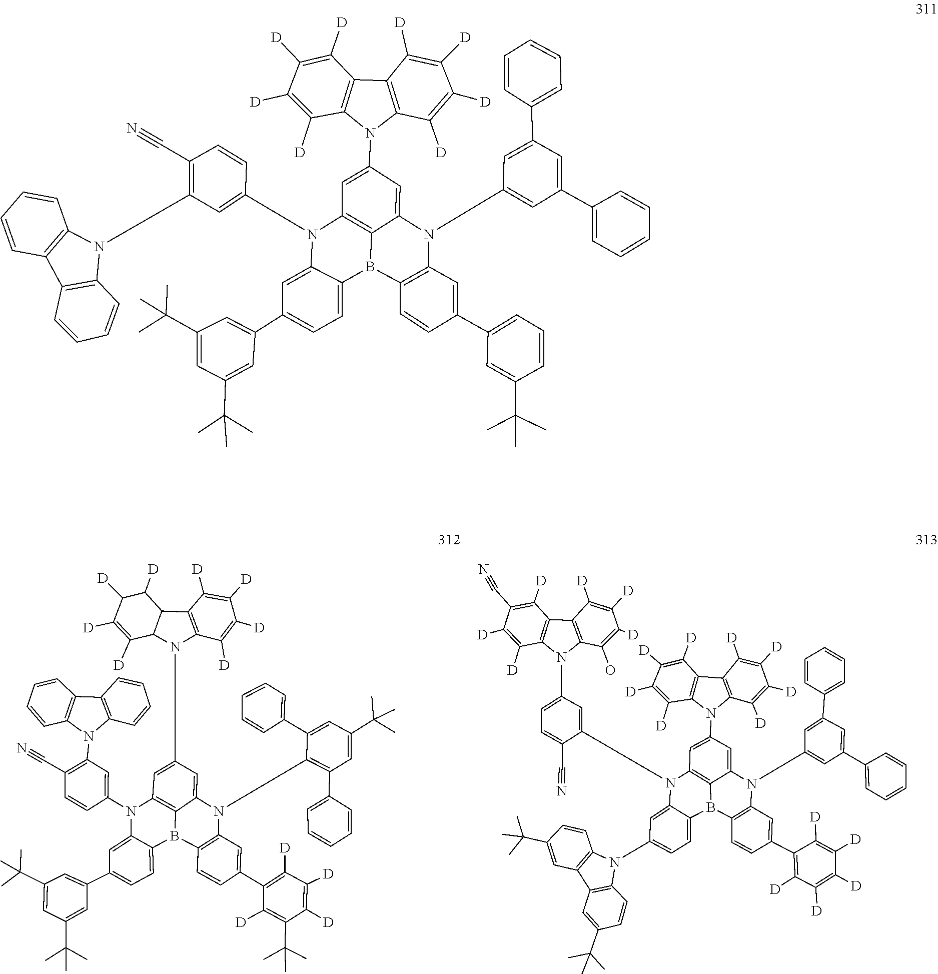 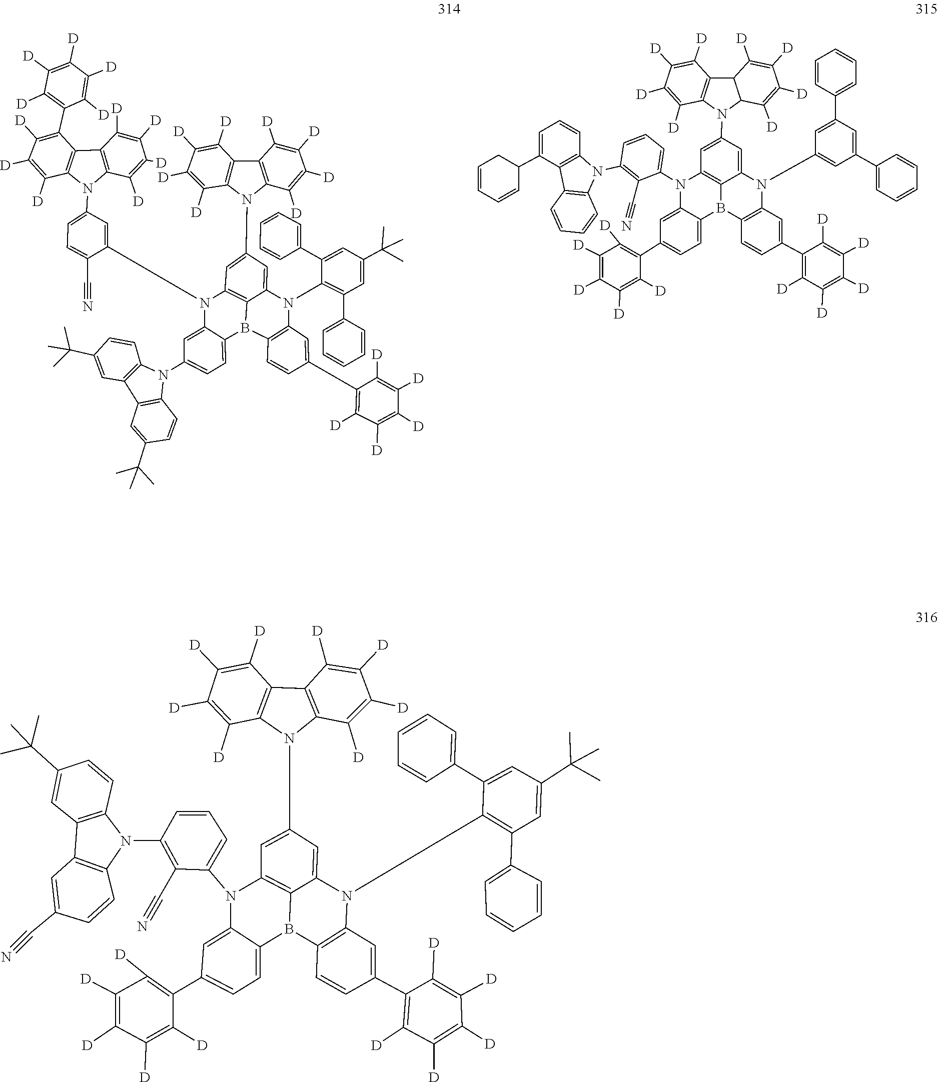 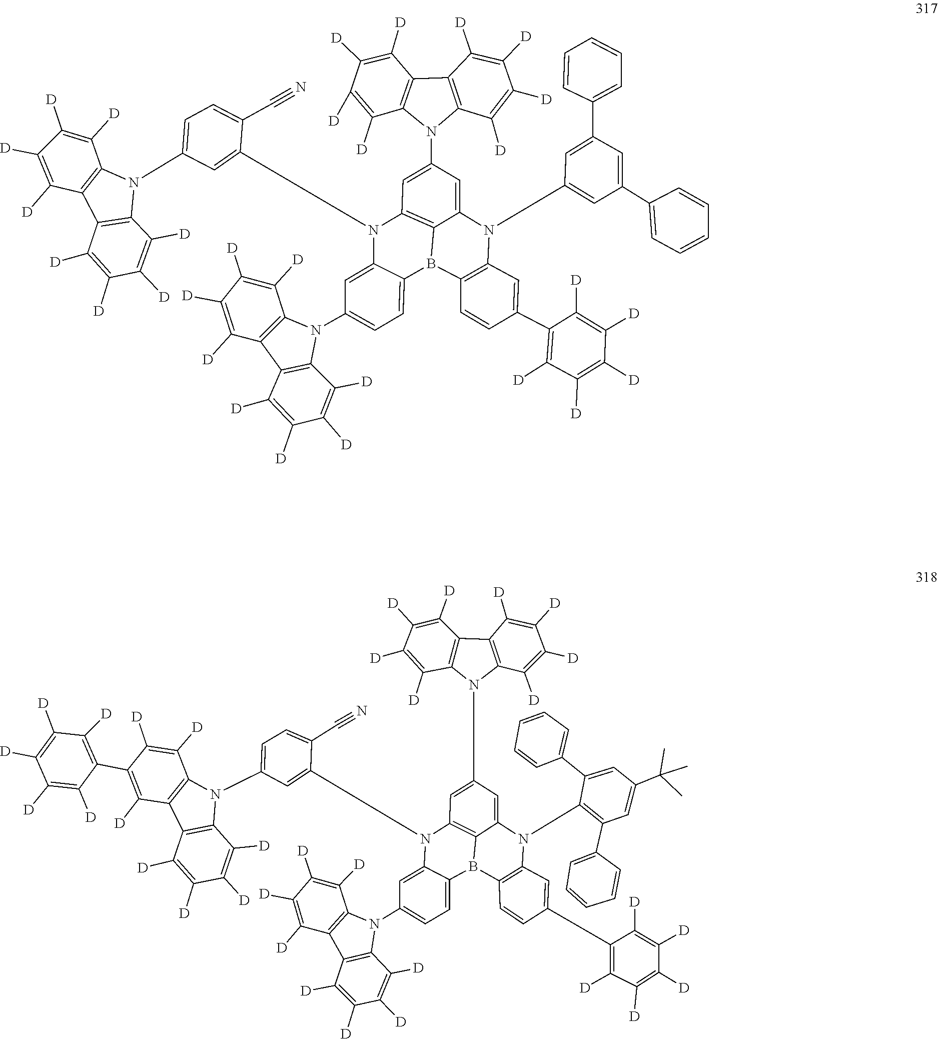 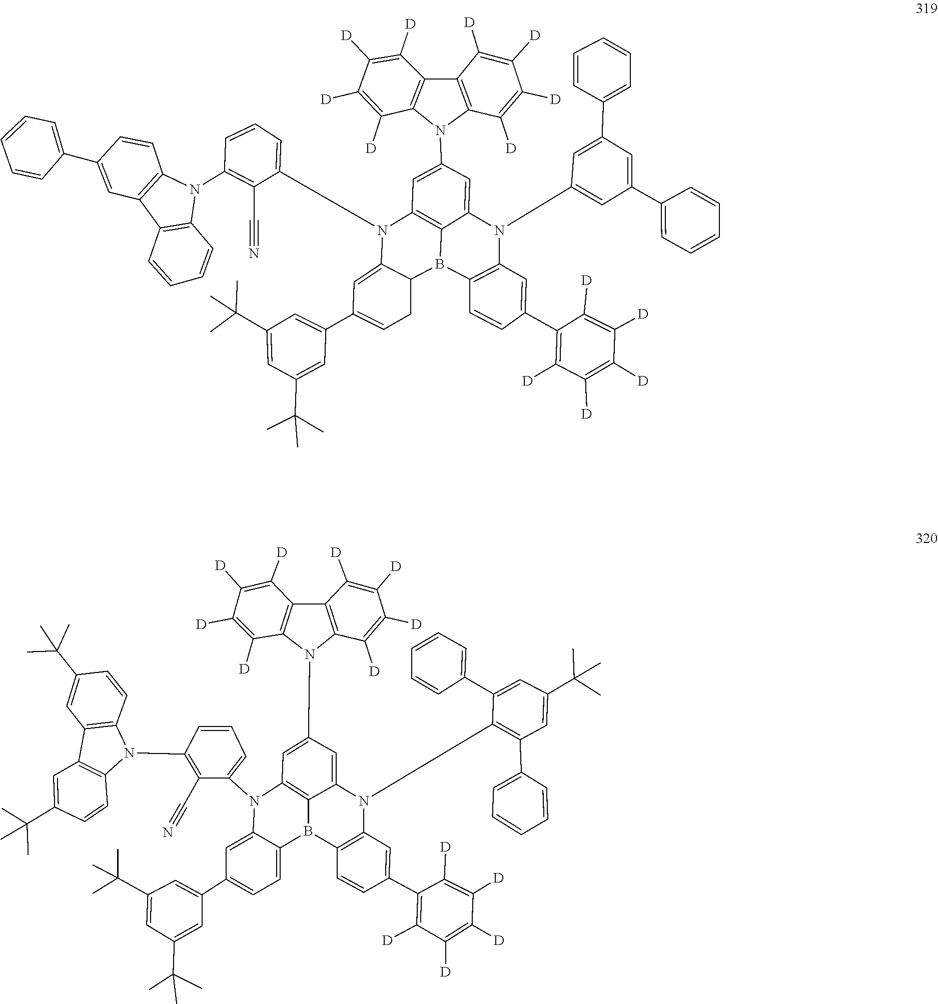 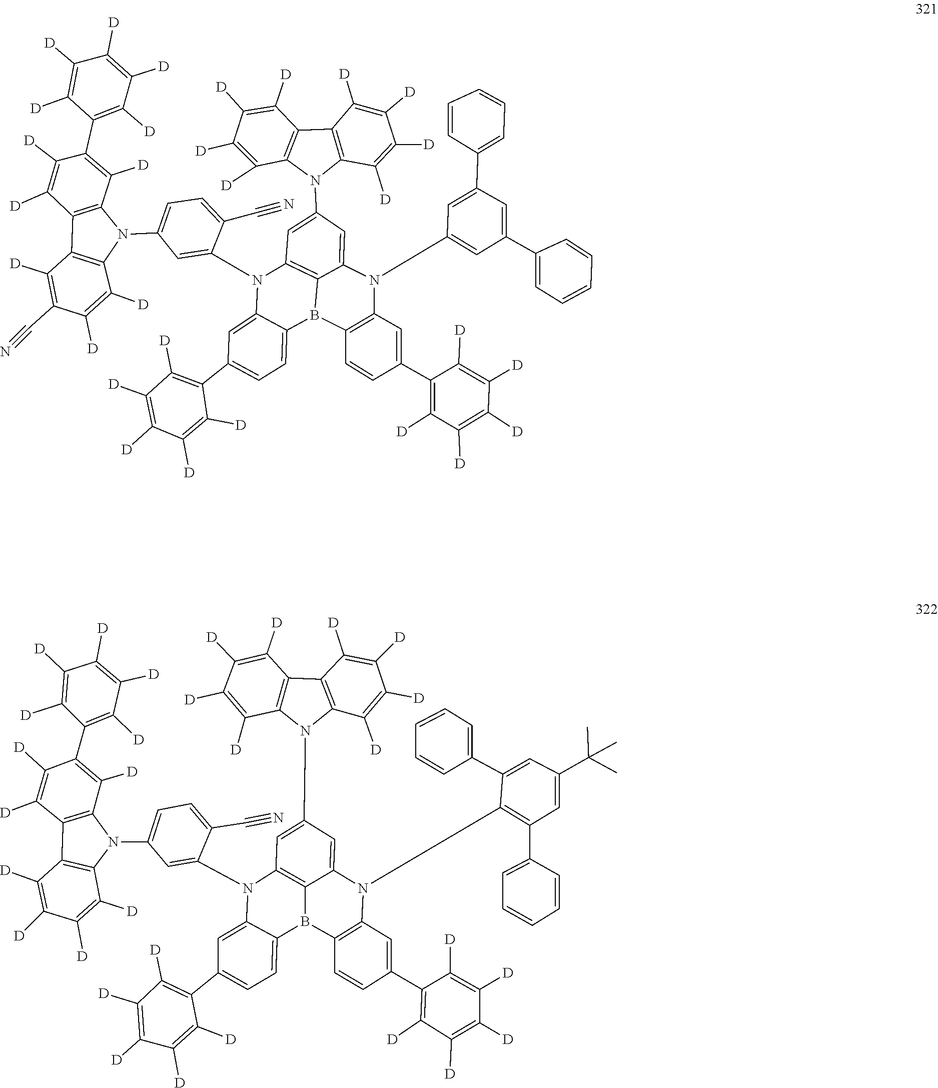 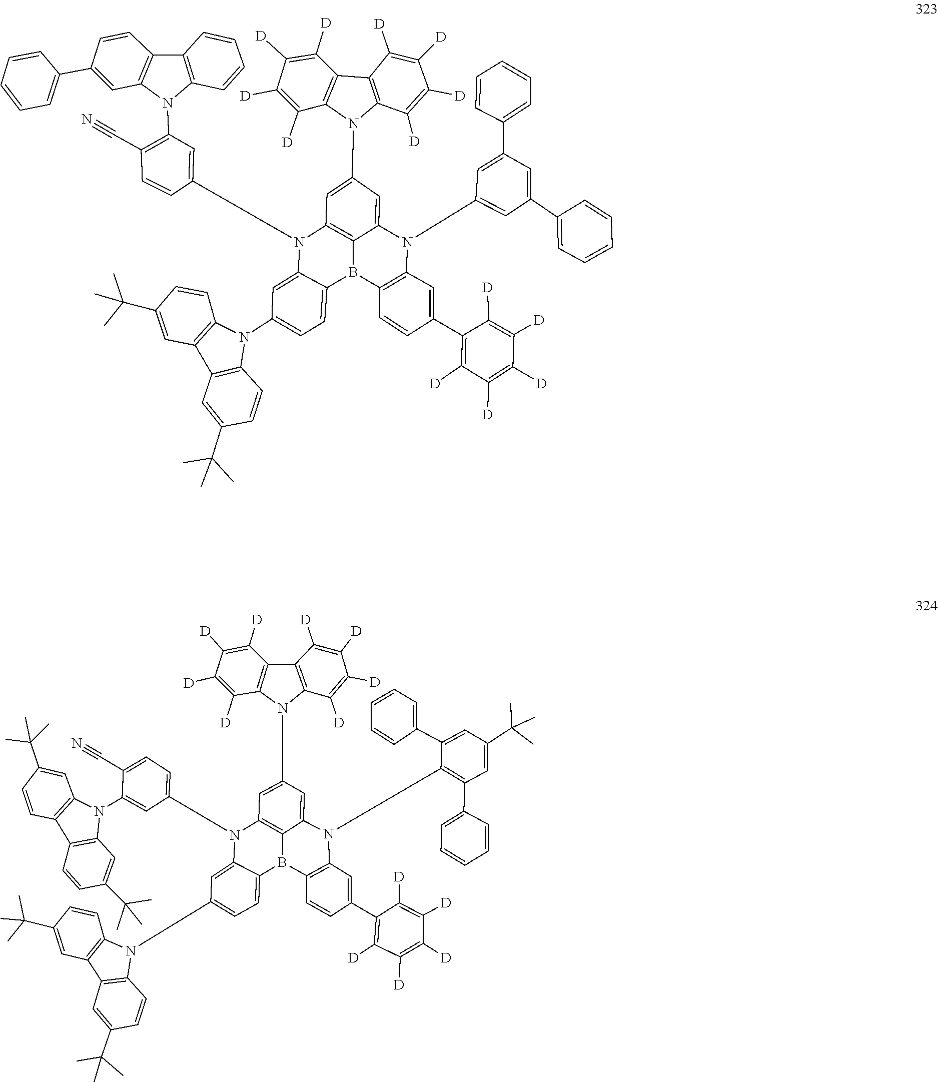 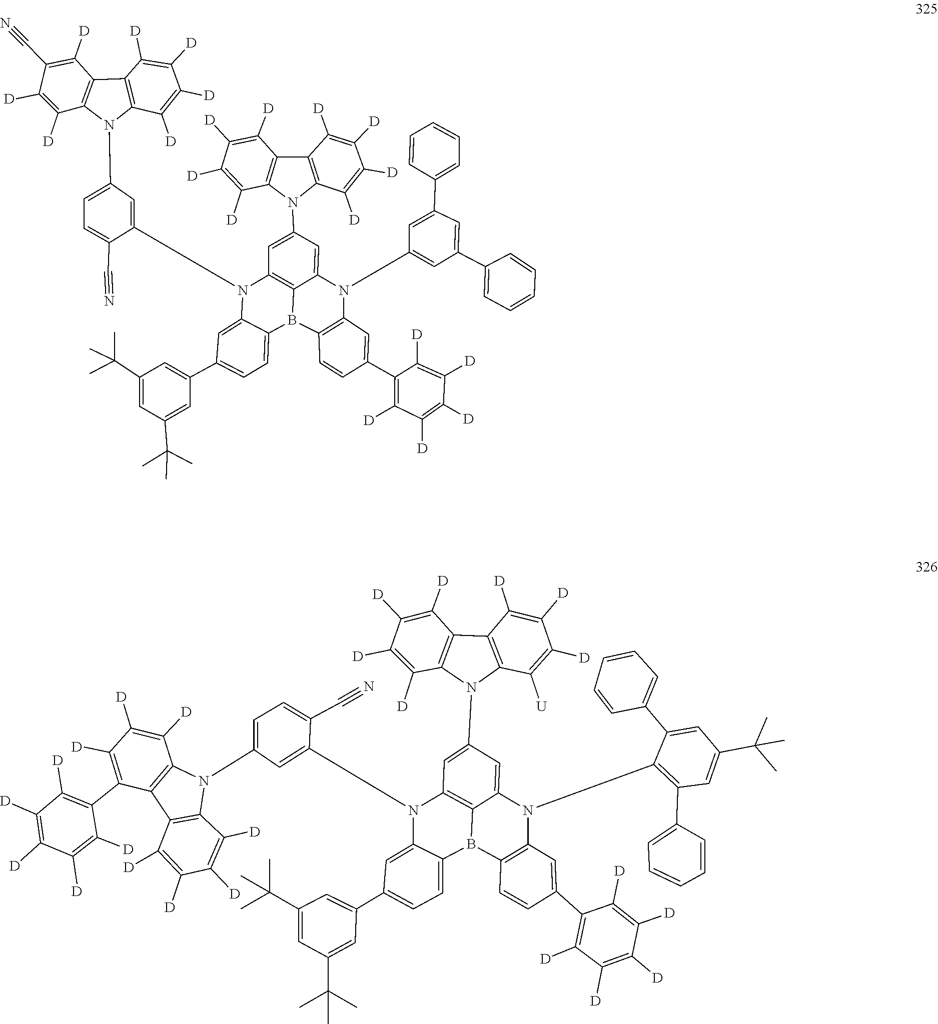 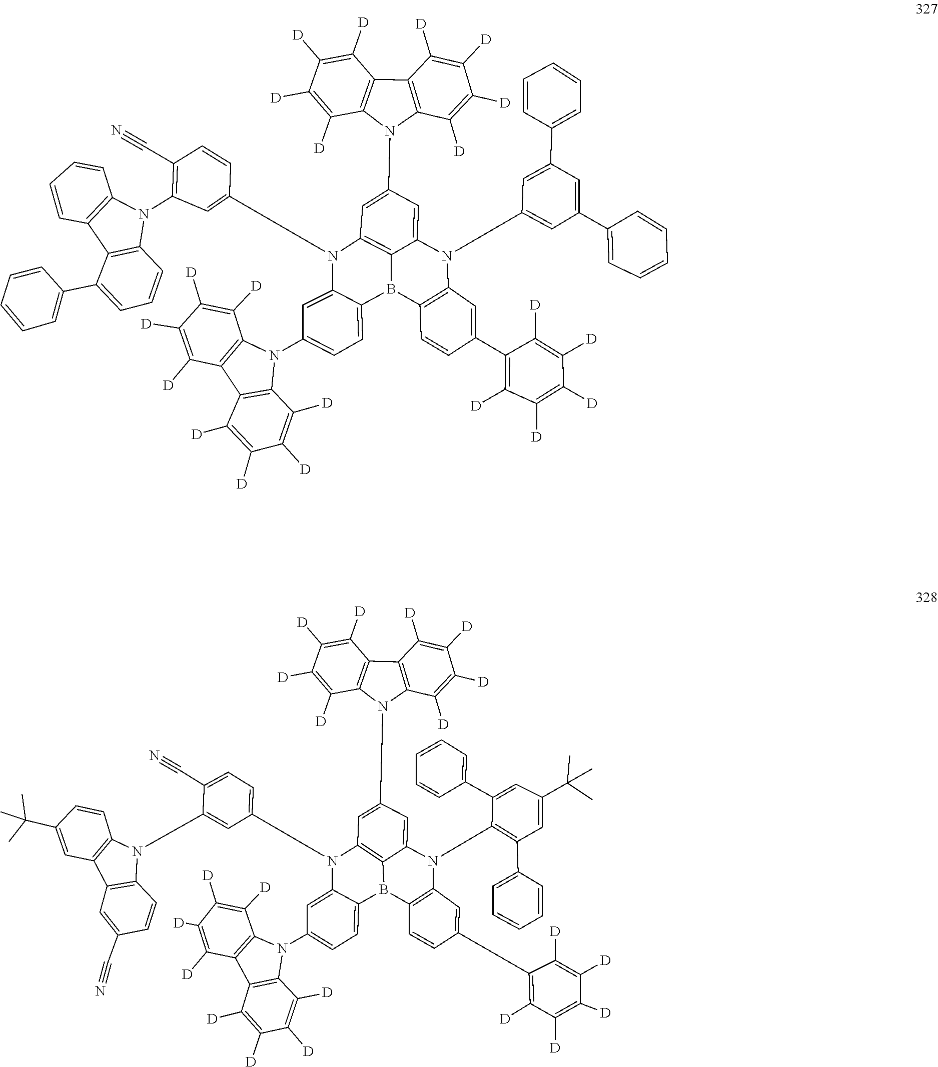 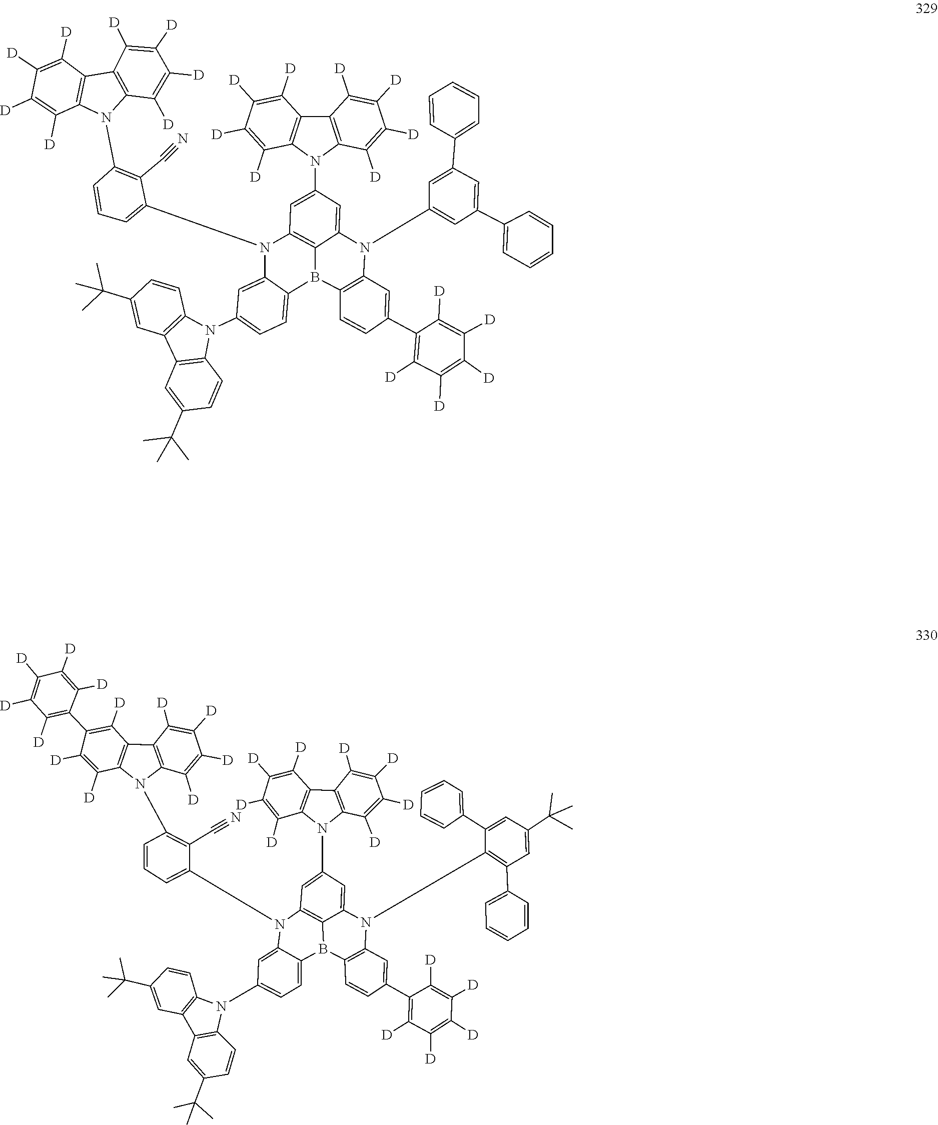 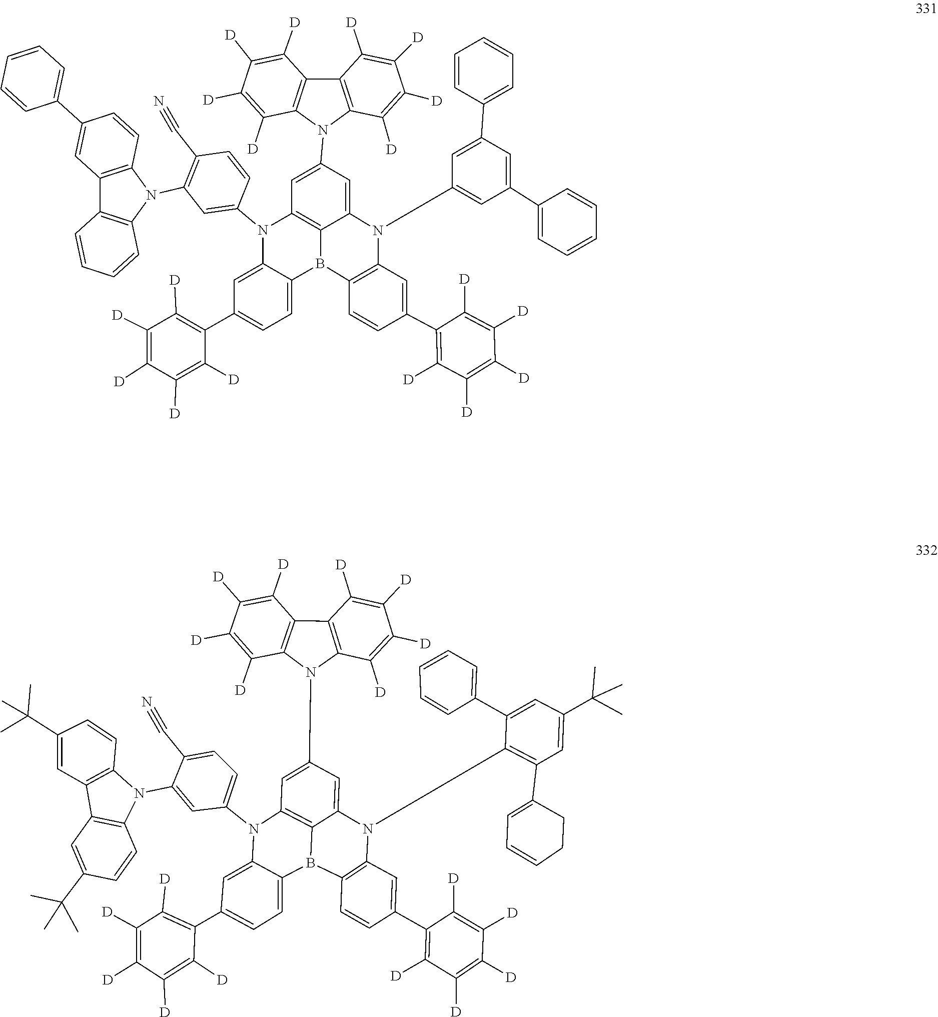 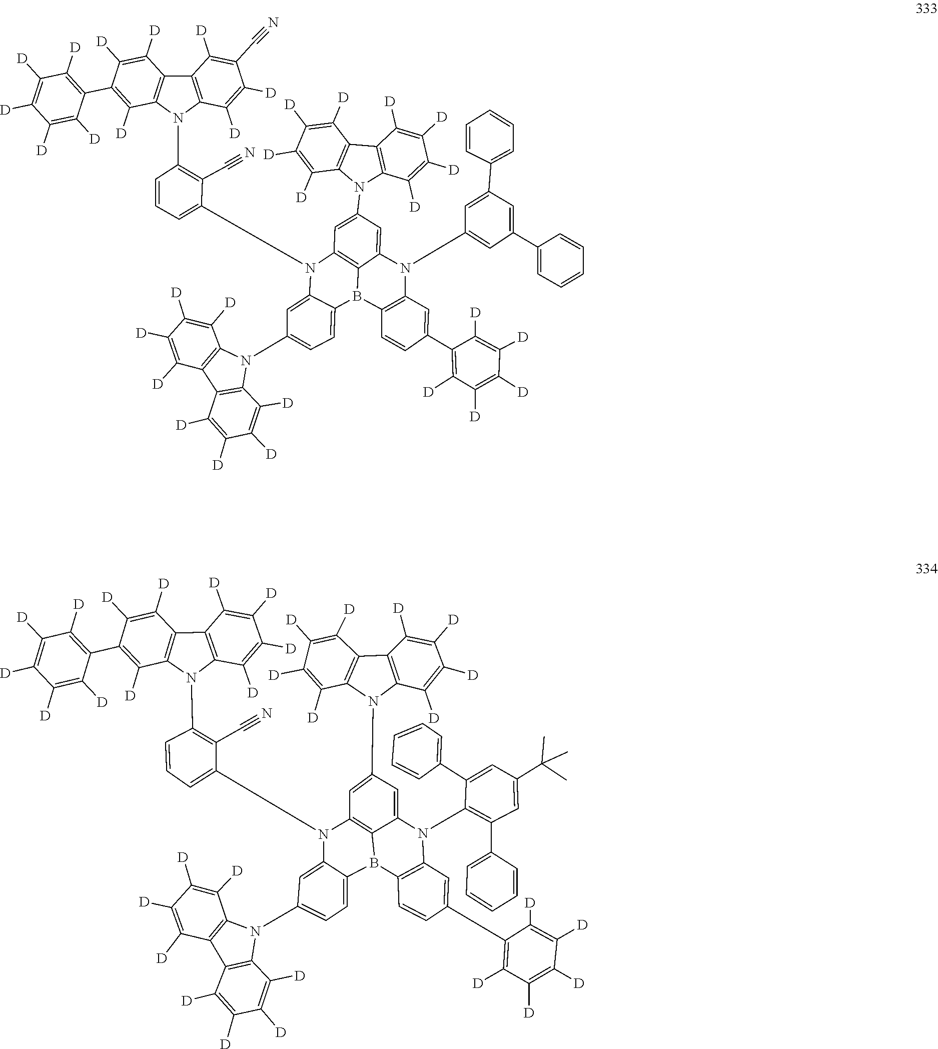 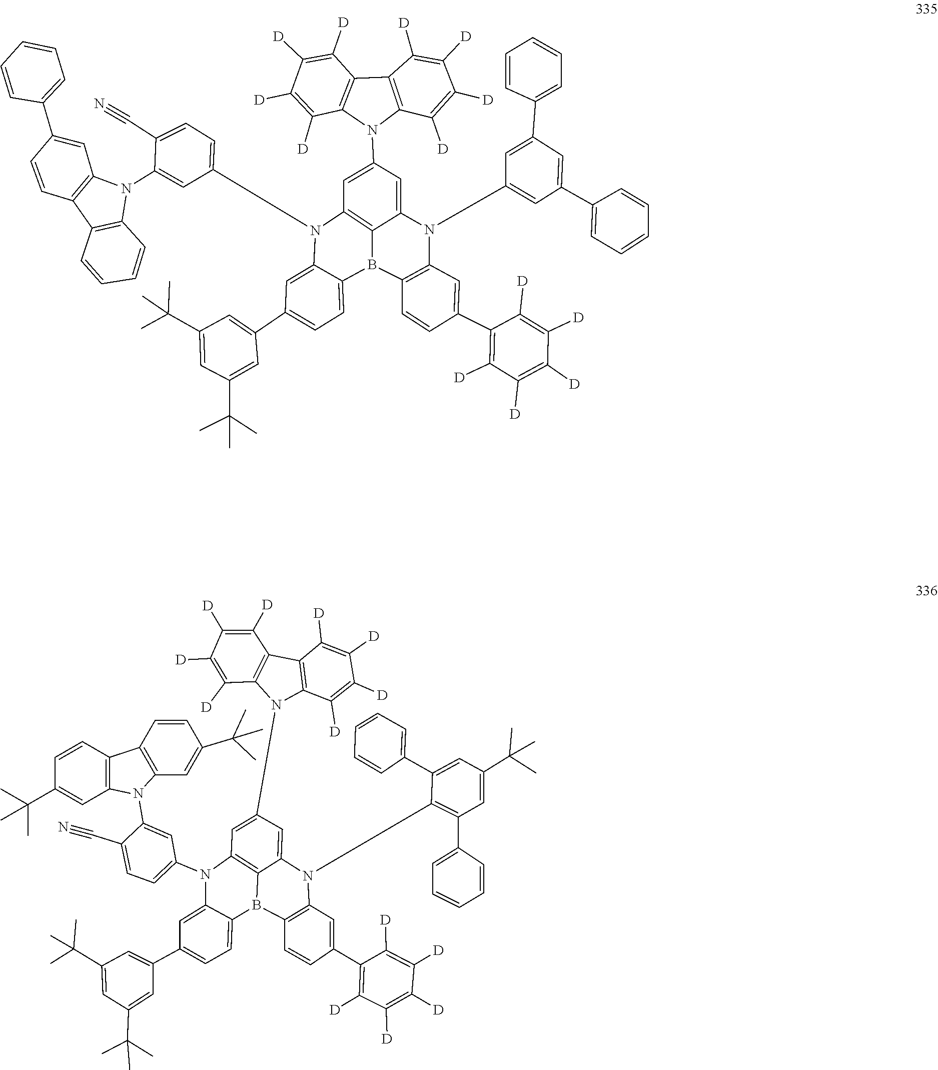 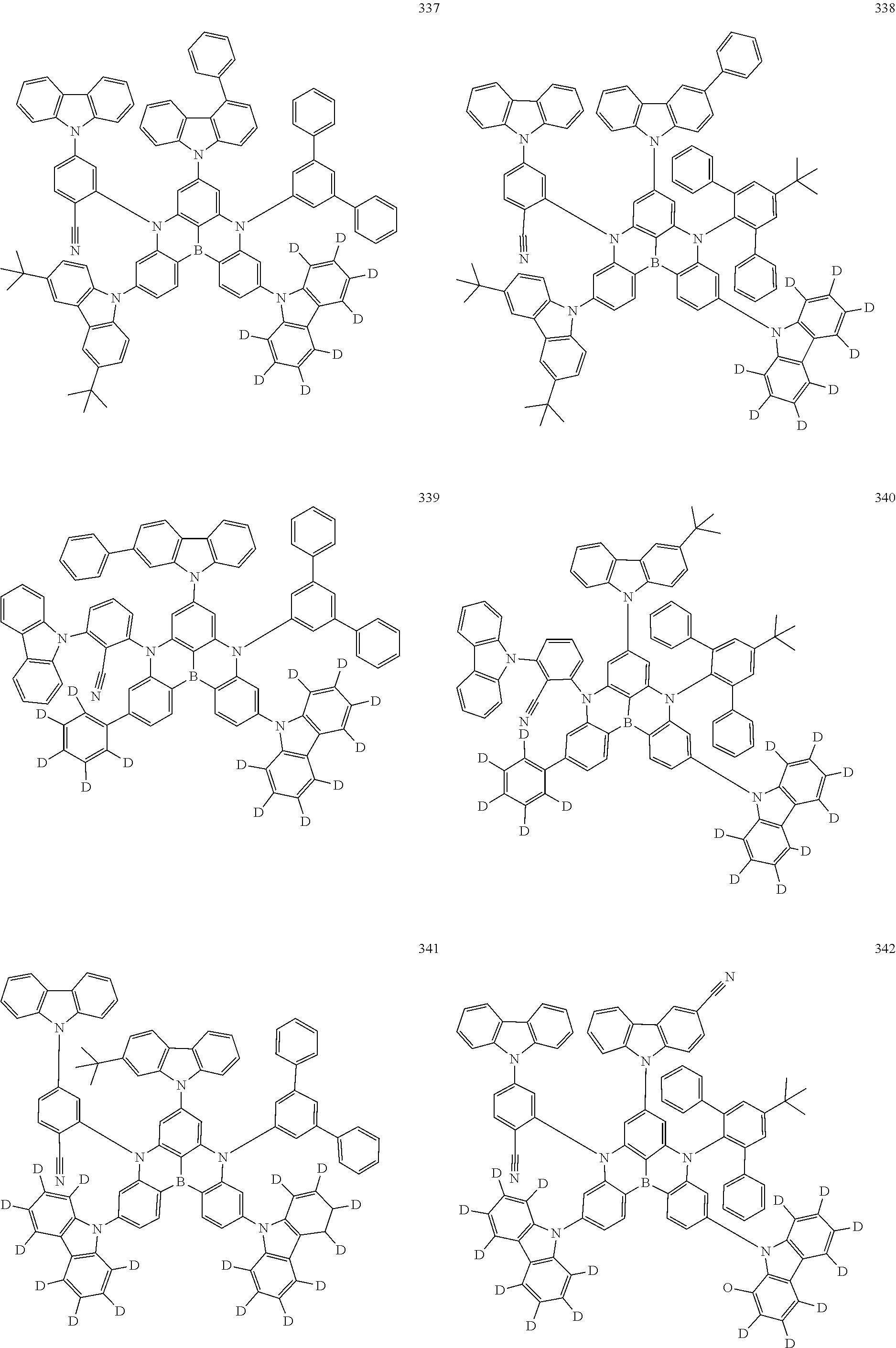 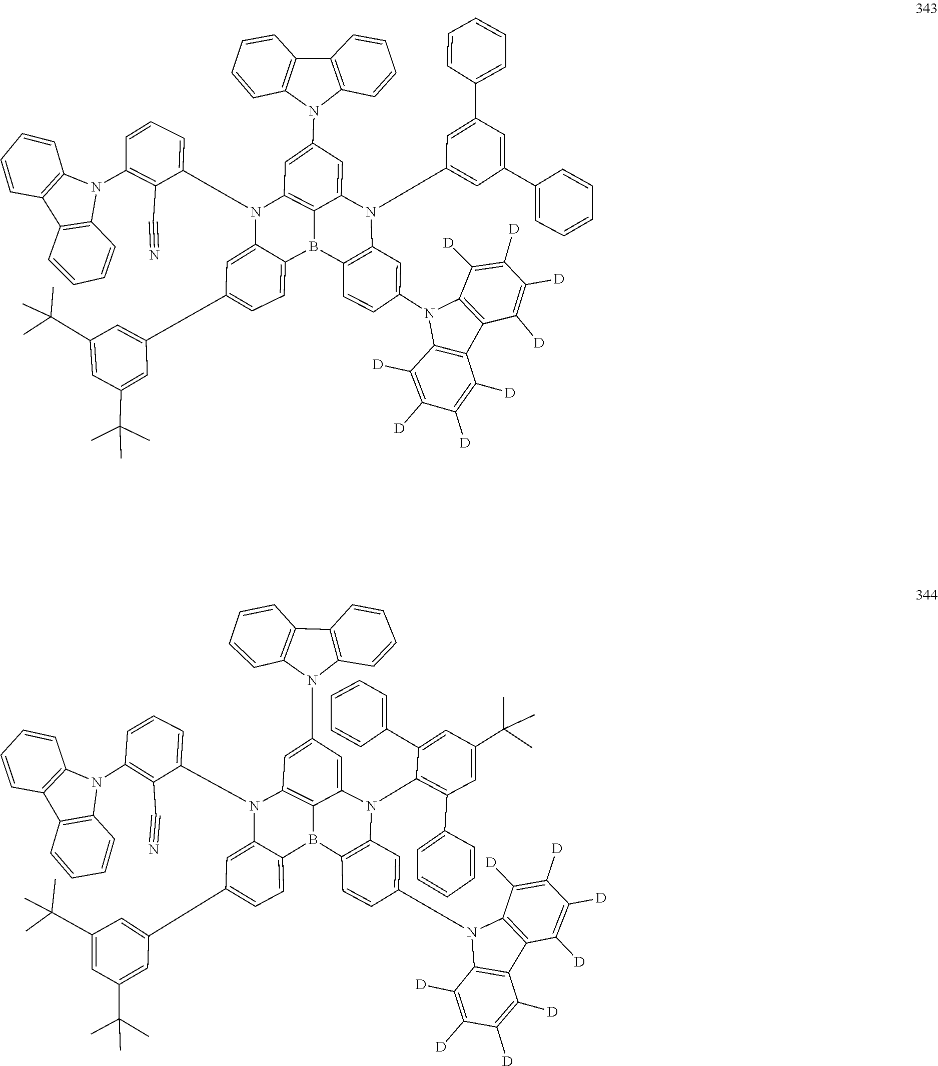 [SMILES: [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1cc(-n3c4ccccc4c4ccccc43)cc3c1B2c1ccc(-c2cc(C(C)(C)C)cc(C(C)(C)C)c2)cc1N3c1cccc(-n2c3ccccc3c3ccccc32)c1C#N ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4ccccc4c4ccccc43)cc3c1B2c1ccc(-c2cc(C(C)(C)C)cc(C(C)(C)C)c2)cc1N3c1cccc(-n2c3ccccc3c3ccccc32)c1C#N] 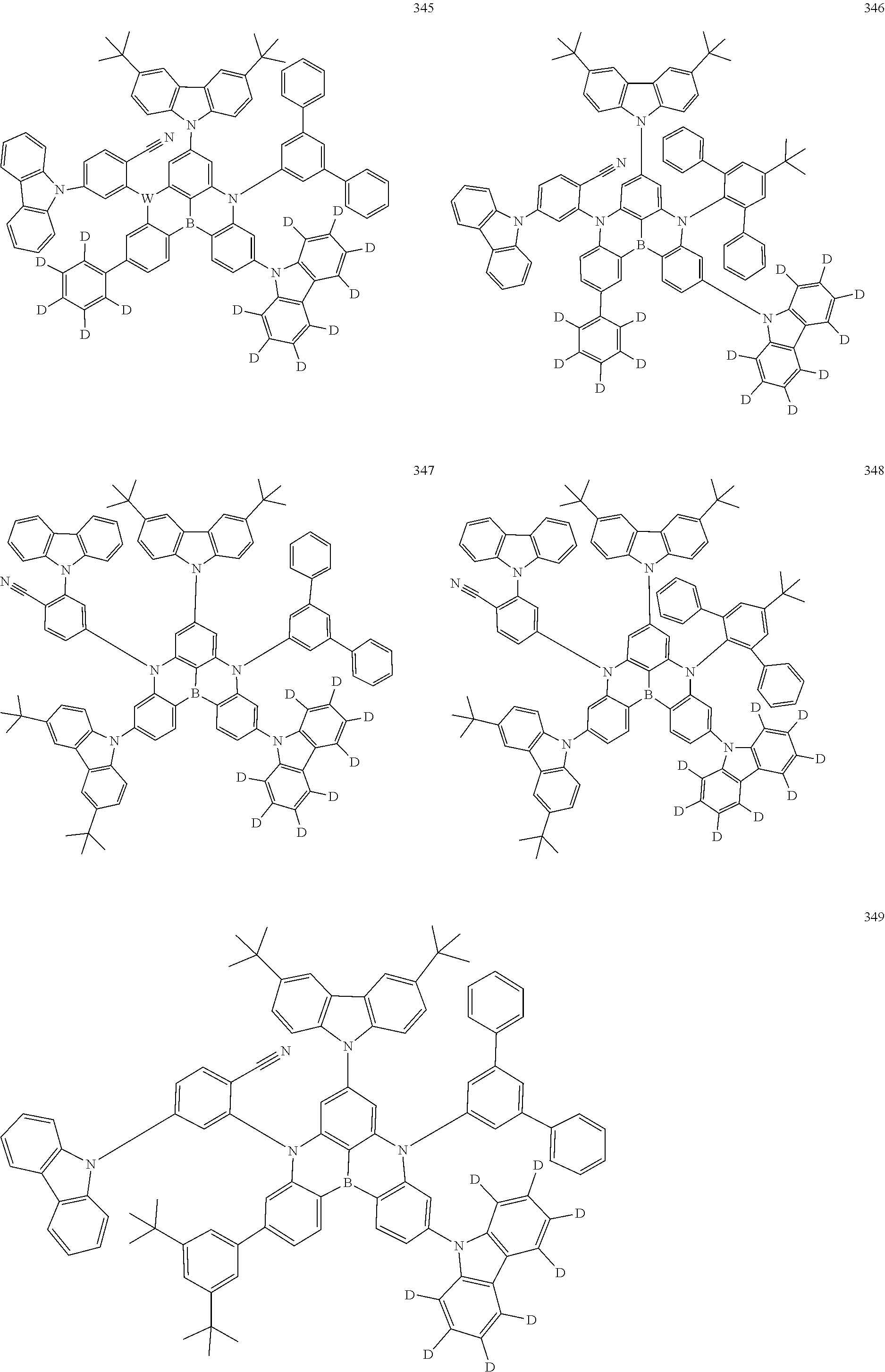 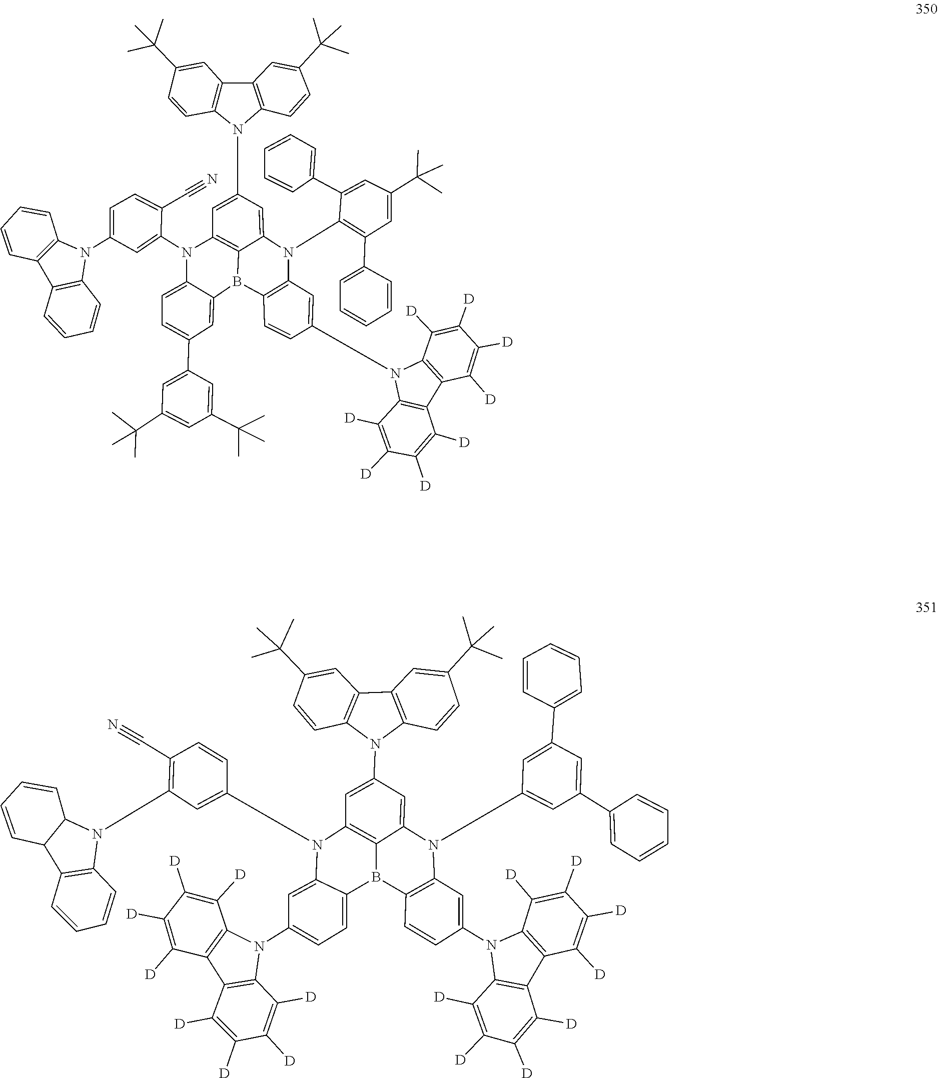 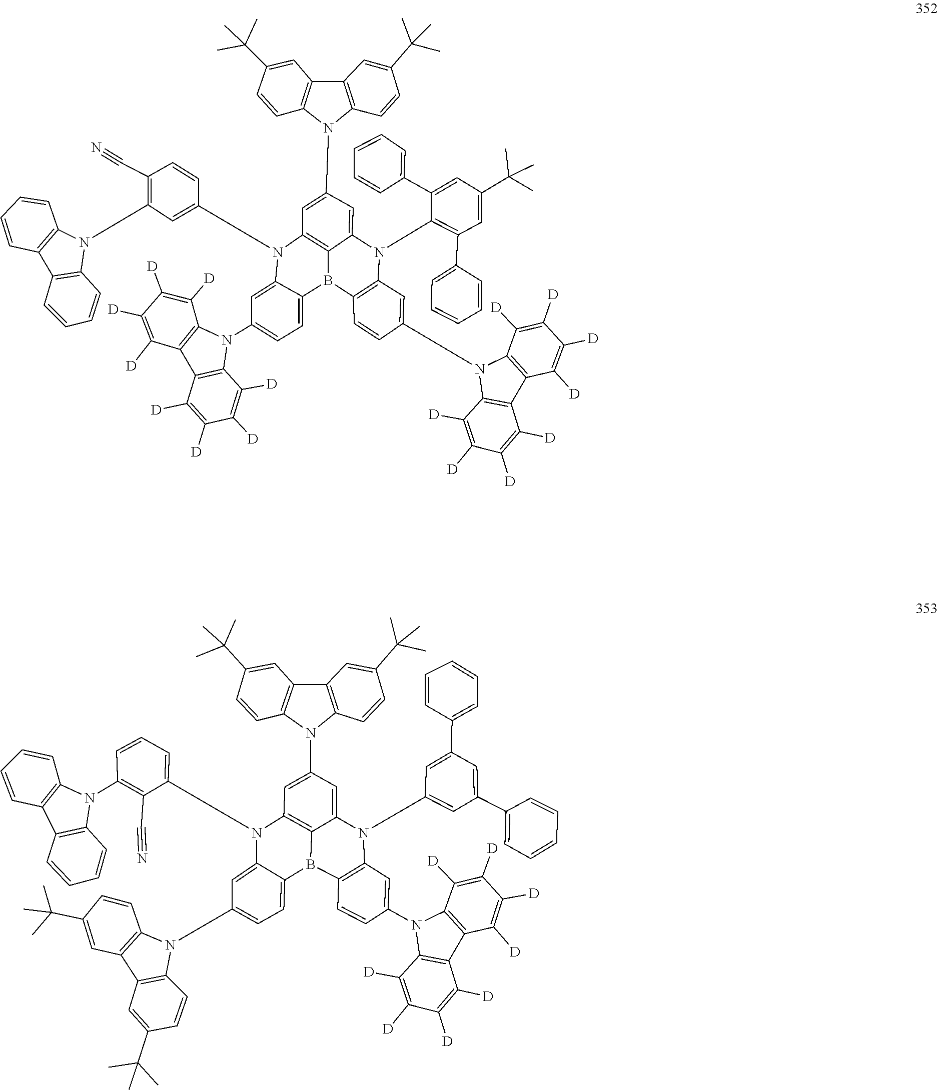 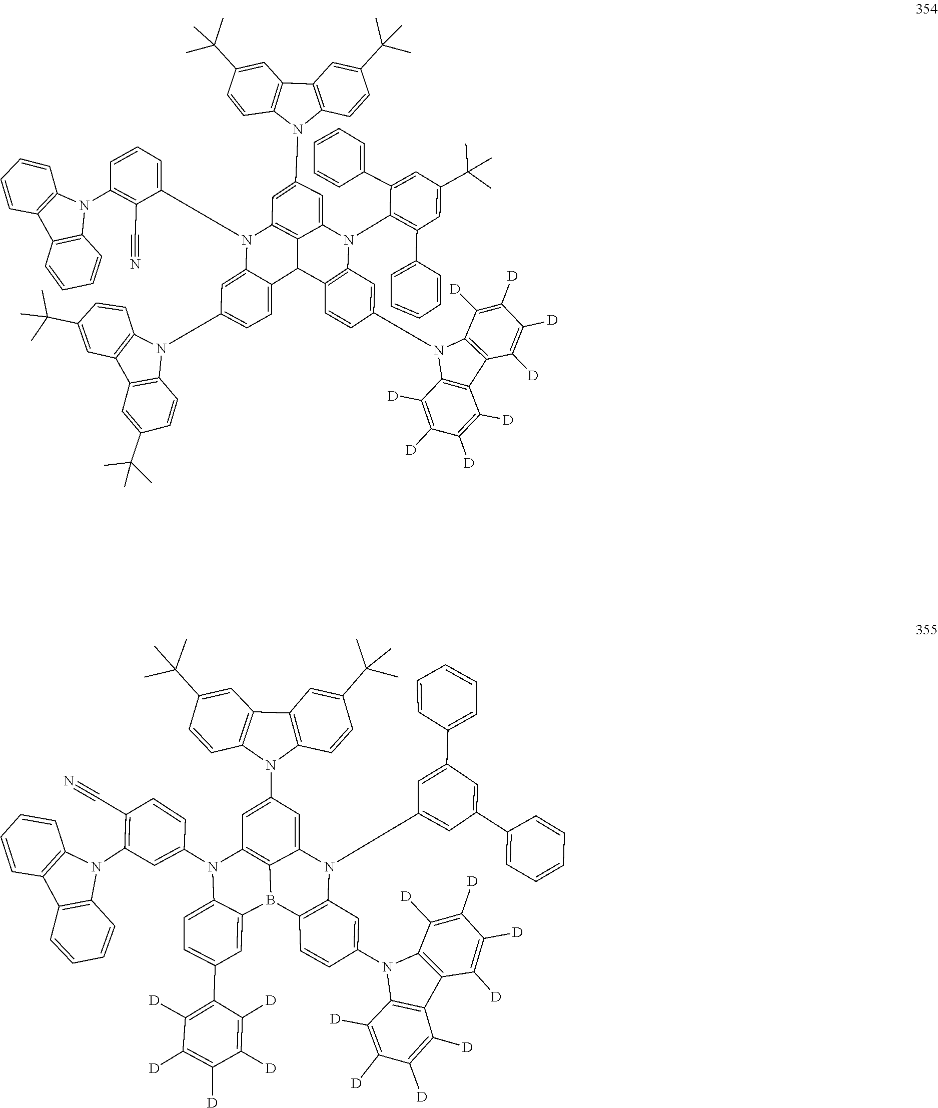 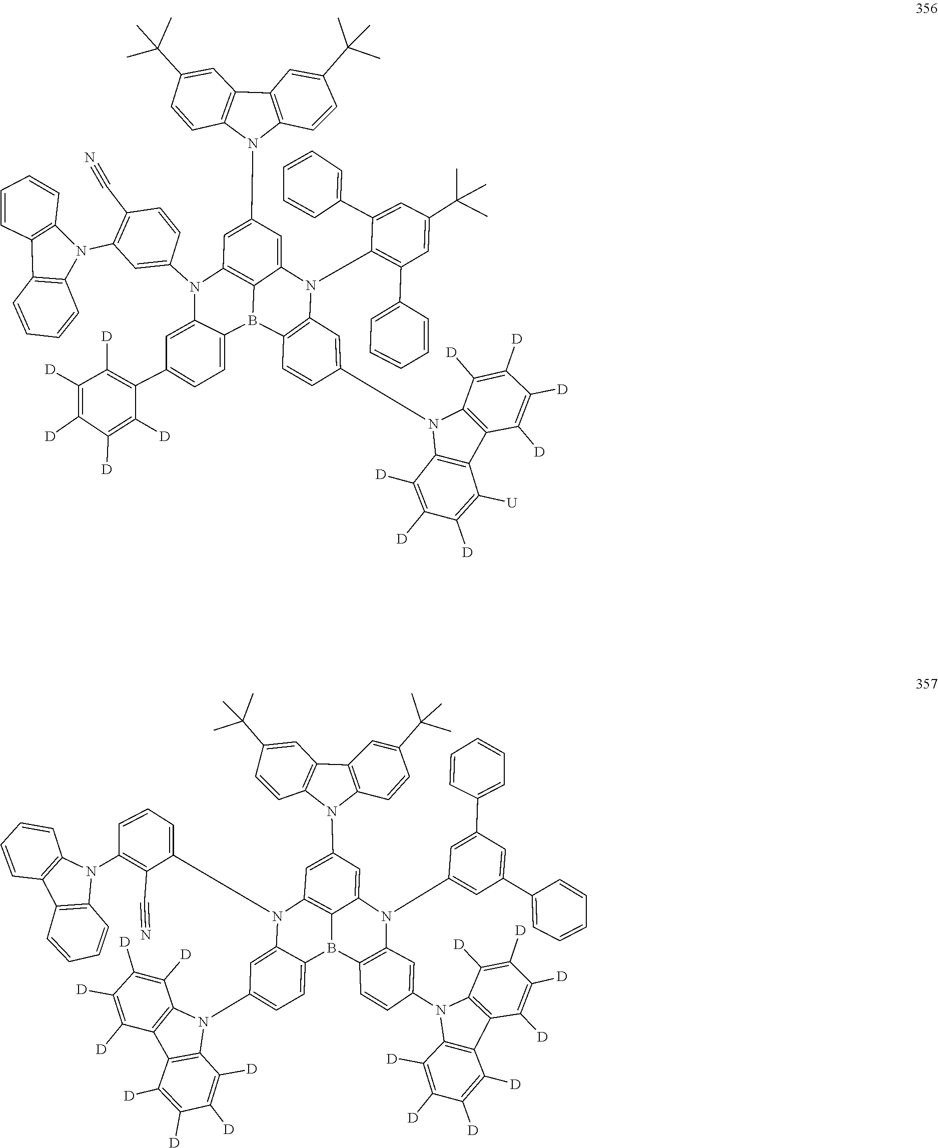 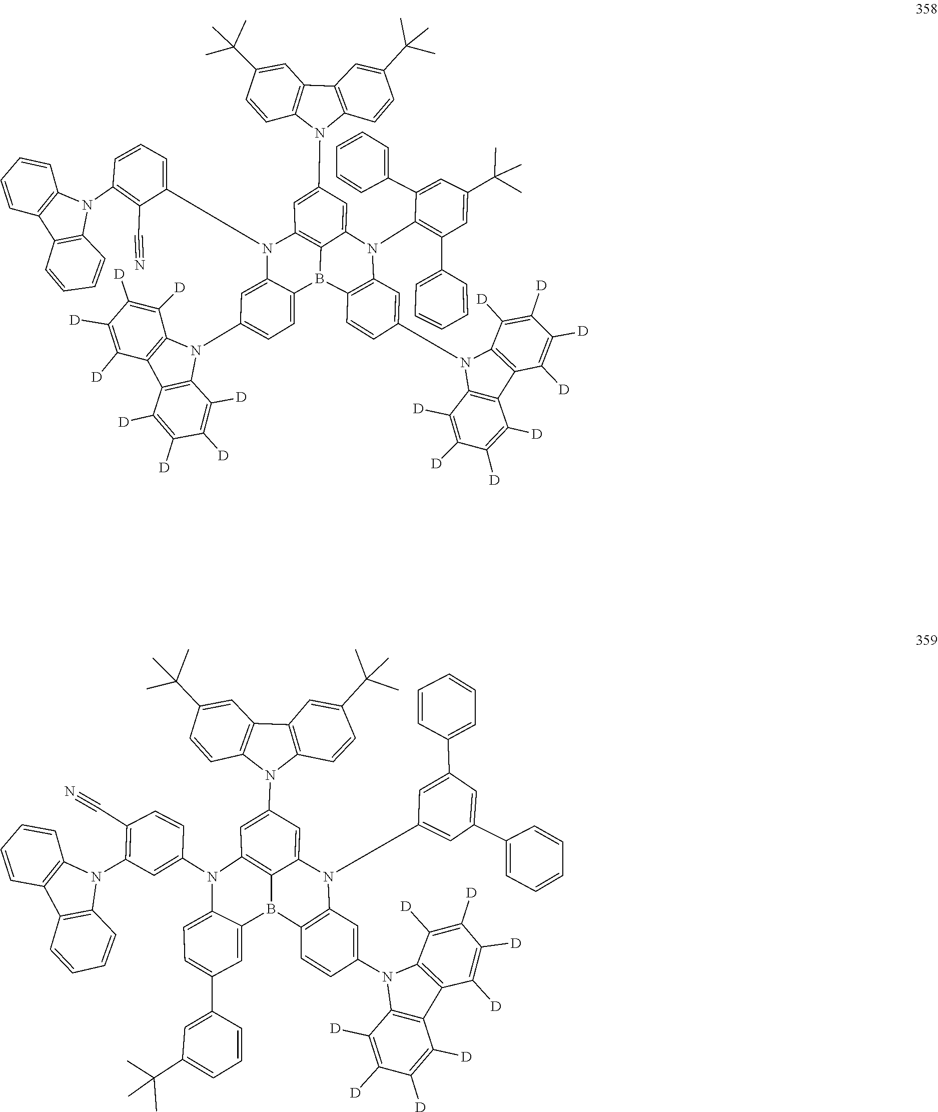 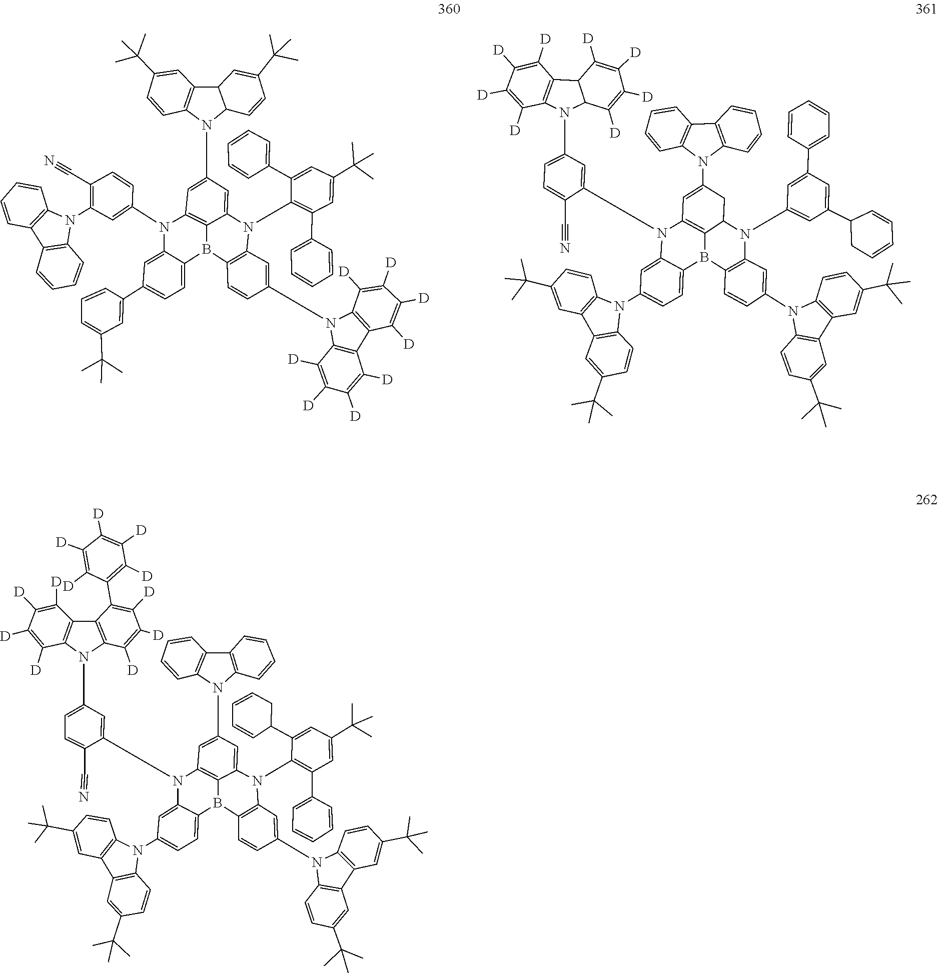 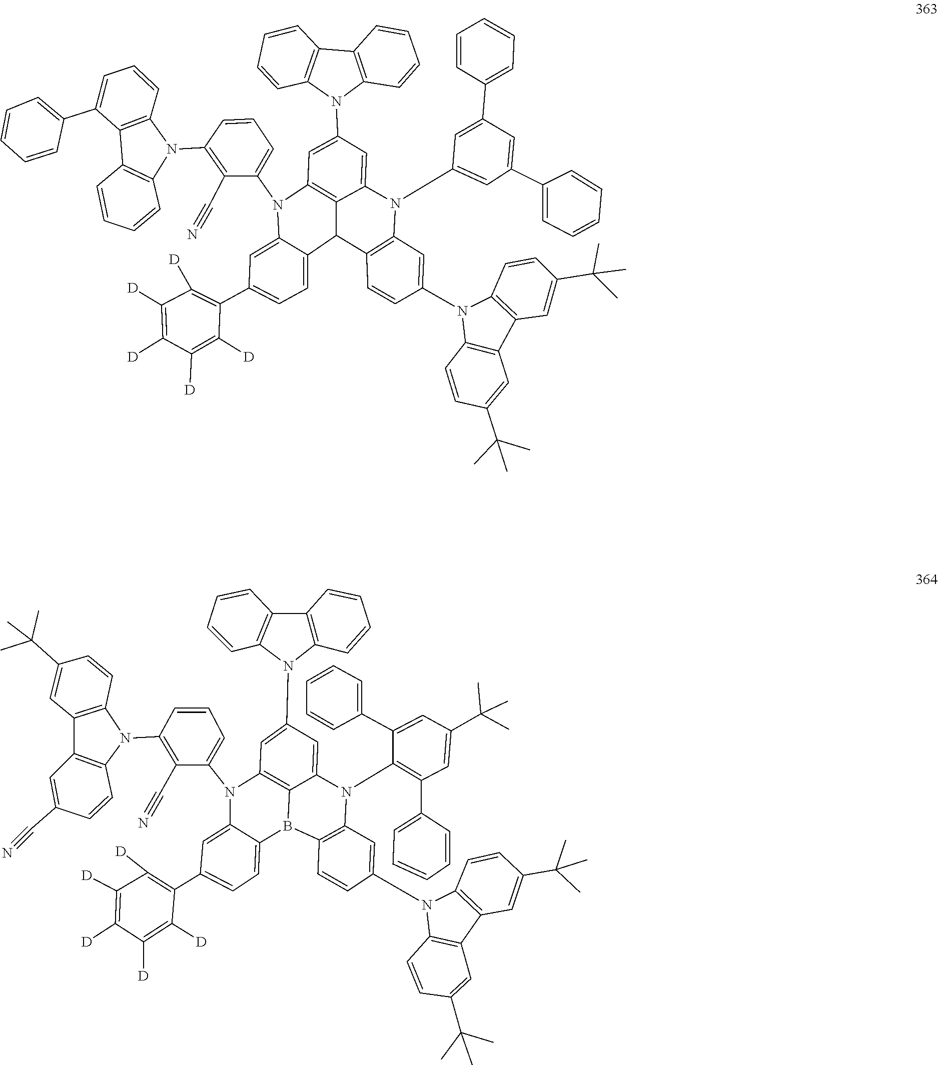 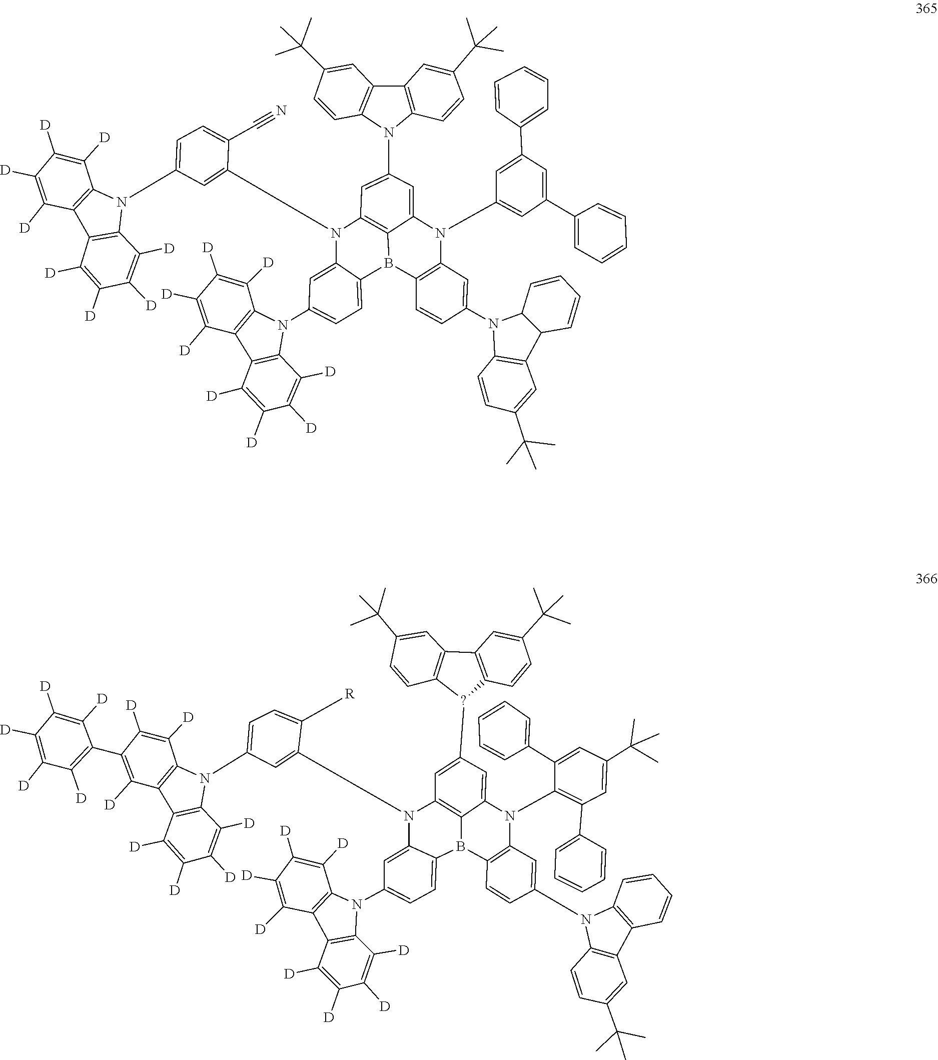 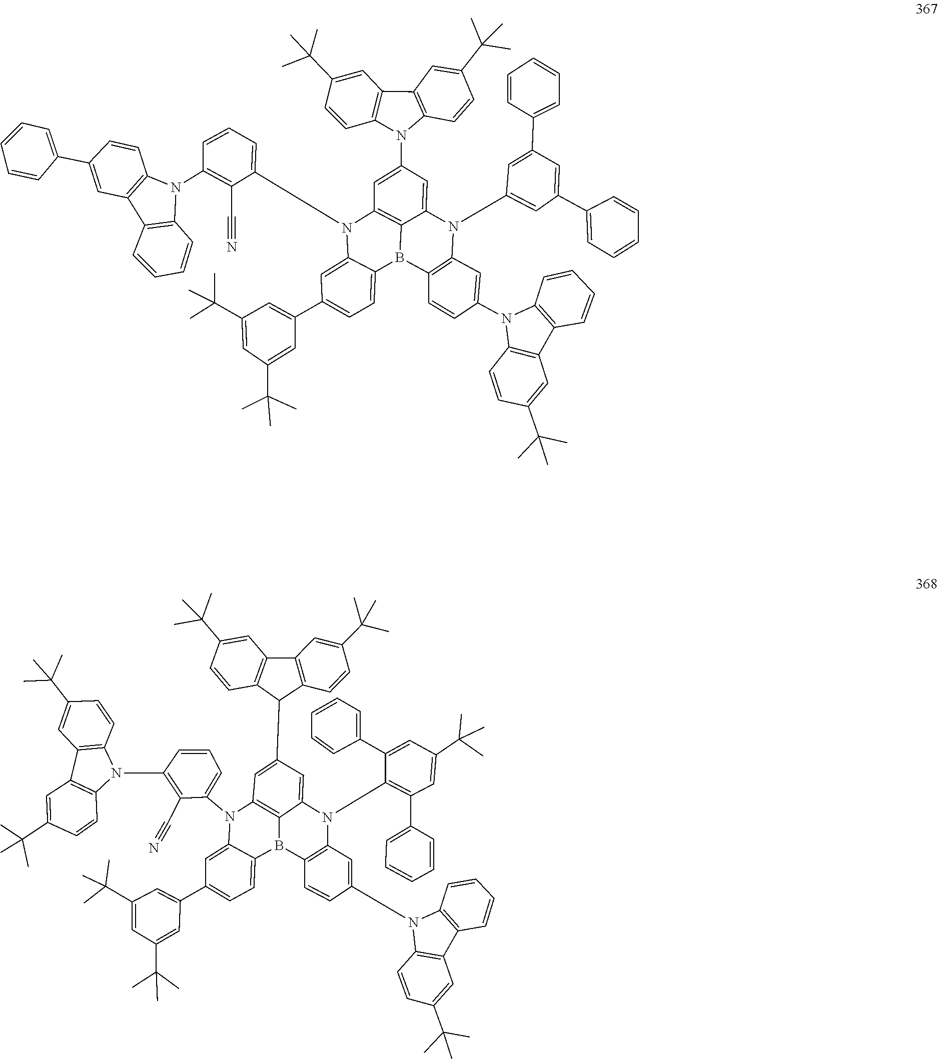 [SMILES: CC(C)(C)c1cc(-c2ccc3c(c2)N(c2cccc(-n4c5ccccc5c5cc(-c6ccccc6)ccc54)c2C#N)c2cc(-n4c5ccc(C(C)(C)C)cc5c5cc(C(C)(C)C)ccc54)cc4c2B3c2ccc(-n3c5ccccc5c5cc(C(C)(C)C)ccc53)cc2N4c2cc(-c3ccccc3)cc(-c3ccccc3)c2)cc(C(C)(C)C)c1 ; CC(C)(C)c1cc(-c2ccc3c(c2)N(c2cccc(-n4c5ccc(C(C)(C)C)cc5c5cc(C(C)(C)C)ccc54)c2C#N)c2cc(C4c5ccc(C(C)(C)C)cc5-c5cc(C(C)(C)C)ccc54)cc4c2B3c2ccc(-n3c5ccccc5c5cc(C(C)(C)C)ccc53)cc2N4c2c(-c3ccccc3)cc(C(C)(C)C)cc2-c2ccccc2)cc(C(C)(C)C)c1] 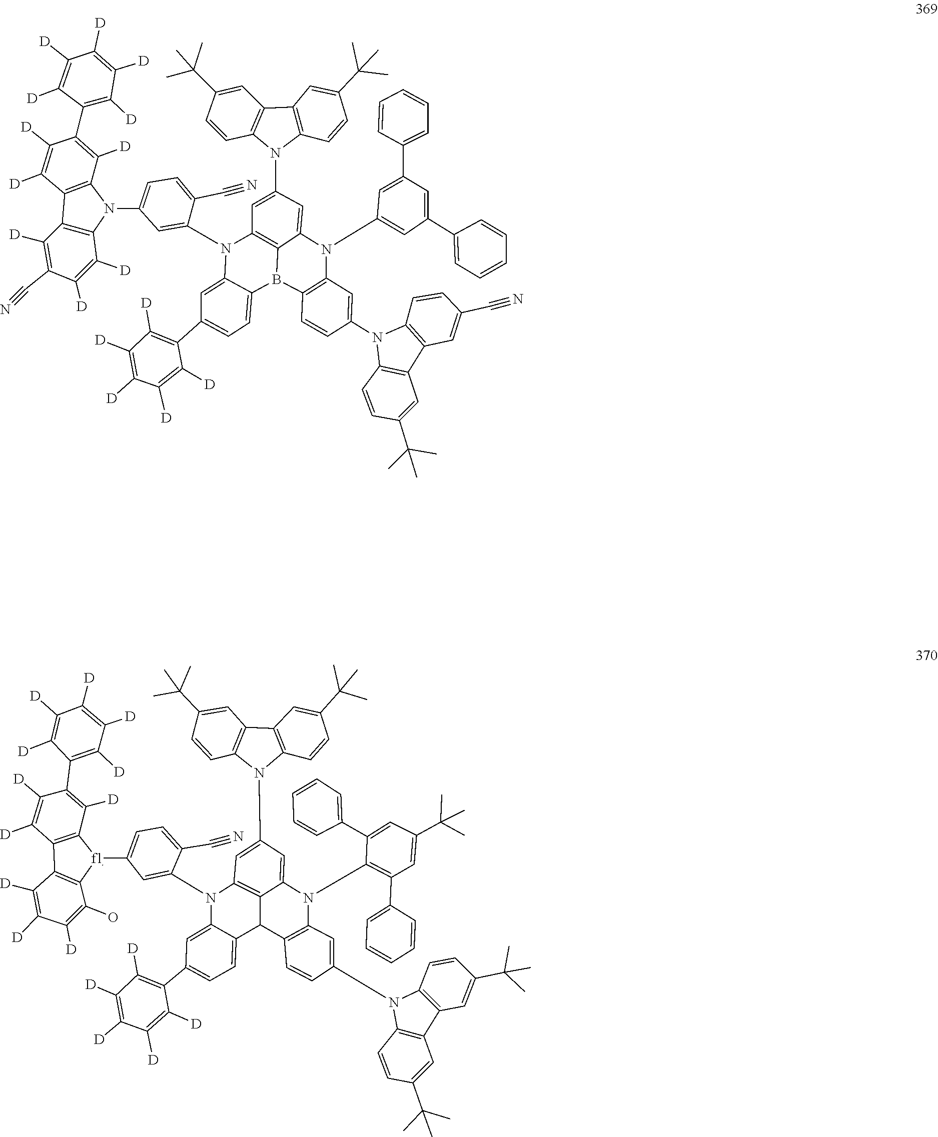 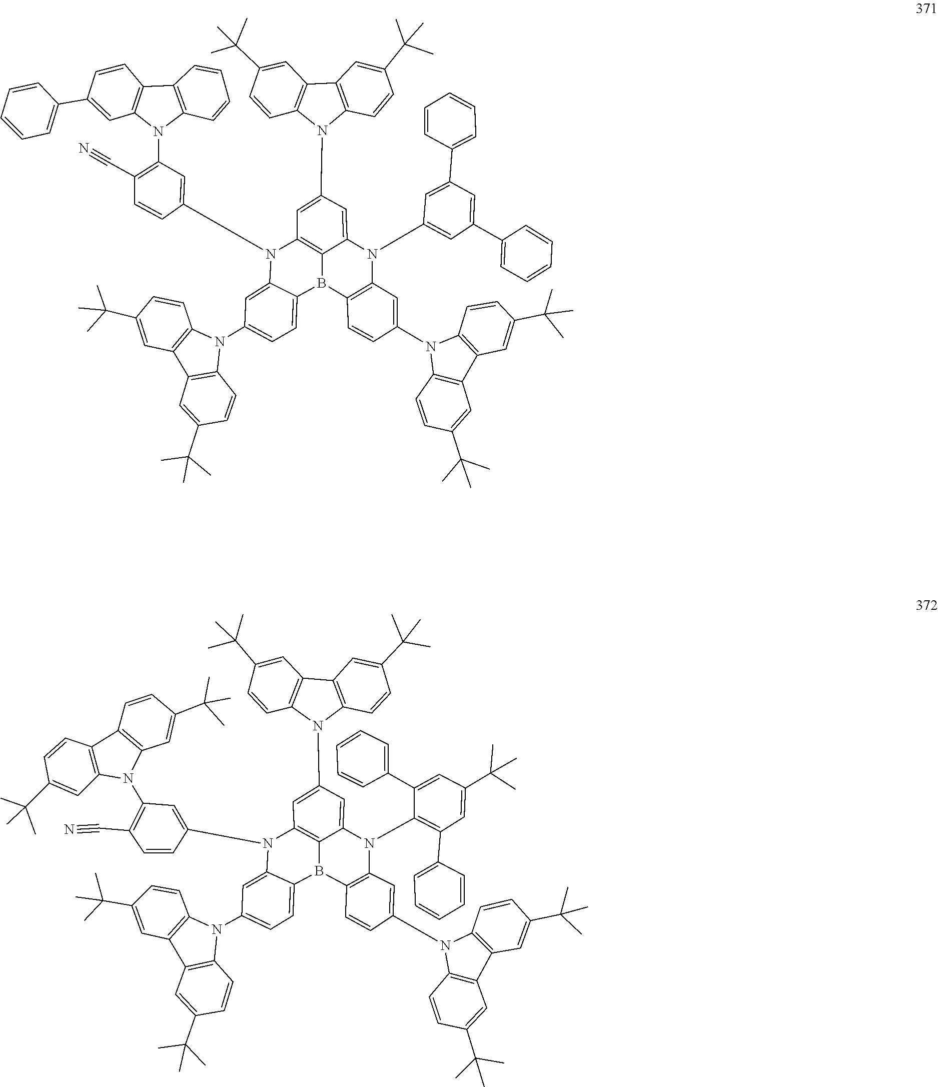
in Compound Group 1, “D” is a deuterium atom.

20. A display device comprising:
a base layer;
a circuit layer on the base layer; and
a display element layer which is on the circuit layer and comprises a light emitting element,
the light emitting element comprising a first electrode, a second electrode on the first electrode, and an emission layer which is between the first electrode and the second electrode and comprises a first compound represented by Formula 1: 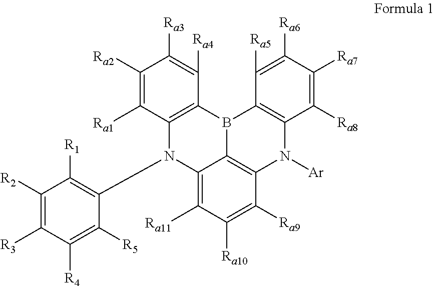
in Formula 1,
Rₐ₁ to Rₐ₁₁ and R₁ to R₅ are each independently a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one selected from among R₁ to R₅ is a cyano group and at least one remaining R₁ to R₅ is a substituent represented by Formula 2, and
Ar is a substituted or unsubstituted aryl group having 6 to 30 ring-forming carbon atoms, or a substituted or unsubstituted heteroaryl group having 2 to 30 ring-forming carbon atoms, 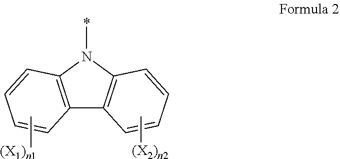
in Formula 2,
X₁ and X₂ are each independently a hydrogen atom, a deuterium atom, a halogen atom, a cyano group, a hydroxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1 and n2 are each independently an integer of 0 to 4, and 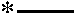 [SMILES: *C]
is a position linked to Formula 1.
